(19) United States
(12) Patent Application Publication
(10) Pub. No.: US 2026/0007071 A1
(43) Pub. Date: Jan. 1, 2026

(54) ORGANIC LIGHT-EMITTING DEVICE AND ORGANIC LIGHT-EMITTING DISPLAY DEVICE COMPRISING THE SAME

(71) Applicant: MATERIAL SCIENCE CO., LTD., Hwaseong-si (KR)

(72) Inventors: Tae Wan LEE, Hwaseong-si (KR); Sang-Hoon HONG, Hwaseong-si (KR)

(21) Appl. No.: 19/234,604

(22) Filed: Jun. 11, 2025

(30) Foreign Application Priority Data
Jun. 26, 2024 (KR) 10-2024-0084058

(51) Int. Cl. H10K 85/60; H10K 50/17

(52) U.S. Cl. CPC H10K 85/633; H10K 85/636; H10K 50/17; H10K 85/615; H10K 85/626; H10K 85/6574; H10K 85/6576

(57) ABSTRACT

The hole injection layer formed by containing the first compound represented by one of Chemical Formulas 1 and 2 and the second compound represented by Chemical Formula 3 in accordance with the present disclosure has excellent hole injection performance, and thus, the organic light-emitting device including the hole injection layer can ensure low driving voltage, high efficiency, and long-lifetime characteristics. In addition, the p-type charge generation layer formed by containing the first compound represented by one of Chemical Formulas 1 and 2 and the second compound represented by Chemical Formula 3 in accordance with the present disclosure facilitates hole and electron movement in a plurality of emitting stacks, and thus, the organic light-emitting device including the p-type charge generation layer can ensure low driving voltage, high efficiency, and long-lifetime characteristics.

### CROSS-REFERENCE TO RELATED APPLICATION

The present application claims priority under 35 U.S.C § 119 to Korean Patent Application No. 10-2024-0084058 filed on Jun. 26, 2024, in the Korean Intellectual Property Office, the entire contents of which are hereby incorporated by reference.

### TECHNICAL FIELD

The present disclosure relates to an organic light-emitting device and an organic light-emitting display device including the same.

### BACKGROUND

Organic light-emitting devices (OLEDs) have a simple structure and various advantages in manufacturing processes compared to other flat panel display devices such as conventional liquid crystal displays (LCDs), plasma display panels (PDPs), and field emission displays (FEDs), and with the advantages of high brightness and excellent viewing angle characteristics, fast response speed, and low driving voltage, they have been actively developed and commercialized to be used as light sources for flat panel displays such as wall-mounted TVs, or backlights for displays, lighting, billboards, and the like.

Organic light-emitting devices were first reported by C. W. Tang et al. of Eastman Kodak Company (C. W. Tang, S. A. Vanslyke, Applied Physics Letters, Vol. 51, p. 913, 1987), and the principle of light emission is generally based on the fact that when a voltage is applied, holes injected from the anode and electrons injected from the cathode recombine to form excitons, which are electron-hole pairs, and the energy of these excitons is transferred to a light-emitting material, thereby being converted into light.

Organic light-emitting devices have a structure including an anode (hole injection electrode), a cathode (electron injection electrode), and one or more intermediate layers disposed between the two electrodes. In the organic light-emitting device, a hole injection layer (HIL), a hole transport layer (HTL), a light-emitting layer (EML), an electron transport layer (ETL), or an electron injection layer (EIL) are stacked in order from the anode, and to increase the efficiency of the light-emitting layer, an electron-blocking layer (EBL), a hole-blocking layer (HBL), or the like may be further included in contact with the light-emitting layer, respectively.

### PRIOR ART LITERATURE

### Patent Documents

(Patent Document 1) Korean Patent No. 10-2086890

### SUMMARY

It is an object of the present disclosure to provide a hole injection layer to which a plurality of species of materials that can improve the driving voltage, efficiency, and lifetime characteristics of an organic light-emitting device is applied, an organic light-emitting device including the same, and an organic light-emitting display device including the same.

In addition, it is an object of the present disclosure to provide a p-type charge generation layer to which a plurality of species of materials that can improve the driving voltage, efficiency, and lifetime characteristics of an organic light-emitting device is applied, an organic light-emitting device including the same, and an organic light-emitting display device including the same.

The objects of the present disclosure are not limited to those mentioned above, and other objects and advantages of the present disclosure that have not been mentioned can be understood through the following description and will be more clearly understood with the embodiments of the present disclosure.

Moreover, it will be readily appreciated that the objects and advantages of the present disclosure can be realized by the means set forth in the claims and combinations thereof.

In order to achieve the above objects, according to one aspect of the present disclosure, an organic light-emitting device including an anode; a cathode facing the anode; and one or more intermediate layers between the anode and the cathode may be provided, wherein at least one of the intermediate layers includes a hole injection layer, and the hole injection layer contains a first compound represented by one of the following Chemical Formulas 1 and 2 and a second compound represented by the following Chemical Formula 3:

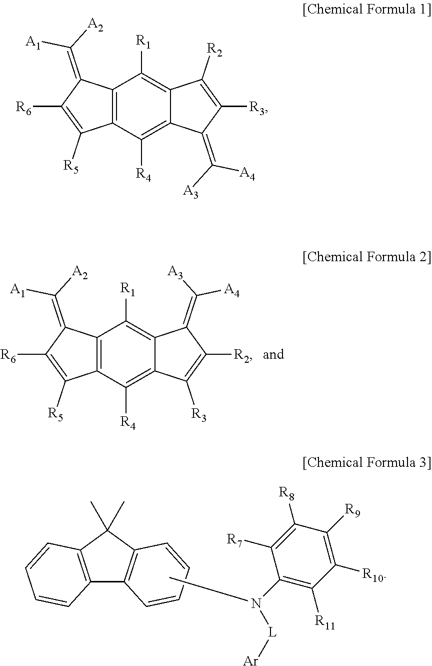

According to another aspect of the present disclosure, an organic light-emitting device including an anode; a cathode facing the anode; and N emitting stacks between the anode and the cathode may be provided, wherein said N is an integer greater than or equal to 2, and

N−1 n-type charge generation layers and N−1 p-type charge generation layers are disposed between the N emitting stacks, and at least one of the p-type charge generation layers contains a first compound represented by one of Chemical Formulas 1 and 2 above and a second compound represented by Chemical Formula 3 above.

The hole injection layer formed by containing the first compound represented by one of Chemical Formulas 1 and 2 and the second compound represented by Chemical Formula 3 in accordance with the present disclosure has excellent hole injection performance, and thus, the organic light-emitting device including the hole injection layer can ensure low driving voltage, high efficiency, and long-lifetime characteristics.

In addition, the p-type charge generation layer formed by containing the first compound represented by one of Chemical Formulas 1 and 2 and the second compound represented by Chemical Formula 3 in accordance with the present disclosure facilitates hole and electron movement in a plurality of emitting stacks, and thus, the organic light-emitting device including the p-type charge generation layer can ensure low driving voltage, high efficiency, and long-lifetime characteristics.

The effects of the present disclosure are not limited to those mentioned above, and other effects that have not been mentioned will be clearly understood by those having ordinary skill in the art from the description below.

### BRIEF DESCRIPTION OF THE DRAWINGS

FIG. 1 schematically shows an organic light-emitting device including a hole injection layer in accordance with one embodiment of the present disclosure;

FIG. 2 schematically shows an organic light-emitting device in a tandem structure including two emitting stacks in which a p-type charge generation layer is disposed in accordance with one embodiment of the present disclosure; and

FIG. 3 schematically shows an organic light-emitting device in a tandem structure including three emitting stacks in which a p-type charge generation layer is disposed in accordance with one embodiment of the present disclosure.

### DETAILED DESCRIPTION OF THE PREFERRED EMBODIMENTS

The foregoing objects, features, and advantages will be described in detail below, and accordingly, those having ordinary skill in the art to which the present disclosure pertains will be able to readily practice the technical ideas of the present disclosure. In describing the present disclosure, if it is determined that specific descriptions of known technologies related to the present disclosure may unnecessarily obscure the gist of the present disclosure, the detailed descriptions will be omitted.

When expressions, such as “includes”, “has,” “consists of”, “arranges” and “is provided with” a component, are used herein, other parts may be added unless “only” is used. When a component is expressed in its singular form, it also encompasses instances where the plural form applies, unless specifically stated otherwise.

In construing components herein, it is construed to include margins of error even if there is no separate explicit description.

A description herein that an arbitrary element is disposed “above (or below)” a component or “on (or under)” the component may mean not only that the arbitrary element is disposed in contact with the upper surface (or lower surface) of the component but also that another element may be interposed between the component and the arbitrary element disposed on (or under) the component.

The term “halogen group” as used herein includes fluorine, chlorine, bromine, and iodine.

The term “alkyl group” as used herein refers to both straight-chain alkyl radicals and branched-chain alkyl radicals. Unless particularly limited, the alkyl group contains 1 to 10 carbon atoms and may include, but is not limited to, methyl, ethyl, propyl, isopropyl, butyl, sec-butyl, isobutyl, tert-butyl, pentyl, isoamyl, hexyl, and the like. In addition, the alkyl group may be optionally substituted.

The term “cycloalkyl group” as used herein refers to a cyclic alkyl radical. Unless particularly limited, the cycloalkyl group contains 3 to 10 carbon atoms and may include, but is not limited to, cyclopropyl, cyclobutyl, cyclopentyl, cyclohexyl, norbornyl, adamantyl, and the like. In addition, the cycloalkyl group may be optionally substituted.

The term “alkenyl group” as used herein refers to both straight-chain alkenyl radicals and branched-chain alkenyl radicals having one or more carbon-carbon double bonds. Unless particularly limited, the alkenyl group contains 2 to 10 carbon atoms and may include, but is not limited to, vinyl, allyl, isopropenyl, 2-butenyl, and the like. In addition, the alkenyl group may be optionally substituted.

The term “cycloalkenyl group” as used herein refers to cyclic alkenyl radicals. Unless particularly limited, the cycloalkenyl group contains 3 to 10 carbon atoms, and furthermore, the cycloalkenyl group may be optionally substituted.

The term “alkynyl group” as used herein refers to both straight-chain alkynyl radicals and branched-chain alkynyl radicals having one or more carbon-carbon triple bonds. Unless particularly limited, the alkynyl group contains 2 to 30 carbon atoms, and may include, but is not limited to, ethynyl, 2-propynyl, and the like. In addition, the alkynyl group may be optionally substituted.

The term “cycloalkynyl group” as used herein refers to cyclic alkynyl radicals. Unless particularly limited, the cycloalkynyl group contains 3 to 20 carbon atoms, and furthermore, the cycloalkynyl group may be optionally substituted.

The terms “aralkyl group” or “arylalkyl group” as used herein are used interchangeably and refer to an alkyl group having an aromatic group as a substituent, and furthermore, the aralkyl group (arylalkyl group) may be optionally substituted.

The terms “aryl group” or “aromatic group” as used herein are used in the same meaning, and the aryl group includes both a monocyclic ring group and a polycyclic ring group. The polycyclic ring may include a “fused ring” that consists of two or more rings in which two carbons are common to two adjacent rings. It may also include forms in which two or more rings are simply attached or fused to each other. Unless particularly limited, the aryl group contains 6 to 30 carbon atoms and may include, but is not limited to, phenyl, naphthyl, anthracenyl, phenanthryl, fluorenyl, dimethylfluorenyl, diphenylfluorenyl, spirofluorenyl, and the like. In addition, the aryl group may be optionally substituted.

The terms “heteroaryl group” or “heteroaromatic group” as used herein are used in the same meaning, and the heteroaryl group includes both a monocyclic ring group and a polycyclic ring group. The polycyclic ring may include a “fused ring” that consists of two or more rings in which two carbons or heteroelements are common to two adjacent rings. It may also include forms in which two or more rings are simply attached or fused to each other. Unless particularly limited, the heteroaryl group contains 1 to 30 carbon atoms, and may form a ring by containing additional heteroelements when there are 1 or 2 carbon atoms. In addition, the heteroaryl group may contain 1 to 30 carbon atoms, wherein one or more carbons in the ring are substituted with heteroatoms such as oxygen (O), nitrogen (N), sulfur (S), or selenium (Se), and may include, but is not limited to, 6-membered monocyclic rings such as pyridyl, pyrazinyl, pyrimidinyl, pyridazinyl, and triazinyl, polycyclic rings such as phenoxathiinyl, indolizinyl, indolyl, purinyl, quinolyl, isoquinolyl, benzoxyzolyl, benzothiazolyl, dibenzoxyzolyl, dibenzothiazolyl, benzoimidazolyl, benzofuranyl, dibenzofuranyl, benzothiophenyl, dibenzothiophenyl, phenylcarbezolyl, 9-phenylcarbazolyl, and carbazolyl, and 2-furanyl, N-imidazolyl, 2-isoxazolyl, 2-pyridinyl, 2-pyrimidinyl, and the like. In addition, the heteroaryl group may be optionally substituted.

The term “heterocyclic group” as used herein refers to one in which one or more of the carbon atoms constituting an aryl group, a cycloalkyl group, a cycloalkenyl group, a cycloalkynyl group, an arylalkyl group, an arylamino group, or the like are substituted by heteroatoms such as oxygen (O), nitrogen (N), sulfur (S), or the like, and with reference to the above definition, includes a heteroaryl group, a heterocycloalkyl group, a heterocycloalkenyl group, a heterocycloalkynyl group, a heteroarylalkyl group, a heteroarylamino group, and the like, and furthermore, the heterocyclic group may be optionally substituted.

The term “carbon ring” as used herein may be used as a term including both “a cycloalkyl group”, “a cycloalkenyl group”, “a cycloalkynyl group”, which are alicyclic ring groups, and “an aryl group (an aromatic group)”, which is an aromatic ring group, unless particularly limited.

The terms “heteroalkyl group”, “heteroalkenyl group”, “heteroalkynyl group”, and “heteroarylalkyl group” as used herein refer to ones that one or more of the carbon atoms constituting the groups are substituted by heteroatoms such as oxygen (O), nitrogen (N), sulfur (S), and furthermore, the heteroalkyl group, heteroalkenyl group, heteroalkynyl group, and heteroarylalkyl group may be optionally substituted.

The terms “alkylamino group”, “arylalkylamino group”, “arylamino group”, and “heteroarylamino group” as used herein refer to ones in which an amino group (or amine group) is substituted with the alkyl group, arylalkyl group, aryl group, or heteroaryl group, and that include all of primary, secondary, and tertiary amino groups (or amine groups), and furthermore, the alkylamino group, arylalkylamino group, arylamino group, and heteroarylamino group may be optionally substituted.

The terms “alkylsilyl group”, “arylsilyl group”, “alkoxy group”, “aryloxy group”, “alkylthio group”, and “arylthio group” as used herein refer to ones in which a silyl group, an oxy group, and a thio group are substituted with the alkyl group and the aryl group, respectively, and furthermore, the alkylsilyl group, arylsilyl group, alkoxy group, aryloxy group, alkylthio group, and arylthio group may be optionally substituted.

The terms “arylene group”, “arylalkylene group”, “heteroarylene group”, and “heteroarylalkylene group” as used herein refer to divalent substituents in which each of the aryl group, arylalkyl group, heteroaryl group, and heteroarylalkyl group contains one more substituent. In addition, the arylene group, arylalkylene group, heteroarylene group, and heteroarylalkylene group may be optionally substituted.

The term “substituted” as used herein means that a hydrogen (H) atom bonded to a carbon atom of a compound of the present disclosure is replaced by a substituent other than hydrogen, and if there is a plurality of substituents, the respective substituents may be the same or different from each other.

The substituents may each be selected independently from the group consisting of deuterium, a cyano group, a nitro group, a halogen group, a hydroxy group, an alkyl group having 1 to 30 carbon atoms, an alkenyl group having 2 to 30 carbon atoms, an alkynyl group having 2 to 24 carbon atoms, a heteroalkyl group having 2 to 30 carbon atoms, an aralkyl group having 6 to 30 carbon atoms, a cycloalkyl group having 3 to 20 carbon atoms, a heterocycloalkyl group having 3 to 20 carbon atoms, an aryl group having 6 to 30 carbon atoms, a heteroaryl group having 2 to 30 carbon atoms, a heteroarylalkyl group having 3 to 30 carbon atoms, an alkoxy group having 1 to 30 carbon atoms, an alkylsilyl group having 1 to 30 carbon atoms, an arylsilyl group having 6 to 30 carbon atoms, and an aryloxy group having 6 to 30 carbon atoms.

Unless particularly limited herein, a substituted position is not limited as long as it is a position where a hydrogen atom is substituted, i.e., a position where a substituent can substitute, and if there are two or more substituents present, the substituents may be the same or different from each other.

Each subject and substituent defined herein may be the same or different unless particularly stated.

The standard for units herein is based on weight (wt) unless particularly stated. For example, if there is a description in “%”, it is interpreted as weight % (wt %).

Hereinafter, an organic light-emitting device and an organic light-emitting display device of the present disclosure will be described in detail.

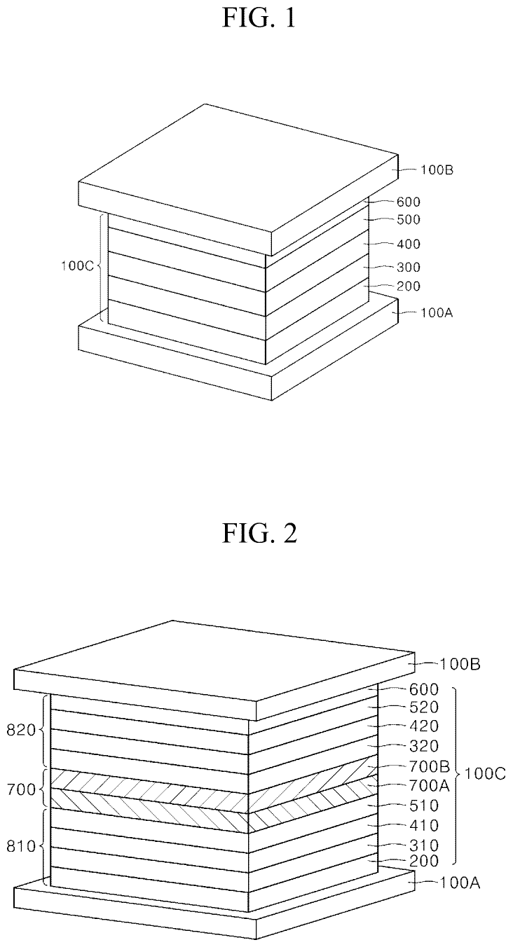

Referring to FIG. 1 in accordance with one aspect of the present disclosure, in the organic light-emitting device, an intermediate layer 100C disposed between an anode 100A and a cathode 100B may include a hole injection layer (HIL) 200, a hole transfer layer (HTL) 300, an emission material layer (EML) 400, an electron transfer layer (ETL) 500, and an electron injection layer (EIL) 600 in sequence from the anode 100A, and the cathode 100B may be formed on the electron injection layer 600, and a protective film (not shown) may be formed thereon.

According to one implementation of the present disclosure, at least one in the intermediate layer 100C may include the hole injection layer 200, and the hole injection layer 200 may include a first compound represented by one of the following Chemical Formulas 1 and 2 and a second compound represented by the following Chemical Formula 3. The hole injection layer 200 acts to improve the interface characteristics between the anode 100A and the hole transfer layer 300, and when the hole injection layer 200 is manufactured using the first compound and the second compound in accordance with the present disclosure together, the organic light-emitting device can ensure low driving voltage, high efficiency, and long-lifetime characteristics.

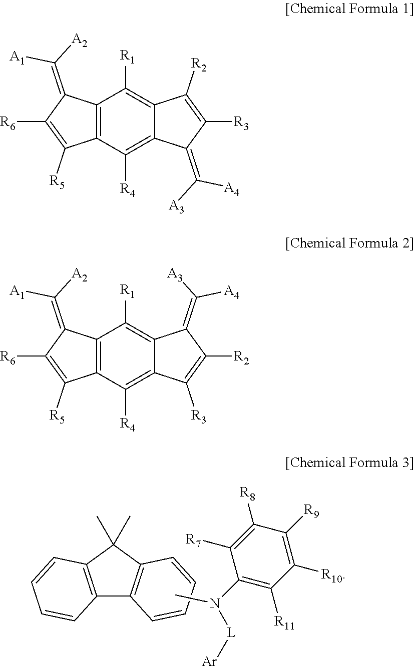

In Chemical Formulas 1 to 3 above,
R₁ to R₁₁ and A₁ to A₄ may be the same or different from each other, and may each be selected independently from the group consisting of hydrogen, deuterium, a cyano group, a trifluoromethyl group, a nitro group, a halogen group, a hydroxy group, a substituted or unsubstituted alkyl group having 1 to 30 carbon atoms, a substituted or unsubstituted cycloalkyl group having 3 to 20 carbon atoms, a substituted or unsubstituted alkenyl group having 2 to 30 carbon atoms, a substituted or unsubstituted cycloalkenyl group having 3 to 20 carbon atoms, a substituted or unsubstituted alkynyl group having 2 to 30 carbon atoms, a substituted or unsubstituted cycloalkynyl group having 3 to 20 carbon atoms, a substituted or unsubstituted aryl group having 6 to 30 carbon atoms, a substituted or unsubstituted arylalkyl group having 7 to 30 carbon atoms, a substituted or unsubstituted heteroaryl group having 5 to 60 carbon atoms, a substituted or unsubstituted heteroarylalkyl group having 6 to 60 carbon atoms, a substituted or unsubstituted amine group, a substituted or unsubstituted alkylamino group having 1 to 30 carbon atoms, an arylalkylamino group having 7 to 30 carbon atoms, a substituted or unsubstituted arylamino group having 6 to 30 carbon atoms, a substituted or unsubstituted heteroarylamino group having 5 to 60 carbon atoms, a substituted or unsubstituted silyl group, a substituted or unsubstituted alkylsilyl group having 1 to 30 carbon atoms, a substituted or unsubstituted arylsilyl group having 6 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthio group having 1 to 30 carbon atoms, and a substituted or unsubstituted arylthio group having 6 to 30 carbon atoms,
at least one or more of R₇, R₉, and R₁₁ above may be selected from the group consisting of a substituted or unsubstituted alkyl group having 1 to 30 carbon atoms, a substituted or unsubstituted aryl group having 5 to 30 carbon atoms, and a substituted or unsubstituted heteroaryl group having 3 to 30 carbon atoms,
L may each be selected independently from a single bond, a substituted or unsubstituted aryl group having 6 to 30 carbon atoms, and a substituted or unsubstituted heteroaryl group having 6 to 30 carbon atoms,
Ar may be the same or different from each other, and may each be selected independently from a substituted or unsubstituted aryl group having 6 to 30 carbon atoms and a substituted or unsubstituted heteroaryl group having 5 to 60 carbon atoms, wherein Ar does not include a 9,9-diphenylfluorene group, and
if substituents of R₁ to R₁₁ and A₁ to A₄, L, and Ar above are present, the substituents may each be substituted independently by one or more substituents selected from the group consisting of a cyano group, a trifluoromethyl group, a nitro group, a halogen group, a hydroxy group, an alkyl group having 1 to 30 carbon atoms, a cycloalkyl group having 3 to 20 carbon atoms, an alkenyl group having 2 to 30 carbon atoms, a cycloalkenyl group having 3 to 20 carbon atoms, an alkynyl group having 2 to 30 carbon atoms, a cycloalkynyl group having 3 to 20 carbon atoms, an aryl group having 6 to 30 carbon atoms, an arylalkyl group having 7 to 30 carbon atoms, a heteroaryl group having 5 to 60 carbon atoms, a heteroarylalkyl group having 6 to 60 carbon atoms, an amine group, an alkylamino group having 1 to 30 carbon atoms, an arylalkylamino group having 7 to 30 carbon atoms, an arylamino group having 6 to 30 carbon atoms, a heteroarylamino group having 5 to 60 carbon atoms, an alkylsilyl group having 1 to 30 carbon atoms, an arylsilyl group having 6 to 30 carbon atoms, an alkoxy group having 1 to 30 carbon atoms, an aryloxy group having 6 to 30 carbon atoms, an alkylthio group having 1 to 30 carbon atoms, and an arylthio group having 6 to 30 carbon atoms, and if substituted by a plurality of substituents, they may be the same or different from each other.

According to one implementation of the present disclosure, A₁ to A₄ above may be the same or different from each other, and may each be selected independently from the group consisting of hydrogen; a cyano group; an unsubstituted aryl group having 6 to 30 carbon atoms, an aryl group having 6 to 30 carbon atoms substituted with one or more selected from a halogen group and a cyano group; an unsubstituted heteroaryl group having 5 to 60 carbon atoms; and a heteroaryl group having 5 to 60 carbon atoms substituted with one or more selected from a halogen group and a cyano group.

According to one implementation of the present disclosure, A₁ to A₄ above may be the same or different from each other, and may each be selected independently from the group consisting of hydrogen; a cyano group; an unsubstituted phenyl group; a phenyl group substituted with one or more selected from a halogen group and a cyano group; an unsubstituted pyridyl group; and a pyridyl group substituted with one or more selected from a halogen group and a cyano group.

According to one implementation of the present disclosure, A₁ to A₄ above may be the same or different from each other, and may each be selected independently from the group consisting of hydrogen; a cyano group; an unsubstituted phenyl group; a phenyl group substituted with one or more selected from a fluorine group (F) and a cyano group; an unsubstituted pyridyl group; and a pyridyl group substituted with one or more selected from a fluorine group and a cyano group.

According to one implementation of the present disclosure, R₁ and R₄ above may be the same or different from each other, and may each be selected independently from the group consisting of hydrogen; a halogen group; a cyano group; a pyridyl group; a haloalkyl group; a haloalkoxy group; an unsubstituted aryl group having 6 to 30 carbon atoms; an aryl group having 6 to 30 carbon atoms substituted with one or more selected from a cyano group, a haloalkyl group, and a haloalkoxy group; an unsubstituted heteroaryl group having 5 to 60 carbon atoms; and a heteroaryl group having 5 to 60 carbon atoms substituted with one or more selected from a cyano group, a haloalkyl group, and a haloalkoxy group.

According to one implementation of the present disclosure, R₁ and R₄ above may be the same or different from each other, and may each be selected independently from the group consisting of hydrogen; a halogen group; a cyano group; a pyridyl group; a haloalkyl group; a haloalkoxy group; an unsubstituted phenyl group; and a phenyl group substituted with one or more selected from a cyano group, a haloalkyl group, and a haloalkoxy group.

According to one implementation of the present disclosure, R₁ and R₄ above may be the same or different from each other, and may each be selected independently from the group consisting of hydrogen; a fluorine group; a cyano group; a pyridyl group; a trifluoromethyl group (—CF₃); a trifluoromethoxy group (—OCF₃); an unsubstituted phenyl group; and a phenyl group substituted with one or more selected from a cyano group, a trifluoromethyl group, and a trifluoromethoxy group.

According to one implementation of the present disclosure, R₂, R₃, R₅, and R₆ above may be the same or different from each other, and may each be selected independently from the group consisting of hydrogen; a halogen group; a cyano group; a haloalkyl group; a haloalkoxy group; a halothioalkoxy group; a silyl group; an unsubstituted aryl group having 6 to 30 carbon atoms; a aryl group having 6 to 30 carbon atom substituted with a silyl group; an unsubstituted heteroaryl group having 5 to 60 carbon atoms; and a heteroaryl group having 5 to 60 carbon atoms substituted with a silyl group, and in this case, the silyl group may be further substituted with one or more selected from a halogen group, a cyano group, a haloalkyl group, a haloalkoxy group, a halothioalkoxy group, and an alkyl group.

R₂, R₃, R₅, and R₆ above may be the same or different from each other, and may each be selected independently from the group consisting of hydrogen; a halogen group; a cyano group; a haloalkyl group; a haloalkoxy group; a halothioalkoxy group; a silyl group; an unsubstituted phenyl group; a phenyl group substituted with a silyl group; an unsubstituted a pyridyl group; a pyridyl group substituted with a silyl group; an unsubstituted pyrimidyl group; and a pyrimidyl group substituted with a silyl group, and in this case, the silyl group may be further substituted with one or more selected from a halogen group, a cyano group, a haloalkyl group, a haloalkoxy group, a halothioalkoxy group, and an alkyl group.

R₂, R₃, R₅, and R₆ above may be the same or different from each other, and may each be selected independently from the group consisting of hydrogen; F; a cyano group; —CF₃; —OCF₃; SCF₃; —Si(CH₃)₃; a phenyl group; a pyridyl group; and a pyrimidyl group, and in this case, the phenyl group, pyridyl group, and pyrimidyl group may be further substituted with one or more selected from F, a cyano group, —CF₃, —OCF₃, SCF₃, and —Si(CH₃)₃, respectively.

According to one implementation of the present disclosure, Chemical Formula 3 above may be represented by one selected from the following Chemical Formulas 3-1 to 3-4, and is preferably one selected from the following Chemical Formulas 3-2 and 3-4, for example.

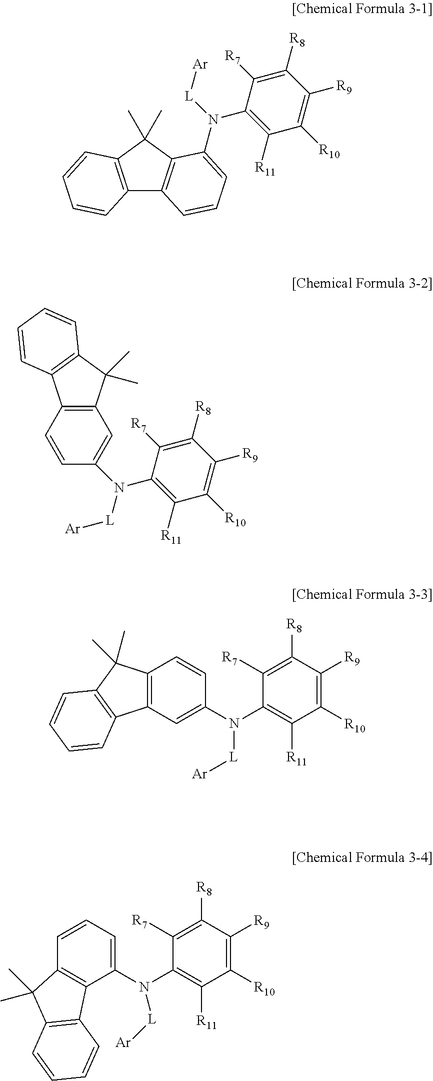

R₇ to R₁₁, L, and Ar above are the same as those defined in Chemical Formula 3 above.

Ar above may be the same or different from each other, and may each be selected independently from the group consisting of a phenyl group, a biphenyl group, a naphthyl group, a phenanthryl group, a 9,9-dimethylfluorenyl group, a dibenzofuranyl group, a dibenzothiophenyl group, a naphthyl group substituted with phenyl, a phenanthryl group substituted with phenyl, a 9,9-dimethylfluorenyl group substituted with phenyl, a dibenzofuranyl group substituted with phenyl, and a dibenzothiophenyl group substituted with phenyl.

The hole injection layer 200 of the present disclosure may contain the first compound and the second compound, and the first compound may be a p-type dopant, and the second compound may be a p-type host.

According to one implementation of the present disclosure, the hole injection layer 200 may consist of the first compound and the second compound.

According to one implementation of the present disclosure, based on 100 wt % of the total weight of the hole injection layer 200, the second compound may be contained in 50 to 90 wt %, and for example, the second compound may be contained in 60 to 80 wt %, for example, in 65 to 75 wt %, and accordingly, the hole injection performance can be made even better, thereby improving the performance of the organic light-emitting device including the same.

According to one implementation of the present disclosure, the structure of the first compound represented by one of Chemical Formulas 1 and 2 above may be selected from the group consisting of the following Compounds PD-1 to PD-450, but is not limited thereto as long as it falls within the definition of Chemical Formula 1 or 2.

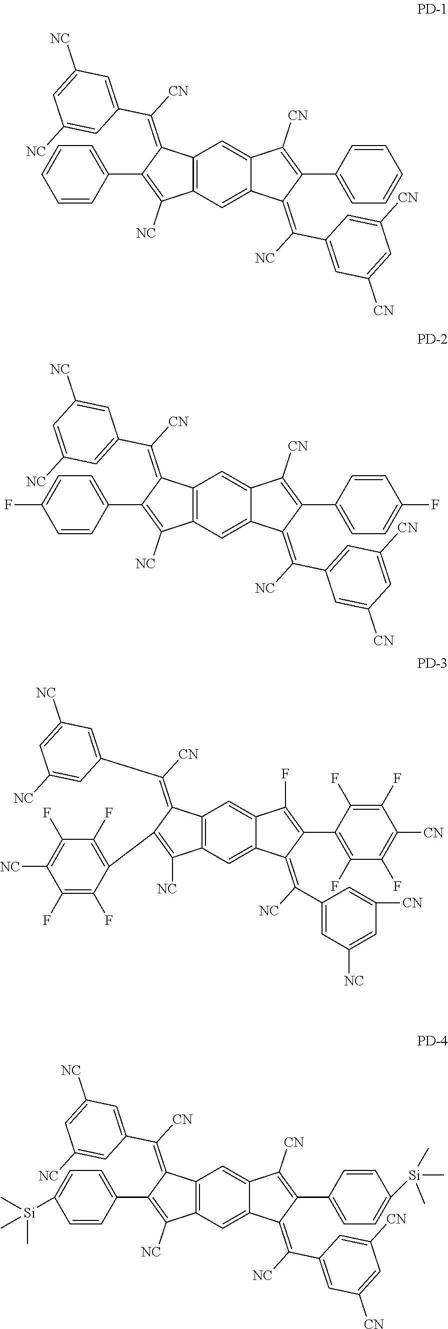

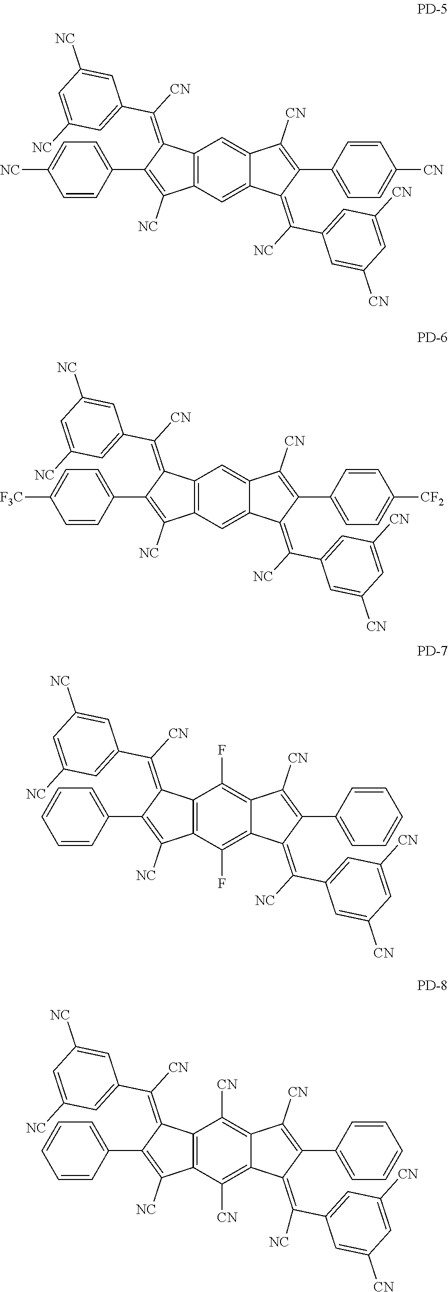

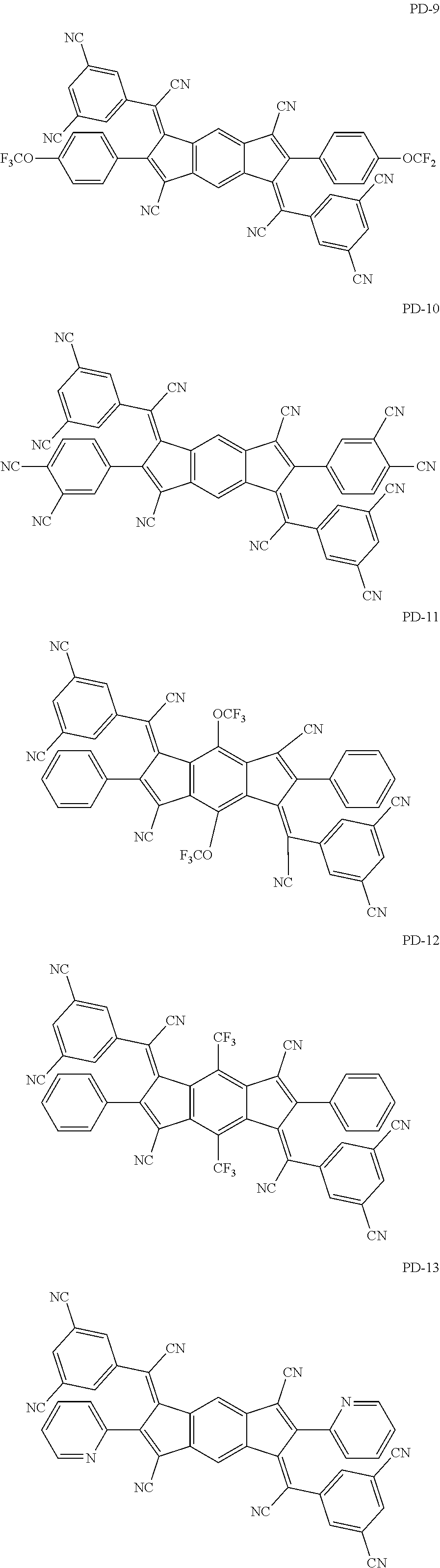

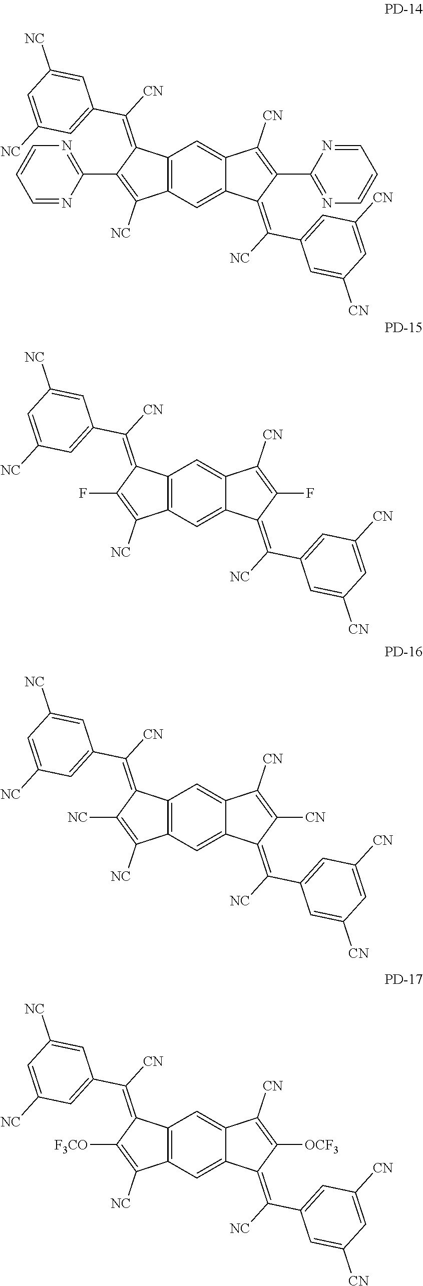 [SMILES: N#CC1=C(c2ncccn2)/C(=C(/C#N)c2cc(C#N)cc(C#N)c2)c2cc3c(cc21)/C(=C(\C#N)c1cc(C#N)cc(C#N)c1)C(c1ncccn1)=C3C#N ; N#CC1=C(F)/C(=C(/C#N)c2cc(C#N)cc(C#N)c2)c2cc3c(cc21)/C(=C(\C#N)c1cc(C#N)cc(C#N)c1)C(F)=C3C#N ; N#CC1=C(C#N)c2cc3c(cc2/C1=C(\C#N)c1cc(C#N)cc(C#N)c1)C(C#N)=C(C#N)/C3=C(/C#N)c1cc(C#N)cc(C#N)c1 ; N#CC1=C(OC(F)(F)F)/C(=C(/C#N)c2cc(C#N)cc(C#N)c2)c2cc3c(cc21)/C(=C(\C#N)c1cc(C#N)cc(C#N)c1)C(OC(F)(F)F)=C3C#N]

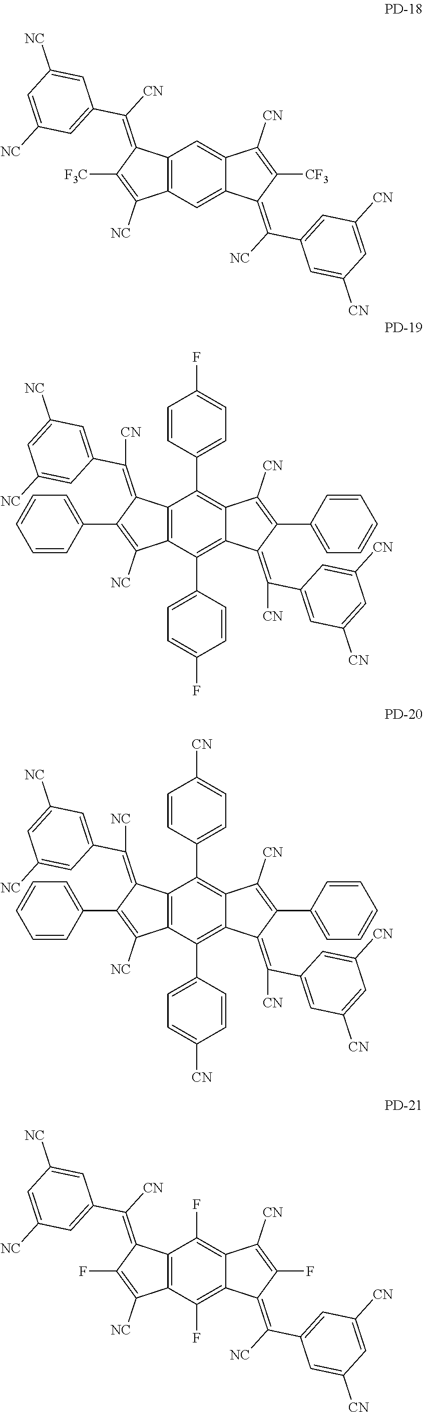 [SMILES: N#CC1=C(C(F)(F)F)/C(=C(/C#N)c2cc(C#N)cc(C#N)c2)c2cc3c(cc21)/C(=C(\C#N)c1cc(C#N)cc(C#N)c1)C(C(F)(F)F)=C3C#N ; N#CC1=C(c2ccccc2)/C(=C(/C#N)c2cc(C#N)cc(C#N)c2)c2c1c(-c1ccc(F)cc1)c1c(c2-c2ccc(F)cc2)C(C#N)=C(c2ccccc2)/C1=C(/C#N)c1cc(C#N)cc(C#N)c1 ; N#CC1=C(c2ccccc2)/C(=C(/C#N)c2cc(C#N)cc(C#N)c2)c2c1c(-c1ccc(C#N)cc1)c1c(c2-c2ccc(C#N)cc2)C(C#N)=C(c2ccccc2)/C1=C(/C#N)c1cc(C#N)cc(C#N)c1 ; N#CC1=C(F)/C(=C(/C#N)c2cc(C#N)cc(C#N)c2)c2c(F)c3c(c(F)c21)/C(=C(\C#N)c1cc(C#N)cc(C#N)c1)C(F)=C3C#N]

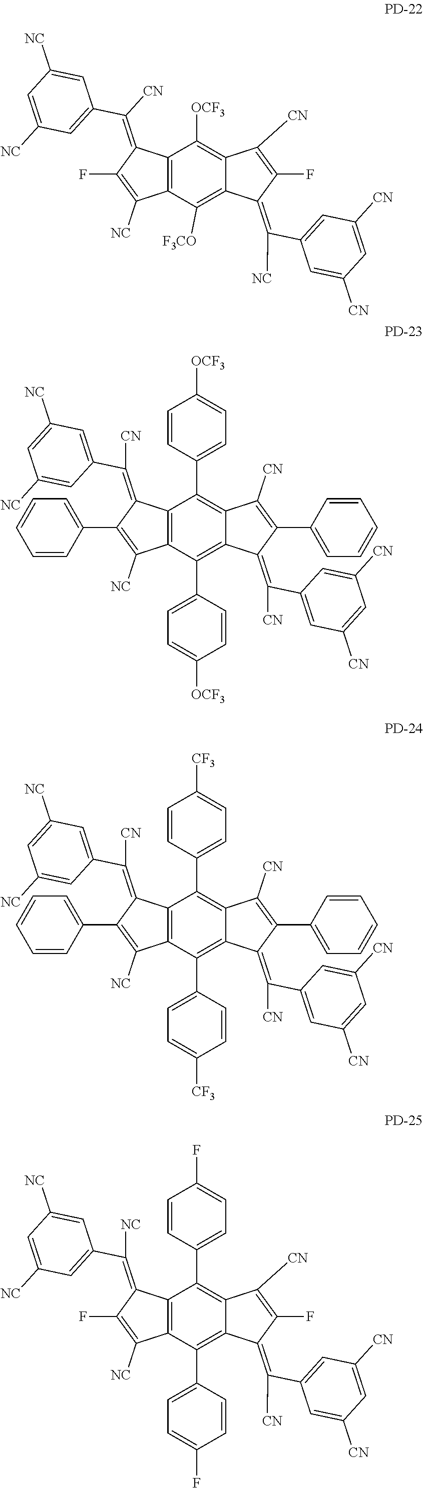

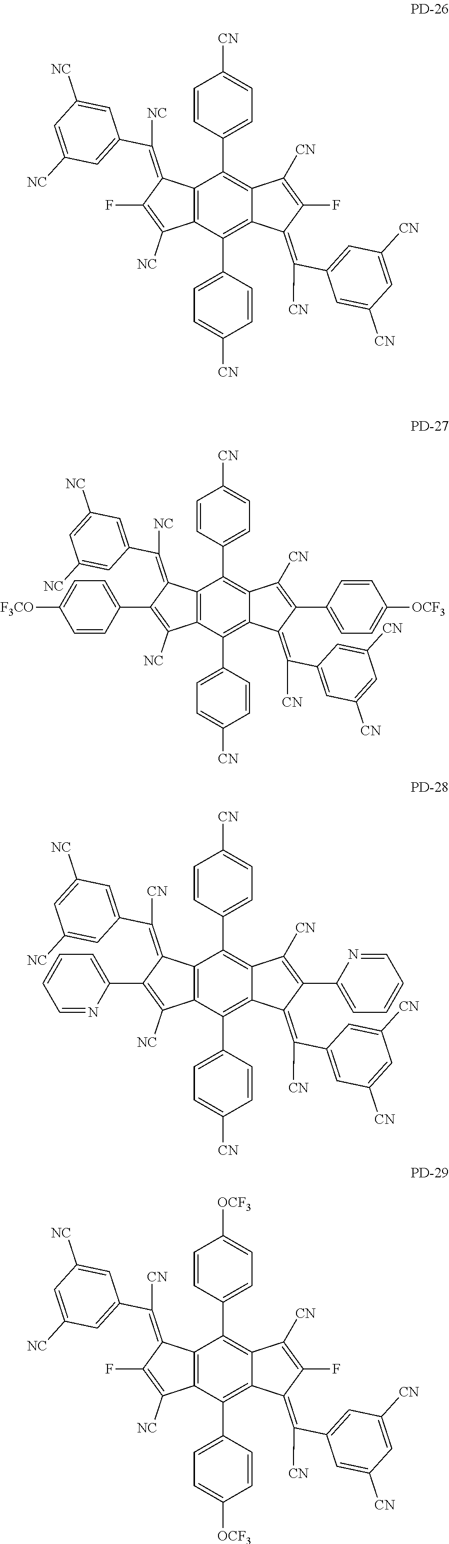

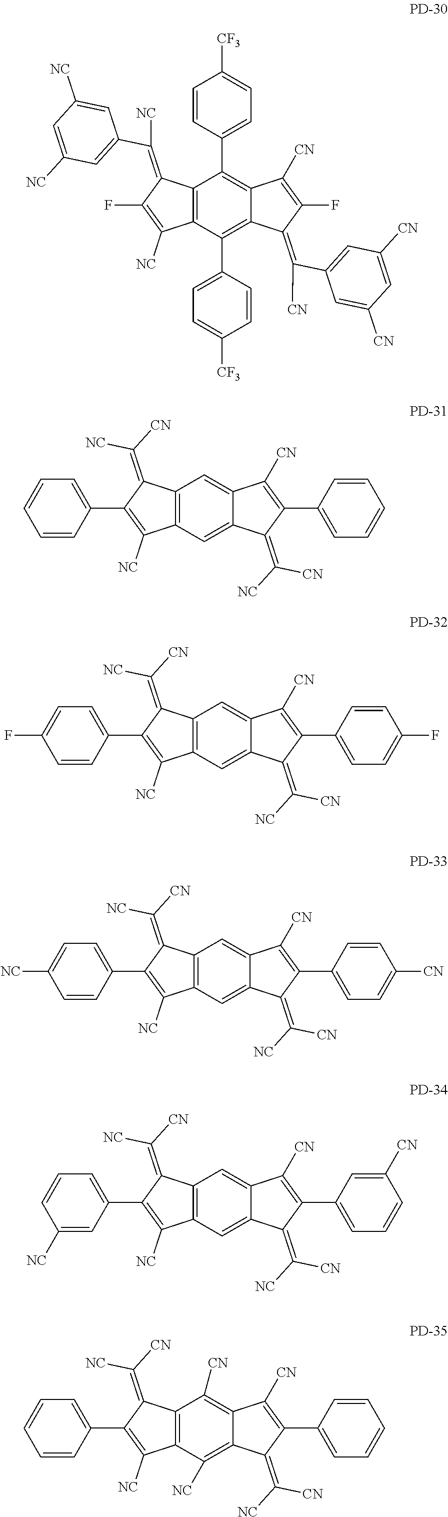

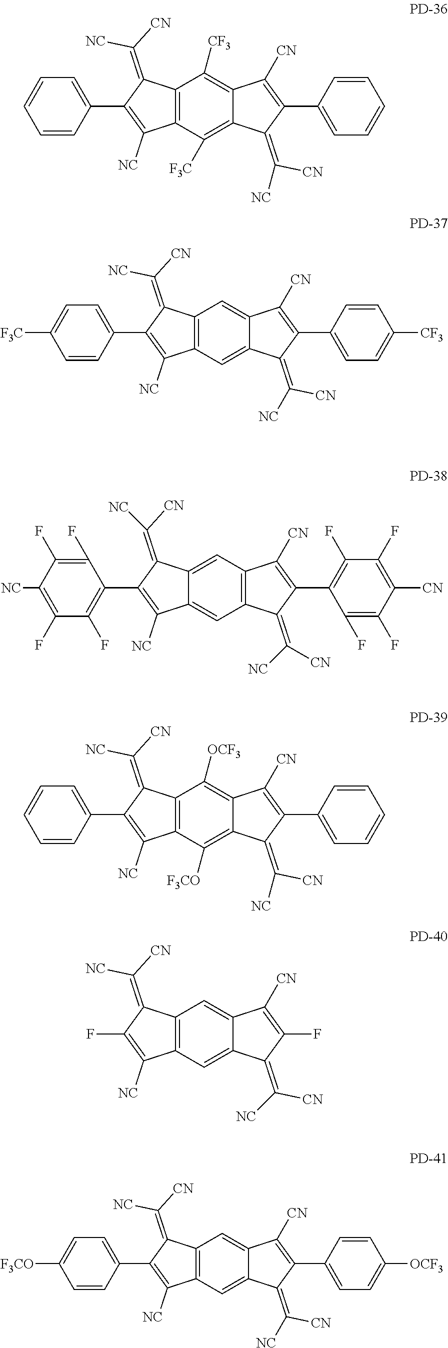

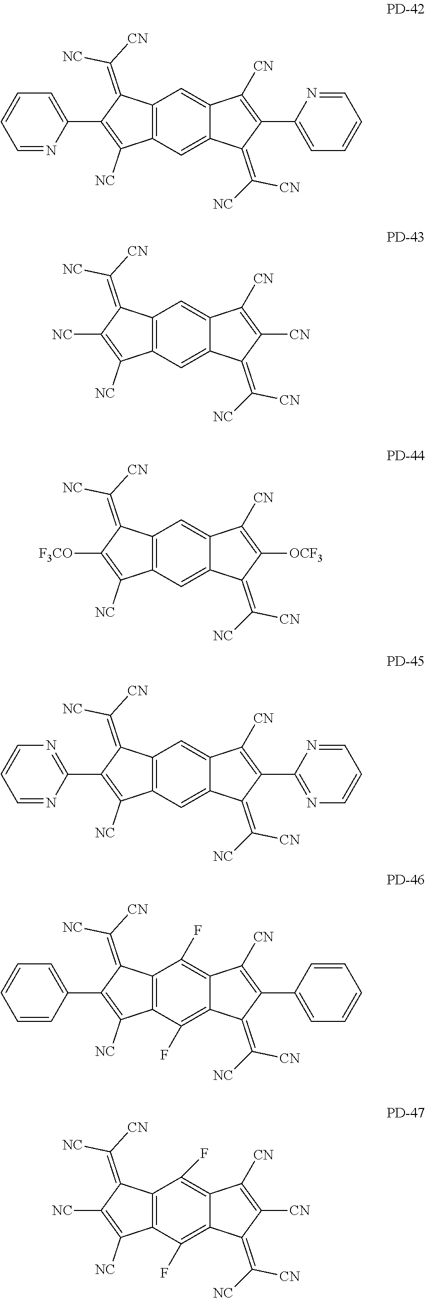 [SMILES: N#CC(C#N)=C1C(c2ccccn2)=C(C#N)c2cc3c(cc21)C(C#N)=C(c1ccccn1)C3=C(C#N)C#N ; N#CC(C#N)=C1C(C#N)=C(C#N)c2cc3c(cc21)C(C#N)=C(C#N)C3=C(C#N)C#N ; N#CC(C#N)=C1C(OC(F)(F)F)=C(C#N)c2cc3c(cc21)C(C#N)=C(OC(F)(F)F)C3=C(C#N)C#N ; N#CC(C#N)=C1C(c2ncccn2)=C(C#N)c2cc3c(cc21)C(C#N)=C(c1ncccn1)C3=C(C#N)C#N ; N#CC(C#N)=C1C(c2ccccc2)=C(C#N)c2c(F)c3c(c(F)c21)C(C#N)=C(c1ccccc1)C3=C(C#N)C#N ; N#CC(C#N)=C1C(C#N)=C(C#N)c2c(F)c3c(c(F)c21)C(C#N)=C(C#N)C3=C(C#N)C#N]

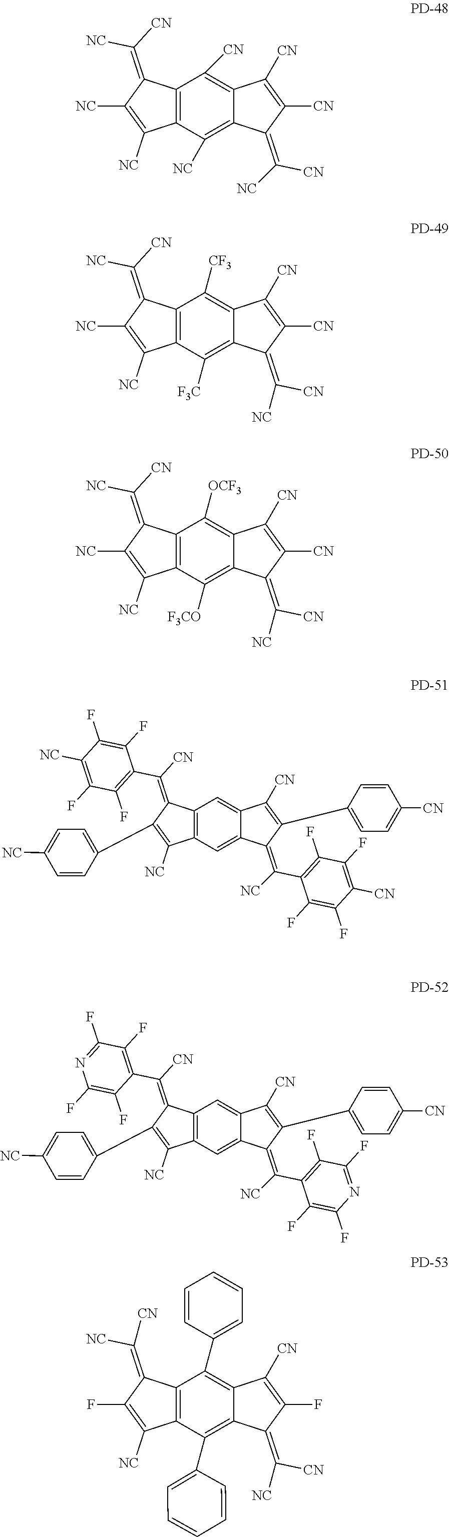

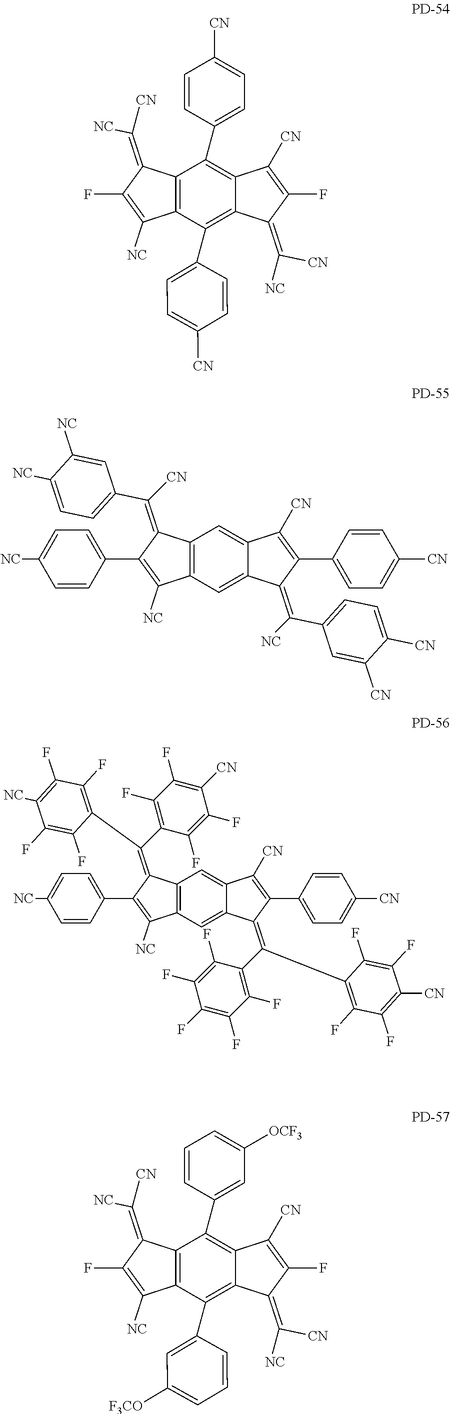

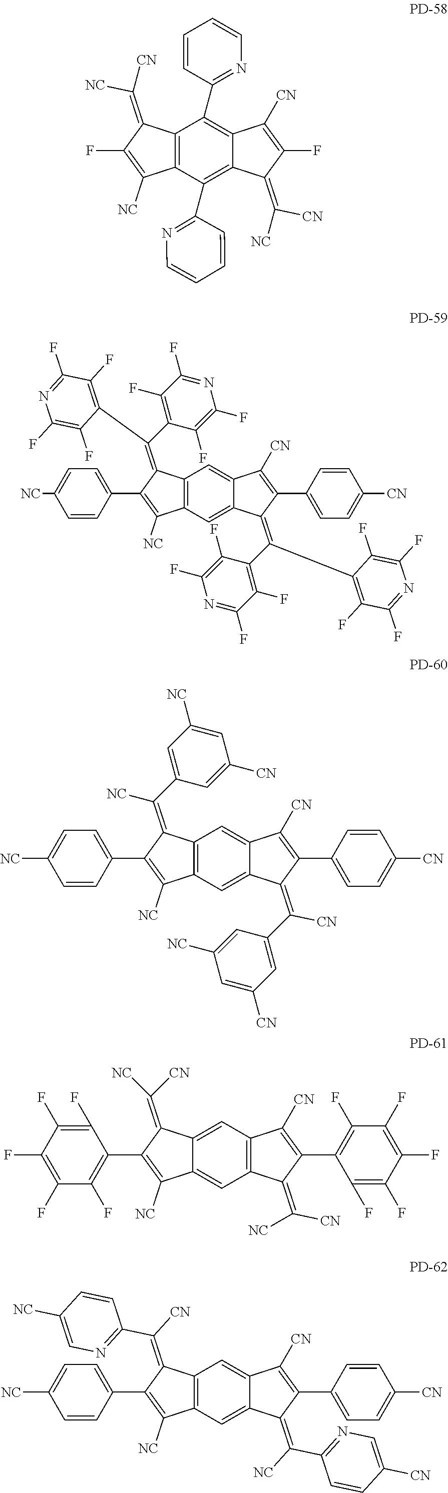

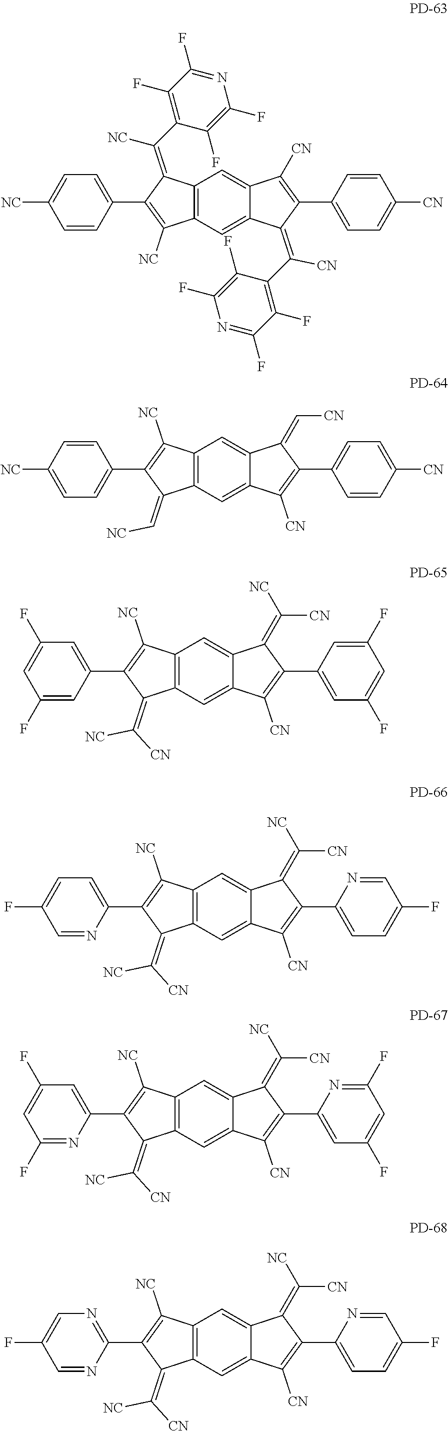

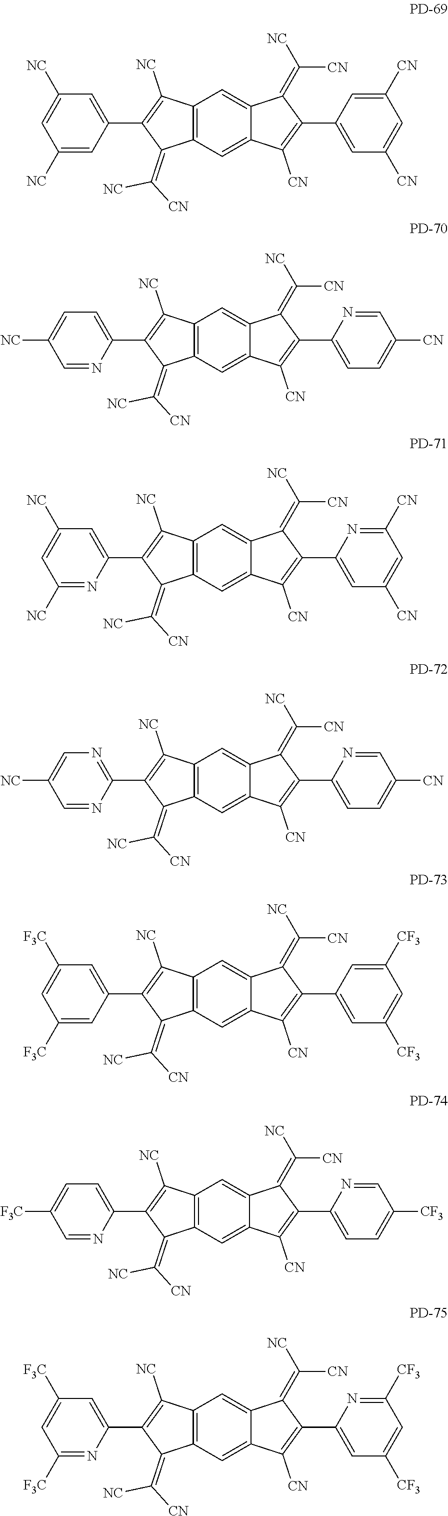

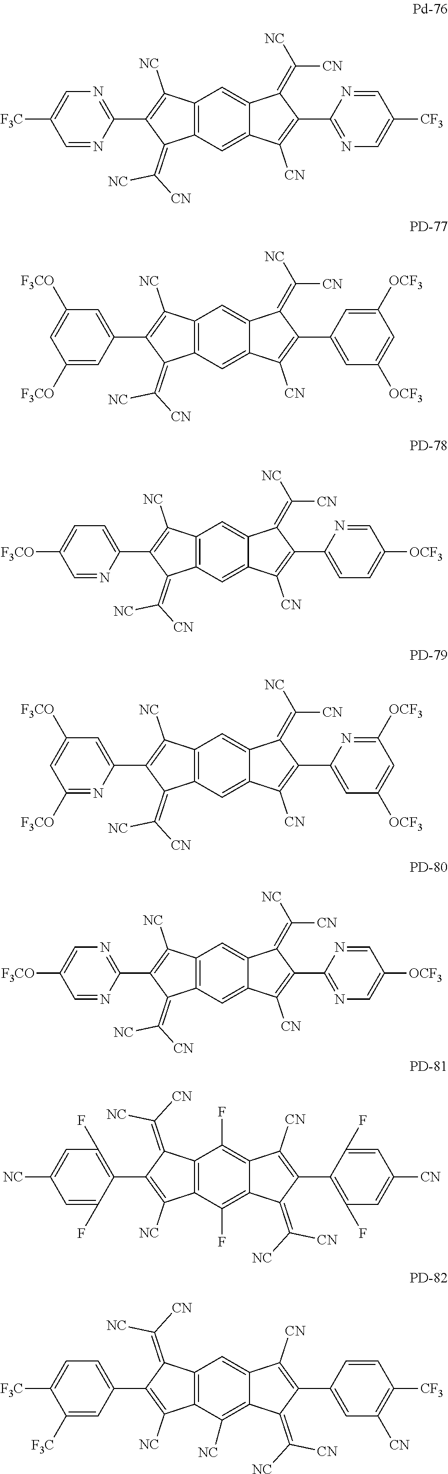

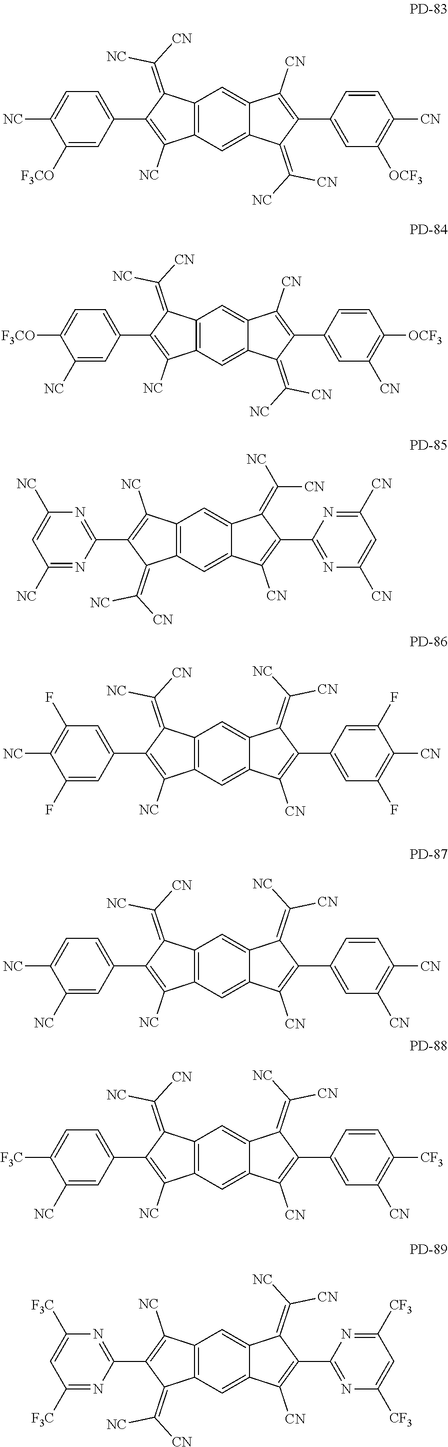

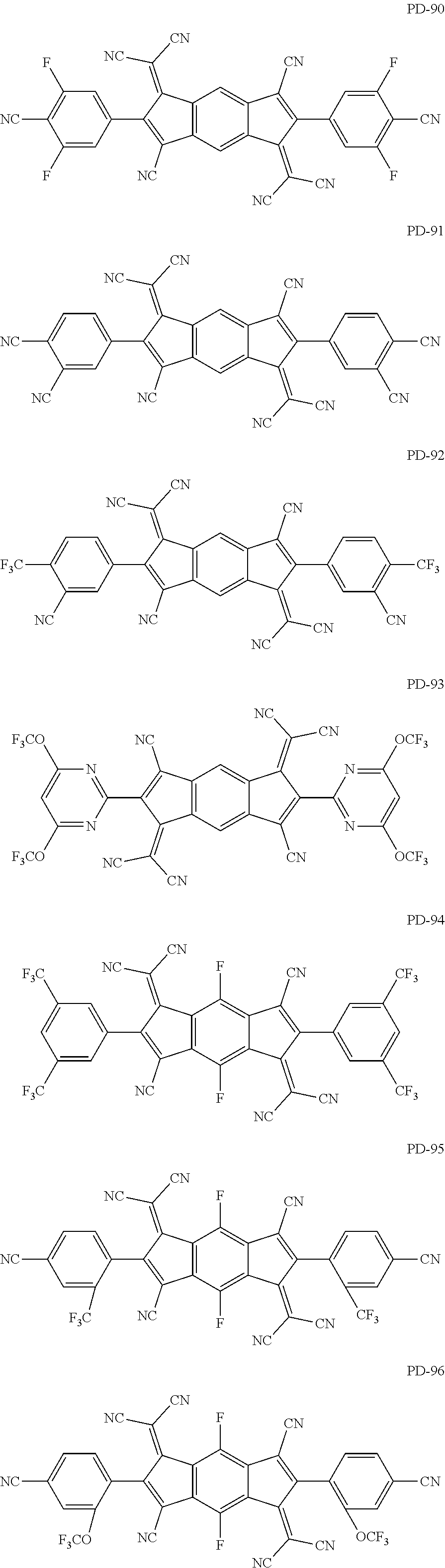

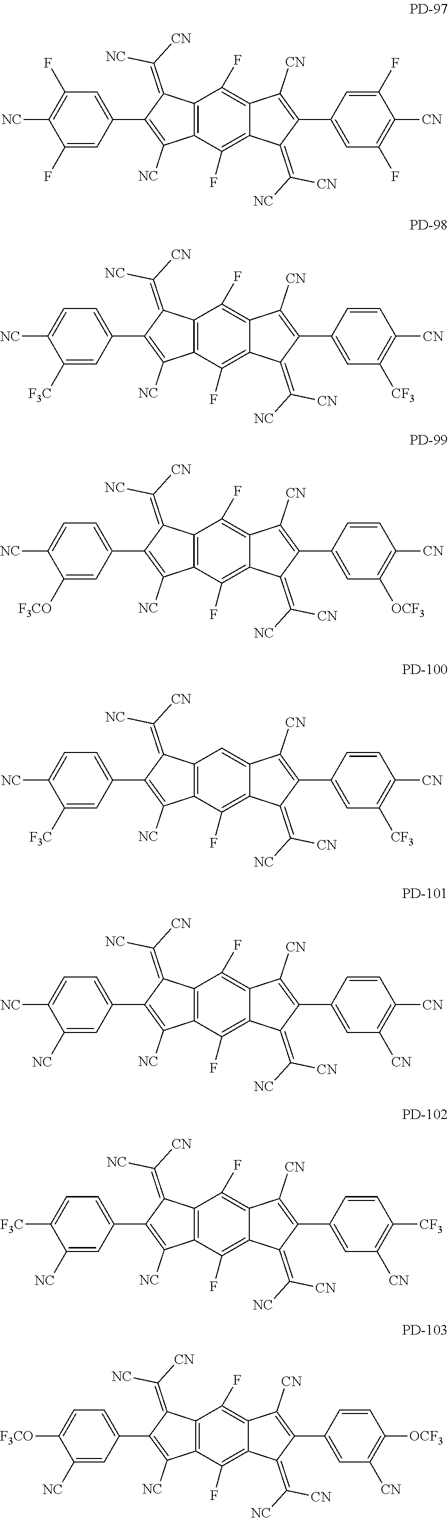

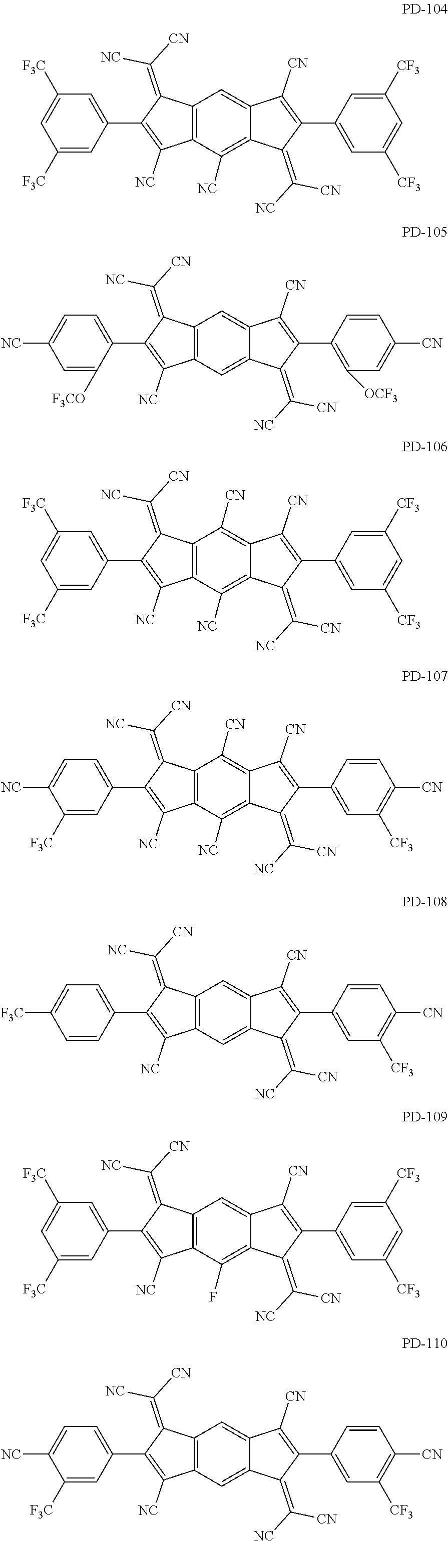

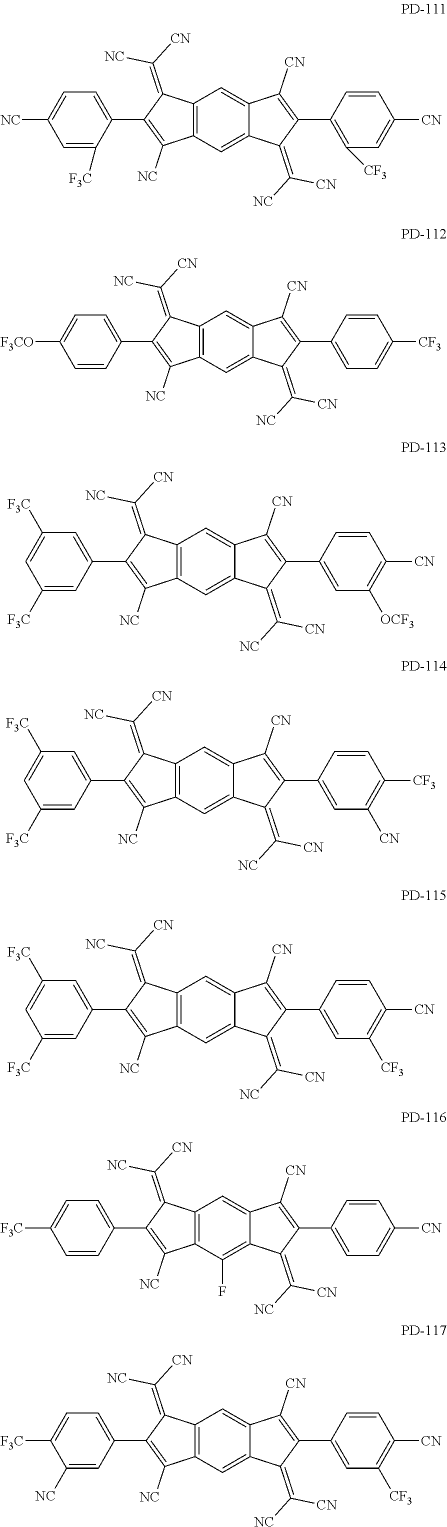

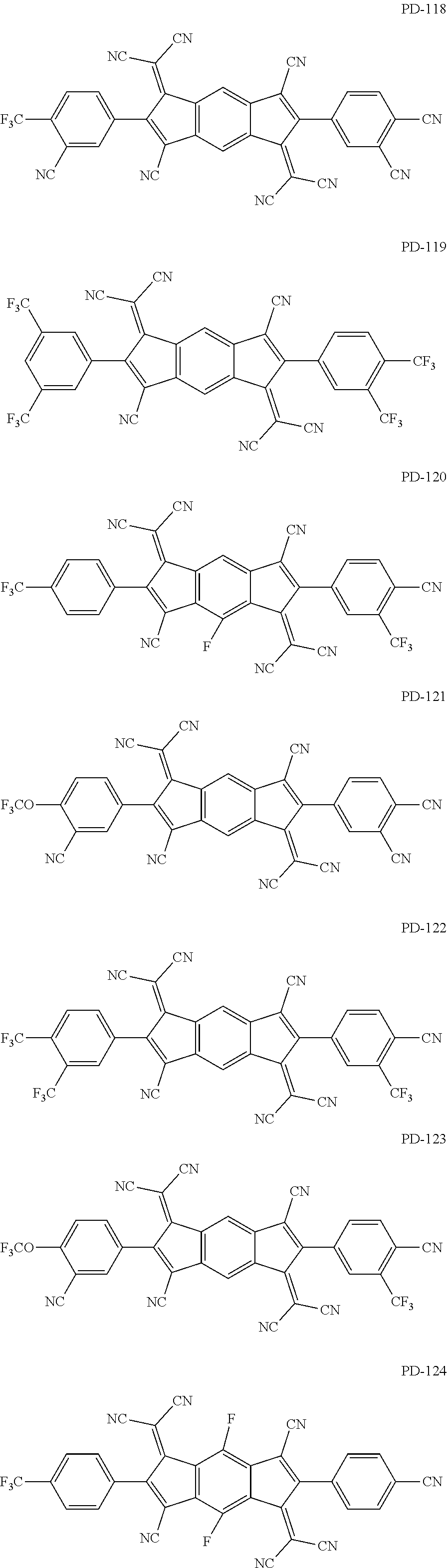

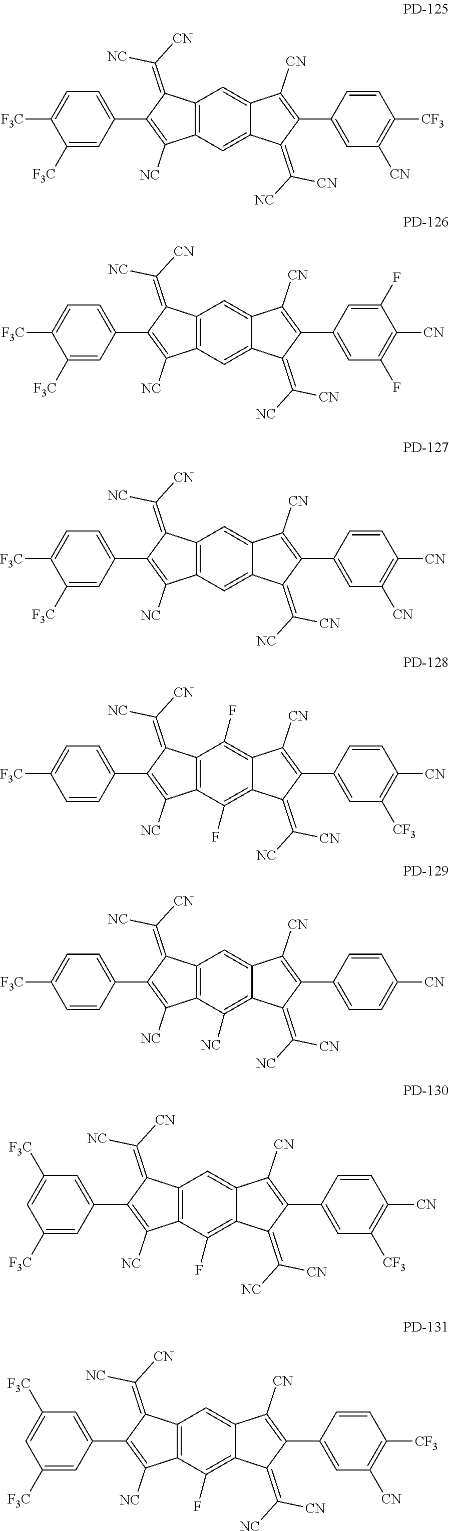

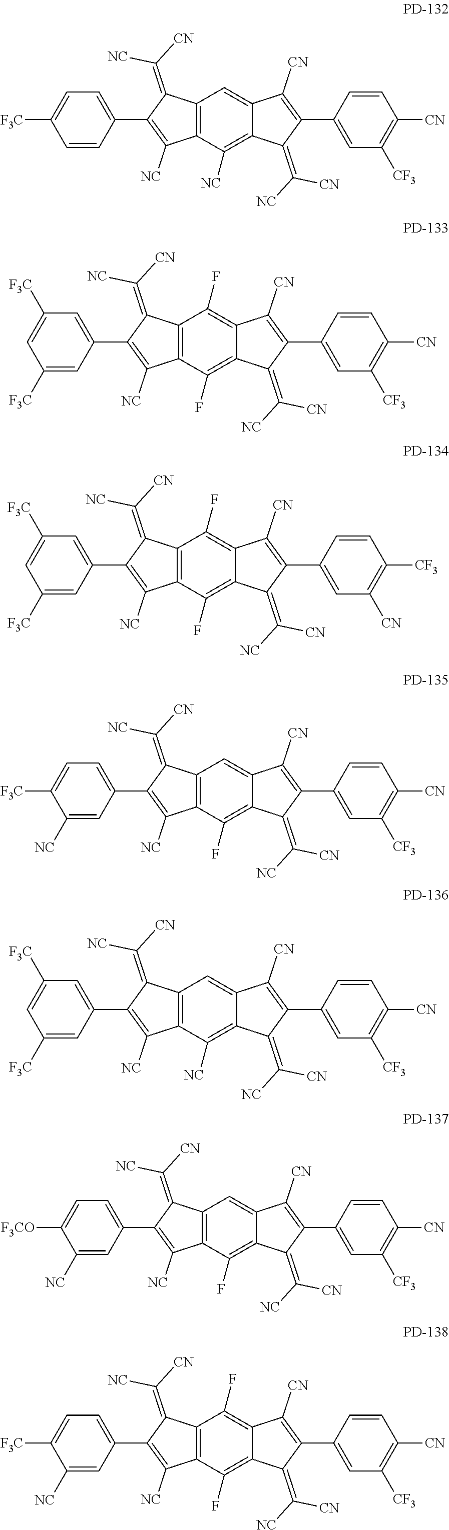

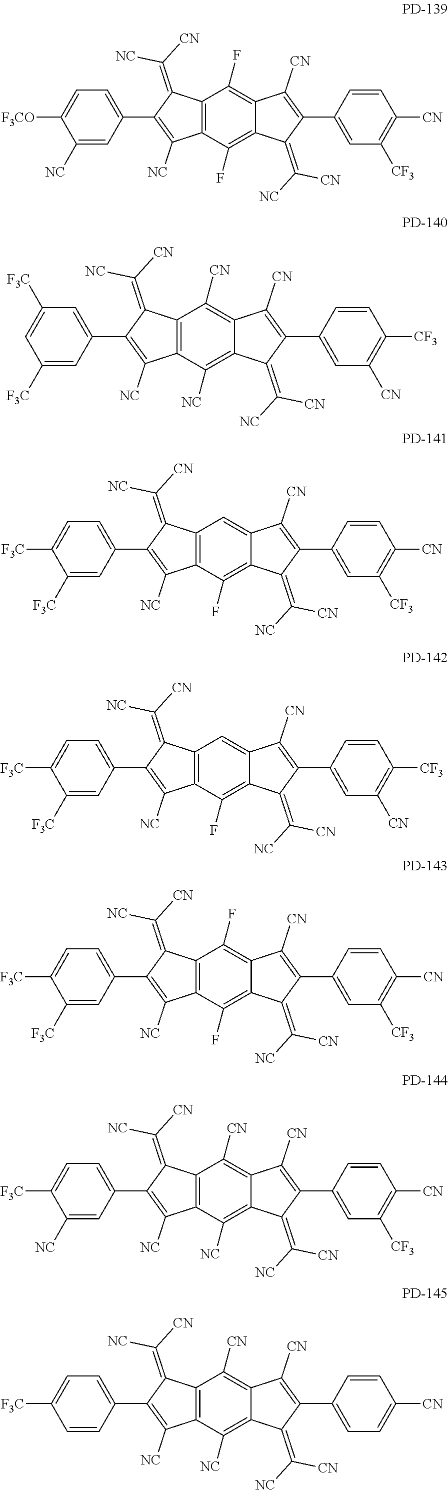

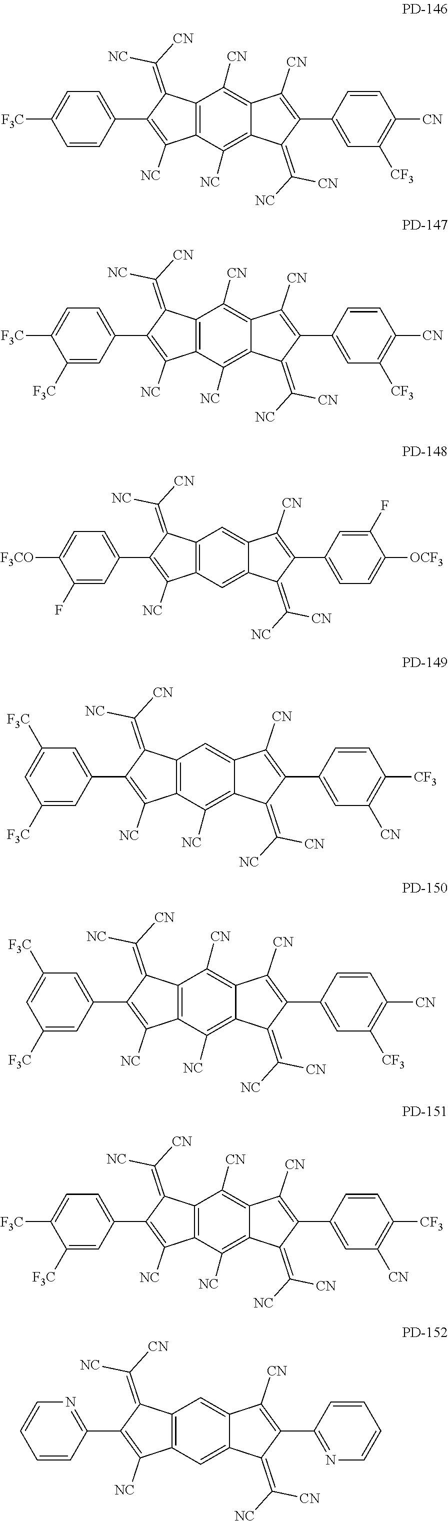

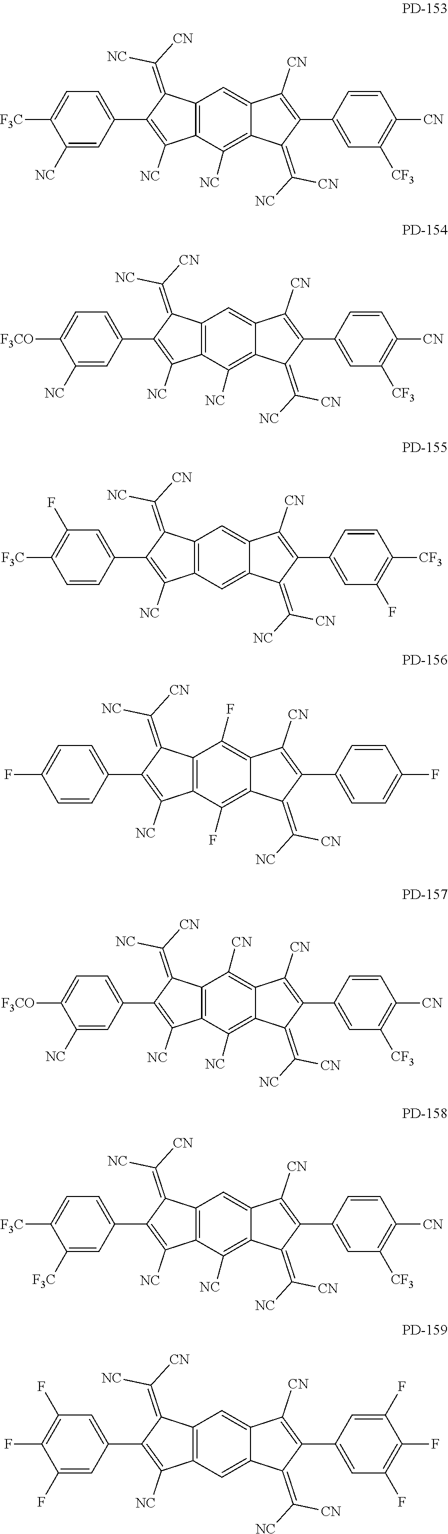

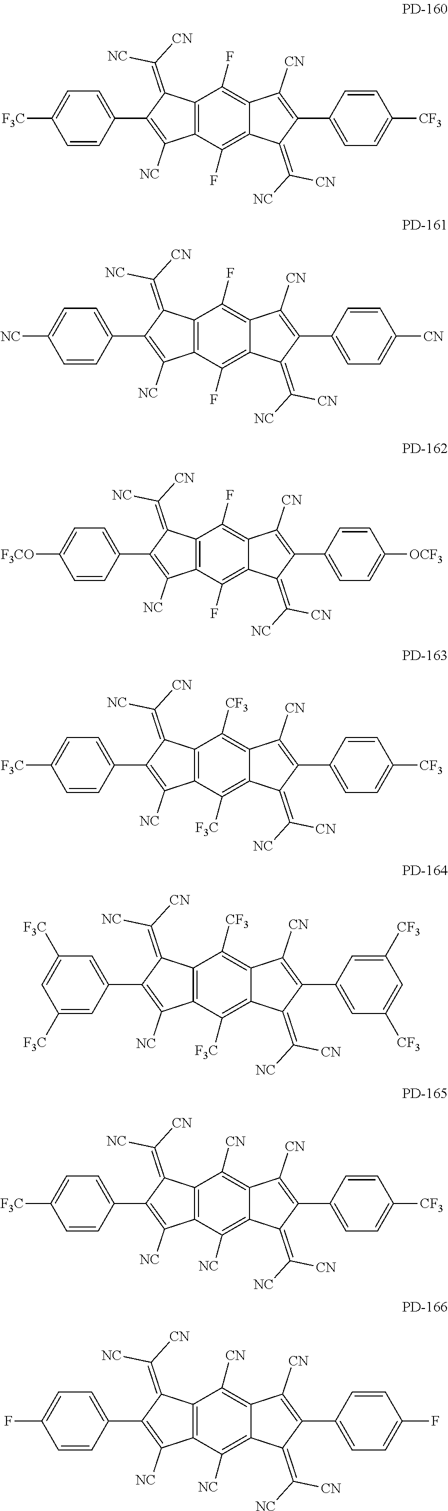

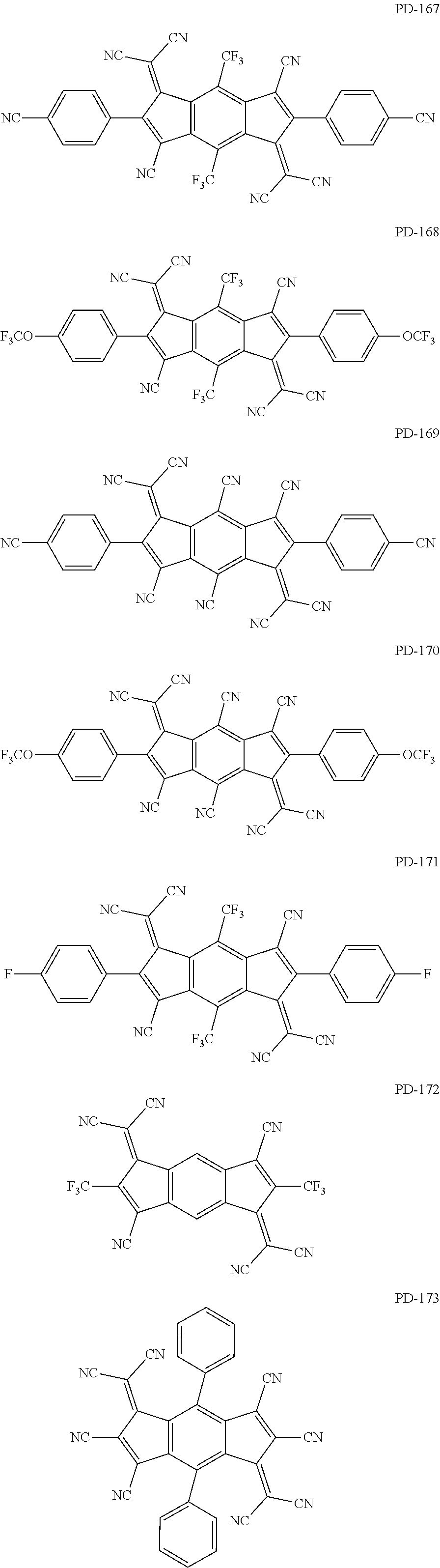

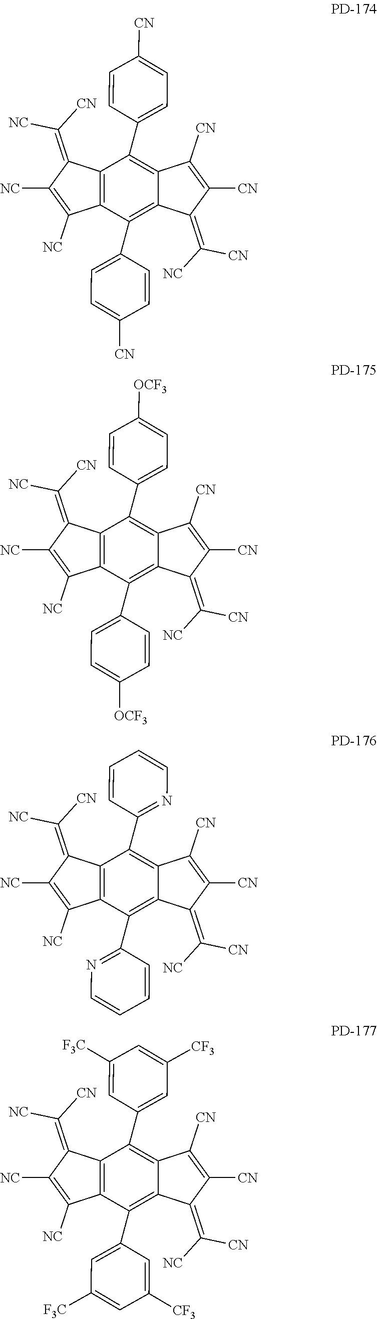

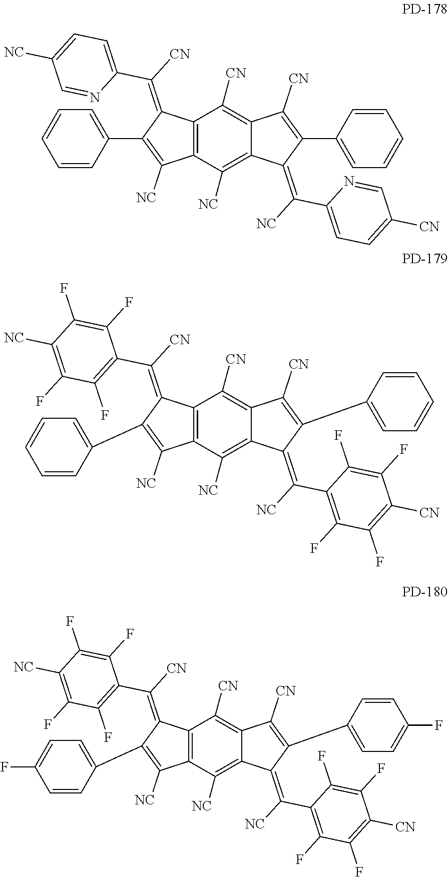 [SMILES: N#CC1=C(c2ccccc2)/C(=C(/C#N)c2ccc(C#N)cn2)c2c(C#N)c3c(c(C#N)c21)/C(=C(\C#N)c1ccc(C#N)cn1)C(c1ccccc1)=C3C#N ; N#CC1=C(c2ccccc2)/C(=C(/C#N)c2c(F)c(F)c(C#N)c(F)c2F)c2c(C#N)c3c(c(C#N)c21)/C(=C(\C#N)c1c(F)c(F)c(C#N)c(F)c1F)C(c1ccccc1)=C3C#N ; N#CC1=C(c2ccc(F)cc2)/C(=C(/C#N)c2c(F)c(F)c(C#N)c(F)c2F)c2c(C#N)c3c(c(C#N)c21)/C(=C(\C#N)c1c(F)c(F)c(C#N)c(F)c1F)C(c1ccc(F)cc1)=C3C#N]

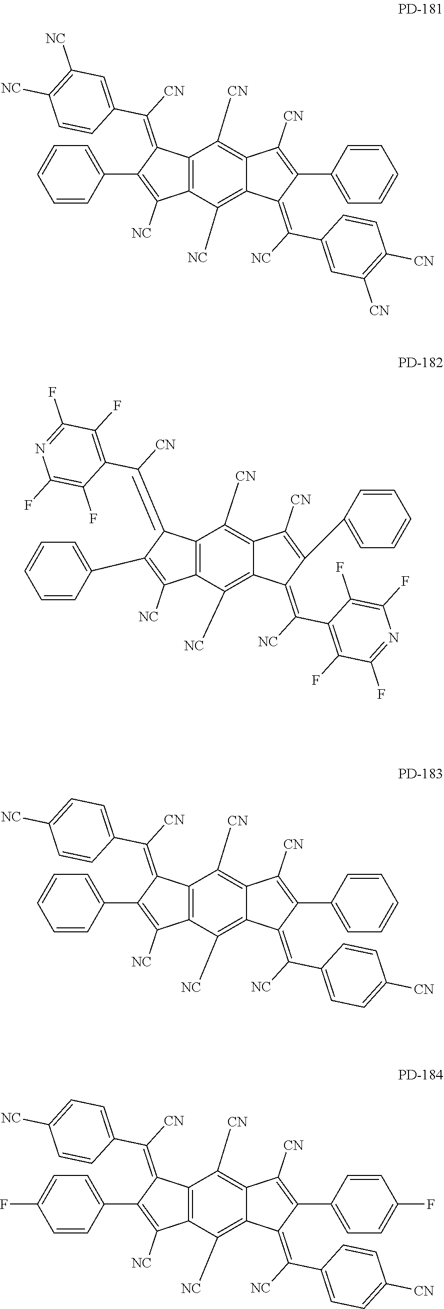 [SMILES: N#CC1=C(c2ccccc2)/C(=C(/C#N)c2ccc(C#N)c(C#N)c2)c2c(C#N)c3c(c(C#N)c21)/C(=C(\C#N)c1ccc(C#N)c(C#N)c1)C(c1ccccc1)=C3C#N ; N#CC1=C(c2ccccc2)/C(=C(/C#N)c2c(F)c(F)nc(F)c2F)c2c(C#N)c3c(c(C#N)c21)/C(=C(\C#N)c1c(F)c(F)nc(F)c1F)C(c1ccccc1)=C3C#N ; N#CC1=C(c2ccccc2)/C(=C(/C#N)c2ccc(C#N)cc2)c2c(C#N)c3c(c(C#N)c21)/C(=C(\C#N)c1ccc(C#N)cc1)C(c1ccccc1)=C3C#N ; N#CC1=C(c2ccc(F)cc2)/C(=C(/C#N)c2ccc(C#N)cc2)c2c(C#N)c3c(c(C#N)c21)/C(=C(\C#N)c1ccc(C#N)cc1)C(c1ccc(F)cc1)=C3C#N]

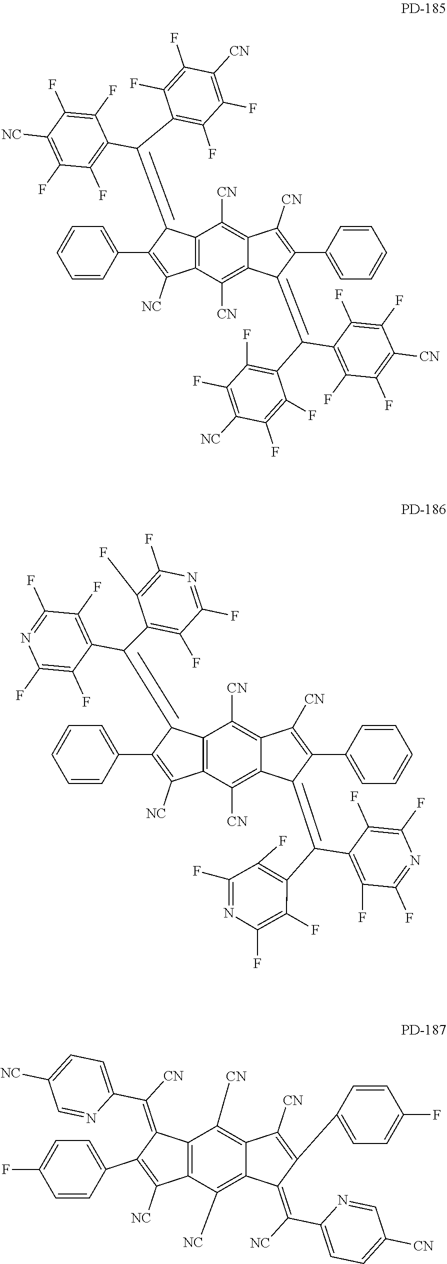 [SMILES: N#CC1=C(c2ccccc2)C(=C(c2c(F)c(F)c(C#N)c(F)c2F)c2c(F)c(F)c(C#N)c(F)c2F)c2c(C#N)c3c(c(C#N)c21)C(=C(c1c(F)c(F)c(C#N)c(F)c1F)c1c(F)c(F)c(C#N)c(F)c1F)C(c1ccccc1)=C3C#N ; N#CC1=C(c2ccccc2)C(=C(c2c(F)c(F)nc(F)c2F)c2c(F)c(F)nc(F)c2F)c2c(C#N)c3c(c(C#N)c21)C(=C(c1c(F)c(F)nc(F)c1F)c1c(F)c(F)nc(F)c1F)C(c1ccccc1)=C3C#N ; N#CC1=C(c2ccc(F)cc2)/C(=C(/C#N)c2ccc(C#N)cn2)c2c(C#N)c3c(c(C#N)c21)/C(=C(\C#N)c1ccc(C#N)cn1)C(c1ccc(F)cc1)=C3C#N]

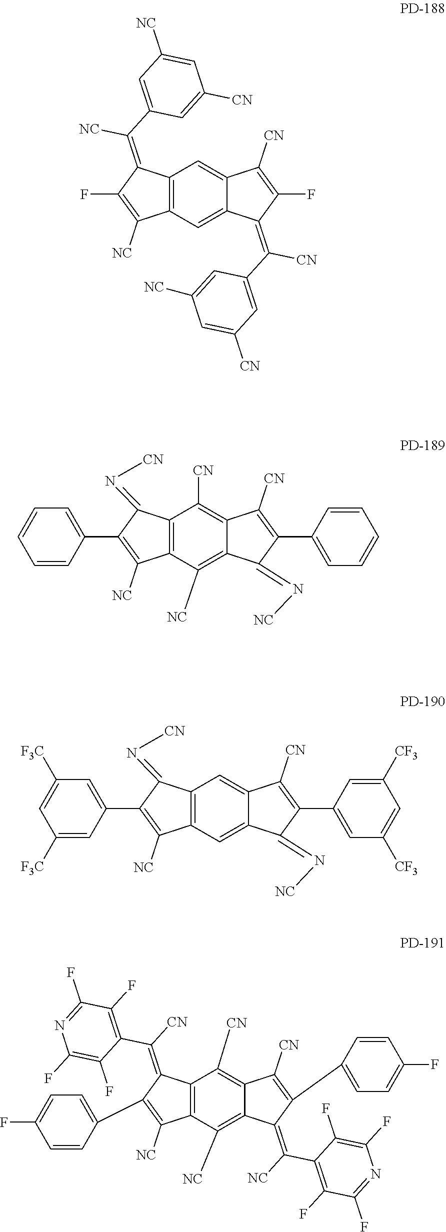 [SMILES: N#CC1=C(F)/C(=C(\C#N)c2cc(C#N)cc(C#N)c2)c2cc3c(cc21)/C(=C(/C#N)c1cc(C#N)cc(C#N)c1)C(F)=C3C#N ; N#C/N=c1/c(-c2ccccc2)c(C#N)c2c(C#N)c3/c(=N\C#N)c(-c4ccccc4)c(C#N)c3c(C#N)c12 ; N#C/N=c1/c(-c2cc(C(F)(F)F)cc(C(F)(F)F)c2)c(C#N)c2cc3/c(=N\C#N)c(-c4cc(C(F)(F)F)cc(C(F)(F)F)c4)c(C#N)c3cc12 ; N#CC1=C(c2ccc(F)cc2)/C(=C(/C#N)c2c(F)c(F)nc(F)c2F)c2c(C#N)c3c(c(C#N)c21)/C(=C(\C#N)c1c(F)c(F)nc(F)c1F)C(c1ccc(F)cc1)=C3C#N]

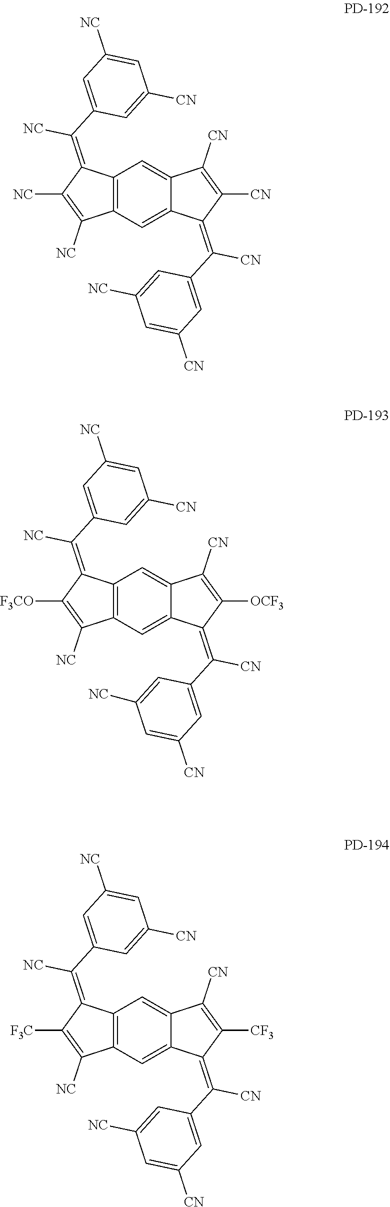 [SMILES: N#CC1=C(C#N)c2cc3c(cc2/C1=C(/C#N)c1cc(C#N)cc(C#N)c1)C(C#N)=C(C#N)/C3=C(\C#N)c1cc(C#N)cc(C#N)c1 ; N#CC1=C(OC(F)(F)F)/C(=C(\C#N)c2cc(C#N)cc(C#N)c2)c2cc3c(cc21)/C(=C(/C#N)c1cc(C#N)cc(C#N)c1)C(OC(F)(F)F)=C3C#N ; N#CC1=C(C(F)(F)F)/C(=C(\C#N)c2cc(C#N)cc(C#N)c2)c2cc3c(cc21)/C(=C(/C#N)c1cc(C#N)cc(C#N)c1)C(C(F)(F)F)=C3C#N]

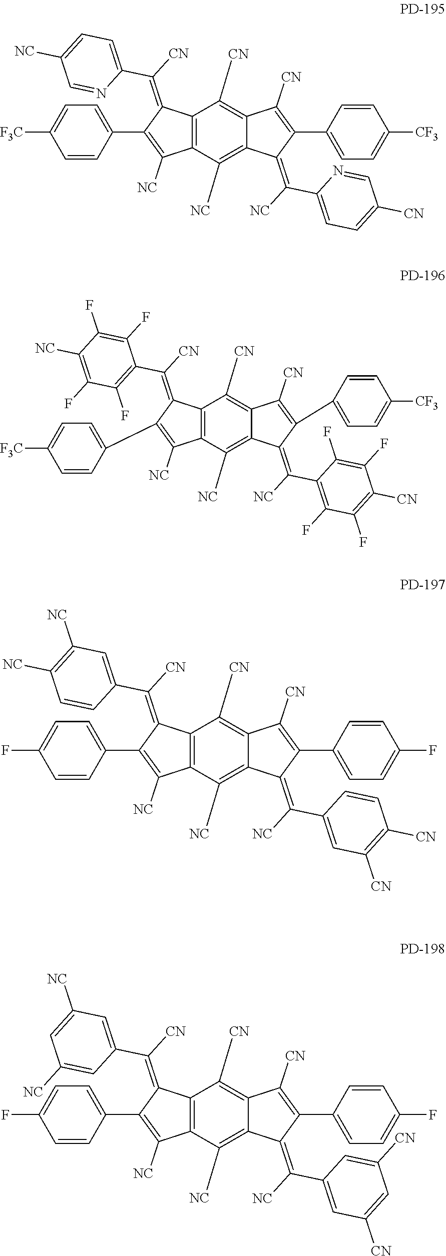

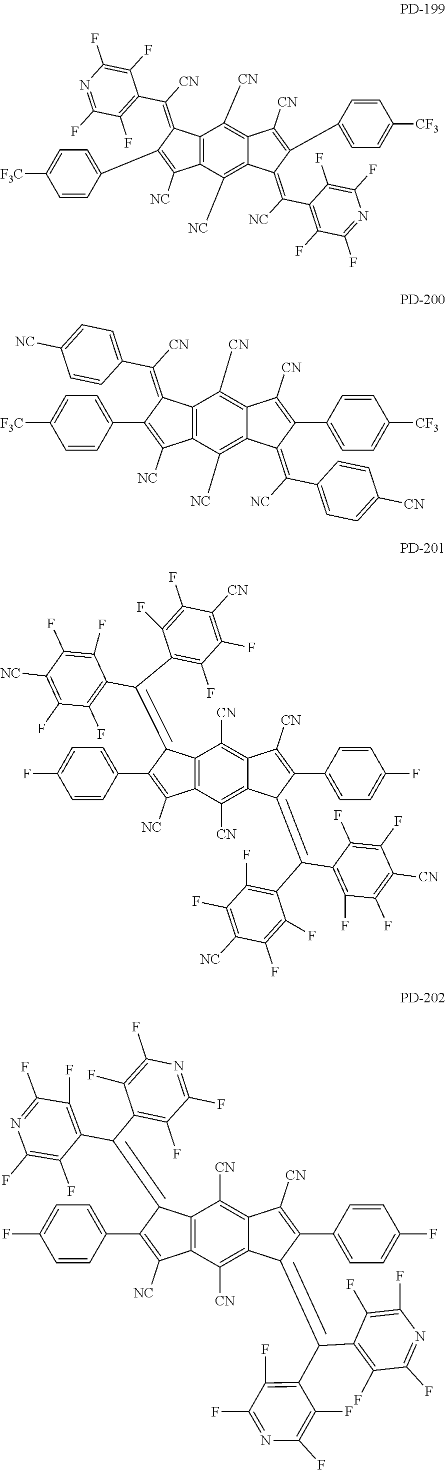

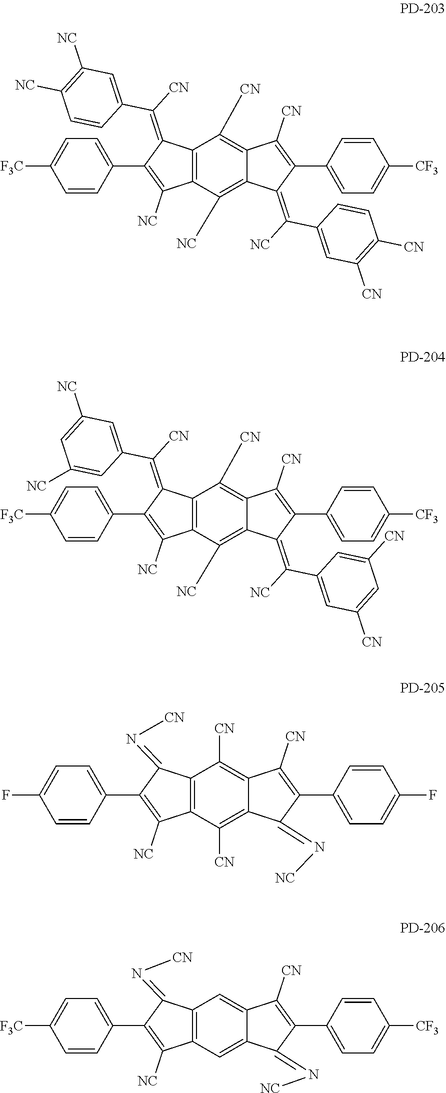 [SMILES: N#CC1=C(c2ccc(C(F)(F)F)cc2)/C(=C(/C#N)c2ccc(C#N)c(C#N)c2)c2c(C#N)c3c(c(C#N)c21)/C(=C(\C#N)c1ccc(C#N)c(C#N)c1)C(c1ccc(C(F)(F)F)cc1)=C3C#N ; N#CC1=C(c2ccc(C(F)(F)F)cc2)/C(=C(/C#N)c2cc(C#N)cc(C#N)c2)c2c(C#N)c3c(c(C#N)c21)/C(=C(\C#N)c1cc(C#N)cc(C#N)c1)C(c1ccc(C(F)(F)F)cc1)=C3C#N ; N#C/N=c1/c(-c2ccc(F)cc2)c(C#N)c2c(C#N)c3/c(=N\C#N)c(-c4ccc(F)cc4)c(C#N)c3c(C#N)c12 ; N#C/N=c1/c(-c2ccc(C(F)(F)F)cc2)c(C#N)c2cc3/c(=N\C#N)c(-c4ccc(C(F)(F)F)cc4)c(C#N)c3cc12]

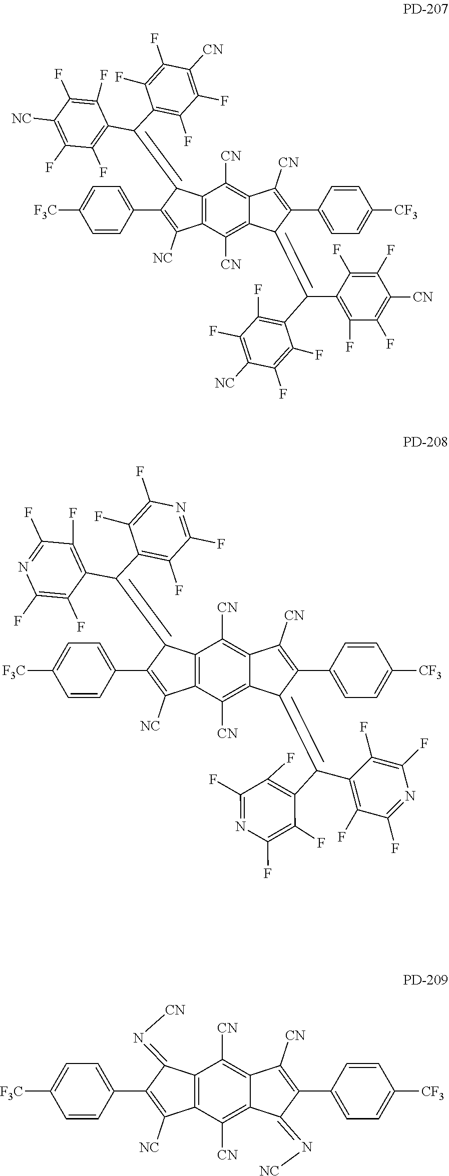 [SMILES: N#CC1=C(c2ccc(C(F)(F)F)cc2)C(=C(c2c(F)c(F)c(C#N)c(F)c2F)c2c(F)c(F)c(C#N)c(F)c2F)c2c(C#N)c3c(c(C#N)c21)C(=C(c1c(F)c(F)c(C#N)c(F)c1F)c1c(F)c(F)c(C#N)c(F)c1F)C(c1ccc(C(F)(F)F)cc1)=C3C#N ; N#CC1=C(c2ccc(C(F)(F)F)cc2)C(=C(c2c(F)c(F)nc(F)c2F)c2c(F)c(F)nc(F)c2F)c2c(C#N)c3c(c(C#N)c21)C(=C(c1c(F)c(F)nc(F)c1F)c1c(F)c(F)nc(F)c1F)C(c1ccc(C(F)(F)F)cc1)=C3C#N ; N#C/N=c1/c(-c2ccc(C(F)(F)F)cc2)c(C#N)c2c(C#N)c3/c(=N\C#N)c(-c4ccc(C(F)(F)F)cc4)c(C#N)c3c(C#N)c12]

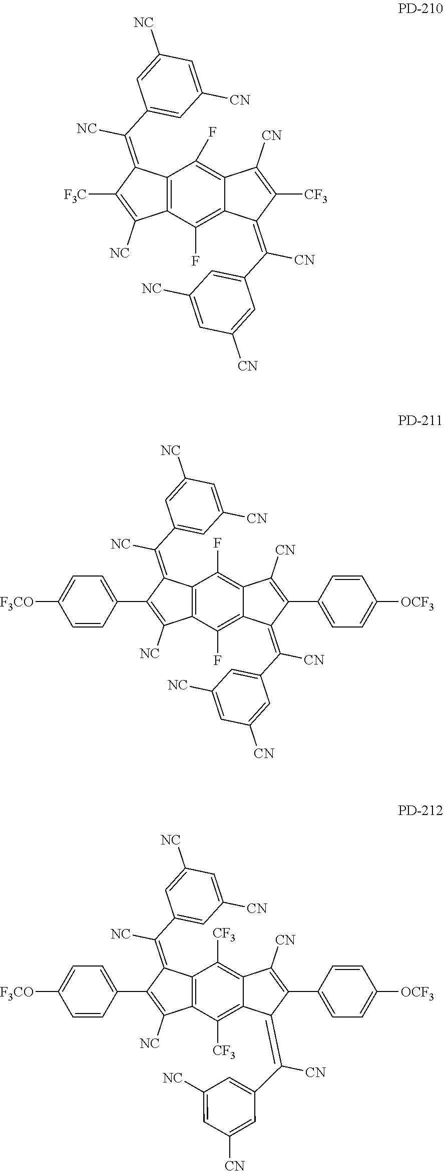

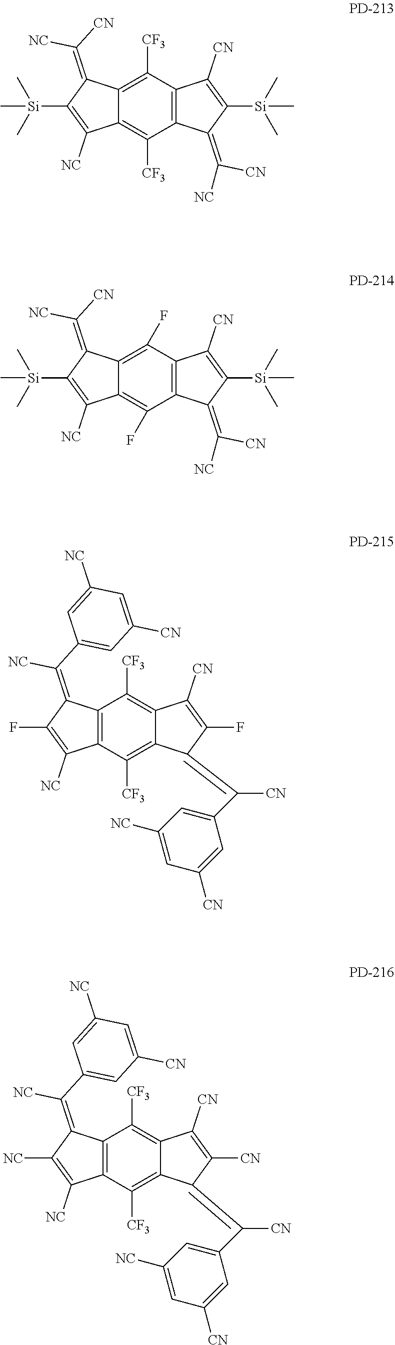

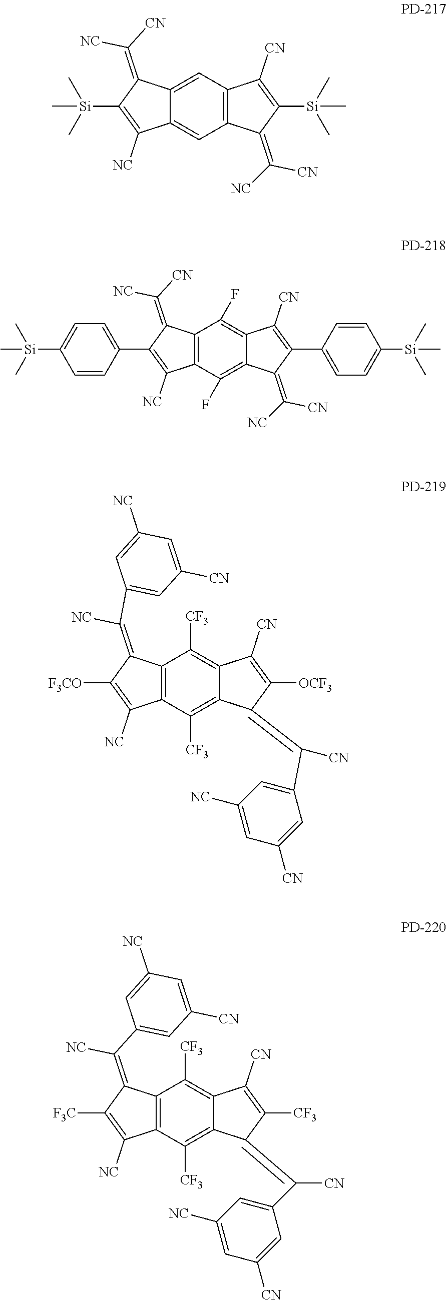

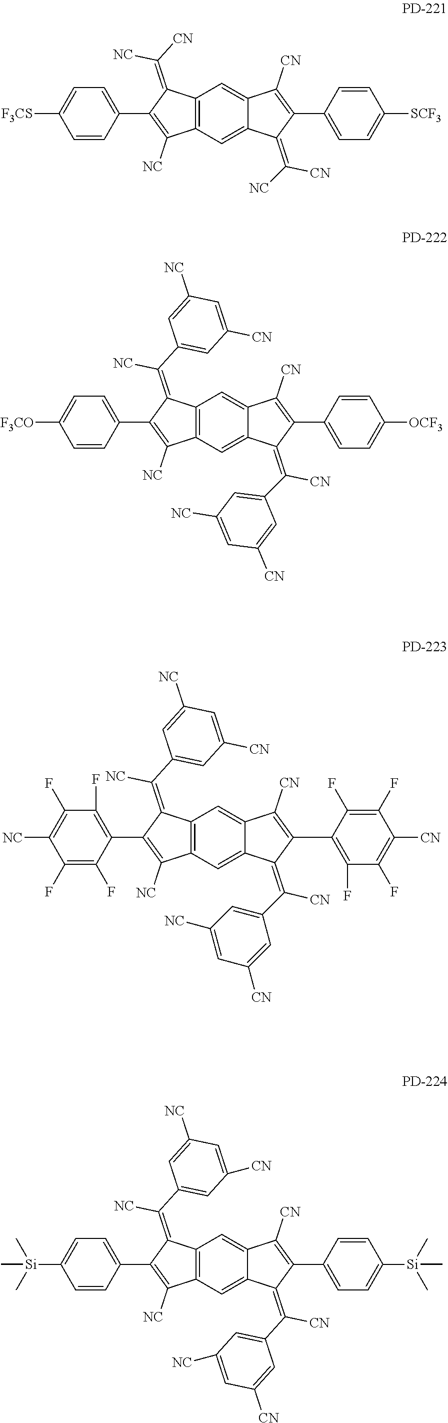

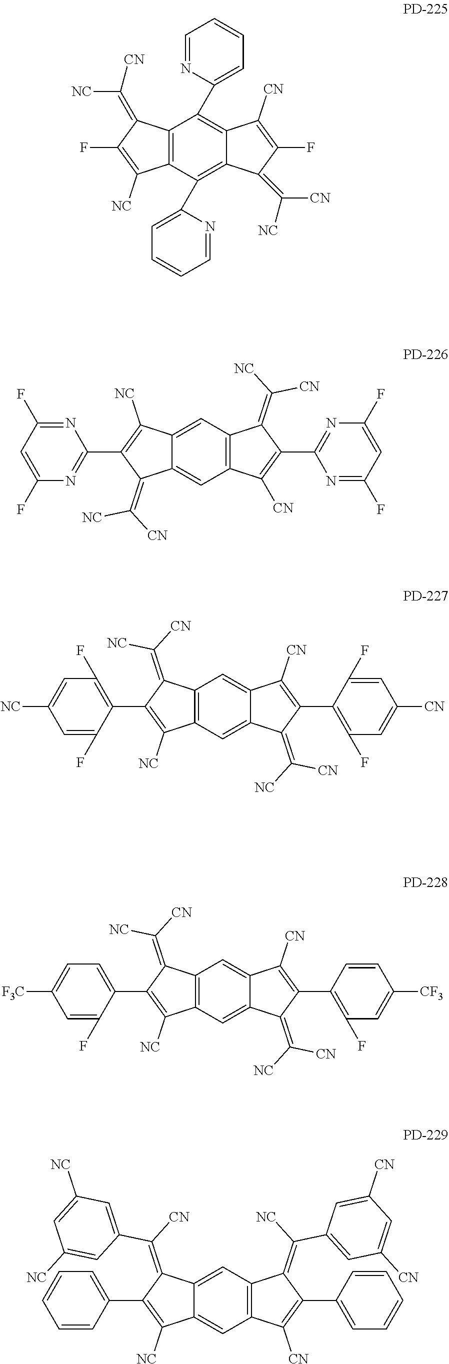 [SMILES: N#CC(C#N)=C1C(F)=C(C#N)c2c1c(-c1ccccn1)c1c(c2-c2ccccn2)C(=C(C#N)C#N)C(F)=C1C#N ; N#CC(C#N)=C1C(c2nc(F)cc(F)n2)=C(C#N)c2cc3c(cc21)C(C#N)=C(c1nc(F)cc(F)n1)C3=C(C#N)C#N ; N#CC(C#N)=C1C(c2c(F)cc(C#N)cc2F)=C(C#N)c2cc3c(cc21)C(C#N)=C(c1c(F)cc(C#N)cc1F)C3=C(C#N)C#N ; N#CC(C#N)=C1C(c2ccc(C(F)(F)F)cc2F)=C(C#N)c2cc3c(cc21)C(C#N)=C(c1ccc(C(F)(F)F)cc1F)C3=C(C#N)C#N ; N#CC1=C(c2ccccc2)/C(=C(/C#N)c2cc(C#N)cc(C#N)c2)c2cc3c(cc21)C(C#N)=C(c1ccccc1)/C3=C(/C#N)c1cc(C#N)cc(C#N)c1]

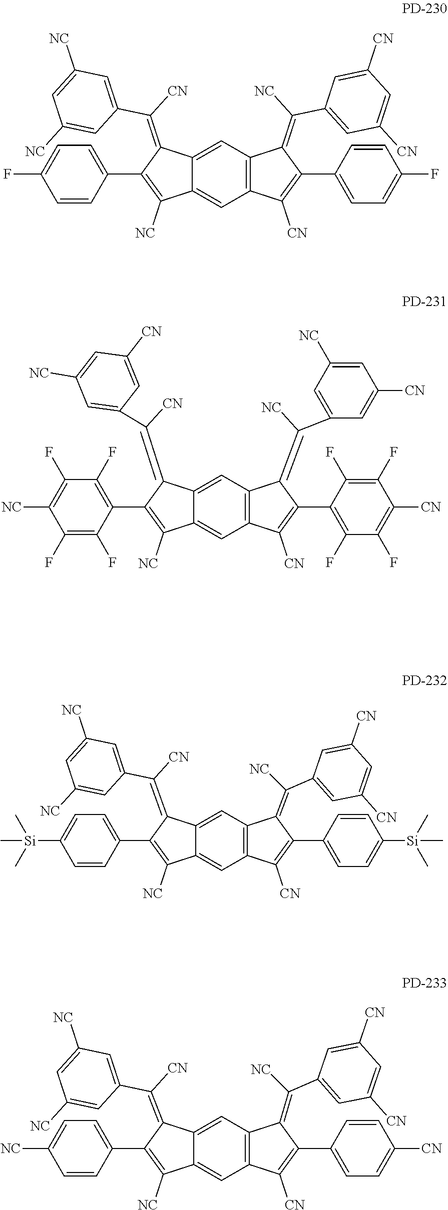

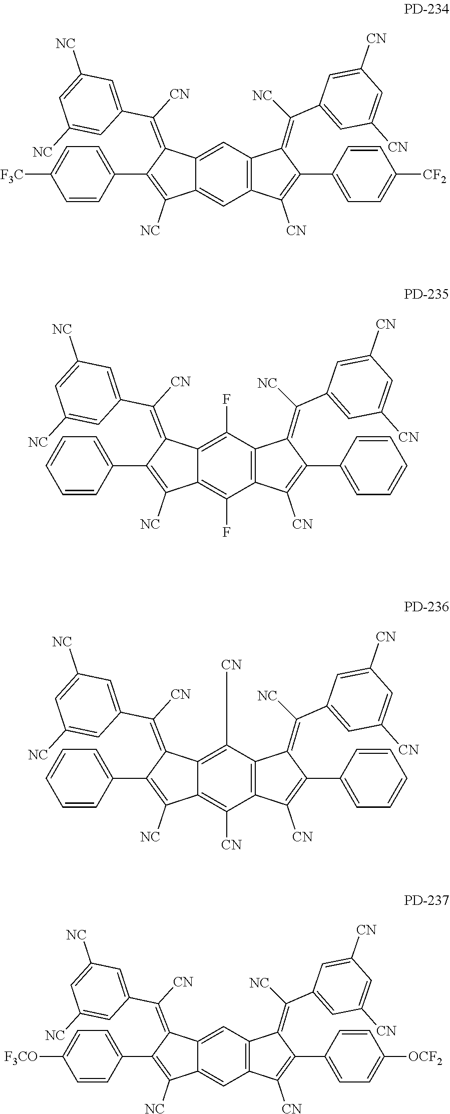

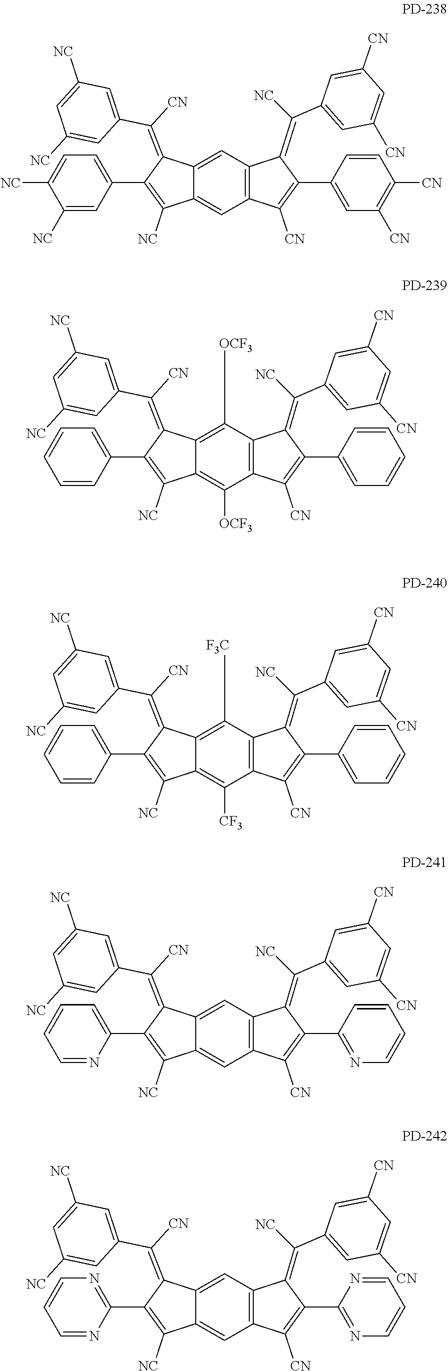

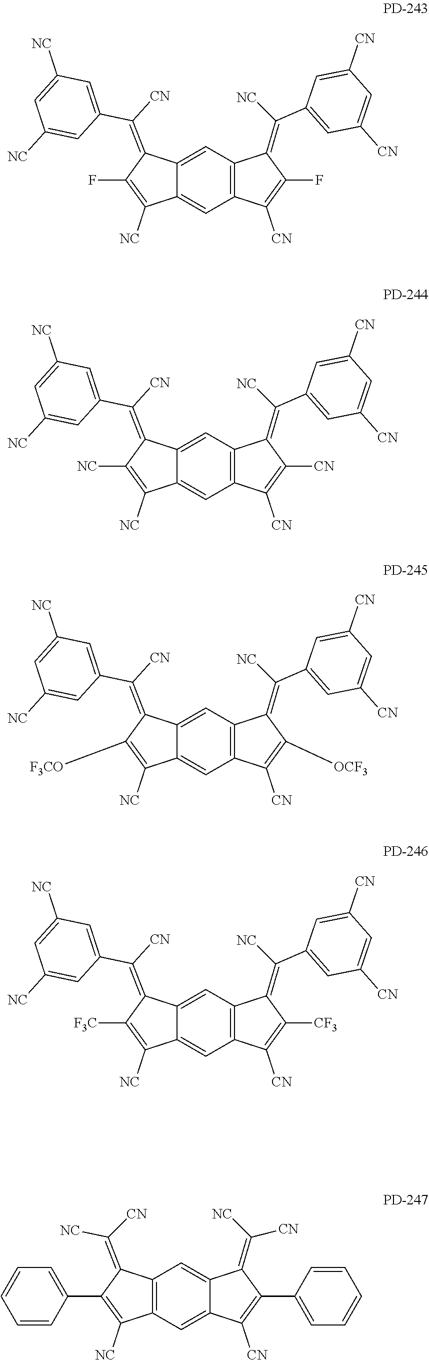 [SMILES: N#CC1=C(F)/C(=C(/C#N)c2cc(C#N)cc(C#N)c2)c2cc3c(cc21)C(C#N)=C(F)/C3=C(/C#N)c1cc(C#N)cc(C#N)c1 ; N#CC1=C(C#N)c2cc3c(cc2/C1=C(\C#N)c1cc(C#N)cc(C#N)c1)/C(=C(\C#N)c1cc(C#N)cc(C#N)c1)C(C#N)=C3C#N ; N#CC1=C(OC(F)(F)F)/C(=C(/C#N)c2cc(C#N)cc(C#N)c2)c2cc3c(cc21)C(C#N)=C(OC(F)(F)F)/C3=C(/C#N)c1cc(C#N)cc(C#N)c1 ; N#CC1=C(C(F)(F)F)/C(=C(/C#N)c2cc(C#N)cc(C#N)c2)c2cc3c(cc21)C(C#N)=C(C(F)(F)F)/C3=C(/C#N)c1cc(C#N)cc(C#N)c1 ; N#CC(C#N)=C1C(c2ccccc2)=C(C#N)c2cc3c(cc21)C(=C(C#N)C#N)C(c1ccccc1)=C3C#N]

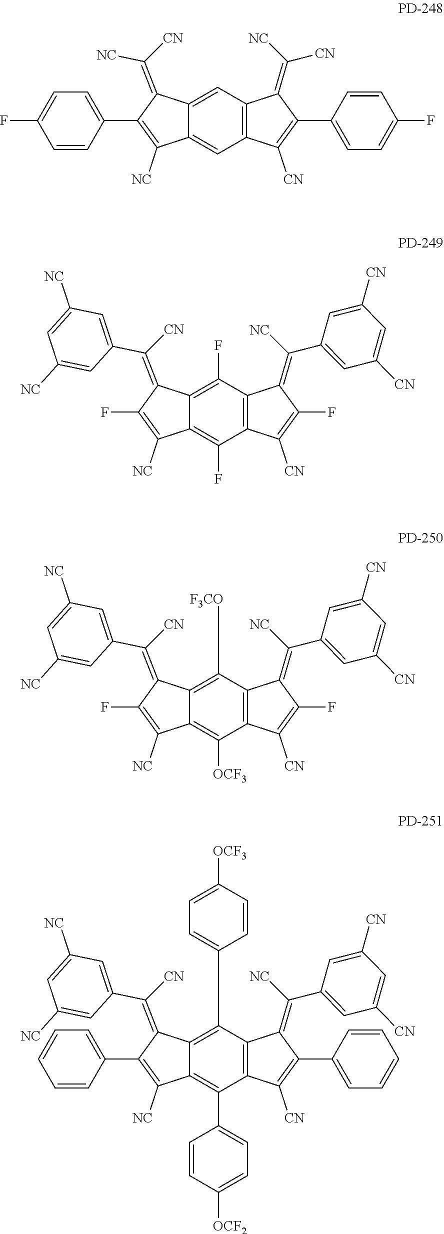

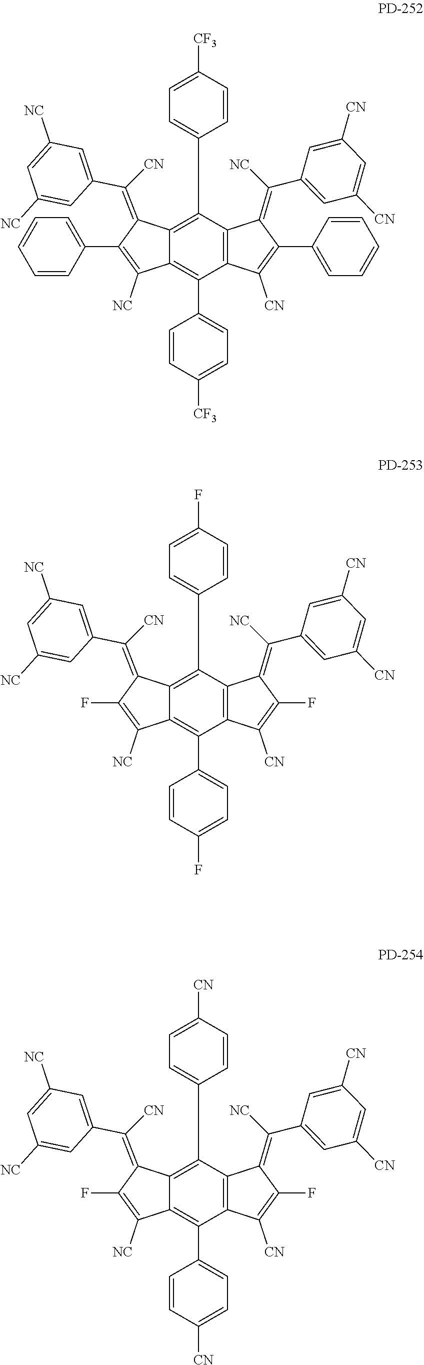 [SMILES: N#CC1=C(c2ccccc2)/C(=C(/C#N)c2cc(C#N)cc(C#N)c2)c2c1c(-c1ccc(C(F)(F)F)cc1)c1c(c2-c2ccc(C(F)(F)F)cc2)/C(=C(\C#N)c2cc(C#N)cc(C#N)c2)C(c2ccccc2)=C1C#N ; N#CC1=C(F)/C(=C(/C#N)c2cc(C#N)cc(C#N)c2)c2c1c(-c1ccc(F)cc1)c1c(c2-c2ccc(F)cc2)/C(=C(\C#N)c2cc(C#N)cc(C#N)c2)C(F)=C1C#N ; N#CC1=C(F)/C(=C(/C#N)c2cc(C#N)cc(C#N)c2)c2c1c(-c1ccc(C#N)cc1)c1c(c2-c2ccc(C#N)cc2)/C(=C(\C#N)c2cc(C#N)cc(C#N)c2)C(F)=C1C#N]

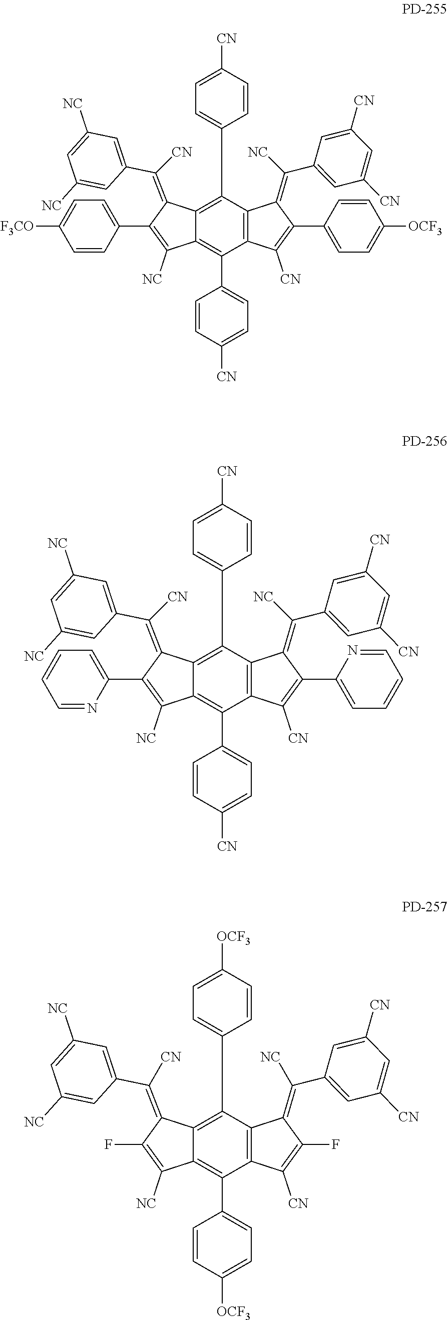 [SMILES: N#CC1=C(c2ccc(OC(F)(F)F)cc2)/C(=C(/C#N)c2cc(C#N)cc(C#N)c2)c2c1c(-c1ccc(C#N)cc1)c1c(c2-c2ccc(C#N)cc2)/C(=C(\C#N)c2cc(C#N)cc(C#N)c2)C(c2ccc(OC(F)(F)F)cc2)=C1C#N ; N#CC1=C(c2ccccn2)/C(=C(/C#N)c2cc(C#N)cc(C#N)c2)c2c1c(-c1ccc(C#N)cc1)c1c(c2-c2ccc(C#N)cc2)/C(=C(\C#N)c2cc(C#N)cc(C#N)c2)C(c2ccccn2)=C1C#N ; N#CC1=C(F)/C(=C(/C#N)c2cc(C#N)cc(C#N)c2)c2c1c(-c1ccc(OC(F)(F)F)cc1)c1c(c2-c2ccc(OC(F)(F)F)cc2)/C(=C(\C#N)c2cc(C#N)cc(C#N)c2)C(F)=C1C#N]

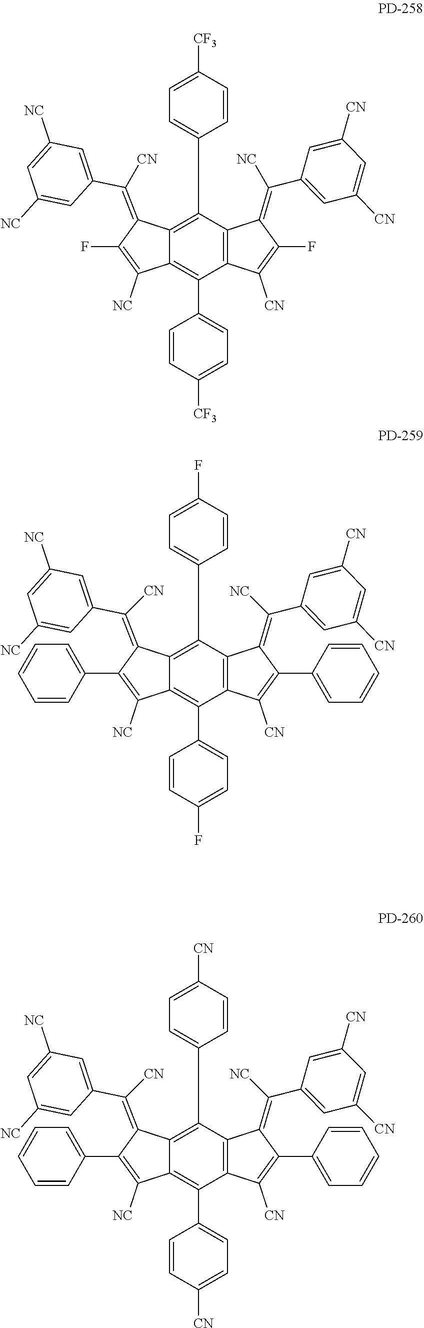 [SMILES: N#CC1=C(F)/C(=C(/C#N)c2cc(C#N)cc(C#N)c2)c2c1c(-c1ccc(C(F)(F)F)cc1)c1c(c2-c2ccc(C(F)(F)F)cc2)/C(=C(\C#N)c2cc(C#N)cc(C#N)c2)C(F)=C1C#N ; N#CC1=C(c2ccccc2)/C(=C(/C#N)c2cc(C#N)cc(C#N)c2)c2c1c(-c1ccc(F)cc1)c1c(c2-c2ccc(F)cc2)/C(=C(\C#N)c2cc(C#N)cc(C#N)c2)C(c2ccccc2)=C1C#N ; N#CC1=C(c2ccccc2)/C(=C(/C#N)c2cc(C#N)cc(C#N)c2)c2c1c(-c1ccc(C#N)cc1)c1c(c2-c2ccc(C#N)cc2)/C(=C(\C#N)c2cc(C#N)cc(C#N)c2)C(c2ccccc2)=C1C#N]

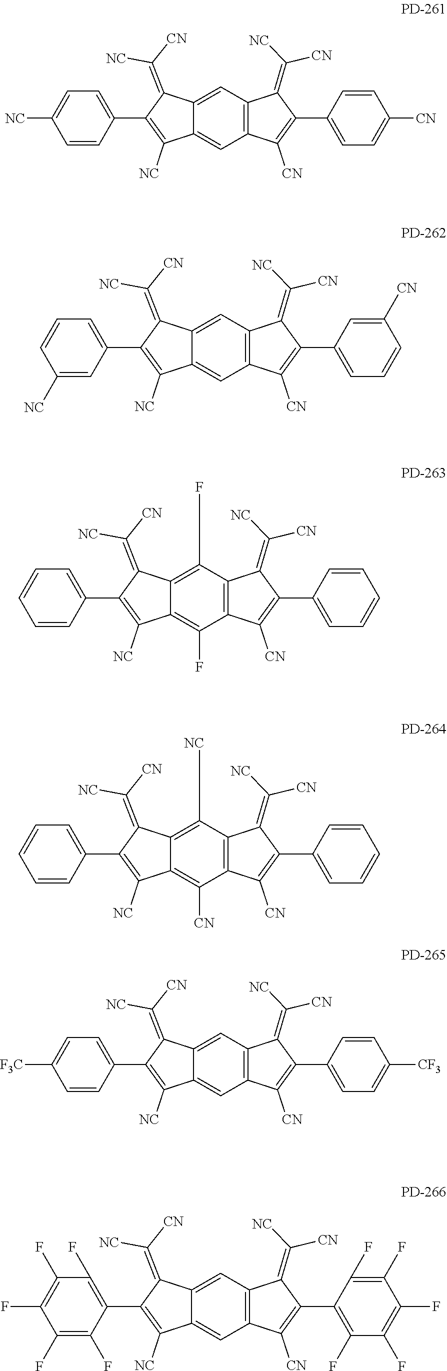

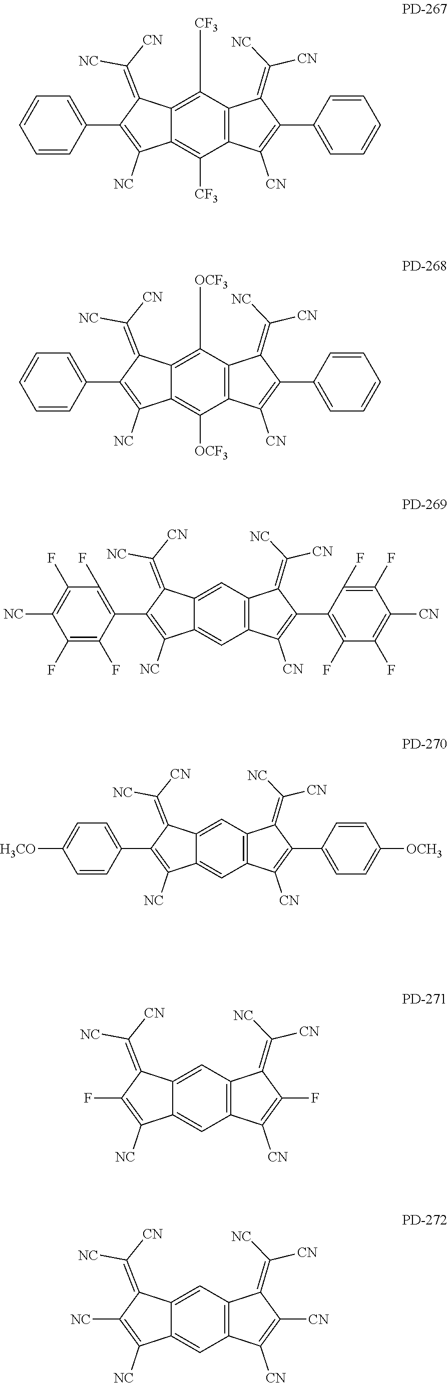 [SMILES: N#CC(C#N)=C1C(c2ccccc2)=C(C#N)c2c1c(C(F)(F)F)c1c(c2C(F)(F)F)C(C#N)=C(c2ccccc2)C1=C(C#N)C#N ; N#CC(C#N)=C1C(c2ccccc2)=C(C#N)c2c(OC(F)(F)F)c3c(c(OC(F)(F)F)c21)C(=C(C#N)C#N)C(c1ccccc1)=C3C#N ; N#CC(C#N)=C1C(c2c(F)c(F)c(C#N)c(F)c2F)=C(C#N)c2cc3c(cc21)C(=C(C#N)C#N)C(c1c(F)c(F)c(C#N)c(F)c1F)=C3C#N ; COc1ccc(C2=C(C#N)c3cc4c(cc3C2=C(C#N)C#N)C(=C(C#N)C#N)C(c2ccc(OC)cc2)=C4C#N)cc1 ; N#CC(C#N)=C1C(F)=C(C#N)c2cc3c(cc21)C(=C(C#N)C#N)C(F)=C3C#N ; N#CC(C#N)=C1C(C#N)=C(C#N)c2cc3c(cc21)C(=C(C#N)C#N)C(C#N)=C3C#N]

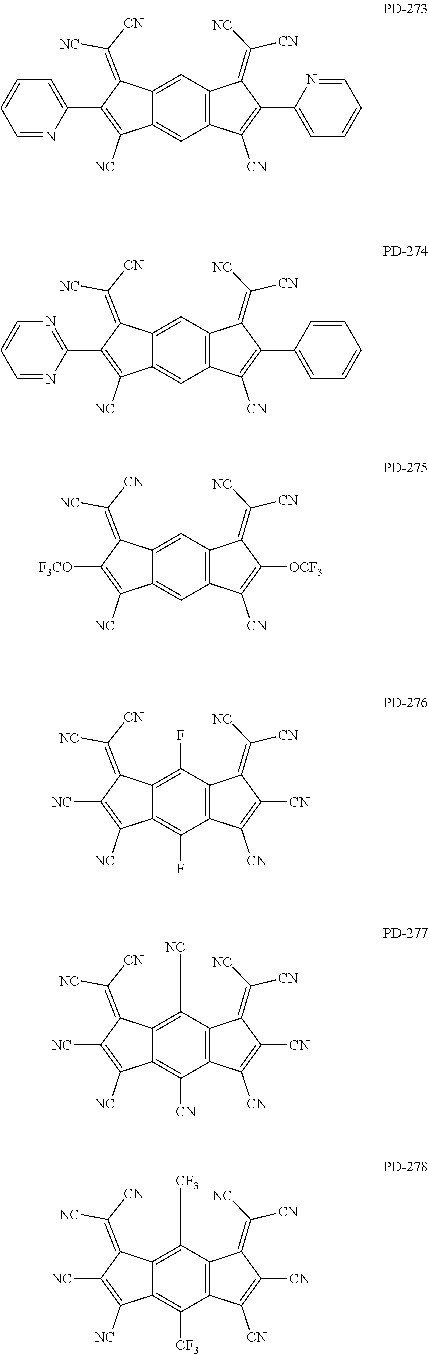 [SMILES: N#CC(C#N)=C1C(c2ccccn2)=C(C#N)c2cc3c(cc21)C(=C(C#N)C#N)C(c1ccccn1)=C3C#N ; N#CC(C#N)=C1C(c2ccccc2)=C(C#N)c2cc3c(cc21)C(=C(C#N)C#N)C(c1ncccn1)=C3C#N ; N#CC(C#N)=C1C(OC(F)(F)F)=C(C#N)c2cc3c(cc21)C(=C(C#N)C#N)C(OC(F)(F)F)=C3C#N ; N#CC(C#N)=C1C(C#N)=C(C#N)c2c(F)c3c(c(F)c21)C(=C(C#N)C#N)C(C#N)=C3C#N ; N#CC(C#N)=C1C(C#N)=C(C#N)c2c(C#N)c3c(c(C#N)c21)C(=C(C#N)C#N)C(C#N)=C3C#N ; N#CC(C#N)=C1C(C#N)=C(C#N)c2c1c(C(F)(F)F)c1c(c2C(F)(F)F)C(C#N)=C(C#N)C1=C(C#N)C#N]

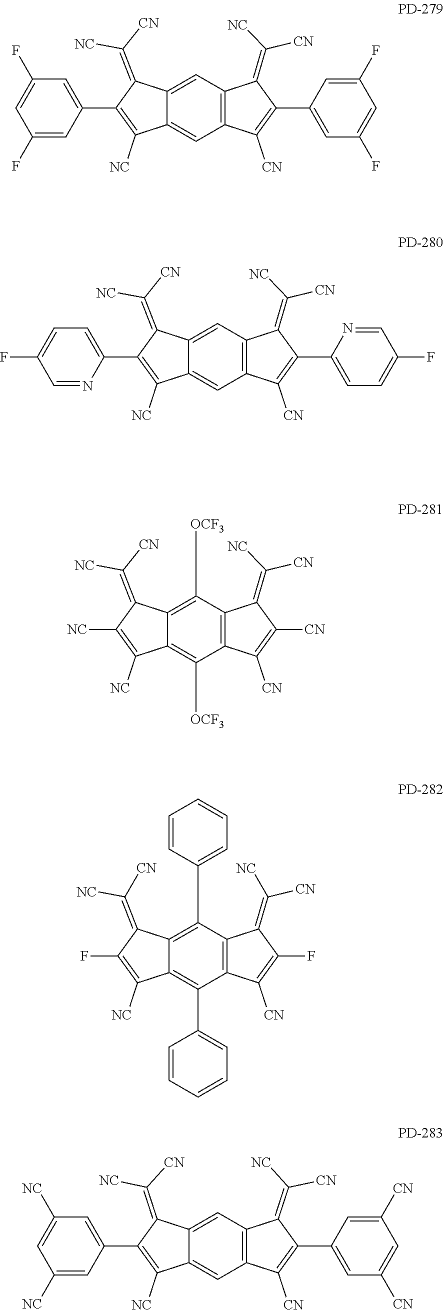 [SMILES: N#CC(C#N)=C1C(c2cc(F)cc(F)c2)=C(C#N)c2cc3c(cc21)C(=C(C#N)C#N)C(c1cc(F)cc(F)c1)=C3C#N ; N#CC(C#N)=C1C(c2ccc(F)cn2)=C(C#N)c2cc3c(cc21)C(=C(C#N)C#N)C(c1ccc(F)cn1)=C3C#N ; N#CC(C#N)=C1C(C#N)=C(C#N)c2c(OC(F)(F)F)c3c(c(OC(F)(F)F)c21)C(=C(C#N)C#N)C(C#N)=C3C#N ; N#CC(C#N)=C1C(F)=C(C#N)c2c1c(-c1ccccc1)c1c(c2-c2ccccc2)C(C#N)=C(F)C1=C(C#N)C#N ; N#CC(C#N)=C1C(c2cc(C#N)cc(C#N)c2)=C(C#N)c2cc3c(cc21)C(=C(C#N)C#N)C(c1cc(C#N)cc(C#N)c1)=C3C#N]

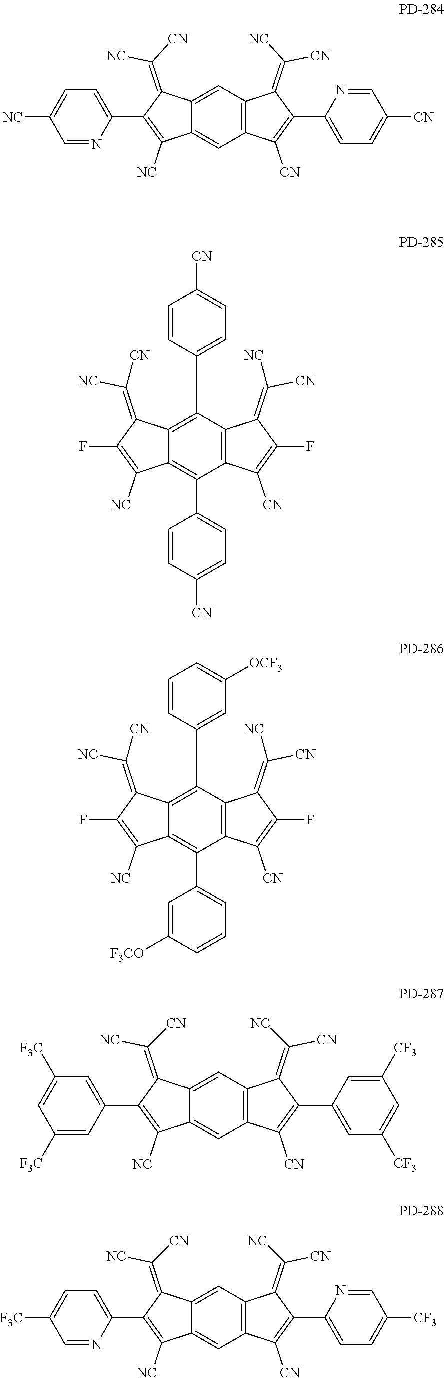 [SMILES: N#CC(C#N)=C1C(c2ccc(C#N)cn2)=C(C#N)c2cc3c(cc21)C(=C(C#N)C#N)C(c1ccc(C#N)cn1)=C3C#N ; N#CC(C#N)=C1C(F)=C(C#N)c2c1c(-c1ccc(C#N)cc1)c1c(c2-c2ccc(C#N)cc2)C(C#N)=C(F)C1=C(C#N)C#N ; N#CC(C#N)=C1C(F)=C(C#N)c2c1c(-c1cccc(OC(F)(F)F)c1)c1c(c2-c2cccc(OC(F)(F)F)c2)C(C#N)=C(F)C1=C(C#N)C#N ; N#CC(C#N)=C1C(c2cc(C(F)(F)F)cc(C(F)(F)F)c2)=C(C#N)c2cc3c(cc21)C(=C(C#N)C#N)C(c1cc(C(F)(F)F)cc(C(F)(F)F)c1)=C3C#N ; N#CC(C#N)=C1C(c2ccc(C(F)(F)F)cn2)=C(C#N)c2cc3c(cc21)C(=C(C#N)C#N)C(c1ccc(C(F)(F)F)cn1)=C3C#N]

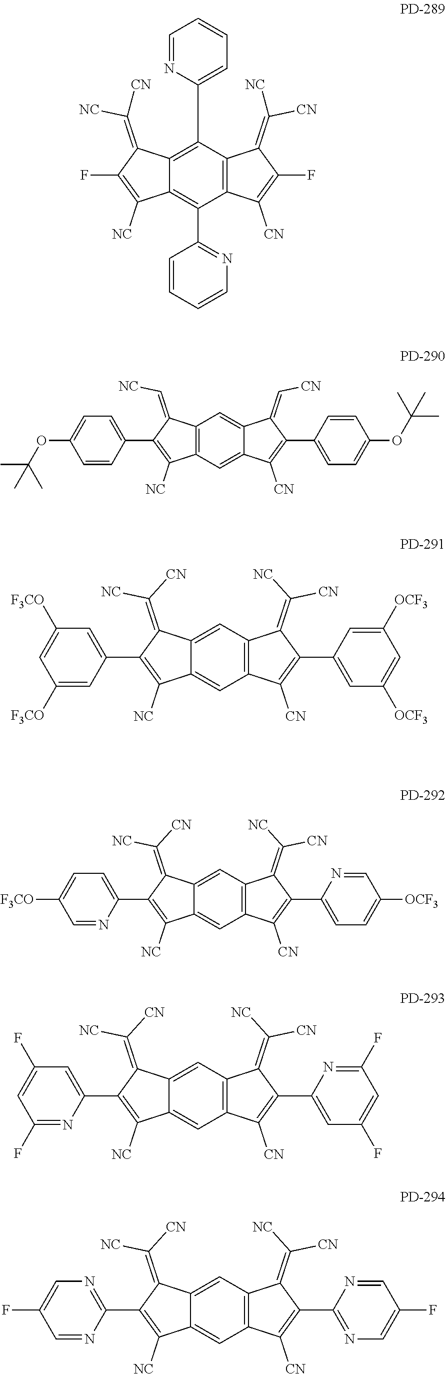

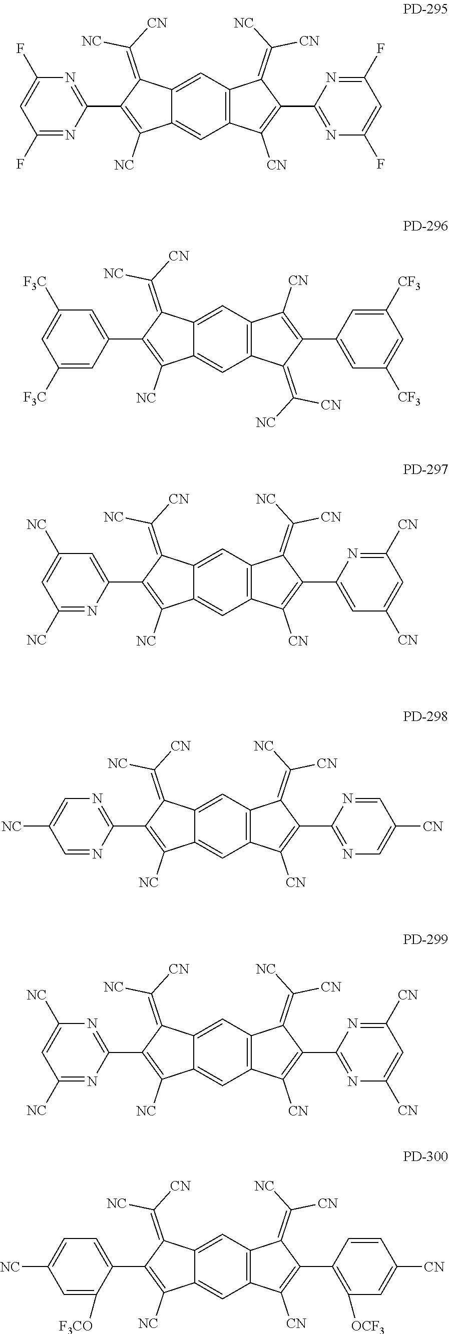

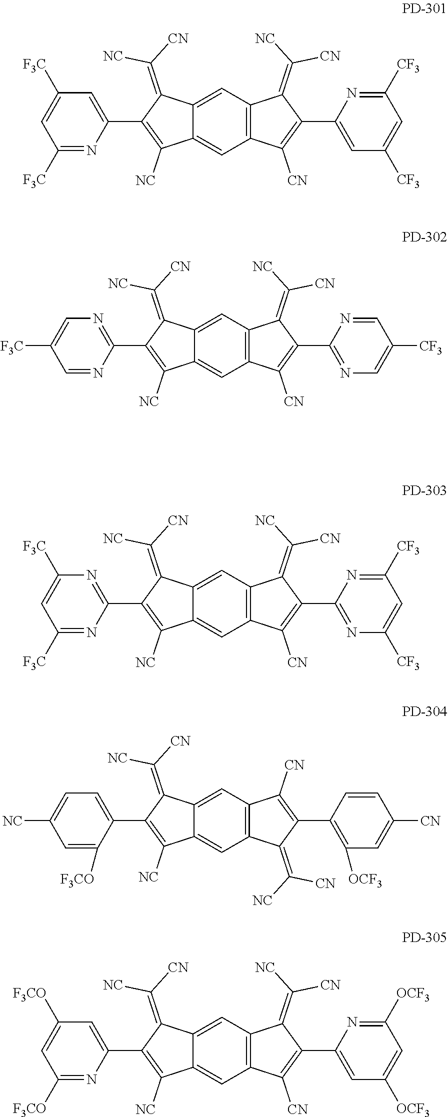

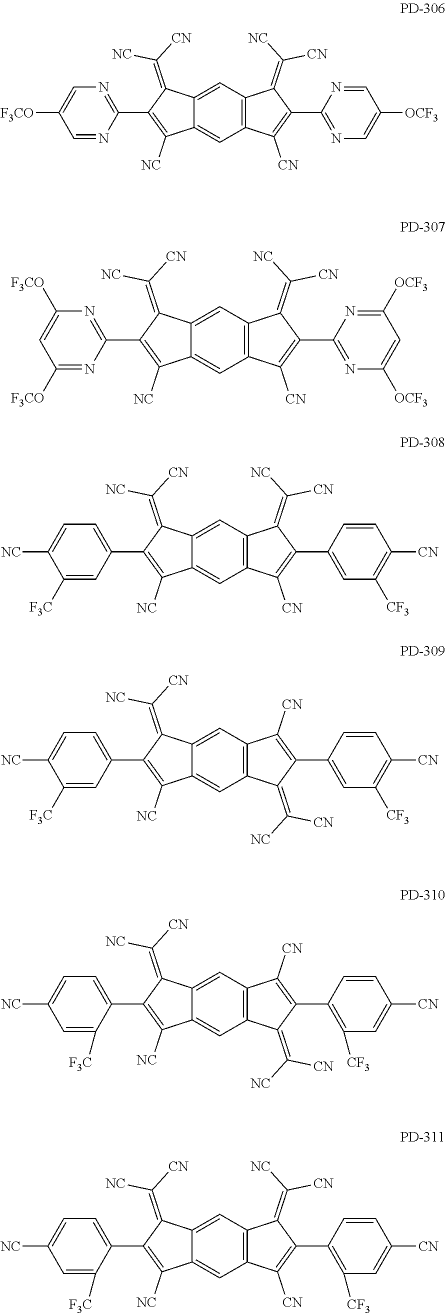

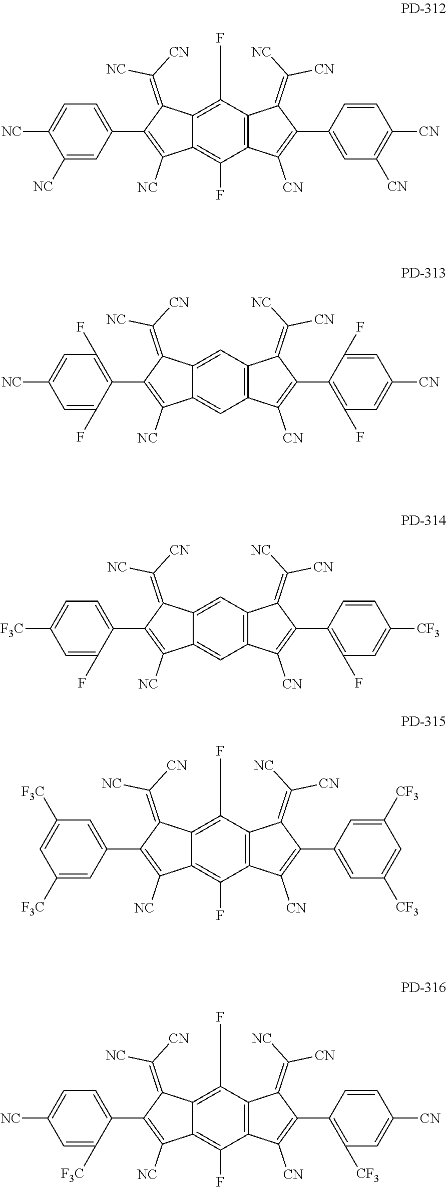

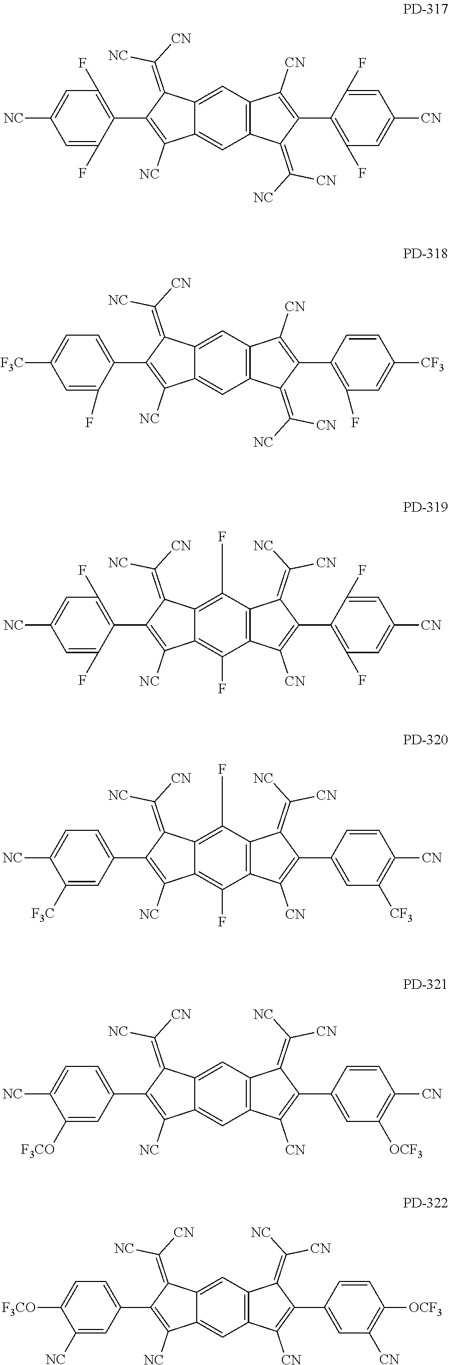

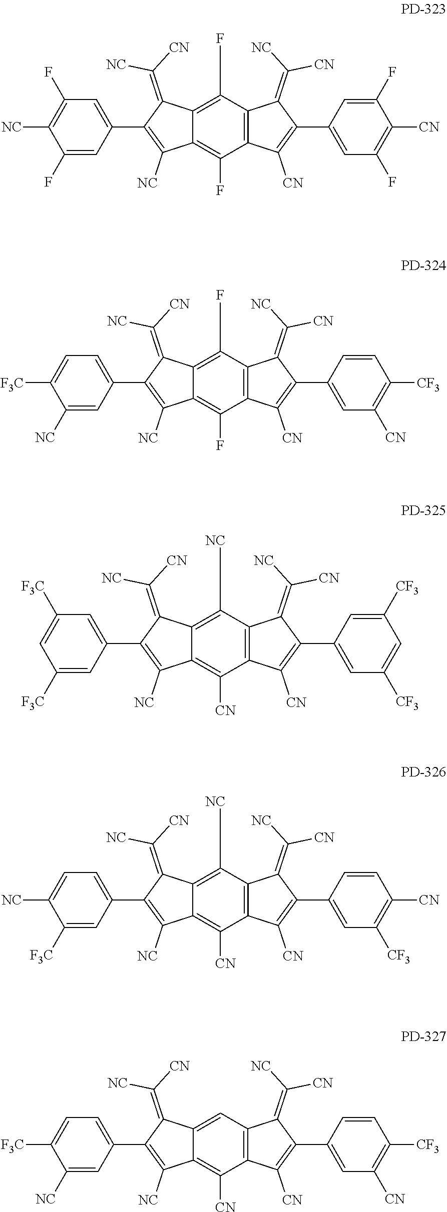

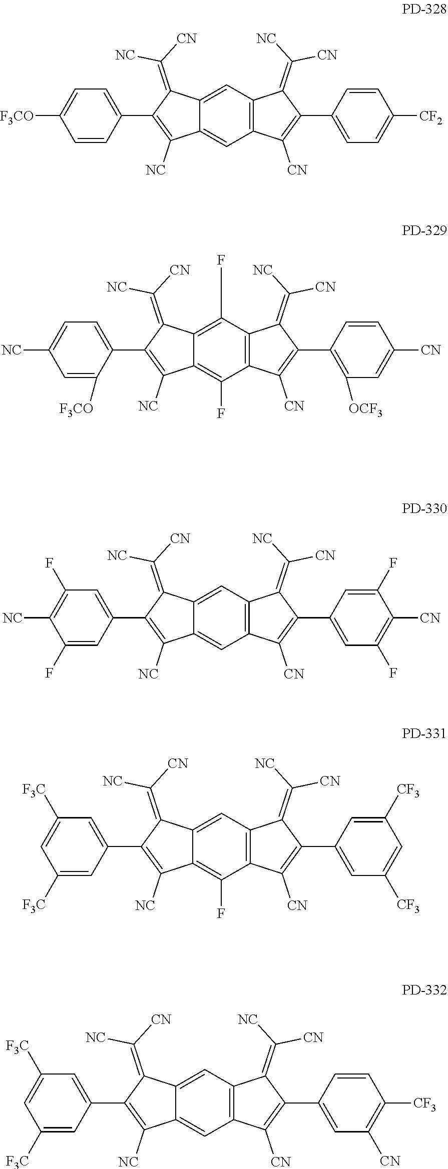

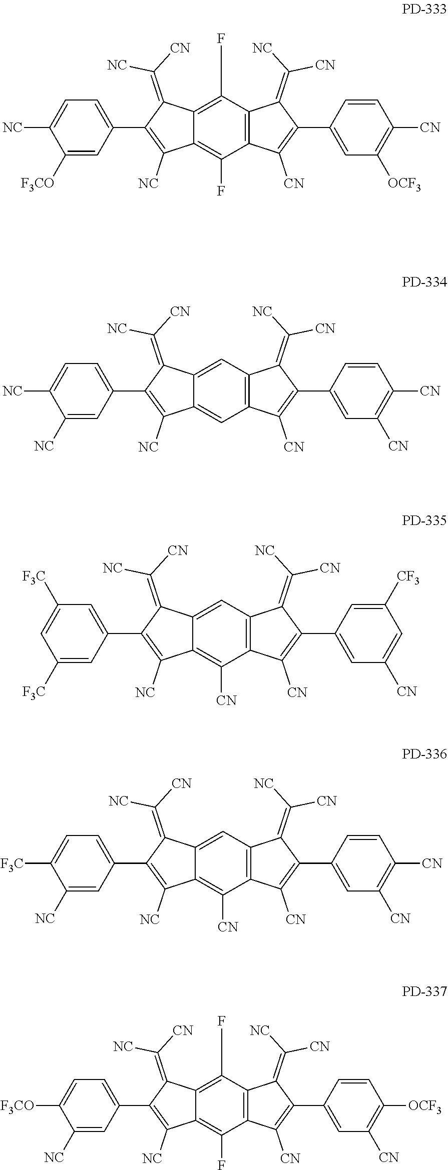

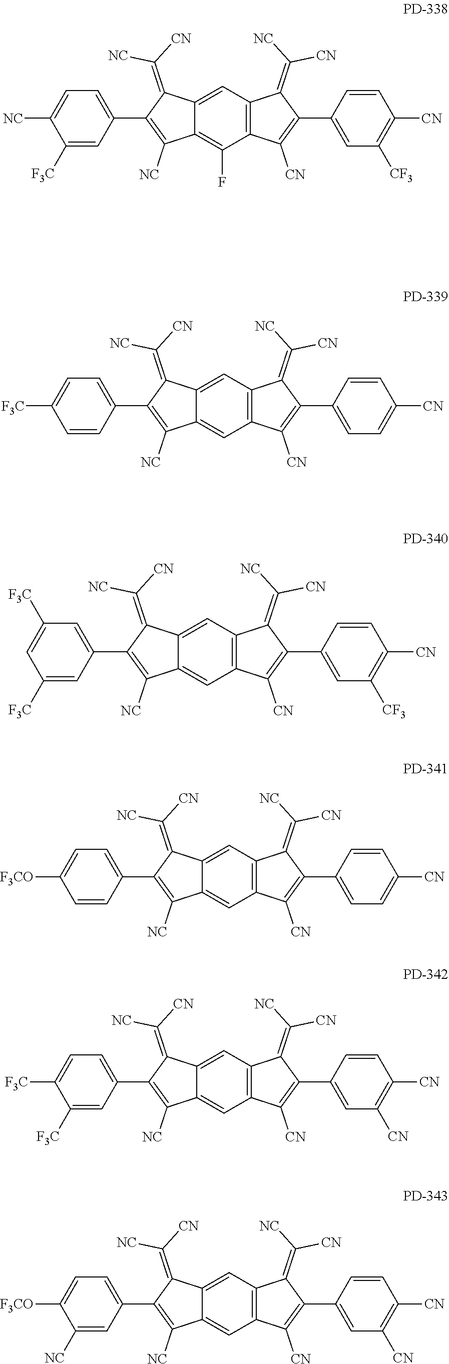

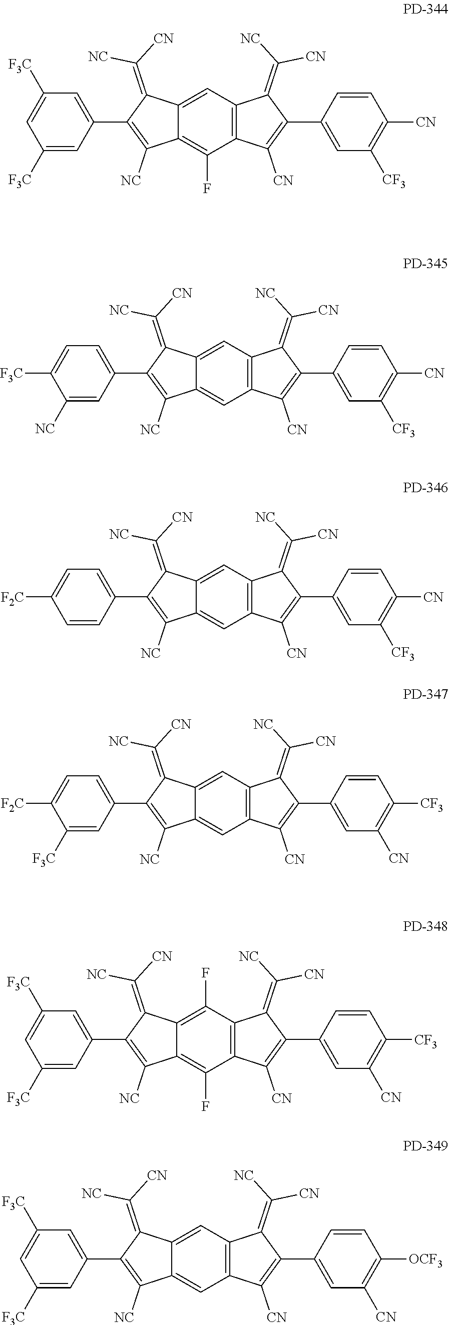

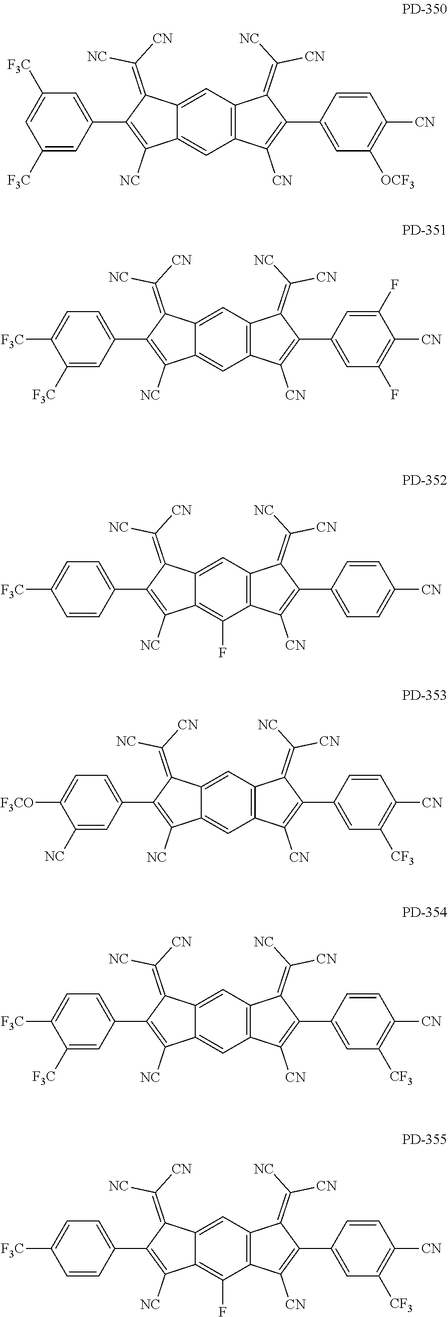

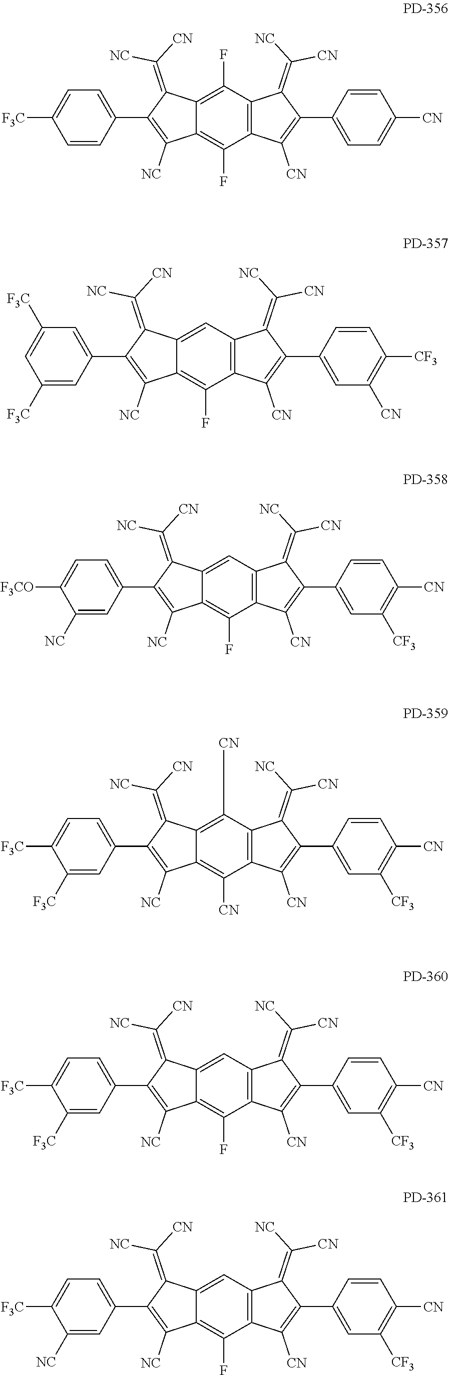

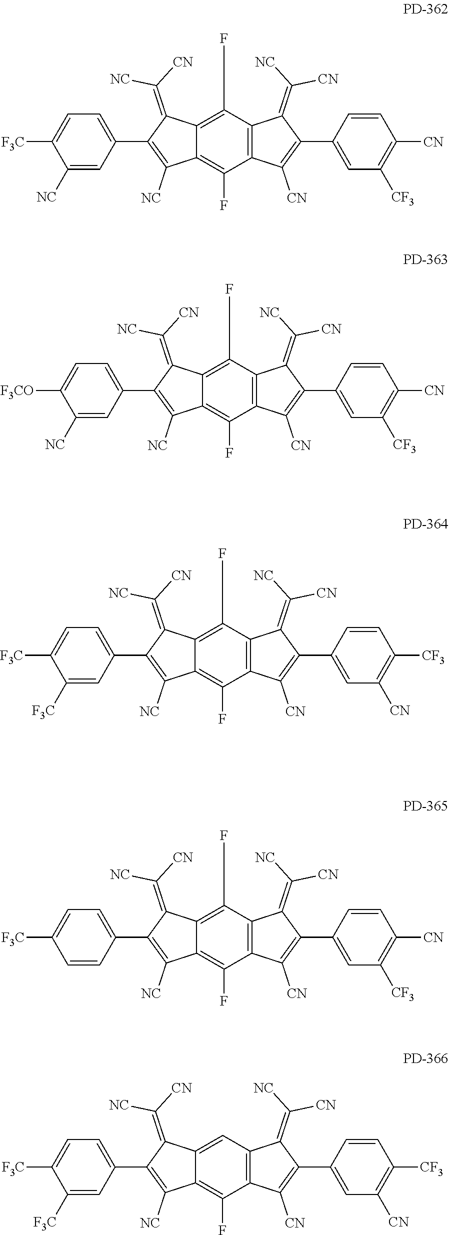

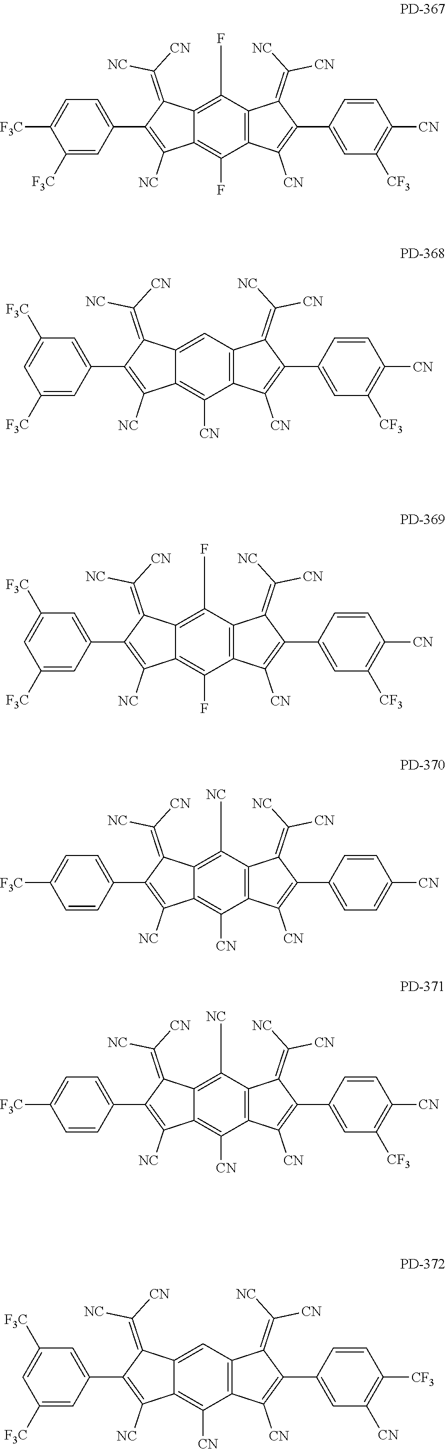

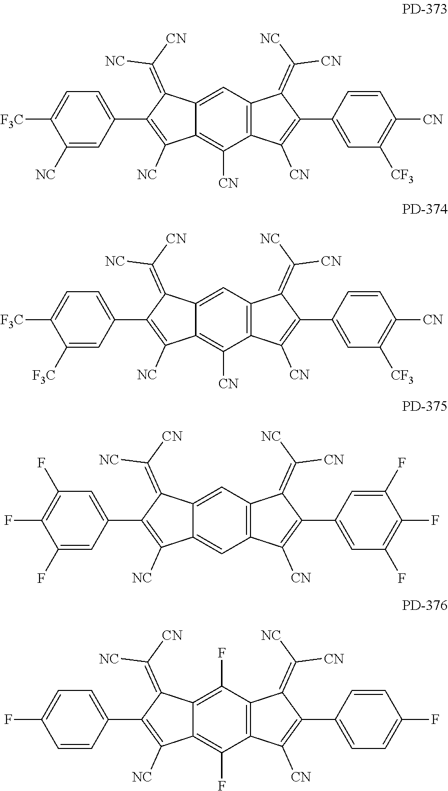 [SMILES: N#CC(C#N)=C1C(c2ccc(C(F)(F)F)c(C#N)c2)=C(C#N)c2c1cc1c(c2C#N)C(C#N)=C(c2ccc(C#N)c(C(F)(F)F)c2)C1=C(C#N)C#N ; N#CC(C#N)=C1C(c2ccc(C#N)c(C(F)(F)F)c2)=C(C#N)c2c1cc1c(c2C#N)C(C#N)=C(c2ccc(C(F)(F)F)c(C(F)(F)F)c2)C1=C(C#N)C#N ; N#CC(C#N)=C1C(c2cc(F)c(F)c(F)c2)=C(C#N)c2cc3c(cc21)C(=C(C#N)C#N)C(c1cc(F)c(F)c(F)c1)=C3C#N ; N#CC(C#N)=C1C(c2ccc(F)cc2)=C(C#N)c2c(F)c3c(c(F)c21)C(=C(C#N)C#N)C(c1ccc(F)cc1)=C3C#N]

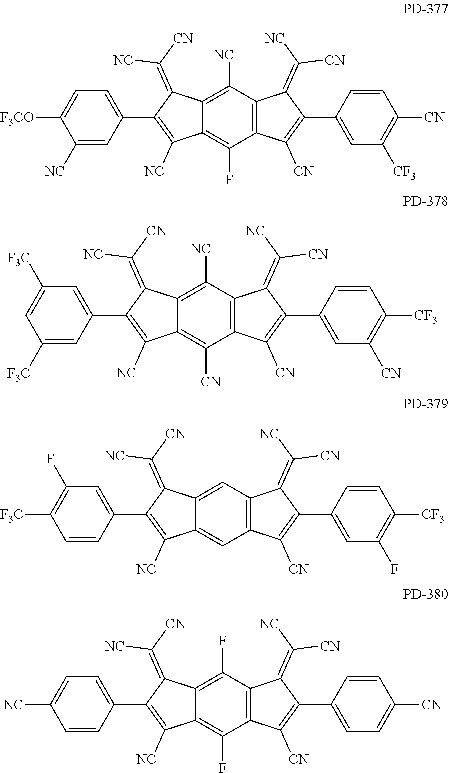 [SMILES: N#CC(C#N)=C1C(c2ccc(OC(F)(F)F)c(C#N)c2)=C(C#N)c2c(F)c3c(c(C#N)c21)C(=C(C#N)C#N)C(c1ccc(C#N)c(C(F)(F)F)c1)=C3C#N ; N#CC(C#N)=C1C(c2cc(C(F)(F)F)cc(C(F)(F)F)c2)=C(C#N)c2c(C#N)c3c(c(C#N)c21)C(=C(C#N)C#N)C(c1ccc(C(F)(F)F)c(C#N)c1)=C3C#N ; N#CC(C#N)=C1C(c2ccc(C(F)(F)F)c(F)c2)=C(C#N)c2cc3c(cc21)C(=C(C#N)C#N)C(c1ccc(C(F)(F)F)c(F)c1)=C3C#N ; N#CC(C#N)=C1C(c2ccc(C#N)cc2)=C(C#N)c2c(F)c3c(c(F)c21)C(=C(C#N)C#N)C(c1ccc(C#N)cc1)=C3C#N]

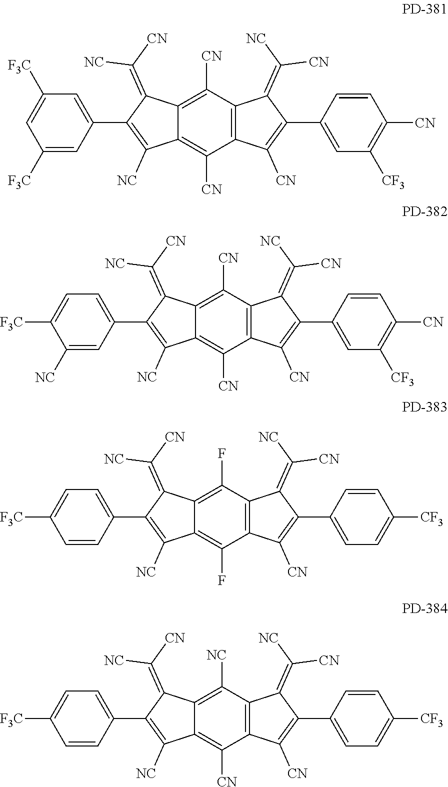 [SMILES: N#CC(C#N)=C1C(c2cc(C(F)(F)F)cc(C(F)(F)F)c2)=C(C#N)c2c(C#N)c3c(c(C#N)c21)C(=C(C#N)C#N)C(c1ccc(C#N)c(C(F)(F)F)c1)=C3C#N ; N#CC(C#N)=C1C(c2ccc(C(F)(F)F)c(C#N)c2)=C(C#N)c2c(C#N)c3c(c(C#N)c21)C(=C(C#N)C#N)C(c1ccc(C#N)c(C(F)(F)F)c1)=C3C#N ; N#CC(C#N)=C1C(c2ccc(C(F)(F)F)cc2)=C(C#N)c2c(F)c3c(c(F)c21)C(=C(C#N)C#N)C(c1ccc(C(F)(F)F)cc1)=C3C#N ; N#CC(C#N)=C1C(c2ccc(C(F)(F)F)cc2)=C(C#N)c2c(C#N)c3c(c(C#N)c21)C(=C(C#N)C#N)C(c1ccc(C(F)(F)F)cc1)=C3C#N]

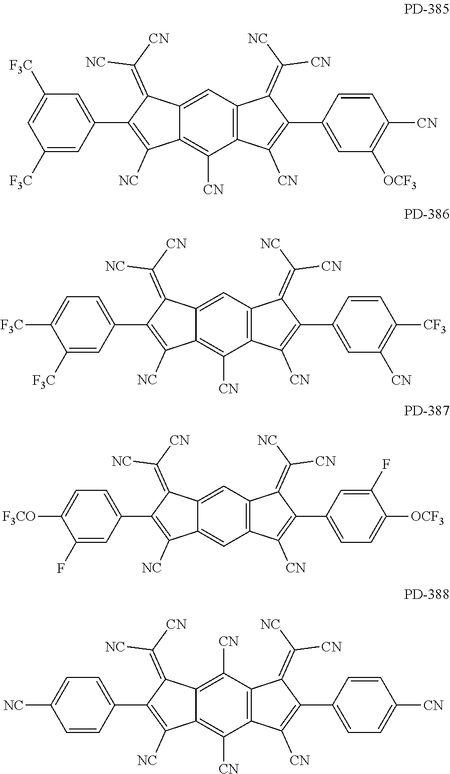 [SMILES: N#CC(C#N)=C1C(c2cc(C(F)(F)F)cc(C(F)(F)F)c2)=C(C#N)c2c1cc1c(c2C#N)C(C#N)=C(c2ccc(C#N)c(OC(F)(F)F)c2)C1=C(C#N)C#N ; N#CC(C#N)=C1C(c2ccc(C(F)(F)F)c(C#N)c2)=C(C#N)c2c1cc1c(c2C#N)C(C#N)=C(c2ccc(C(F)(F)F)c(C(F)(F)F)c2)C1=C(C#N)C#N ; N#CC(C#N)=C1C(c2ccc(OC(F)(F)F)c(F)c2)=C(C#N)c2cc3c(cc21)C(=C(C#N)C#N)C(c1ccc(OC(F)(F)F)c(F)c1)=C3C#N ; N#CC(C#N)=C1C(c2ccc(C#N)cc2)=C(C#N)c2c(C#N)c3c(c(C#N)c21)C(=C(C#N)C#N)C(c1ccc(C#N)cc1)=C3C#N]

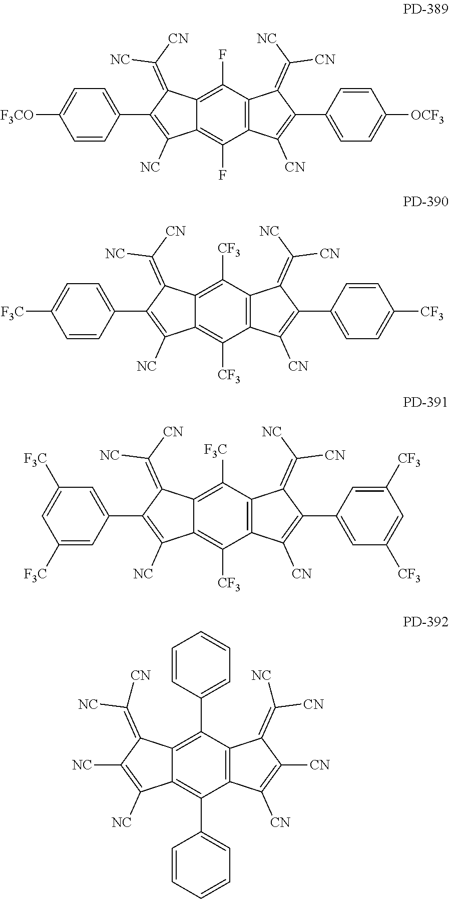 [SMILES: N#CC(C#N)=C1C(c2ccc(OC(F)(F)F)cc2)=C(C#N)c2c(F)c3c(c(F)c21)C(=C(C#N)C#N)C(c1ccc(OC(F)(F)F)cc1)=C3C#N ; N#CC(C#N)=C1C(c2ccc(C(F)(F)F)cc2)=C(C#N)c2c1c(C(F)(F)F)c1c(c2C(F)(F)F)C(C#N)=C(c2ccc(C(F)(F)F)cc2)C1=C(C#N)C#N ; N#CC(C#N)=C1C(c2cc(C(F)(F)F)cc(C(F)(F)F)c2)=C(C#N)c2c1c(C(F)(F)F)c1c(c2C(F)(F)F)C(C#N)=C(c2cc(C(F)(F)F)cc(C(F)(F)F)c2)C1=C(C#N)C#N ; N#CC(C#N)=C1C(C#N)=C(C#N)c2c1c(-c1ccccc1)c1c(c2-c2ccccc2)C(C#N)=C(C#N)C1=C(C#N)C#N]

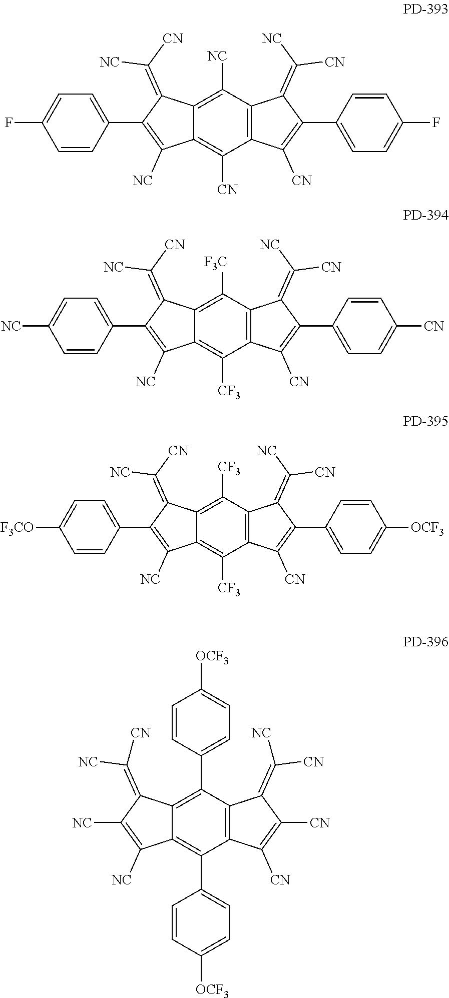 [SMILES: N#CC(C#N)=C1C(c2ccc(F)cc2)=C(C#N)c2c(C#N)c3c(c(C#N)c21)C(=C(C#N)C#N)C(c1ccc(F)cc1)=C3C#N ; N#CC(C#N)=C1C(c2ccc(C#N)cc2)=C(C#N)c2c1c(C(F)(F)F)c1c(c2C(F)(F)F)C(C#N)=C(c2ccc(C#N)cc2)C1=C(C#N)C#N ; N#CC(C#N)=C1C(c2ccc(OC(F)(F)F)cc2)=C(C#N)c2c1c(C(F)(F)F)c1c(c2C(F)(F)F)C(C#N)=C(c2ccc(OC(F)(F)F)cc2)C1=C(C#N)C#N ; N#CC(C#N)=C1C(C#N)=C(C#N)c2c1c(-c1ccc(OC(F)(F)F)cc1)c1c(c2-c2ccc(OC(F)(F)F)cc2)C(C#N)=C(C#N)C1=C(C#N)C#N]

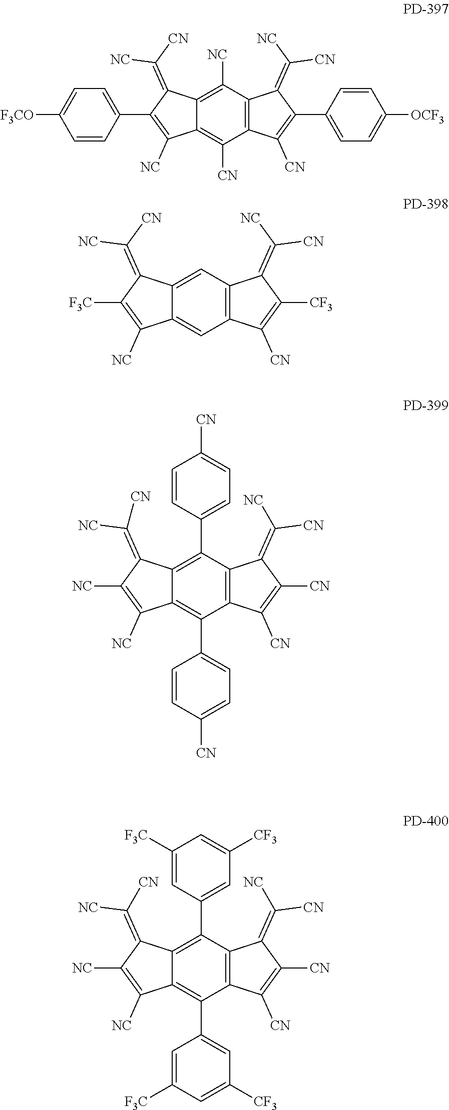 [SMILES: N#CC(C#N)=C1C(c2ccc(OC(F)(F)F)cc2)=C(C#N)c2c(C#N)c3c(c(C#N)c21)C(=C(C#N)C#N)C(c1ccc(OC(F)(F)F)cc1)=C3C#N ; N#CC(C#N)=C1C(C(F)(F)F)=C(C#N)c2cc3c(cc21)C(=C(C#N)C#N)C(C(F)(F)F)=C3C#N ; N#CC(C#N)=C1C(C#N)=C(C#N)c2c1c(-c1ccc(C#N)cc1)c1c(c2-c2ccc(C#N)cc2)C(C#N)=C(C#N)C1=C(C#N)C#N ; N#CC(C#N)=C1C(C#N)=C(C#N)c2c1c(-c1cc(C(F)(F)F)cc(C(F)(F)F)c1)c1c(c2-c2cc(C(F)(F)F)cc(C(F)(F)F)c2)C(C#N)=C(C#N)C1=C(C#N)C#N]

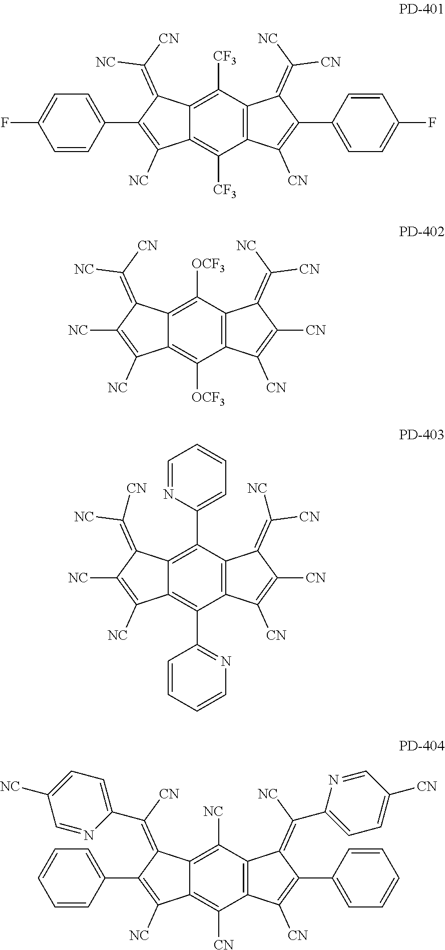 [SMILES: N#CC(C#N)=C1C(c2ccc(F)cc2)=C(C#N)c2c1c(C(F)(F)F)c1c(c2C(F)(F)F)C(C#N)=C(c2ccc(F)cc2)C1=C(C#N)C#N ; N#CC(C#N)=C1C(C#N)=C(C#N)c2c(OC(F)(F)F)c3c(c(OC(F)(F)F)c21)C(=C(C#N)C#N)C(C#N)=C3C#N ; N#CC(C#N)=C1C(C#N)=C(C#N)c2c1c(-c1ccccn1)c1c(c2-c2ccccn2)C(C#N)=C(C#N)C1=C(C#N)C#N ; N#CC1=C(c2ccccc2)/C(=C(/C#N)c2ccc(C#N)cn2)c2c(C#N)c3c(c(C#N)c21)C(C#N)=C(c1ccccc1)/C3=C(/C#N)c1ccc(C#N)cn1]

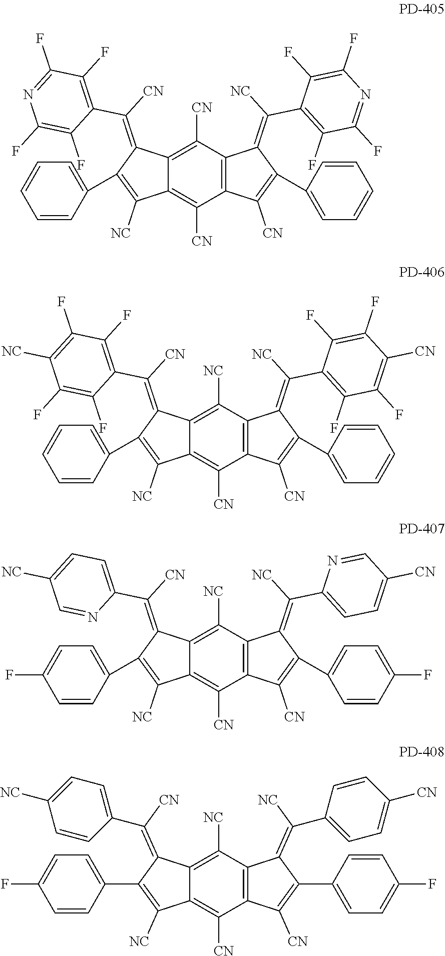 [SMILES: N#CC1=C(c2ccccc2)/C(=C(/C#N)c2c(F)c(F)nc(F)c2F)c2c(C#N)c3c(c(C#N)c21)C(C#N)=C(c1ccccc1)/C3=C(/C#N)c1c(F)c(F)nc(F)c1F ; N#CC1=C(c2ccccc2)/C(=C(/C#N)c2c(F)c(F)c(C#N)c(F)c2F)c2c(C#N)c3c(c(C#N)c21)C(C#N)=C(c1ccccc1)/C3=C(/C#N)c1c(F)c(F)c(C#N)c(F)c1F ; N#CC1=C(c2ccc(F)cc2)/C(=C(/C#N)c2ccc(C#N)cn2)c2c(C#N)c3c(c(C#N)c21)C(C#N)=C(c1ccc(F)cc1)/C3=C(/C#N)c1ccc(C#N)cn1 ; N#CC1=C(c2ccc(F)cc2)/C(=C(/C#N)c2ccc(C#N)cc2)c2c(C#N)c3c(c(C#N)c21)C(C#N)=C(c1ccc(F)cc1)/C3=C(/C#N)c1ccc(C#N)cc1]

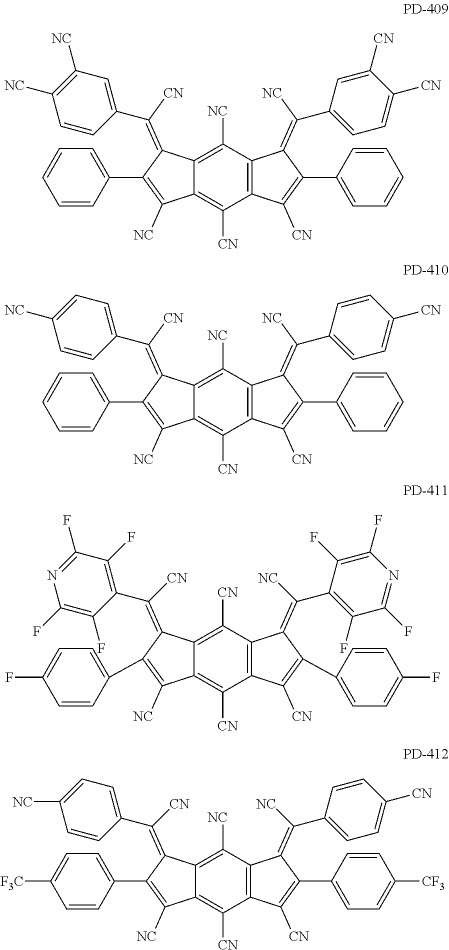 [SMILES: N#CC1=C(c2ccccc2)/C(=C(/C#N)c2ccc(C#N)c(C#N)c2)c2c(C#N)c3c(c(C#N)c21)C(C#N)=C(c1ccccc1)/C3=C(/C#N)c1ccc(C#N)c(C#N)c1 ; N#CC1=C(c2ccccc2)/C(=C(/C#N)c2ccc(C#N)cc2)c2c(C#N)c3c(c(C#N)c21)C(C#N)=C(c1ccccc1)/C3=C(/C#N)c1ccc(C#N)cc1 ; N#CC1=C(c2ccc(F)cc2)/C(=C(/C#N)c2c(F)c(F)nc(F)c2F)c2c(C#N)c3c(c(C#N)c21)C(C#N)=C(c1ccc(F)cc1)/C3=C(/C#N)c1c(F)c(F)nc(F)c1F ; N#CC1=C(c2ccc(C(F)(F)F)cc2)/C(=C(/C#N)c2ccc(C#N)cc2)c2c(C#N)c3c(c(C#N)c21)C(C#N)=C(c1ccc(C(F)(F)F)cc1)/C3=C(/C#N)c1ccc(C#N)cc1]

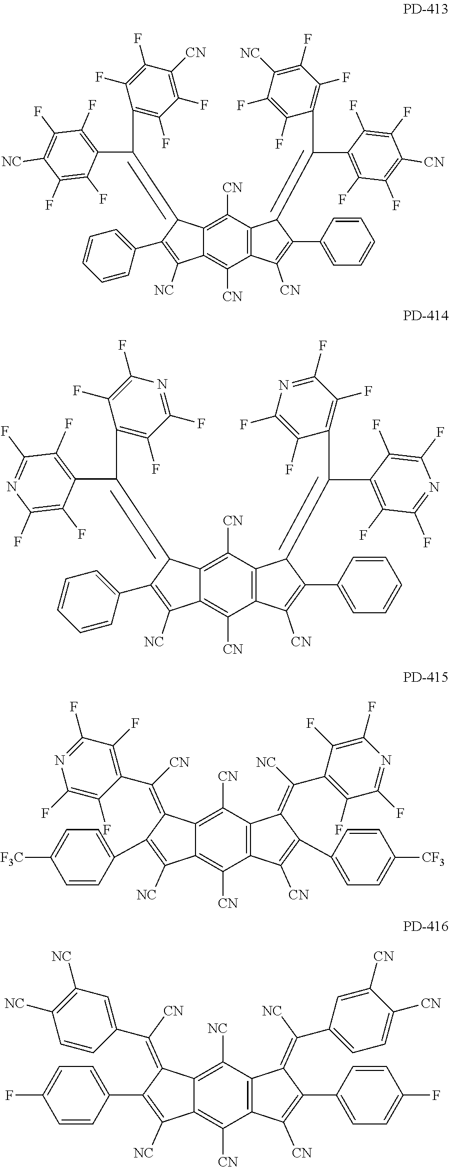

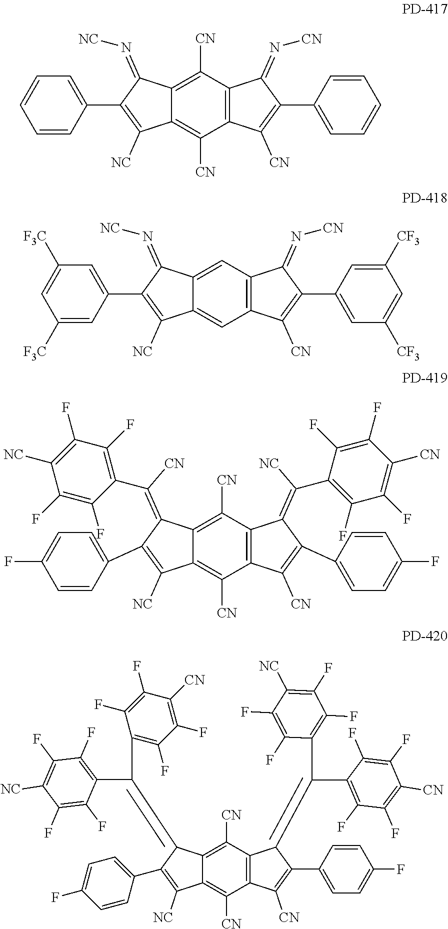 [SMILES: N#C/N=c1\c(-c2ccccc2)c(C#N)c2c(C#N)c3c(C#N)c(-c4ccccc4)/c(=N\C#N)c3c(C#N)c12 ; N#C/N=c1\c(-c2cc(C(F)(F)F)cc(C(F)(F)F)c2)c(C#N)c2cc3c(C#N)c(-c4cc(C(F)(F)F)cc(C(F)(F)F)c4)/c(=N\C#N)c3cc12 ; N#CC1=C(c2ccc(F)cc2)/C(=C(/C#N)c2c(F)c(F)c(C#N)c(F)c2F)c2c(C#N)c3c(c(C#N)c21)C(C#N)=C(c1ccc(F)cc1)/C3=C(/C#N)c1c(F)c(F)c(C#N)c(F)c1F ; N#CC1=C(c2ccc(F)cc2)C(=C(c2c(F)c(F)c(C#N)c(F)c2F)c2c(F)c(F)c(C#N)c(F)c2F)c2c(C#N)c3c(c(C#N)c21)C(C#N)=C(c1ccc(F)cc1)C3=C(c1c(F)c(F)c(C#N)c(F)c1F)c1c(F)c(F)c(C#N)c(F)c1F]

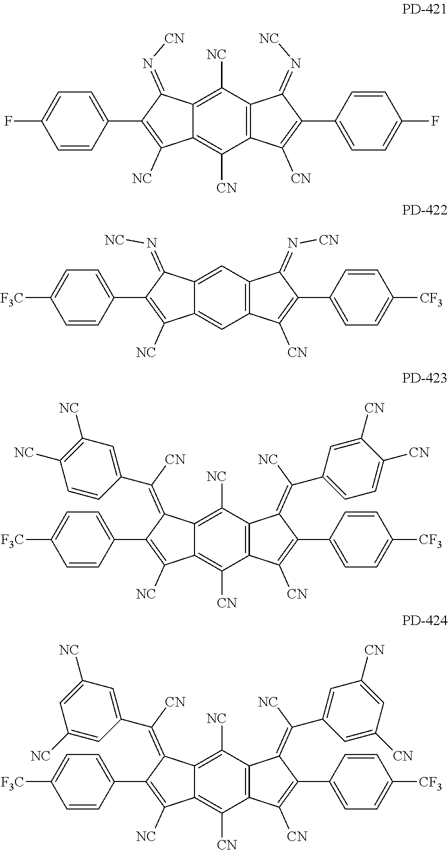 [SMILES: N#C/N=c1/c(-c2ccc(F)cc2)c(C#N)c2c(C#N)c3c(C#N)c(-c4ccc(F)cc4)/c(=N/C#N)c3c(C#N)c12 ; N#C/N=c1\c(-c2ccc(C(F)(F)F)cc2)c(C#N)c2cc3c(C#N)c(-c4ccc(C(F)(F)F)cc4)/c(=N\C#N)c3cc12 ; N#CC1=C(c2ccc(C(F)(F)F)cc2)/C(=C(/C#N)c2ccc(C#N)c(C#N)c2)c2c(C#N)c3c(c(C#N)c21)C(C#N)=C(c1ccc(C(F)(F)F)cc1)/C3=C(/C#N)c1ccc(C#N)c(C#N)c1 ; N#CC1=C(c2ccc(C(F)(F)F)cc2)/C(=C(/C#N)c2cc(C#N)cc(C#N)c2)c2c(C#N)c3c(c(C#N)c21)C(C#N)=C(c1ccc(C(F)(F)F)cc1)/C3=C(/C#N)c1cc(C#N)cc(C#N)c1]

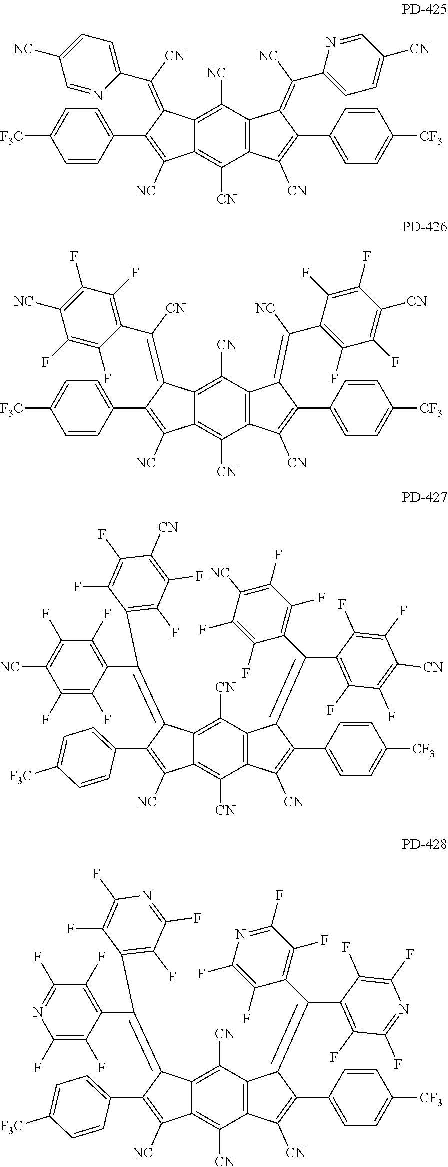

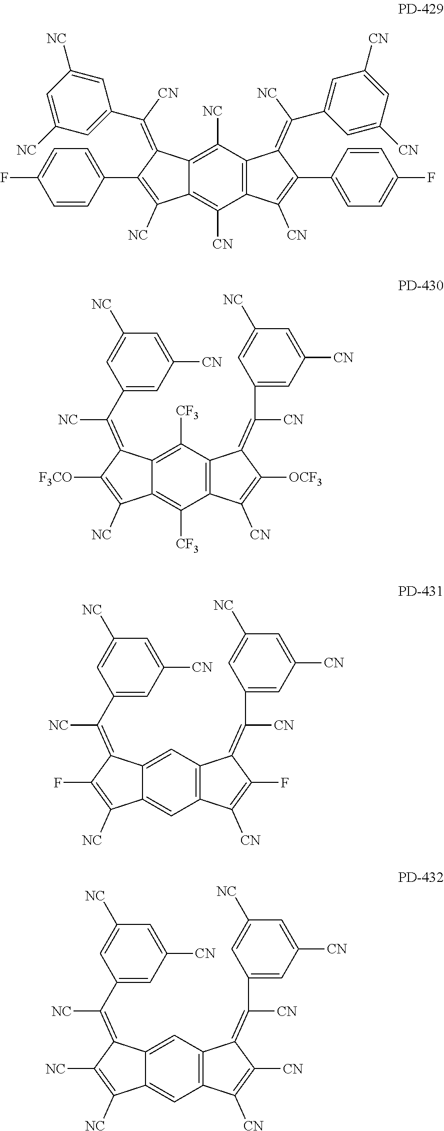 [SMILES: N#CC1=C(c2ccc(F)cc2)/C(=C(/C#N)c2cc(C#N)cc(C#N)c2)c2c(C#N)c3c(c(C#N)c21)C(C#N)=C(c1ccc(F)cc1)/C3=C(/C#N)c1cc(C#N)cc(C#N)c1 ; N#CC1=C(OC(F)(F)F)/C(=C(\C#N)c2cc(C#N)cc(C#N)c2)c2c1c(C(F)(F)F)c1c(c2C(F)(F)F)/C(=C(/C#N)c2cc(C#N)cc(C#N)c2)C(OC(F)(F)F)=C1C#N ; N#CC1=C(F)/C(=C(\C#N)c2cc(C#N)cc(C#N)c2)c2cc3c(cc21)C(C#N)=C(F)/C3=C(\C#N)c1cc(C#N)cc(C#N)c1 ; N#CC1=C(C#N)c2cc3c(cc2/C1=C(/C#N)c1cc(C#N)cc(C#N)c1)/C(=C(/C#N)c1cc(C#N)cc(C#N)c1)C(C#N)=C3C#N]

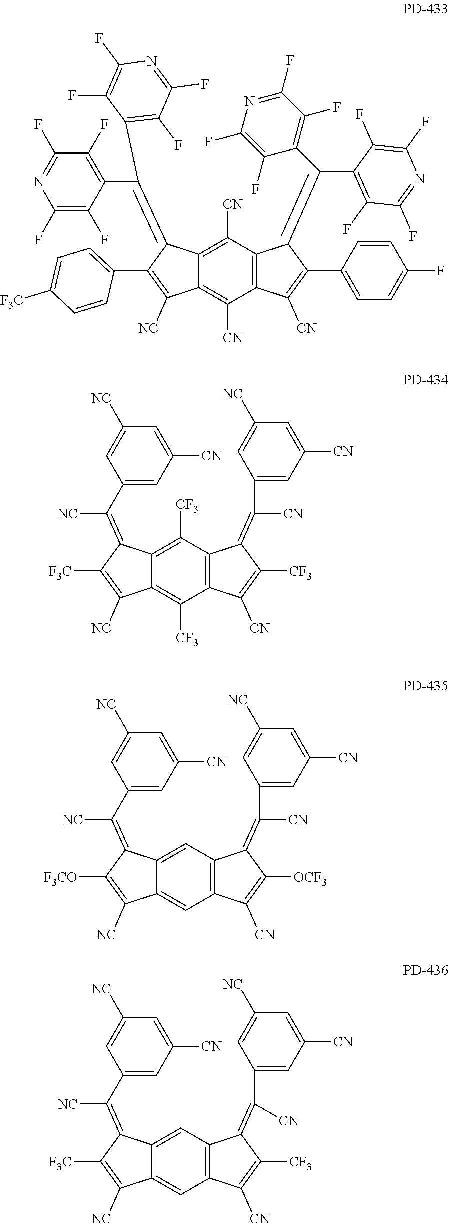

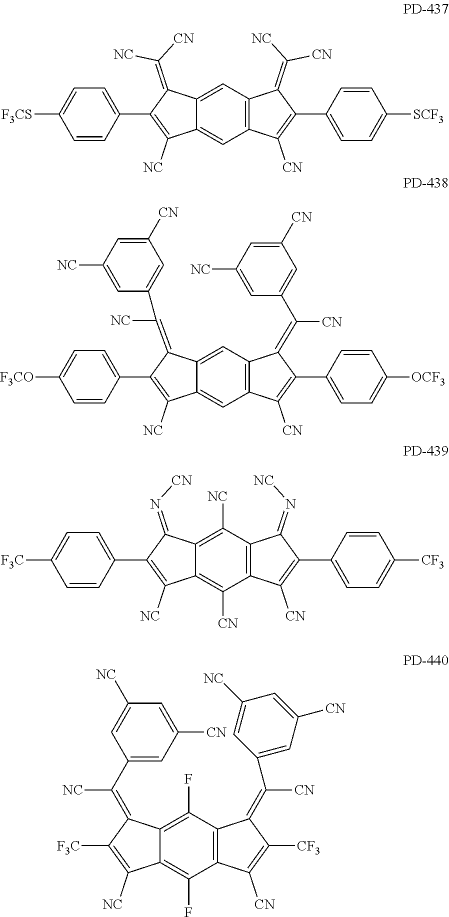

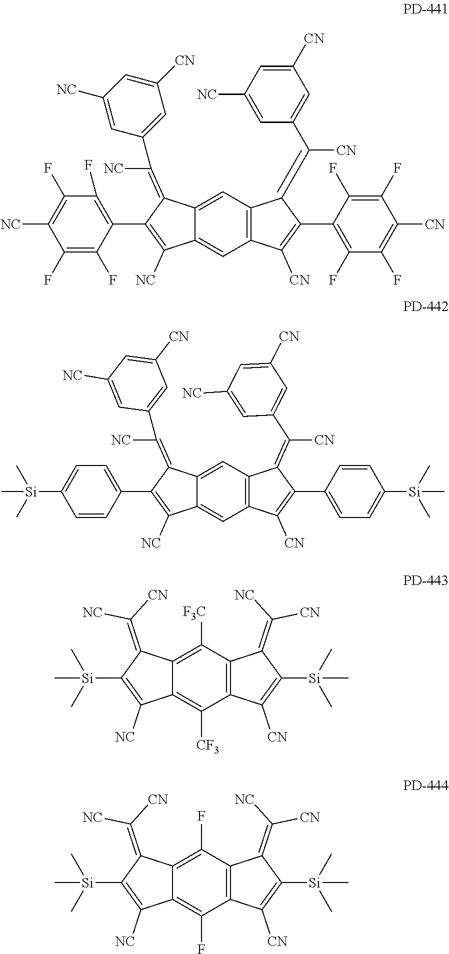

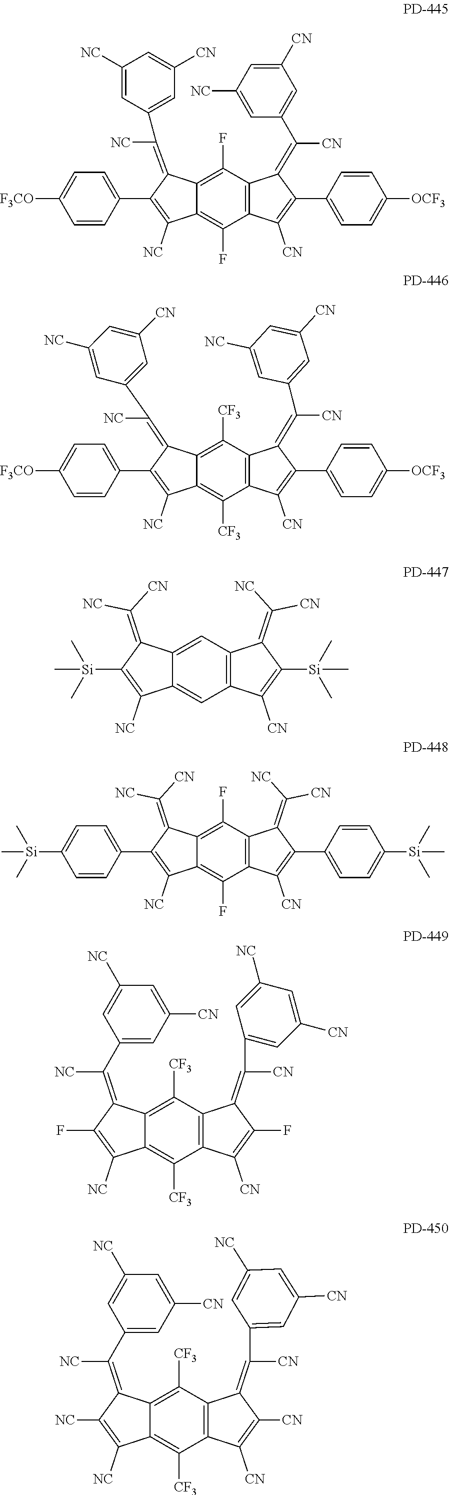

According to one implementation of the present disclosure, the structure of the second compound represented by Chemical Formula 3 above may be one selected from the group consisting of the following Compounds PH-1 to PH-315, but is not limited thereto as long as it falls within the definition of Chemical Formula 3.

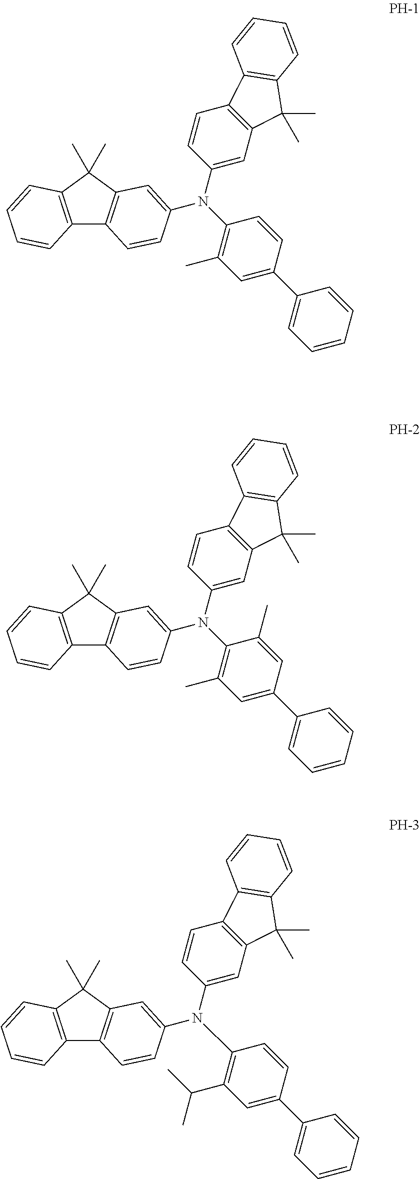 [SMILES: Cc1cc(-c2ccccc2)ccc1N(c1ccc2c(c1)C(C)(C)c1ccccc1-2)c1ccc2c(c1)C(C)(C)c1ccccc1-2 ; Cc1cc(-c2ccccc2)cc(C)c1N(c1ccc2c(c1)C(C)(C)c1ccccc1-2)c1ccc2c(c1)C(C)(C)c1ccccc1-2 ; CC(C)c1cc(-c2ccccc2)ccc1N(c1ccc2c(c1)C(C)(C)c1ccccc1-2)c1ccc2c(c1)C(C)(C)c1ccccc1-2]

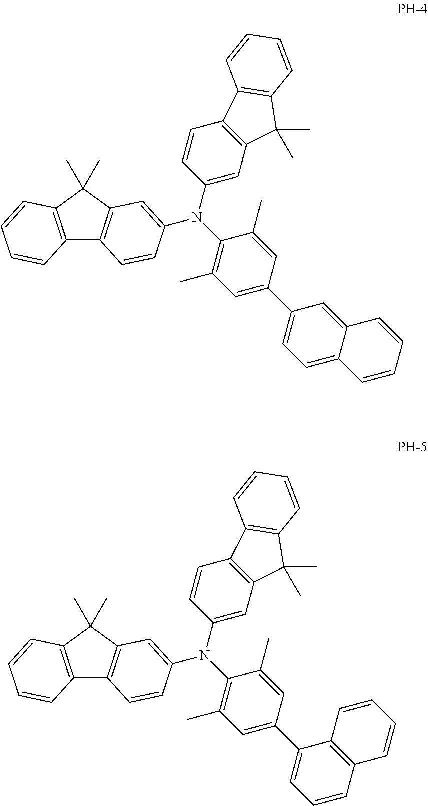 [SMILES: Cc1cc(-c2ccc3ccccc3c2)cc(C)c1N(c1ccc2c(c1)C(C)(C)c1ccccc1-2)c1ccc2c(c1)C(C)(C)c1ccccc1-2 ; Cc1cc(-c2cccc3ccccc23)cc(C)c1N(c1ccc2c(c1)C(C)(C)c1ccccc1-2)c1ccc2c(c1)C(C)(C)c1ccccc1-2]

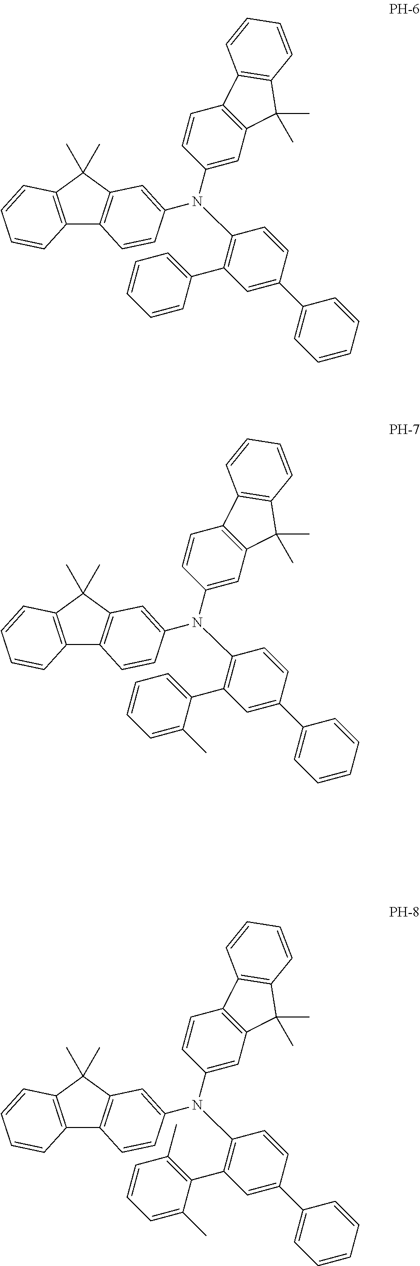 [SMILES: CC1(C)c2ccccc2-c2ccc(N(c3ccc4c(c3)C(C)(C)c3ccccc3-4)c3ccc(-c4ccccc4)cc3-c3ccccc3)cc21 ; Cc1ccccc1-c1cc(-c2ccccc2)ccc1N(c1ccc2c(c1)C(C)(C)c1ccccc1-2)c1ccc2c(c1)C(C)(C)c1ccccc1-2 ; Cc1cccc(C)c1-c1cc(-c2ccccc2)ccc1N(c1ccc2c(c1)C(C)(C)c1ccccc1-2)c1ccc2c(c1)C(C)(C)c1ccccc1-2]

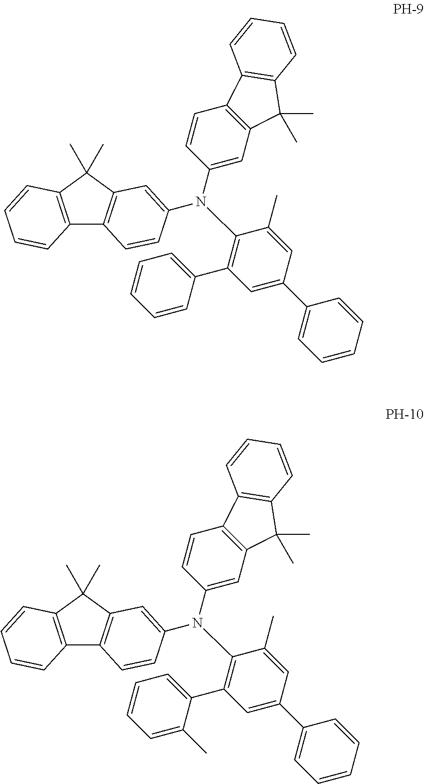 [SMILES: Cc1cc(-c2ccccc2)cc(-c2ccccc2)c1N(c1ccc2c(c1)C(C)(C)c1ccccc1-2)c1ccc2c(c1)C(C)(C)c1ccccc1-2 ; Cc1ccccc1-c1cc(-c2ccccc2)cc(C)c1N(c1ccc2c(c1)C(C)(C)c1ccccc1-2)c1ccc2c(c1)C(C)(C)c1ccccc1-2]

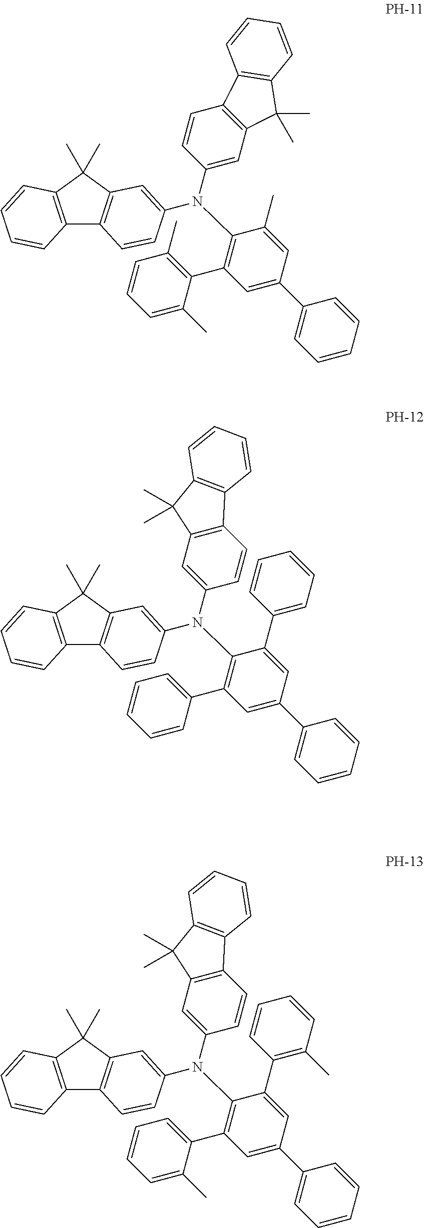 [SMILES: Cc1cccc(C)c1-c1cc(-c2ccccc2)cc(C)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3ccccc3)cc21 ; Cc1ccccc1-c1cc(-c2ccccc2)cc(-c2ccccc2C)c1N(c1ccc2c(c1)C(C)(C)c1ccccc1-2)c1ccc2c(c1)C(C)(C)c1ccccc1-2]

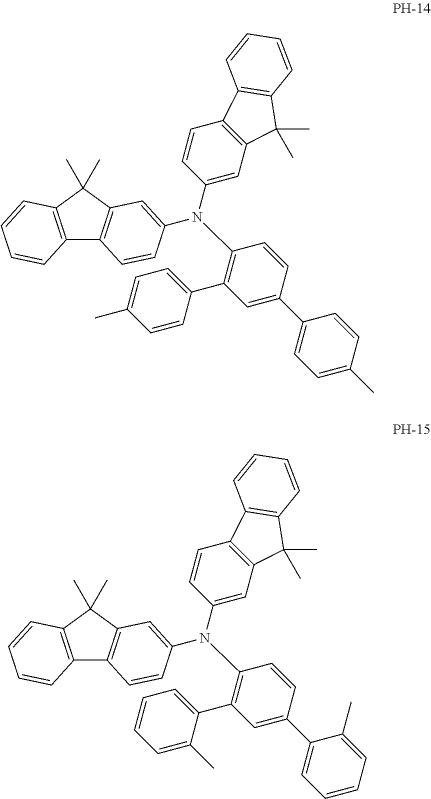 [SMILES: Cc1ccc(-c2ccc(N(c3ccc4c(c3)C(C)(C)c3ccccc3-4)c3ccc4c(c3)C(C)(C)c3ccccc3-4)c(-c3ccc(C)cc3)c2)cc1 ; Cc1ccccc1-c1ccc(N(c2ccc3c(c2)C(C)(C)c2ccccc2-3)c2ccc3c(c2)C(C)(C)c2ccccc2-3)c(-c2ccccc2C)c1]

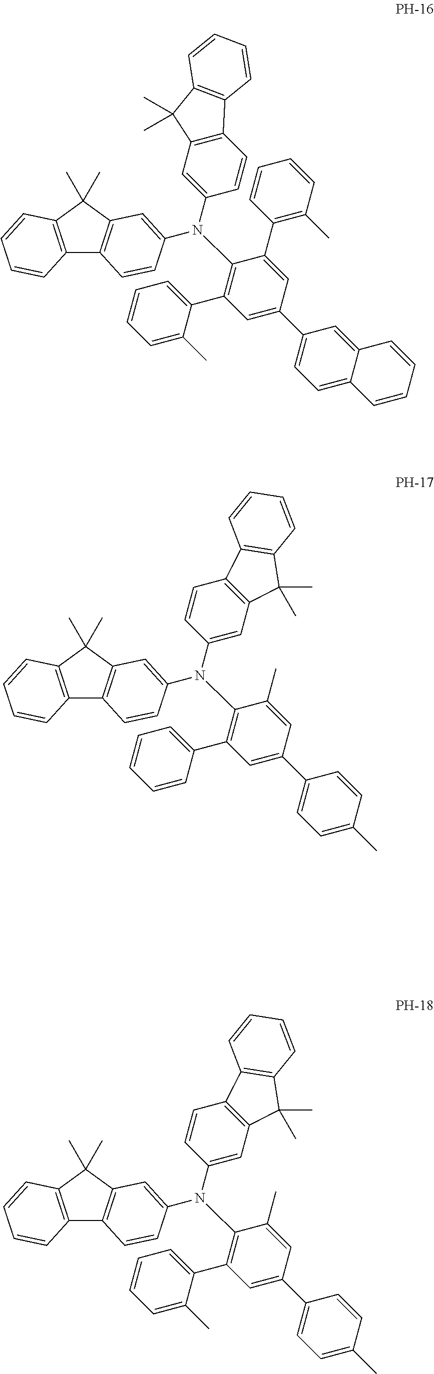 [SMILES: Cc1ccccc1-c1cc(-c2ccc3ccccc3c2)cc(-c2ccccc2C)c1N(c1ccc2c(c1)C(C)(C)c1ccccc1-2)c1ccc2c(c1)C(C)(C)c1ccccc1-2 ; Cc1ccc(-c2cc(C)c(N(c3ccc4c(c3)C(C)(C)c3ccccc3-4)c3ccc4c(c3)C(C)(C)c3ccccc3-4)c(-c3ccccc3)c2)cc1 ; Cc1ccc(-c2cc(C)c(N(c3ccc4c(c3)C(C)(C)c3ccccc3-4)c3ccc4c(c3)C(C)(C)c3ccccc3-4)c(-c3ccccc3C)c2)cc1]

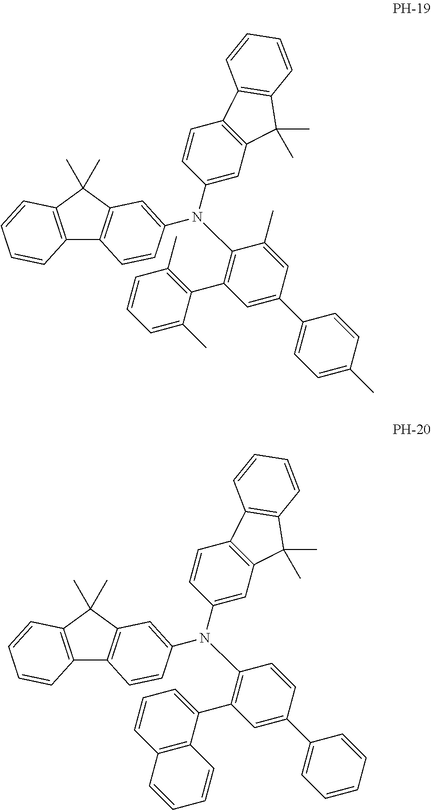 [SMILES: Cc1ccc(-c2cc(C)c(N(c3ccc4c(c3)C(C)(C)c3ccccc3-4)c3ccc4c(c3)C(C)(C)c3ccccc3-4)c(-c3c(C)cccc3C)c2)cc1 ; CC1(C)c2ccccc2-c2ccc(N(c3ccc4c(c3)C(C)(C)c3ccccc3-4)c3ccc(-c4ccccc4)cc3-c3cccc4ccccc34)cc21]

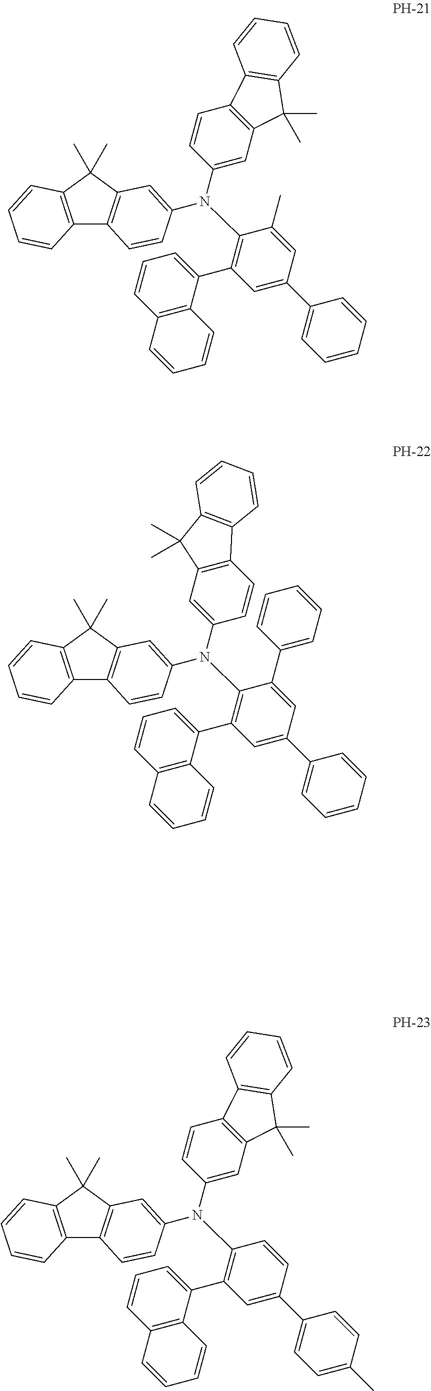 [SMILES: Cc1cc(-c2ccccc2)cc(-c2cccc3ccccc23)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3cccc4ccccc34)cc21 ; Cc1ccc(-c2ccc(N(c3ccc4c(c3)C(C)(C)c3ccccc3-4)c3ccc4c(c3)C(C)(C)c3ccccc3-4)c(-c3cccc4ccccc34)c2)cc1]

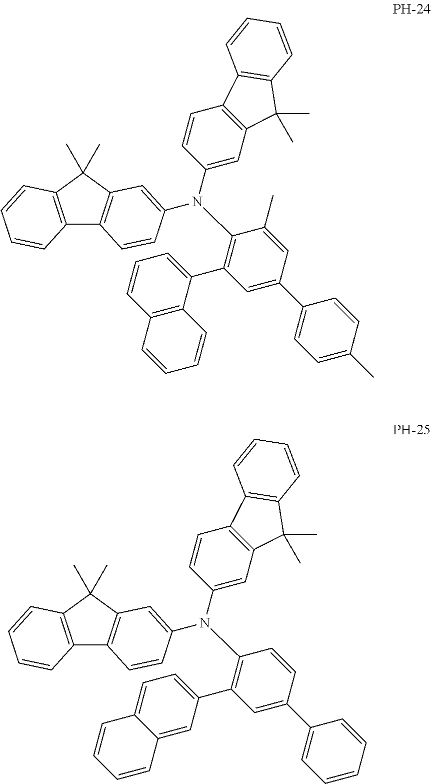 [SMILES: Cc1ccc(-c2cc(C)c(N(c3ccc4c(c3)C(C)(C)c3ccccc3-4)c3ccc4c(c3)C(C)(C)c3ccccc3-4)c(-c3cccc4ccccc34)c2)cc1 ; CC1(C)c2ccccc2-c2ccc(N(c3ccc4c(c3)C(C)(C)c3ccccc3-4)c3ccc(-c4ccccc4)cc3-c3ccc4ccccc4c3)cc21]

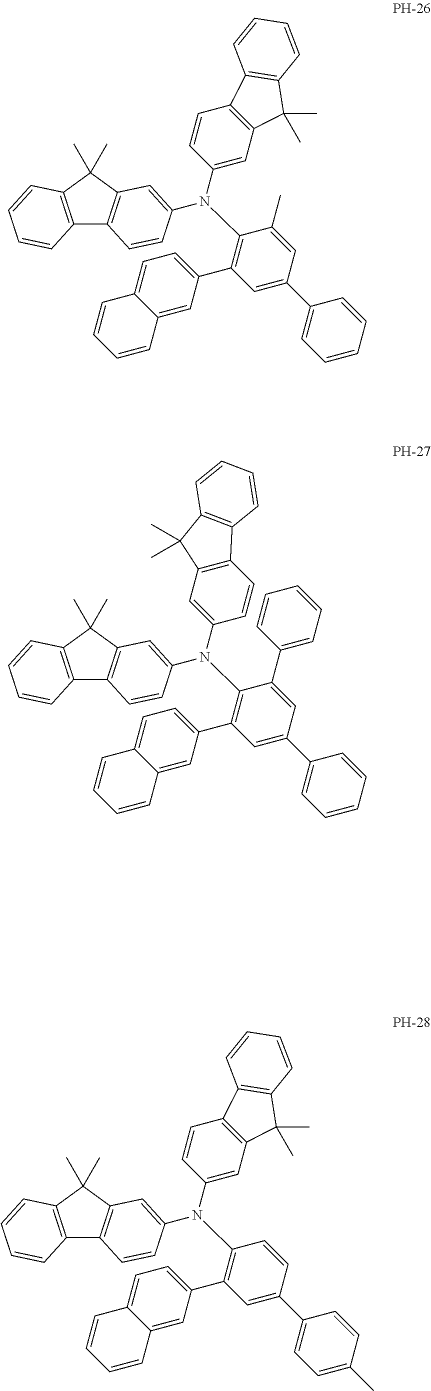 [SMILES: Cc1cc(-c2ccccc2)cc(-c2ccc3ccccc3c2)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3ccc4ccccc4c3)cc21 ; Cc1ccc(-c2ccc(N(c3ccc4c(c3)C(C)(C)c3ccccc3-4)c3ccc4c(c3)C(C)(C)c3ccccc3-4)c(-c3ccc4ccccc4c3)c2)cc1]

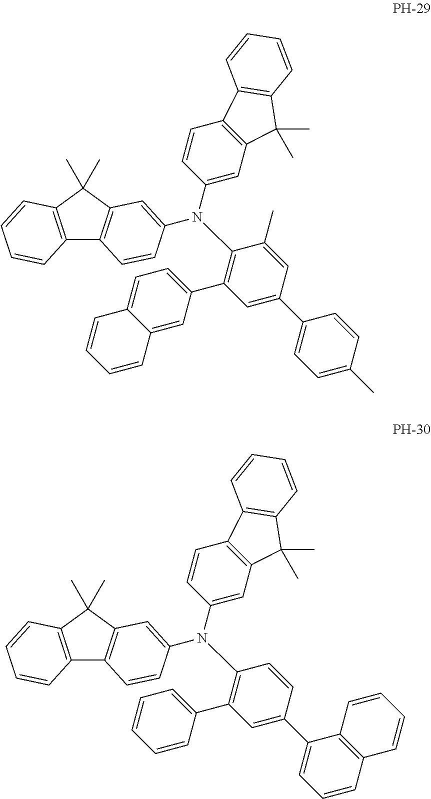 [SMILES: Cc1ccc(-c2cc(C)c(N(c3ccc4c(c3)C(C)(C)c3ccccc3-4)c3ccc4c(c3)C(C)(C)c3ccccc3-4)c(-c3ccc4ccccc4c3)c2)cc1 ; CC1(C)c2ccccc2-c2ccc(N(c3ccc4c(c3)C(C)(C)c3ccccc3-4)c3ccc(-c4cccc5ccccc45)cc3-c3ccccc3)cc21]

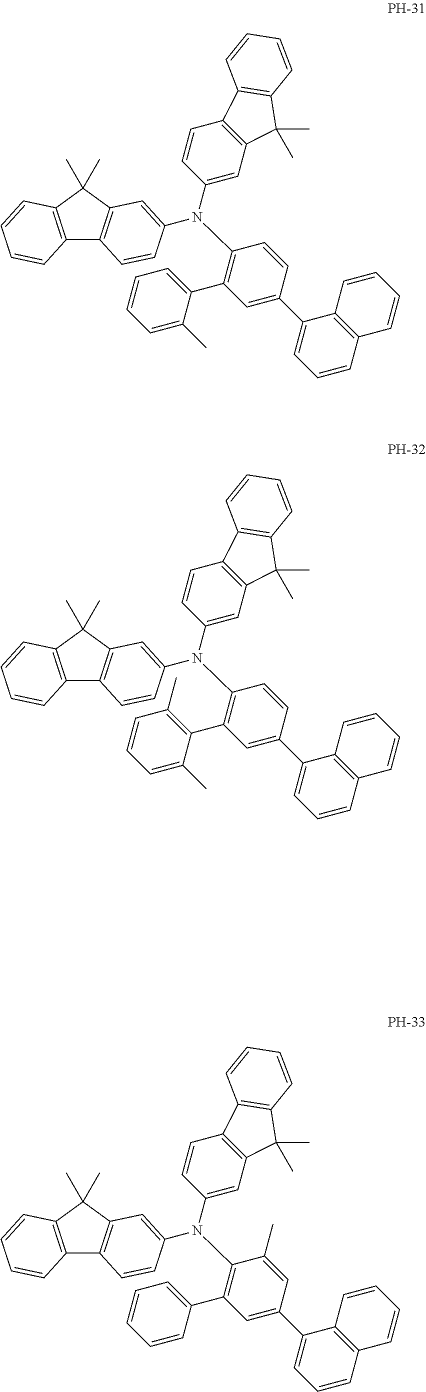 [SMILES: Cc1ccccc1-c1cc(-c2cccc3ccccc23)ccc1N(c1ccc2c(c1)C(C)(C)c1ccccc1-2)c1ccc2c(c1)C(C)(C)c1ccccc1-2 ; Cc1cccc(C)c1-c1cc(-c2cccc3ccccc23)ccc1N(c1ccc2c(c1)C(C)(C)c1ccccc1-2)c1ccc2c(c1)C(C)(C)c1ccccc1-2 ; Cc1cc(-c2cccc3ccccc23)cc(-c2ccccc2)c1N(c1ccc2c(c1)C(C)(C)c1ccccc1-2)c1ccc2c(c1)C(C)(C)c1ccccc1-2]

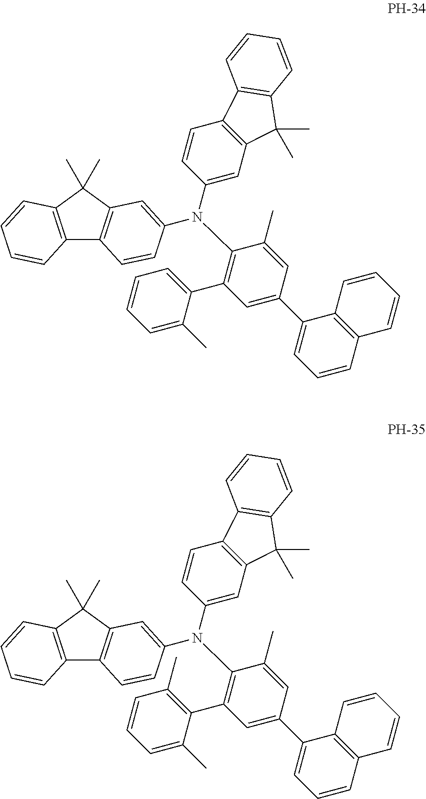 [SMILES: Cc1ccccc1-c1cc(-c2cccc3ccccc23)cc(C)c1N(c1ccc2c(c1)C(C)(C)c1ccccc1-2)c1ccc2c(c1)C(C)(C)c1ccccc1-2 ; Cc1cccc(C)c1-c1cc(-c2cccc3ccccc23)cc(C)c1N(c1ccc2c(c1)C(C)(C)c1ccccc1-2)c1ccc2c(c1)C(C)(C)c1ccccc1-2]

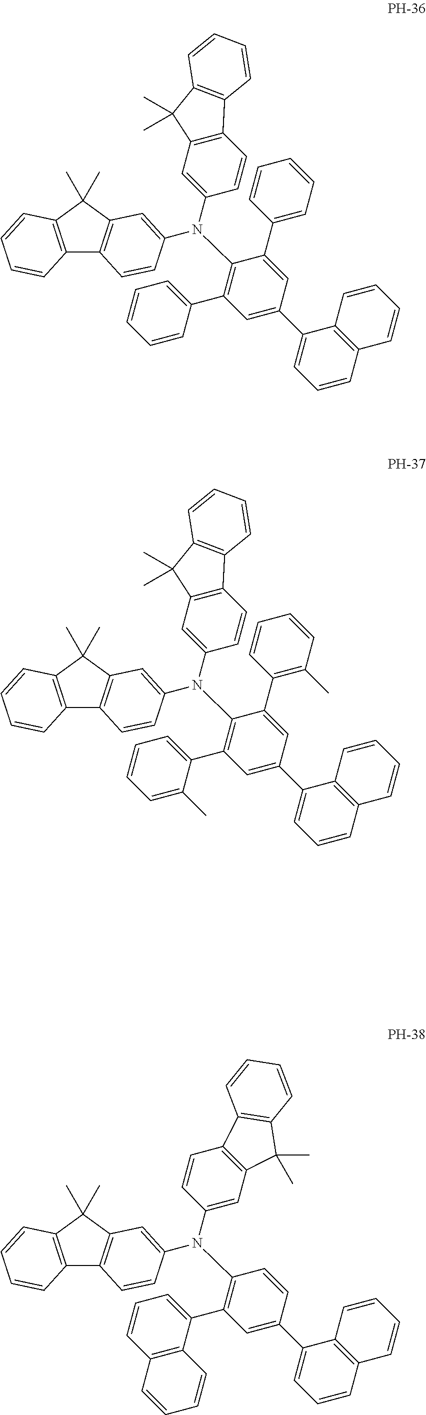 [SMILES: CC1(C)c2ccccc2-c2ccc(N(c3ccc4c(c3)C(C)(C)c3ccccc3-4)c3c(-c4ccccc4)cc(-c4cccc5ccccc45)cc3-c3ccccc3)cc21 ; Cc1ccccc1-c1cc(-c2cccc3ccccc23)cc(-c2ccccc2C)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3ccc(-c4cccc5ccccc45)cc3-c3cccc4ccccc34)cc21]

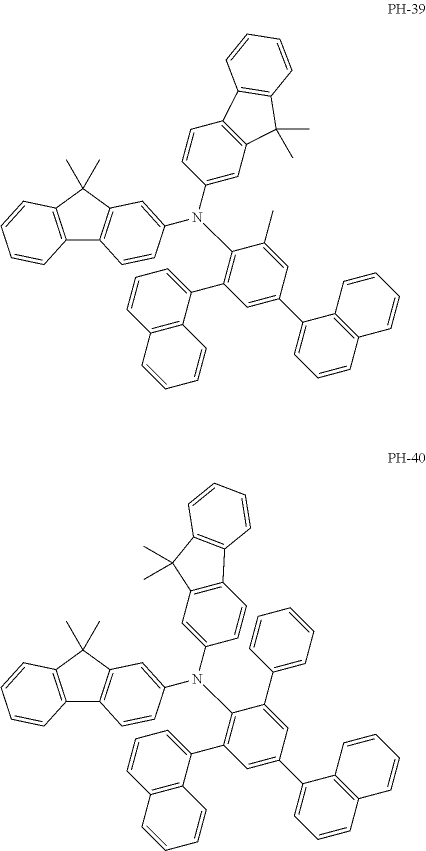 [SMILES: Cc1cc(-c2cccc3ccccc23)cc(-c2cccc3ccccc23)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4cccc5ccccc45)cc3-c3cccc4ccccc34)cc21]

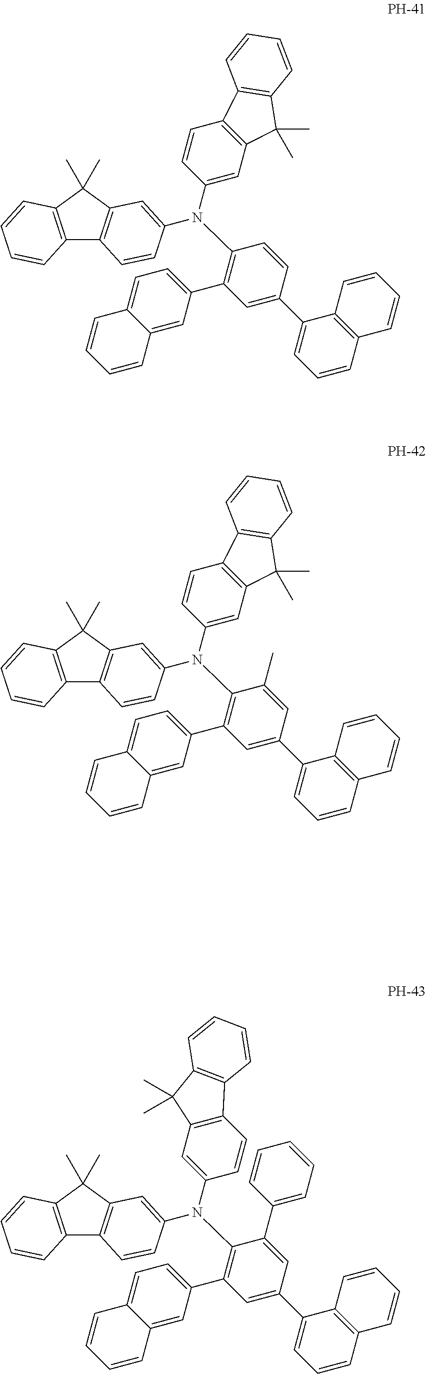 [SMILES: CC1(C)c2ccccc2-c2ccc(N(c3ccc4c(c3)C(C)(C)c3ccccc3-4)c3ccc(-c4cccc5ccccc45)cc3-c3ccc4ccccc4c3)cc21 ; Cc1cc(-c2cccc3ccccc23)cc(-c2ccc3ccccc3c2)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4cccc5ccccc45)cc3-c3ccc4ccccc4c3)cc21]

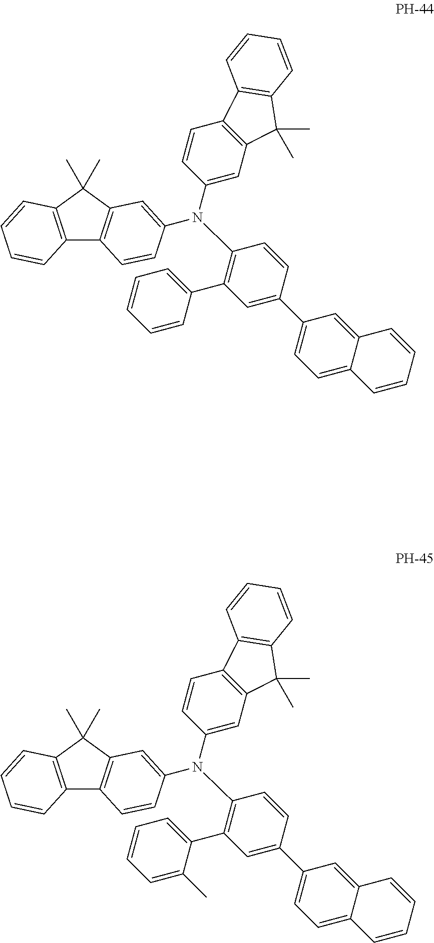 [SMILES: CC1(C)c2ccccc2-c2ccc(N(c3ccc4c(c3)C(C)(C)c3ccccc3-4)c3ccc(-c4ccc5ccccc5c4)cc3-c3ccccc3)cc21 ; Cc1ccccc1-c1cc(-c2ccc3ccccc3c2)ccc1N(c1ccc2c(c1)C(C)(C)c1ccccc1-2)c1ccc2c(c1)C(C)(C)c1ccccc1-2]

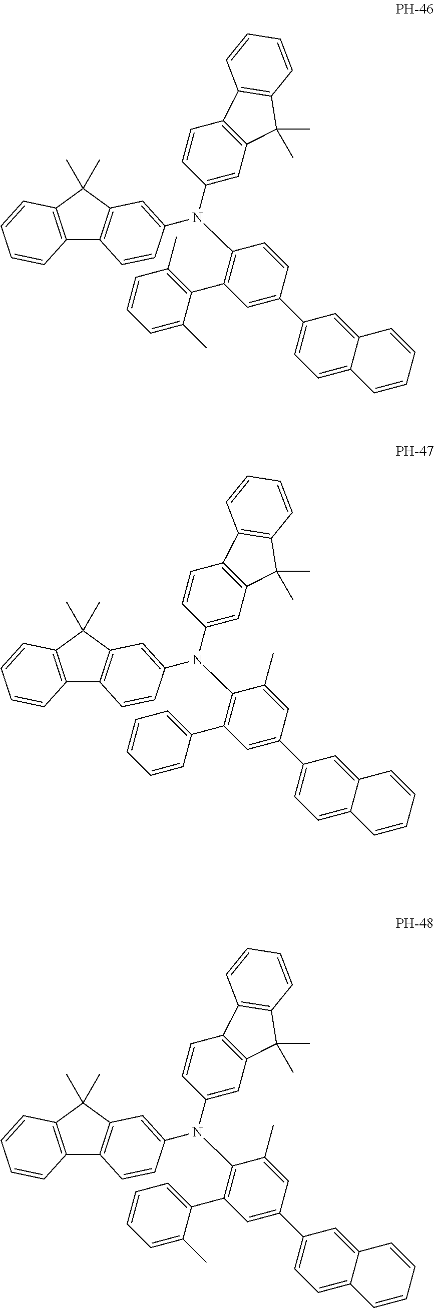 [SMILES: Cc1cccc(C)c1-c1cc(-c2ccc3ccccc3c2)ccc1N(c1ccc2c(c1)C(C)(C)c1ccccc1-2)c1ccc2c(c1)C(C)(C)c1ccccc1-2 ; Cc1cc(-c2ccc3ccccc3c2)cc(-c2ccccc2)c1N(c1ccc2c(c1)C(C)(C)c1ccccc1-2)c1ccc2c(c1)C(C)(C)c1ccccc1-2 ; Cc1ccccc1-c1cc(-c2ccc3ccccc3c2)cc(C)c1N(c1ccc2c(c1)C(C)(C)c1ccccc1-2)c1ccc2c(c1)C(C)(C)c1ccccc1-2]

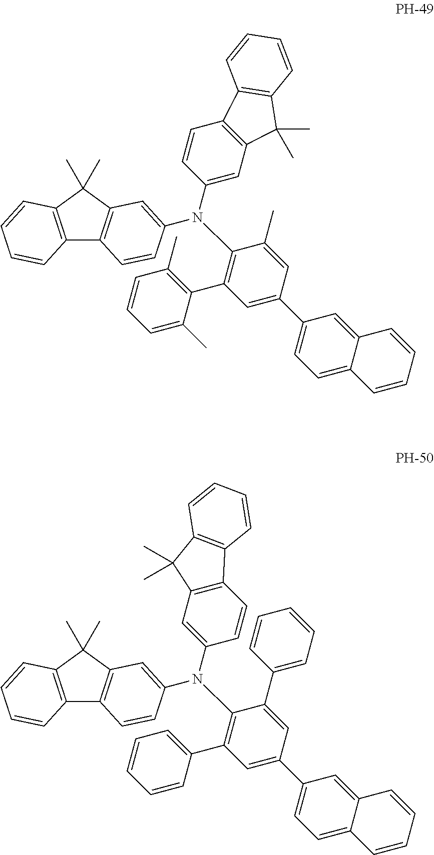 [SMILES: Cc1cccc(C)c1-c1cc(-c2ccc3ccccc3c2)cc(C)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccc5ccccc5c4)cc3-c3ccccc3)cc21]

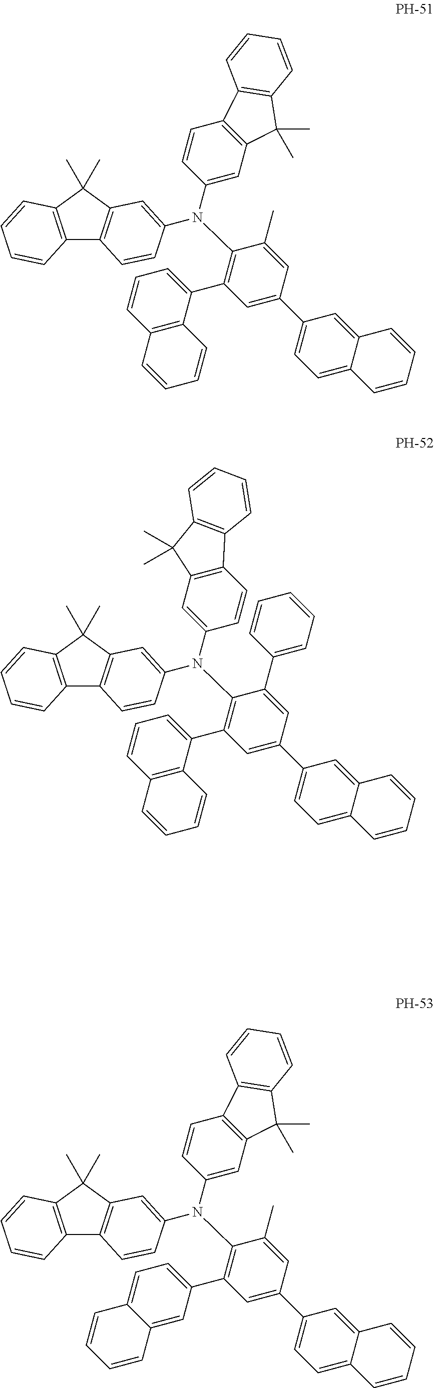 [SMILES: Cc1cc(-c2ccc3ccccc3c2)cc(-c2cccc3ccccc23)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccc5ccccc5c4)cc3-c3cccc4ccccc34)cc21 ; Cc1cc(-c2ccc3ccccc3c2)cc(-c2ccc3ccccc3c2)c1N(c1ccc2c(c1)C(C)(C)c1ccccc1-2)c1ccc2c(c1)C(C)(C)c1ccccc1-2]

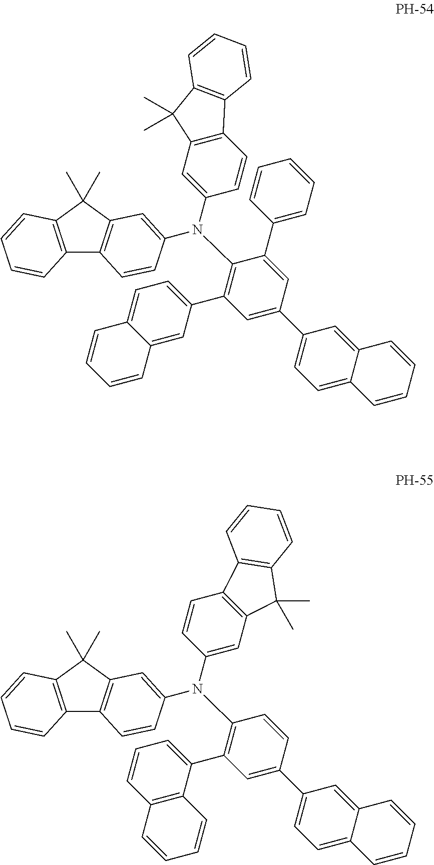 [SMILES: CC1(C)c2ccccc2-c2ccc(N(c3ccc4c(c3)C(C)(C)c3ccccc3-4)c3c(-c4ccccc4)cc(-c4ccc5ccccc5c4)cc3-c3ccc4ccccc4c3)cc21 ; CC1(C)c2ccccc2-c2ccc(N(c3ccc4c(c3)C(C)(C)c3ccccc3-4)c3ccc(-c4ccc5ccccc5c4)cc3-c3cccc4ccccc34)cc21]

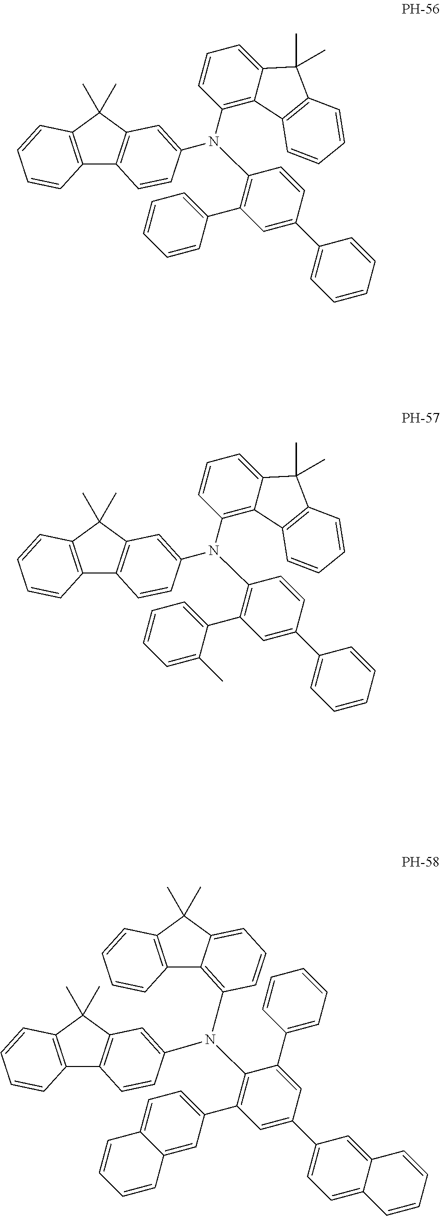 [SMILES: CC1(C)c2ccccc2-c2ccc(N(c3ccc(-c4ccccc4)cc3-c3ccccc3)c3cccc4c3-c3ccccc3C4(C)C)cc21 ; Cc1ccccc1-c1cc(-c2ccccc2)ccc1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4ccc5ccccc5c4)cc3-c3ccc4ccccc4c3)cc21]

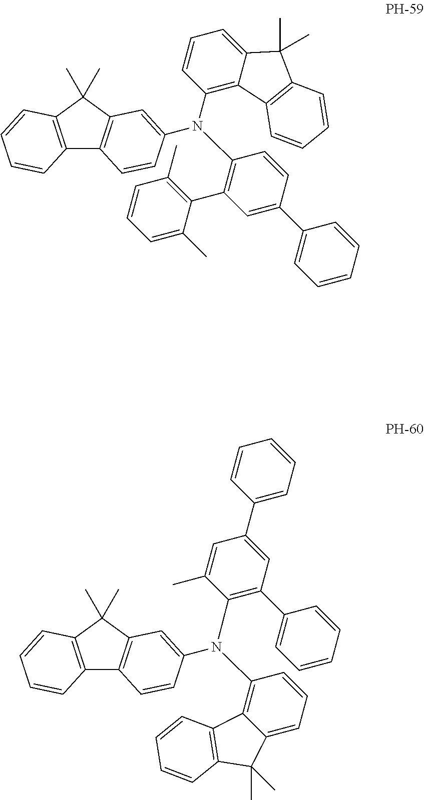 [SMILES: Cc1cccc(C)c1-c1cc(-c2ccccc2)ccc1N(c1ccc2c(c1)C(C)(C)c1ccccc1-2)c1cccc2c1-c1ccccc1C2(C)C ; Cc1cc(-c2ccccc2)cc(-c2ccccc2)c1N(c1ccc2c(c1)C(C)(C)c1ccccc1-2)c1cccc2c1-c1ccccc1C2(C)C]

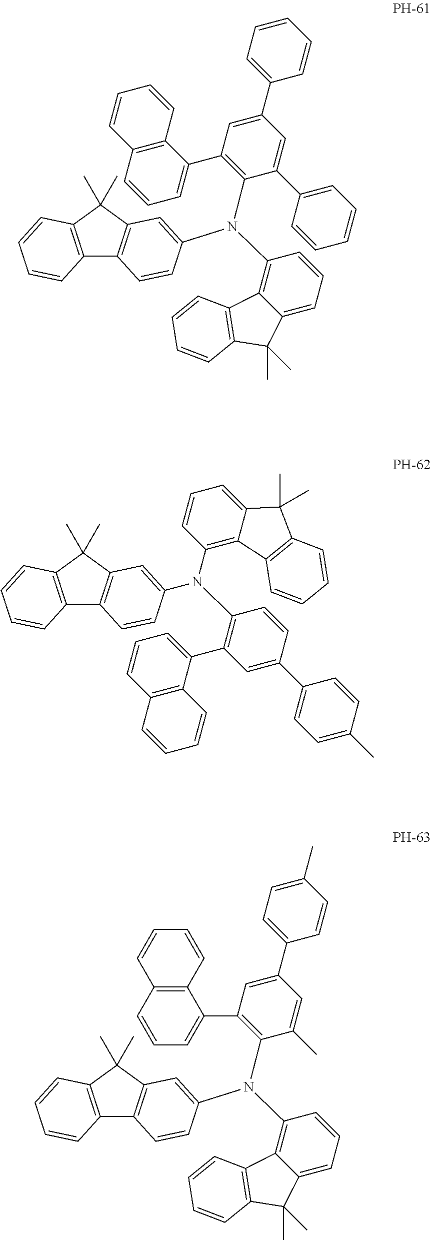 [SMILES: CC1(C)c2ccccc2-c2ccc(N(c3cccc4c3-c3ccccc3C4(C)C)c3c(-c4ccccc4)cc(-c4ccccc4)cc3-c3cccc4ccccc34)cc21 ; Cc1ccc(-c2ccc(N(c3ccc4c(c3)C(C)(C)c3ccccc3-4)c3cccc4c3-c3ccccc3C4(C)C)c(-c3cccc4ccccc34)c2)cc1 ; Cc1ccc(-c2cc(C)c(N(c3ccc4c(c3)C(C)(C)c3ccccc3-4)c3cccc4c3-c3ccccc3C4(C)C)c(-c3cccc4ccccc34)c2)cc1]

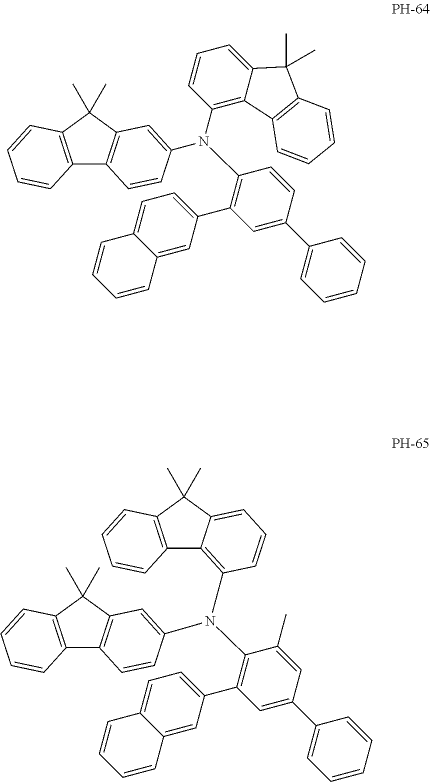 [SMILES: CC1(C)c2ccccc2-c2ccc(N(c3ccc(-c4ccccc4)cc3-c3ccc4ccccc4c3)c3cccc4c3-c3ccccc3C4(C)C)cc21 ; Cc1cc(-c2ccccc2)cc(-c2ccc3ccccc3c2)c1N(c1ccc2c(c1)C(C)(C)c1ccccc1-2)c1cccc2c1-c1ccccc1C2(C)C]

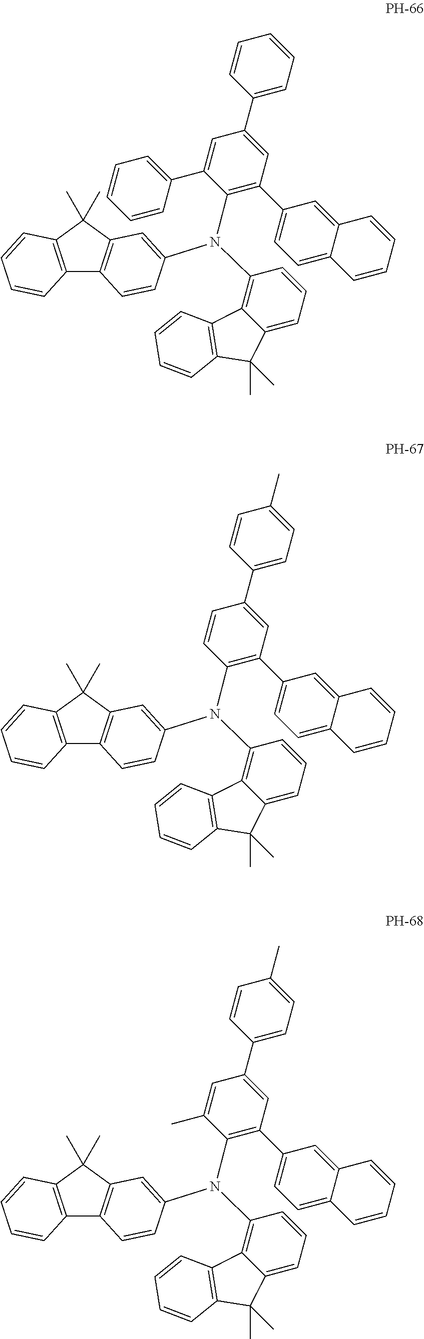 [SMILES: CC1(C)c2ccccc2-c2ccc(N(c3cccc4c3-c3ccccc3C4(C)C)c3c(-c4ccccc4)cc(-c4ccccc4)cc3-c3ccc4ccccc4c3)cc21 ; Cc1ccc(-c2ccc(N(c3ccc4c(c3)C(C)(C)c3ccccc3-4)c3cccc4c3-c3ccccc3C4(C)C)c(-c3ccc4ccccc4c3)c2)cc1 ; Cc1ccc(-c2cc(C)c(N(c3ccc4c(c3)C(C)(C)c3ccccc3-4)c3cccc4c3-c3ccccc3C4(C)C)c(-c3ccc4ccccc4c3)c2)cc1]

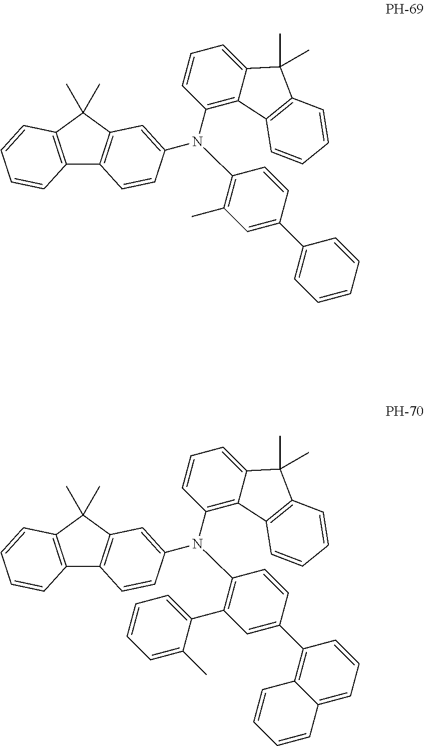 [SMILES: Cc1cc(-c2ccccc2)ccc1N(c1ccc2c(c1)C(C)(C)c1ccccc1-2)c1cccc2c1-c1ccccc1C2(C)C ; Cc1ccccc1-c1cc(-c2cccc3ccccc23)ccc1N(c1ccc2c(c1)C(C)(C)c1ccccc1-2)c1cccc2c1-c1ccccc1C2(C)C]

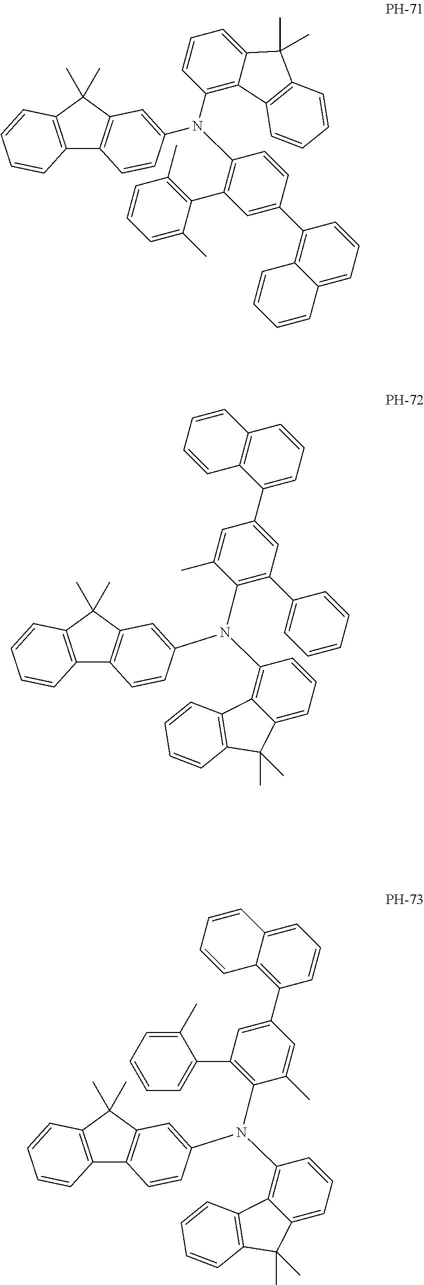 [SMILES: Cc1cccc(C)c1-c1cc(-c2cccc3ccccc23)ccc1N(c1ccc2c(c1)C(C)(C)c1ccccc1-2)c1cccc2c1-c1ccccc1C2(C)C ; Cc1cc(-c2cccc3ccccc23)cc(-c2ccccc2)c1N(c1ccc2c(c1)C(C)(C)c1ccccc1-2)c1cccc2c1-c1ccccc1C2(C)C ; Cc1ccccc1-c1cc(-c2cccc3ccccc23)cc(C)c1N(c1ccc2c(c1)C(C)(C)c1ccccc1-2)c1cccc2c1-c1ccccc1C2(C)C]

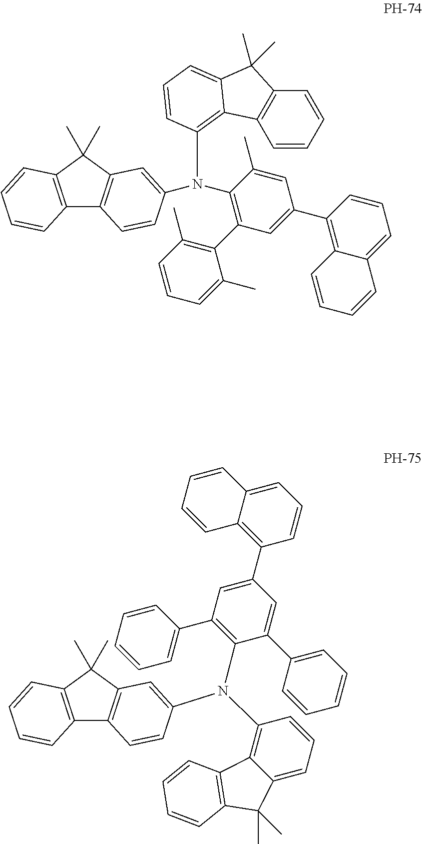 [SMILES: Cc1cccc(C)c1-c1cc(-c2cccc3ccccc23)cc(C)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4cccc5ccccc45)cc3-c3ccccc3)cc21]

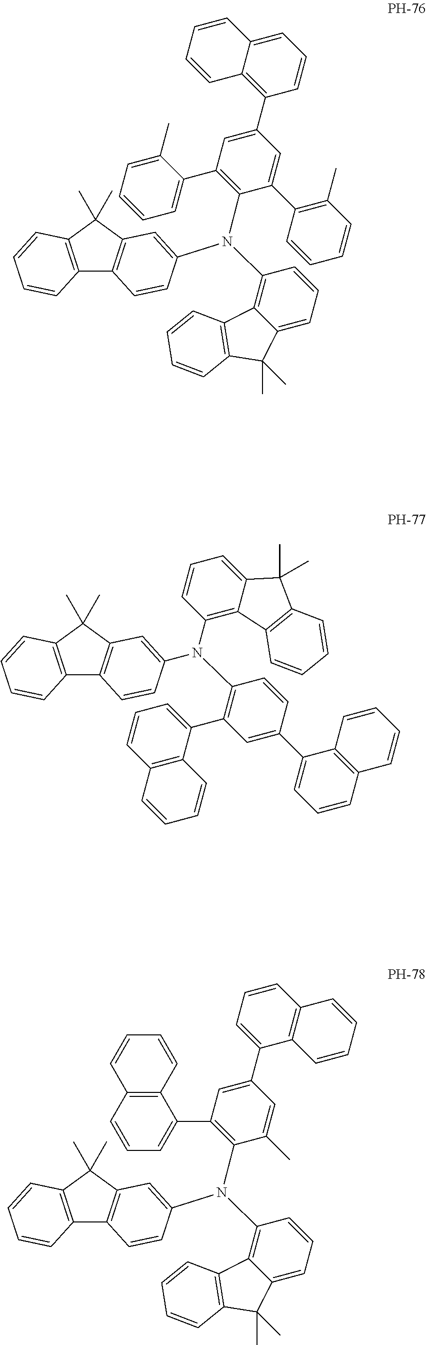 [SMILES: Cc1ccccc1-c1cc(-c2cccc3ccccc23)cc(-c2ccccc2C)c1N(c1ccc2c(c1)C(C)(C)c1ccccc1-2)c1cccc2c1-c1ccccc1C2(C)C ; CC1(C)c2ccccc2-c2ccc(N(c3ccc(-c4cccc5ccccc45)cc3-c3cccc4ccccc34)c3cccc4c3-c3ccccc3C4(C)C)cc21 ; Cc1cc(-c2cccc3ccccc23)cc(-c2cccc3ccccc23)c1N(c1ccc2c(c1)C(C)(C)c1ccccc1-2)c1cccc2c1-c1ccccc1C2(C)C]

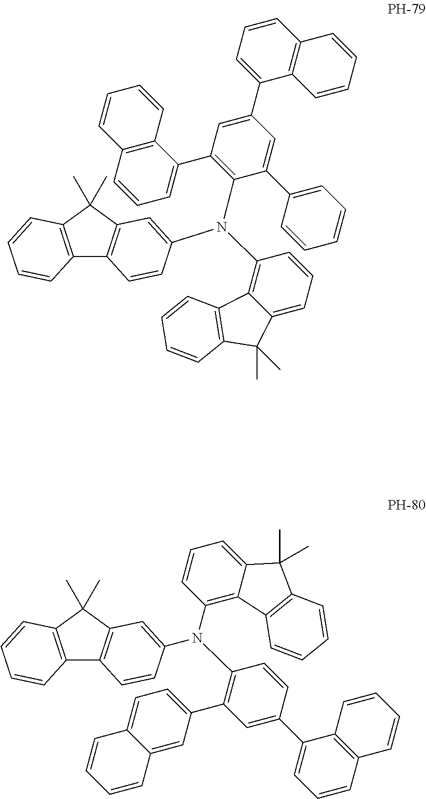 [SMILES: CC1(C)c2ccccc2-c2ccc(N(c3cccc4c3-c3ccccc3C4(C)C)c3c(-c4ccccc4)cc(-c4cccc5ccccc45)cc3-c3cccc4ccccc34)cc21 ; CC1(C)c2ccccc2-c2ccc(N(c3ccc(-c4cccc5ccccc45)cc3-c3ccc4ccccc4c3)c3cccc4c3-c3ccccc3C4(C)C)cc21]

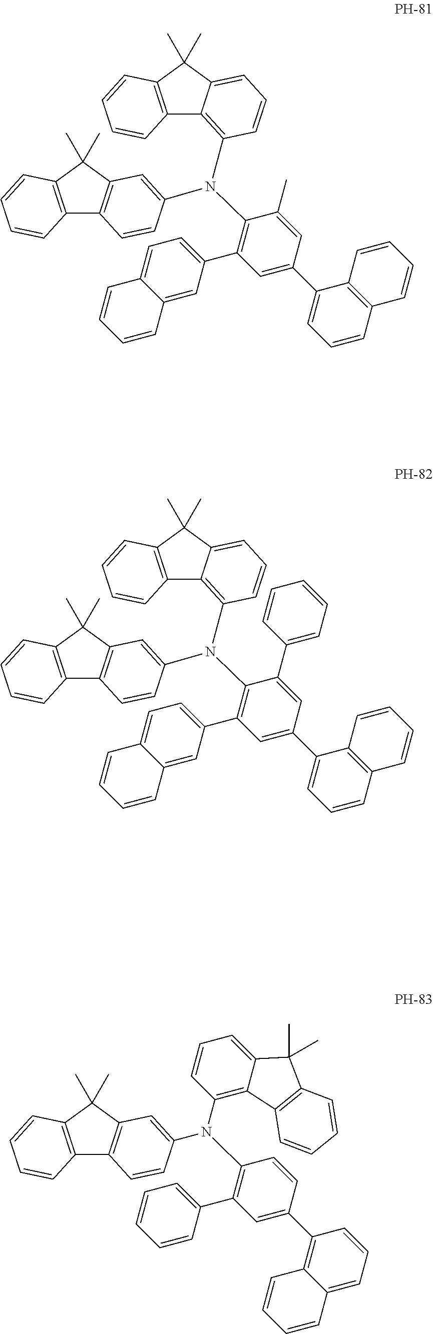 [SMILES: Cc1cc(-c2cccc3ccccc23)cc(-c2ccc3ccccc3c2)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4cccc5ccccc45)cc3-c3ccc4ccccc4c3)cc21 ; CC1(C)c2ccccc2-c2ccc(N(c3ccc(-c4cccc5ccccc45)cc3-c3ccccc3)c3cccc4c3-c3ccccc3C4(C)C)cc21]

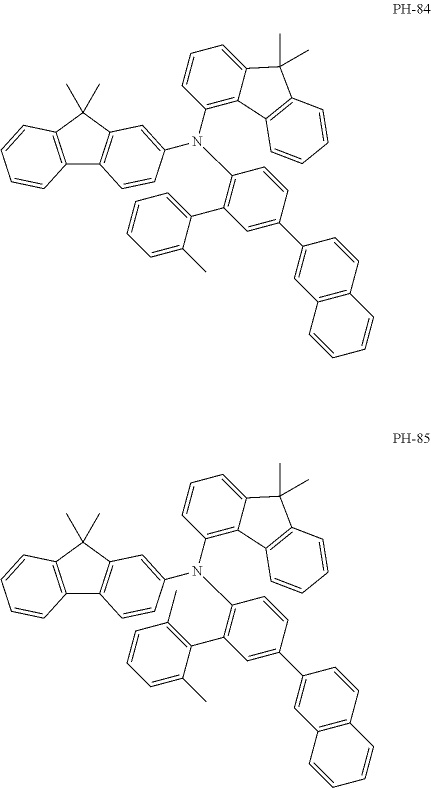 [SMILES: Cc1ccccc1-c1cc(-c2ccc3ccccc3c2)ccc1N(c1ccc2c(c1)C(C)(C)c1ccccc1-2)c1cccc2c1-c1ccccc1C2(C)C ; Cc1cccc(C)c1-c1cc(-c2ccc3ccccc3c2)ccc1N(c1ccc2c(c1)C(C)(C)c1ccccc1-2)c1cccc2c1-c1ccccc1C2(C)C]

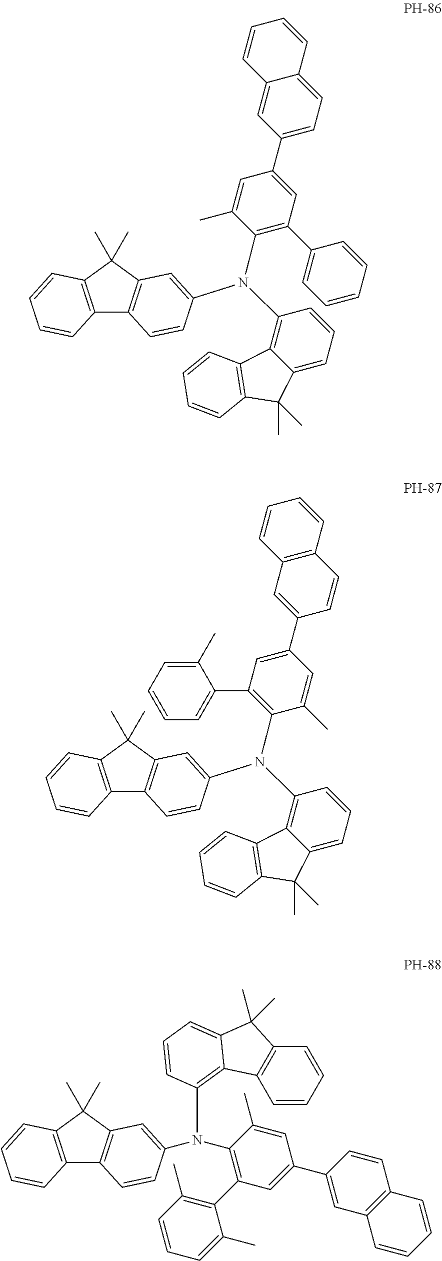 [SMILES: Cc1cc(-c2ccc3ccccc3c2)cc(-c2ccccc2)c1N(c1ccc2c(c1)C(C)(C)c1ccccc1-2)c1cccc2c1-c1ccccc1C2(C)C ; Cc1ccccc1-c1cc(-c2ccc3ccccc3c2)cc(C)c1N(c1ccc2c(c1)C(C)(C)c1ccccc1-2)c1cccc2c1-c1ccccc1C2(C)C ; Cc1cccc(C)c1-c1cc(-c2ccc3ccccc3c2)cc(C)c1N(c1ccc2c(c1)C(C)(C)c1ccccc1-2)c1cccc2c1-c1ccccc1C2(C)C]

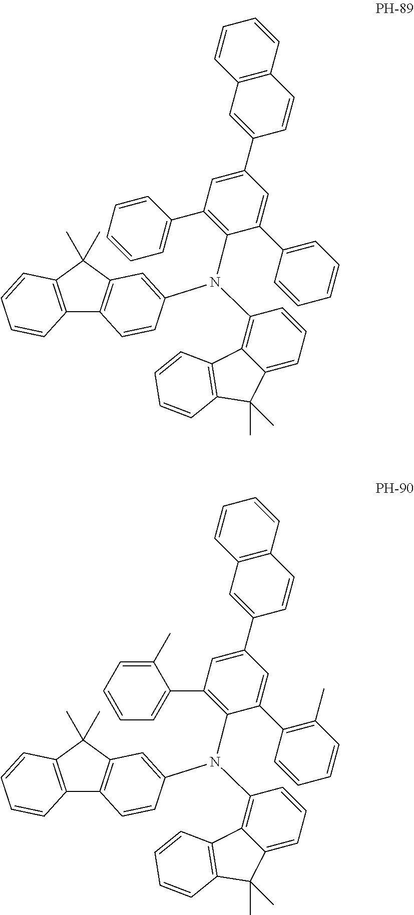 [SMILES: CC1(C)c2ccccc2-c2ccc(N(c3cccc4c3-c3ccccc3C4(C)C)c3c(-c4ccccc4)cc(-c4ccc5ccccc5c4)cc3-c3ccccc3)cc21 ; Cc1ccccc1-c1cc(-c2ccc3ccccc3c2)cc(-c2ccccc2C)c1N(c1ccc2c(c1)C(C)(C)c1ccccc1-2)c1cccc2c1-c1ccccc1C2(C)C]

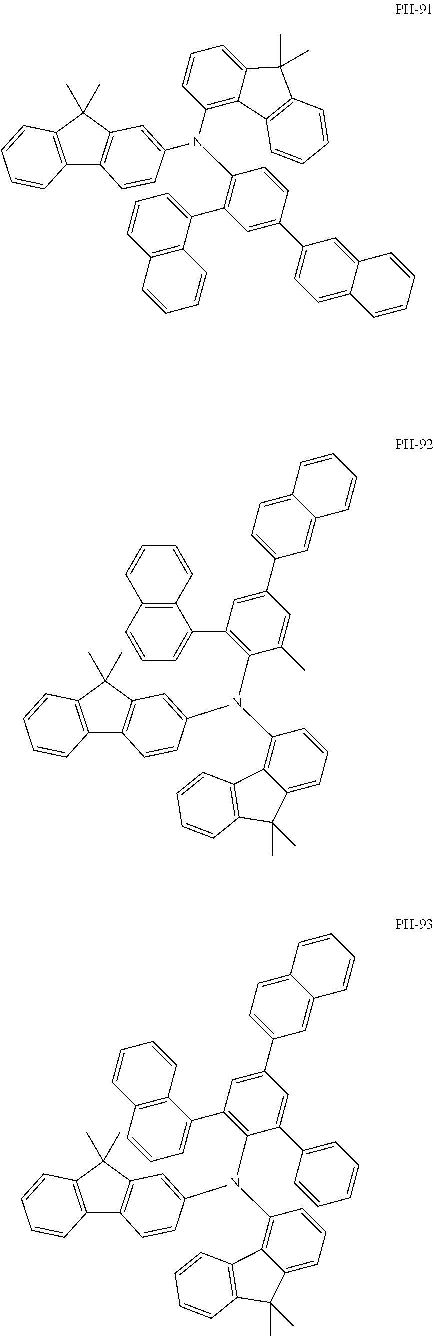 [SMILES: CC1(C)c2ccccc2-c2ccc(N(c3ccc(-c4ccc5ccccc5c4)cc3-c3cccc4ccccc34)c3cccc4c3-c3ccccc3C4(C)C)cc21 ; Cc1cc(-c2ccc3ccccc3c2)cc(-c2cccc3ccccc23)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4ccc5ccccc5c4)cc3-c3cccc4ccccc34)cc21]

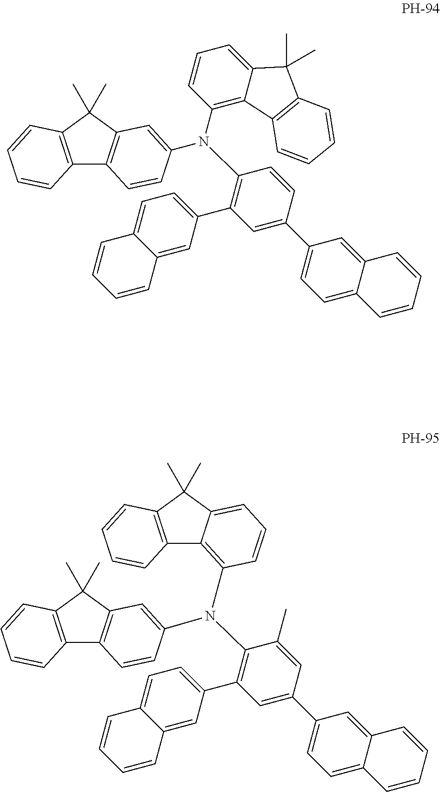 [SMILES: CC1(C)c2ccccc2-c2ccc(N(c3ccc(-c4ccc5ccccc5c4)cc3-c3ccc4ccccc4c3)c3cccc4c3-c3ccccc3C4(C)C)cc21 ; Cc1cc(-c2ccc3ccccc3c2)cc(-c2ccc3ccccc3c2)c1N(c1ccc2c(c1)C(C)(C)c1ccccc1-2)c1cccc2c1-c1ccccc1C2(C)C]

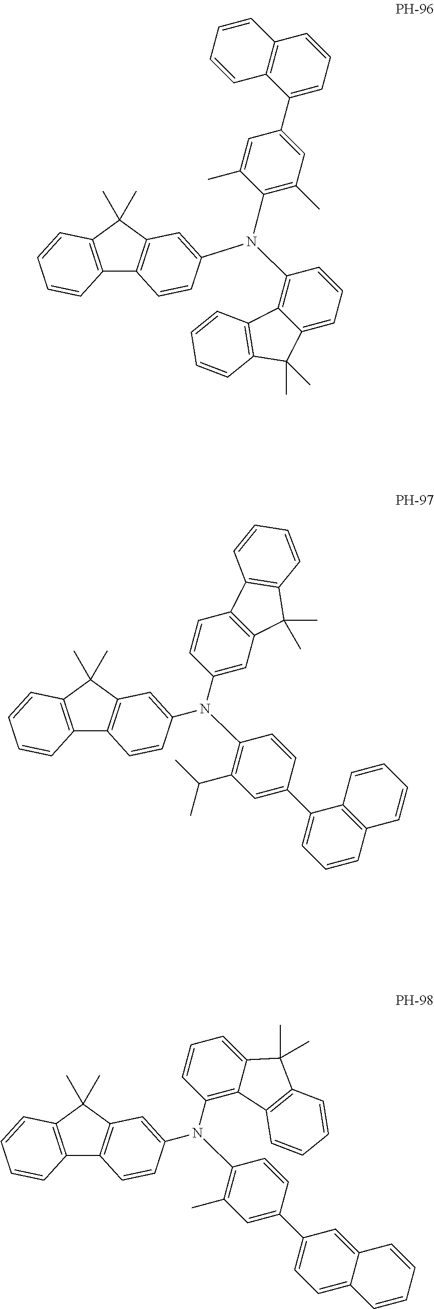 [SMILES: Cc1cc(-c2cccc3ccccc23)cc(C)c1N(c1ccc2c(c1)C(C)(C)c1ccccc1-2)c1cccc2c1-c1ccccc1C2(C)C ; CC(C)c1cc(-c2cccc3ccccc23)ccc1N(c1ccc2c(c1)C(C)(C)c1ccccc1-2)c1ccc2c(c1)C(C)(C)c1ccccc1-2 ; Cc1cc(-c2ccc3ccccc3c2)ccc1N(c1ccc2c(c1)C(C)(C)c1ccccc1-2)c1cccc2c1-c1ccccc1C2(C)C]

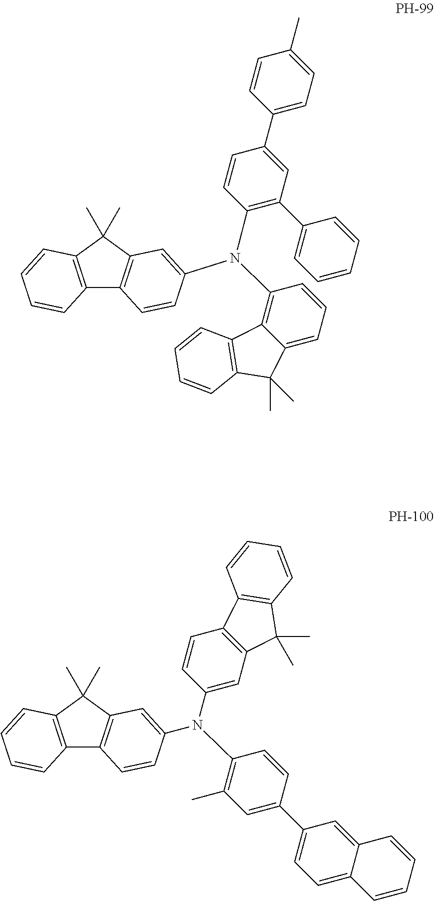 [SMILES: Cc1ccc(-c2ccc(N(c3ccc4c(c3)C(C)(C)c3ccccc3-4)c3cccc4c3-c3ccccc3C4(C)C)c(-c3ccccc3)c2)cc1 ; Cc1cc(-c2ccc3ccccc3c2)ccc1N(c1ccc2c(c1)C(C)(C)c1ccccc1-2)c1ccc2c(c1)C(C)(C)c1ccccc1-2]

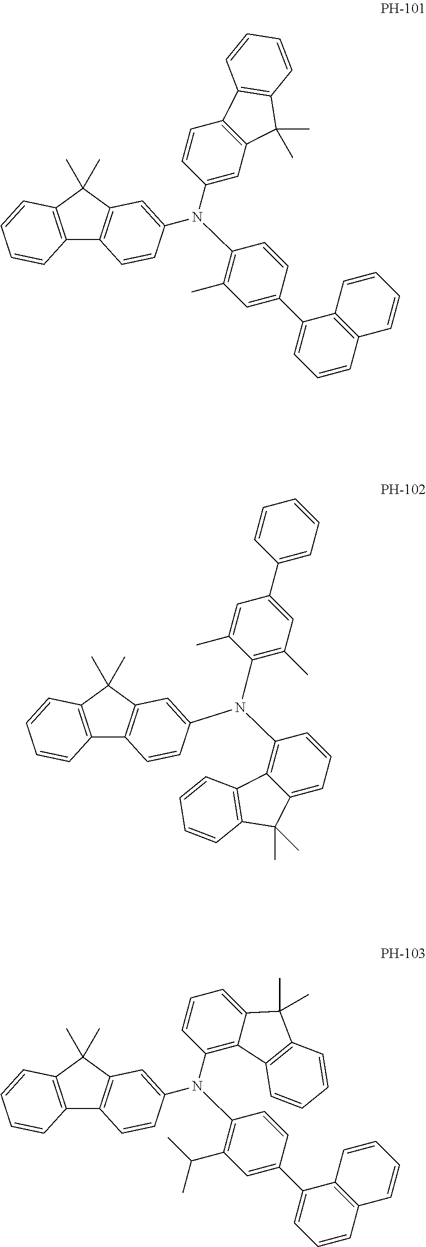 [SMILES: Cc1cc(-c2cccc3ccccc23)ccc1N(c1ccc2c(c1)C(C)(C)c1ccccc1-2)c1ccc2c(c1)C(C)(C)c1ccccc1-2 ; Cc1cc(-c2ccccc2)cc(C)c1N(c1ccc2c(c1)C(C)(C)c1ccccc1-2)c1cccc2c1-c1ccccc1C2(C)C ; CC(C)c1cc(-c2cccc3ccccc23)ccc1N(c1ccc2c(c1)C(C)(C)c1ccccc1-2)c1cccc2c1-c1ccccc1C2(C)C]

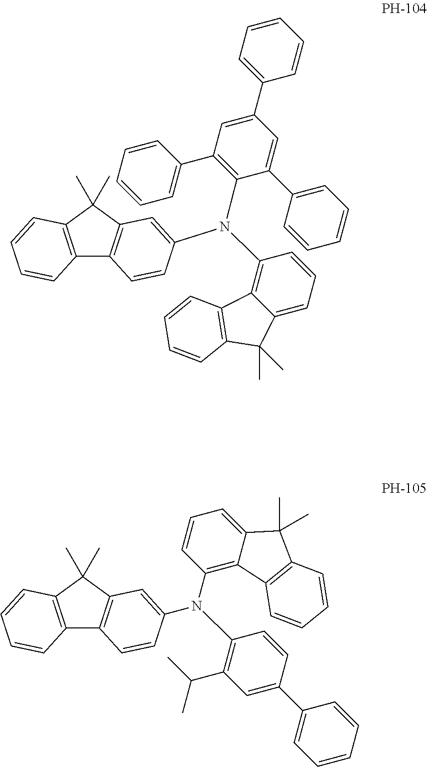 [SMILES: CC1(C)c2ccccc2-c2ccc(N(c3cccc4c3-c3ccccc3C4(C)C)c3c(-c4ccccc4)cc(-c4ccccc4)cc3-c3ccccc3)cc21 ; CC(C)c1cc(-c2ccccc2)ccc1N(c1ccc2c(c1)C(C)(C)c1ccccc1-2)c1cccc2c1-c1ccccc1C2(C)C]

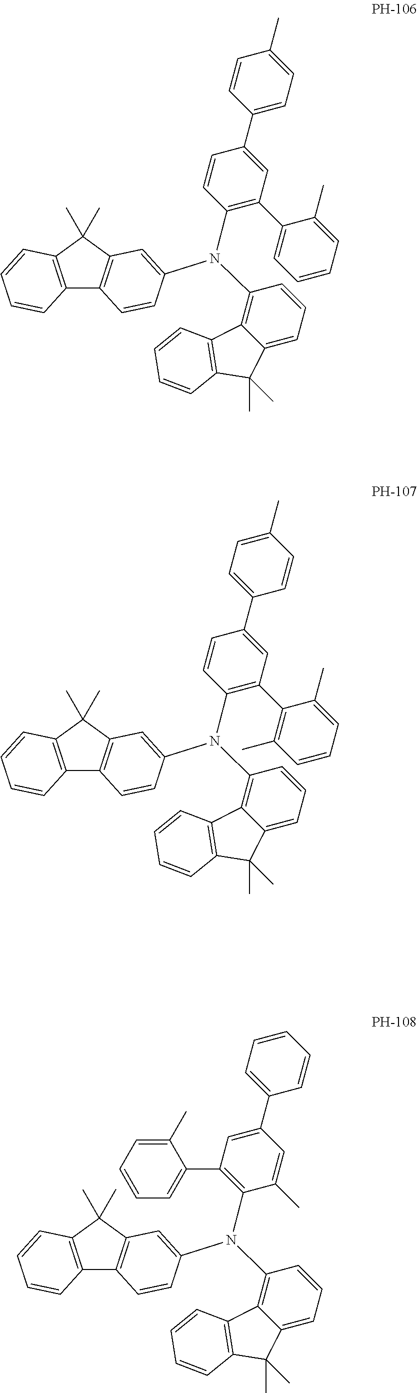 [SMILES: Cc1ccc(-c2ccc(N(c3ccc4c(c3)C(C)(C)c3ccccc3-4)c3cccc4c3-c3ccccc3C4(C)C)c(-c3ccccc3C)c2)cc1 ; Cc1ccc(-c2ccc(N(c3ccc4c(c3)C(C)(C)c3ccccc3-4)c3cccc4c3-c3ccccc3C4(C)C)c(-c3c(C)cccc3C)c2)cc1 ; Cc1ccccc1-c1cc(-c2ccccc2)cc(C)c1N(c1ccc2c(c1)C(C)(C)c1ccccc1-2)c1cccc2c1-c1ccccc1C2(C)C]

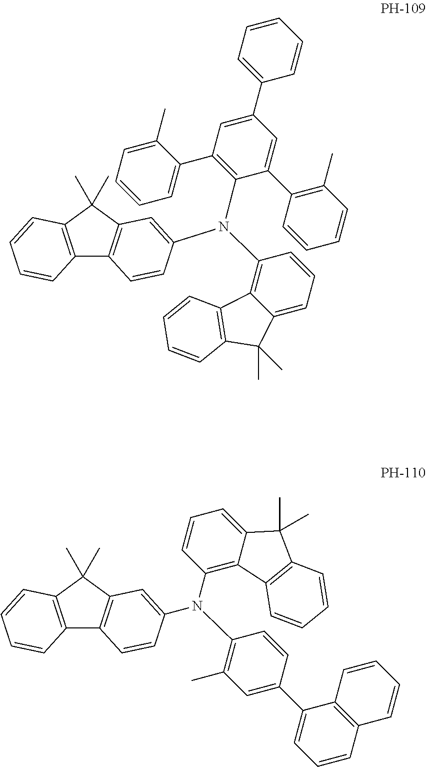 [SMILES: Cc1ccccc1-c1cc(-c2ccccc2)cc(-c2ccccc2C)c1N(c1ccc2c(c1)C(C)(C)c1ccccc1-2)c1cccc2c1-c1ccccc1C2(C)C ; Cc1cc(-c2cccc3ccccc23)ccc1N(c1ccc2c(c1)C(C)(C)c1ccccc1-2)c1cccc2c1-c1ccccc1C2(C)C]

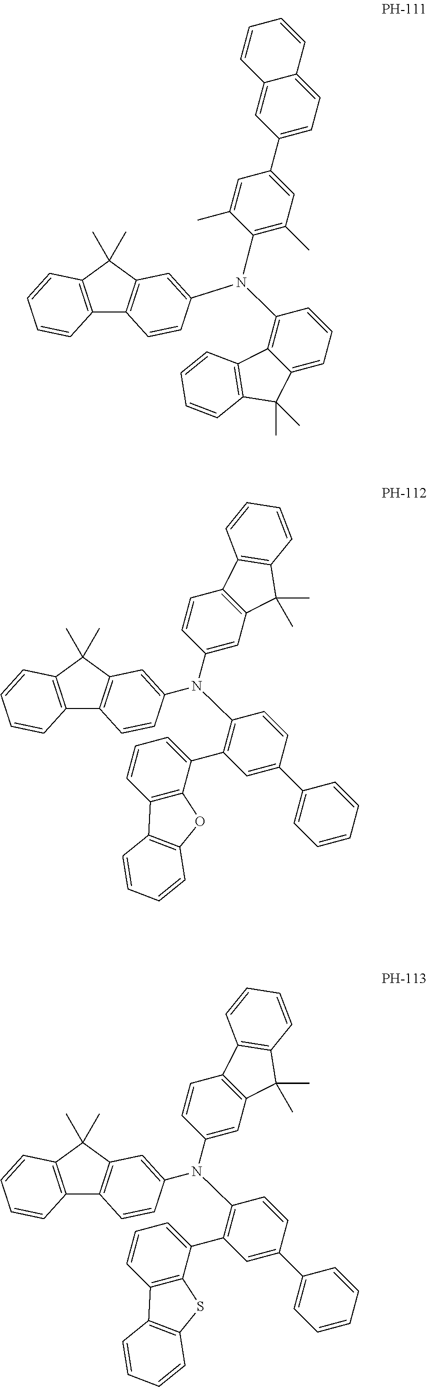 [SMILES: Cc1cc(-c2ccc3ccccc3c2)cc(C)c1N(c1ccc2c(c1)C(C)(C)c1ccccc1-2)c1cccc2c1-c1ccccc1C2(C)C ; CC1(C)c2ccccc2-c2ccc(N(c3ccc4c(c3)C(C)(C)c3ccccc3-4)c3ccc(-c4ccccc4)cc3-c3cccc4c3oc3ccccc34)cc21 ; CC1(C)c2ccccc2-c2ccc(N(c3ccc4c(c3)C(C)(C)c3ccccc3-4)c3ccc(-c4ccccc4)cc3-c3cccc4c3sc3ccccc34)cc21]

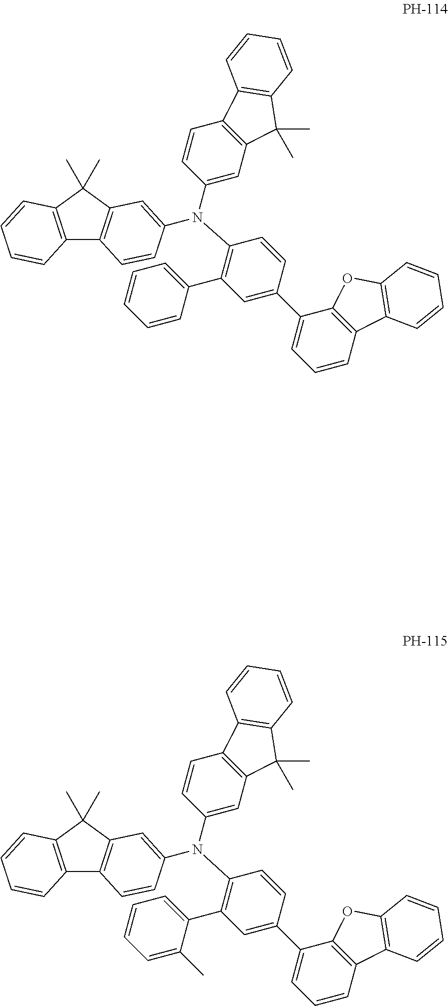 [SMILES: CC1(C)c2ccccc2-c2ccc(N(c3ccc4c(c3)C(C)(C)c3ccccc3-4)c3ccc(-c4cccc5c4oc4ccccc45)cc3-c3ccccc3)cc21 ; Cc1ccccc1-c1cc(-c2cccc3c2oc2ccccc23)ccc1N(c1ccc2c(c1)C(C)(C)c1ccccc1-2)c1ccc2c(c1)C(C)(C)c1ccccc1-2]

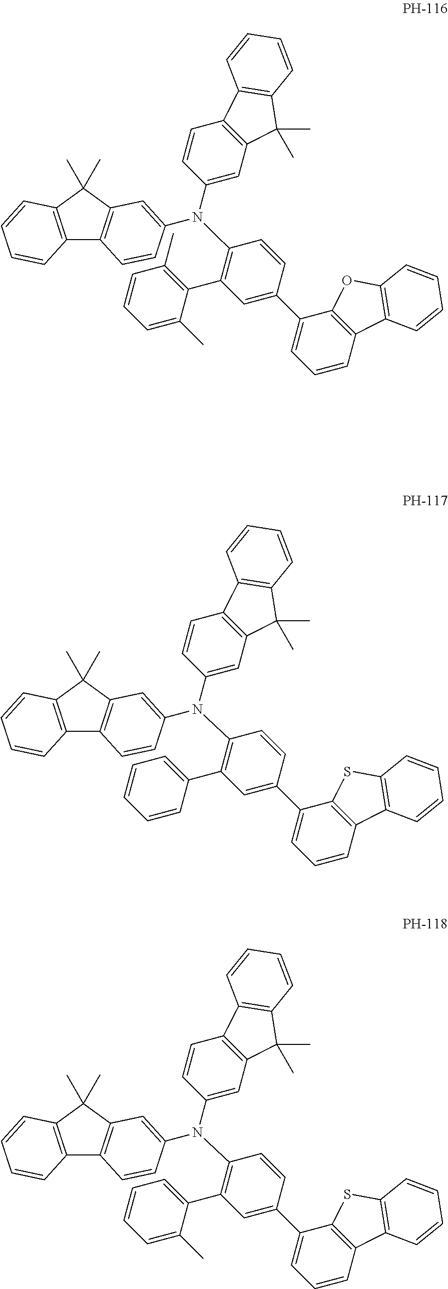 [SMILES: Cc1cccc(C)c1-c1cc(-c2cccc3c2oc2ccccc23)ccc1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3ccc(-c4cccc5c4sc4ccccc45)cc3-c3ccccc3)cc21 ; Cc1ccccc1-c1cc(-c2cccc3c2sc2ccccc23)ccc1N(c1ccc2c(c1)C(C)(C)c1ccccc1-2)c1ccc2c(c1)C(C)(C)c1ccccc1-2]

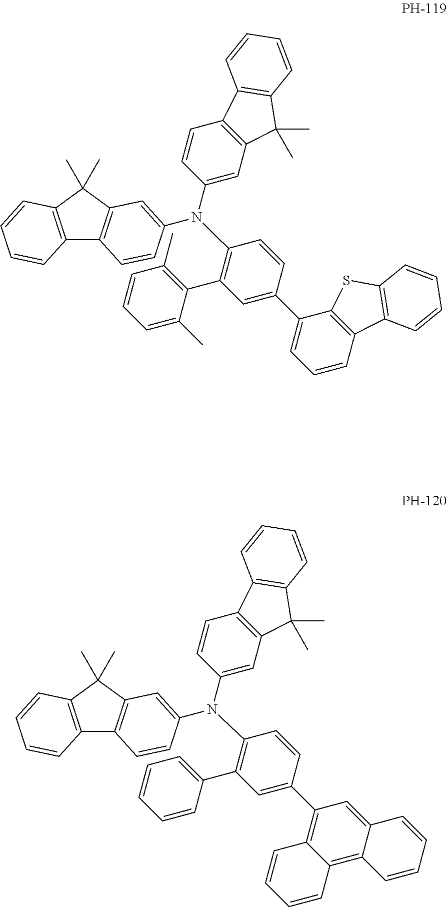 [SMILES: Cc1cccc(C)c1-c1cc(-c2cccc3c2sc2ccccc23)ccc1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3ccc(-c4cc5ccccc5c5ccccc45)cc3-c3ccccc3)cc21]

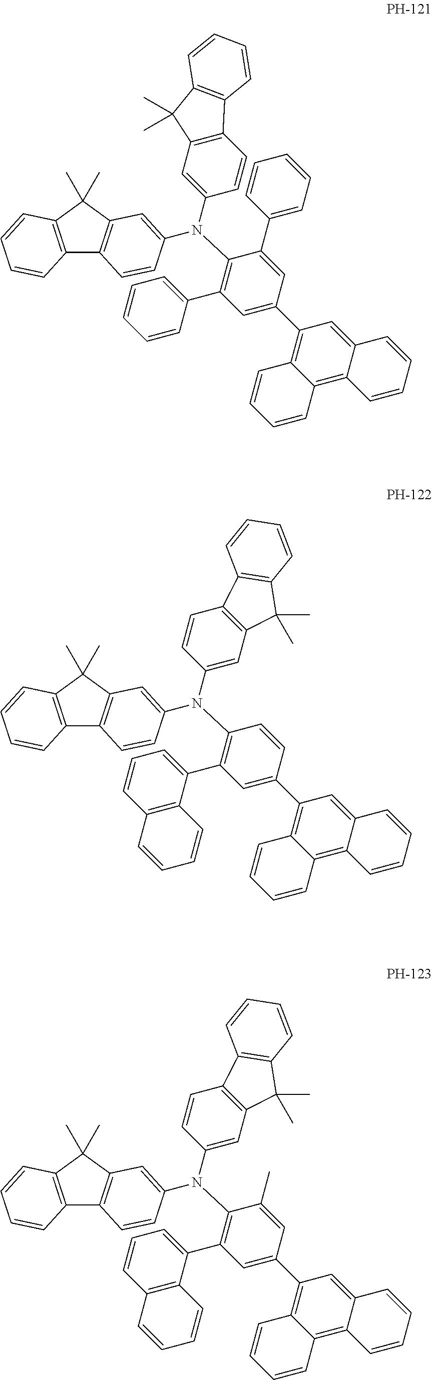 [SMILES: CC1(C)c2ccccc2-c2ccc(N(c3ccc4c(c3)C(C)(C)c3ccccc3-4)c3c(-c4ccccc4)cc(-c4cc5ccccc5c5ccccc45)cc3-c3ccccc3)cc21 ; CC1(C)c2ccccc2-c2ccc(N(c3ccc4c(c3)C(C)(C)c3ccccc3-4)c3ccc(-c4cc5ccccc5c5ccccc45)cc3-c3cccc4ccccc34)cc21 ; Cc1cc(-c2cc3ccccc3c3ccccc23)cc(-c2cccc3ccccc23)c1N(c1ccc2c(c1)C(C)(C)c1ccccc1-2)c1ccc2c(c1)C(C)(C)c1ccccc1-2]

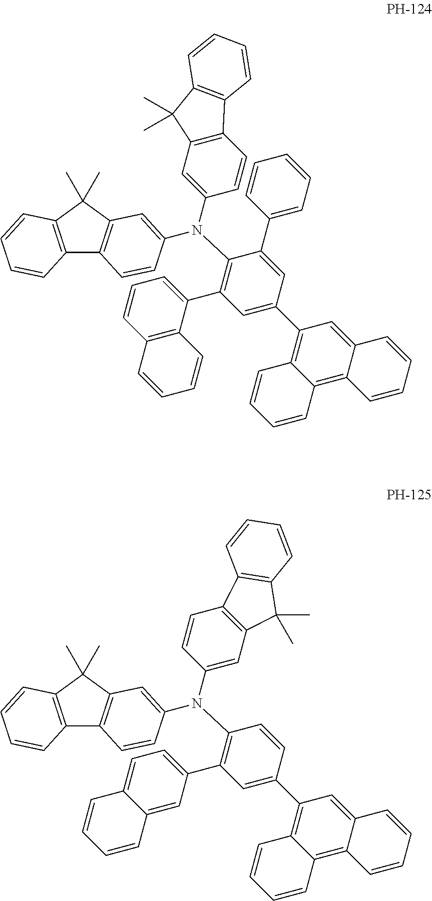 [SMILES: CC1(C)c2ccccc2-c2ccc(N(c3ccc4c(c3)C(C)(C)c3ccccc3-4)c3c(-c4ccccc4)cc(-c4cc5ccccc5c5ccccc45)cc3-c3cccc4ccccc34)cc21 ; CC1(C)c2ccccc2-c2ccc(N(c3ccc4c(c3)C(C)(C)c3ccccc3-4)c3ccc(-c4cc5ccccc5c5ccccc45)cc3-c3ccc4ccccc4c3)cc21]

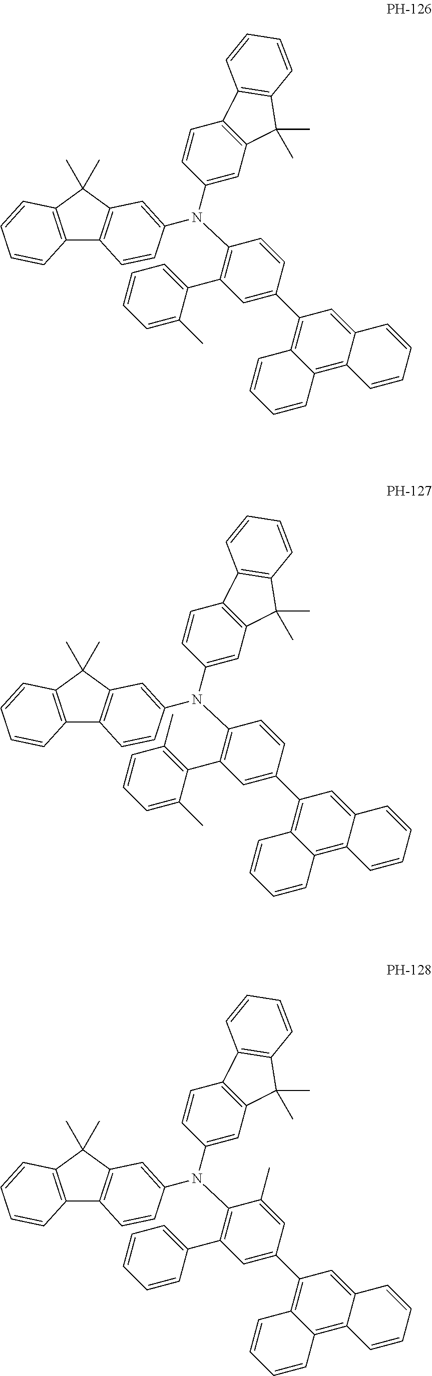 [SMILES: Cc1ccccc1-c1cc(-c2cc3ccccc3c3ccccc23)ccc1N(c1ccc2c(c1)C(C)(C)c1ccccc1-2)c1ccc2c(c1)C(C)(C)c1ccccc1-2 ; Cc1cccc(C)c1-c1cc(-c2cc3ccccc3c3ccccc23)ccc1N(c1ccc2c(c1)C(C)(C)c1ccccc1-2)c1ccc2c(c1)C(C)(C)c1ccccc1-2 ; Cc1cc(-c2cc3ccccc3c3ccccc23)cc(-c2ccccc2)c1N(c1ccc2c(c1)C(C)(C)c1ccccc1-2)c1ccc2c(c1)C(C)(C)c1ccccc1-2]

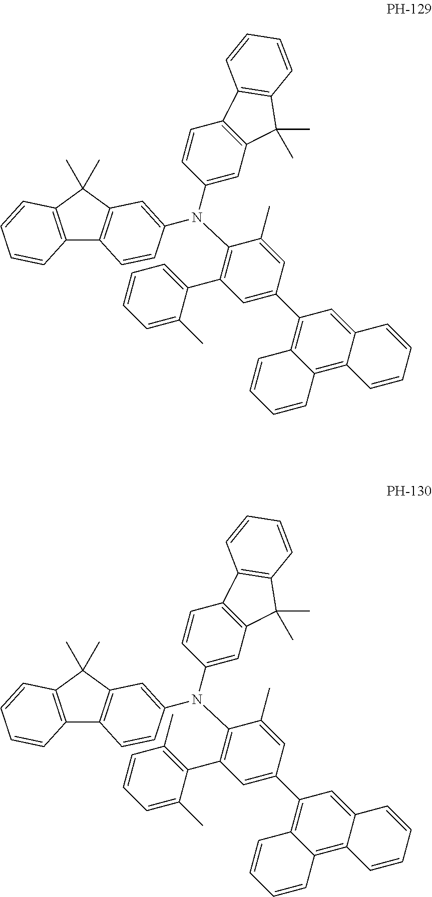 [SMILES: Cc1ccccc1-c1cc(-c2cc3ccccc3c3ccccc23)cc(C)c1N(c1ccc2c(c1)C(C)(C)c1ccccc1-2)c1ccc2c(c1)C(C)(C)c1ccccc1-2 ; Cc1cccc(C)c1-c1cc(-c2cc3ccccc3c3ccccc23)cc(C)c1N(c1ccc2c(c1)C(C)(C)c1ccccc1-2)c1ccc2c(c1)C(C)(C)c1ccccc1-2]

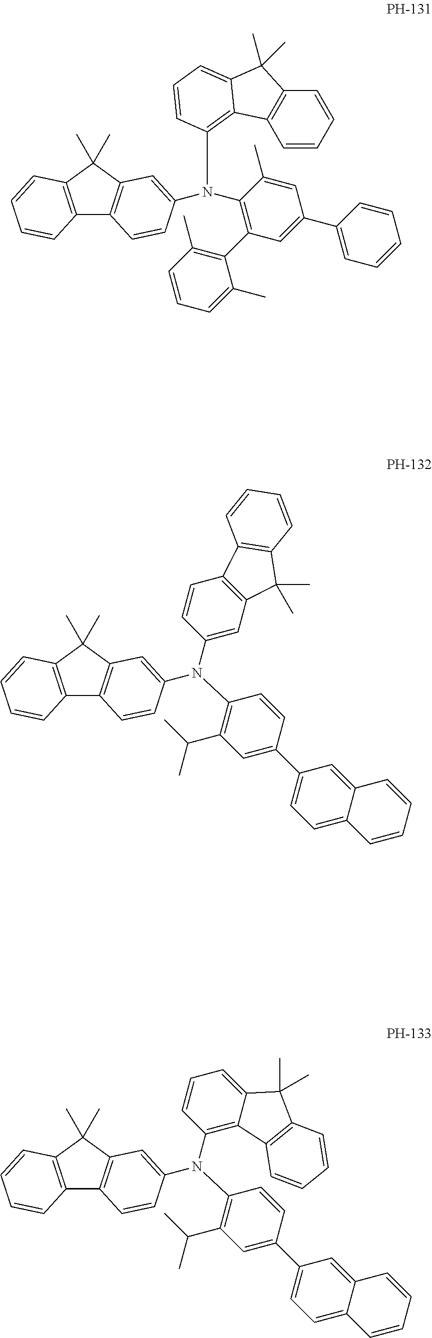 [SMILES: Cc1cccc(C)c1-c1cc(-c2ccccc2)cc(C)c1N(c1ccc2c(c1)C(C)(C)c1ccccc1-2)c1cccc2c1-c1ccccc1C2(C)C ; CC(C)c1cc(-c2ccc3ccccc3c2)ccc1N(c1ccc2c(c1)C(C)(C)c1ccccc1-2)c1ccc2c(c1)C(C)(C)c1ccccc1-2 ; CC(C)c1cc(-c2ccc3ccccc3c2)ccc1N(c1ccc2c(c1)C(C)(C)c1ccccc1-2)c1cccc2c1-c1ccccc1C2(C)C]

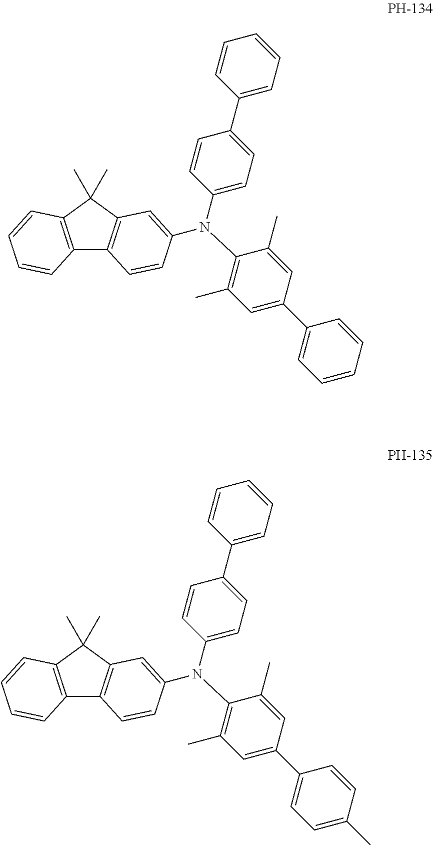 [SMILES: Cc1cc(-c2ccccc2)cc(C)c1N(c1ccc(-c2ccccc2)cc1)c1ccc2c(c1)C(C)(C)c1ccccc1-2 ; Cc1ccc(-c2cc(C)c(N(c3ccc(-c4ccccc4)cc3)c3ccc4c(c3)C(C)(C)c3ccccc3-4)c(C)c2)cc1]

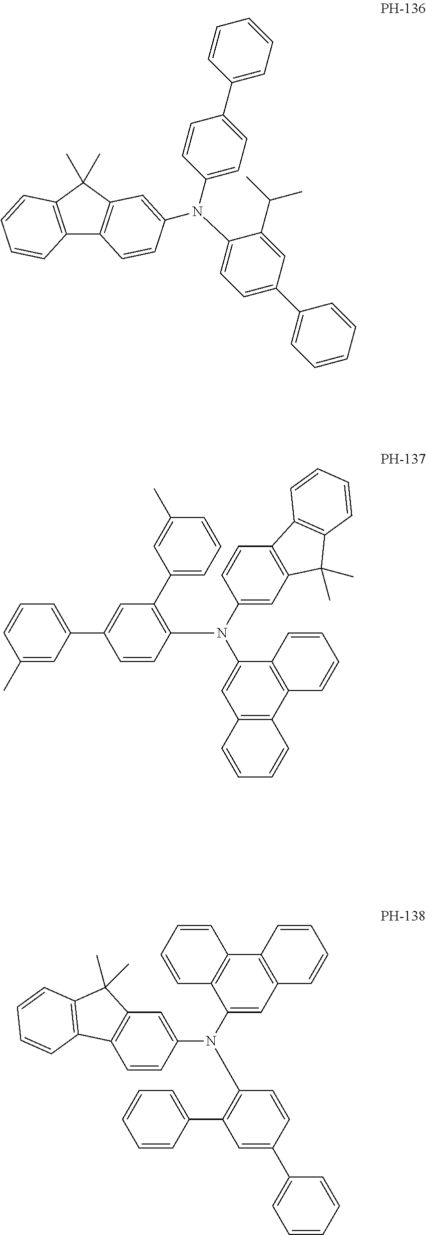 [SMILES: CC(C)c1cc(-c2ccccc2)ccc1N(c1ccc(-c2ccccc2)cc1)c1ccc2c(c1)C(C)(C)c1ccccc1-2 ; Cc1cccc(-c2ccc(N(c3ccc4c(c3)C(C)(C)c3ccccc3-4)c3cc4ccccc4c4ccccc34)c(-c3cccc(C)c3)c2)c1 ; CC1(C)c2ccccc2-c2ccc(N(c3ccc(-c4ccccc4)cc3-c3ccccc3)c3cc4ccccc4c4ccccc34)cc21]

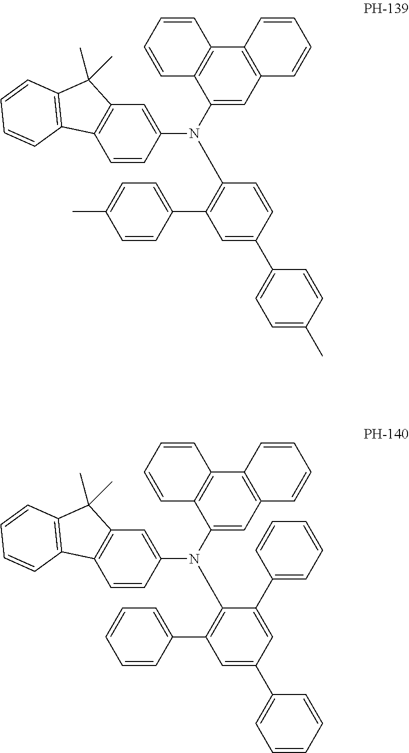 [SMILES: Cc1ccc(-c2ccc(N(c3ccc4c(c3)C(C)(C)c3ccccc3-4)c3cc4ccccc4c4ccccc34)c(-c3ccc(C)cc3)c2)cc1 ; CC1(C)c2ccccc2-c2ccc(N(c3c(-c4ccccc4)cc(-c4ccccc4)cc3-c3ccccc3)c3cc4ccccc4c4ccccc34)cc21]

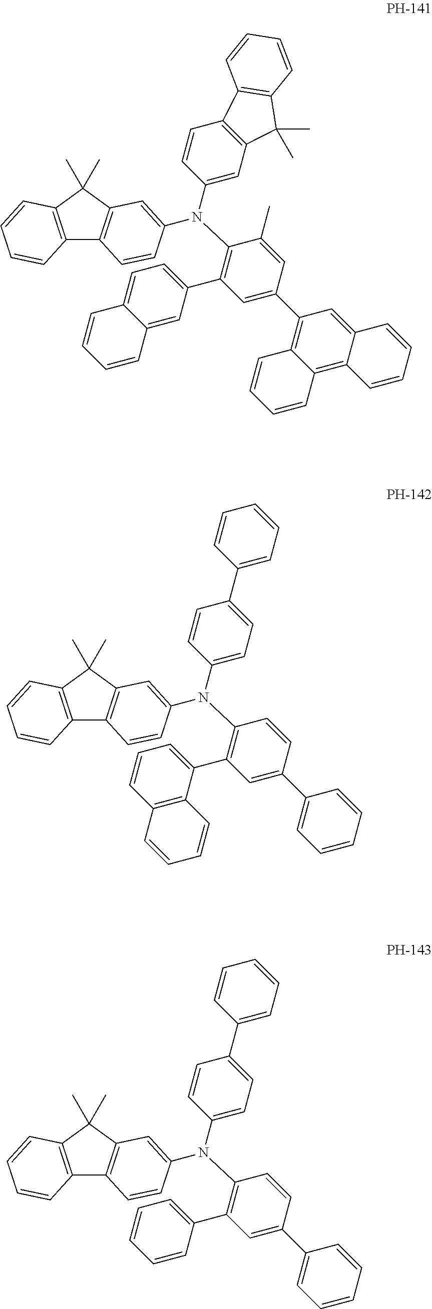 [SMILES: Cc1cc(-c2cc3ccccc3c3ccccc23)cc(-c2ccc3ccccc3c2)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc(-c4ccccc4)cc3)c3ccc(-c4ccccc4)cc3-c3cccc4ccccc34)cc21 ; CC1(C)c2ccccc2-c2ccc(N(c3ccc(-c4ccccc4)cc3)c3ccc(-c4ccccc4)cc3-c3ccccc3)cc21]

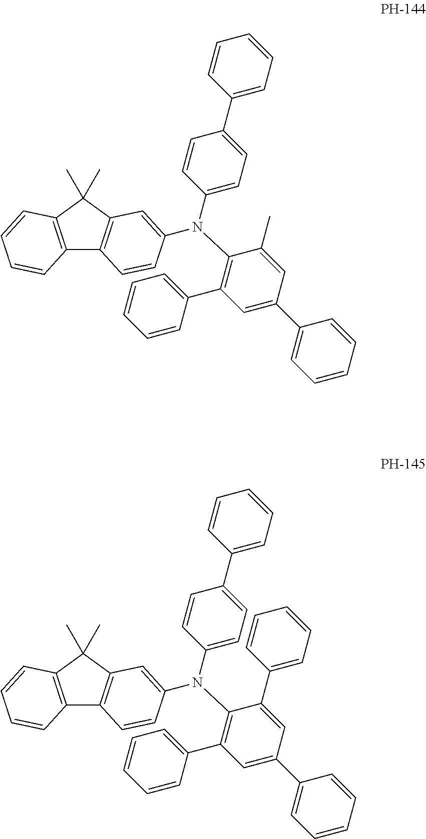 [SMILES: Cc1cc(-c2ccccc2)cc(-c2ccccc2)c1N(c1ccc(-c2ccccc2)cc1)c1ccc2c(c1)C(C)(C)c1ccccc1-2 ; CC1(C)c2ccccc2-c2ccc(N(c3ccc(-c4ccccc4)cc3)c3c(-c4ccccc4)cc(-c4ccccc4)cc3-c3ccccc3)cc21]

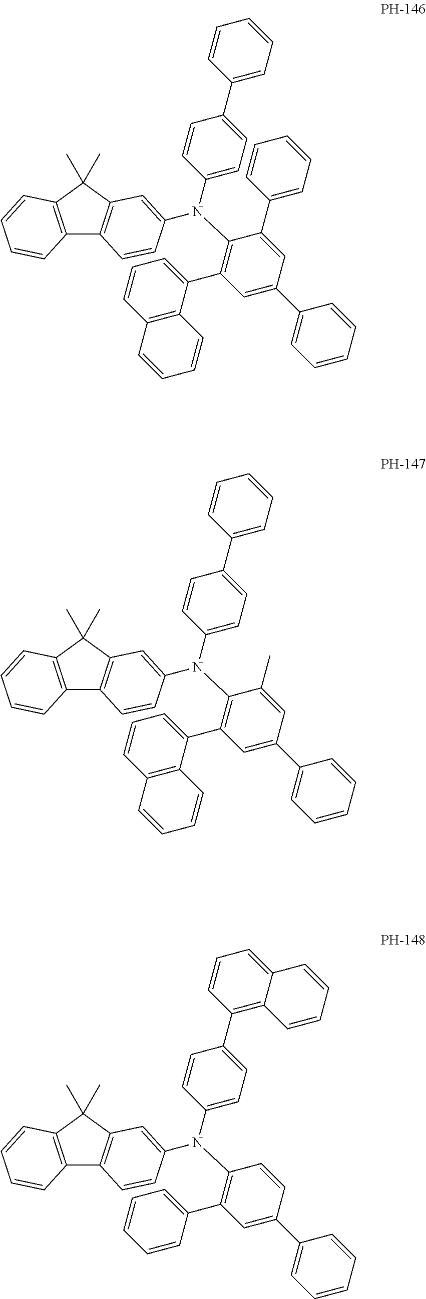 [SMILES: CC1(C)c2ccccc2-c2ccc(N(c3ccc(-c4ccccc4)cc3)c3c(-c4ccccc4)cc(-c4ccccc4)cc3-c3cccc4ccccc34)cc21 ; Cc1cc(-c2ccccc2)cc(-c2cccc3ccccc23)c1N(c1ccc(-c2ccccc2)cc1)c1ccc2c(c1)C(C)(C)c1ccccc1-2 ; CC1(C)c2ccccc2-c2ccc(N(c3ccc(-c4cccc5ccccc45)cc3)c3ccc(-c4ccccc4)cc3-c3ccccc3)cc21]

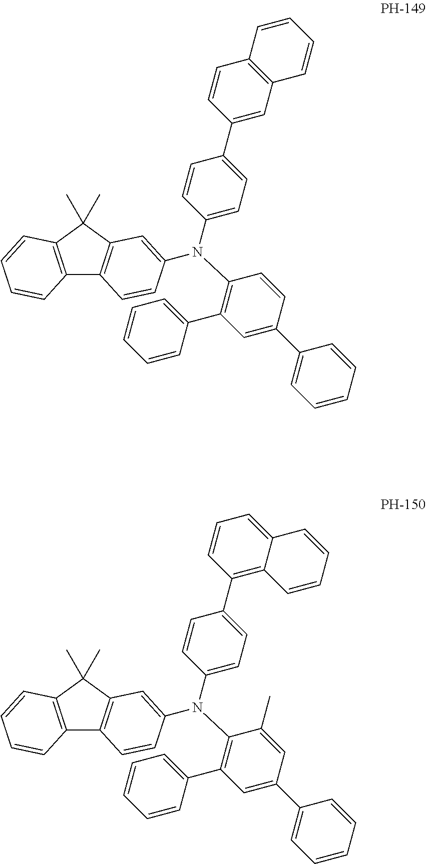 [SMILES: CC1(C)c2ccccc2-c2ccc(N(c3ccc(-c4ccc5ccccc5c4)cc3)c3ccc(-c4ccccc4)cc3-c3ccccc3)cc21 ; Cc1cc(-c2ccccc2)cc(-c2ccccc2)c1N(c1ccc(-c2cccc3ccccc23)cc1)c1ccc2c(c1)C(C)(C)c1ccccc1-2]

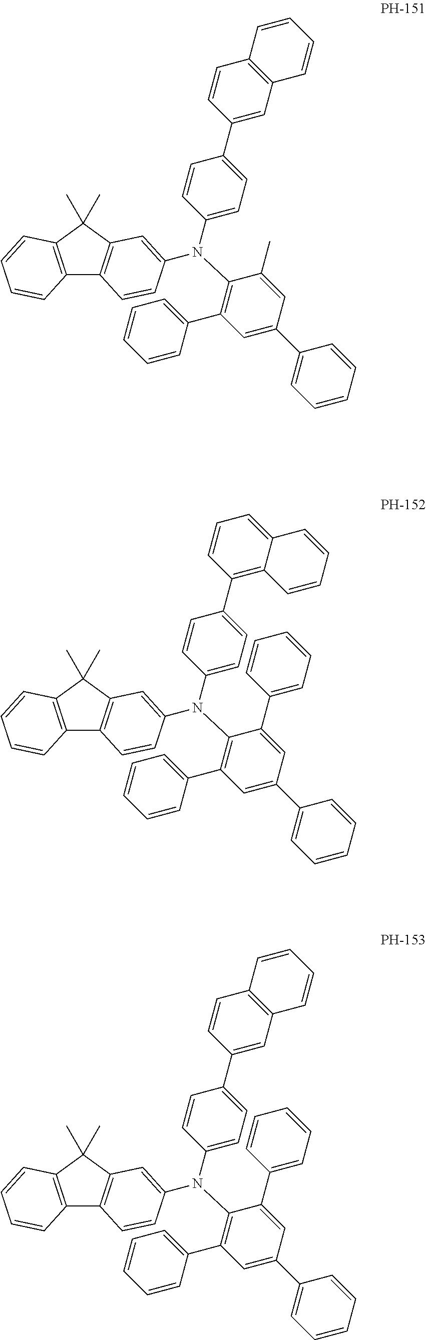 [SMILES: Cc1cc(-c2ccccc2)cc(-c2ccccc2)c1N(c1ccc(-c2ccc3ccccc3c2)cc1)c1ccc2c(c1)C(C)(C)c1ccccc1-2 ; CC1(C)c2ccccc2-c2ccc(N(c3ccc(-c4cccc5ccccc45)cc3)c3c(-c4ccccc4)cc(-c4ccccc4)cc3-c3ccccc3)cc21 ; CC1(C)c2ccccc2-c2ccc(N(c3ccc(-c4ccc5ccccc5c4)cc3)c3c(-c4ccccc4)cc(-c4ccccc4)cc3-c3ccccc3)cc21]

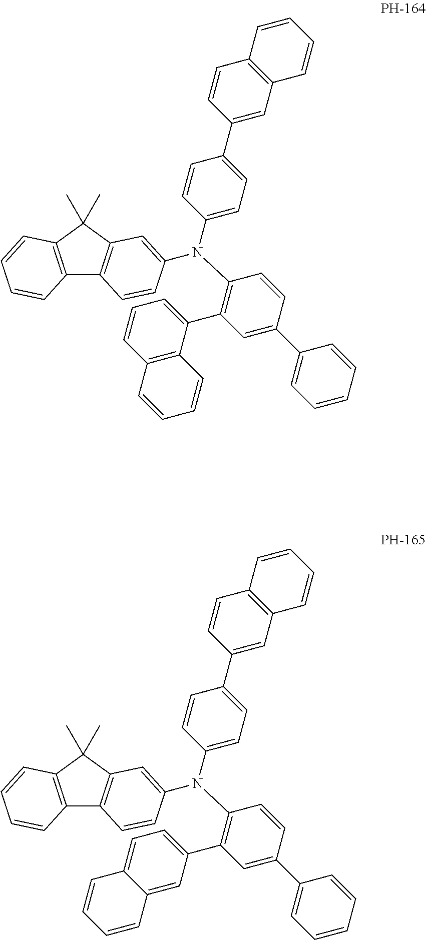 [SMILES: CC1(C)c2ccccc2-c2ccc(N(c3ccc(-c4ccc5ccccc5c4)cc3)c3ccc(-c4ccccc4)cc3-c3cccc4ccccc34)cc21 ; CC1(C)c2ccccc2-c2ccc(N(c3ccc(-c4ccc5ccccc5c4)cc3)c3ccc(-c4ccccc4)cc3-c3ccc4ccccc4c3)cc21]

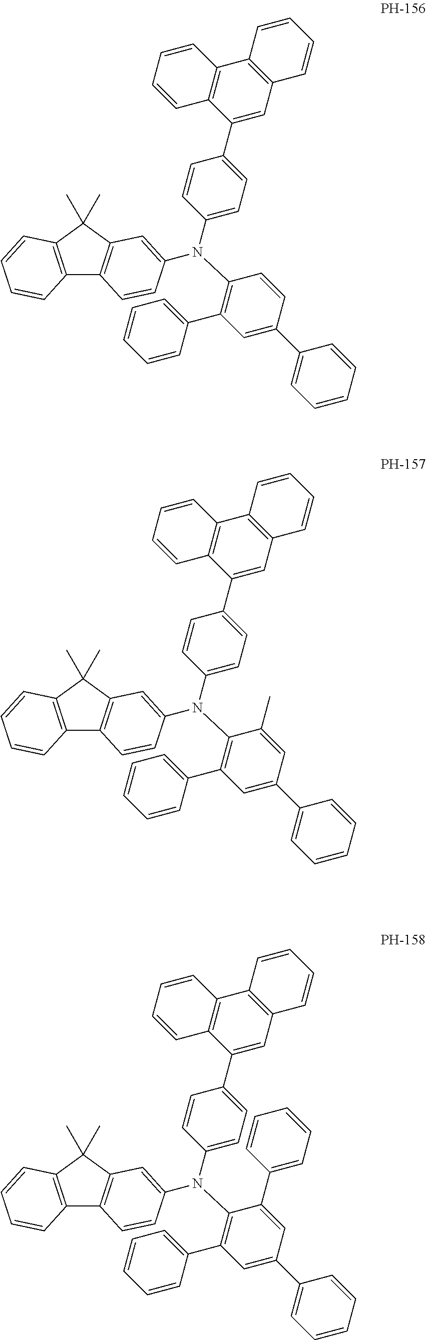 [SMILES: CC1(C)c2ccccc2-c2ccc(N(c3ccc(-c4cc5ccccc5c5ccccc45)cc3)c3ccc(-c4ccccc4)cc3-c3ccccc3)cc21 ; Cc1cc(-c2ccccc2)cc(-c2ccccc2)c1N(c1ccc(-c2cc3ccccc3c3ccccc23)cc1)c1ccc2c(c1)C(C)(C)c1ccccc1-2 ; CC1(C)c2ccccc2-c2ccc(N(c3ccc(-c4cc5ccccc5c5ccccc45)cc3)c3c(-c4ccccc4)cc(-c4ccccc4)cc3-c3ccccc3)cc21]

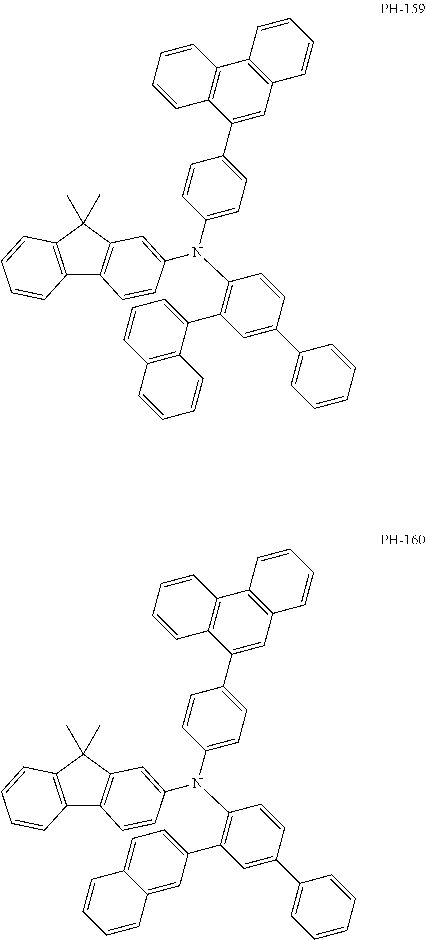 [SMILES: CC1(C)c2ccccc2-c2ccc(N(c3ccc(-c4cc5ccccc5c5ccccc45)cc3)c3ccc(-c4ccccc4)cc3-c3cccc4ccccc34)cc21 ; CC1(C)c2ccccc2-c2ccc(N(c3ccc(-c4cc5ccccc5c5ccccc45)cc3)c3ccc(-c4ccccc4)cc3-c3ccc4ccccc4c3)cc21]

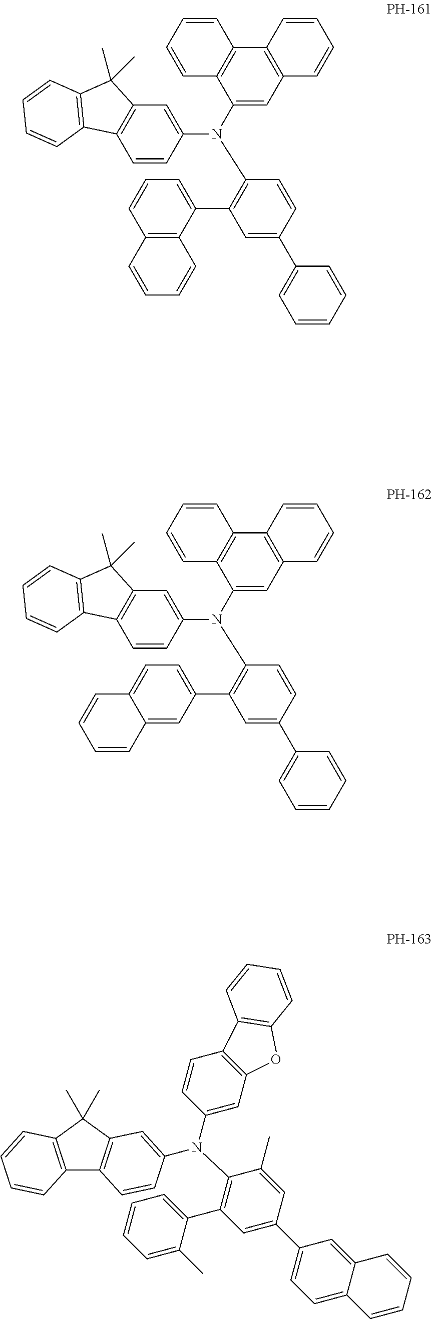 [SMILES: CC1(C)c2ccccc2-c2ccc(N(c3ccc(-c4ccccc4)cc3-c3cccc4ccccc34)c3cc4ccccc4c4ccccc34)cc21 ; CC1(C)c2ccccc2-c2ccc(N(c3ccc(-c4ccccc4)cc3-c3ccc4ccccc4c3)c3cc4ccccc4c4ccccc34)cc21 ; Cc1ccccc1-c1cc(-c2ccc3ccccc3c2)cc(C)c1N(c1ccc2c(c1)C(C)(C)c1ccccc1-2)c1ccc2c(c1)oc1ccccc12]

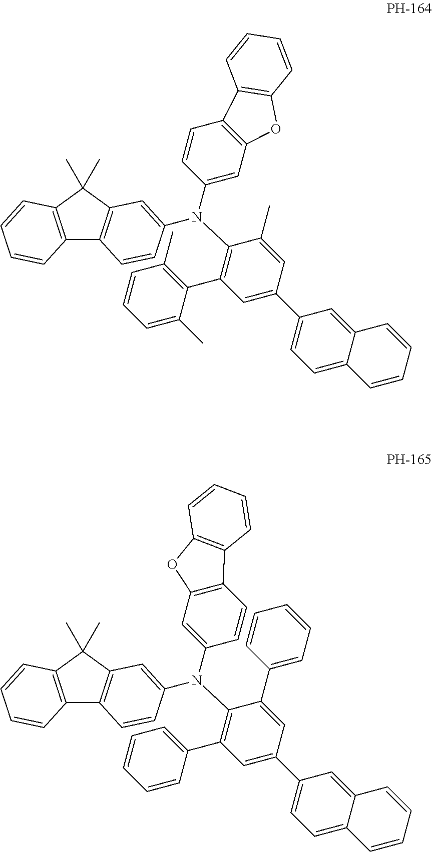 [SMILES: Cc1cccc(C)c1-c1cc(-c2ccc3ccccc3c2)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccc5ccccc5c4)cc3-c3ccccc3)cc21]

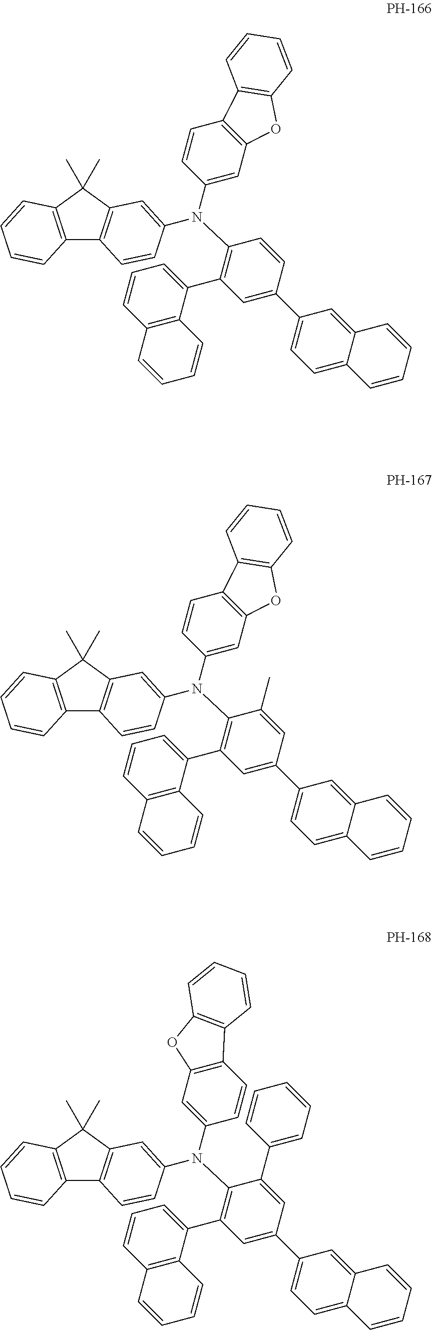 [SMILES: CC1(C)c2ccccc2-c2ccc(N(c3ccc4c(c3)oc3ccccc34)c3ccc(-c4ccc5ccccc5c4)cc3-c3cccc4ccccc34)cc21 ; Cc1cc(-c2ccc3ccccc3c2)cc(-c2cccc3ccccc23)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccc5ccccc5c4)cc3-c3cccc4ccccc34)cc21]

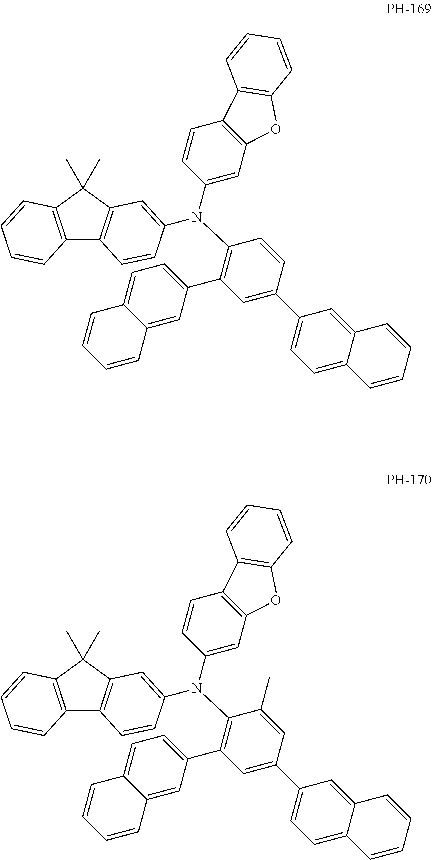 [SMILES: CC1(C)c2ccccc2-c2ccc(N(c3ccc4c(c3)oc3ccccc34)c3ccc(-c4ccc5ccccc5c4)cc3-c3ccc4ccccc4c3)cc21 ; Cc1cc(-c2ccc3ccccc3c2)cc(-c2ccc3ccccc3c2)c1N(c1ccc2c(c1)C(C)(C)c1ccccc1-2)c1ccc2c(c1)oc1ccccc12]

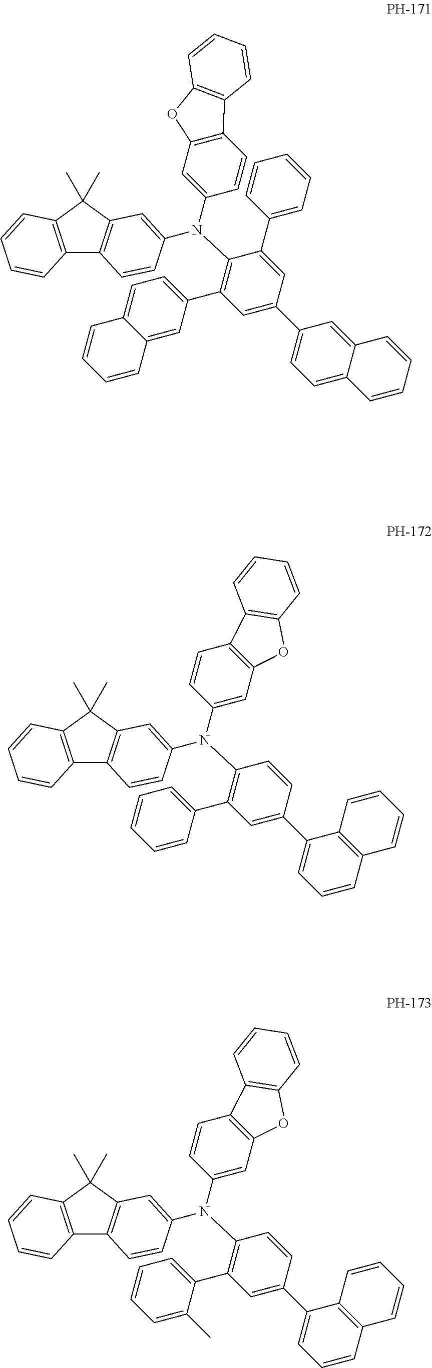 [SMILES: CC1(C)c2ccccc2-c2ccc(N(c3ccc4c(c3)oc3ccccc34)c3c(-c4ccccc4)cc(-c4ccc5ccccc5c4)cc3-c3ccc4ccccc4c3)cc21 ; CC1(C)c2ccccc2-c2ccc(N(c3ccc4c(c3)oc3ccccc34)c3ccc(-c4cccc5ccccc45)cc3-c3ccccc3)cc21 ; Cc1ccccc1-c1cc(-c2cccc3ccccc23)ccc1N(c1ccc2c(c1)C(C)(C)c1ccccc1-2)c1ccc2c(c1)oc1ccccc12]

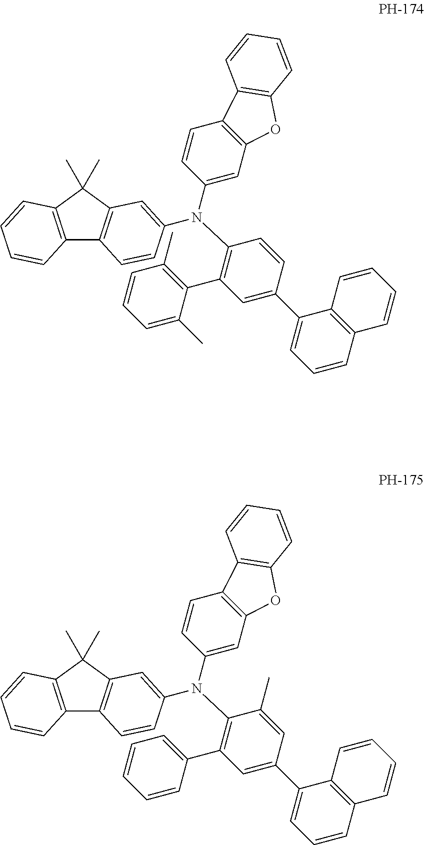 [SMILES: Cc1cccc(C)c1-c1cc(-c2cccc3ccccc23)ccc1N(c1ccc2c(c1)C(C)(C)c1ccccc1-2)c1ccc2c(c1)oc1ccccc12 ; Cc1cc(-c2cccc3ccccc23)cc(-c2ccccc2)c1N(c1ccc2c(c1)C(C)(C)c1ccccc1-2)c1ccc2c(c1)oc1ccccc12]

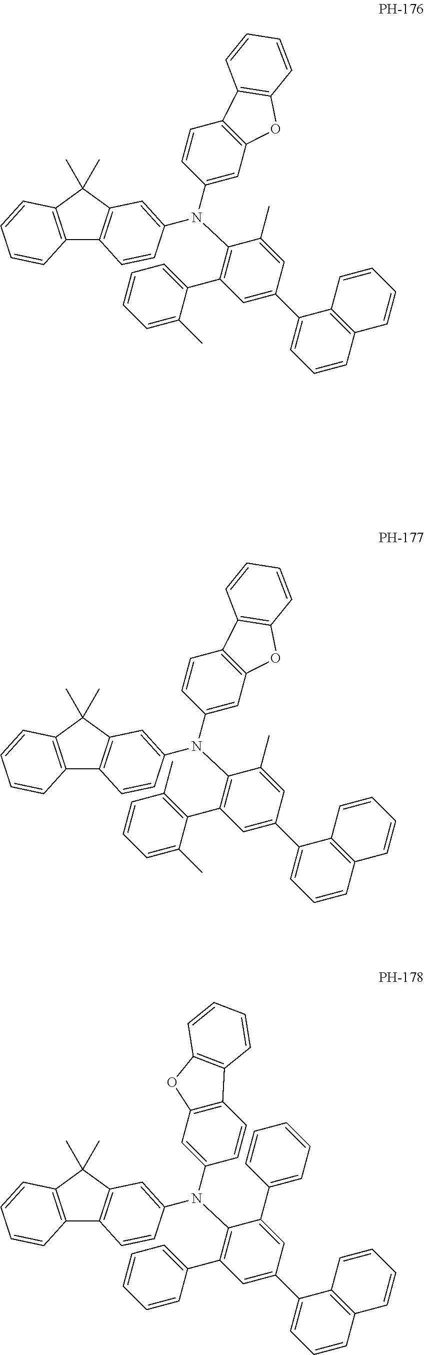 [SMILES: Cc1ccccc1-c1cc(-c2cccc3ccccc23)cc(C)c1N(c1ccc2c(c1)C(C)(C)c1ccccc1-2)c1ccc2c(c1)oc1ccccc12 ; Cc1cccc(C)c1-c1cc(-c2cccc3ccccc23)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4cccc5ccccc45)cc3-c3ccccc3)cc21]

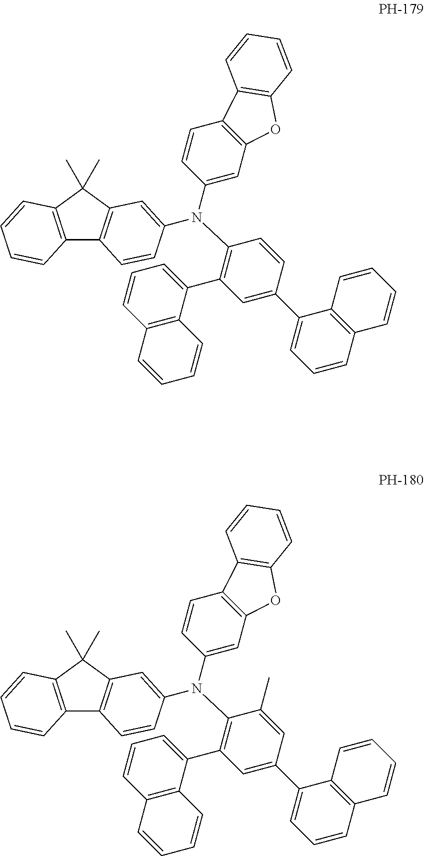 [SMILES: CC1(C)c2ccccc2-c2ccc(N(c3ccc4c(c3)oc3ccccc34)c3ccc(-c4cccc5ccccc45)cc3-c3cccc4ccccc34)cc21 ; Cc1cc(-c2cccc3ccccc23)cc(-c2cccc3ccccc23)c1N(c1ccc2c(c1)C(C)(C)c1ccccc1-2)c1ccc2c(c1)oc1ccccc12]

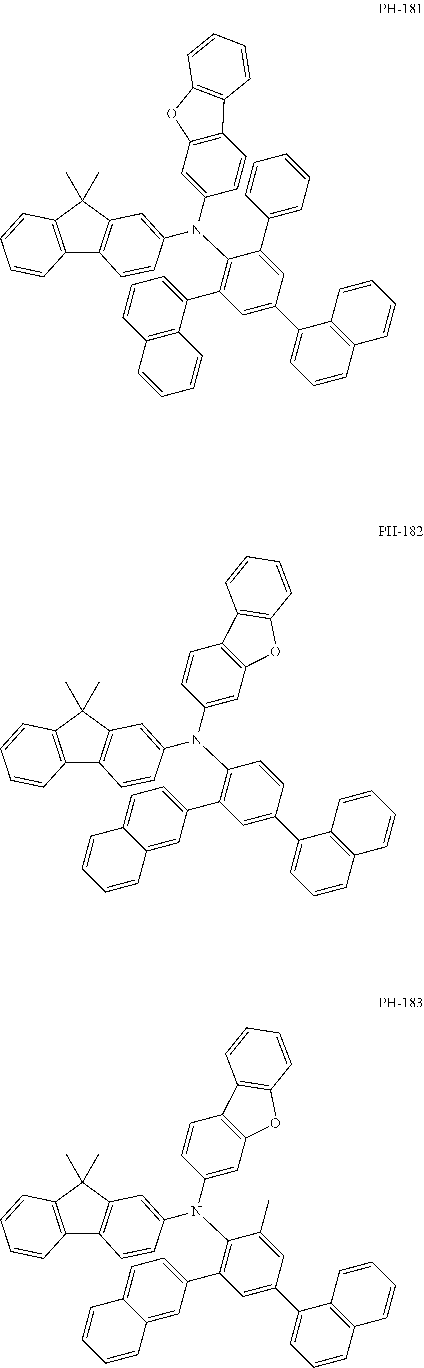 [SMILES: CC1(C)c2ccccc2-c2ccc(N(c3ccc4c(c3)oc3ccccc34)c3c(-c4ccccc4)cc(-c4cccc5ccccc45)cc3-c3cccc4ccccc34)cc21 ; CC1(C)c2ccccc2-c2ccc(N(c3ccc4c(c3)oc3ccccc34)c3ccc(-c4cccc5ccccc45)cc3-c3ccc4ccccc4c3)cc21 ; Cc1cc(-c2cccc3ccccc23)cc(-c2ccc3ccccc3c2)c1N(c1ccc2c(c1)C(C)(C)c1ccccc1-2)c1ccc2c(c1)oc1ccccc12]

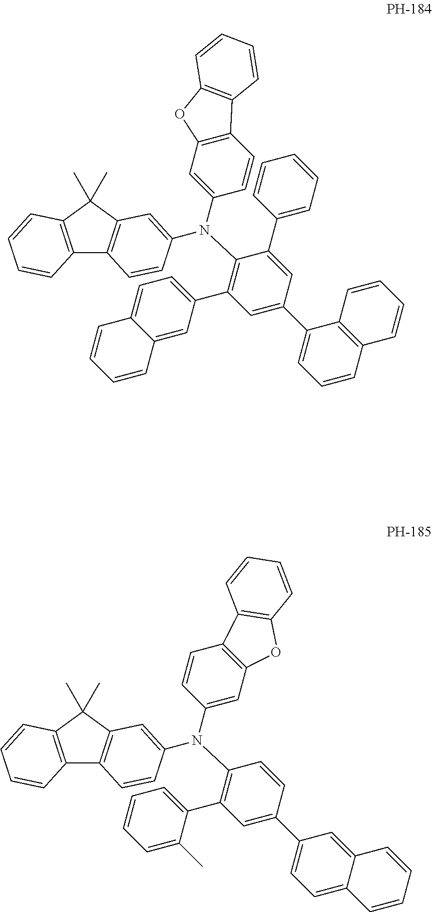 [SMILES: CC1(C)c2ccccc2-c2ccc(N(c3ccc4c(c3)oc3ccccc34)c3c(-c4ccccc4)cc(-c4cccc5ccccc45)cc3-c3ccc4ccccc4c3)cc21 ; Cc1ccccc1-c1cc(-c2ccc3ccccc3c2)ccc1N(c1ccc2c(c1)C(C)(C)c1ccccc1-2)c1ccc2c(c1)oc1ccccc12]

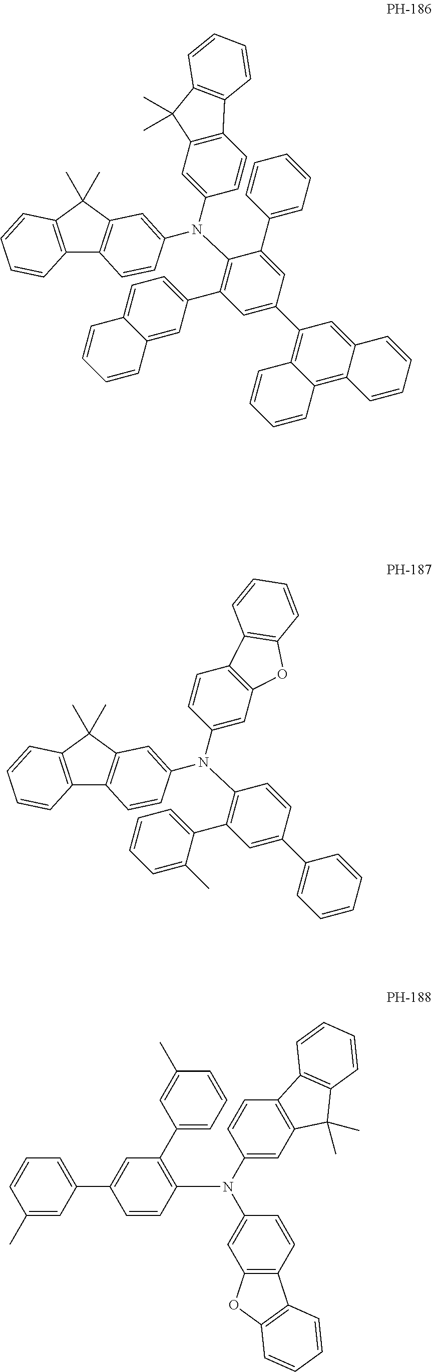 [SMILES: CC1(C)c2ccccc2-c2ccc(N(c3ccc4c(c3)C(C)(C)c3ccccc3-4)c3c(-c4ccccc4)cc(-c4cc5ccccc5c5ccccc45)cc3-c3ccc4ccccc4c3)cc21 ; Cc1ccccc1-c1cc(-c2ccccc2)ccc1N(c1ccc2c(c1)C(C)(C)c1ccccc1-2)c1ccc2c(c1)oc1ccccc12 ; Cc1cccc(-c2ccc(N(c3ccc4c(c3)C(C)(C)c3ccccc3-4)c3ccc4c(c3)oc3ccccc34)c(-c3cccc(C)c3)c2)c1]

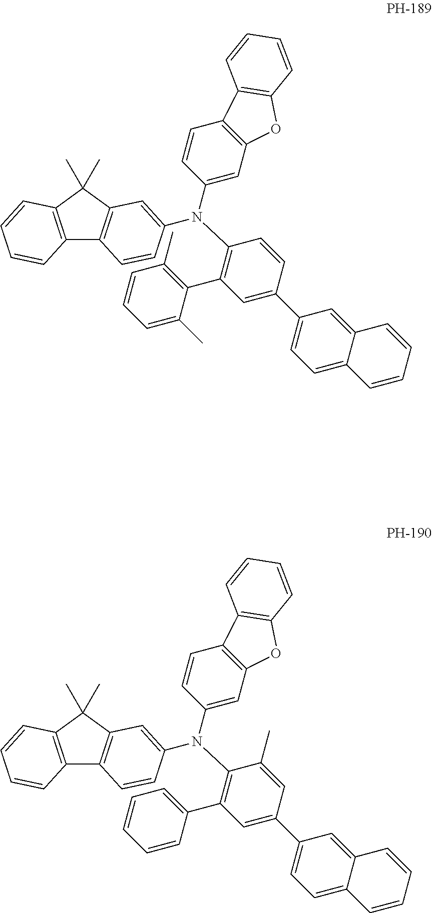 [SMILES: Cc1cccc(C)c1-c1cc(-c2ccc3ccccc3c2)ccc1N(c1ccc2c(c1)C(C)(C)c1ccccc1-2)c1ccc2c(c1)oc1ccccc12 ; Cc1cc(-c2ccc3ccccc3c2)cc(-c2ccccc2)c1N(c1ccc2c(c1)C(C)(C)c1ccccc1-2)c1ccc2c(c1)oc1ccccc12]

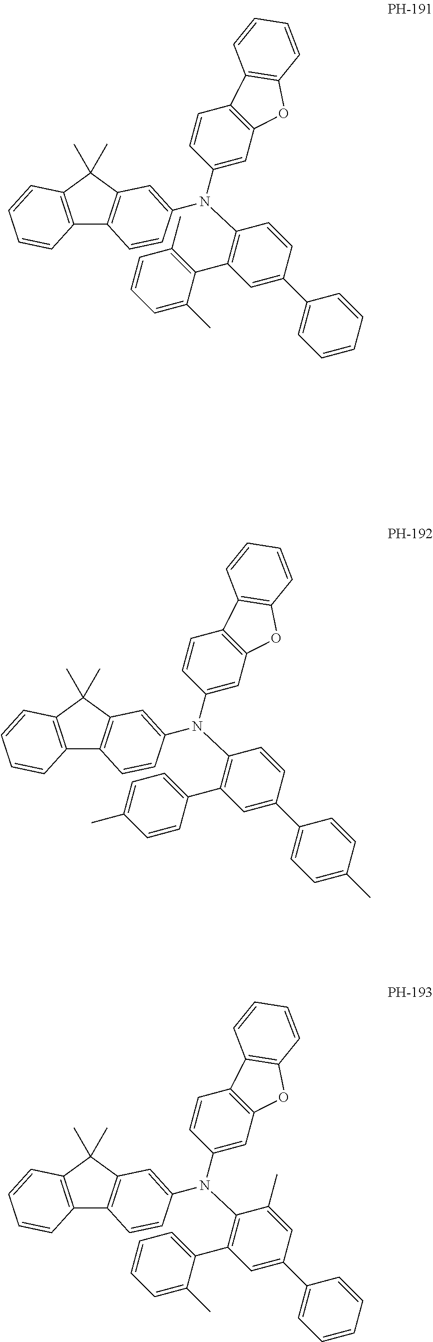 [SMILES: Cc1cccc(C)c1-c1cc(-c2ccccc2)ccc1N(c1ccc2c(c1)C(C)(C)c1ccccc1-2)c1ccc2c(c1)oc1ccccc12 ; Cc1ccc(-c2ccc(N(c3ccc4c(c3)C(C)(C)c3ccccc3-4)c3ccc4c(c3)oc3ccccc34)c(-c3ccc(C)cc3)c2)cc1 ; Cc1ccccc1-c1cc(-c2ccccc2)cc(C)c1N(c1ccc2c(c1)C(C)(C)c1ccccc1-2)c1ccc2c(c1)oc1ccccc12]

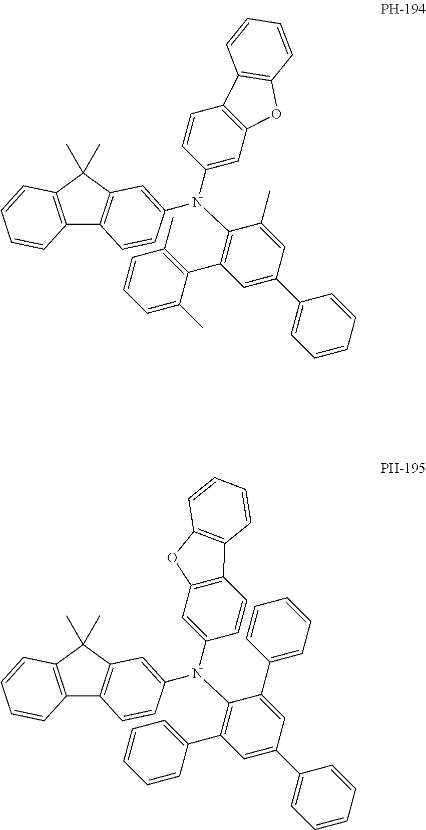 [SMILES: Cc1cccc(C)c1-c1cc(-c2ccccc2)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccccc4)cc3-c3ccccc3)cc21]

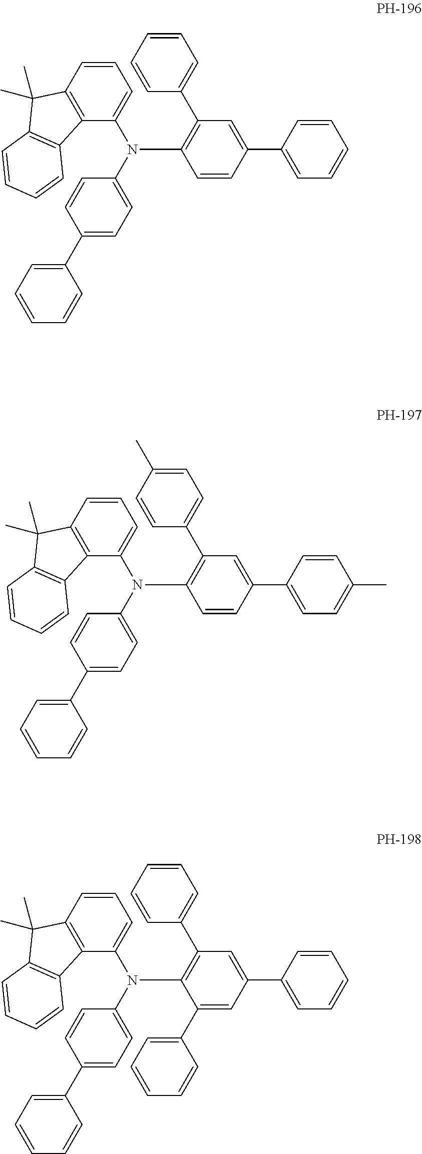

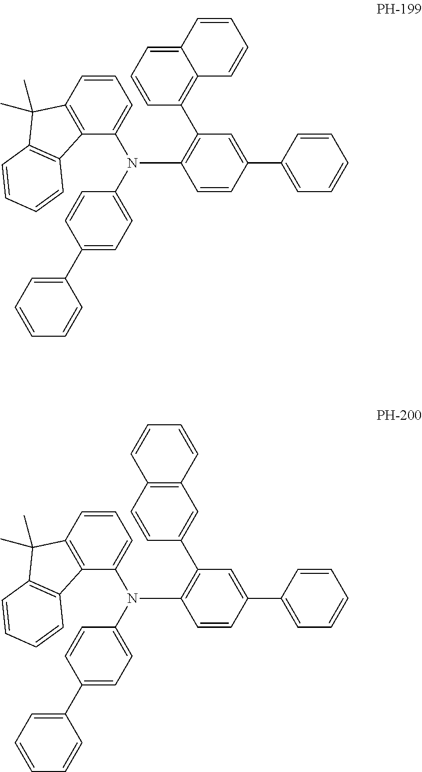 [SMILES: CC1(C)c2ccccc2-c2c(N(c3ccc(-c4ccccc4)cc3)c3ccc(-c4ccccc4)cc3-c3cccc4ccccc34)cccc21 ; CC1(C)c2ccccc2-c2c(N(c3ccc(-c4ccccc4)cc3)c3ccc(-c4ccccc4)cc3-c3ccc4ccccc4c3)cccc21]

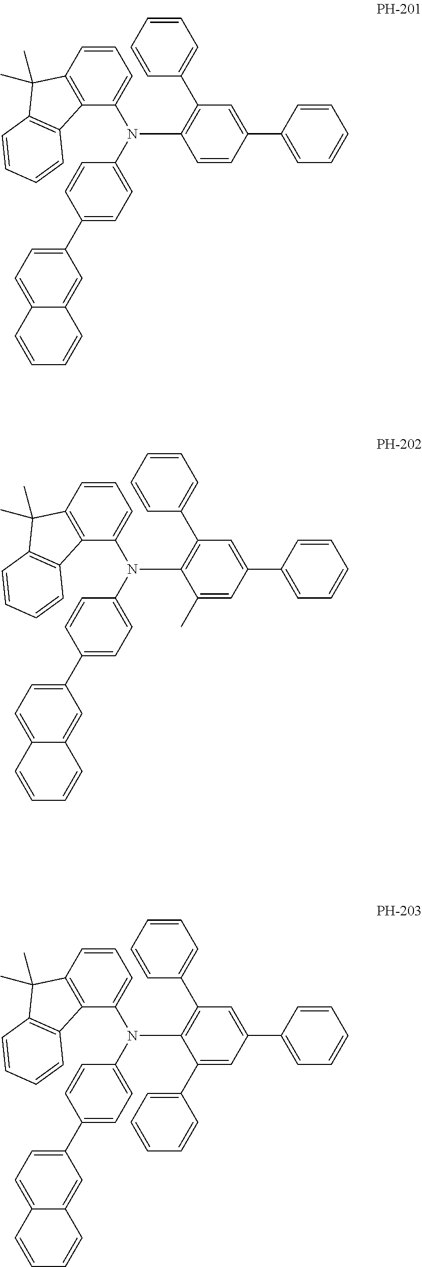 [SMILES: CC1(C)c2ccccc2-c2c(N(c3ccc(-c4ccc5ccccc5c4)cc3)c3ccc(-c4ccccc4)cc3-c3ccccc3)cccc21 ; Cc1cc(-c2ccccc2)cc(-c2ccccc2)c1N(c1ccc(-c2ccc3ccccc3c2)cc1)c1cccc2c1-c1ccccc1C2(C)C ; CC1(C)c2ccccc2-c2c(N(c3ccc(-c4ccc5ccccc5c4)cc3)c3c(-c4ccccc4)cc(-c4ccccc4)cc3-c3ccccc3)cccc21]

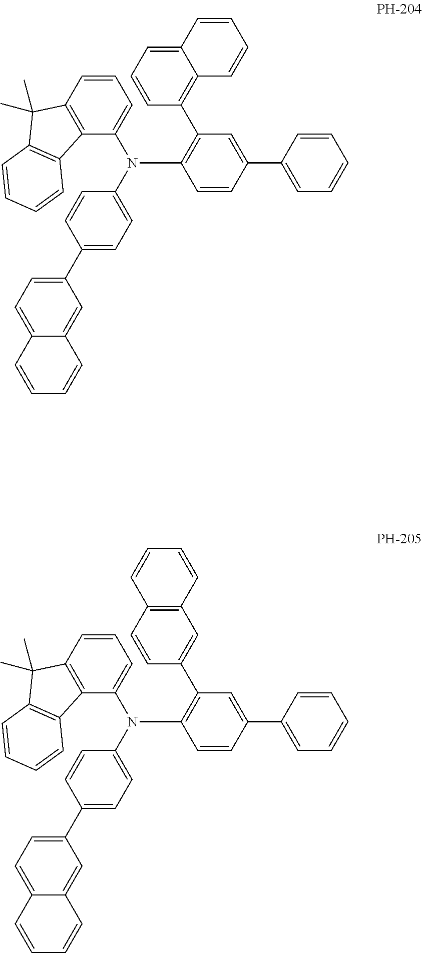 [SMILES: CC1(C)c2ccccc2-c2c(N(c3ccc(-c4ccc5ccccc5c4)cc3)c3ccc(-c4ccccc4)cc3-c3cccc4ccccc34)cccc21 ; CC1(C)c2ccccc2-c2c(N(c3ccc(-c4ccc5ccccc5c4)cc3)c3ccc(-c4ccccc4)cc3-c3ccc4ccccc4c3)cccc21]

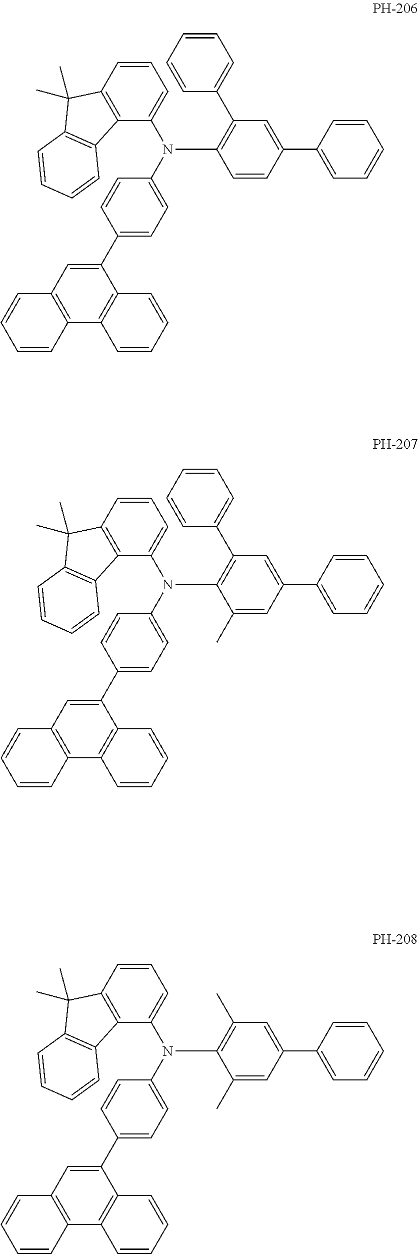 [SMILES: CC1(C)c2ccccc2-c2c(N(c3ccc(-c4cc5ccccc5c5ccccc45)cc3)c3ccc(-c4ccccc4)cc3-c3ccccc3)cccc21 ; Cc1cc(-c2ccccc2)cc(-c2ccccc2)c1N(c1ccc(-c2cc3ccccc3c3ccccc23)cc1)c1cccc2c1-c1ccccc1C2(C)C ; Cc1cc(-c2ccccc2)cc(C)c1N(c1ccc(-c2cc3ccccc3c3ccccc23)cc1)c1cccc2c1-c1ccccc1C2(C)C]

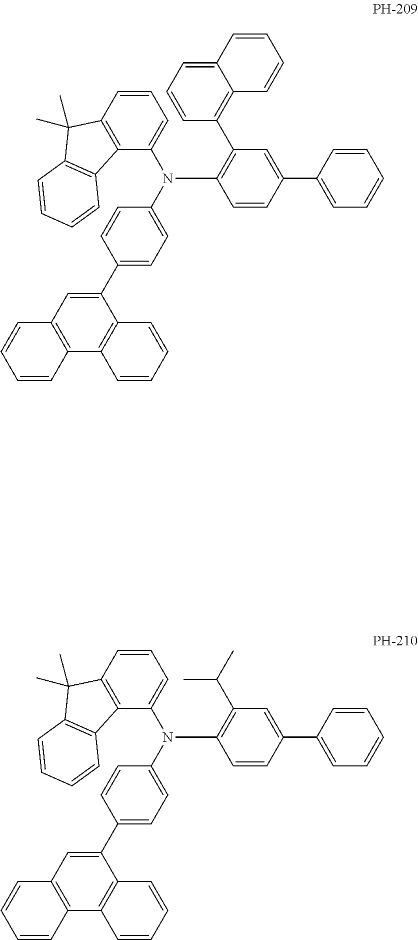 [SMILES: CC1(C)c2ccccc2-c2c(N(c3ccc(-c4cc5ccccc5c5ccccc45)cc3)c3ccc(-c4ccccc4)cc3-c3cccc4ccccc34)cccc21 ; CC(C)c1cc(-c2ccccc2)ccc1N(c1ccc(-c2cc3ccccc3c3ccccc23)cc1)c1cccc2c1-c1ccccc1C2(C)C]

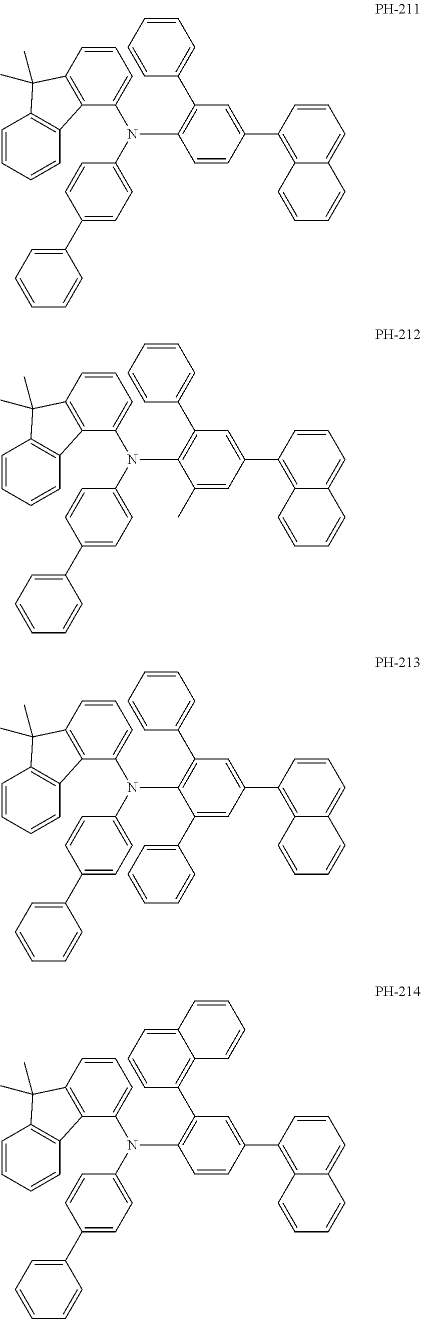 [SMILES: CC1(C)c2ccccc2-c2c(N(c3ccc(-c4ccccc4)cc3)c3ccc(-c4cccc5ccccc45)cc3-c3ccccc3)cccc21 ; Cc1cc(-c2cccc3ccccc23)cc(-c2ccccc2)c1N(c1ccc(-c2ccccc2)cc1)c1cccc2c1-c1ccccc1C2(C)C ; CC1(C)c2ccccc2-c2c(N(c3ccc(-c4ccccc4)cc3)c3c(-c4ccccc4)cc(-c4cccc5ccccc45)cc3-c3ccccc3)cccc21 ; CC1(C)c2ccccc2-c2c(N(c3ccc(-c4ccccc4)cc3)c3ccc(-c4cccc5ccccc45)cc3-c3cccc4ccccc34)cccc21]

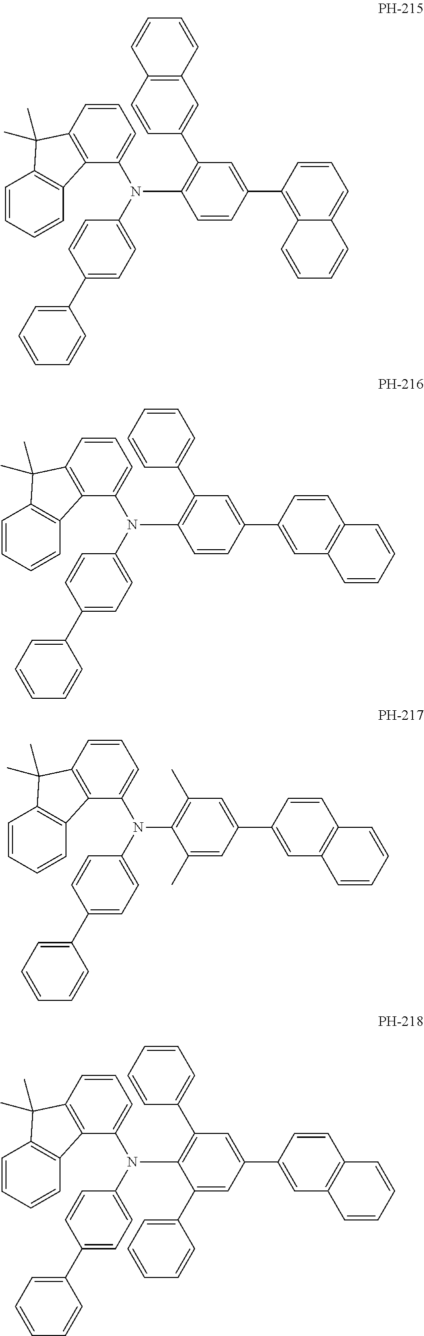

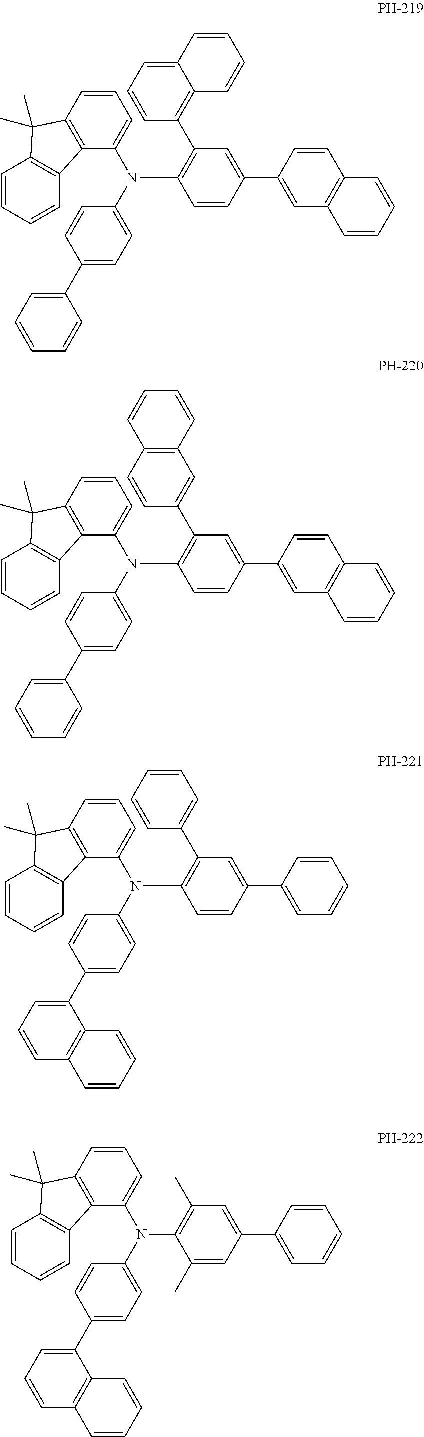 [SMILES: CC1(C)c2ccccc2-c2c(N(c3ccc(-c4ccccc4)cc3)c3ccc(-c4ccc5ccccc5c4)cc3-c3cccc4ccccc34)cccc21 ; CC1(C)c2ccccc2-c2c(N(c3ccc(-c4ccccc4)cc3)c3ccc(-c4ccc5ccccc5c4)cc3-c3ccc4ccccc4c3)cccc21 ; CC1(C)c2ccccc2-c2c(N(c3ccc(-c4cccc5ccccc45)cc3)c3ccc(-c4ccccc4)cc3-c3ccccc3)cccc21 ; Cc1cc(-c2ccccc2)cc(C)c1N(c1ccc(-c2cccc3ccccc23)cc1)c1cccc2c1-c1ccccc1C2(C)C]

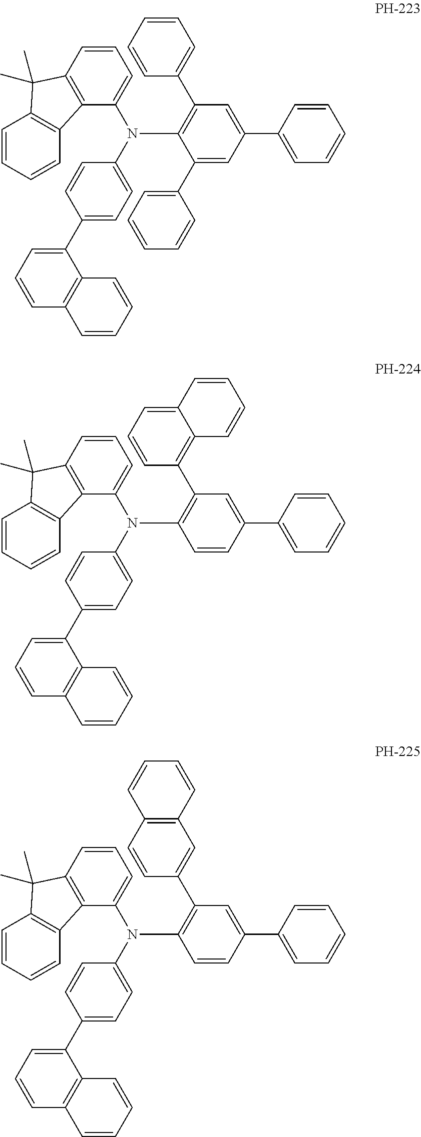

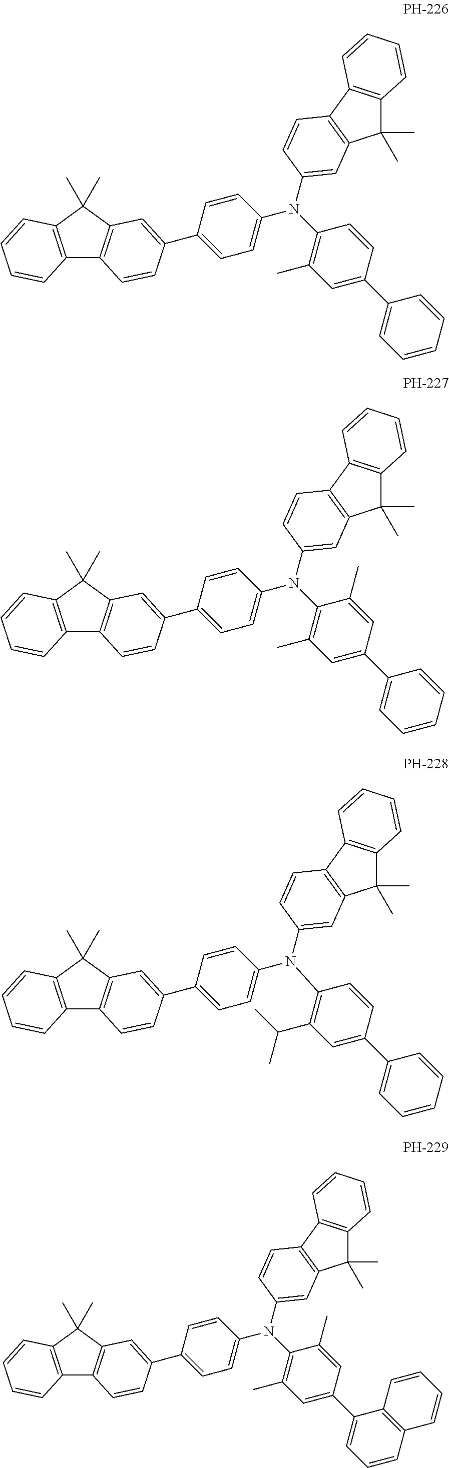 [SMILES: Cc1cc(-c2ccccc2)ccc1N(c1ccc(-c2ccc3c(c2)C(C)(C)c2ccccc2-3)cc1)c1ccc2c(c1)C(C)(C)c1ccccc1-2 ; Cc1cc(-c2ccccc2)cc(C)c1N(c1ccc(-c2ccc3c(c2)C(C)(C)c2ccccc2-3)cc1)c1ccc2c(c1)C(C)(C)c1ccccc1-2 ; CC(C)c1cc(-c2ccccc2)ccc1N(c1ccc(-c2ccc3c(c2)C(C)(C)c2ccccc2-3)cc1)c1ccc2c(c1)C(C)(C)c1ccccc1-2 ; Cc1cc(-c2cccc3ccccc23)cc(C)c1N(c1ccc(-c2ccc3c(c2)C(C)(C)c2ccccc2-3)cc1)c1ccc2c(c1)C(C)(C)c1ccccc1-2]

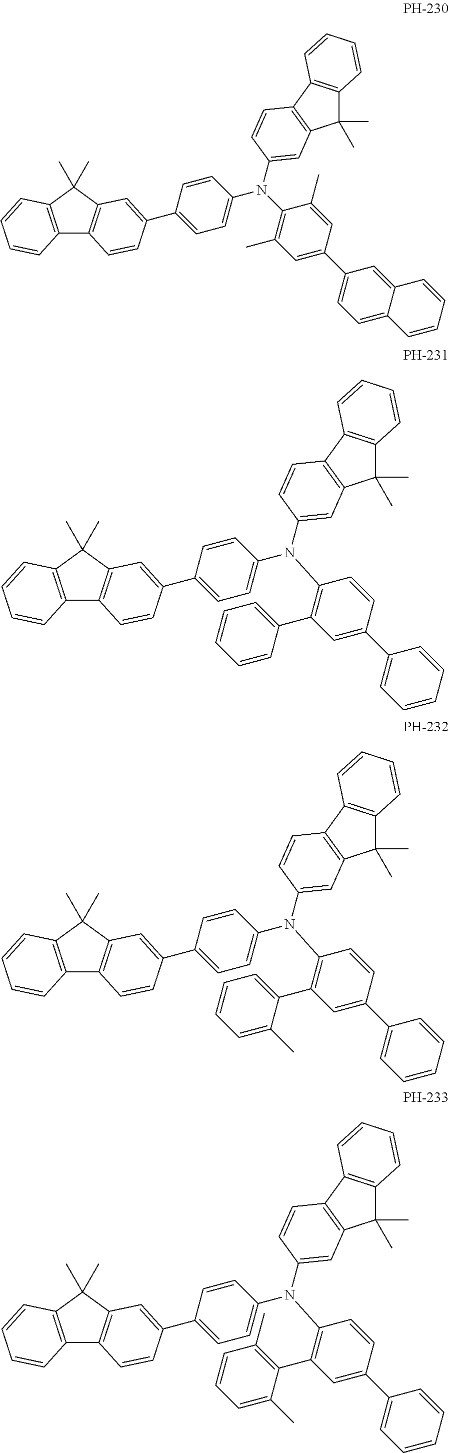 [SMILES: Cc1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4ccc(-c5ccccc5)cc4-c4ccccc4)cc3)cc21 ; Cc1ccccc1-c1cc(-c2ccccc2)ccc1N(c1ccc(-c2ccc3c(c2)C(C)(C)c2ccccc2-3)cc1)c1ccc2c(c1)C(C)(C)c1ccccc1-2 ; Cc1cccc(C)c1-c1cc(-c2ccccc2)ccc1N(c1ccc(-c2ccc3c(c2)C(C)(C)c2ccccc2-3)cc1)c1ccc2c(c1)C(C)(C)c1ccccc1-2]

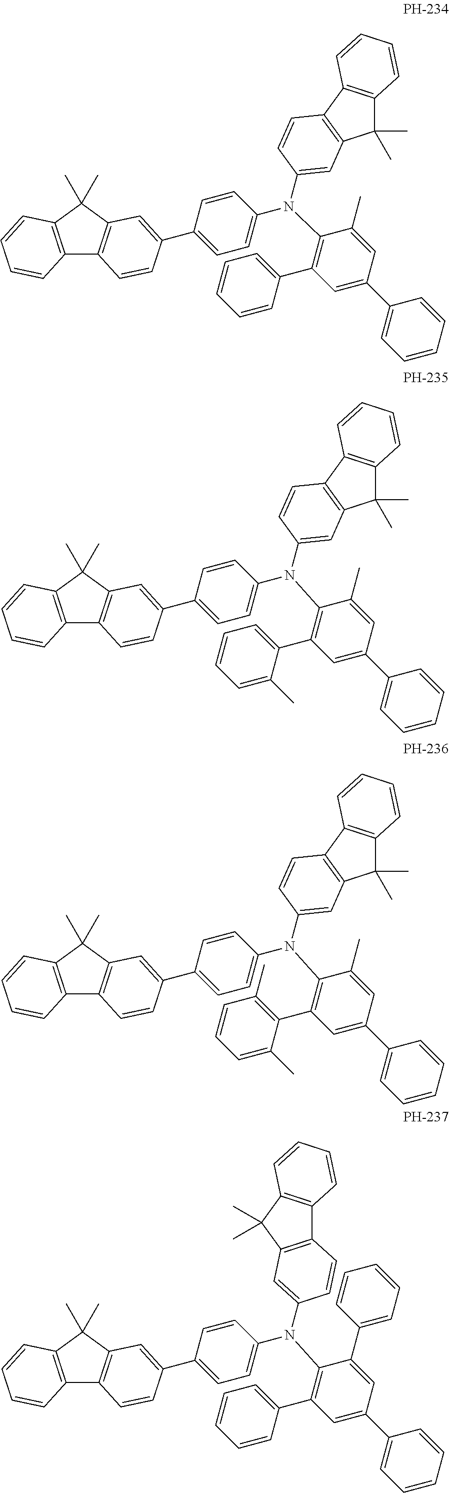 [SMILES: Cc1cc(-c2ccccc2)cc(-c2ccccc2)c1N(c1ccc(-c2ccc3c(c2)C(C)(C)c2ccccc2-3)cc1)c1ccc2c(c1)C(C)(C)c1ccccc1-2 ; Cc1ccccc1-c1cc(-c2ccccc2)cc(C)c1N(c1ccc(-c2ccc3c(c2)C(C)(C)c2ccccc2-3)cc1)c1ccc2c(c1)C(C)(C)c1ccccc1-2 ; Cc1cccc(C)c1-c1cc(-c2ccccc2)cc(C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccccc5)cc4-c4ccccc4)cc3)cc21]

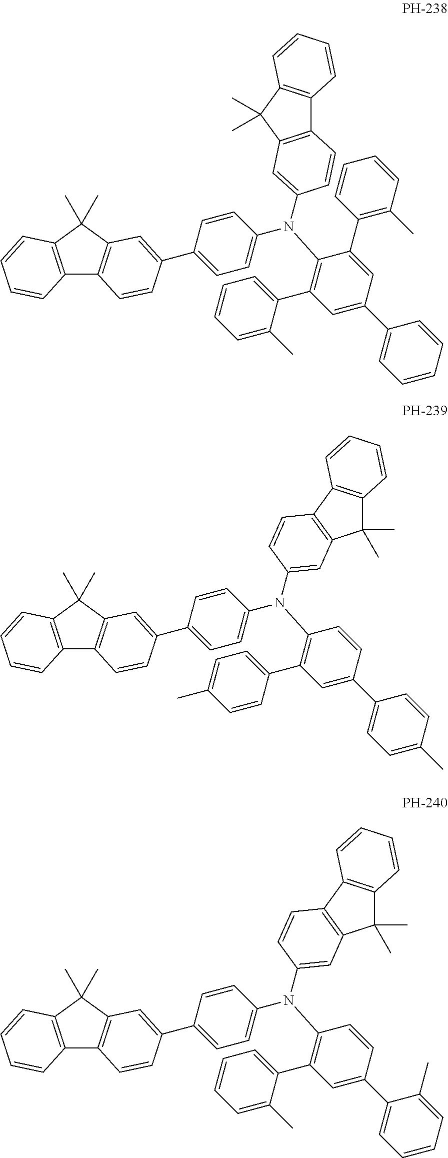 [SMILES: Cc1ccccc1-c1cc(-c2ccccc2)cc(-c2ccccc2C)c1N(c1ccc(-c2ccc3c(c2)C(C)(C)c2ccccc2-3)cc1)c1ccc2c(c1)C(C)(C)c1ccccc1-2 ; Cc1ccc(-c2ccc(N(c3ccc(-c4ccc5c(c4)C(C)(C)c4ccccc4-5)cc3)c3ccc4c(c3)C(C)(C)c3ccccc3-4)c(-c3ccc(C)cc3)c2)cc1 ; Cc1ccccc1-c1ccc(N(c2ccc(-c3ccc4c(c3)C(C)(C)c3ccccc3-4)cc2)c2ccc3c(c2)C(C)(C)c2ccccc2-3)c(-c2ccccc2C)c1]

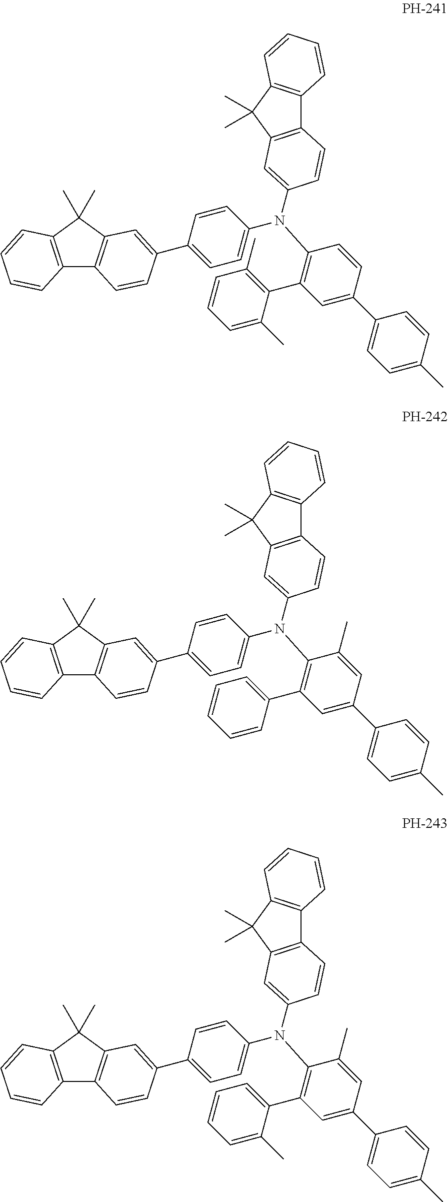 [SMILES: Cc1ccc(-c2ccc(N(c3ccc(-c4ccc5c(c4)C(C)(C)c4ccccc4-5)cc3)c3ccc4c(c3)C(C)(C)c3ccccc3-4)c(-c3c(C)cccc3C)c2)cc1 ; Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3ccccc3)c2)cc1 ; Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3ccccc3C)c2)cc1]

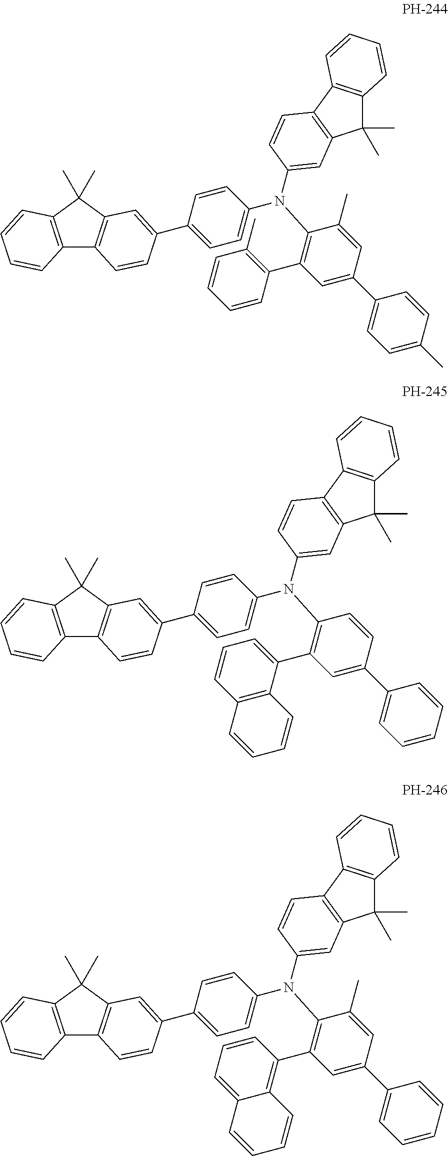 [SMILES: Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3ccccc3C)c2)cc1 ; CC1(C)c2ccccc2-c2ccc(-c3ccc(N(c4ccc5c(c4)C(C)(C)c4ccccc4-5)c4ccc(-c5ccccc5)cc4-c4cccc5ccccc45)cc3)cc21 ; Cc1cc(-c2ccccc2)cc(-c2cccc3ccccc23)c1N(c1ccc(-c2ccc3c(c2)C(C)(C)c2ccccc2-3)cc1)c1ccc2c(c1)C(C)(C)c1ccccc1-2]

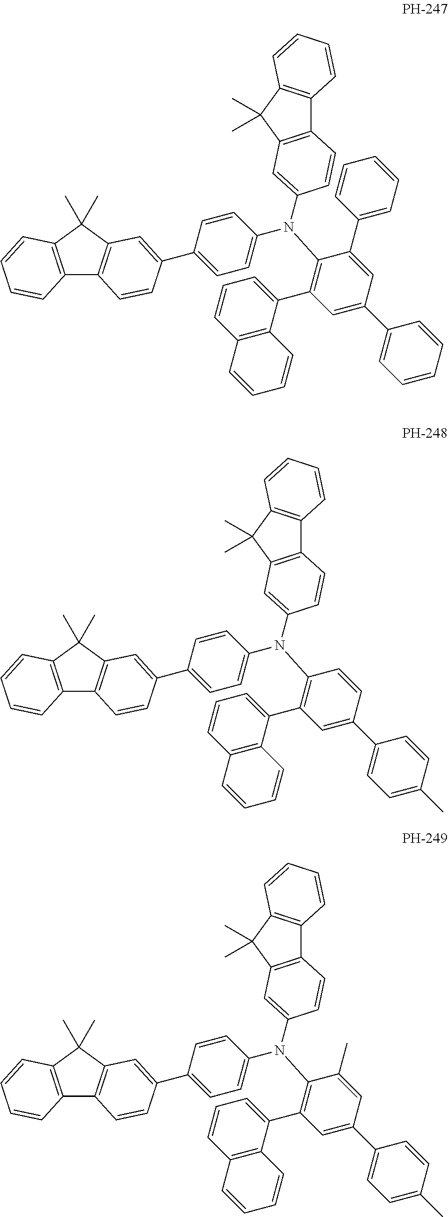 [SMILES: CC1(C)c2ccccc2-c2ccc(-c3ccc(N(c4ccc5c(c4)C(C)(C)c4ccccc4-5)c4c(-c5ccccc5)cc(-c5ccccc5)cc4-c4cccc5ccccc45)cc3)cc21 ; Cc1ccc(-c2ccc(N(c3ccc(-c4ccc5c(c4)C(C)(C)c4ccccc4-5)cc3)c3ccc4c(c3)C(C)(C)c3ccccc3-4)c(-c3cccc4ccccc34)c2)cc1 ; Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3cccc4ccccc34)c2)cc1]

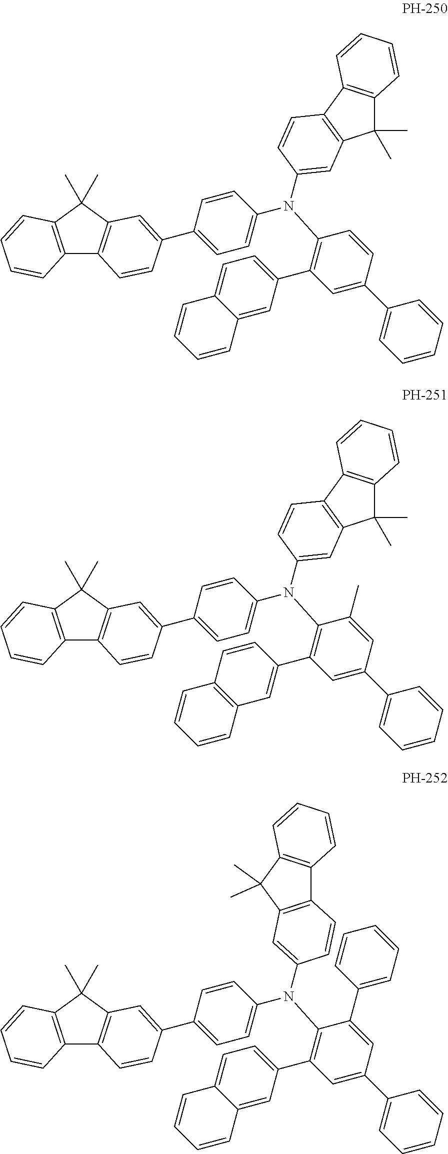 [SMILES: CC1(C)c2ccccc2-c2ccc(-c3ccc(N(c4ccc5c(c4)C(C)(C)c4ccccc4-5)c4ccc(-c5ccccc5)cc4-c4ccc5ccccc5c4)cc3)cc21 ; Cc1cc(-c2ccccc2)cc(-c2ccc3ccccc3c2)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccccc5)cc4-c4ccc5ccccc5c4)cc3)cc21]

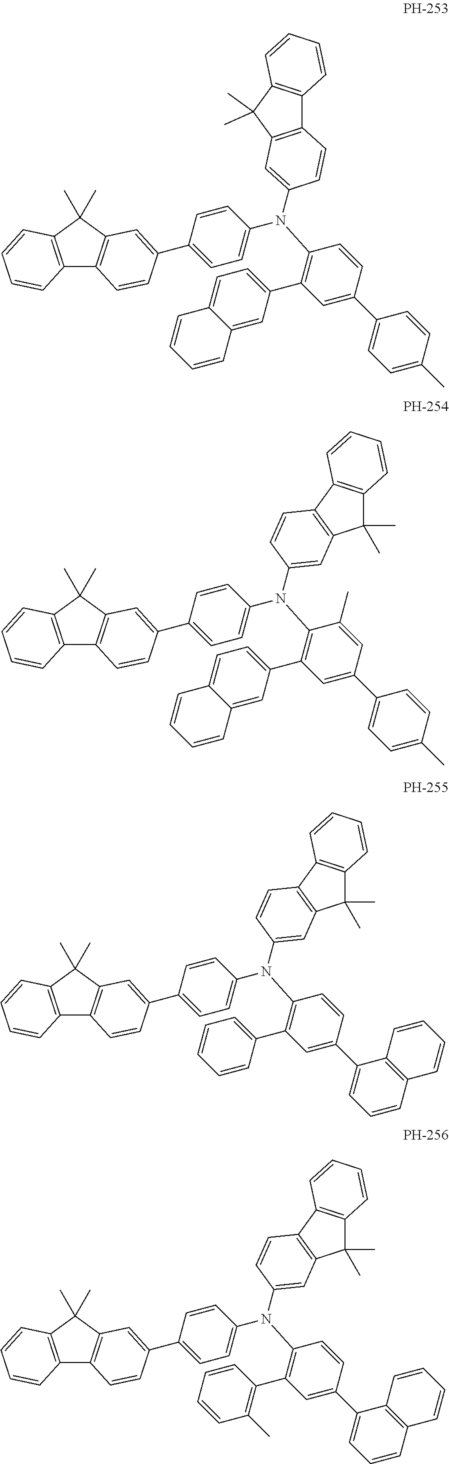 [SMILES: Cc1ccc(-c2ccc(N(c3ccc(-c4ccc5c(c4)C(C)(C)c4ccccc4-5)cc3)c3ccc4c(c3)C(C)(C)c3ccccc3-4)c(-c3ccc4ccccc4c3)c2)cc1 ; Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3ccc4ccccc4c3)c2)cc1 ; CC1(C)c2ccccc2-c2ccc(-c3ccc(N(c4ccc5c(c4)C(C)(C)c4ccccc4-5)c4ccc(-c5cccc6ccccc56)cc4-c4ccccc4)cc3)cc21 ; Cc1ccccc1-c1cc(-c2cccc3ccccc23)ccc1N(c1ccc(-c2ccc3c(c2)C(C)(C)c2ccccc2-3)cc1)c1ccc2c(c1)C(C)(C)c1ccccc1-2]

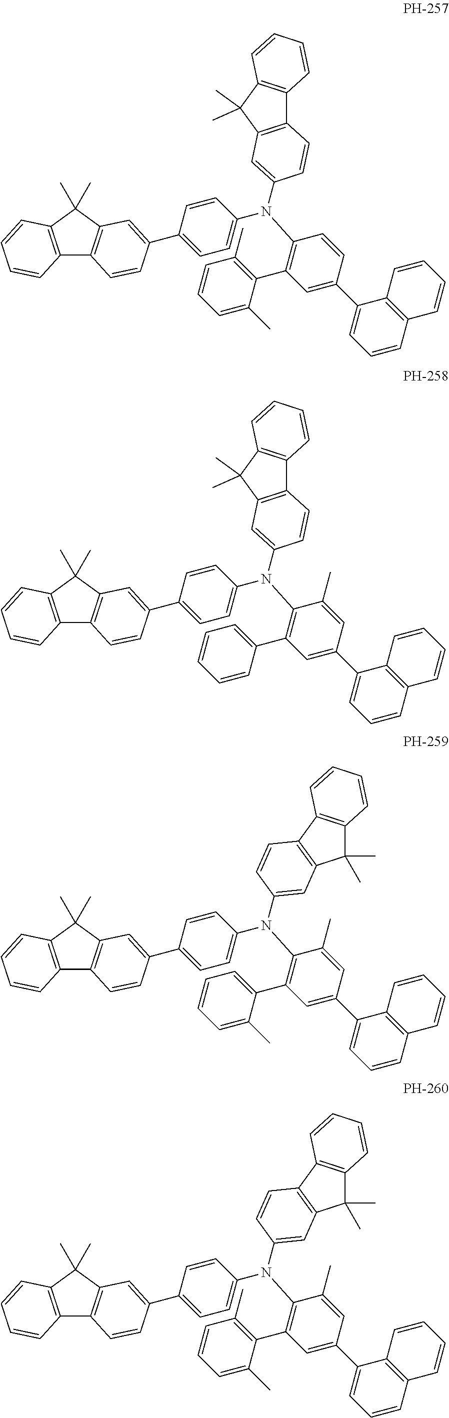 [SMILES: Cc1cccc(C)c1-c1cc(-c2cccc3ccccc23)ccc1N(c1ccc(-c2ccc3c(c2)C(C)(C)c2ccccc2-3)cc1)c1ccc2c(c1)C(C)(C)c1ccccc1-2 ; Cc1cc(-c2cccc3ccccc23)cc(-c2ccccc2)c1N(c1ccc(-c2ccc3c(c2)C(C)(C)c2ccccc2-3)cc1)c1ccc2c(c1)C(C)(C)c1ccccc1-2 ; Cc1ccccc1-c1cc(-c2cccc3ccccc23)cc(C)c1N(c1ccc(-c2ccc3c(c2)C(C)(C)c2ccccc2-3)cc1)c1ccc2c(c1)C(C)(C)c1ccccc1-2 ; Cc1cccc(C)c1-c1cc(-c2cccc3ccccc23)cc(C)c1N(c1ccc(-c2ccc3c(c2)C(C)(C)c2ccccc2-3)cc1)c1ccc2c(c1)C(C)(C)c1ccccc1-2]

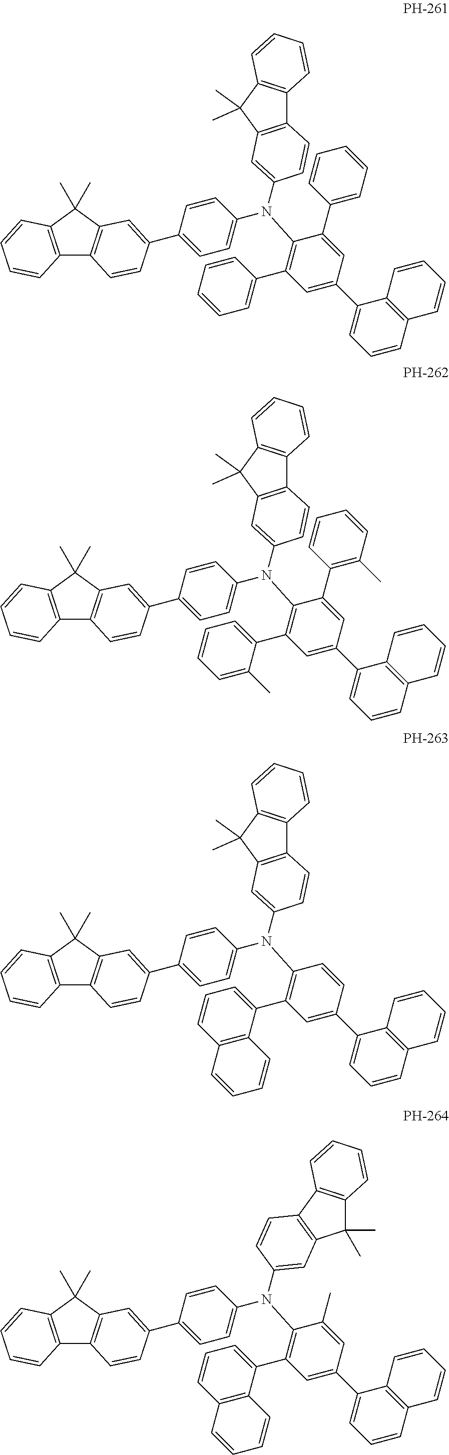 [SMILES: CC1(C)c2ccccc2-c2ccc(-c3ccc(N(c4ccc5c(c4)C(C)(C)c4ccccc4-5)c4c(-c5ccccc5)cc(-c5cccc6ccccc56)cc4-c4ccccc4)cc3)cc21 ; Cc1ccccc1-c1cc(-c2cccc3ccccc23)cc(-c2ccccc2C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4ccc(-c5cccc6ccccc56)cc4-c4cccc5ccccc45)cc3)cc21 ; Cc1cc(-c2cccc3ccccc23)cc(-c2cccc3ccccc23)c1N(c1ccc(-c2ccc3c(c2)C(C)(C)c2ccccc2-3)cc1)c1ccc2c(c1)C(C)(C)c1ccccc1-2]

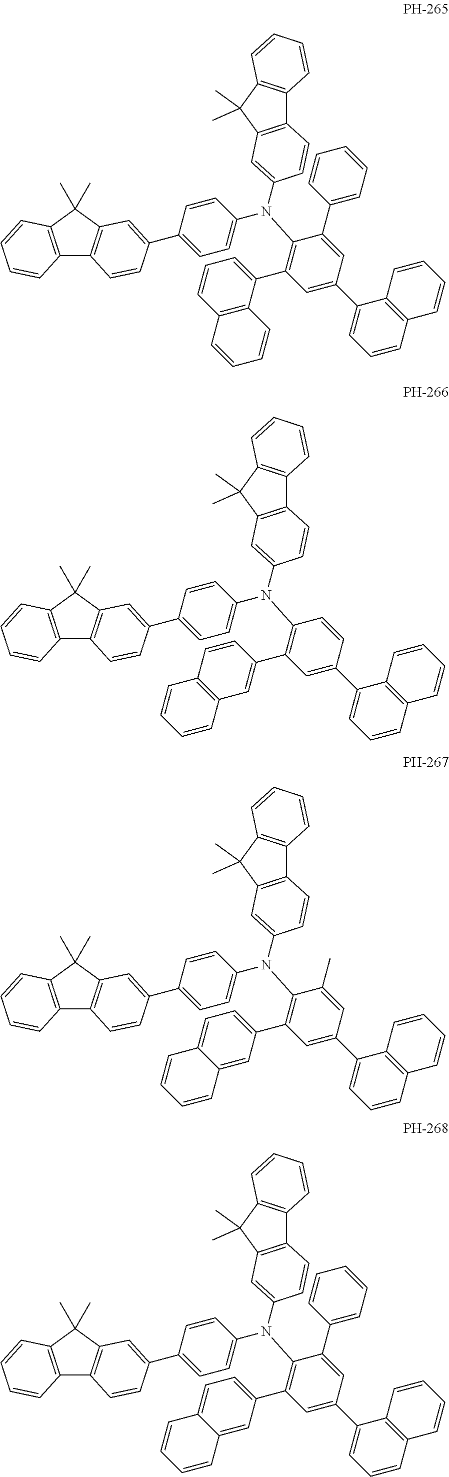 [SMILES: CC1(C)c2ccccc2-c2ccc(-c3ccc(N(c4ccc5c(c4)C(C)(C)c4ccccc4-5)c4c(-c5ccccc5)cc(-c5cccc6ccccc56)cc4-c4cccc5ccccc45)cc3)cc21 ; CC1(C)c2ccccc2-c2ccc(-c3ccc(N(c4ccc5c(c4)C(C)(C)c4ccccc4-5)c4ccc(-c5cccc6ccccc56)cc4-c4ccc5ccccc5c4)cc3)cc21 ; Cc1cc(-c2cccc3ccccc23)cc(-c2ccc3ccccc3c2)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5cccc6ccccc56)cc4-c4ccc5ccccc5c4)cc3)cc21]

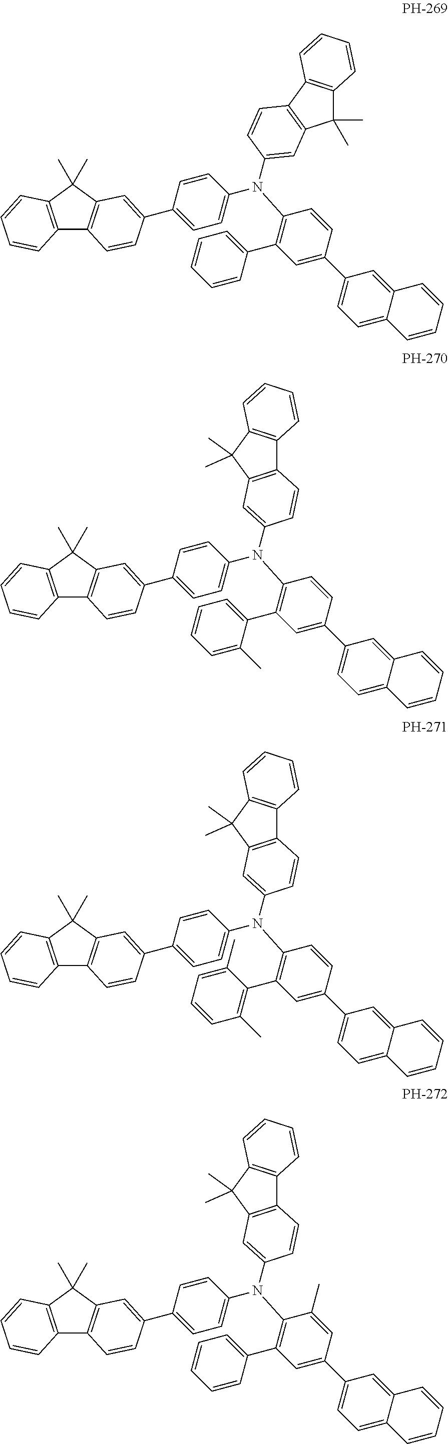 [SMILES: CC1(C)c2ccccc2-c2ccc(-c3ccc(N(c4ccc5c(c4)C(C)(C)c4ccccc4-5)c4ccc(-c5ccc6ccccc6c5)cc4-c4ccccc4)cc3)cc21 ; Cc1ccccc1-c1cc(-c2ccc3ccccc3c2)ccc1N(c1ccc(-c2ccc3c(c2)C(C)(C)c2ccccc2-3)cc1)c1ccc2c(c1)C(C)(C)c1ccccc1-2 ; Cc1cccc(C)c1-c1cc(-c2ccc3ccccc3c2)ccc1N(c1ccc(-c2ccc3c(c2)C(C)(C)c2ccccc2-3)cc1)c1ccc2c(c1)C(C)(C)c1ccccc1-2 ; Cc1cc(-c2ccc3ccccc3c2)cc(-c2ccccc2)c1N(c1ccc(-c2ccc3c(c2)C(C)(C)c2ccccc2-3)cc1)c1ccc2c(c1)C(C)(C)c1ccccc1-2]

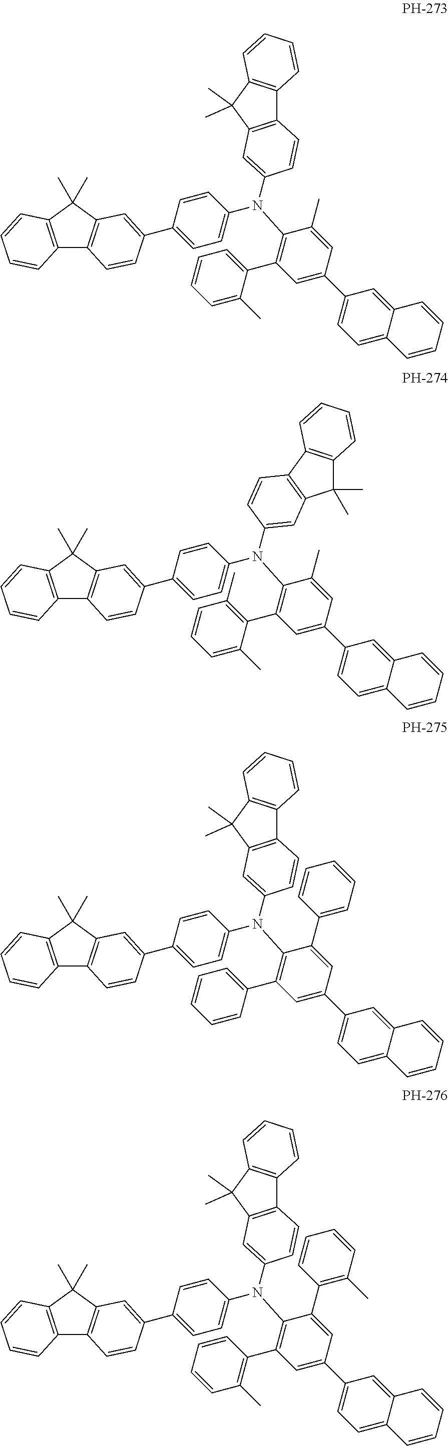 [SMILES: Cc1ccccc1-c1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2 ; Cc1cccc(C)c1-c1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4ccccc4)cc3)cc21 ; Cc1ccccc1-c1cc(-c2ccc3ccccc3c2)cc(-c2ccccc2C)c1N(c1ccc(-c2ccc3c(c2)C(C)(C)c2ccccc2-3)cc1)c1ccc2c(c1)C(C)(C)c1ccccc1-2]

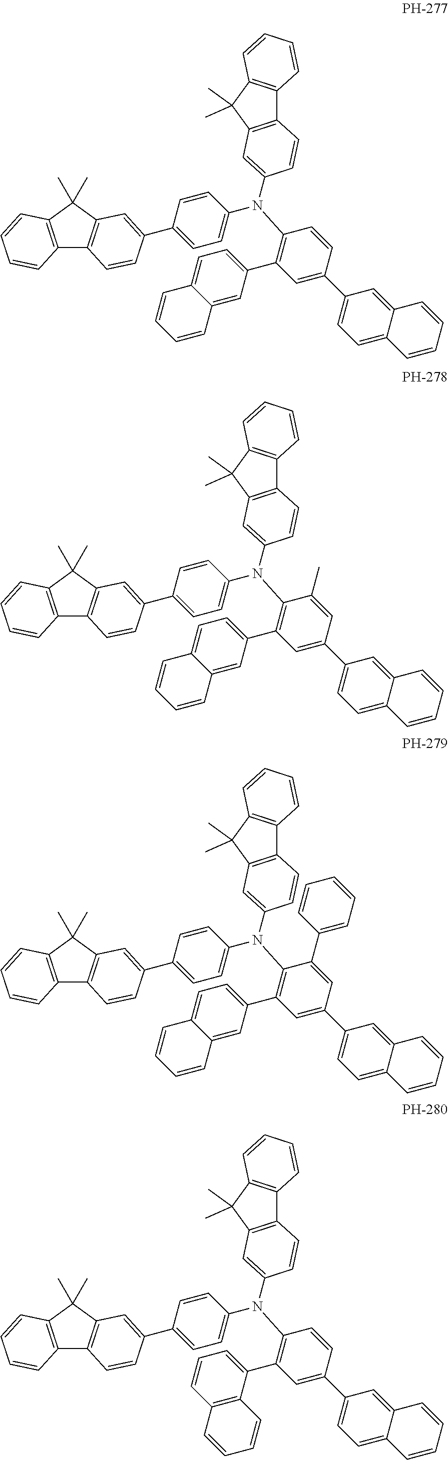 [SMILES: CC1(C)c2ccccc2-c2ccc(-c3ccc(N(c4ccc5c(c4)C(C)(C)c4ccccc4-5)c4ccc(-c5ccc6ccccc6c5)cc4-c4ccc5ccccc5c4)cc3)cc21 ; Cc1cc(-c2ccc3ccccc3c2)cc(-c2ccc3ccccc3c2)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4ccc5ccccc5c4)cc3)cc21 ; CC1(C)c2ccccc2-c2ccc(-c3ccc(N(c4ccc5c(c4)C(C)(C)c4ccccc4-5)c4ccc(-c5ccc6ccccc6c5)cc4-c4cccc5ccccc45)cc3)cc21]

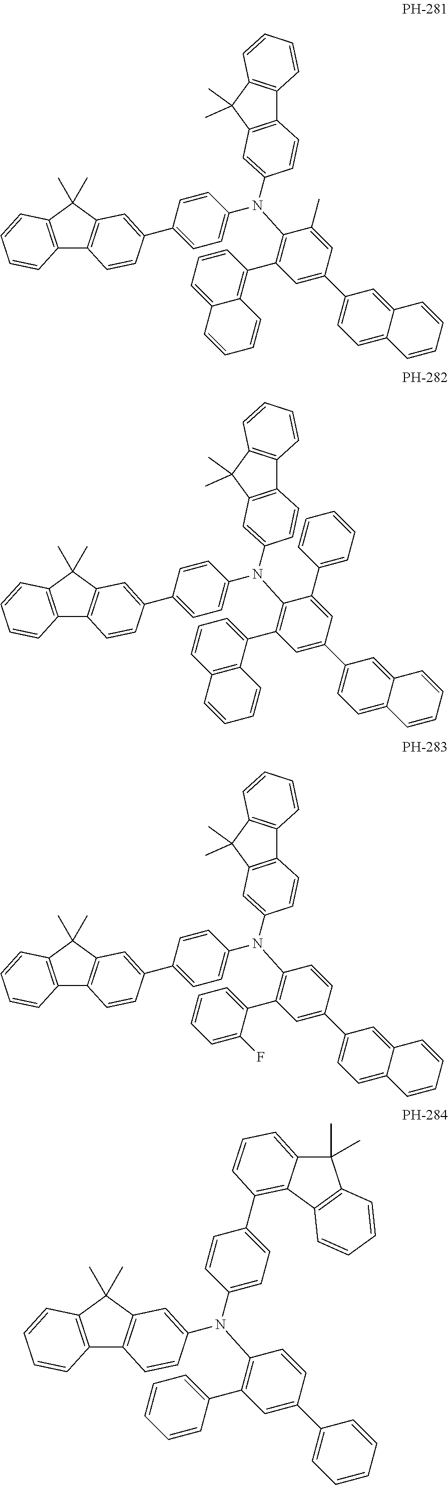 [SMILES: Cc1cc(-c2ccc3ccccc3c2)cc(-c2cccc3ccccc23)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4cccc5ccccc45)cc3)cc21 ; CC1(C)c2ccccc2-c2ccc(-c3ccc(N(c4ccc5c(c4)C(C)(C)c4ccccc4-5)c4ccc(-c5ccc6ccccc6c5)cc4-c4ccccc4F)cc3)cc21 ; CC1(C)c2ccccc2-c2ccc(N(c3ccc(-c4cccc5c4-c4ccccc4C5(C)C)cc3)c3ccc(-c4ccccc4)cc3-c3ccccc3)cc21]

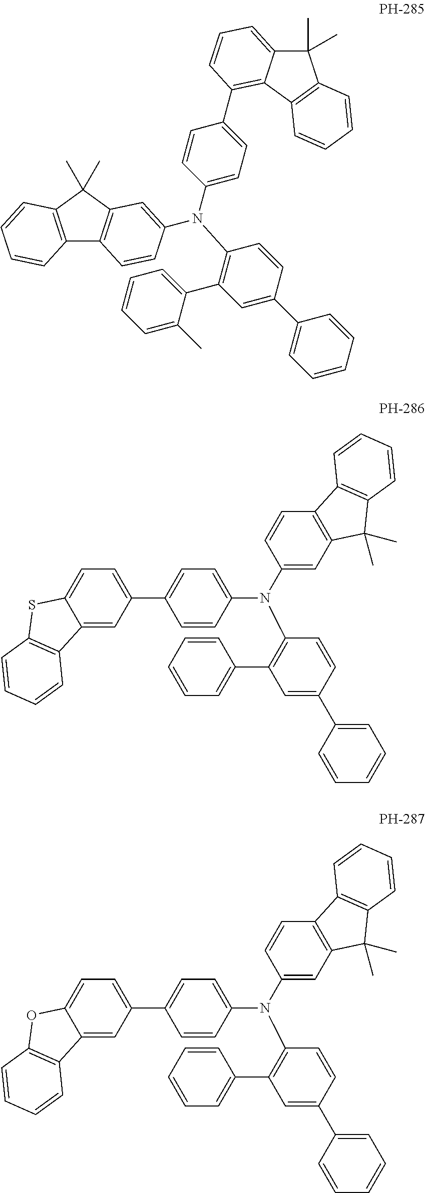 [SMILES: Cc1ccccc1-c1cc(-c2ccccc2)ccc1N(c1ccc(-c2cccc3c2-c2ccccc2C3(C)C)cc1)c1ccc2c(c1)C(C)(C)c1ccccc1-2 ; CC1(C)c2ccccc2-c2ccc(N(c3ccc(-c4ccc5sc6ccccc6c5c4)cc3)c3ccc(-c4ccccc4)cc3-c3ccccc3)cc21 ; CC1(C)c2ccccc2-c2ccc(N(c3ccc(-c4ccc5oc6ccccc6c5c4)cc3)c3ccc(-c4ccccc4)cc3-c3ccccc3)cc21]

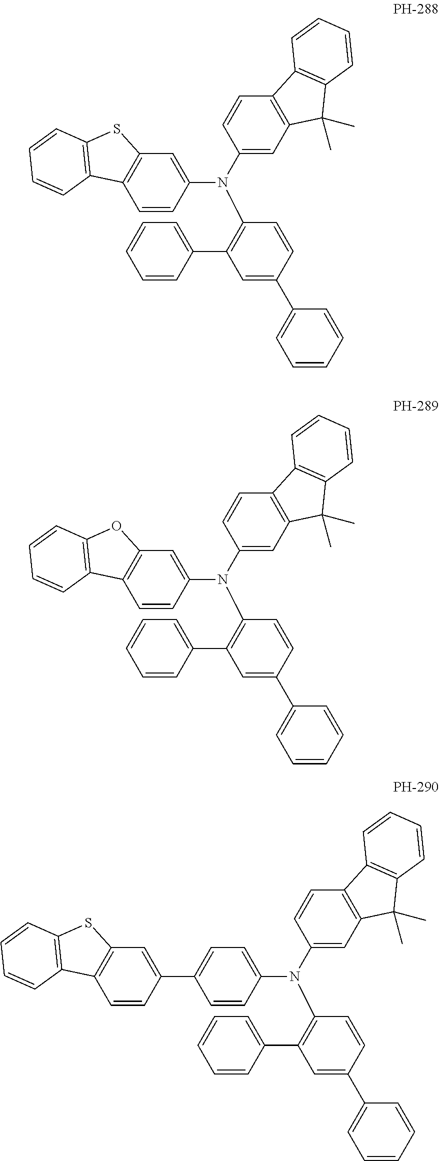 [SMILES: CC1(C)c2ccccc2-c2ccc(N(c3ccc4c(c3)sc3ccccc34)c3ccc(-c4ccccc4)cc3-c3ccccc3)cc21 ; CC1(C)c2ccccc2-c2ccc(N(c3ccc4c(c3)oc3ccccc34)c3ccc(-c4ccccc4)cc3-c3ccccc3)cc21 ; CC1(C)c2ccccc2-c2ccc(N(c3ccc(-c4ccc5c(c4)sc4ccccc45)cc3)c3ccc(-c4ccccc4)cc3-c3ccccc3)cc21]

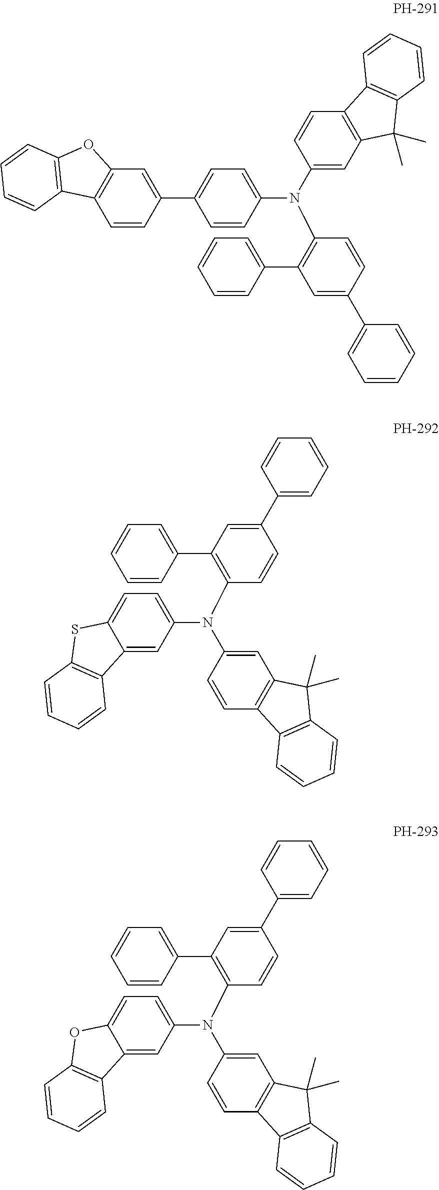 [SMILES: CC1(C)c2ccccc2-c2ccc(N(c3ccc(-c4ccc5c(c4)oc4ccccc45)cc3)c3ccc(-c4ccccc4)cc3-c3ccccc3)cc21 ; CC1(C)c2ccccc2-c2ccc(N(c3ccc4sc5ccccc5c4c3)c3ccc(-c4ccccc4)cc3-c3ccccc3)cc21 ; CC1(C)c2ccccc2-c2ccc(N(c3ccc4oc5ccccc5c4c3)c3ccc(-c4ccccc4)cc3-c3ccccc3)cc21]

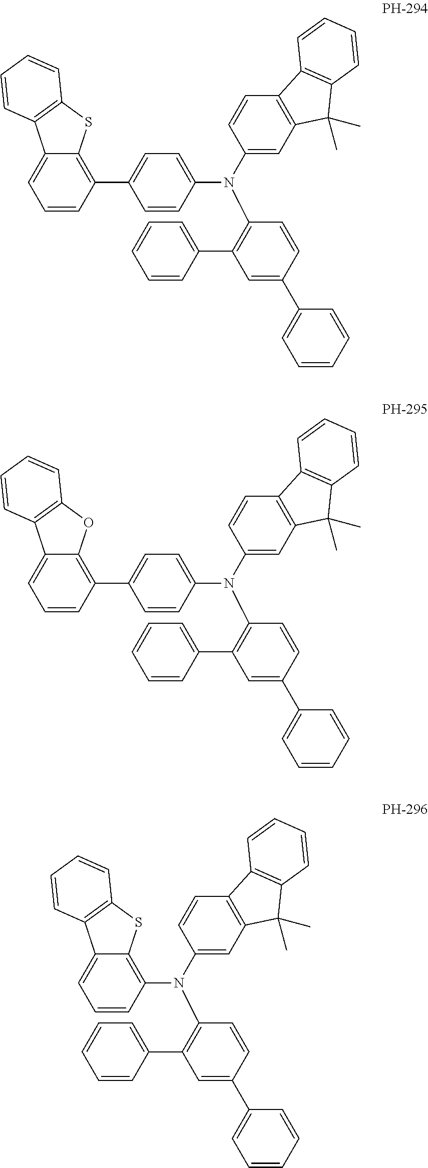 [SMILES: CC1(C)c2ccccc2-c2ccc(N(c3ccc(-c4cccc5c4sc4ccccc45)cc3)c3ccc(-c4ccccc4)cc3-c3ccccc3)cc21 ; CC1(C)c2ccccc2-c2ccc(N(c3ccc(-c4cccc5c4oc4ccccc45)cc3)c3ccc(-c4ccccc4)cc3-c3ccccc3)cc21 ; CC1(C)c2ccccc2-c2ccc(N(c3ccc(-c4ccccc4)cc3-c3ccccc3)c3cccc4c3sc3ccccc34)cc21]

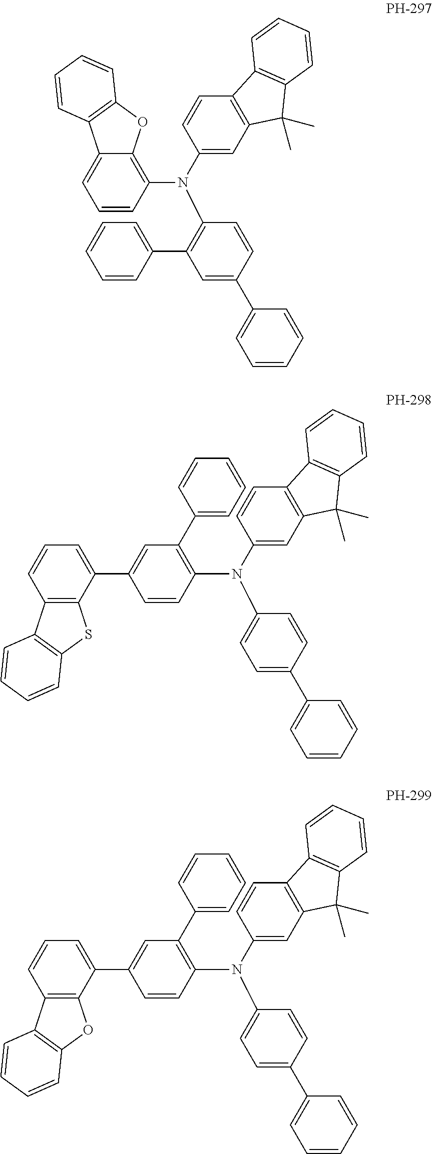 [SMILES: CC1(C)c2ccccc2-c2ccc(N(c3ccc(-c4ccccc4)cc3-c3ccccc3)c3cccc4c3oc3ccccc34)cc21 ; CC1(C)c2ccccc2-c2ccc(N(c3ccc(-c4ccccc4)cc3)c3ccc(-c4cccc5c4sc4ccccc45)cc3-c3ccccc3)cc21 ; CC1(C)c2ccccc2-c2ccc(N(c3ccc(-c4ccccc4)cc3)c3ccc(-c4cccc5c4oc4ccccc45)cc3-c3ccccc3)cc21]

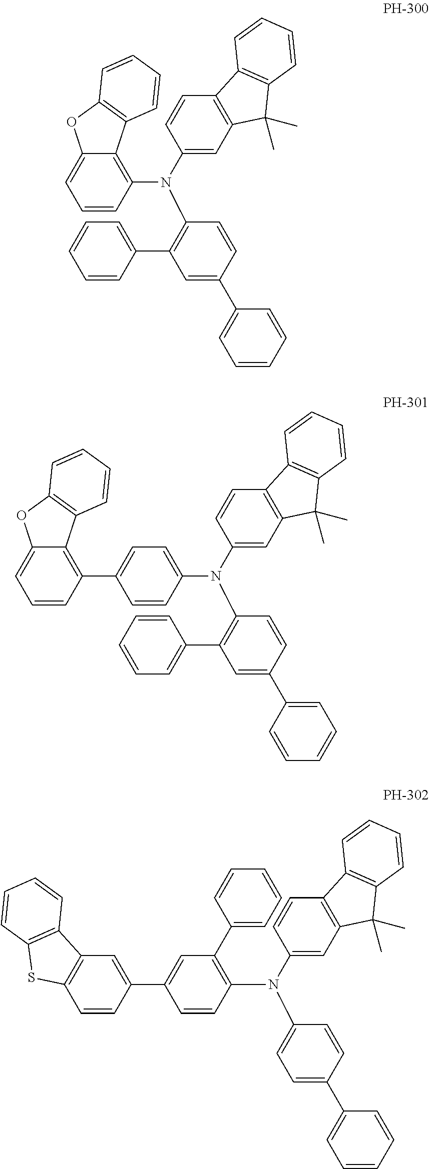 [SMILES: CC1(C)c2ccccc2-c2ccc(N(c3ccc(-c4ccccc4)cc3-c3ccccc3)c3cccc4oc5ccccc5c34)cc21 ; CC1(C)c2ccccc2-c2ccc(N(c3ccc(-c4cccc5oc6ccccc6c45)cc3)c3ccc(-c4ccccc4)cc3-c3ccccc3)cc21 ; CC1(C)c2ccccc2-c2ccc(N(c3ccc(-c4ccccc4)cc3)c3ccc(-c4ccc5sc6ccccc6c5c4)cc3-c3ccccc3)cc21]

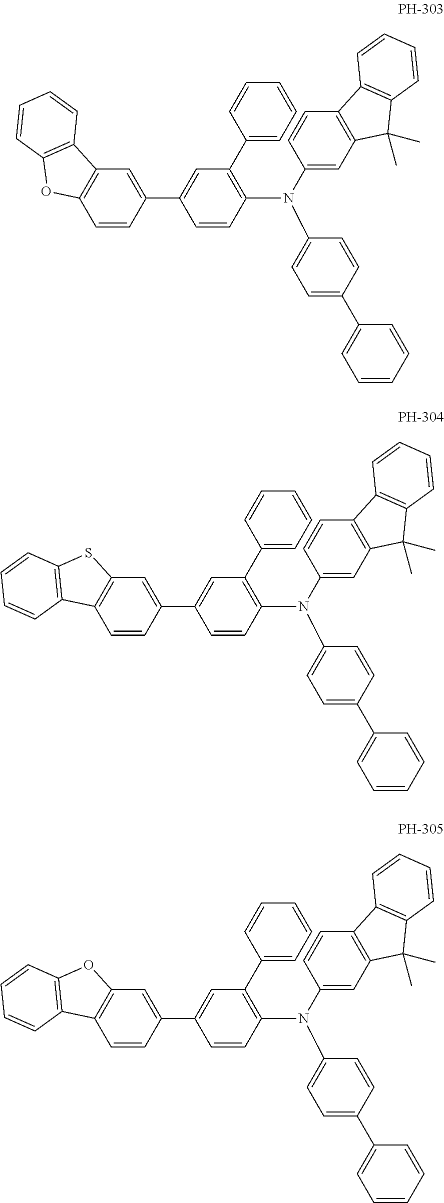 [SMILES: CC1(C)c2ccccc2-c2ccc(N(c3ccc(-c4ccccc4)cc3)c3ccc(-c4ccc5oc6ccccc6c5c4)cc3-c3ccccc3)cc21 ; CC1(C)c2ccccc2-c2ccc(N(c3ccc(-c4ccccc4)cc3)c3ccc(-c4ccc5c(c4)sc4ccccc45)cc3-c3ccccc3)cc21 ; CC1(C)c2ccccc2-c2ccc(N(c3ccc(-c4ccccc4)cc3)c3ccc(-c4ccc5c(c4)oc4ccccc45)cc3-c3ccccc3)cc21]

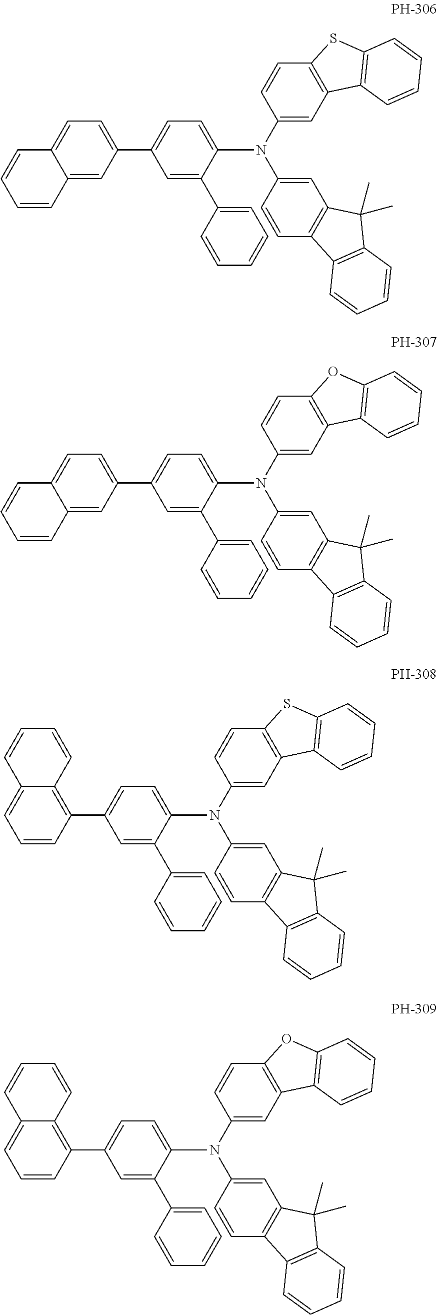 [SMILES: CC1(C)c2ccccc2-c2ccc(N(c3ccc4sc5ccccc5c4c3)c3ccc(-c4ccc5ccccc5c4)cc3-c3ccccc3)cc21 ; CC1(C)c2ccccc2-c2ccc(N(c3ccc4oc5ccccc5c4c3)c3ccc(-c4ccc5ccccc5c4)cc3-c3ccccc3)cc21 ; CC1(C)c2ccccc2-c2ccc(N(c3ccc4sc5ccccc5c4c3)c3ccc(-c4cccc5ccccc45)cc3-c3ccccc3)cc21 ; CC1(C)c2ccccc2-c2ccc(N(c3ccc4oc5ccccc5c4c3)c3ccc(-c4cccc5ccccc45)cc3-c3ccccc3)cc21]

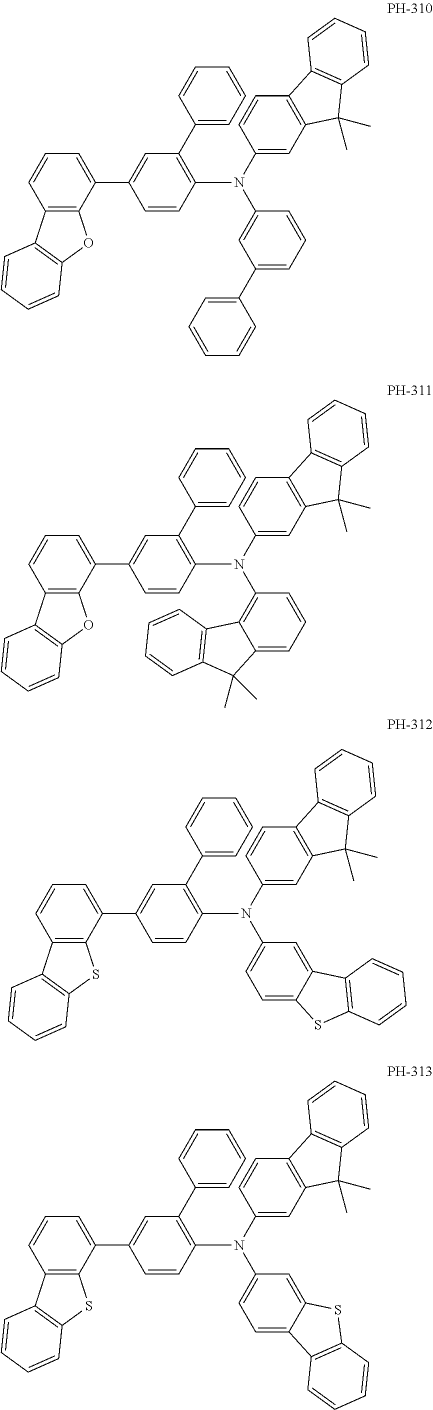 [SMILES: CC1(C)c2ccccc2-c2ccc(N(c3cccc(-c4ccccc4)c3)c3ccc(-c4cccc5c4oc4ccccc45)cc3-c3ccccc3)cc21 ; CC1(C)c2ccccc2-c2ccc(N(c3ccc(-c4cccc5c4oc4ccccc45)cc3-c3ccccc3)c3cccc4c3-c3ccccc3C4(C)C)cc21 ; CC1(C)c2ccccc2-c2ccc(N(c3ccc4sc5ccccc5c4c3)c3ccc(-c4cccc5c4sc4ccccc45)cc3-c3ccccc3)cc21 ; CC1(C)c2ccccc2-c2ccc(N(c3ccc4c(c3)sc3ccccc34)c3ccc(-c4cccc5c4sc4ccccc45)cc3-c3ccccc3)cc21]

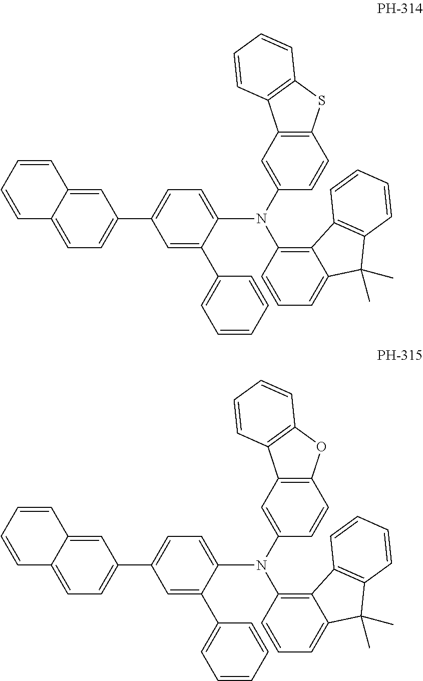 [SMILES: CC1(C)c2ccccc2-c2c(N(c3ccc4sc5ccccc5c4c3)c3ccc(-c4ccc5ccccc5c4)cc3-c3ccccc3)cccc21 ; CC1(C)c2ccccc2-c2c(N(c3ccc4oc5ccccc5c4c3)c3ccc(-c4ccc5ccccc5c4)cc3-c3ccccc3)cccc21]

The anode 100A may include, but is not limited to, materials such as indium tin oxide (ITO), indium zine oxide (IZO), tin oxide (SnO₂), and zine oxide (ZnO), which are transparent, have a relatively large work function value, and have excellent conductivity.

The cathode 100B may include materials such as lithium (Li), aluminum (Al), aluminum-lithium (Al—Li), calcium (Ca), magnesium (Mg), magnesium-indium (Mg—In), and magnesium-silver (Mg—Ag). Further, in the case of a top-emitting organic light-emitting device, a transparent cathode that allows light to transmit may be formed using indium tin oxide (ITO) or indium zine oxide (IZO), but is not limited thereto. In order to prevent external moisture or the like from penetrating the organic light-emitting device, a capping layer (CPL) and/or a protecting layer (or an encapsulation layer or seal cap) formed on top of the cathode of the organic light-emitting device may be further included.

The hole transfer layer 300 is disposed between the anode 100A and the emission material layer 400. The hole transfer layer 300 of the present disclosure should be formed of a material having excellent hole transfer properties. For example, the hole transfer layer 300 may contain a phthalocyanine derivative, a porphyrin derivative, a triarylamine derivative, or an indolocarbazole derivative. For example, it may contain, but is not limited to, 1,4,5,8,9,11-hexaazatriphenylene-hexacarbonitrile (HAT-CN), copper phthalocyanine (CuPc), 4,4′,4″-tris(3-methylphenylamino)triphenylamine (m-MTDATA), 4,4′,4″-tris(3-methylphenylamino)phenoxybenzene (m-MTDAPB), 4,4′,4″-tri(N-carbazolyl)triphenylamine (TCTA), 4,4′,4″-tris(N-(2-naphthyl)-N-phenylamino)-triphenylamine (2-TNATA), N4,N4,N4′,N4′-Tetra([1,1′-biphenyl]-4-yl)-[1,1′-biphenyl]-4,4′-diamine, Bis(N-(1-naphthyl-n-phenyl))benzidine (α-NPD), N,N′-di(naphthalen-1-yl)-N,N′-biphenyl-benzidine (NPB), N,N′-biphenyl-N,N′-bis(3-methylphenyl)-1,1′-biphenyl-4,4′-diamine (TPD), etc.

Although not shown in FIG. 1, an electron-blocking layer (EBL) or a hole-blocking layer (HBL) may be further included in contact with the emission material layer, respectively, in order to increase the efficiency of the emission material layer.

According to the present disclosure, the emission material layer 400 may be formed by being doped with a dopant in order to improve the emission efficiency of the host and the device and the like, and the emission material layer 400 may emit light in blue, green, or red but is not limited thereto, and may be combined with emission material layers of various colors and color coordinates used in organic light-emitting devices. For example, the CIEx coordinate of a blue emission material layer may have a range of 0.01 to 0.15 and the CIEy coordinate may have a range of 0.03 to 0.07, and the CIEx coordinate of a green emission material layer may have a range of 0.19 to 0.32 and the CIEy coordinate may have a range of 0.65 to 0.76.

Dopant materials of the emission material layer and host materials of the emission material layer may be selected according to the selected color of the emission material layer 400 included in the organic light-emitting device of the present disclosure. For example, the doping concentration of the dopant of the emission material layer may be adjusted within a range of 1 to 20 wt % based on the total weight of the host of the emission material layer and is not limited thereto, but may be, for example, 3 to 15 wt %, for example, 5 to 10 wt %, for example, 3 to 8 wt %, for example, 2 to 7 wt %, but is not limited thereto.

For example, the host of the emission material layer 400 may include, but is not limited to, 9,10-Bis(2-naphthyl)anthracene (ADN), CBP (carbazole biphenyl), mCP (1,3-bis(carbazol-9-yl), and the like, which are common materials used in the art.

For example, the dopant of the emission material layer 400 may include, but is not limited to, N1,N1,N6,N6-tetrakis(4-(1-silyl)phenyl)pyrene-1,6-diamine, iridium complex metal compounds (e.g., Ir(ppy)₃), and the like, which are common materials used in the art.

In addition, the electron transfer layer 500 and the electron injection layer 600 may be stacked in sequence between the emission material layer 400 and the cathode 100B. The material of the electron transfer layer 500 is required to have high electron mobility, and can stably supply electrons to the emission material layer through smooth electron transfer.

For example, the compounds for the electron transfer layer 500 or the electron injection layer 600 are not particularly limited, and any compounds commonly used in the art as compounds for the electron transfer layer 500 or the electron injection layer 600 may be used.

For example, the compounds for forming the electron transfer layer 500 and/or the electron injection layer 600 may each independently include pyridine derivatives, naphthalene derivatives, anthracene derivatives, phenanthroline derivatives, perinone derivatives, coumarin derivatives, naphthalimide derivatives, anthraquinone derivatives, diphenoquinone derivatives, diphenylquinone derivatives, perylene derivatives, oxadiazole derivatives, thiophene derivatives, triazole derivatives, thiadiazole derivatives, metal complexes of oxine derivatives, quinolinol-based metal complexes, quinoxaline derivatives, polymers of quinoxaline derivatives, benzazole compounds, gallium complexes, pyrazole derivatives, perfluorinated phenylene derivatives, triazine derivatives, pyrazine derivatives, benzoquinoline derivatives, imidazopyridine derivatives, borane derivatives, benzimidazole derivatives, benzoxazole derivatives, benzothiazole derivatives, quinoline derivatives, oligopyridine derivatives such as terpyridine, bipyridine derivatives, terpyridine derivatives, naphthyridine derivatives, aldazine derivatives, carbazole derivatives, indole derivatives, phosphine oxide derivatives, bistyryl derivatives, quinolinol-based metal complexes, hydroxyazole-based metal complexes, azomethine-based metal complexes, tropolone-based metal complexes, flavonol-based metal complexes, benzoquinoline-based metal complexes, metal salts, etc. These compounds may be used alone, but may also be mixed and used with other materials. For example, materials such as 2-(4-(9,10-di(naphthalen-2-yl)anthracen-2-yl)phenyl)-1-phenyl-1H-benzo[d]imidazole, tris(8-hydroxyquinolinato)aluminum (Alq₃), LiF, Liq, Li₂O, BaO, NaCl, and CsF may be included, but are not limited thereto.

The organic light-emitting device of the present disclosure may be a white organic light-emitting device having a tandem structure.

The organic light-emitting device may include a plurality of emitting stacks (or emitting parts) including an anode and a cathode opposed to each other on a substrate and an emission material layer stacked between the anode and the cathode and configured to emit light of a particular wavelength band. The plurality of emitting stacks may be adapted to emit the same color or different colors. In addition, one emitting stack may include one or more emission material layers, and may emit the same or different colors if there are two or more emission material layers.

In the case of a tandem organic light-emitting device in accordance with one implementation of the present disclosure, N emitting stacks may be included, N−1 charge generation layers (CGLs) may be disposed between different emitting stacks, thereby forming a structure connected by the charge generation layers, and the N−1 charge generation layers (CGLs) may include N−1 n-type charge generation layers (n-CGLs) and N−1 p-type charge generation layers (p-CGLs). In this case, N is an integer greater than or equal to 2, and for example, N may be one of 2, 3, 4, and 5. According to one example of the present disclosure, the p-type charge generation layer of the organic light-emitting device including a plurality of emitting stacks may preferably include a first compound represented by Chemical Formulas 1 or 2 of the present disclosure and a second compound represented by Chemical Formula 3 of the present disclosure, and the definitions and descriptions of Chemical Formulas 1 to 3 may be applied in the same manner as described in FIG. 1.

In this case, one or more hole injection layers included in the emitting stacks may contain a first compound represented by one of Chemical Formulas 1 and 2 and a second compound represented by Chemical Formula 3 of the present disclosure.

The p-type charge generation layer (p-CGL) of the present disclosure may include a first compound and a second compound, wherein the first compound may be a p-type dopant, and the second compound may be a p-type host.

According to one implementation of the present disclosure, the p-type charge generation layer (p-CGL) may consist of the first compound and the second compound.

According to one implementation of the present disclosure, based on 100% of the total weight of the p-type charge generation layer (p-CGL), the second compound may be contained in 50 to 90 wt %, and for example, the second compound may be contained in 60 to 80 wt %, for example, in 65 to 75 wt %, and thereby, the performance of the organic light-emitting device including the same can be improved by facilitating hole and electron movement.

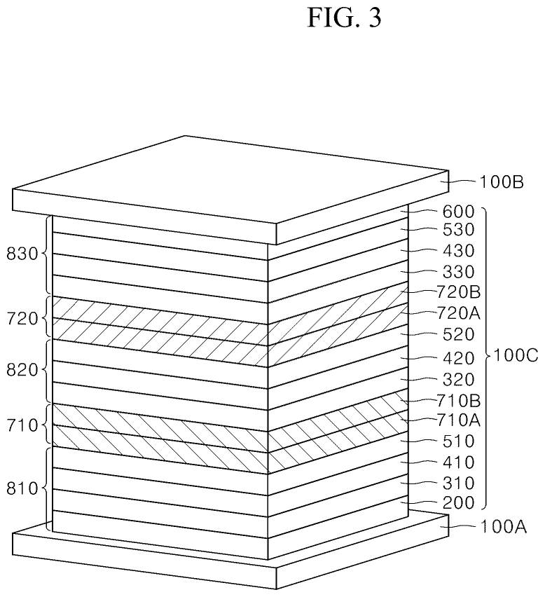

FIGS. 2 and 3, which are example implementations of the present disclosure, are cross-sectional views schematically showing organic light-emitting devices in a tandem structure having two emitting stacks and three emitting stacks, respectively.

As shown in FIG. 2, an organic light-emitting device 100 of the present disclosure includes an anode 100A and a cathode 100B facing each other, and an intermediate layer 100C positioned between the anode 100A and the cathode 100B. The intermediate layer 100C includes a first emitting stack 810 positioned between the anode 100A and the cathode 100B and including a first emission material layer 410, a second emitting stack 820 positioned between the first emitting stack 810 and the cathode 100B and including a second emission material layer 420, and a charge generation layer 700 positioned between the first and second emitting stacks 810 and 820.

The charge generation layer 700 may include an n-type charge generation layer 700A and a p-type charge generation layer 700B. The p-type charge generation layer 700B may contain a first compound represented by one of Chemical Formulas 1 and 2 of the present disclosure and a second compound represented by Chemical Formula 3 of the present disclosure, and thereby, the organic light-emitting device can ensure low driving voltage, high efficiency, and long-lifetime characteristics. The definitions and descriptions of Chemical Formulas 1 to 3 above are the same as those described with respect to FIG. 1.

For example, the n-type charge generation layer 700A may be formed of a single component of an amphoteric compound that can be used as an n-type host, and, for example, may be formed by doping a dopant for electron injection or electron transfer, such as an alkali metal or alkaline earth metal compound, in addition to the n-type host. Metal components that can be used as dopants for electron injection or electron transfer include, but are not limited to, alkali metals such as lithium (Li), sodium (Na), potassium (K), and cesium (Cs), and/or alkaline earth metals such as magnesium (Mg), strontium (Sr), barium (Ba), and radium (Ra). For example, the dopant may be added in a proportion of about 1 to 30 wt % based on the amphoteric compound used as the n-type host, but is not limited thereto.

The anode 100A, the cathode 100B, the hole injection layer 200, and the electron injection layer 600 of FIG. 2 may be applied in the same manner as described in FIG. 1. The first hole transfer layer 310 and the second hole transfer layer 320 of FIG. 2 may be applied in the same or similar manner as described above with respect to the hole transfer layer 300 of FIG. 1, and the compounds for forming the first hole transfer layer 310 and the second hole transfer layer 320 may be the same or different from each other. The first emission material layer 410 and the second emission material layer 420 of FIG. 2 may be applied in the same or similar manner as described with respect to the emission material layer 400 of FIG. 1, and the compounds for forming the first emission material layer 410 and the second emission material layer 420 may be the same or different from each other. The first electron transfer layer 510 and the second electron transfer layer 520 of FIG. 2 may be applied in the same or similar manner as described with respect to the electron transfer layer 500 of FIG. 1, and the compounds for forming the first electron transfer layer 510 and the second electron transfer layer 520 may be the same or different from each other.

As shown in FIG. 3, an organic light-emitting device 100 of the present disclosure includes an anode 100A and a cathode 100B facing each other, and an intermediate layer 100C positioned between the anode 100A and the cathode 100B. The intermediate layer 100C includes a first emitting stack 810 positioned between the anode 100A and the cathode 100B and including a first emission material layer 410; a second emitting stack 820 including a second emission material layer 420; a third emitting stack 830 including a third emission material layer 430; a first charge generation layer 710 positioned between the first and second emitting stacks 810 and 820; and a second charge generation layer 720 positioned between the second and third emitting stacks 820 and 830. The first and second charge generation layers 710 and 720 may include first and second n-type charge generation layers 710A and 720A and first and second p-type charge generation layers 710B and 720B, respectively.

The first and second n-type charge generation layers 710A and 720A and the first and second p-type charge generation layers 710B and 720B of FIG. 3 may be applied in the same manner as the n-type charge generation layer 700A and the p-type charge generation layer 700B described in FIG. 2.

For example, one or more of the first and second p-type charge generation layers 710B and 720B may include a first compound represented by one of Chemical Formulas 1 and 2 of the present disclosure and a second compound represented by Chemical Formula 3 of the present disclosure, and thereby, the organic light-emitting device can ensure low driving voltage, high efficiency, and long-lifetime characteristics. The definitions and descriptions of Chemical Formulas 1 to 3 above are the same as those described with respect to FIG. 1.

For example, if one of the first and second p-type charge generation layers 710B and 720B is selected to include the first compound represented by one of Chemical Formulas 1 and 2 and the second compound represented by Chemical Formula 3 in accordance with the present disclosure, the other p-type charge generation layer may be formed of a single component of an amphoteric compound that can be used as a p-type host, and may be formed, for example, by doping a metal or a hole injection dopant in addition to the p-type host. For example, the metal may include, but is not limited to, one or more of Al, Cu, Fe, Pb, Zn, Au, Pt, W, In, Mo, Ni, and Ti. For example, the hole injection dopant may include, but is not limited to, one or more of F4-TCNQ, iodine, FeCl₃, FeF₃, and SbCl₅. For example, the metal or hole injection dopant may be added in a proportion of about 1 to 30 wt % based on the amphoteric compound used as the p-type host, but is not limited thereto.

The kinds of compounds for forming the first and second n-type charge generation layers 710A and 720A of FIG. 3 are the same as those described with respect to the n-type charge generation layer 700A in FIG. 2, and the first n-type charge generation layer 710A and the second n-type charge generation layer 720A may be the same or different from each other.

The anode 100A, the cathode 100B, the hole injection layer 200, and the electron injection layer 600 of FIG. 3 may be applied in the same manner as described in FIG. 1. The first hole transfer layer 310, the second hole transfer layer 320, and the third hole transfer layer 330 of FIG. 3 may be applied in the same or similar manner as described above with respect to the hole transfer layer 300 of FIG. 1, and the compounds for forming the first hole transfer layer 310, the second hole transfer layer 320, and the third hole transfer layer 330 may be the same or different from each other. The first emission material layer 410, the second emission material layer 420, and the third emission material layer 430 of FIG. 3 may be applied in the same or similar manner as described with respect to the emission material layer 400 of FIG. 1, and the compounds for forming the first emission material layer 410, the second emission material layer 420, and the third emission material layer 430 may be the same or different from each other. The first electron transfer layer 510, the second electron transfer layer 520, and the third electron transfer layer 530 of FIG. 3 may be applied in the same or similar manner as described with respect to the electron transfer layer 500 of FIG. 1, and the compounds for forming the first electron transfer layer 510, the second electron transfer layer 520, and the third electron transfer layer 530 may be the same or different from each other.

Furthermore, although not shown in the drawings, an organic light-emitting device in accordance with one implementation of the present disclosure may include a tandem structure in which four or more emitting stacks and three or more charge generation layers are disposed between an anode and a cathode. In this case, one or more of p-type charge generation layers may include a first compound represented by one of Chemical Formulas 1 and 2 and a second compound represented by Chemical Formula 3 in accordance with the present disclosure. The definitions and descriptions of Chemical Formulas 1 to 3 above are the same as those described with respect to FIG. 1.

The organic light-emitting device in accordance with the present disclosure can be utilized in an organic light-emitting display device, a lighting device with the organic light-emitting device applied thereto, and the like. An organic light-emitting display device to which the organic light-emitting device (FIGS. 1 to 3) in accordance with an example embodiment of the present disclosure is applied can be provided.

The organic light-emitting display device may include a substrate and the organic light-emitting device of FIGS. 1 to 3. A driving thin film transistor, which is a driving device, and the organic light-emitting device to be connected to the driving thin film transistor are positioned on the substrate.

In addition, the organic light-emitting display device may include a color filter that absorbs light generated by the organic light-emitting device. For example, the color filter may absorb red (R), green (G), blue (B), and white (W) light. In this case, red, green, and blue color filter patterns that absorb light may be formed separately for each pixel region, and each of these color filter patterns may be arranged to overlap, respectively, with the intermediate layer of an organic light-emitting device that emits light in the wavelength band to be absorbed. By adopting the color filter, the organic light-emitting display device can implement full color.

For example, if the organic light-emitting display device is a bottom-emission type, a color filter that absorbs light may be positioned on top of the interlayer insulating film corresponding to the organic light-emitting device. For example, if the organic light-emitting display device is a top-emission type, a color filter may be positioned on top of the organic light-emitting device, i.e., on top of the cathode.

In the following, embodiments and experimental examples of the above compounds will be described by taking representative examples. However, the synthesis methods of the compounds of the present disclosure are not limited to the methods illustrated below, or the practice of the present disclosure is not limited to the embodiments and experimental examples below.

### <Experimental Group 1>

### Embodiment 1

A substrate on which ITO (100 nm), which is the anode of an organic light-emitting device, was deposited was patterned by dividing it into cathode and anode regions and an insulating layer through a photolithography process, and then, was surface-treated with UV-ozone treatment and O₂:N₂ plasma for the purpose of increasing the work function of the anode (ITO) and cleaning.

Next, a hole injection layer (HIL) was formed in a thickness of 10 nm on the anode by mixing Compound PD-73 as a first compound (p-type dopant) and Compound PH-6 as a second compound (p-type host) (first compound:second compound=3:7, weight ratio).

A hole transfer layer (HTL) was formed in a thickness of 90 nm by vacuum-depositing N4,N4,N4′,N4′-Tetra([1,1′-biphenyl]-4-yl)-[1,1′-biphenyl]-4,4′-diamine on the hole injection layer, and an electron-blocking layer (EBL) was formed with a thickness of 15 nm of N-Phenyl-N-(4-(spiro[benzo[d,e]anthracene-7,9′-fluorene]-2′-yl)phenyl)dibenzo[b,d]furan-4-amine on top of the hole transfer layer (HTL).

An emission material layer (EML) was deposited in a thickness of 25 nm by doping N1,N6-bis(dibenzo[b,d]furan-4-yl)-3,8-diisopropyl-N1,N6-diphenyl-1,5-dihydropyrene-1,6-diamine as a pyrene-based dopant into 9,10-Bis(2-naphthyl)anthracene (ADN) as a host in 3 wt % (host:dopant=97:3) on the electron-blocking layer (EBL).

An electron transfer layer (ETL) was deposited in a thickness of 25 nm on the emission material layer (EML) by mixing 2-(4-(9,10-Di(naphthalene-2-yl)anthracene-2-yl)phenyl)-1-phenyl-1H-benzo[d]imidazole and Liq in a weight ratio of 1:1. An electron injection layer (EIL) was deposited with a thickness of 1 nm of Liq on the electron transfer layer (ETL), and a cathode was formed by depositing aluminum in a thickness of 100 nm on the electron injection layer (EIL).

A capping layer (CPL) was formed by depositing N4,N4′-bis[4-[bis(3-methylphenyl)amino]phenyl]-N4,N4′-diphenyl-[1,1′-biphenyl]-4,4′-diamine (DNTPD) in a thickness of 1,000 Å on the cathode. A seal cap was bonded onto the capping layer (CPL) with a UV-curable adhesive, thereby manufacturing to protect the organic light-emitting device from oxygen (O₂) or moisture in the atmosphere.

### Embodiment 2

An organic light-emitting device was manufactured in the same manner as in Embodiment 1, except that Compound PD-287 was used instead of Compound PD-73, as shown in Table 1 below,

### Embodiments 3, 5, 7, 9, 11, 13, 15, 17, 19 and 21

Organic light-emitting devices were manufactured in the same manner as in Embodiment 1, except that different compounds in Table 1 were used instead of Compound PH-6, as shown in Table 1 below.

### Embodiments 4, 6, 8, 10, 12, 14, 16, 18, 20 and 22

Organic light-emitting devices were manufactured in the same manner as in Embodiment 2, except that different compounds in Table 1 were used instead of Compound PH-6, as shown in Table 1 below.

### Comparative Examples 1 to 4

In Comparative Example 1, an organic light-emitting device was manufactured in the same manner as in Embodiment 1, except that the hole injection layer was manufactured with Compound PD-73 alone.

In Comparative Example 2, an organic light-emitting device was manufactured in the same manner as in Embodiment 1, except that the hole injection layer was manufactured with Compound PD-287 alone.

In Comparative Example 3, an organic light-emitting device was manufactured in the same manner as in Embodiment 1, except that Compound A was used instead of Compound PH-6 when manufacturing the hole injection layer.

In Comparative Example 4, an organic light-emitting device was manufactured in the same manner as in Embodiment 2, except that Compound A was used instead of Compound PH-6 when manufacturing the hole injection layer.

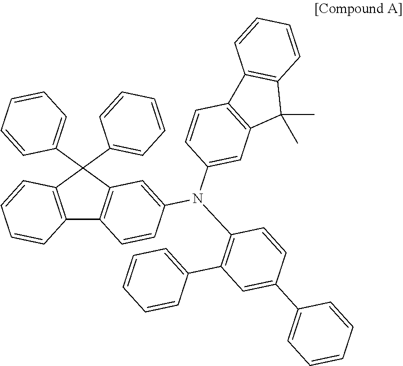 [SMILES: CC1(C)c2ccccc2-c2ccc(N(c3ccc4c(c3)C(c3ccccc3)(c3ccccc3)c3ccccc3-4)c3ccc(-c4ccccc4)cc3-c3ccccc3)cc21]

### Experimental Example 1—Device Performance Evaluation for Embodiments 1 to 22 and Comparative Examples 1 to 4

For each of the organic light-emitting devices of Embodiments 1 to 22 and Comparative Examples 1 to 4, the driving voltage (V) and efficiency (EQE, %) were measured by applying a current of 10 mA/cm² using a CS-2000 instrument from KONICA MINOLTA, and the lifetime (LT95, hr) was measured in a method of checking the time it takes for the brightness to decrease from the initial brightness to a 95% level with constant current driving of 10 mA/cm² by using an M6000 instrument from McScience. The measurement results of Experimental Example 1 are shown in Table 1 below.

TABLE 1

| | p-dopant | p-host | Driving | | |
|---|---|---|---|---|---|
| | (First | (Second | voltage | Efficiency | Lifetime |
| | compound) | compound) | (V) | (EQE, %) | (LT95, hr) |
| Embodiment 1 | PD-73 | PH-6 | 4.69 | 9.5 | 218 |
| Embodiment 2 | PD-287 | PH-6 | 4.63 | 9.7 | 219 |
| Embodiment 3 | PD-73 | PH-148 | 4.58 | 9.1 | 222 |
| Embodiment 4 | PD-287 | PH-148 | 4.51 | 9.4 | 224 |
| Embodiment 5 | PD-73 | PH-149 | 4.57 | 9.5 | 225 |
| Embodiment 6 | PD-287 | PH-149 | 4.53 | 10.0 | 224 |
| Embodiment 7 | PD-73 | PH-196 | 4.75 | 9.4 | 222 |
| Embodiment 8 | PD-287 | PH-196 | 4.71 | 9.9 | 227 |
| Embodiment 9 | PD-73 | PH-231 | 4.45 | 9.7 | 225 |
| Embodiment 10 | PD-287 | PH-231 | 4.39 | 10.3 | 226 |
| Embodiment 11 | PD-73 | PH-255 | 4.48 | 8.7 | 226 |
| Embodiment 12 | PD-287 | PH-255 | 4.41 | 8.8 | 227 |
| Embodiment 13 | PD-73 | PH-269 | 4.47 | 8.5 | 219 |
| Embodiment 14 | PD-287 | PH-269 | 4.44 | 8.8 | 221 |
| Embodiment 15 | PD-73 | PH-287 | 4.38 | 9.7 | 222 |
| Embodiment 16 | PD-287 | PH-287 | 4.32 | 9.8 | 217 |
| Embodiment 17 | PD-73 | PH-291 | 4.39 | 8.9 | 223 |
| Embodiment 18 | PD-287 | PH-291 | 4.34 | 9.3 | 225 |
| Embodiment 19 | PD-73 | PH-307 | 4.44 | 9.1 | 226 |
| Embodiment 20 | PD-287 | PH-307 | 4.31 | 9.7 | 222 |
| Embodiment 21 | PD-73 | PH-288 | 4.54 | 10.1 | 229 |
| Embodiment 22 | PD-287 | PH-288 | 4.48 | 10.5 | 223 |
| Comparative | PD-73 | — | 8.58 | 4.8 | 47 |
| Example 1 | | | | | |
| Comparative | PD-287 | — | 8.37 | 4.9 | 61 |
| Example 2 | | | | | |
| Comparative | PD-73 | Compound A | 5.67 | 7.6 | 159 |
| Example 3 | | | | | |
| Comparative | PD-287 | Compound A | 5.56 | 7.7 | 178 |
| Example 4 | | | | | |

### <Experimental Group 2>

### Embodiment 23

An organic light-emitting device of Embodiment 23 was manufactured in the same manner as in Embodiment 1 above, but the only difference was that instead of the emission material layer of Embodiment 1, an emission material layer (EML) was deposited in a thickness of 25 nm by doping 2,12-Di-tert-butyl-5,9-bis(4-(tert-butyl)phenyl)-7-(3,5-di-tert-butylphenyl)-5,9-dihydro-5,9-diaza-13b-boranaphtho[3,2,1-de]anthracene (t-DABNA-dtB) as a boron-based dopant into 9,10-Bis(2-naphthyl)anthracene (ADN) as a host in 3 wt % (host:dopant=97:3).

### Embodiments 24 to 44

Organic light-emitting devices of Embodiments 24 to 44 were manufactured, respectively, in the same manner as in Embodiment 23 above, except that the material of the hole injection layer was changed as shown in Table 2 below.

### Comparative Examples 5 to 8

In Comparative Example 5, an organic light-emitting device was manufactured in the same manner as in Embodiment 23, except that the hole injection layer was manufactured with Compound PD-73 alone.

In Comparative Example 6, an organic light-emitting device was manufactured in the same manner as in Embodiment 23, except that the hole injection layer was manufactured with Compound PD-287 alone.

In Comparative Example 7, an organic light-emitting device was manufactured in the same manner as in Embodiment 23, except that Compound A was used instead of Compound PH-6 when manufacturing the hole injection layer.

In Comparative Example 8, an organic light-emitting device was manufactured in the same manner as in Embodiment 23, except that Compound A was used instead of Compound PH-6 when manufacturing the hole injection layer.

Compound A used in Comparative Examples 7 and 8 is the same as Compound A used in Comparative Examples 3 and 4.

### Experimental Example 2—Device Performance Evaluation for Embodiments 23 to 44 and Comparative Examples 5 to 8

As in Experimental Example 1 above, the driving voltage, efficiency (EQE), and lifetime (LT95) were measured for each of the organic light-emitting devices of Embodiments 23 to 44 and Comparative Examples 5 to 8, and the measurement results are shown in Table 2 below.

TABLE 2

| | p-dopant | p-host | Driving | | |
|---|---|---|---|---|---|
| | (First | (Second | voltage | Efficiency | Lifetime |
| | compound) | compound) | (V) | (EQE, %) | (LT95, hr) |
| Embodiment 23 | PD-73 | PH-6 | 3.59 | 12.7 | 248 |
| Embodiment 24 | PD-287 | PH-6 | 3.48 | 12.8 | 250 |
| Embodiment 25 | PD-73 | PH-148 | 3.45 | 12.1 | 253 |
| Embodiment 26 | PD-287 | PH-148 | 3.36 | 12.5 | 251 |
| Embodiment 27 | PD-73 | PH-149 | 3.35 | 12.8 | 255 |
| Embodiment 28 | PD-287 | PH-149 | 3.28 | 13.1 | 257 |
| Embodiment 29 | PD-73 | PH-196 | 3.86 | 12.5 | 254 |
| Embodiment 30 | PD-287 | PH-196 | 3.75 | 12.9 | 257 |
| Embodiment 31 | PD-73 | PH-231 | 3.34 | 12.4 | 258 |
| Embodiment 32 | PD-287 | PH-231 | 3.29 | 13.4 | 261 |
| Embodiment 33 | PD-73 | PH-255 | 3.38 | 11.9 | 253 |
| Embodiment 34 | PD-287 | PH-255 | 3.30 | 12.1 | 257 |
| Embodiment 35 | PD-73 | PH-269 | 3.43 | 11.8 | 248 |
| Embodiment 36 | PD-287 | PH-269 | 3.18 | 12.3 | 251 |
| Embodiment 37 | PD-73 | PH-287 | 3.99 | 12.8 | 247 |
| Embodiment 38 | PD-287 | PH-287 | 3.54 | 12.9 | 251 |
| Embodiment 39 | PD-73 | PH-291 | 3.87 | 11.7 | 253 |
| Embodiment 40 | PD-287 | PH-291 | 3.47 | 12.1 | 256 |
| Embodiment 41 | PD-73 | PH-307 | 3.74 | 12.4 | 251 |
| Embodiment 42 | PD-287 | PH-307 | 3.53 | 12.7 | 252 |
| Embodiment 43 | PD-73 | PH-288 | 3.66 | 12.4 | 259 |
| Embodiment 44 | PD-287 | PH-288 | 3.35 | 13.4 | 257 |
| Comparative | PD-73 | — | 8.38 | 4.9 | 69 |
| Example 5 | | | | | |
| Comparative | PD-287 | — | 8.05 | 5.1 | 83 |
| Example 6 | | | | | |
| Comparative | PD-73 | Compound A | 5.32 | 7.8 | 179 |
| Example 7 | | | | | |
| Comparative | PD-287 | Compound A | 5.10 | 7.9 | 199 |
| Example 8 | | | | | |

From the results in Tables 1 and 2 above, it has been confirmed that the organic light-emitting devices including the hole injection layers manufactured with the compound represented by one of Chemical Formulas 1 and 2 and the compound represented by Chemical Formula 3 in accordance with the present disclosure as the p-type dopant and p-type host (second compound) can improve the driving voltage, efficiency, and lifetime characteristics compared to those using the p-type dopant alone as in Comparative Examples 1, 2, 5, and 6.

Furthermore, it has been confirmed that by using the compound that does not contain a 9,9-diphenylfluorene moiety as the p-type host (second compound), the organic light-emitting devices in accordance with the present disclosure can improve the driving voltage, efficiency, and lifetime characteristics compared to the organic light-emitting devices using the compound containing a 9,9-diphenylfluorene moiety as the p-type host (second compound) as in Comparative Examples 3, 4, 7, and 8.

### <Experimental Group 3>

### Embodiments 45 to 54 and Comparative Examples 9 to 14

Organic light-emitting devices of Embodiments 45 to 54 and Comparative Examples 9 to 14 were manufactured, respectively, in the same manner as in Embodiment 23 above, except that the mixing weight ratio (the total weight of the hole injection layer being 100 wt %) of the p-type dopant (first compound) and the p-type host (second compound) in the hole injection layer (HIL) was changed as described in Table 3 below.

### Experimental Example 3—Device Performance Evaluation According to the Content of the Second Compound

As in Experimental Example 1 above, the driving voltage, efficiency (EQE), and lifetime (LT95) were measured for each of the organic light-emitting devices of Embodiments 45 to 54 and Comparative Examples 9 to 14, and the measurement results are shown in Table 3 below.

TABLE 3

| | p-dopant | p-host | | | |
|---|---|---|---|---|---|
| | (First | (Second | Driving | | |
| | compound) | compound) | voltage | Efficiency | Lifetime |
| | [wt %] | [wt %] | (V) | (EQE, %) | (LT95, hr) |
| Embodiment 45 | PD-73 | PH-6 | 4.93 | 9.3 | 189 |
| | [10] | [90] | | | |
| Embodiment 46 | PD-287 | PH-6 | 4.89 | 9.9 | 205 |
| | [10] | [90] | | | |
| Embodiment 47 | PD-73 | PH-6 | 4.12 | 11.0 | 226 |
| | [20] | [80] | | | |
| Embodiment 48 | PD-287 | PH-6 | 4.03 | 11.2 | 228 |
| | [20] | [80] | | | |
| Embodiment 49 | PD-73 | PH-6 | 3.59 | 12.7 | 248 |
| | [30] | [70] | | | |
| Embodiment 50 | PD-287 | PH-6 | 3.48 | 12.8 | 250 |
| | [30] | [70] | | | |
| Embodiment 51 | PD-73 | PH-6 | 4.43 | 11.8 | 236 |
| | [40] | [60] | | | |
| Embodiment 52 | PD-287 | PH-6 | 4.39 | 12.0 | 241 |
| | [40] | [60] | | | |
| Embodiment 53 | PD-73 | PH-6 | 4.75 | 9.6 | 185 |
| | [50] | [50] | | | |
| Embodiment 54 | PD-287 | PH-6 | 4.64 | 10.1 | 198 |
| | [50] | [50] | | | |
| Comparative | PD-73 | — | 8.38 | 4.9 | 69 |
| Example 9 | [100] | | | | |
| Comparative | PD-287 | — | 8.05 | 5.1 | 83 |
| Example 10 | [100] | | | | |
| Comparative | PD-73 | PH-6 | 8.25 | 5.3 | 73 |
| Example 11 | [5] | [95] | | | |
| Comparative | PD-287 | PH-6 | 8.15 | 5.5 | 95 |
| Example 12 | [5] | [95] | | | |
| Comparative | PD-73 | PH-6 | 6.38 | 8.3 | 132 |
| Example 13 | [60] | [40] | | | |
| Comparative | PD-287 | PH-6 | 6.12 | 8.8 | 153 |
| Example 14 | [60] | [40] | | | |

From the results of Embodiments 45 to 54 and Comparative Examples 9 to 14 shown in Table 3 above, it has been confirmed that the organic light-emitting devices including the hole injection layers formed of the compound (p-type dopant, first compound) represented by one of Chemical Formulas 1 and 2 and the compound (p-type host, second compound) represented by Chemical Formula 3 of the present disclosure can improve driving voltage, efficiency, and lifetime characteristics when the p-type host (second compound) is contained in 50 to 90 wt % based on 100 wt % of the total weight of the hole injection layer.

In addition, as can be seen in Comparative Examples 11 and 12, it has been confirmed that the effect of improving the emission efficiency, driving voltage, and lifetime characteristics is low as in Comparative Examples 9 and 10 when the p-type host (second compound) exceeds 90 wt % based on 100 wt % of the total weight of the hole injection layer.

Moreover, as can be seen in Comparative Examples 13 and 14, it has been confirmed that the effect of improving the emission efficiency, driving voltage, and lifetime characteristics is insignificant when the p-type host (second compound) is less than 50 wt % based on 100 wt % of the total weight of the hole injection layer.

### <Experimental Group 4>

### Embodiment 55

A substrate on which ITO (100 nm), which is the anode of an organic light-emitting device, was deposited was patterned by dividing it into cathode and anode regions and an insulating layer through a photolithography process, and then, was surface-treated with UV-ozone treatment and O₂:N₂ plasma for the purpose of increasing the work function of the anode (ITO) and cleaning.

Next, a hole injection layer (HIL) was formed with a thickness of 10 nm of 1,4,5,8,9,11-hexaazatriphenylene-hexacarbonitrile (HAT-CN) on the anode.

A first hole transfer layer (HTL 1) was formed in a thickness of 90 nm by vacuum-depositing N4,N4,N4′,N4′-Tetra([1,1′-biphenyl]-4-yl)-[1,1′-biphenyl]-4,4′-diamine on the hole injection layer. An electron-blocking layer (EBL) was formed with a thickness of 15 nm of N-Phenyl-N-(4-(spiro[benzo[d,e]anthracene-7,9′-fluorene]-2′-yl)phenyl)dibenzo[b,d]furan-4-amine on the first hole transfer layer (HTL 1).

A first emission material layer (EML 1) was deposited in a thickness of 25 nm by doping 2,12-Di-tert-butyl-5,9-bis(4-(tert-butyl)phenyl)-7-(3,5-di-tert-butylphenyl)-5,9-dihydro-5,9-diaza-13b-boranaphtho[3,2,1-de]anthracene (t-DABNA-dtB) as a dopant into 9,10-Bis(2-naphthyl)anthracene (ADN) as a host in 3 wt % (host:dopant=97:3, weight ratio) on the electron-blocking layer (EBL).

A first electron transfer layer (ETL 1) with a thickness of 25 nm was deposited by mixing 2-(4-(9,10-Di(naphthalene-2-yl)anthracene-2-yl)phenyl)-1-phenyl-1H-benzo[d]imidazole and Liq in a weight ratio of 1:1 on the first emission material layer.

An n-type charge generation layer (n-CGL) was formed in a thickness of 185 Å by mixing Compound B below and Li in a weight ratio of 98:2 on the first electron transfer layer (ETL 1).

A p-type charge generation layer (p-CGL) was formed in a thickness of 80 Å by vacuum-depositing Compound PD-73 as a first compound (p-type dopant) and Compound PH-6 as a second compound (p-type host) (first compound:second compound=3:7, weight ratio) on the n-type charge generation layer (n-CGL).

A second hole transfer layer (HTL 2) was formed by depositing N4,N4,N4′,N4′-Tetra([1,1′-biphenyl]-4-yl)-[1,1′-biphenyl]-4,4′-diamine in a thickness of 30 nm on the p-type charge generation layer (p-CGL).

A second emission material layer (EML 2) was deposited in a thickness of 35 nm by doping Ir(ppy)₃[tris(2-phenylpyridine)-iridium] as a dopant into 4,4′-N,N′-dicarbazole-biphenyl (CBP) as a host in 5 wt % (host:dopant=95:5, weight ratio) on the second hole transfer layer.

A second electron transfer layer (ETL 2) was deposited in a thickness of 30 nm by mixing N-phenyl-N-(4-(10-phenylanthracen-9-yl)phenyl)pyridin-4-amine and Liq in a 1:1 ratio on the second emission material layer (EML). Liq was deposited in a thickness of 1 nm as an electron injection layer (EIL) on the second electron transfer layer (ETL 2). A cathode was deposited with a thickness of 16 nm of a mixture of magnesium (Mg) and silver (Ag) (Mg:Ag=1:4, weight ratio) on the electron injection layer (EIL). A capping layer (CPL) was deposited in a thickness of 60 nm by using N4,N4′-bis[4-[bis(3-methylphenyl)amino]phenyl]-N4,N4′-diphenyl-[1,1′-biphenyl]-4,4′-diamine (DNTPD) on the cathode. A seal cap containing a desiccant was bonded onto the capping layer (CPL) with a UV-curable adhesive, allowing the organic light-emitting device to be protected from oxygen or moisture in the atmosphere.

### Embodiment 56

An organic light-emitting device was manufactured in the same manner as in Embodiment 55, except that only Compound PD-287 was used instead of Compound PD-73 in Embodiment 55 above.

### Comparative Examples 15 and 16

In Comparative Example 15, an organic light-emitting device was manufactured in the same manner as in Embodiment 55, except that Compound PD-73 was used alone in the p-type charge generation layer.

In Comparative Example 16, an organic light-emitting device was manufactured in the same manner as in Embodiment 55, except that Compound PD-287 was used alone in the p-type charge generation layer.

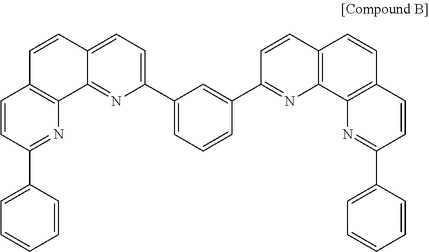 [SMILES: c1ccc(-c2ccc3ccc4ccc(-c5cccc(-c6ccc7ccc8ccc(-c9ccccc9)nc8c7n6)c5)nc4c3n2)cc1]

### Experimental Example 4—Evaluation of Organic Light-Emitting Devices Having a Tandem Structure with Two Emitting Stacks

As in Experimental Example 1 above, the driving voltage, efficiency (EQE), and lifetime (LT95) were measured for each of the organic light-emitting devices of Embodiments 55 to 56 and Comparative Examples 15 and 16, and the measurement results are shown in Table 4 below.

TABLE 4

| | p-dopant | p-host | Driving | | |
|---|---|---|---|---|---|
| | (First | (Second | voltage | Efficiency | Lifetime |
| | compound) | compound) | (V) | (EQE, %) | (LT95, hr) |
| Embodiment 55 | PD-73 | PH-6 | 11.13 | 36.8 | 425 |
| Embodiment 56 | PD-287 | PH-6 | 10.89 | 39.5 | 487 |
| Comparative | PD-73 | — | 15.37 | 26.4 | 255 |
| Example 15 | | | | | |
| Comparative | PD-287 | — | 14.85 | 28.5 | 289 |
| Example 16 | | | | | |

From the results in Table 4 above, it has been confirmed that Embodiments 55 and 56, which are organic light-emitting devices including the p-type charge generation layer manufactured by mixing the p-type dopant (first compound) that is a compound represented by one of Chemical Formulas 1 and 2 and the p-type host (second compound) that is a compound represented by Chemical Formula 3 in accordance with the present disclosure, have improved emission efficiency, driving voltage, and lifetime characteristics compared to the organic light-emitting devices of Comparative Examples 15 and 16 in which the p-type dopant (first compound) was used alone in the p-type charge generation layer.

In addition, it has been confirmed that the emission efficiency, driving voltage, and lifetime characteristics of the organic light-emitting device have been improved in the charge generation layer including the p-type dopant (first compound) and the p-type host (second compound) in the weight ratio as in Embodiments 45 to 54 confirmed in Experimental Example 3.

### Comparative Examples 17 to 20

In Comparative Example 17, an organic light-emitting device was manufactured in the same manner as in Embodiment 1, except that Compound C was used instead of Compound PH-6 when manufacturing the hole injection layer.

In Comparative Example 18, an organic light-emitting device was manufactured in the same manner as in Embodiment 1, except that Compound D was used instead of Compound PH-6 when manufacturing the hole injection layer.

In Comparative Example 19, an organic light-emitting device was manufactured in the same manner as in Embodiment 2, except that Compound C was used instead of Compound PH-6 when manufacturing the hole injection layer.

In Comparative Example 20, an organic light-emitting device was manufactured in the same manner as in Embodiment 2, except that Compound D was used instead of Compound PH-6 when manufacturing the hole injection layer.

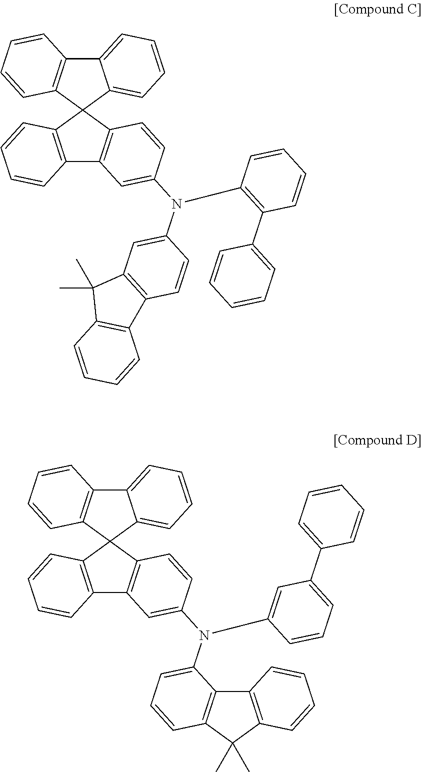 [SMILES: CC1(C)c2ccccc2-c2ccc(N(c3ccc4c(c3)-c3ccccc3C43c4ccccc4-c4ccccc43)c3ccccc3-c3ccccc3)cc21 ; CC1(C)c2ccccc2-c2c(N(c3cccc(-c4ccccc4)c3)c3ccc4c(c3)-c3ccccc3C43c4ccccc4-c4ccccc43)cccc21]

### Experimental Example 5—Device Performance Evaluation Comparative Examples 17 to 20

As in Experimental Example 1 above, the driving voltage, efficiency (EQE), and lifetime (LT95) were measured for each of the organic light-emitting devices of Comparative Examples 17 to 20, and the measurement results are shown in Table 5 below.

TABLE 5

| | p-dopant | p-host | Driving | | |
|---|---|---|---|---|---|
| | (First | (Second | voltage | Efficiency | Lifetime |
| | compound) | compound) | (V) | (EQE, %) | (LT95, hr) |
| Comparative | PD-73 | Compound C | 5.70 | 7.8 | 150 |
| Example 17 | | | | | |
| Comparative | PD-287 | Compound C | 5.66 | 7.7 | 155 |
| Example 18 | | | | | |
| Comparative | PD-73 | Compound D | 5.74 | 7.7 | 157 |
| Example 19 | | | | | |
| Comparative | PD-287 | Compound D | 5.69 | 7.5 | 158 |
| Example 20 | | | | | |

From the results in Tables 5 above, it has been confirmed that the organic light-emitting devices in accordance with the present disclosure using p-type host (second compound) not containing a 9,9′-spirobifluorene moiety can improve the driving voltage, efficiency, and lifetime characteristics compared to the organic light-emitting devices using the compound containing a 9,9′-spirobifluorene moiety as the p-type host (second compound) as in Comparative Examples 17 to 20.

While the embodiments of the present specification have been described in greater detail above, the present specification is not necessarily limited to these embodiments and may be modified and practiced in a variety of ways without departing from the scope of the technical ideas of the present specification. Therefore, the embodiments disclosed herein are intended not to limit but to describe the technical ideas of the present specification, and the scope of the technical ideas of the present specification is not limited by these embodiments. Therefore, it should be understood that the embodiments described above are illustrative and not limiting in all aspects.

What is claimed is:

1. An organic light-emitting device comprising:
an anode;
a cathode facing the anode; and
one or more intermediate layers between the anode and the cathode,
wherein at least one of the intermediate layers comprises a hole injection layer, and
the hole injection layer comprises a first compound represented by one of the following Chemical Formulas 1 and 2 and a second compound represented by the following Chemical Formula 3: 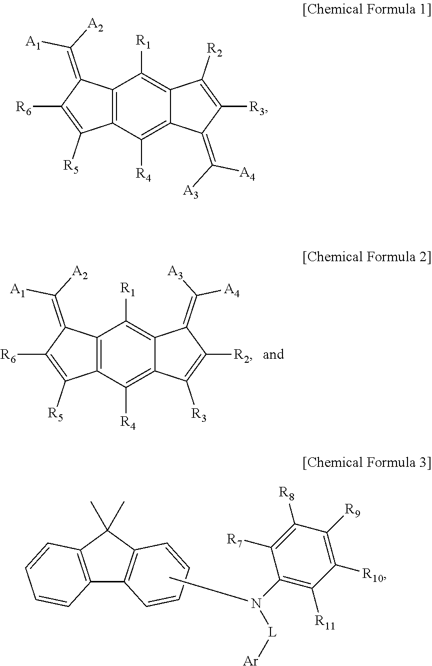
wherein in the Chemical Formulas 1 to 3,
R₁ to R₁₁ and A₁ to A₄ are the same or different from each other, and are each selected independently from a group consisting of hydrogen, deuterium, a cyano group, a trifluoromethyl group, a nitro group, a halogen group, a hydroxy group, a substituted or unsubstituted alkyl group having 1 to 30 carbon atoms, a substituted or unsubstituted cycloalkyl group having 3 to 20 carbon atoms, a substituted or unsubstituted alkenyl group having 2 to 30 carbon atoms, a substituted or unsubstituted cycloalkenyl group having 3 to 20 carbon atoms, a substituted or unsubstituted alkynyl group having 2 to 30 carbon atoms, a substituted or unsubstituted cycloalkynyl group having 3 to 20 carbon atoms, a substituted or unsubstituted aryl group having 6 to 30 carbon atoms, a substituted or unsubstituted arylalkyl group having 7 to 30 carbon atoms, a substituted or unsubstituted heteroaryl group having 5 to 60 carbon atoms, a substituted or unsubstituted heteroarylalkyl group having 6 to 60 carbon atoms, a substituted or unsubstituted amine group, a substituted or unsubstituted alkylamino group having 1 to 30 carbon atoms, an arylalkylamino group having 7 to 30 carbon atoms, a substituted or unsubstituted arylamino group having 6 to 30 carbon atoms, a substituted or unsubstituted heteroarylamino group having 5 to 60 carbon atoms, a substituted or unsubstituted silyl group, a substituted or unsubstituted alkylsilyl group having 1 to 30 carbon atoms, a substituted or unsubstituted arylsilyl group having 6 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthio group having 1 to 30 carbon atoms, and a substituted or unsubstituted arylthio group having 6 to 30 carbon atoms,
at least one or more of R₇, R₉, and R₁₁ are selected from a group consisting of a substituted or unsubstituted alkyl group having 1 to 30 carbon atoms, a substituted or unsubstituted aryl group having 5 to 30 carbon atoms, and a substituted or unsubstituted heteroaryl group having 3 to 30 carbon atoms,
L is each selected independently from a single bond, a substituted or unsubstituted aryl group having 6 to 30 carbon atoms, and a substituted or unsubstituted heteroaryl group having 6 to 30 carbon atoms,
Ar is the same or different from each other, and is each selected independently from a substituted or unsubstituted aryl group having 6 to 30 carbon atoms and a substituted or unsubstituted heteroaryl group having 5 to 60 carbon atoms, wherein Ar does not comprise a 9,9-diphenylfluorenyl group, and
if there are substituents of R₁ to R₁₁ and A₁ to A₄, L, and Ar present, the substituents are each substituted independently by one or more substituents selected from a group consisting of a cyano group, a trifluoromethyl group, a nitro group, a halogen group, a hydroxy group, an alkyl group having 1 to 30 carbon atoms, a cycloalkyl group having 3 to 20 carbon atoms, an alkenyl group having 2 to 30 carbon atoms, a cycloalkenyl group having 3 to 20 carbon atoms, an alkynyl group having 2 to 30 carbon atoms, a cycloalkynyl group having 3 to 20 carbon atoms, an aryl group having 6 to 30 carbon atoms, an arylalkyl group having 7 to 30 carbon atoms, a heteroaryl group having 5 to 60 carbon atoms, a heteroarylalkyl group having 6 to 60 carbon atoms, an amine group, an alkylamino group having 1 to 30 carbon atoms, an arylalkylamino group having 7 to 30 carbon atoms, an arylamino group having 6 to 30 carbon atoms, a heteroarylamino group having 5 to 60 carbon atoms, an alkylsilyl group having 1 to 30 carbon atoms, an arylsilyl group having 6 to 30 carbon atoms, an alkoxy group having 1 to 30 carbon atoms, an aryloxy group having 6 to 30 carbon atoms, an alkylthio group having 1 to 30 carbon atoms, and an arylthio group having 6 to 30 carbon atoms, and if substituted by a plurality of substituents, the substituents are the same or different from each other.

2. The organic light-emitting device of claim 1, wherein the Chemical Formula 3 is represented by one selected from the following Chemical Formulas 3-1 to 3-4: 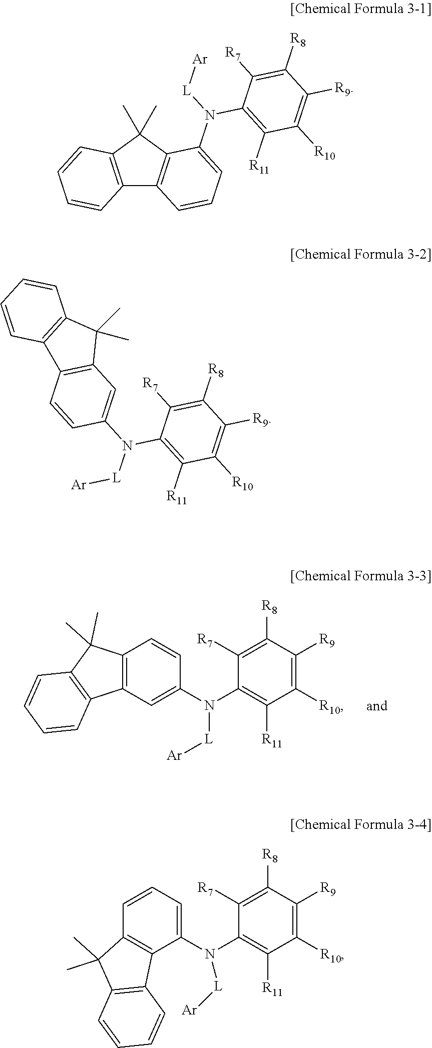
where R₇ to R₁₁, L, and Ar are the same as defined in the Chemical Formula 3.

3. The organic light-emitting device of claim 2, wherein the Chemical Formula 3 is represented by one selected from the Chemical Formulas 3-2 and 3-4.

4. The organic light-emitting device of claim 1, wherein a structure of the first compound represented by one of the Chemical Formulas 1 and 2 is selected from a group consisting of the following Compounds PD-1 to PD-450:

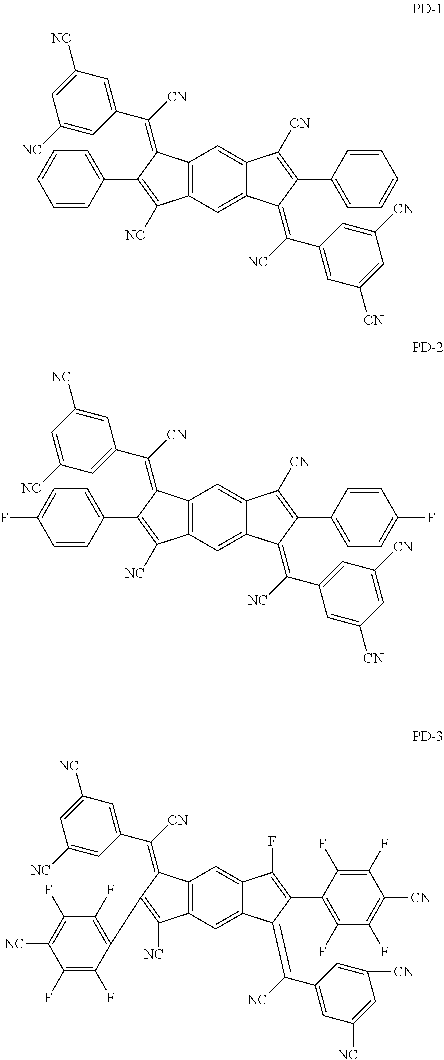

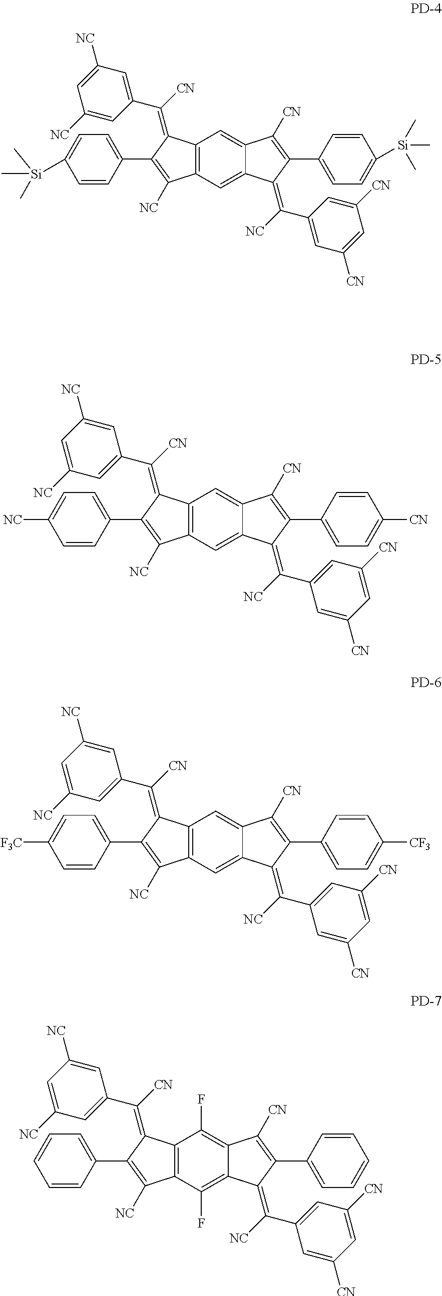

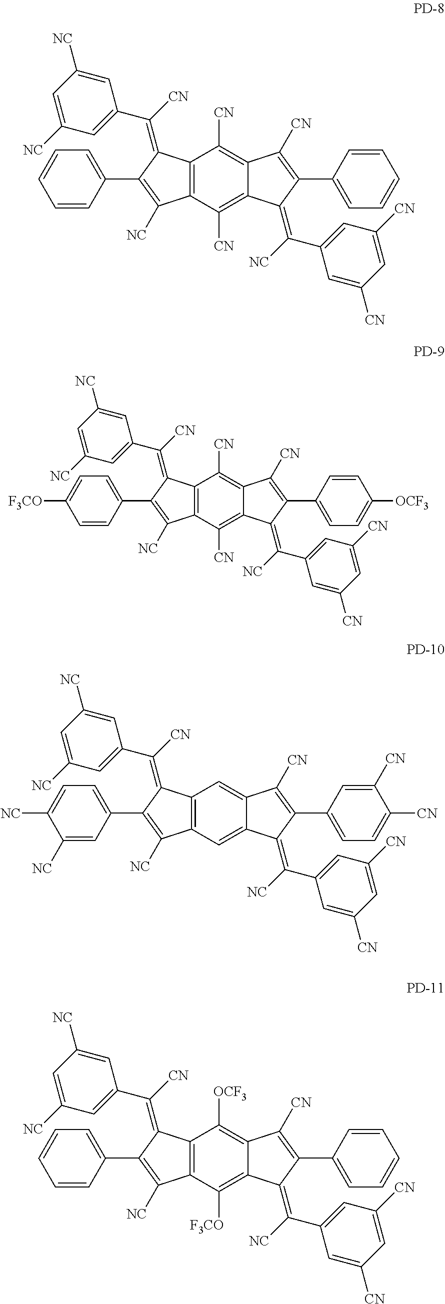

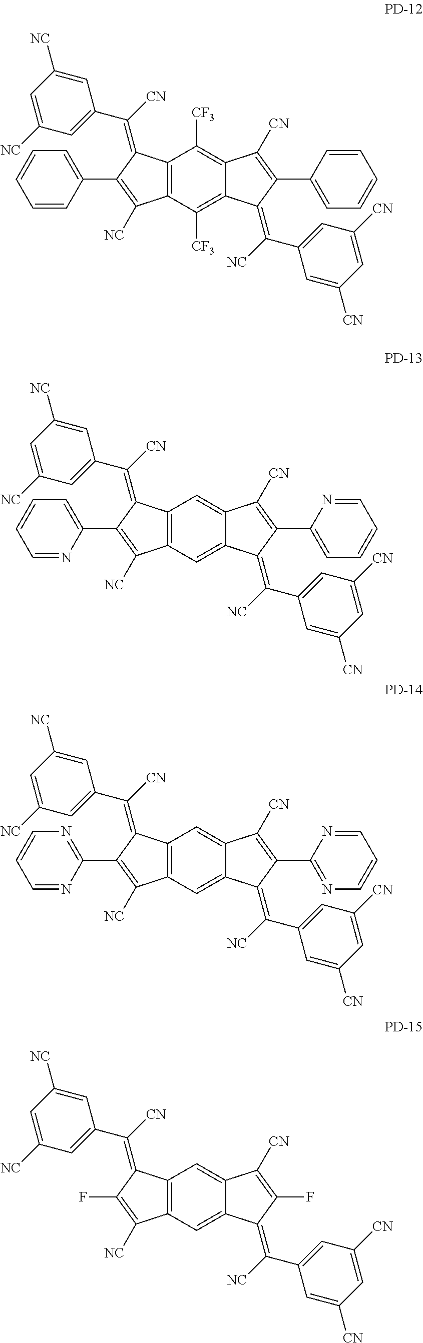 [SMILES: N#CC1=C(c2ccccc2)/C(=C(/C#N)c2cc(C#N)cc(C#N)c2)c2c1c(C(F)(F)F)c1c(c2C(F)(F)F)C(C#N)=C(c2ccccc2)/C1=C(/C#N)c1cc(C#N)cc(C#N)c1 ; N#CC1=C(c2ccccn2)/C(=C(/C#N)c2cc(C#N)cc(C#N)c2)c2cc3c(cc21)/C(=C(\C#N)c1cc(C#N)cc(C#N)c1)C(c1ccccn1)=C3C#N ; N#CC1=C(c2ncccn2)/C(=C(/C#N)c2cc(C#N)cc(C#N)c2)c2cc3c(cc21)/C(=C(\C#N)c1cc(C#N)cc(C#N)c1)C(c1ncccn1)=C3C#N ; N#CC1=C(F)/C(=C(/C#N)c2cc(C#N)cc(C#N)c2)c2cc3c(cc21)/C(=C(\C#N)c1cc(C#N)cc(C#N)c1)C(F)=C3C#N]

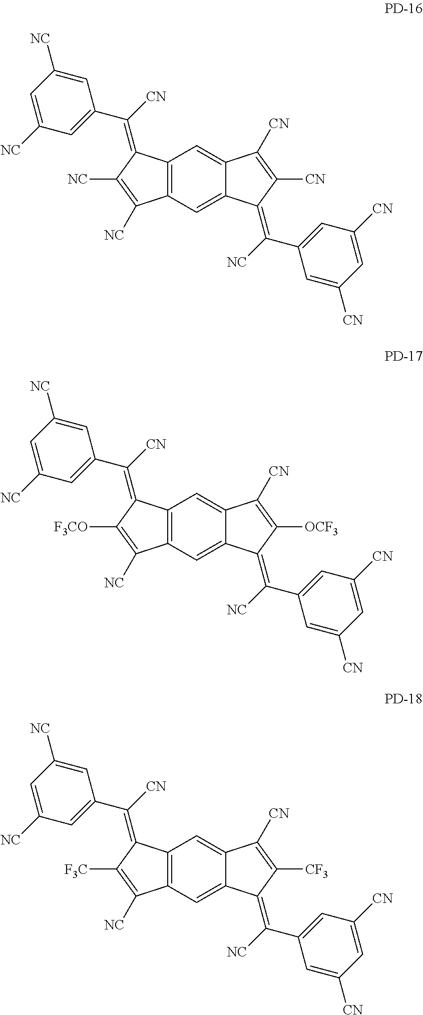 [SMILES: N#CC1=C(C#N)c2cc3c(cc2/C1=C(\C#N)c1cc(C#N)cc(C#N)c1)C(C#N)=C(C#N)/C3=C(/C#N)c1cc(C#N)cc(C#N)c1 ; N#CC1=C(OC(F)(F)F)/C(=C(/C#N)c2cc(C#N)cc(C#N)c2)c2cc3c(cc21)/C(=C(\C#N)c1cc(C#N)cc(C#N)c1)C(OC(F)(F)F)=C3C#N ; N#CC1=C(C(F)(F)F)/C(=C(/C#N)c2cc(C#N)cc(C#N)c2)c2cc3c(cc21)/C(=C(\C#N)c1cc(C#N)cc(C#N)c1)C(C(F)(F)F)=C3C#N]

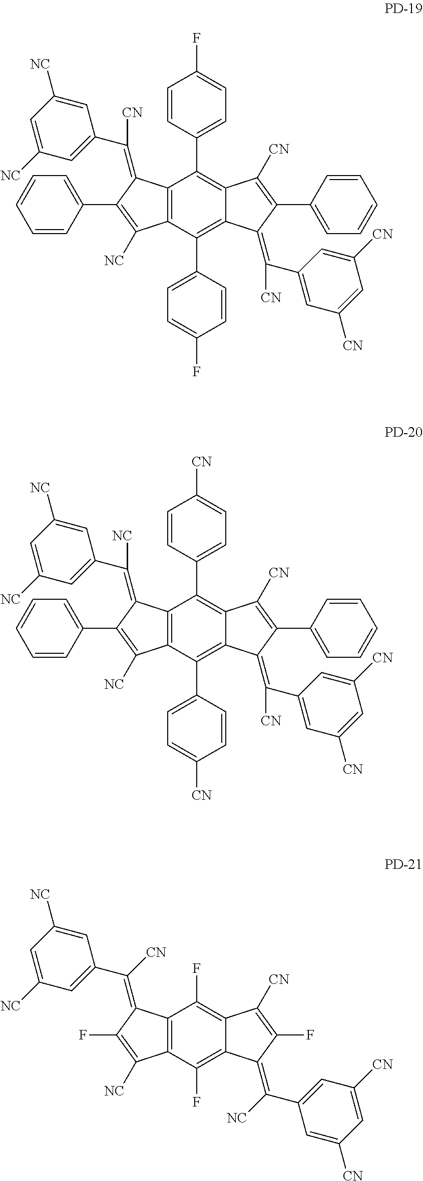 [SMILES: N#CC1=C(c2ccccc2)/C(=C(/C#N)c2cc(C#N)cc(C#N)c2)c2c1c(-c1ccc(F)cc1)c1c(c2-c2ccc(F)cc2)C(C#N)=C(c2ccccc2)/C1=C(/C#N)c1cc(C#N)cc(C#N)c1 ; N#CC1=C(c2ccccc2)/C(=C(/C#N)c2cc(C#N)cc(C#N)c2)c2c1c(-c1ccc(C#N)cc1)c1c(c2-c2ccc(C#N)cc2)C(C#N)=C(c2ccccc2)/C1=C(/C#N)c1cc(C#N)cc(C#N)c1 ; N#CC1=C(F)/C(=C(/C#N)c2cc(C#N)cc(C#N)c2)c2c(F)c3c(c(F)c21)/C(=C(\C#N)c1cc(C#N)cc(C#N)c1)C(F)=C3C#N]

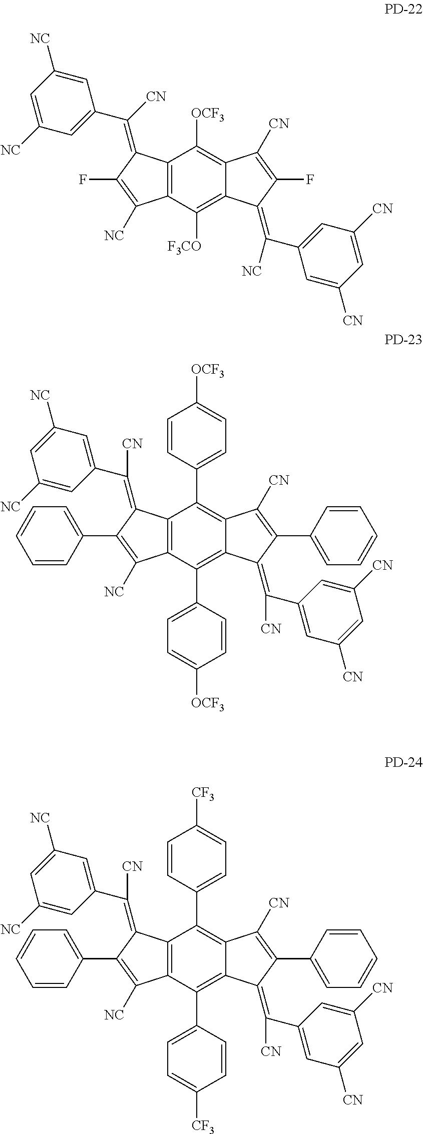 [SMILES: N#CC1=C(F)/C(=C(/C#N)c2cc(C#N)cc(C#N)c2)c2c(OC(F)(F)F)c3c(c(OC(F)(F)F)c21)/C(=C(\C#N)c1cc(C#N)cc(C#N)c1)C(F)=C3C#N ; N#CC1=C(c2ccccc2)/C(=C(/C#N)c2cc(C#N)cc(C#N)c2)c2c1c(-c1ccc(OC(F)(F)F)cc1)c1c(c2-c2ccc(OC(F)(F)F)cc2)C(C#N)=C(c2ccccc2)/C1=C(/C#N)c1cc(C#N)cc(C#N)c1 ; N#CC1=C(c2ccccc2)/C(=C(/C#N)c2cc(C#N)cc(C#N)c2)c2c1c(-c1ccc(C(F)(F)F)cc1)c1c(c2-c2ccc(C(F)(F)F)cc2)C(C#N)=C(c2ccccc2)/C1=C(/C#N)c1cc(C#N)cc(C#N)c1]

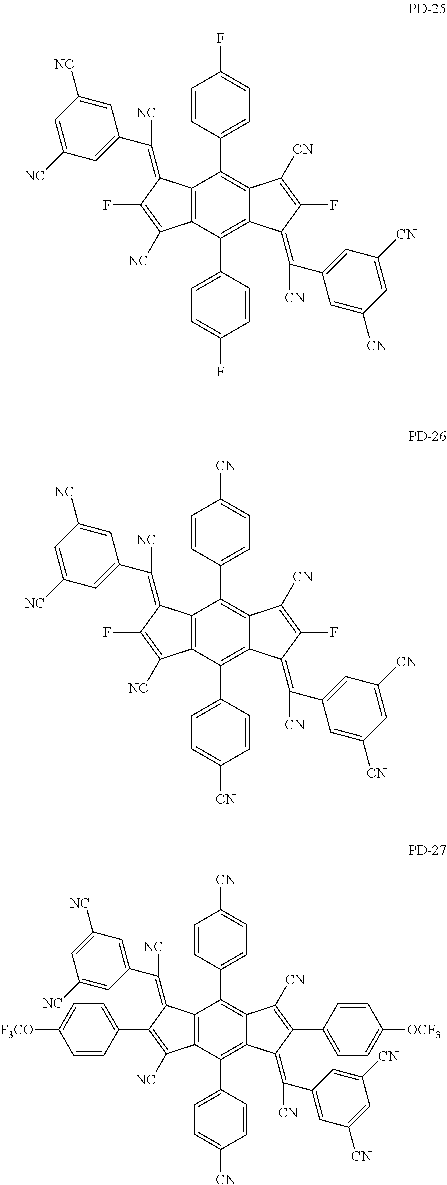 [SMILES: N#CC1=C(F)/C(=C(/C#N)c2cc(C#N)cc(C#N)c2)c2c1c(-c1ccc(F)cc1)c1c(c2-c2ccc(F)cc2)C(C#N)=C(F)/C1=C(/C#N)c1cc(C#N)cc(C#N)c1 ; N#CC1=C(F)/C(=C(/C#N)c2cc(C#N)cc(C#N)c2)c2c1c(-c1ccc(C#N)cc1)c1c(c2-c2ccc(C#N)cc2)C(C#N)=C(F)/C1=C(/C#N)c1cc(C#N)cc(C#N)c1 ; N#CC1=C(c2ccc(OC(F)(F)F)cc2)/C(=C(/C#N)c2cc(C#N)cc(C#N)c2)c2c1c(-c1ccc(C#N)cc1)c1c(c2-c2ccc(C#N)cc2)C(C#N)=C(c2ccc(OC(F)(F)F)cc2)/C1=C(/C#N)c1cc(C#N)cc(C#N)c1]

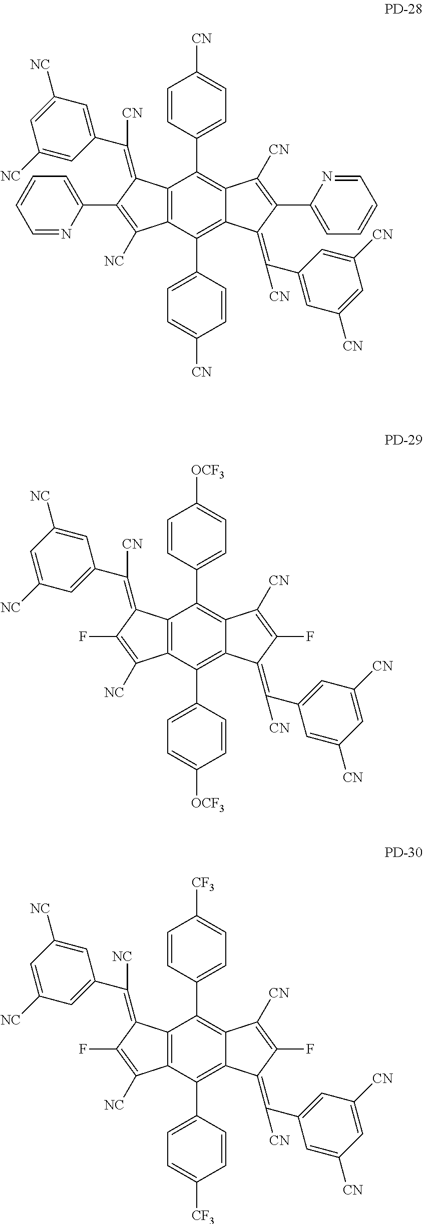 [SMILES: N#CC1=C(c2ccccn2)/C(=C(/C#N)c2cc(C#N)cc(C#N)c2)c2c1c(-c1ccc(C#N)cc1)c1c(c2-c2ccc(C#N)cc2)C(C#N)=C(c2ccccn2)/C1=C(/C#N)c1cc(C#N)cc(C#N)c1 ; N#CC1=C(F)/C(=C(/C#N)c2cc(C#N)cc(C#N)c2)c2c1c(-c1ccc(OC(F)(F)F)cc1)c1c(c2-c2ccc(OC(F)(F)F)cc2)C(C#N)=C(F)/C1=C(/C#N)c1cc(C#N)cc(C#N)c1 ; N#CC1=C(F)/C(=C(/C#N)c2cc(C#N)cc(C#N)c2)c2c1c(-c1ccc(C(F)(F)F)cc1)c1c(c2-c2ccc(C(F)(F)F)cc2)C(C#N)=C(F)/C1=C(/C#N)c1cc(C#N)cc(C#N)c1]

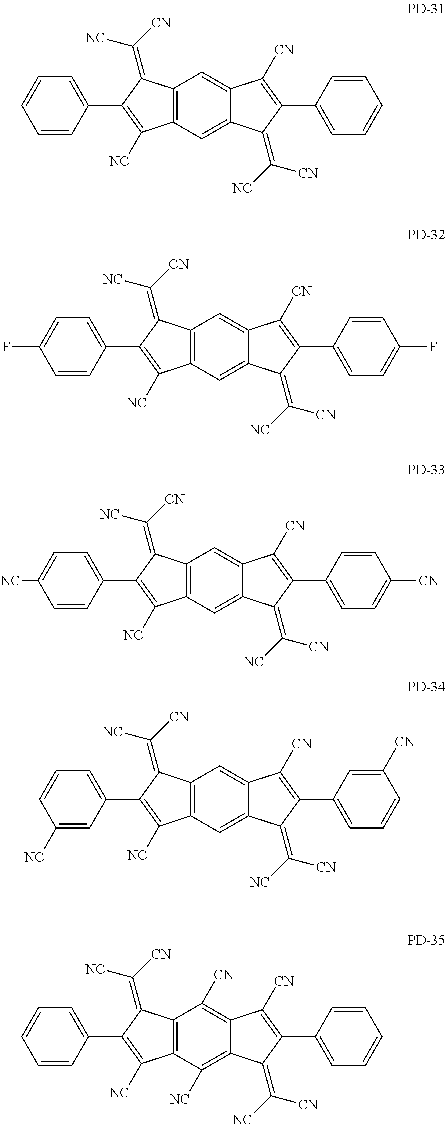

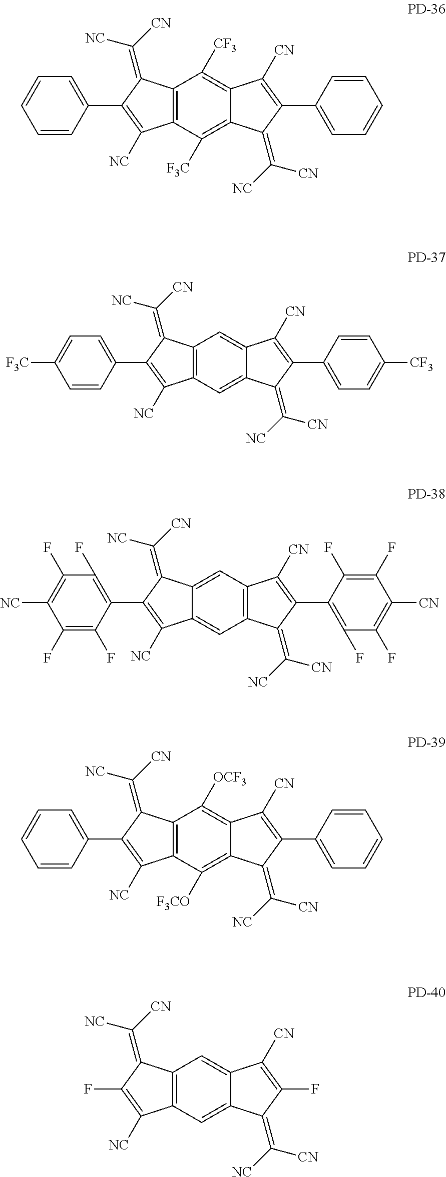 [SMILES: N#CC(C#N)=C1C(c2ccccc2)=C(C#N)c2c1c(C(F)(F)F)c1c(c2C(F)(F)F)C(=C(C#N)C#N)C(c2ccccc2)=C1C#N ; N#CC(C#N)=C1C(c2ccc(C(F)(F)F)cc2)=C(C#N)c2cc3c(cc21)C(C#N)=C(c1ccc(C(F)(F)F)cc1)C3=C(C#N)C#N ; N#CC(C#N)=C1C(c2c(F)c(F)c(C#N)c(F)c2F)=C(C#N)c2cc3c(cc21)C(C#N)=C(c1c(F)c(F)c(C#N)c(F)c1F)C3=C(C#N)C#N ; N#CC(C#N)=C1C(c2ccccc2)=C(C#N)c2c(OC(F)(F)F)c3c(c(OC(F)(F)F)c21)C(C#N)=C(c1ccccc1)C3=C(C#N)C#N ; N#CC(C#N)=C1C(F)=C(C#N)c2cc3c(cc21)C(C#N)=C(F)C3=C(C#N)C#N]

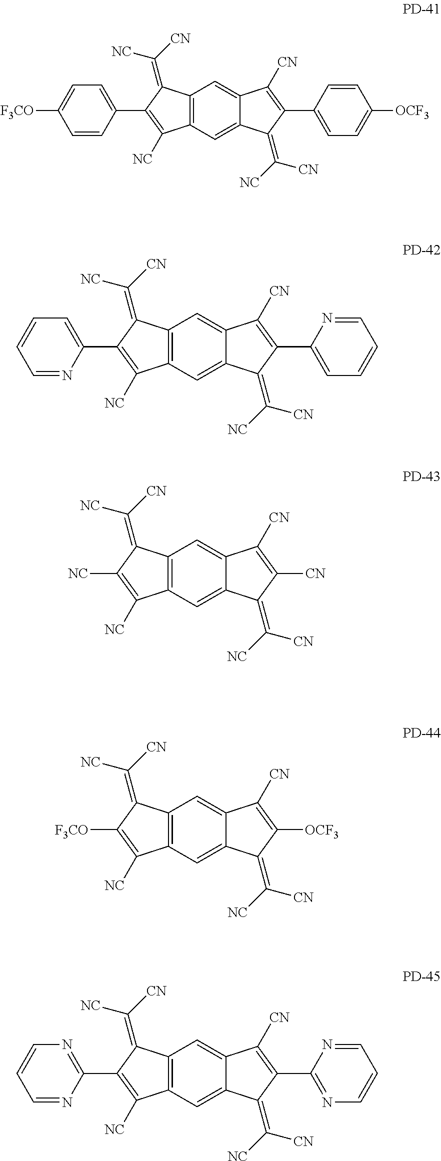 [SMILES: N#CC(C#N)=C1C(c2ccc(OC(F)(F)F)cc2)=C(C#N)c2cc3c(cc21)C(C#N)=C(c1ccc(OC(F)(F)F)cc1)C3=C(C#N)C#N ; N#CC(C#N)=C1C(c2ccccn2)=C(C#N)c2cc3c(cc21)C(C#N)=C(c1ccccn1)C3=C(C#N)C#N ; N#CC(C#N)=C1C(C#N)=C(C#N)c2cc3c(cc21)C(C#N)=C(C#N)C3=C(C#N)C#N ; N#CC(C#N)=C1C(OC(F)(F)F)=C(C#N)c2cc3c(cc21)C(C#N)=C(OC(F)(F)F)C3=C(C#N)C#N ; N#CC(C#N)=C1C(c2ncccn2)=C(C#N)c2cc3c(cc21)C(C#N)=C(c1ncccn1)C3=C(C#N)C#N]

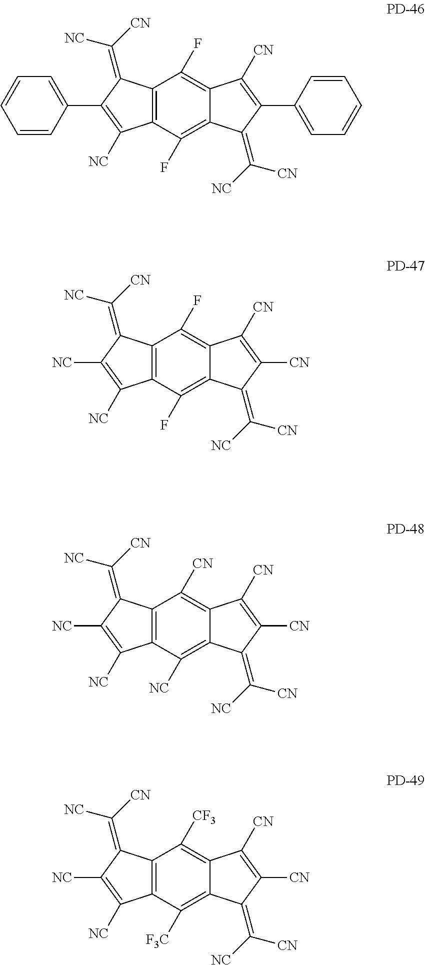 [SMILES: N#CC(C#N)=C1C(c2ccccc2)=C(C#N)c2c(F)c3c(c(F)c21)C(C#N)=C(c1ccccc1)C3=C(C#N)C#N ; N#CC(C#N)=C1C(C#N)=C(C#N)c2c(F)c3c(c(F)c21)C(C#N)=C(C#N)C3=C(C#N)C#N ; N#CC(C#N)=C1C(C#N)=C(C#N)c2c(C#N)c3c(c(C#N)c21)C(C#N)=C(C#N)C3=C(C#N)C#N ; N#CC(C#N)=C1C(C#N)=C(C#N)c2c1c(C(F)(F)F)c1c(c2C(F)(F)F)C(=C(C#N)C#N)C(C#N)=C1C#N]

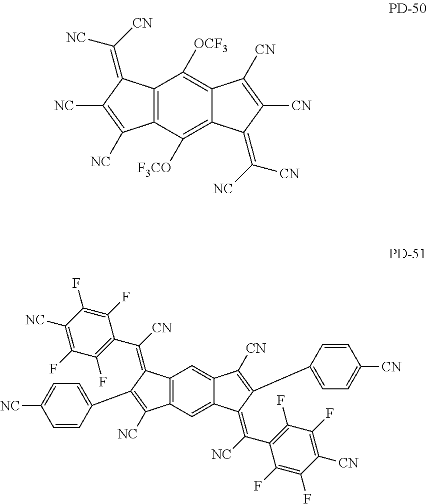 [SMILES: N#CC(C#N)=C1C(C#N)=C(C#N)c2c(OC(F)(F)F)c3c(c(OC(F)(F)F)c21)C(C#N)=C(C#N)C3=C(C#N)C#N ; N#CC1=C(c2ccc(C#N)cc2)/C(=C(/C#N)c2c(F)c(F)c(C#N)c(F)c2F)c2cc3c(cc21)/C(=C(\C#N)c1c(F)c(F)c(C#N)c(F)c1F)C(c1ccc(C#N)cc1)=C3C#N]

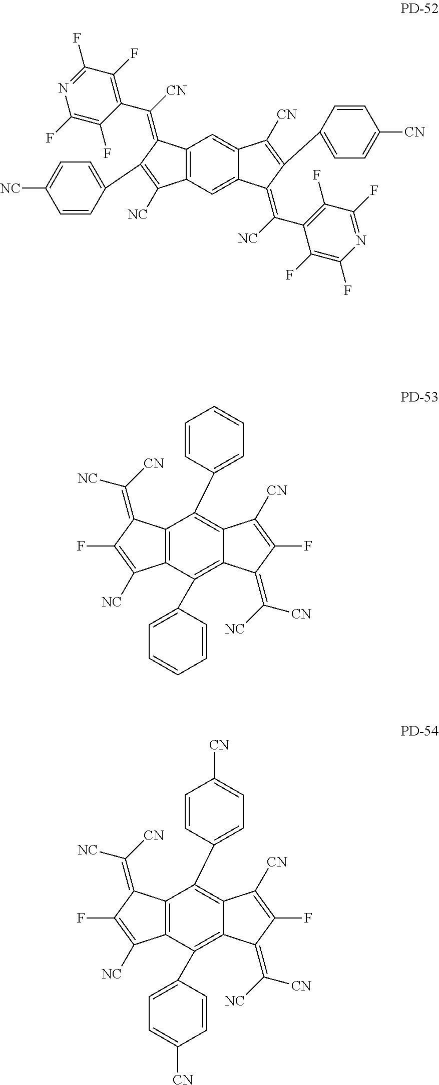 [SMILES: N#CC1=C(c2ccc(C#N)cc2)/C(=C(/C#N)c2c(F)c(F)nc(F)c2F)c2cc3c(cc21)/C(=C(\C#N)c1c(F)c(F)nc(F)c1F)C(c1ccc(C#N)cc1)=C3C#N ; N#CC(C#N)=C1C(F)=C(C#N)c2c1c(-c1ccccc1)c1c(c2-c2ccccc2)C(=C(C#N)C#N)C(F)=C1C#N ; N#CC(C#N)=C1C(F)=C(C#N)c2c1c(-c1ccc(C#N)cc1)c1c(c2-c2ccc(C#N)cc2)C(=C(C#N)C#N)C(F)=C1C#N]

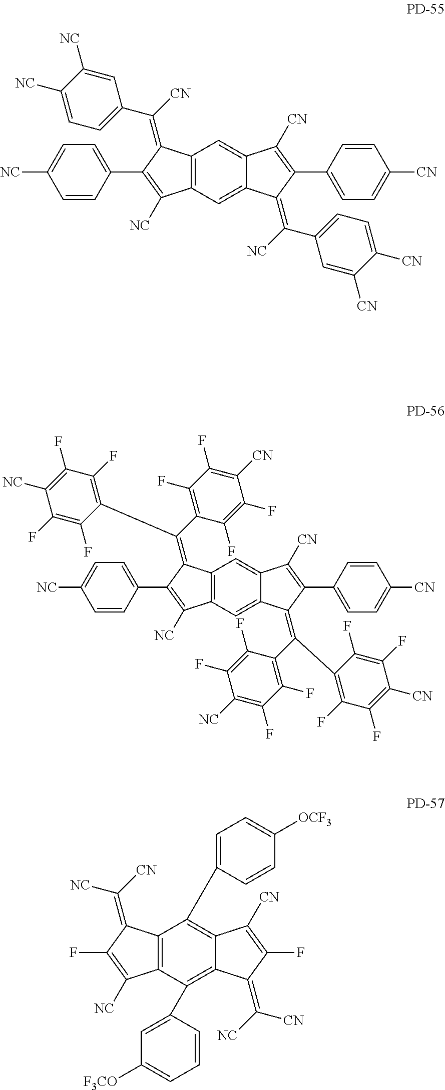 [SMILES: N#CC1=C(c2ccc(C#N)cc2)/C(=C(/C#N)c2ccc(C#N)c(C#N)c2)c2cc3c(cc21)/C(=C(\C#N)c1ccc(C#N)c(C#N)c1)C(c1ccc(C#N)cc1)=C3C#N ; N#CC1=C(c2ccc(C#N)cc2)C(=C(c2c(F)c(F)c(C#N)c(F)c2F)c2c(F)c(F)c(C#N)c(F)c2F)c2cc3c(cc21)C(=C(c1c(F)c(F)c(C#N)c(F)c1F)c1c(F)c(F)c(C#N)c(F)c1F)C(c1ccc(C#N)cc1)=C3C#N ; N#CC(C#N)=C1C(F)=C(C#N)c2c1c(-c1ccc(OC(F)(F)F)cc1)c1c(c2-c2cccc(OC(F)(F)F)c2)C(=C(C#N)C#N)C(F)=C1C#N]

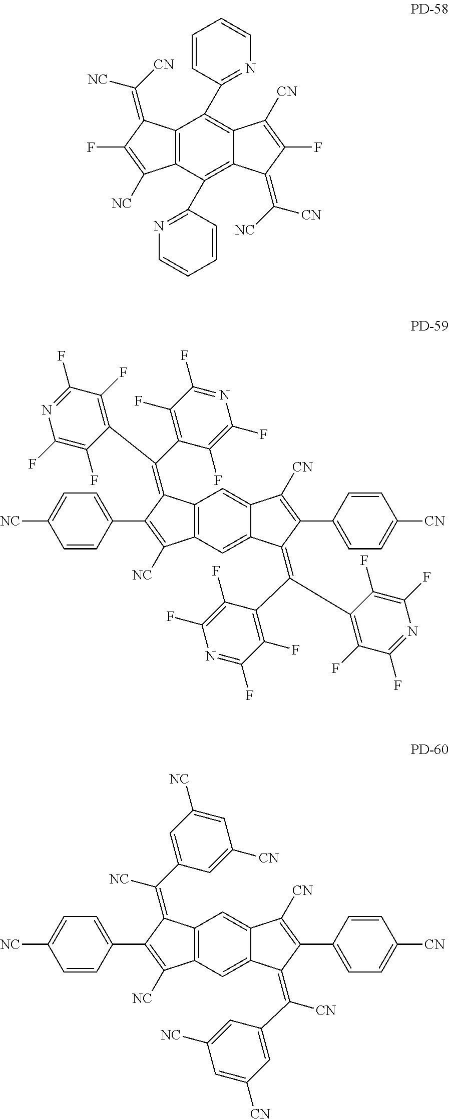 [SMILES: N#CC(C#N)=C1C(F)=C(C#N)c2c1c(-c1ccccn1)c1c(c2-c2ccccn2)C(=C(C#N)C#N)C(F)=C1C#N ; N#CC1=C(c2ccc(C#N)cc2)C(=C(c2c(F)c(F)nc(F)c2F)c2c(F)c(F)nc(F)c2F)c2cc3c(cc21)C(=C(c1c(F)c(F)nc(F)c1F)c1c(F)c(F)nc(F)c1F)C(c1ccc(C#N)cc1)=C3C#N ; N#CC1=C(c2ccc(C#N)cc2)/C(=C(\C#N)c2cc(C#N)cc(C#N)c2)c2cc3c(cc21)/C(=C(/C#N)c1cc(C#N)cc(C#N)c1)C(c1ccc(C#N)cc1)=C3C#N]

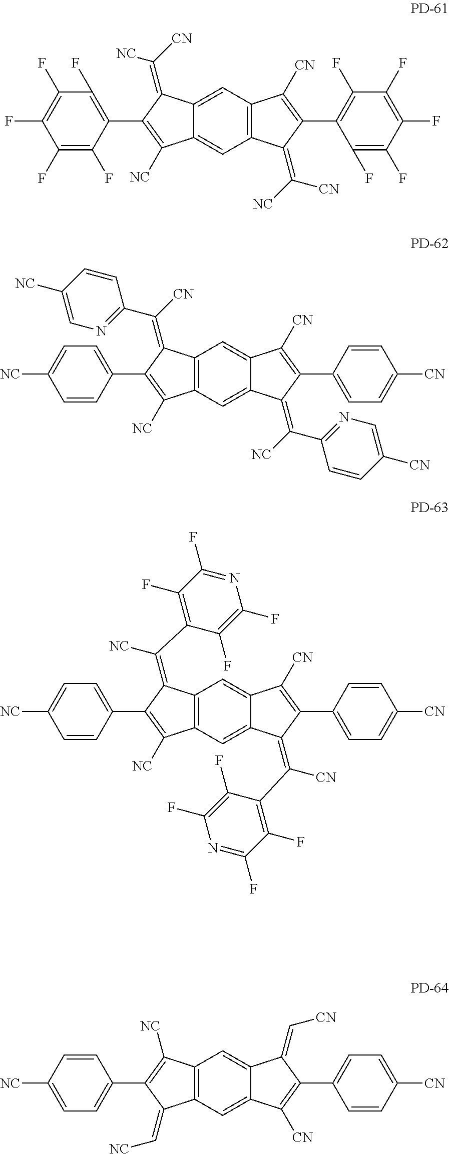

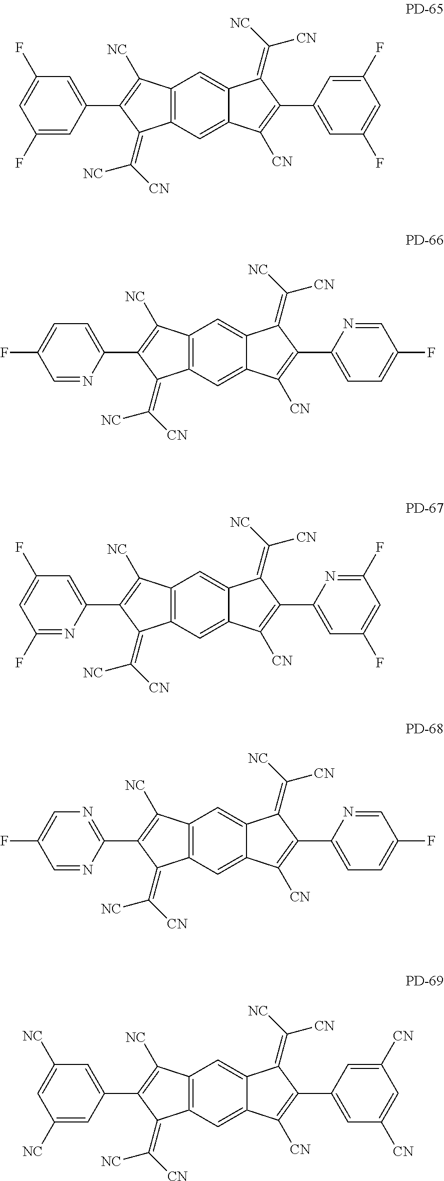 [SMILES: N#CC(C#N)=C1C(c2cc(F)cc(F)c2)=C(C#N)c2cc3c(cc21)C(C#N)=C(c1cc(F)cc(F)c1)C3=C(C#N)C#N ; N#CC(C#N)=C1C(c2ccc(F)cn2)=C(C#N)c2cc3c(cc21)C(C#N)=C(c1ccc(F)cn1)C3=C(C#N)C#N ; N#CC(C#N)=C1C(c2cc(F)cc(F)n2)=C(C#N)c2cc3c(cc21)C(C#N)=C(c1cc(F)cc(F)n1)C3=C(C#N)C#N ; N#CC(C#N)=C1C(c2ccc(F)cn2)=C(C#N)c2cc3c(cc21)C(C#N)=C(c1ncc(F)cn1)C3=C(C#N)C#N ; N#CC(C#N)=C1C(c2cc(C#N)cc(C#N)c2)=C(C#N)c2cc3c(cc21)C(C#N)=C(c1cc(C#N)cc(C#N)c1)C3=C(C#N)C#N]

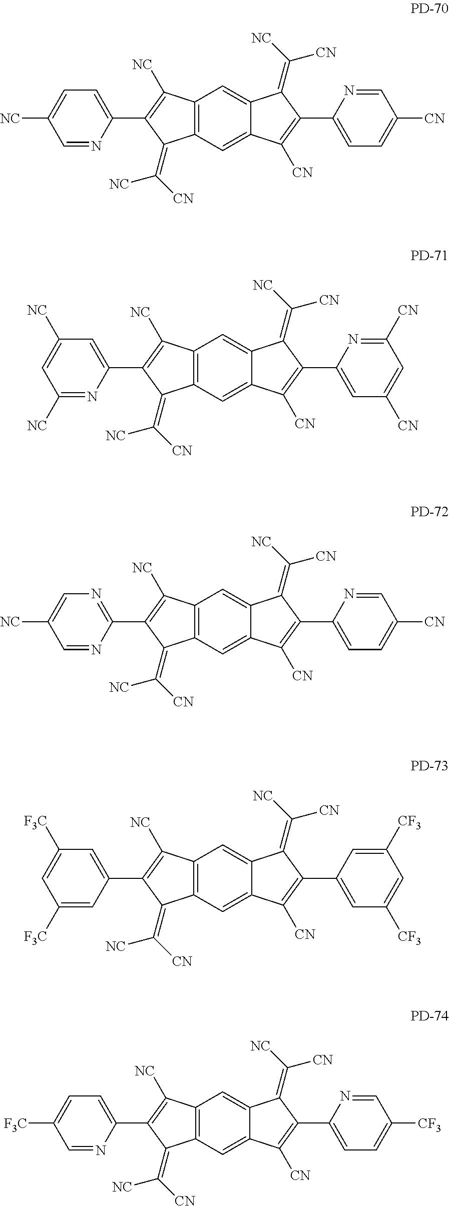 [SMILES: N#CC(C#N)=C1C(c2ccc(C#N)cn2)=C(C#N)c2cc3c(cc21)C(C#N)=C(c1ccc(C#N)cn1)C3=C(C#N)C#N ; N#CC(C#N)=C1C(c2cc(C#N)cc(C#N)n2)=C(C#N)c2cc3c(cc21)C(C#N)=C(c1cc(C#N)cc(C#N)n1)C3=C(C#N)C#N ; N#CC(C#N)=C1C(c2ccc(C#N)cn2)=C(C#N)c2cc3c(cc21)C(C#N)=C(c1ncc(C#N)cn1)C3=C(C#N)C#N ; N#CC(C#N)=C1C(c2cc(C(F)(F)F)cc(C(F)(F)F)c2)=C(C#N)c2cc3c(cc21)C(C#N)=C(c1cc(C(F)(F)F)cc(C(F)(F)F)c1)C3=C(C#N)C#N ; N#CC(C#N)=C1C(c2ccc(C(F)(F)F)cn2)=C(C#N)c2cc3c(cc21)C(C#N)=C(c1ccc(C(F)(F)F)cn1)C3=C(C#N)C#N]

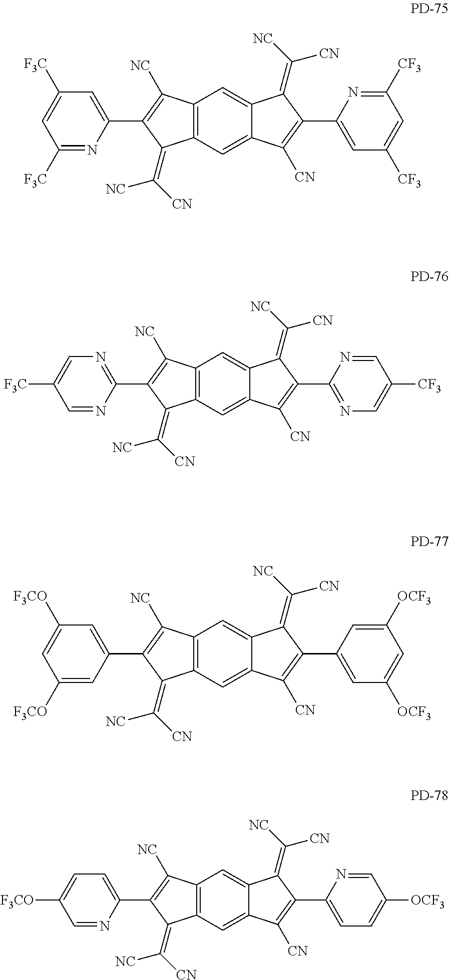 [SMILES: N#CC(C#N)=C1C(c2cc(C(F)(F)F)cc(C(F)(F)F)n2)=C(C#N)c2cc3c(cc21)C(C#N)=C(c1cc(C(F)(F)F)cc(C(F)(F)F)n1)C3=C(C#N)C#N ; N#CC(C#N)=C1C(c2ncc(C(F)(F)F)cn2)=C(C#N)c2cc3c(cc21)C(C#N)=C(c1ncc(C(F)(F)F)cn1)C3=C(C#N)C#N ; N#CC(C#N)=C1C(c2cc(OC(F)(F)F)cc(OC(F)(F)F)c2)=C(C#N)c2cc3c(cc21)C(C#N)=C(c1cc(OC(F)(F)F)cc(OC(F)(F)F)c1)C3=C(C#N)C#N ; N#CC(C#N)=C1C(c2ccc(OC(F)(F)F)cn2)=C(C#N)c2cc3c(cc21)C(C#N)=C(c1ccc(OC(F)(F)F)cn1)C3=C(C#N)C#N]

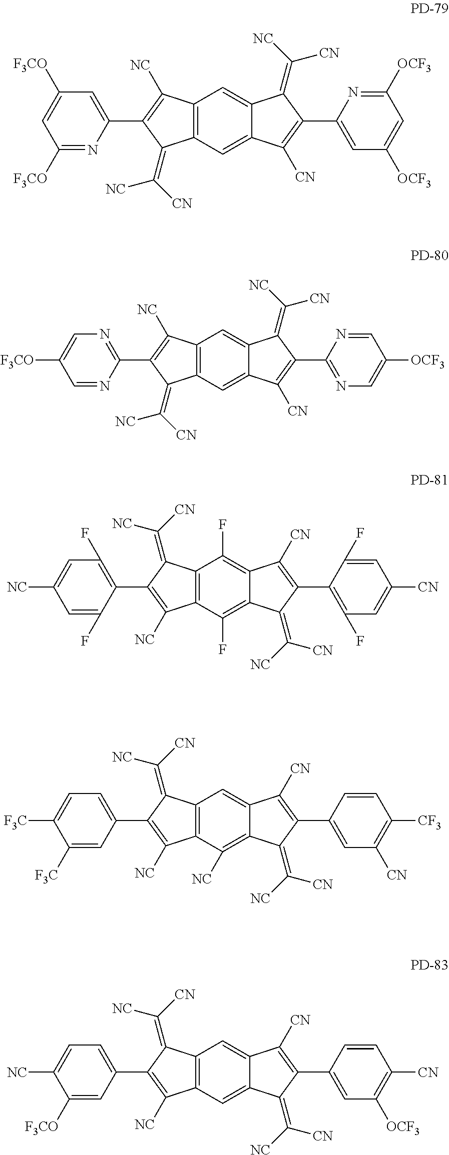

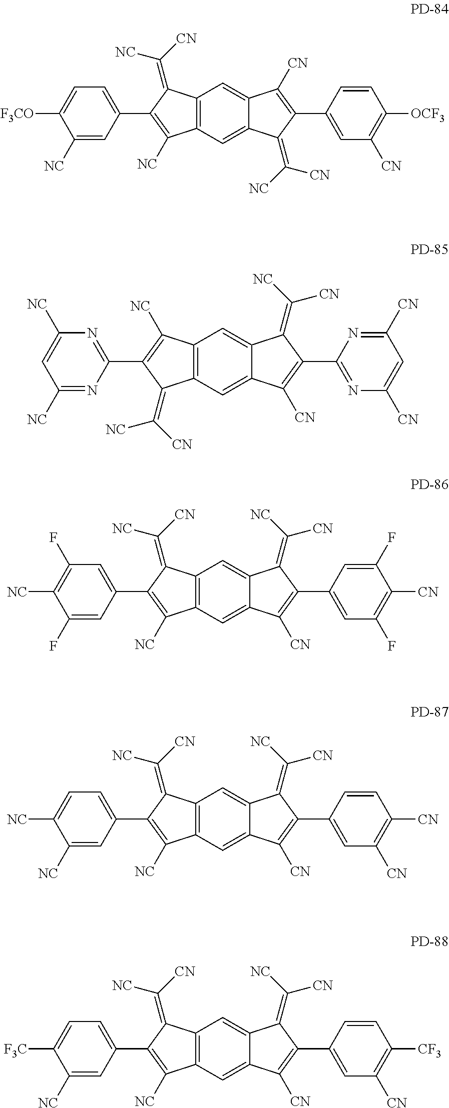 [SMILES: N#CC(C#N)=C1C(c2ccc(OC(F)(F)F)c(C#N)c2)=C(C#N)c2cc3c(cc21)C(C#N)=C(c1ccc(OC(F)(F)F)c(C#N)c1)C3=C(C#N)C#N ; N#CC(C#N)=C1C(c2nc(C#N)cc(C#N)n2)=C(C#N)c2cc3c(cc21)C(C#N)=C(c1nc(C#N)cc(C#N)n1)C3=C(C#N)C#N ; N#CC(C#N)=C1C(c2cc(F)c(C#N)c(F)c2)=C(C#N)c2cc3c(cc21)C(=C(C#N)C#N)C(c1cc(F)c(C#N)c(F)c1)=C3C#N ; N#CC(C#N)=C1C(c2ccc(C#N)c(C#N)c2)=C(C#N)c2cc3c(cc21)C(=C(C#N)C#N)C(c1ccc(C#N)c(C#N)c1)=C3C#N ; N#CC(C#N)=C1C(c2ccc(C(F)(F)F)c(C#N)c2)=C(C#N)c2cc3c(cc21)C(=C(C#N)C#N)C(c1ccc(C(F)(F)F)c(C#N)c1)=C3C#N]

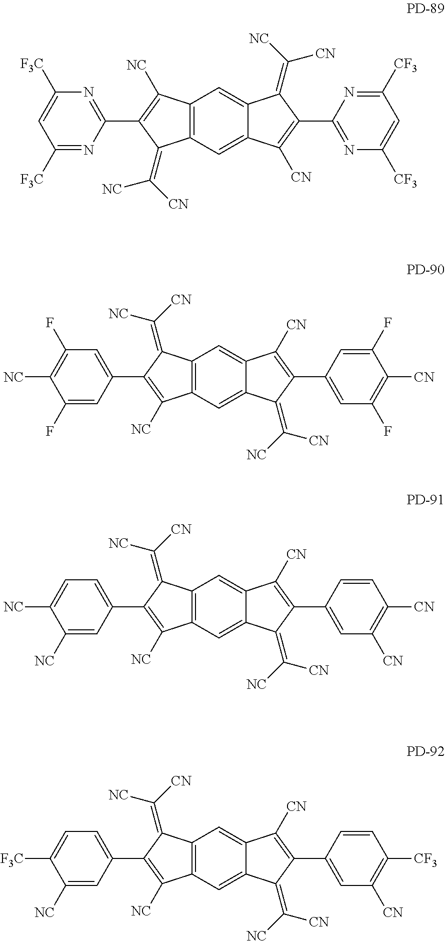 [SMILES: N#CC(C#N)=C1C(c2nc(C(F)(F)F)cc(C(F)(F)F)n2)=C(C#N)c2cc3c(cc21)C(C#N)=C(c1nc(C(F)(F)F)cc(C(F)(F)F)n1)C3=C(C#N)C#N ; N#CC(C#N)=C1C(c2cc(F)c(C#N)c(F)c2)=C(C#N)c2cc3c(cc21)C(C#N)=C(c1cc(F)c(C#N)c(F)c1)C3=C(C#N)C#N ; N#CC(C#N)=C1C(c2ccc(C#N)c(C#N)c2)=C(C#N)c2cc3c(cc21)C(C#N)=C(c1ccc(C#N)c(C#N)c1)C3=C(C#N)C#N ; N#CC(C#N)=C1C(c2ccc(C(F)(F)F)c(C#N)c2)=C(C#N)c2cc3c(cc21)C(C#N)=C(c1ccc(C(F)(F)F)c(C#N)c1)C3=C(C#N)C#N]

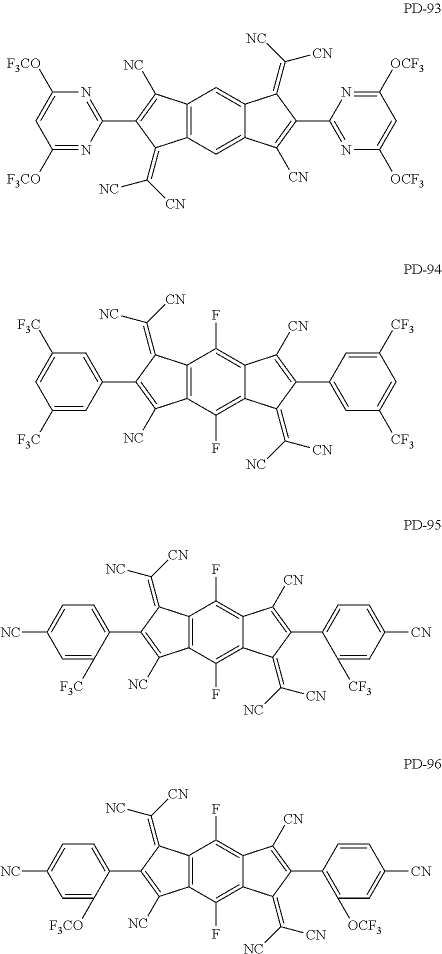 [SMILES: N#CC(C#N)=C1C(c2nc(OC(F)(F)F)cc(OC(F)(F)F)n2)=C(C#N)c2cc3c(cc21)C(C#N)=C(c1nc(OC(F)(F)F)cc(OC(F)(F)F)n1)C3=C(C#N)C#N ; N#CC(C#N)=C1C(c2cc(C(F)(F)F)cc(C(F)(F)F)c2)=C(C#N)c2c(F)c3c(c(F)c21)C(C#N)=C(c1cc(C(F)(F)F)cc(C(F)(F)F)c1)C3=C(C#N)C#N ; N#CC(C#N)=C1C(c2ccc(C#N)cc2C(F)(F)F)=C(C#N)c2c(F)c3c(c(F)c21)C(C#N)=C(c1ccc(C#N)cc1C(F)(F)F)C3=C(C#N)C#N ; N#CC(C#N)=C1C(c2ccc(C#N)cc2OC(F)(F)F)=C(C#N)c2c(F)c3c(c(F)c21)C(C#N)=C(c1ccc(C#N)cc1OC(F)(F)F)C3=C(C#N)C#N]

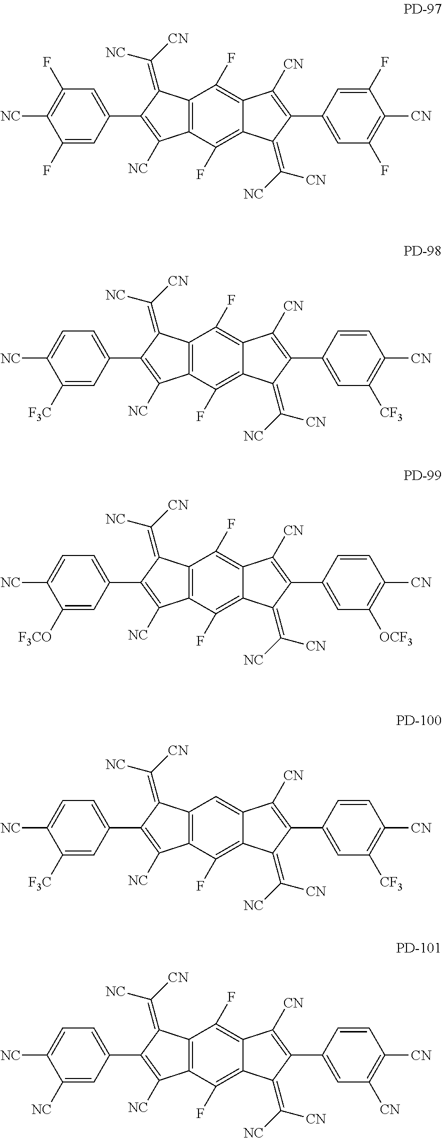

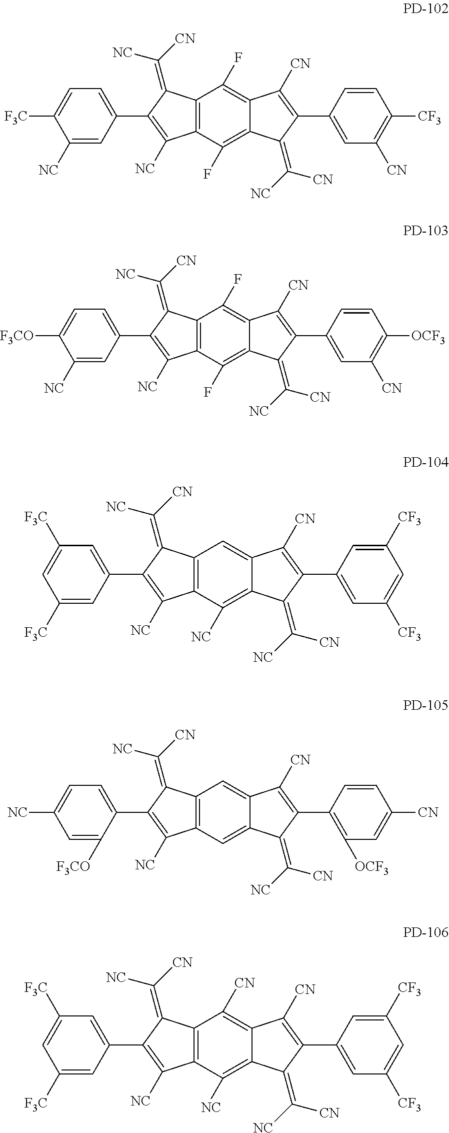

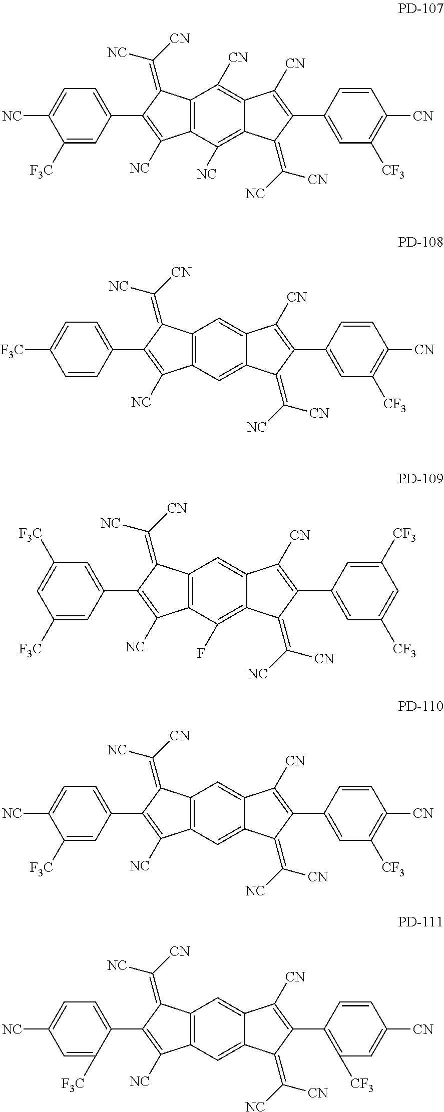

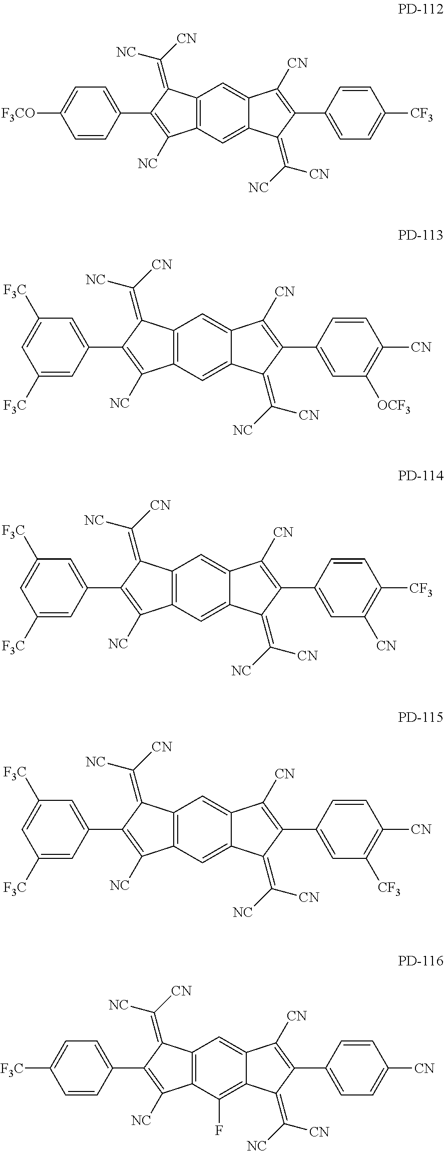

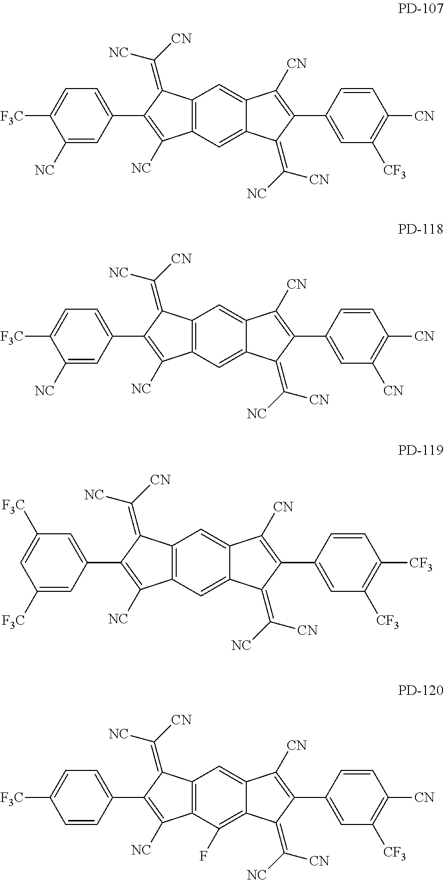 [SMILES: N#CC(C#N)=C1C(c2ccc(C(F)(F)F)c(C#N)c2)=C(C#N)c2cc3c(cc21)C(C#N)=C(c1ccc(C#N)c(C(F)(F)F)c1)C3=C(C#N)C#N ; N#CC(C#N)=C1C(c2ccc(C#N)c(C#N)c2)=C(C#N)c2cc3c(cc21)C(C#N)=C(c1ccc(C(F)(F)F)c(C#N)c1)C3=C(C#N)C#N ; N#CC(C#N)=C1C(c2cc(C(F)(F)F)cc(C(F)(F)F)c2)=C(C#N)c2cc3c(cc21)C(C#N)=C(c1ccc(C(F)(F)F)c(C(F)(F)F)c1)C3=C(C#N)C#N ; N#CC(C#N)=C1C(c2ccc(C(F)(F)F)cc2)=C(C#N)c2c1cc1c(c2F)C(=C(C#N)C#N)C(c2ccc(C#N)c(C(F)(F)F)c2)=C1C#N]

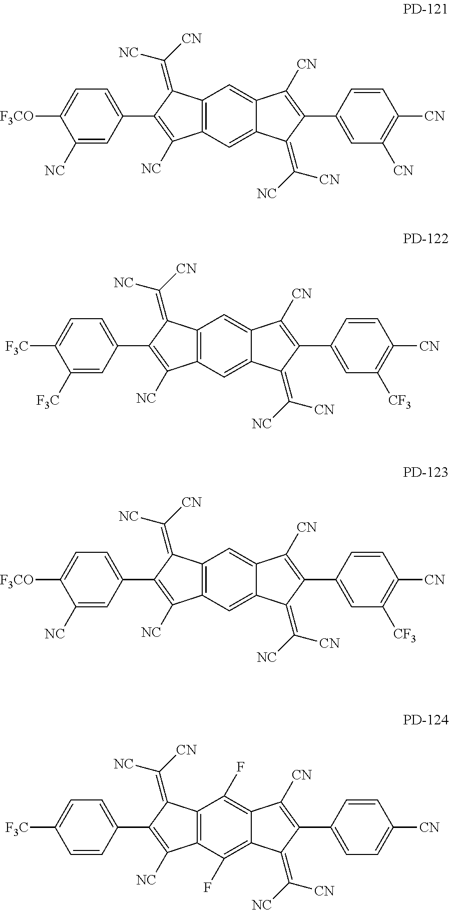 [SMILES: N#CC(C#N)=C1C(c2ccc(C#N)c(C#N)c2)=C(C#N)c2cc3c(cc21)C(C#N)=C(c1ccc(OC(F)(F)F)c(C#N)c1)C3=C(C#N)C#N ; N#CC(C#N)=C1C(c2ccc(C#N)c(C(F)(F)F)c2)=C(C#N)c2cc3c(cc21)C(C#N)=C(c1ccc(C(F)(F)F)c(C(F)(F)F)c1)C3=C(C#N)C#N ; N#CC(C#N)=C1C(c2ccc(OC(F)(F)F)c(C#N)c2)=C(C#N)c2cc3c(cc21)C(C#N)=C(c1ccc(C#N)c(C(F)(F)F)c1)C3=C(C#N)C#N ; N#CC(C#N)=C1C(c2ccc(C#N)cc2)=C(C#N)c2c(F)c3c(c(F)c21)C(C#N)=C(c1ccc(C(F)(F)F)cc1)C3=C(C#N)C#N]

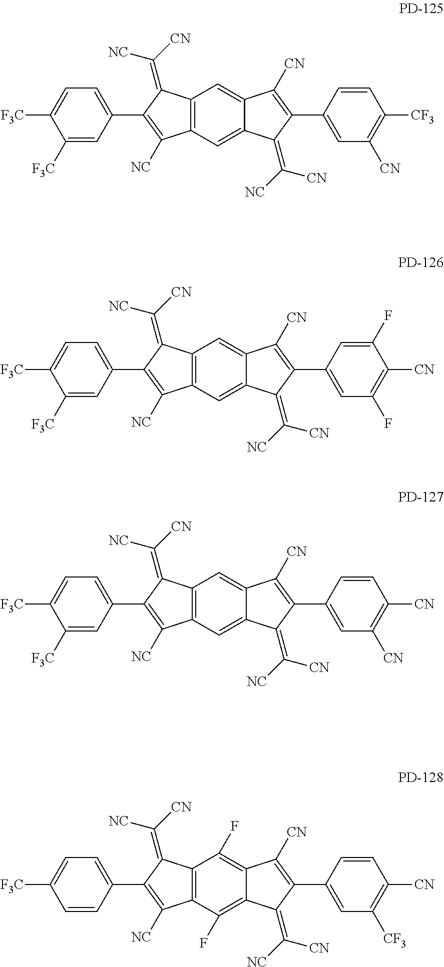 [SMILES: N#CC(C#N)=C1C(c2ccc(C(F)(F)F)c(C#N)c2)=C(C#N)c2cc3c(cc21)C(C#N)=C(c1ccc(C(F)(F)F)c(C(F)(F)F)c1)C3=C(C#N)C#N ; N#CC(C#N)=C1C(c2cc(F)c(C#N)c(F)c2)=C(C#N)c2cc3c(cc21)C(C#N)=C(c1ccc(C(F)(F)F)c(C(F)(F)F)c1)C3=C(C#N)C#N ; N#CC(C#N)=C1C(c2ccc(C#N)c(C#N)c2)=C(C#N)c2cc3c(cc21)C(C#N)=C(c1ccc(C(F)(F)F)c(C(F)(F)F)c1)C3=C(C#N)C#N ; N#CC(C#N)=C1C(c2ccc(C(F)(F)F)cc2)=C(C#N)c2c(F)c3c(c(F)c21)C(C#N)=C(c1ccc(C#N)c(C(F)(F)F)c1)C3=C(C#N)C#N]

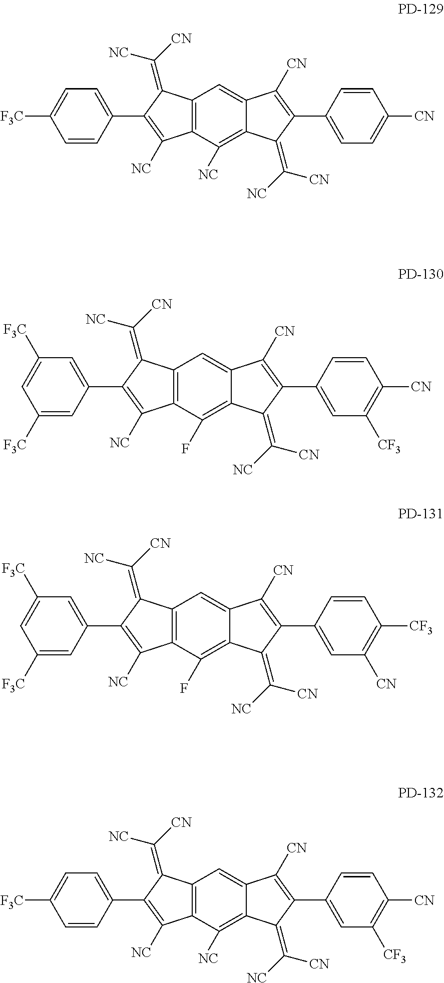

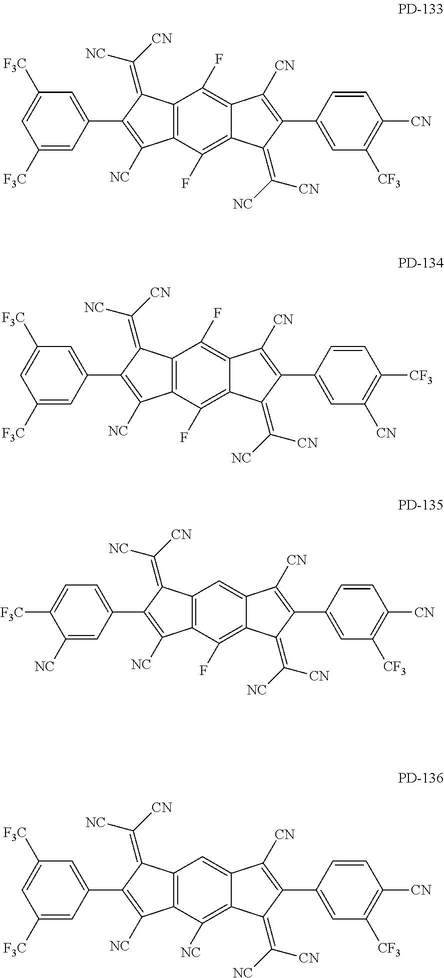

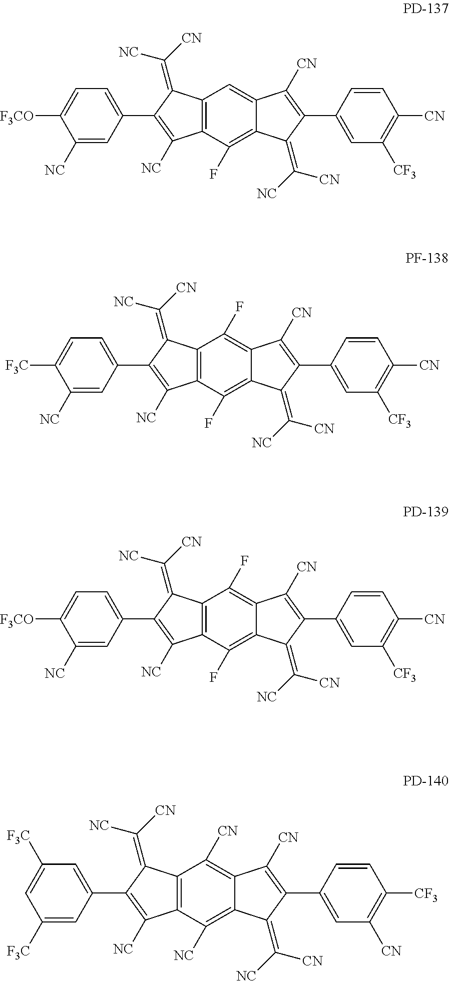 [SMILES: N#CC(C#N)=C1C(c2ccc(OC(F)(F)F)c(C#N)c2)=C(C#N)c2c1cc1c(c2F)C(=C(C#N)C#N)C(c2ccc(C#N)c(C(F)(F)F)c2)=C1C#N ; N#CC(C#N)=C1C(c2ccc(C(F)(F)F)c(C#N)c2)=C(C#N)c2c(F)c3c(c(F)c21)C(C#N)=C(c1ccc(C#N)c(C(F)(F)F)c1)C3=C(C#N)C#N ; N#CC(C#N)=C1C(c2ccc(OC(F)(F)F)c(C#N)c2)=C(C#N)c2c(F)c3c(c(F)c21)C(C#N)=C(c1ccc(C#N)c(C(F)(F)F)c1)C3=C(C#N)C#N ; N#CC(C#N)=C1C(c2cc(C(F)(F)F)cc(C(F)(F)F)c2)=C(C#N)c2c(C#N)c3c(c(C#N)c21)C(C#N)=C(c1ccc(C(F)(F)F)c(C#N)c1)C3=C(C#N)C#N]

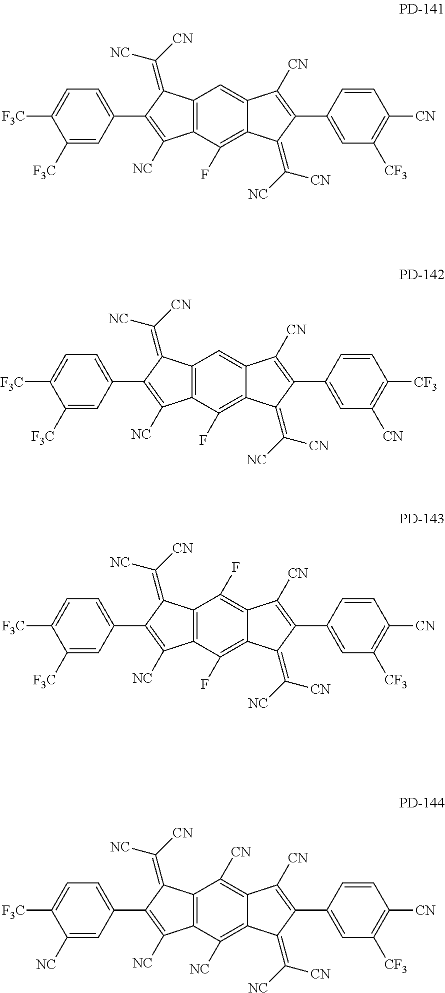 [SMILES: N#CC(C#N)=C1C(c2ccc(C(F)(F)F)c(C(F)(F)F)c2)=C(C#N)c2c1cc1c(c2F)C(=C(C#N)C#N)C(c2ccc(C#N)c(C(F)(F)F)c2)=C1C#N ; N#CC(C#N)=C1C(c2ccc(C(F)(F)F)c(C(F)(F)F)c2)=C(C#N)c2c1cc1c(c2F)C(=C(C#N)C#N)C(c2ccc(C(F)(F)F)c(C#N)c2)=C1C#N ; N#CC(C#N)=C1C(c2ccc(C#N)c(C(F)(F)F)c2)=C(C#N)c2c(F)c3c(c(F)c21)C(C#N)=C(c1ccc(C(F)(F)F)c(C(F)(F)F)c1)C3=C(C#N)C#N ; N#CC(C#N)=C1C(c2ccc(C(F)(F)F)c(C#N)c2)=C(C#N)c2c(C#N)c3c(c(C#N)c21)C(C#N)=C(c1ccc(C#N)c(C(F)(F)F)c1)C3=C(C#N)C#N]

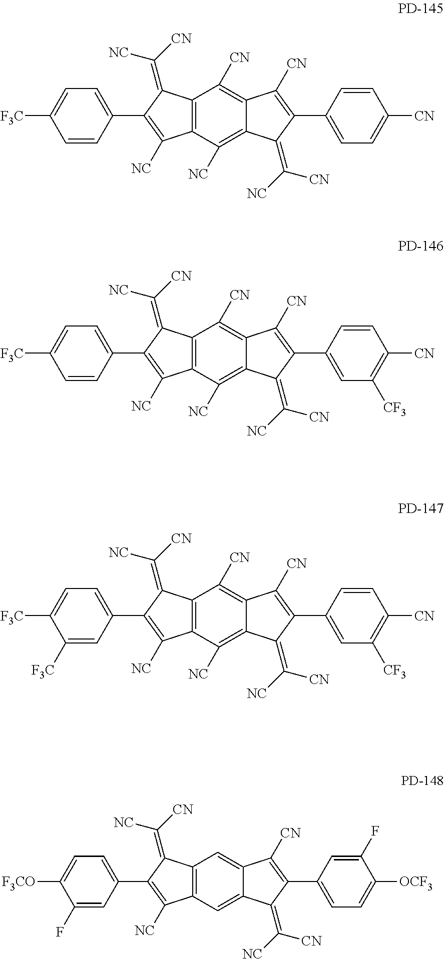 [SMILES: N#CC(C#N)=C1C(c2ccc(C#N)cc2)=C(C#N)c2c(C#N)c3c(c(C#N)c21)C(C#N)=C(c1ccc(C(F)(F)F)cc1)C3=C(C#N)C#N ; N#CC(C#N)=C1C(c2ccc(C(F)(F)F)cc2)=C(C#N)c2c(C#N)c3c(c(C#N)c21)C(C#N)=C(c1ccc(C#N)c(C(F)(F)F)c1)C3=C(C#N)C#N ; N#CC(C#N)=C1C(c2ccc(C#N)c(C(F)(F)F)c2)=C(C#N)c2c(C#N)c3c(c(C#N)c21)C(C#N)=C(c1ccc(C(F)(F)F)c(C(F)(F)F)c1)C3=C(C#N)C#N ; N#CC(C#N)=C1C(c2ccc(OC(F)(F)F)c(F)c2)=C(C#N)c2cc3c(cc21)C(C#N)=C(c1ccc(OC(F)(F)F)c(F)c1)C3=C(C#N)C#N]

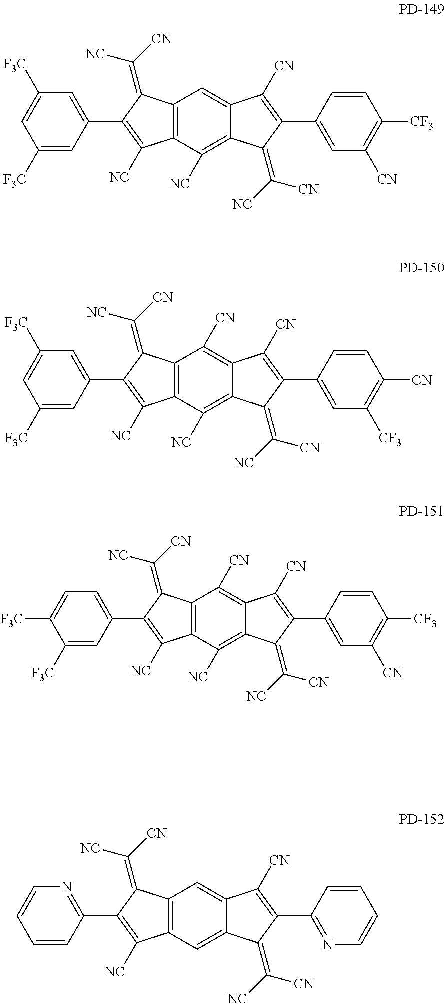 [SMILES: N#CC(C#N)=C1C(c2cc(C(F)(F)F)cc(C(F)(F)F)c2)=C(C#N)c2c1cc1c(c2C#N)C(=C(C#N)C#N)C(c2ccc(C(F)(F)F)c(C#N)c2)=C1C#N ; N#CC(C#N)=C1C(c2cc(C(F)(F)F)cc(C(F)(F)F)c2)=C(C#N)c2c(C#N)c3c(c(C#N)c21)C(C#N)=C(c1ccc(C#N)c(C(F)(F)F)c1)C3=C(C#N)C#N ; N#CC(C#N)=C1C(c2ccc(C(F)(F)F)c(C#N)c2)=C(C#N)c2c(C#N)c3c(c(C#N)c21)C(C#N)=C(c1ccc(C(F)(F)F)c(C(F)(F)F)c1)C3=C(C#N)C#N ; N#CC(C#N)=C1C(c2ccccn2)=C(C#N)c2cc3c(cc21)C(C#N)=C(c1ccccn1)C3=C(C#N)C#N]

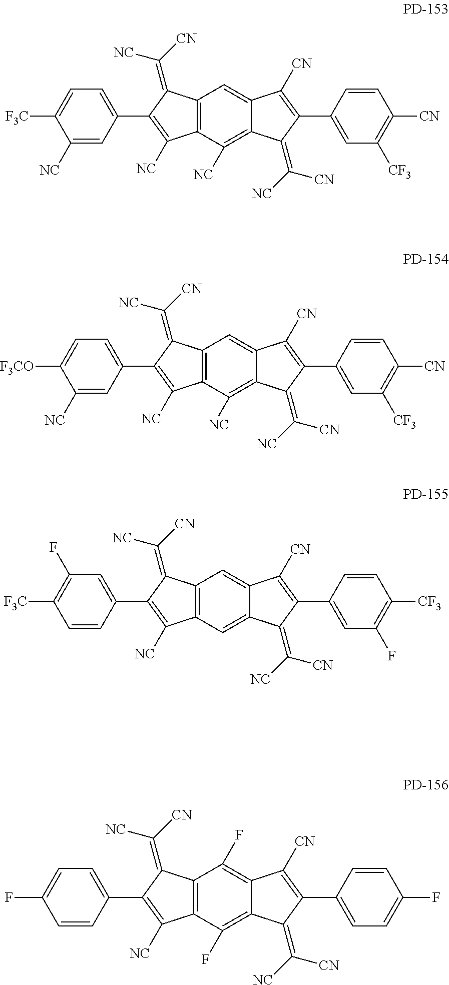

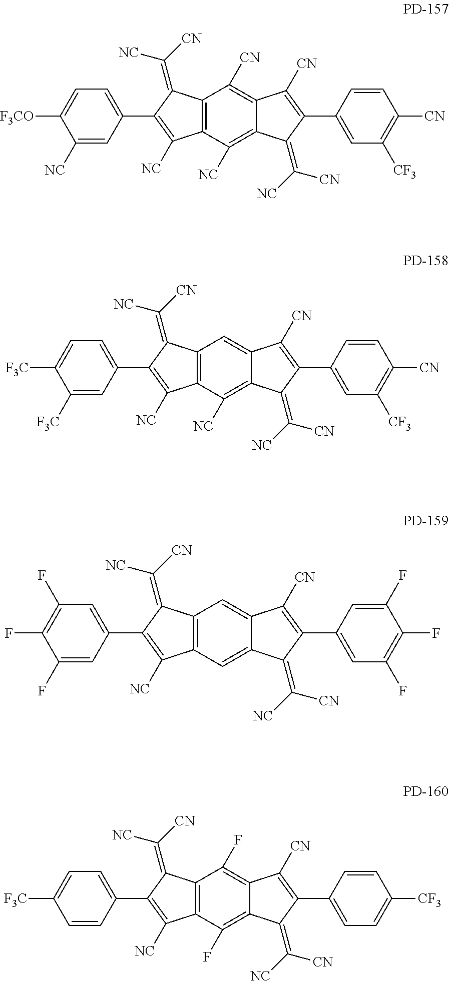 [SMILES: N#CC(C#N)=C1C(c2ccc(OC(F)(F)F)c(C#N)c2)=C(C#N)c2c(C#N)c3c(c(C#N)c21)C(C#N)=C(c1ccc(C#N)c(C(F)(F)F)c1)C3=C(C#N)C#N ; N#CC(C#N)=C1C(c2ccc(C(F)(F)F)c(C(F)(F)F)c2)=C(C#N)c2c1cc1c(c2C#N)C(=C(C#N)C#N)C(c2ccc(C#N)c(C(F)(F)F)c2)=C1C#N ; N#CC(C#N)=C1C(c2cc(F)c(F)c(F)c2)=C(C#N)c2cc3c(cc21)C(C#N)=C(c1cc(F)c(F)c(F)c1)C3=C(C#N)C#N ; N#CC(C#N)=C1C(c2ccc(C(F)(F)F)cc2)=C(C#N)c2c(F)c3c(c(F)c21)C(C#N)=C(c1ccc(C(F)(F)F)cc1)C3=C(C#N)C#N]

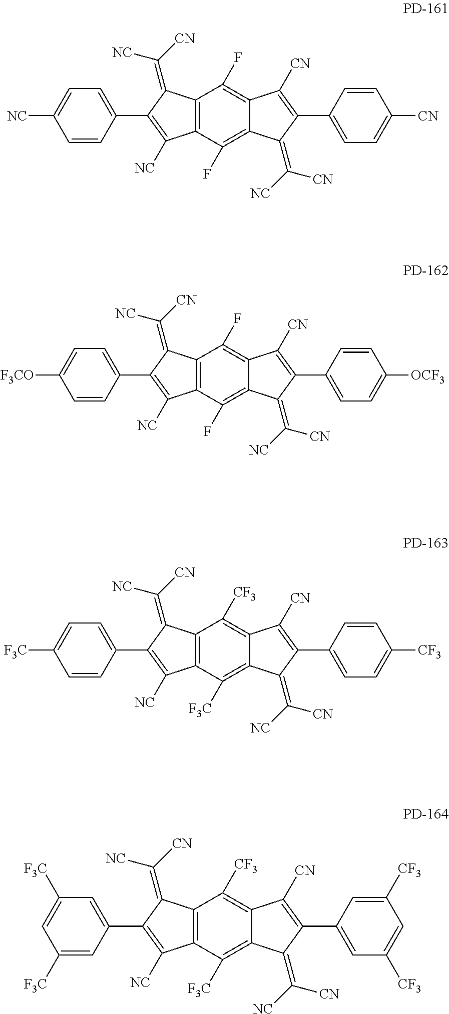 [SMILES: N#CC(C#N)=C1C(c2ccc(C#N)cc2)=C(C#N)c2c(F)c3c(c(F)c21)C(C#N)=C(c1ccc(C#N)cc1)C3=C(C#N)C#N ; N#CC(C#N)=C1C(c2ccc(OC(F)(F)F)cc2)=C(C#N)c2c(F)c3c(c(F)c21)C(C#N)=C(c1ccc(OC(F)(F)F)cc1)C3=C(C#N)C#N ; N#CC(C#N)=C1C(c2ccc(C(F)(F)F)cc2)=C(C#N)c2c1c(C(F)(F)F)c1c(c2C(F)(F)F)C(=C(C#N)C#N)C(c2ccc(C(F)(F)F)cc2)=C1C#N ; N#CC(C#N)=C1C(c2cc(C(F)(F)F)cc(C(F)(F)F)c2)=C(C#N)c2c1c(C(F)(F)F)c1c(c2C(F)(F)F)C(=C(C#N)C#N)C(c2cc(C(F)(F)F)cc(C(F)(F)F)c2)=C1C#N]

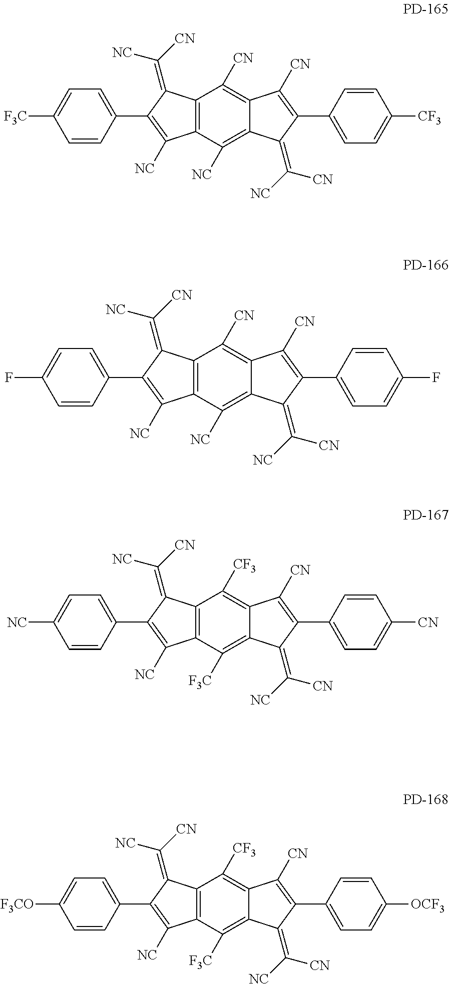 [SMILES: N#CC(C#N)=C1C(c2ccc(C(F)(F)F)cc2)=C(C#N)c2c(C#N)c3c(c(C#N)c21)C(C#N)=C(c1ccc(C(F)(F)F)cc1)C3=C(C#N)C#N ; N#CC(C#N)=C1C(c2ccc(F)cc2)=C(C#N)c2c(C#N)c3c(c(C#N)c21)C(C#N)=C(c1ccc(F)cc1)C3=C(C#N)C#N ; N#CC(C#N)=C1C(c2ccc(C#N)cc2)=C(C#N)c2c1c(C(F)(F)F)c1c(c2C(F)(F)F)C(=C(C#N)C#N)C(c2ccc(C#N)cc2)=C1C#N ; N#CC(C#N)=C1C(c2ccc(OC(F)(F)F)cc2)=C(C#N)c2c1c(C(F)(F)F)c1c(c2C(F)(F)F)C(=C(C#N)C#N)C(c2ccc(OC(F)(F)F)cc2)=C1C#N]

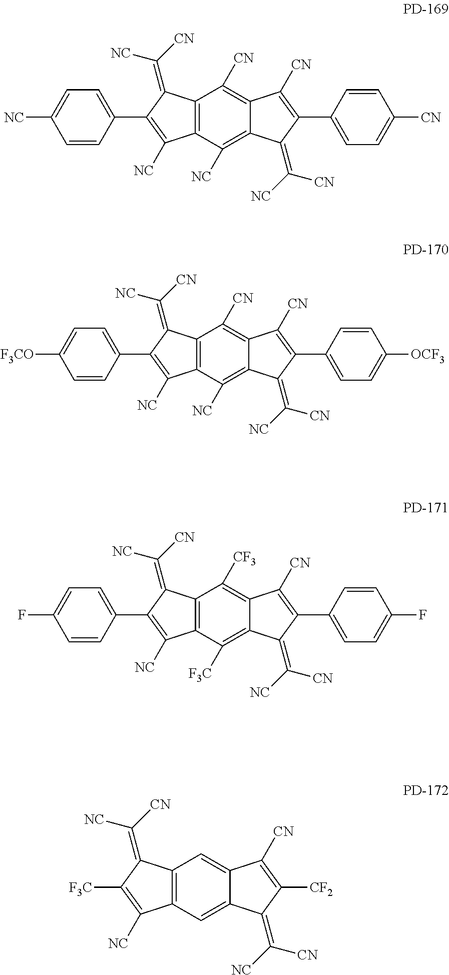

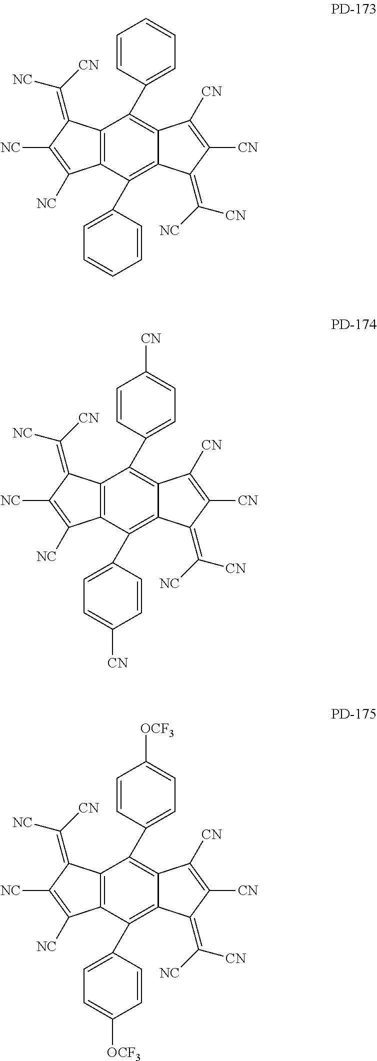 [SMILES: N#CC(C#N)=C1C(C#N)=C(C#N)c2c1c(-c1ccccc1)c1c(c2-c2ccccc2)C(=C(C#N)C#N)C(C#N)=C1C#N ; N#CC(C#N)=C1C(C#N)=C(C#N)c2c1c(-c1ccc(C#N)cc1)c1c(c2-c2ccc(C#N)cc2)C(=C(C#N)C#N)C(C#N)=C1C#N ; N#CC(C#N)=C1C(C#N)=C(C#N)c2c1c(-c1ccc(OC(F)(F)F)cc1)c1c(c2-c2ccc(OC(F)(F)F)cc2)C(=C(C#N)C#N)C(C#N)=C1C#N]

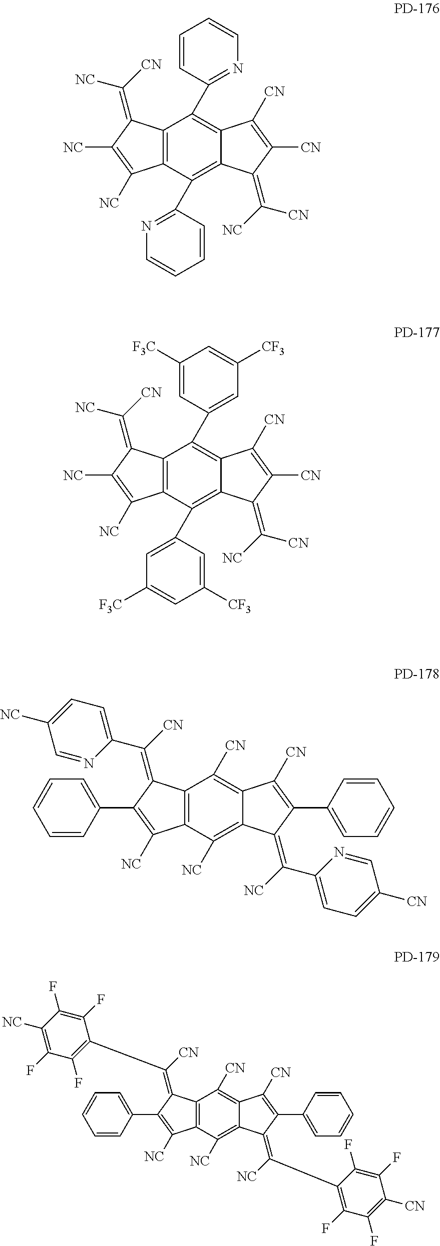 [SMILES: N#CC(C#N)=C1C(C#N)=C(C#N)c2c1c(-c1ccccn1)c1c(c2-c2ccccn2)C(=C(C#N)C#N)C(C#N)=C1C#N ; N#CC(C#N)=C1C(C#N)=C(C#N)c2c1c(-c1cc(C(F)(F)F)cc(C(F)(F)F)c1)c1c(c2-c2cc(C(F)(F)F)cc(C(F)(F)F)c2)C(=C(C#N)C#N)C(C#N)=C1C#N ; N#CC1=C(c2ccccc2)/C(=C(/C#N)c2ccc(C#N)cn2)c2c(C#N)c3c(c(C#N)c21)/C(=C(\C#N)c1ccc(C#N)cn1)C(c1ccccc1)=C3C#N ; N#CC1=C(c2ccccc2)/C(=C(/C#N)c2c(F)c(F)c(C#N)c(F)c2F)c2c(C#N)c3c(c(C#N)c21)/C(=C(\C#N)c1c(F)c(F)c(C#N)c(F)c1F)C(c1ccccc1)=C3C#N]

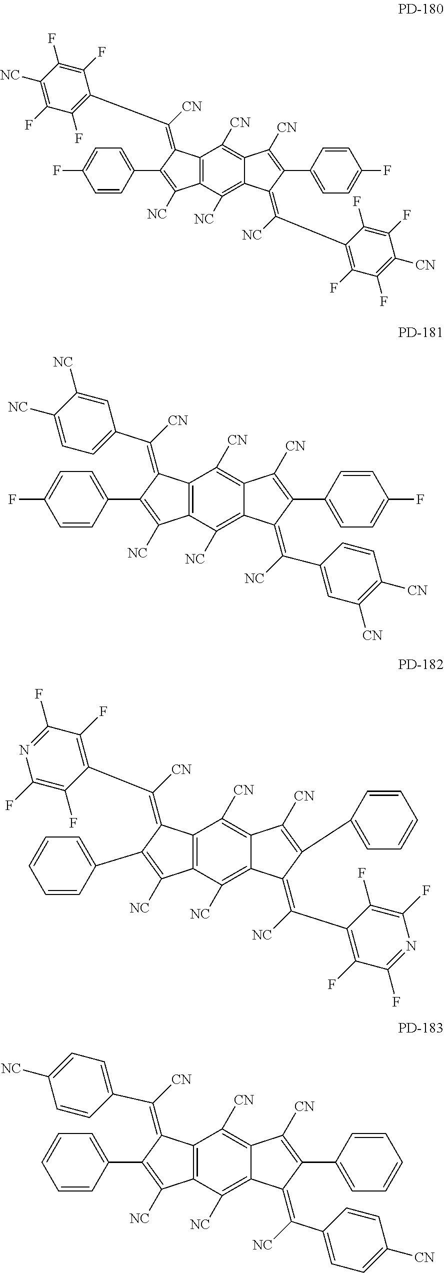 [SMILES: N#CC1=C(c2ccc(F)cc2)/C(=C(/C#N)c2c(F)c(F)c(C#N)c(F)c2F)c2c(C#N)c3c(c(C#N)c21)/C(=C(\C#N)c1c(F)c(F)c(C#N)c(F)c1F)C(c1ccc(F)cc1)=C3C#N ; N#CC1=C(c2ccc(F)cc2)/C(=C(/C#N)c2ccc(C#N)c(C#N)c2)c2c(C#N)c3c(c(C#N)c21)/C(=C(\C#N)c1ccc(C#N)c(C#N)c1)C(c1ccc(F)cc1)=C3C#N ; N#CC1=C(c2ccccc2)/C(=C(/C#N)c2c(F)c(F)nc(F)c2F)c2c(C#N)c3c(c(C#N)c21)/C(=C(\C#N)c1c(F)c(F)nc(F)c1F)C(c1ccccc1)=C3C#N ; N#CC1=C(c2ccccc2)/C(=C(/C#N)c2ccc(C#N)cc2)c2c(C#N)c3c(c(C#N)c21)/C(=C(\C#N)c1ccc(C#N)cc1)C(c1ccccc1)=C3C#N]

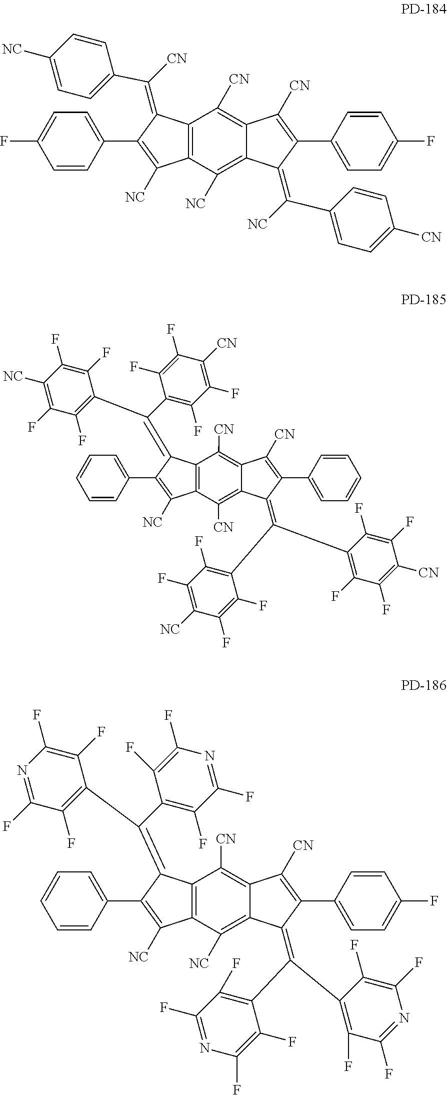 [SMILES: N#CC1=C(c2ccc(F)cc2)/C(=C(/C#N)c2ccc(C#N)cc2)c2c(C#N)c3c(c(C#N)c21)/C(=C(\C#N)c1ccc(C#N)cc1)C(c1ccc(F)cc1)=C3C#N ; N#CC1=C(c2ccccc2)C(=C(c2c(F)c(F)c(C#N)c(F)c2F)c2c(F)c(F)c(C#N)c(F)c2F)c2c(C#N)c3c(c(C#N)c21)C(=C(c1c(F)c(F)c(C#N)c(F)c1F)c1c(F)c(F)c(C#N)c(F)c1F)C(c1ccccc1)=C3C#N ; N#CC1=C(c2ccccc2)C(=C(c2c(F)c(F)nc(F)c2F)c2c(F)c(F)nc(F)c2F)c2c(C#N)c3c(c(C#N)c21)C(=C(c1c(F)c(F)nc(F)c1F)c1c(F)c(F)nc(F)c1F)C(c1ccc(F)cc1)=C3C#N]

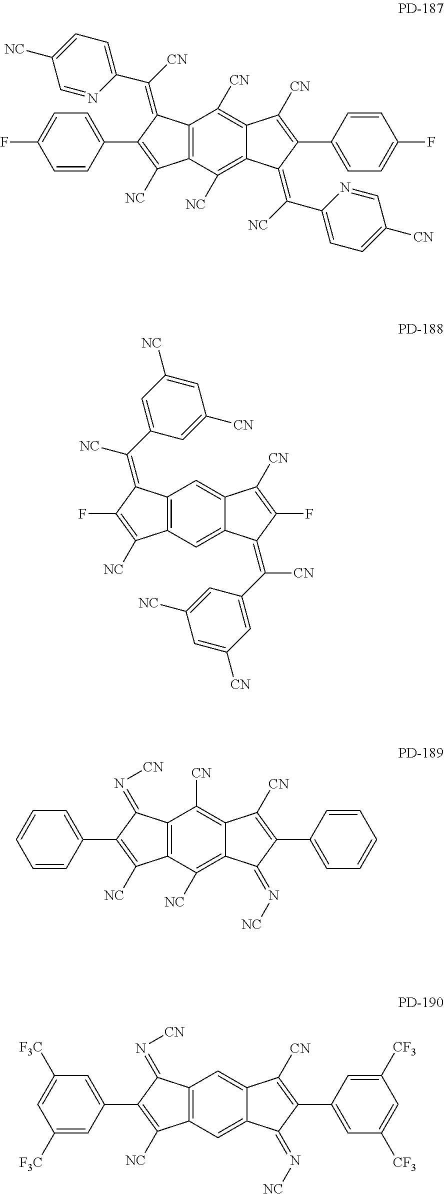 [SMILES: N#CC1=C(c2ccc(F)cc2)/C(=C(/C#N)c2ccc(C#N)cn2)c2c(C#N)c3c(c(C#N)c21)/C(=C(\C#N)c1ccc(C#N)cn1)C(c1ccc(F)cc1)=C3C#N ; N#CC1=C(F)/C(=C(\C#N)c2cc(C#N)cc(C#N)c2)c2cc3c(cc21)/C(=C(/C#N)c1cc(C#N)cc(C#N)c1)C(F)=C3C#N ; N#C/N=c1/c(-c2ccccc2)c(C#N)c2c(C#N)c3/c(=N\C#N)c(-c4ccccc4)c(C#N)c3c(C#N)c12 ; N#C/N=c1/c(-c2cc(C(F)(F)F)cc(C(F)(F)F)c2)c(C#N)c2cc3/c(=N\C#N)c(-c4cc(C(F)(F)F)cc(C(F)(F)F)c4)c(C#N)c3cc12]

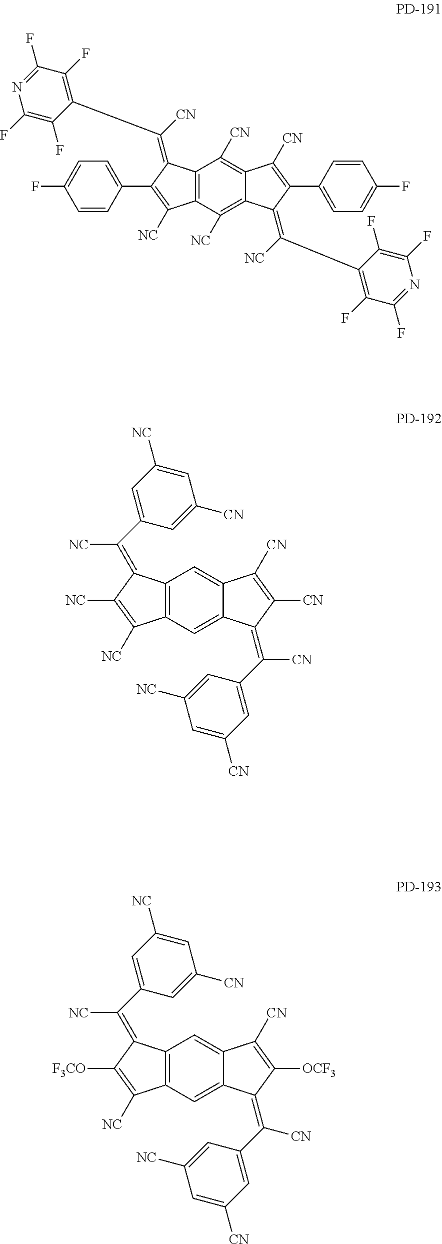 [SMILES: N#CC1=C(c2ccc(F)cc2)/C(=C(/C#N)c2c(F)c(F)nc(F)c2F)c2c(C#N)c3c(c(C#N)c21)/C(=C(\C#N)c1c(F)c(F)nc(F)c1F)C(c1ccc(F)cc1)=C3C#N ; N#CC1=C(C#N)c2cc3c(cc2/C1=C(/C#N)c1cc(C#N)cc(C#N)c1)C(C#N)=C(C#N)/C3=C(\C#N)c1cc(C#N)cc(C#N)c1 ; N#CC1=C(OC(F)(F)F)/C(=C(\C#N)c2cc(C#N)cc(C#N)c2)c2cc3c(cc21)/C(=C(/C#N)c1cc(C#N)cc(C#N)c1)C(OC(F)(F)F)=C3C#N]

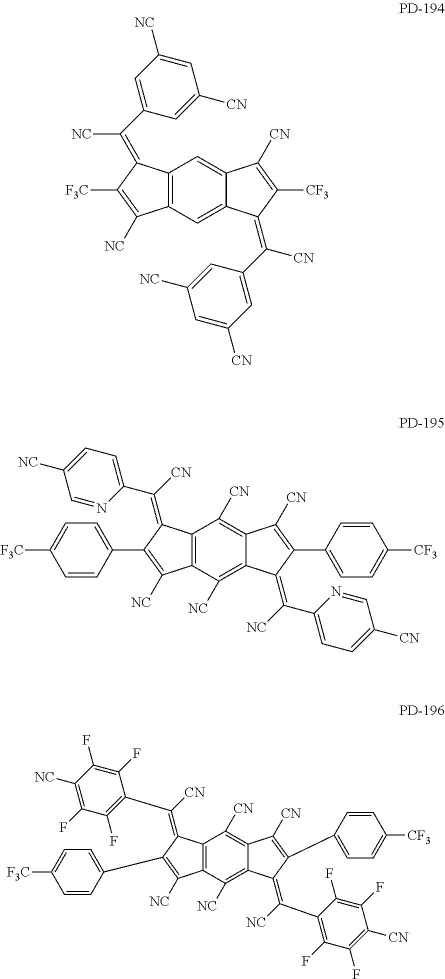 [SMILES: N#CC1=C(C(F)(F)F)/C(=C(\C#N)c2cc(C#N)cc(C#N)c2)c2cc3c(cc21)/C(=C(/C#N)c1cc(C#N)cc(C#N)c1)C(C(F)(F)F)=C3C#N ; N#CC1=C(c2ccc(C(F)(F)F)cc2)/C(=C(/C#N)c2ccc(C#N)cn2)c2c(C#N)c3c(c(C#N)c21)/C(=C(\C#N)c1ccc(C#N)cn1)C(c1ccc(C(F)(F)F)cc1)=C3C#N ; N#CC1=C(c2ccc(C(F)(F)F)cc2)/C(=C(/C#N)c2c(F)c(F)c(C#N)c(F)c2F)c2c(C#N)c3c(c(C#N)c21)/C(=C(\C#N)c1c(F)c(F)c(C#N)c(F)c1F)C(c1ccc(C(F)(F)F)cc1)=C3C#N]

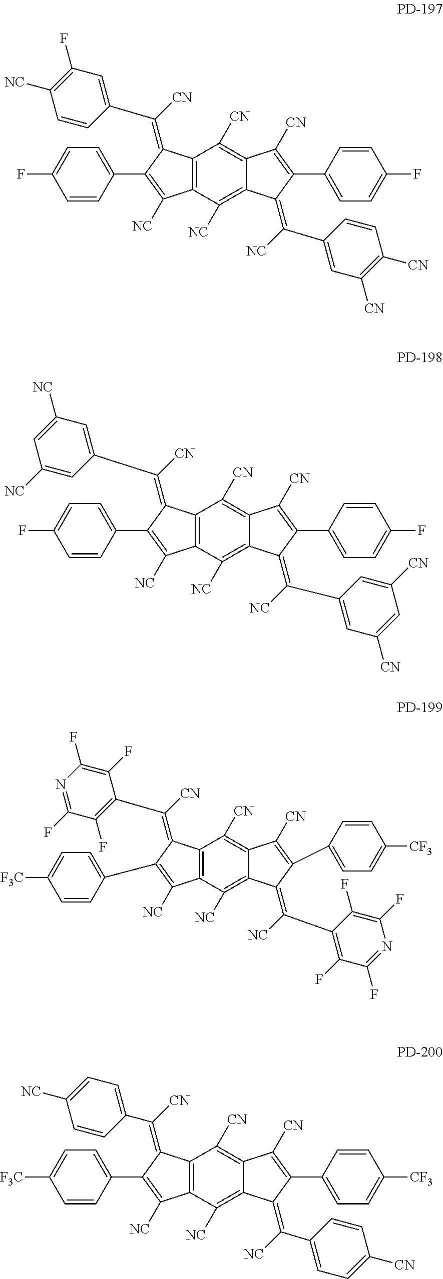

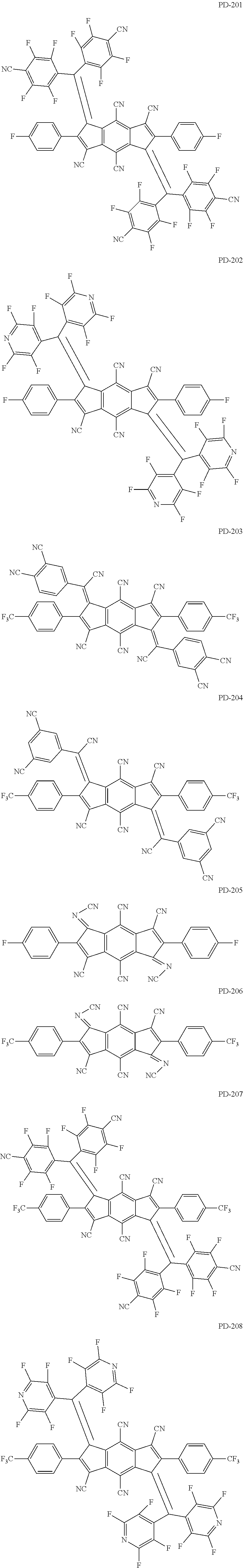

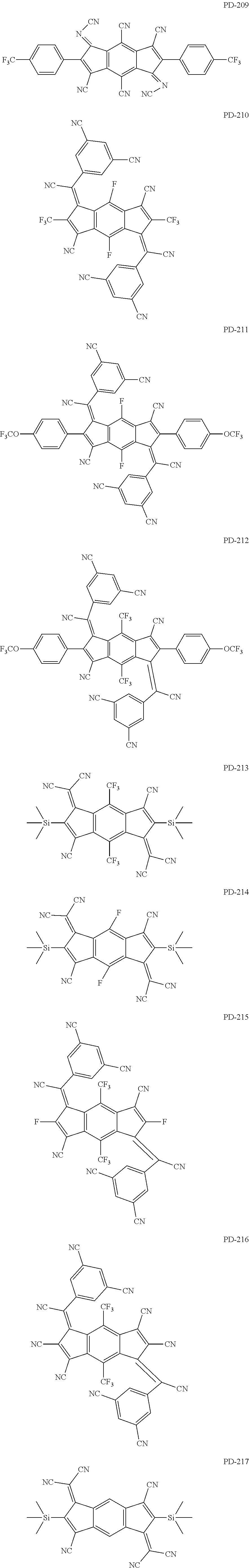

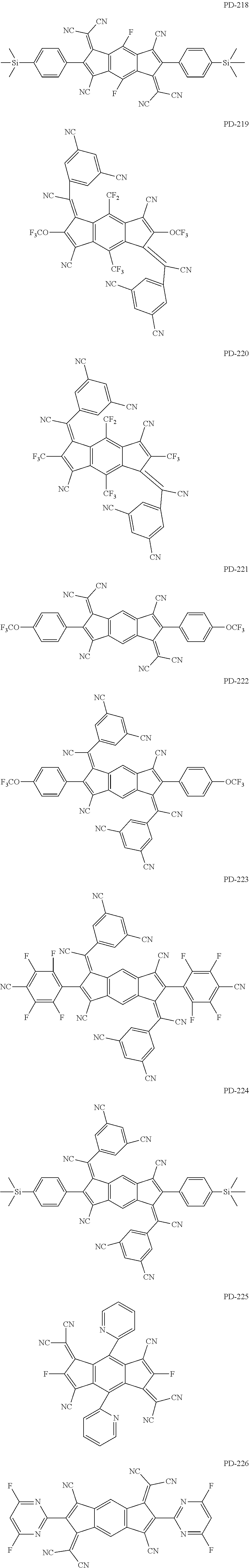

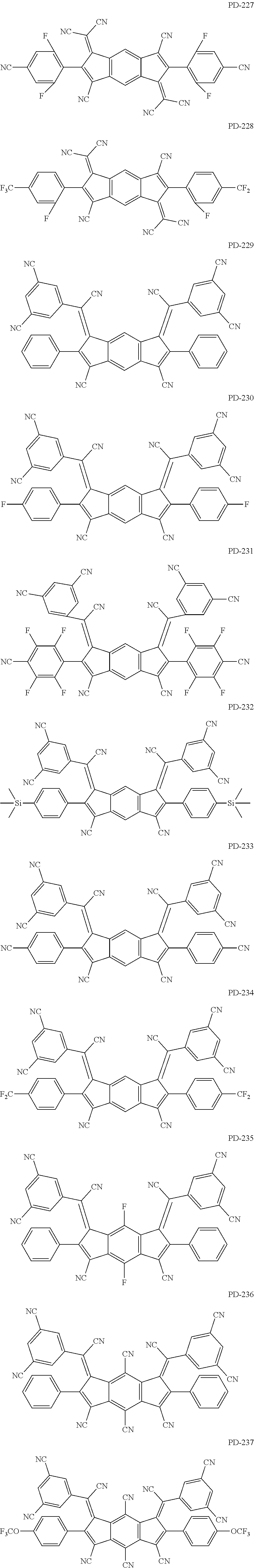

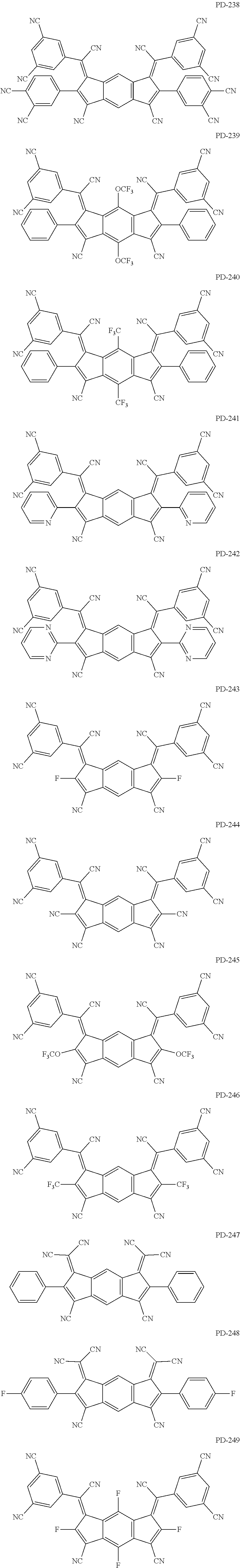

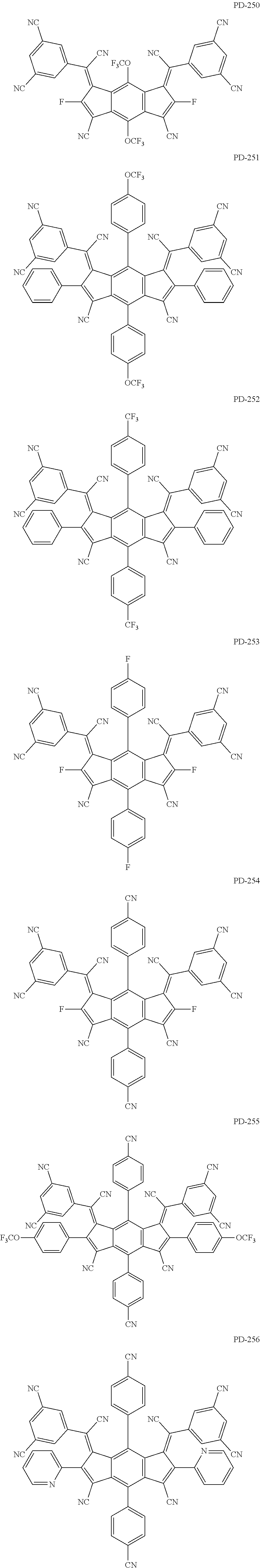

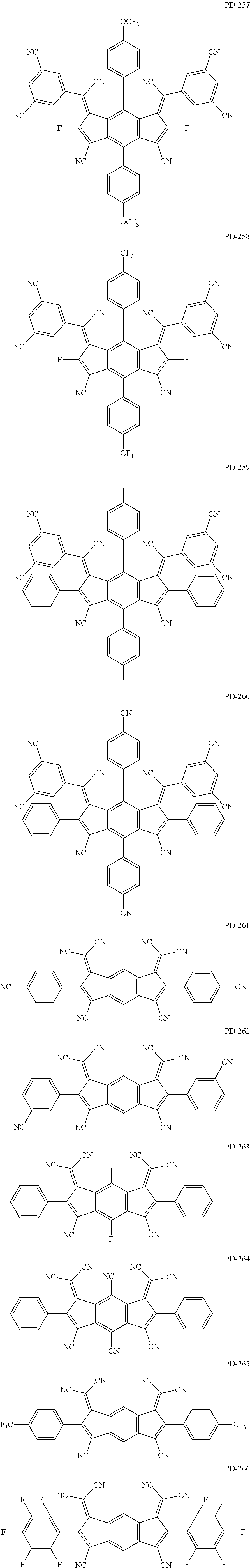

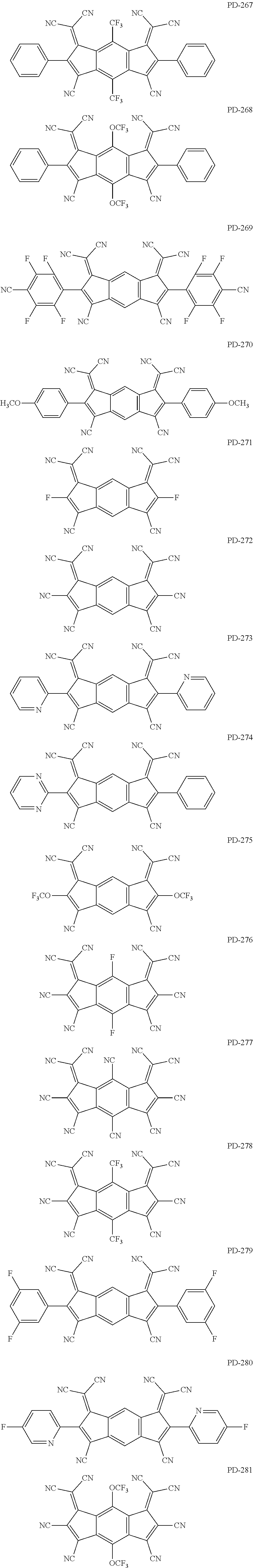

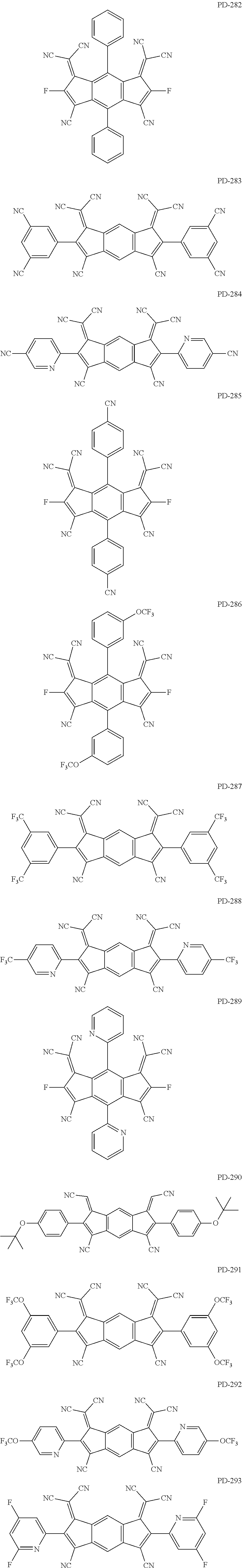

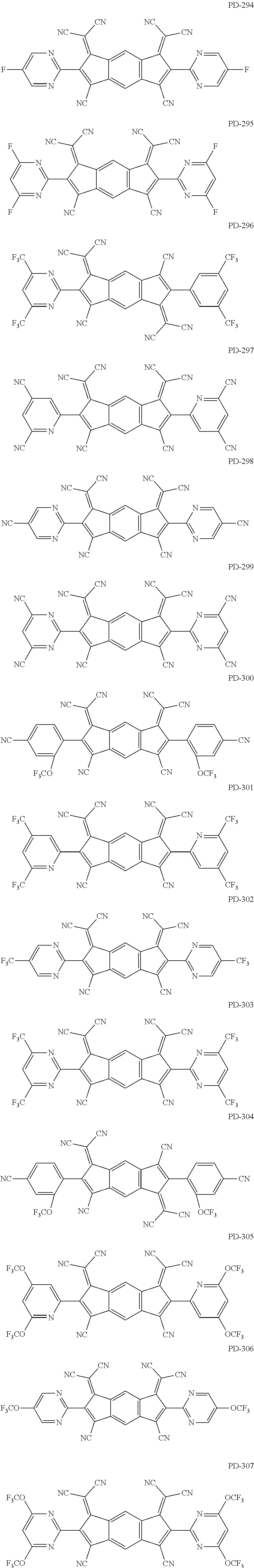

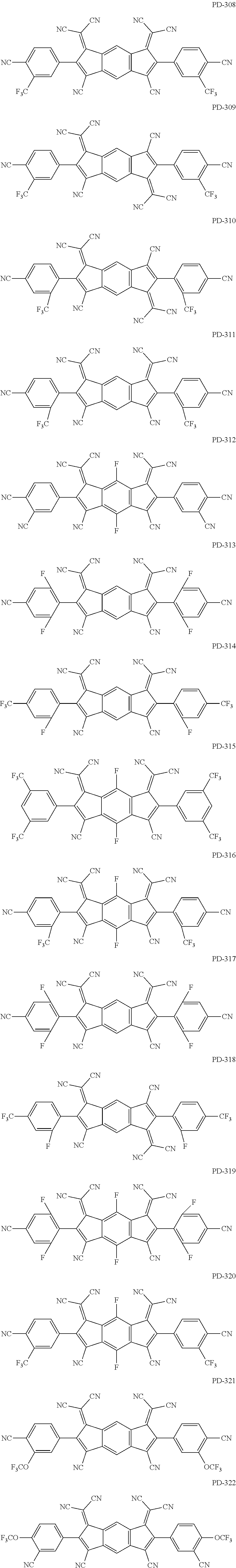

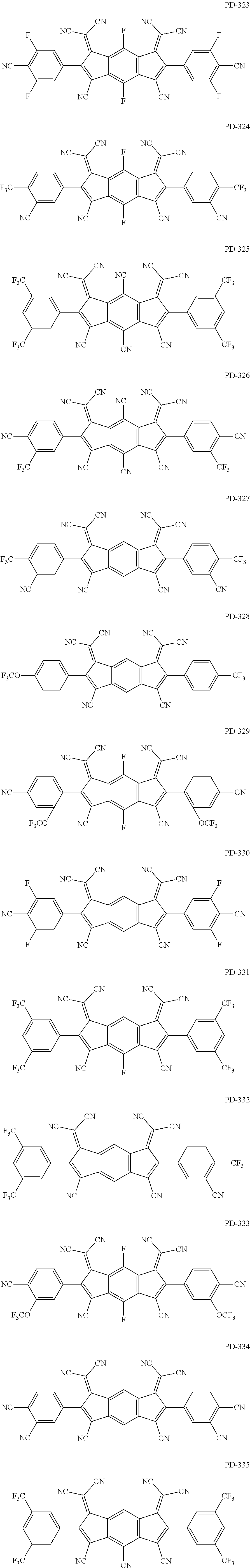

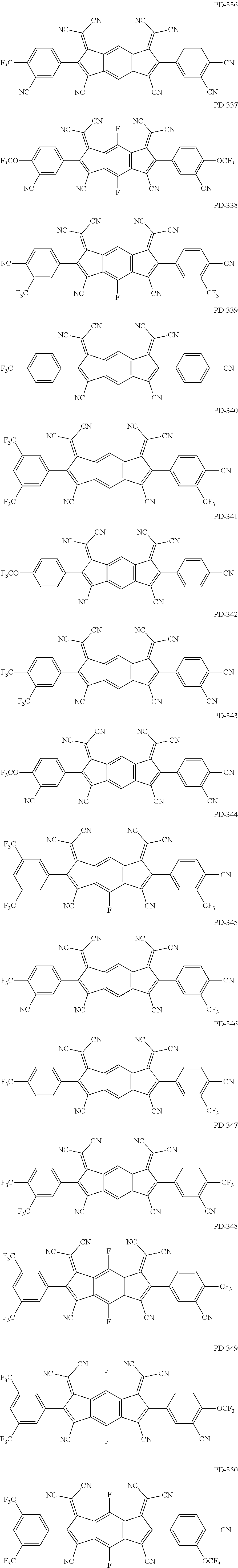

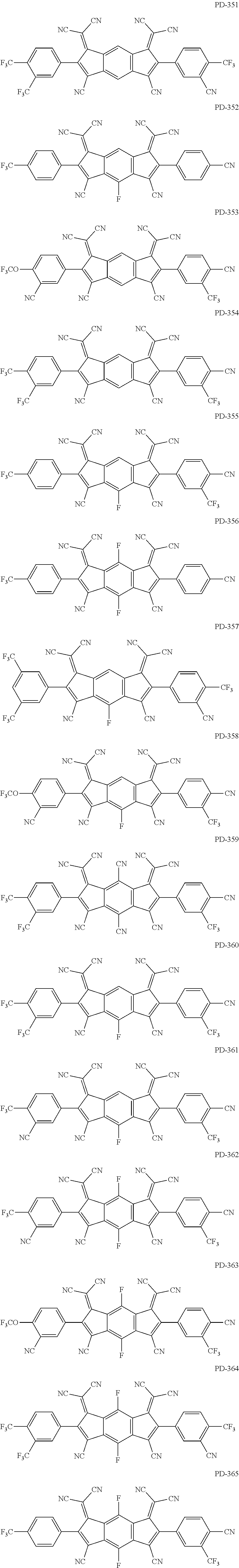

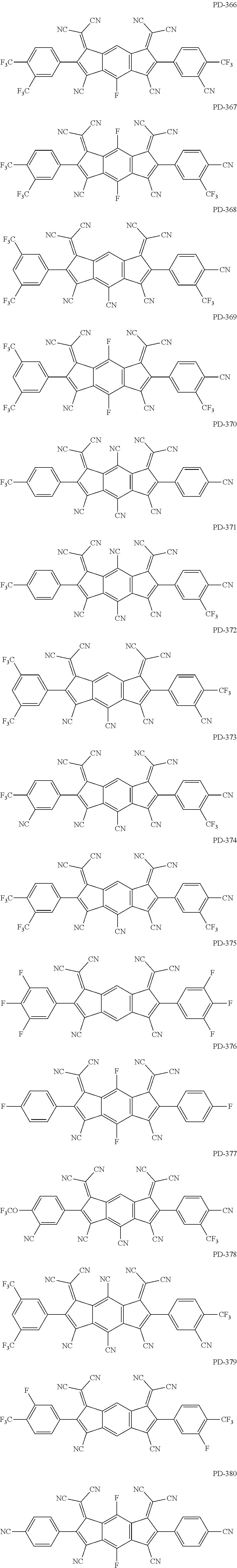

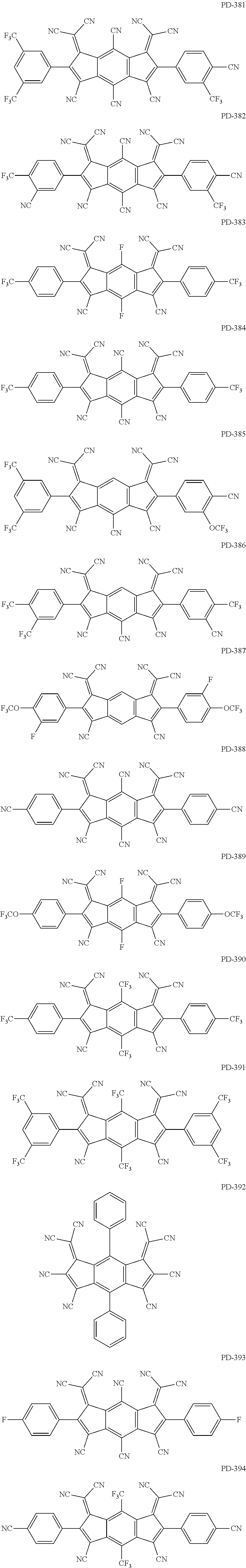

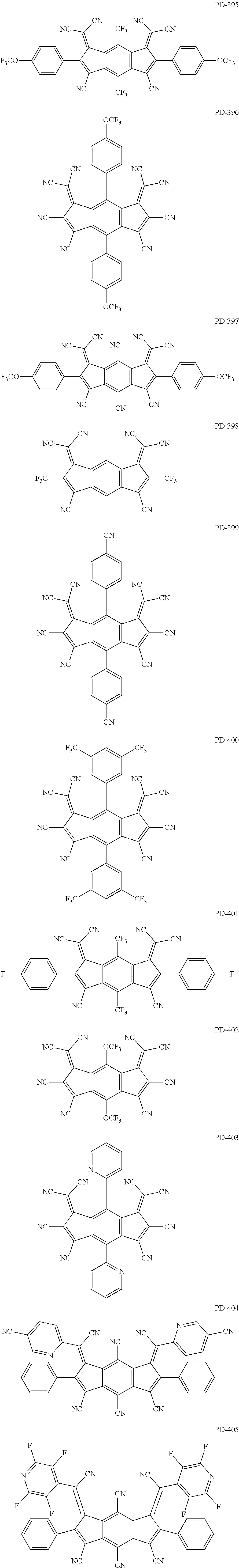

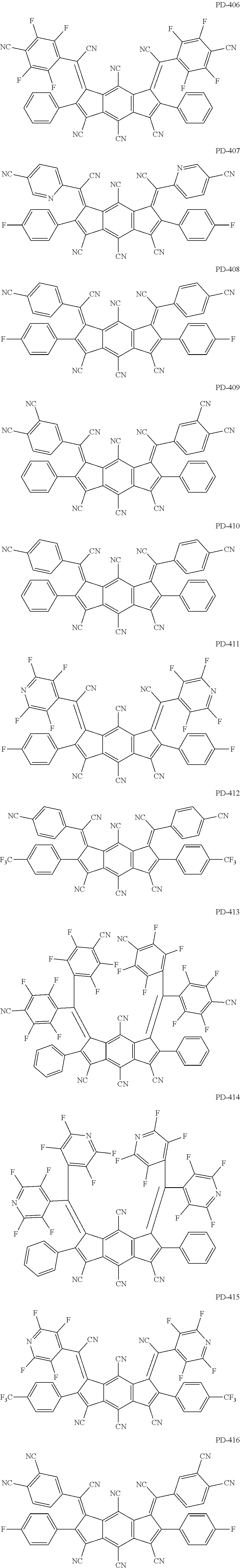

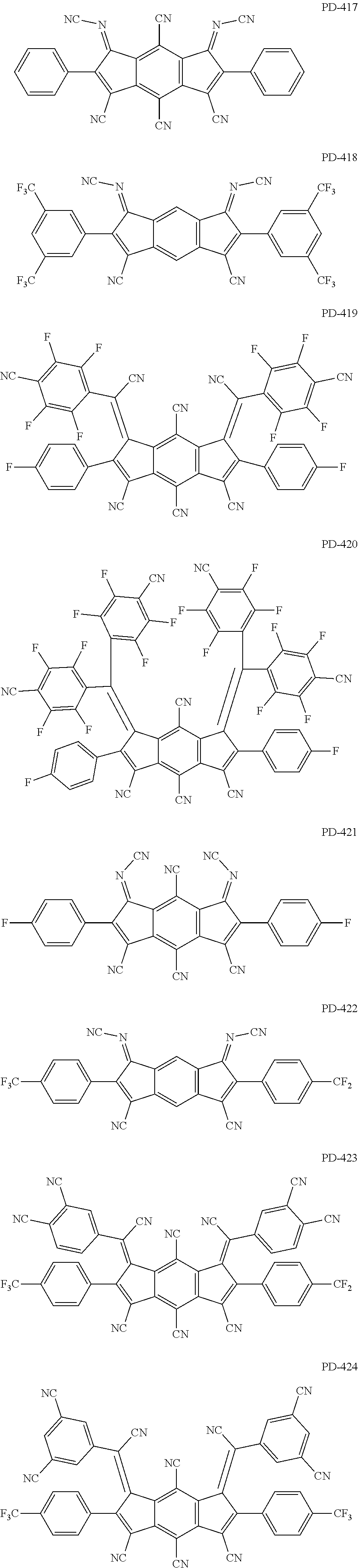

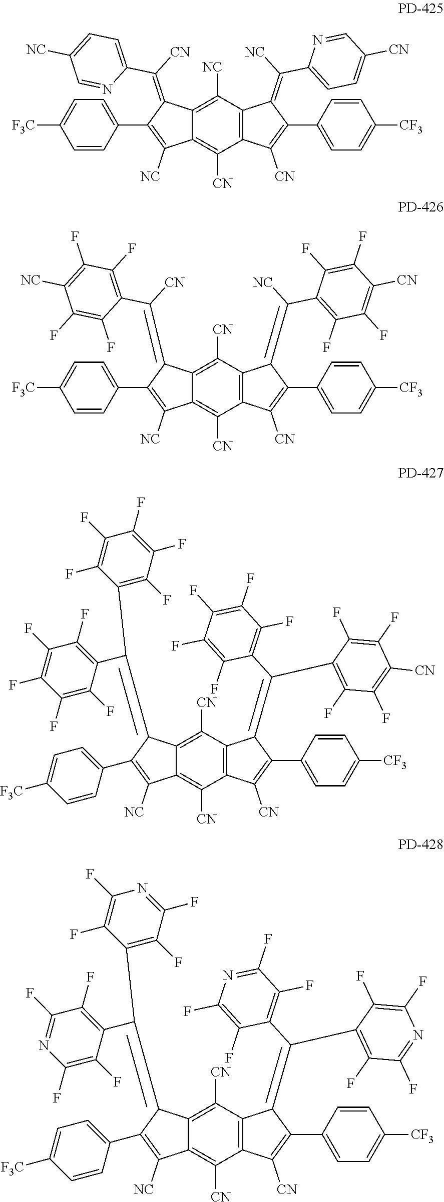

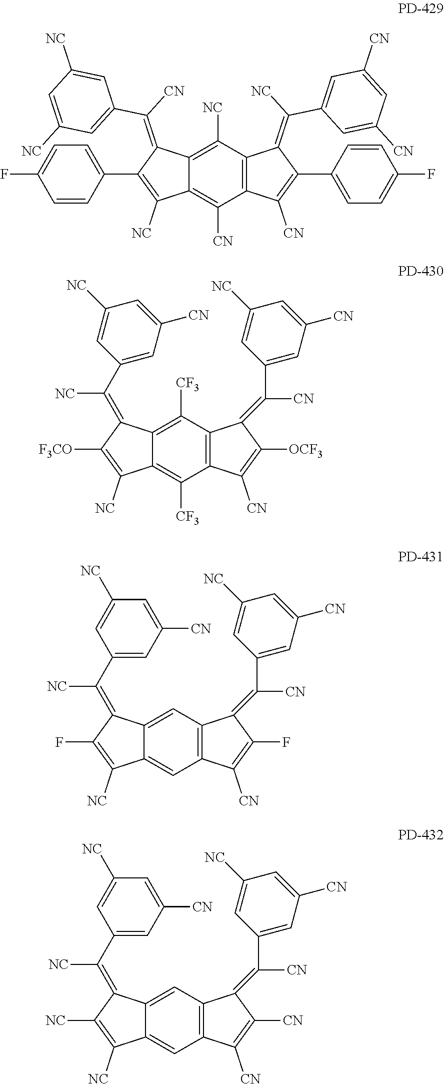

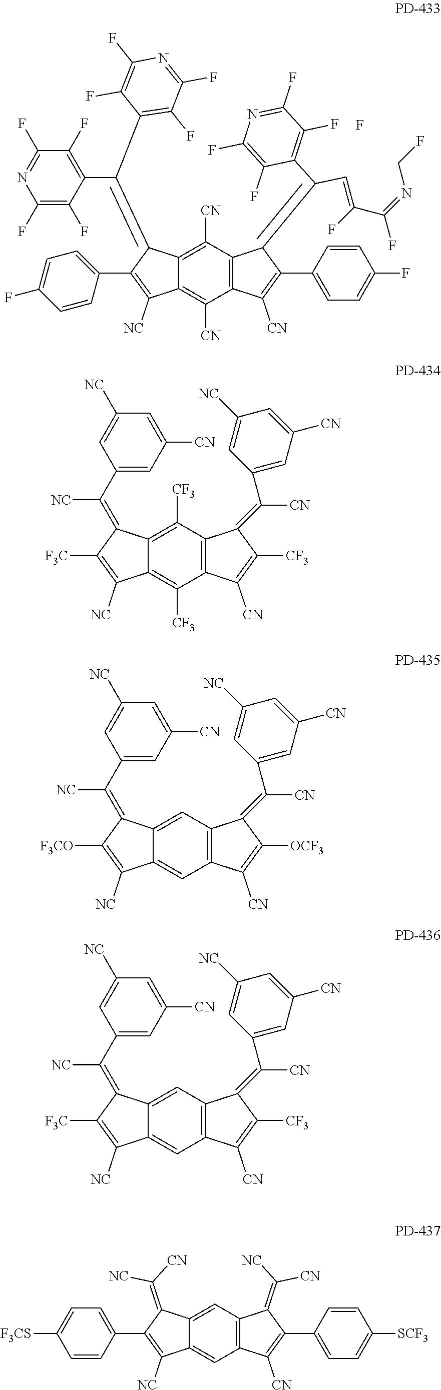

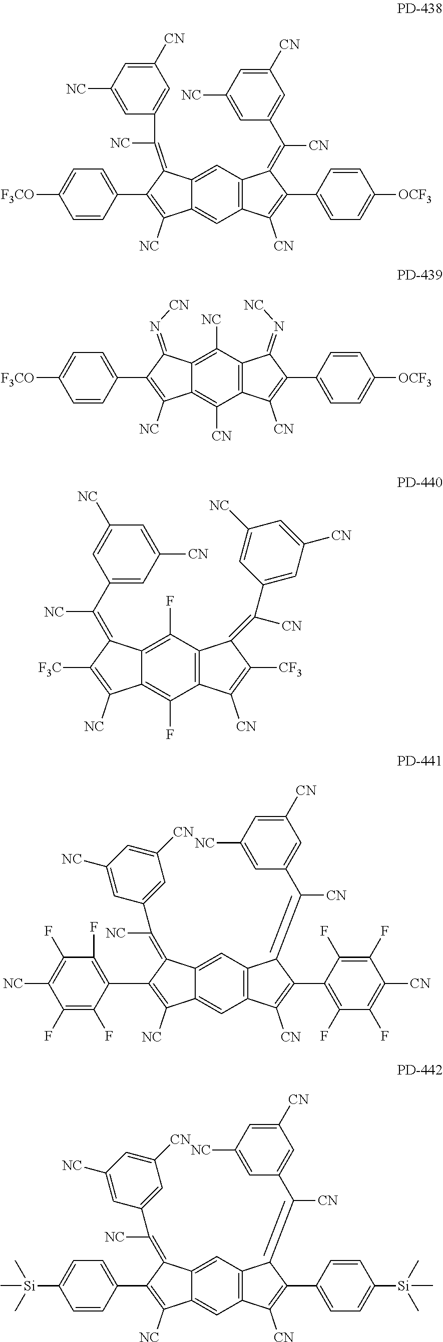

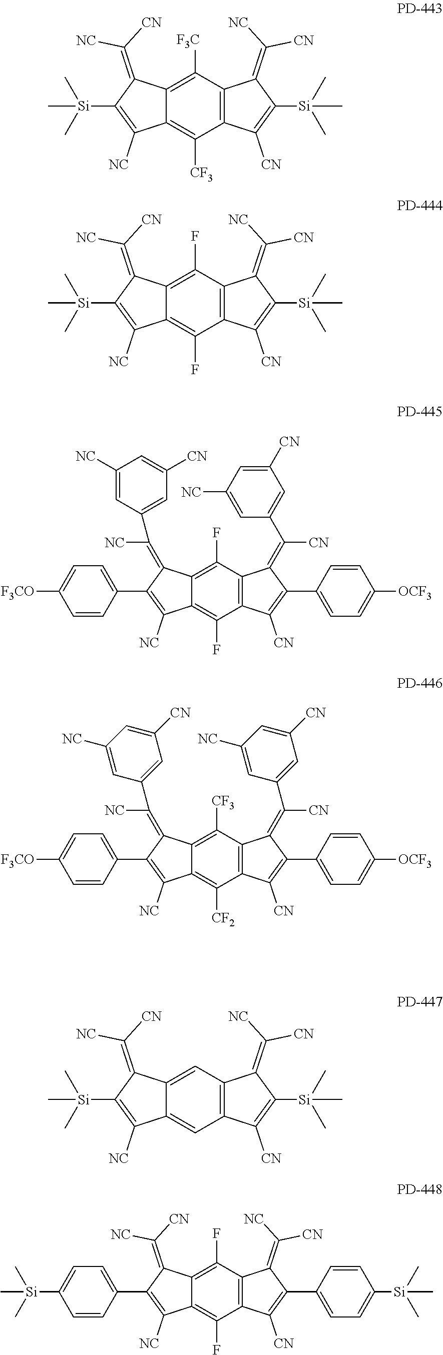

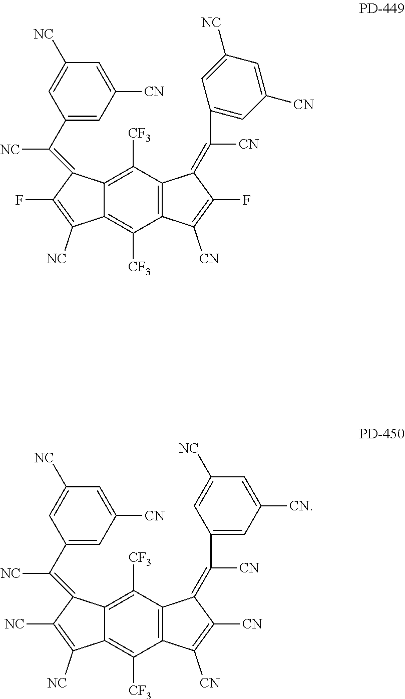 [SMILES: N#CC1=C(F)/C(=C(\C#N)c2cc(C#N)cc(C#N)c2)c2c1c(C(F)(F)F)c1c(c2C(F)(F)F)/C(=C(/C#N)c2cc(C#N)cc(C#N)c2)C(F)=C1C#N ; N#CC1=C(C#N)c2c(c(C(F)(F)F)c3c(c2C(F)(F)F)C(C#N)=C(C#N)/C3=C(\C#N)c2cc(C#N)cc(C#N)c2)/C1=C(/C#N)c1cc(C#N)cc(C#N)c1]

5. The organic light-emitting device of claim 1, wherein a structure of the second compound represented by the Chemical Formula 3 is selected from a group consisting of the following Compounds PH-1 to PH-315:

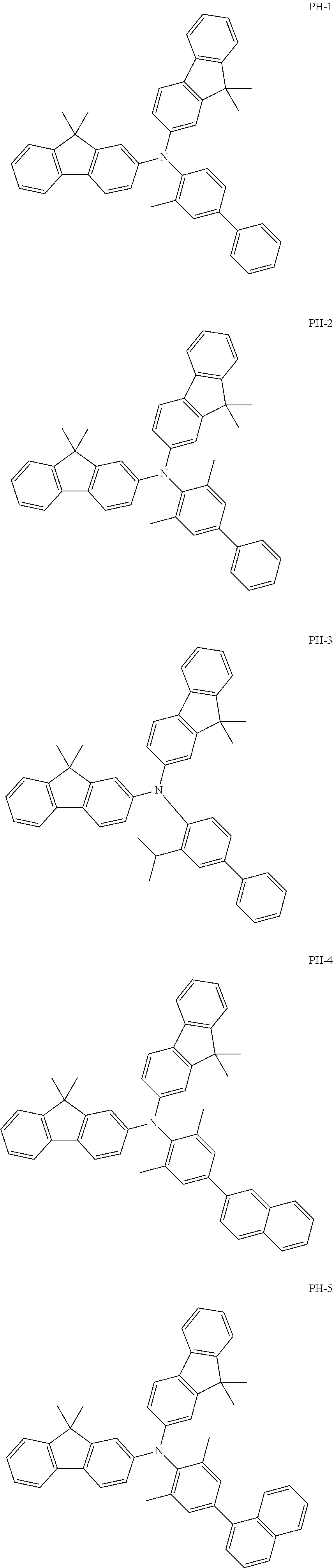 [SMILES: Cc1cc(-c2ccccc2)ccc1N(c1ccc2c(c1)C(C)(C)c1ccccc1-2)c1ccc2c(c1)C(C)(C)c1ccccc1-2 ; Cc1cc(-c2ccccc2)cc(C)c1N(c1ccc2c(c1)C(C)(C)c1ccccc1-2)c1ccc2c(c1)C(C)(C)c1ccccc1-2 ; CC(C)c1cc(-c2ccccc2)ccc1N(c1ccc2c(c1)C(C)(C)c1ccccc1-2)c1ccc2c(c1)C(C)(C)c1ccccc1-2 ; Cc1cc(-c2ccc3ccccc3c2)cc(C)c1N(c1ccc2c(c1)C(C)(C)c1ccccc1-2)c1ccc2c(c1)C(C)(C)c1ccccc1-2 ; Cc1cc(-c2cccc3ccccc23)cc(C)c1N(c1ccc2c(c1)C(C)(C)c1ccccc1-2)c1ccc2c(c1)C(C)(C)c1ccccc1-2]

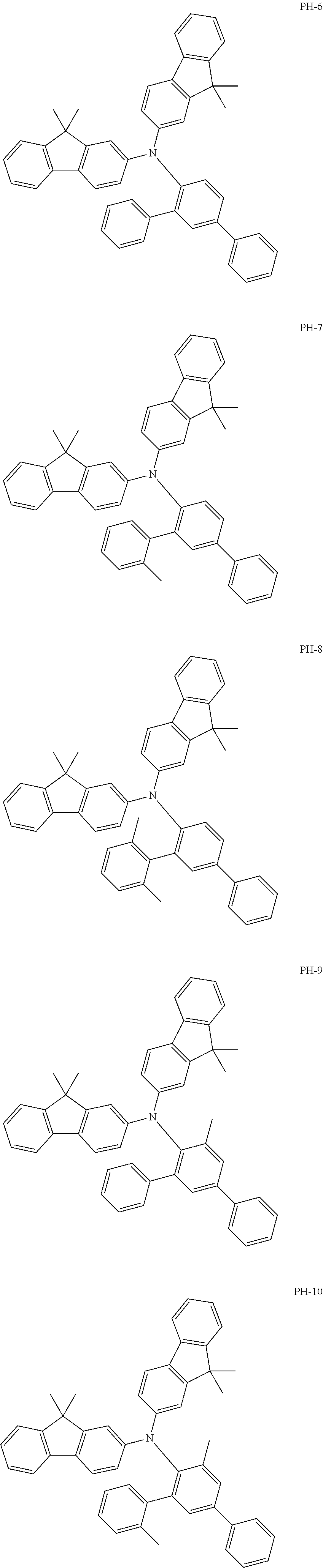 [SMILES: CC1(C)c2ccccc2-c2ccc(N(c3ccc4c(c3)C(C)(C)c3ccccc3-4)c3ccc(-c4ccccc4)cc3-c3ccccc3)cc21 ; Cc1ccccc1-c1cc(-c2ccccc2)ccc1N(c1ccc2c(c1)C(C)(C)c1ccccc1-2)c1ccc2c(c1)C(C)(C)c1ccccc1-2 ; Cc1cccc(C)c1-c1cc(-c2ccccc2)ccc1N(c1ccc2c(c1)C(C)(C)c1ccccc1-2)c1ccc2c(c1)C(C)(C)c1ccccc1-2 ; Cc1cc(-c2ccccc2)cc(-c2ccccc2)c1N(c1ccc2c(c1)C(C)(C)c1ccccc1-2)c1ccc2c(c1)C(C)(C)c1ccccc1-2 ; Cc1ccccc1-c1cc(-c2ccccc2)cc(C)c1N(c1ccc2c(c1)C(C)(C)c1ccccc1-2)c1ccc2c(c1)C(C)(C)c1ccccc1-2]

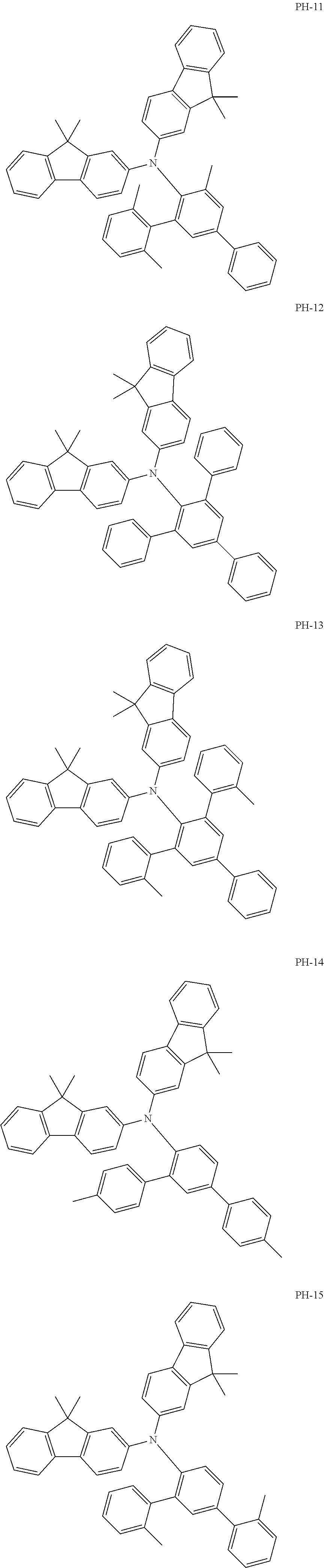 [SMILES: Cc1cccc(C)c1-c1cc(-c2ccccc2)cc(C)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3ccccc3)cc21 ; Cc1ccccc1-c1cc(-c2ccccc2)cc(-c2ccccc2C)c1N(c1ccc2c(c1)C(C)(C)c1ccccc1-2)c1ccc2c(c1)C(C)(C)c1ccccc1-2 ; Cc1ccc(-c2ccc(N(c3ccc4c(c3)C(C)(C)c3ccccc3-4)c3ccc4c(c3)C(C)(C)c3ccccc3-4)c(-c3ccc(C)cc3)c2)cc1 ; Cc1ccccc1-c1ccc(N(c2ccc3c(c2)C(C)(C)c2ccccc2-3)c2ccc3c(c2)C(C)(C)c2ccccc2-3)c(-c2ccccc2C)c1]

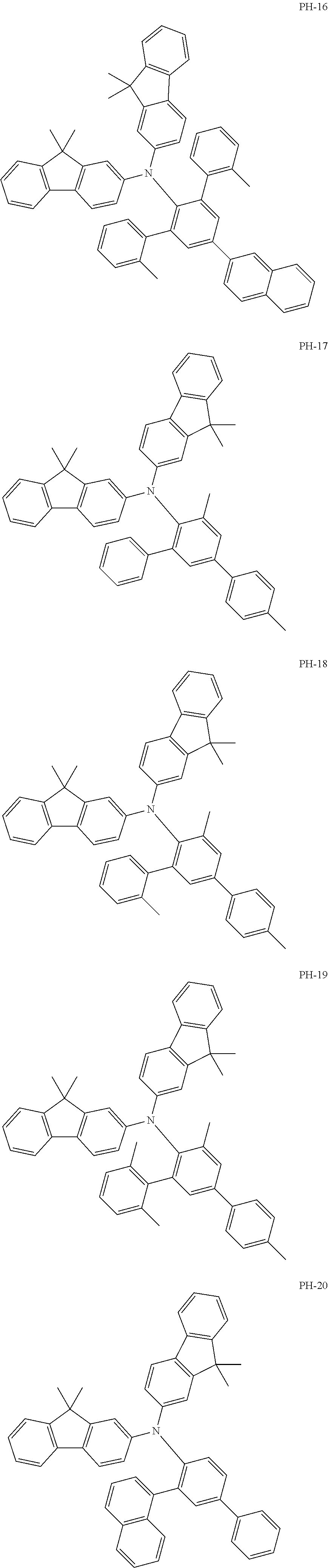 [SMILES: Cc1ccccc1-c1cc(-c2ccc3ccccc3c2)cc(-c2ccccc2C)c1N(c1ccc2c(c1)C(C)(C)c1ccccc1-2)c1ccc2c(c1)C(C)(C)c1ccccc1-2 ; Cc1ccc(-c2cc(C)c(N(c3ccc4c(c3)C(C)(C)c3ccccc3-4)c3ccc4c(c3)C(C)(C)c3ccccc3-4)c(-c3ccccc3)c2)cc1 ; Cc1ccc(-c2cc(C)c(N(c3ccc4c(c3)C(C)(C)c3ccccc3-4)c3ccc4c(c3)C(C)(C)c3ccccc3-4)c(-c3ccccc3C)c2)cc1 ; Cc1ccc(-c2cc(C)c(N(c3ccc4c(c3)C(C)(C)c3ccccc3-4)c3ccc4c(c3)C(C)(C)c3ccccc3-4)c(-c3c(C)cccc3C)c2)cc1 ; CC1(C)c2ccccc2-c2ccc(N(c3ccc4c(c3)C(C)(C)c3ccccc3-4)c3ccc(-c4ccccc4)cc3-c3cccc4ccccc34)cc21]

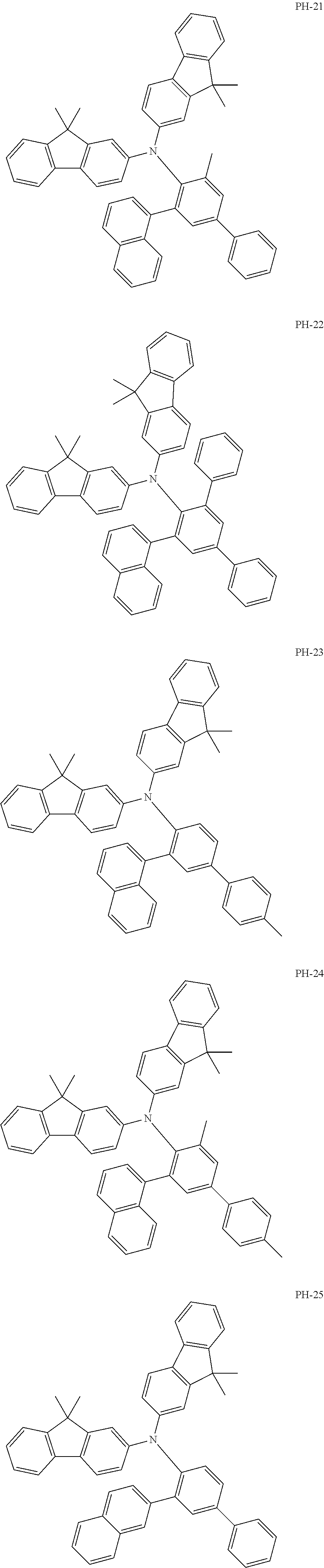 [SMILES: Cc1cc(-c2ccccc2)cc(-c2cccc3ccccc23)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3cccc4ccccc34)cc21 ; Cc1ccc(-c2ccc(N(c3ccc4c(c3)C(C)(C)c3ccccc3-4)c3ccc4c(c3)C(C)(C)c3ccccc3-4)c(-c3cccc4ccccc34)c2)cc1 ; Cc1ccc(-c2cc(C)c(N(c3ccc4c(c3)C(C)(C)c3ccccc3-4)c3ccc4c(c3)C(C)(C)c3ccccc3-4)c(-c3cccc4ccccc34)c2)cc1 ; CC1(C)c2ccccc2-c2ccc(N(c3ccc4c(c3)C(C)(C)c3ccccc3-4)c3ccc(-c4ccccc4)cc3-c3ccc4ccccc4c3)cc21]

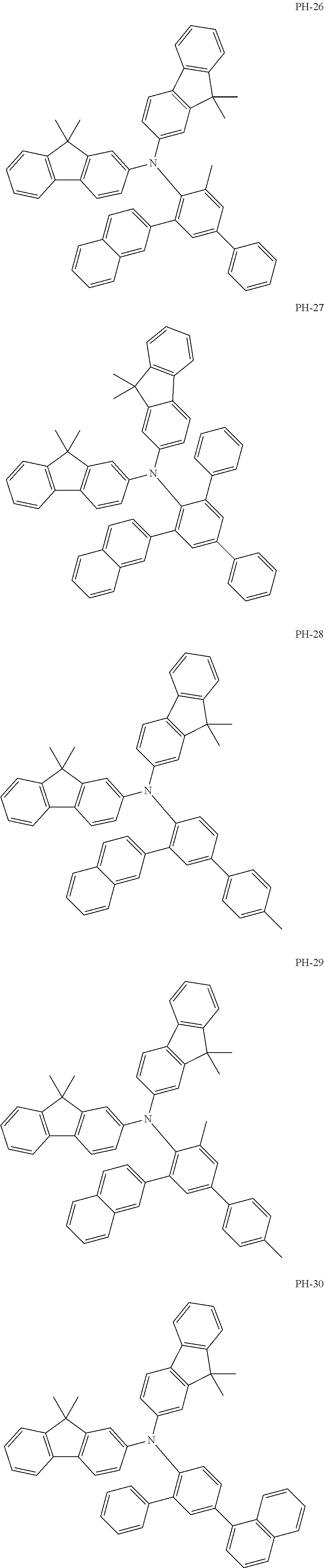 [SMILES: Cc1cc(-c2ccccc2)cc(-c2ccc3ccccc3c2)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3ccc4ccccc4c3)cc21 ; Cc1ccc(-c2ccc(N(c3ccc4c(c3)C(C)(C)c3ccccc3-4)c3ccc4c(c3)C(C)(C)c3ccccc3-4)c(-c3ccc4ccccc4c3)c2)cc1 ; Cc1ccc(-c2cc(C)c(N(c3ccc4c(c3)C(C)(C)c3ccccc3-4)c3ccc4c(c3)C(C)(C)c3ccccc3-4)c(-c3ccc4ccccc4c3)c2)cc1 ; CC1(C)c2ccccc2-c2ccc(N(c3ccc4c(c3)C(C)(C)c3ccccc3-4)c3ccc(-c4cccc5ccccc45)cc3-c3ccccc3)cc21]

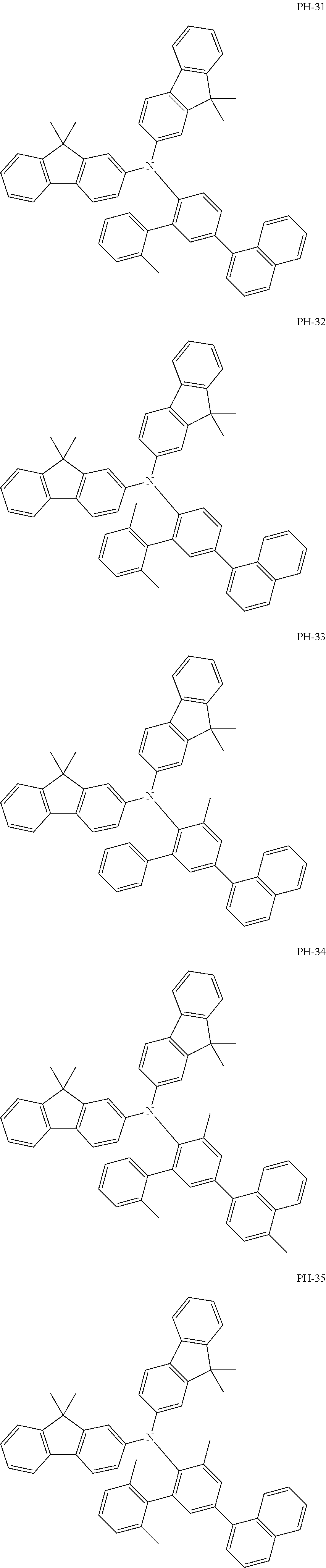 [SMILES: Cc1ccccc1-c1cc(-c2cccc3ccccc23)ccc1N(c1ccc2c(c1)C(C)(C)c1ccccc1-2)c1ccc2c(c1)C(C)(C)c1ccccc1-2 ; Cc1cccc(C)c1-c1cc(-c2cccc3ccccc23)ccc1N(c1ccc2c(c1)C(C)(C)c1ccccc1-2)c1ccc2c(c1)C(C)(C)c1ccccc1-2 ; Cc1cc(-c2cccc3ccccc23)cc(-c2ccccc2)c1N(c1ccc2c(c1)C(C)(C)c1ccccc1-2)c1ccc2c(c1)C(C)(C)c1ccccc1-2 ; Cc1ccccc1-c1cc(-c2ccc(C)c3ccccc23)cc(C)c1N(c1ccc2c(c1)C(C)(C)c1ccccc1-2)c1ccc2c(c1)C(C)(C)c1ccccc1-2 ; Cc1cccc(C)c1-c1cc(-c2cccc3ccccc23)cc(C)c1N(c1ccc2c(c1)C(C)(C)c1ccccc1-2)c1ccc2c(c1)C(C)(C)c1ccccc1-2]

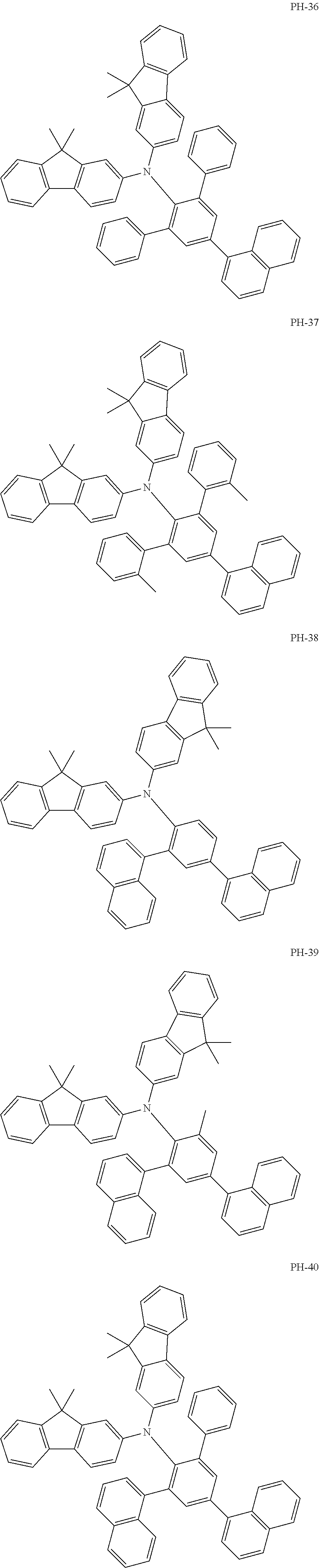

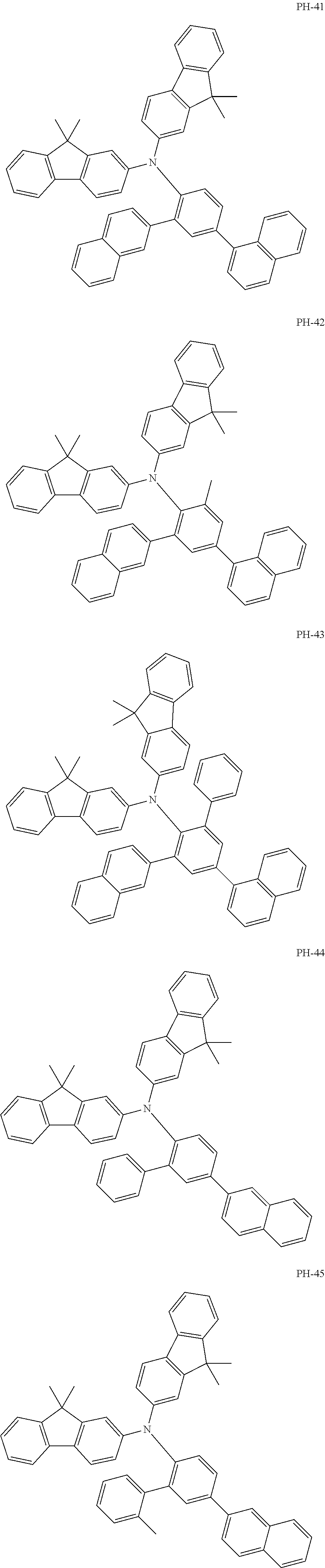

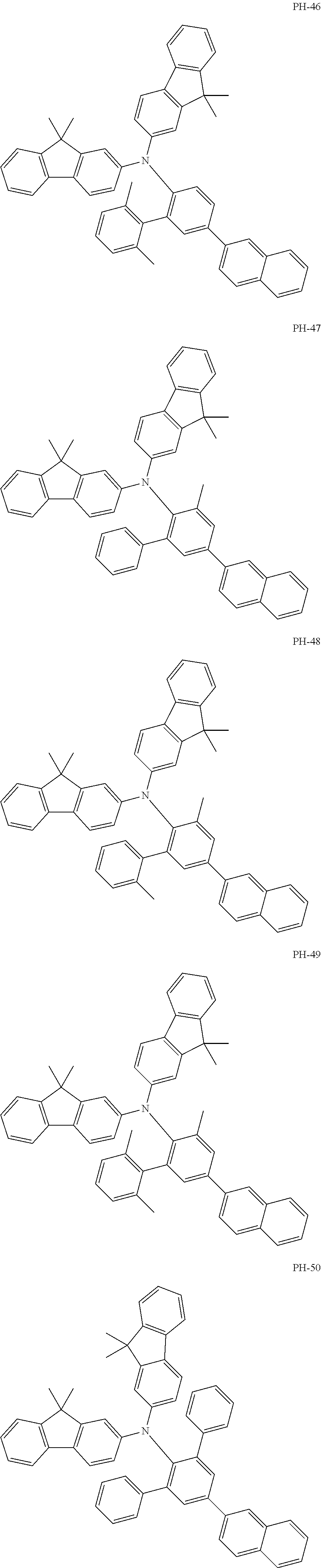

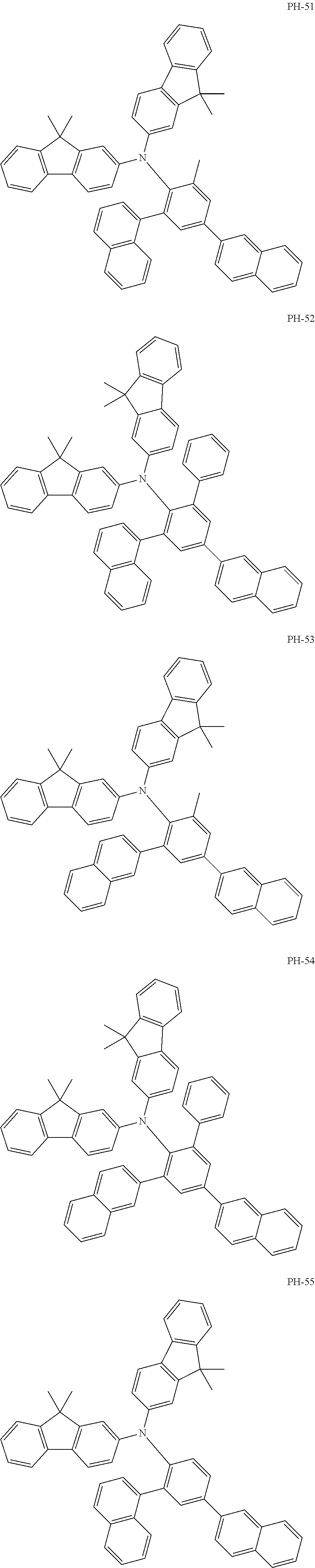

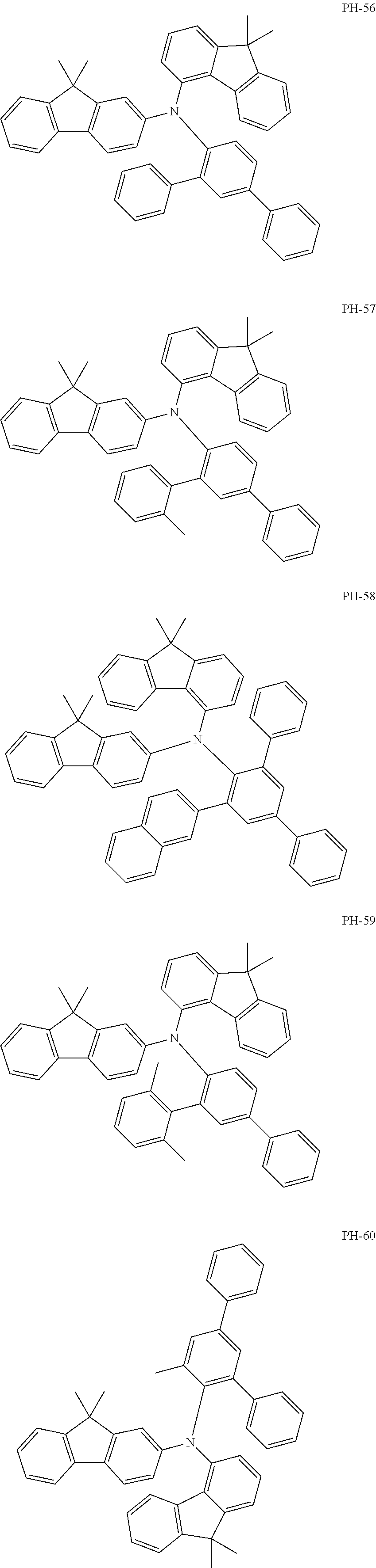 [SMILES: CC1(C)c2ccccc2-c2ccc(N(c3ccc(-c4ccccc4)cc3-c3ccccc3)c3cccc4c3-c3ccccc3C4(C)C)cc21 ; Cc1ccccc1-c1cc(-c2ccccc2)ccc1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4ccccc4)cc3-c3ccc4ccccc4c3)cc21 ; Cc1cccc(C)c1-c1cc(-c2ccccc2)ccc1N(c1ccc2c(c1)C(C)(C)c1ccccc1-2)c1cccc2c1-c1ccccc1C2(C)C ; Cc1cc(-c2ccccc2)cc(-c2ccccc2)c1N(c1ccc2c(c1)C(C)(C)c1ccccc1-2)c1cccc2c1-c1ccccc1C2(C)C]

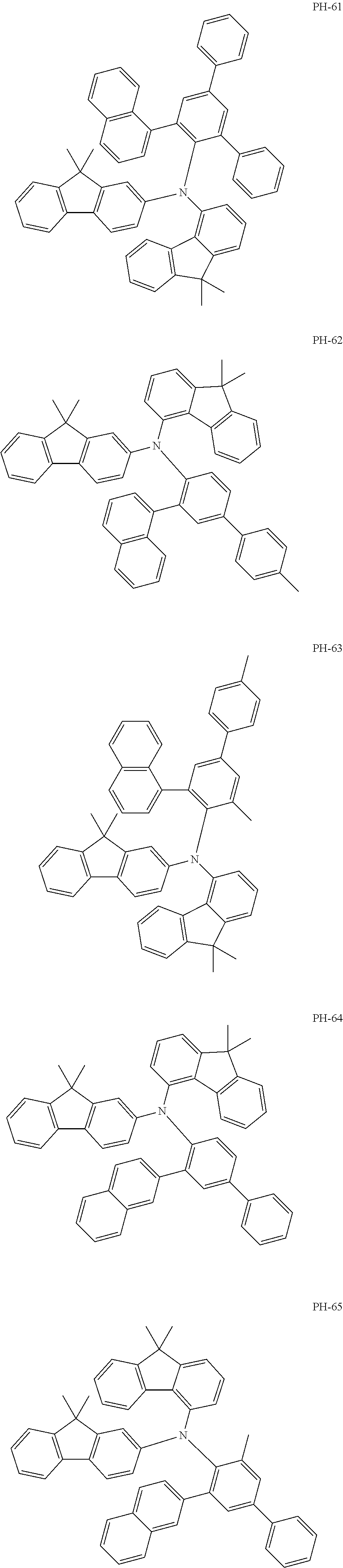 [SMILES: CC1(C)c2ccccc2-c2ccc(N(c3cccc4c3-c3ccccc3C4(C)C)c3c(-c4ccccc4)cc(-c4ccccc4)cc3-c3cccc4ccccc34)cc21 ; Cc1ccc(-c2ccc(N(c3ccc4c(c3)C(C)(C)c3ccccc3-4)c3cccc4c3-c3ccccc3C4(C)C)c(-c3cccc4ccccc34)c2)cc1 ; Cc1ccc(-c2cc(C)c(N(c3ccc4c(c3)C(C)(C)c3ccccc3-4)c3cccc4c3-c3ccccc3C4(C)C)c(-c3cccc4ccccc34)c2)cc1 ; CC1(C)c2ccccc2-c2ccc(N(c3ccc(-c4ccccc4)cc3-c3ccc4ccccc4c3)c3cccc4c3-c3ccccc3C4(C)C)cc21 ; Cc1cc(-c2ccccc2)cc(-c2ccc3ccccc3c2)c1N(c1ccc2c(c1)C(C)(C)c1ccccc1-2)c1cccc2c1-c1ccccc1C2(C)C]

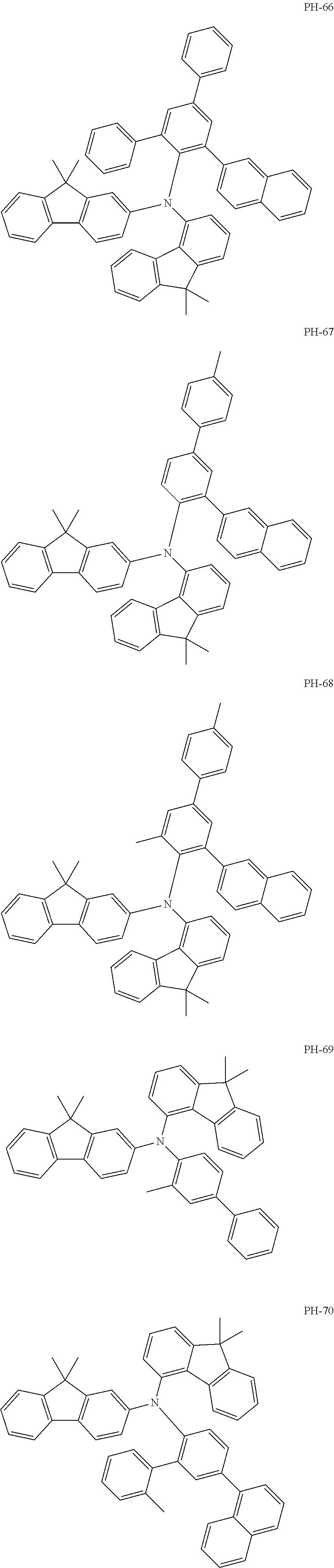 [SMILES: CC1(C)c2ccccc2-c2ccc(N(c3cccc4c3-c3ccccc3C4(C)C)c3c(-c4ccccc4)cc(-c4ccccc4)cc3-c3ccc4ccccc4c3)cc21 ; Cc1ccc(-c2ccc(N(c3ccc4c(c3)C(C)(C)c3ccccc3-4)c3cccc4c3-c3ccccc3C4(C)C)c(-c3ccc4ccccc4c3)c2)cc1 ; Cc1ccc(-c2cc(C)c(N(c3ccc4c(c3)C(C)(C)c3ccccc3-4)c3cccc4c3-c3ccccc3C4(C)C)c(-c3ccc4ccccc4c3)c2)cc1 ; Cc1cc(-c2ccccc2)ccc1N(c1ccc2c(c1)C(C)(C)c1ccccc1-2)c1cccc2c1-c1ccccc1C2(C)C ; Cc1ccccc1-c1cc(-c2cccc3ccccc23)ccc1N(c1ccc2c(c1)C(C)(C)c1ccccc1-2)c1cccc2c1-c1ccccc1C2(C)C]

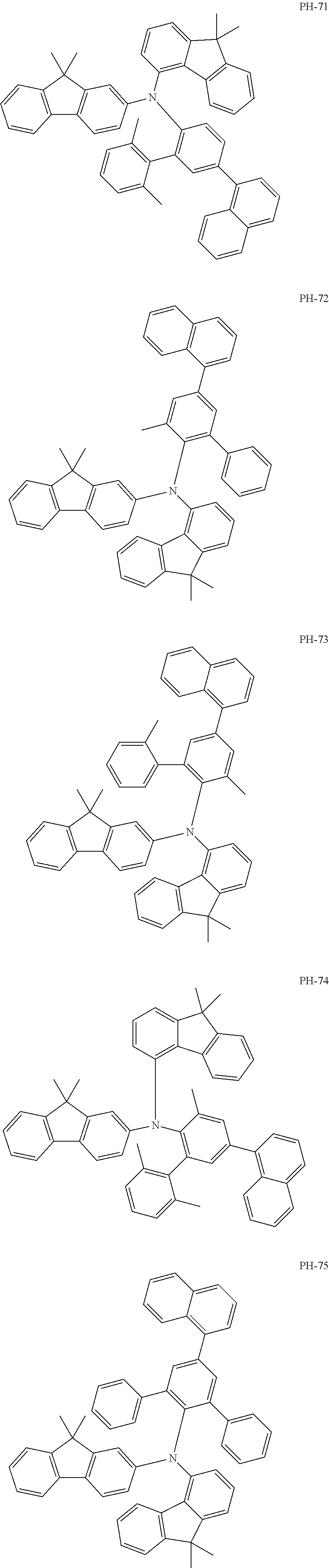 [SMILES: Cc1cccc(C)c1-c1cc(-c2cccc3ccccc23)ccc1N(c1ccc2c(c1)C(C)(C)c1ccccc1-2)c1cccc2c1-c1ccccc1C2(C)C ; Cc1cc(-c2cccc3ccccc23)cc(-c2ccccc2)c1N(c1ccc2c(c1)C(C)(C)c1ccccc1-2)c1cccc2c1-c1ccccc1C2(C)C ; Cc1ccccc1-c1cc(-c2cccc3ccccc23)cc(C)c1N(c1ccc2c(c1)C(C)(C)c1ccccc1-2)c1cccc2c1-c1ccccc1C2(C)C ; Cc1cccc(C)c1-c1cc(-c2cccc3ccccc23)cc(C)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4cccc5ccccc45)cc3-c3ccccc3)cc21]

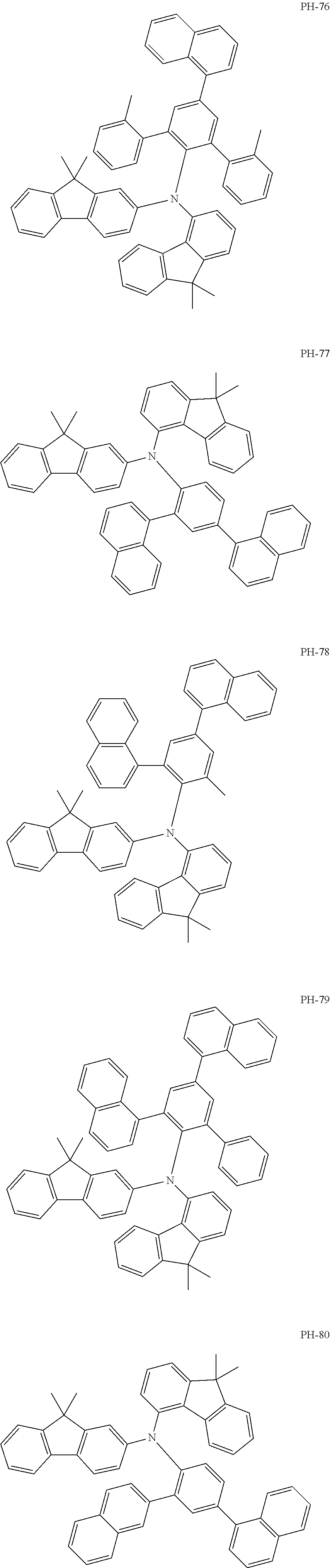

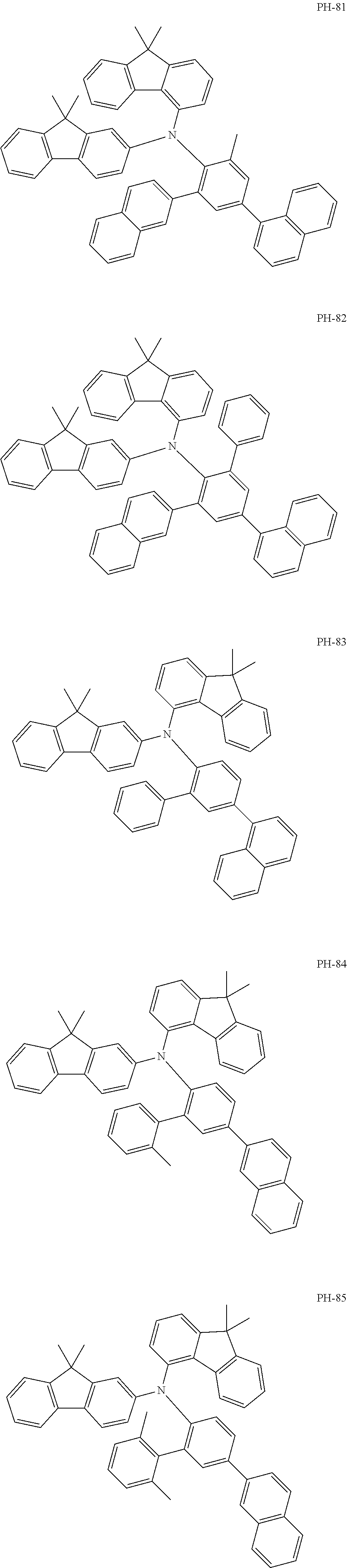 [SMILES: Cc1cc(-c2cccc3ccccc23)cc(-c2ccc3ccccc3c2)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4cccc5ccccc45)cc3-c3ccc4ccccc4c3)cc21 ; CC1(C)c2ccccc2-c2ccc(N(c3ccc(-c4cccc5ccccc45)cc3-c3ccccc3)c3cccc4c3-c3ccccc3C4(C)C)cc21 ; Cc1ccccc1-c1cc(-c2ccc3ccccc3c2)ccc1N(c1ccc2c(c1)C(C)(C)c1ccccc1-2)c1cccc2c1-c1ccccc1C2(C)C ; Cc1cccc(C)c1-c1cc(-c2ccc3ccccc3c2)ccc1N(c1ccc2c(c1)C(C)(C)c1ccccc1-2)c1cccc2c1-c1ccccc1C2(C)C]

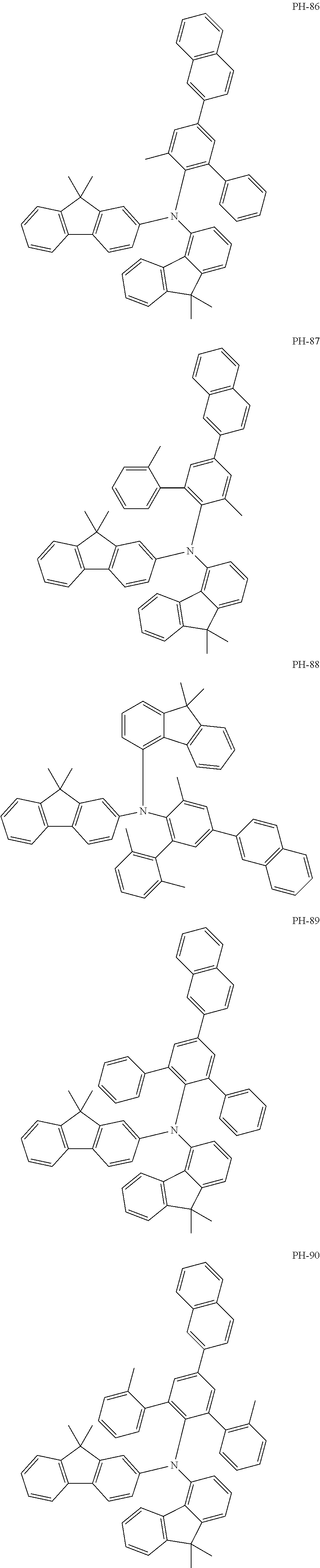

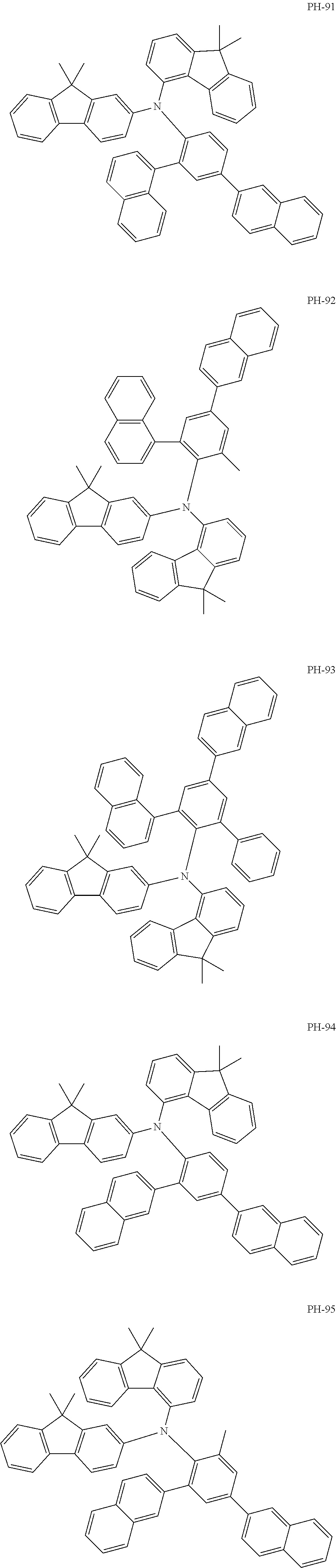 [SMILES: CC1(C)c2ccccc2-c2ccc(N(c3ccc(-c4ccc5ccccc5c4)cc3-c3cccc4ccccc34)c3cccc4c3-c3ccccc3C4(C)C)cc21 ; Cc1cc(-c2ccc3ccccc3c2)cc(-c2cccc3ccccc23)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4ccc5ccccc5c4)cc3-c3cccc4ccccc34)cc21 ; CC1(C)c2ccccc2-c2ccc(N(c3ccc(-c4ccc5ccccc5c4)cc3-c3ccc4ccccc4c3)c3cccc4c3-c3ccccc3C4(C)C)cc21 ; Cc1cc(-c2ccc3ccccc3c2)cc(-c2ccc3ccccc3c2)c1N(c1ccc2c(c1)C(C)(C)c1ccccc1-2)c1cccc2c1-c1ccccc1C2(C)C]

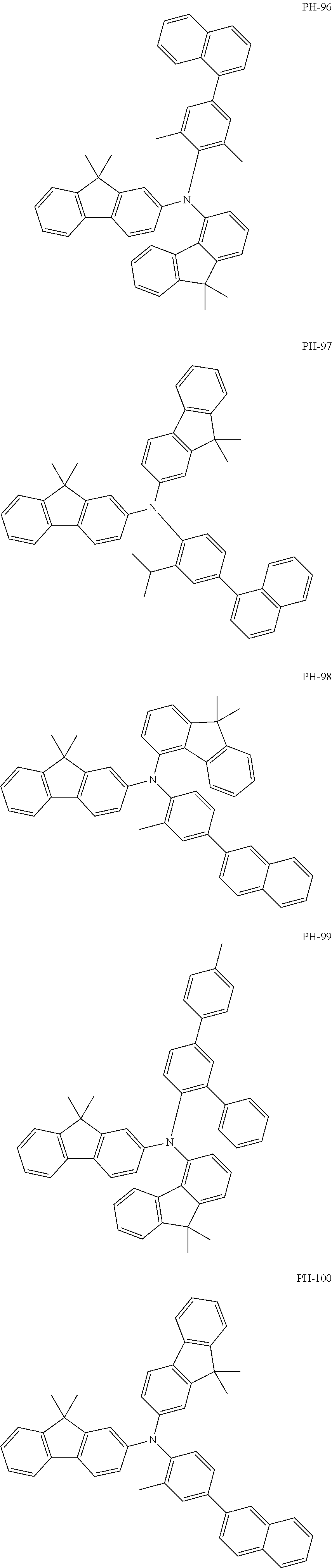 [SMILES: Cc1cc(-c2cccc3ccccc23)cc(C)c1N(c1ccc2c(c1)C(C)(C)c1ccccc1-2)c1cccc2c1-c1ccccc1C2(C)C ; CC(C)c1cc(-c2cccc3ccccc23)ccc1N(c1ccc2c(c1)C(C)(C)c1ccccc1-2)c1ccc2c(c1)C(C)(C)c1ccccc1-2 ; Cc1cc(-c2ccc3ccccc3c2)ccc1N(c1ccc2c(c1)C(C)(C)c1ccccc1-2)c1cccc2c1-c1ccccc1C2(C)C ; Cc1ccc(-c2ccc(N(c3ccc4c(c3)C(C)(C)c3ccccc3-4)c3cccc4c3-c3ccccc3C4(C)C)c(-c3ccccc3)c2)cc1 ; Cc1cc(-c2ccc3ccccc3c2)ccc1N(c1ccc2c(c1)C(C)(C)c1ccccc1-2)c1ccc2c(c1)C(C)(C)c1ccccc1-2]

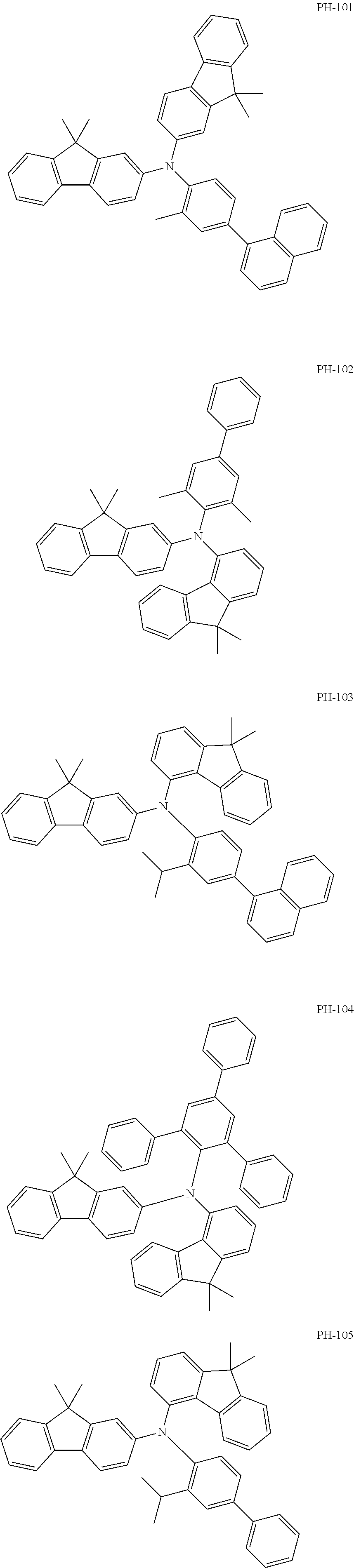

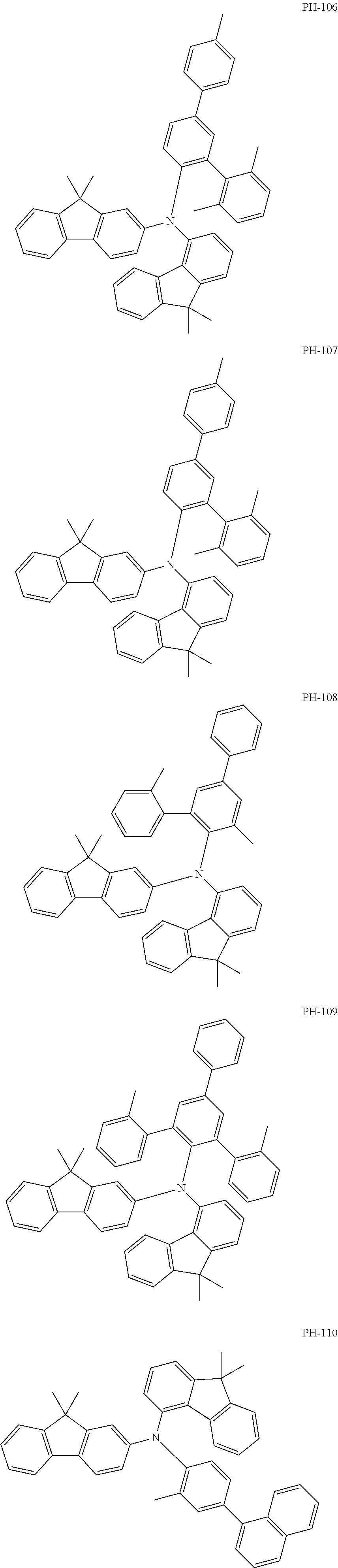

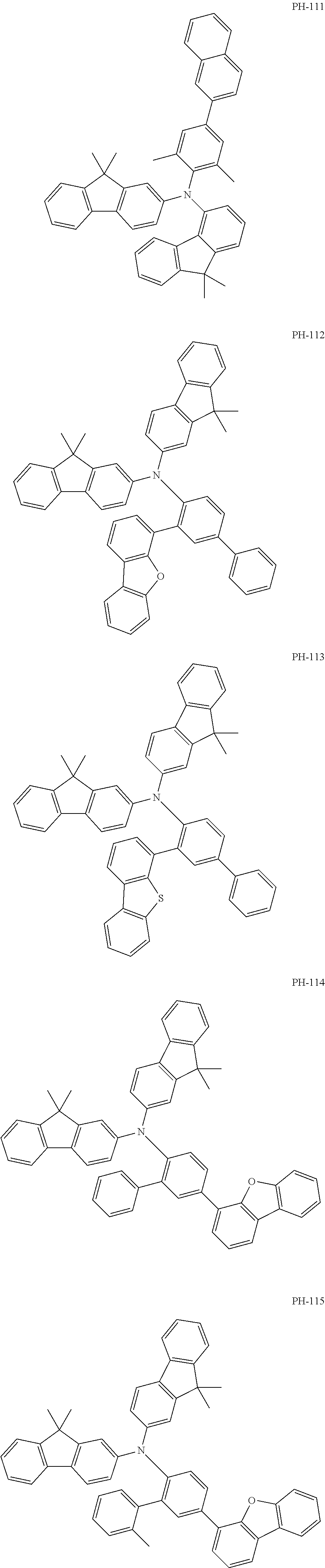 [SMILES: Cc1cc(-c2ccc3ccccc3c2)cc(C)c1N(c1ccc2c(c1)C(C)(C)c1ccccc1-2)c1cccc2c1-c1ccccc1C2(C)C ; CC1(C)c2ccccc2-c2ccc(N(c3ccc4c(c3)C(C)(C)c3ccccc3-4)c3ccc(-c4ccccc4)cc3-c3cccc4c3oc3ccccc34)cc21 ; CC1(C)c2ccccc2-c2ccc(N(c3ccc4c(c3)C(C)(C)c3ccccc3-4)c3ccc(-c4ccccc4)cc3-c3cccc4c3sc3ccccc34)cc21 ; CC1(C)c2ccccc2-c2ccc(N(c3ccc4c(c3)C(C)(C)c3ccccc3-4)c3ccc(-c4cccc5c4oc4ccccc45)cc3-c3ccccc3)cc21 ; Cc1ccccc1-c1cc(-c2cccc3c2oc2ccccc23)ccc1N(c1ccc2c(c1)C(C)(C)c1ccccc1-2)c1ccc2c(c1)C(C)(C)c1ccccc1-2]

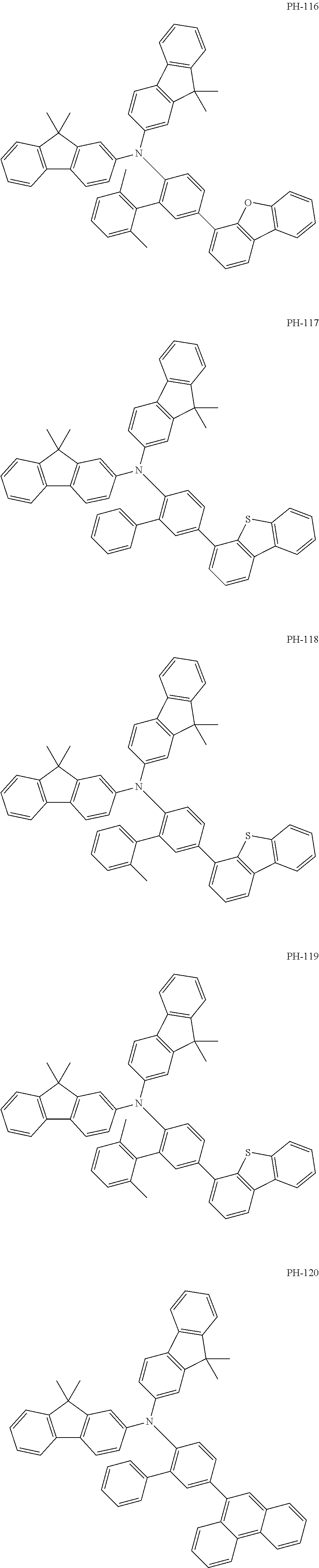

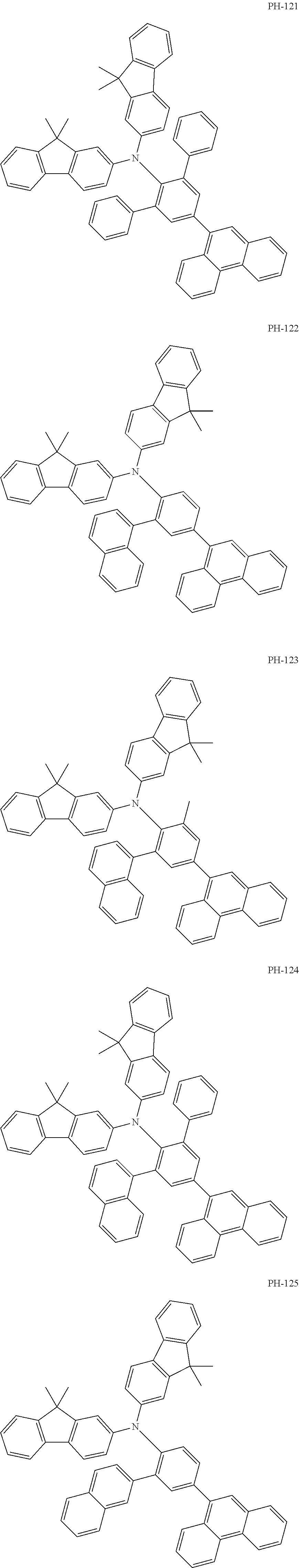

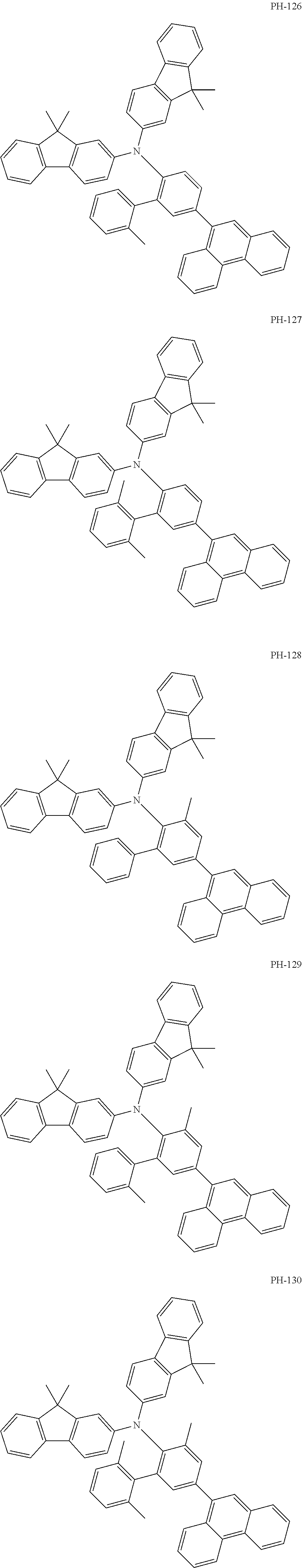

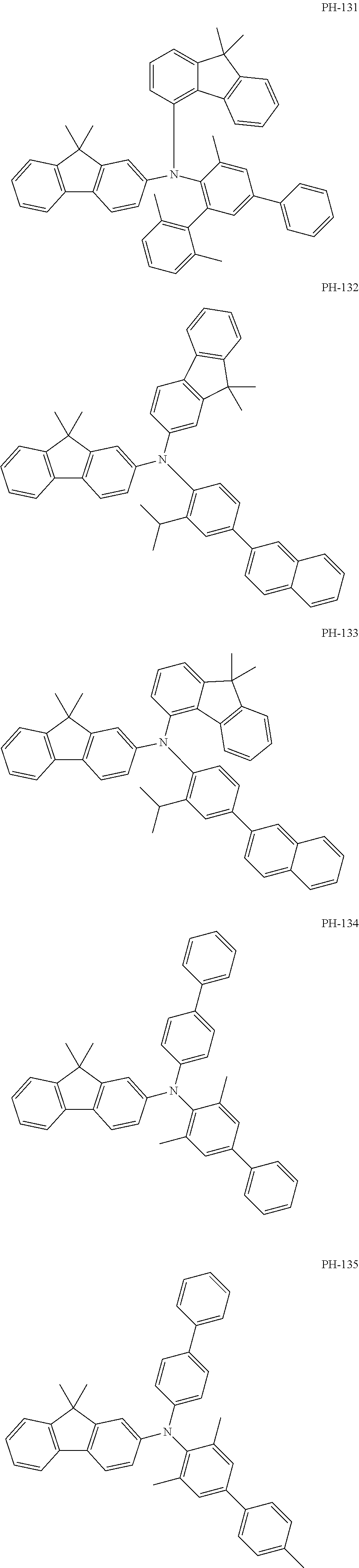 [SMILES: Cc1cccc(C)c1-c1cc(-c2ccccc2)cc(C)c1N(c1ccc2c(c1)C(C)(C)c1ccccc1-2)c1cccc2c1-c1ccccc1C2(C)C ; CC(C)c1cc(-c2ccc3ccccc3c2)ccc1N(c1ccc2c(c1)C(C)(C)c1ccccc1-2)c1ccc2c(c1)C(C)(C)c1ccccc1-2 ; CC(C)c1cc(-c2ccc3ccccc3c2)ccc1N(c1ccc2c(c1)C(C)(C)c1ccccc1-2)c1cccc2c1-c1ccccc1C2(C)C ; Cc1cc(-c2ccccc2)cc(C)c1N(c1ccc(-c2ccccc2)cc1)c1ccc2c(c1)C(C)(C)c1ccccc1-2 ; Cc1ccc(-c2cc(C)c(N(c3ccc(-c4ccccc4)cc3)c3ccc4c(c3)C(C)(C)c3ccccc3-4)c(C)c2)cc1]

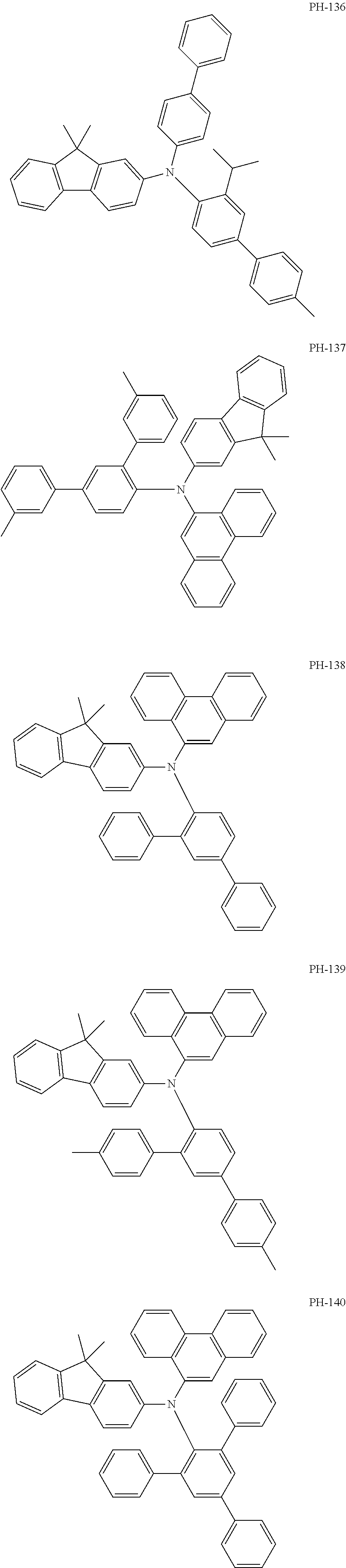 [SMILES: Cc1ccc(-c2ccc(N(c3ccc(-c4ccccc4)cc3)c3ccc4c(c3)C(C)(C)c3ccccc3-4)c(C(C)C)c2)cc1 ; Cc1cccc(-c2ccc(N(c3ccc4c(c3)C(C)(C)c3ccccc3-4)c3cc4ccccc4c4ccccc34)c(-c3cccc(C)c3)c2)c1 ; CC1(C)c2ccccc2-c2ccc(N(c3ccc(-c4ccccc4)cc3-c3ccccc3)c3cc4ccccc4c4ccccc34)cc21 ; Cc1ccc(-c2ccc(N(c3ccc4c(c3)C(C)(C)c3ccccc3-4)c3cc4ccccc4c4ccccc34)c(-c3ccc(C)cc3)c2)cc1 ; CC1(C)c2ccccc2-c2ccc(N(c3c(-c4ccccc4)cc(-c4ccccc4)cc3-c3ccccc3)c3cc4ccccc4c4ccccc34)cc21]

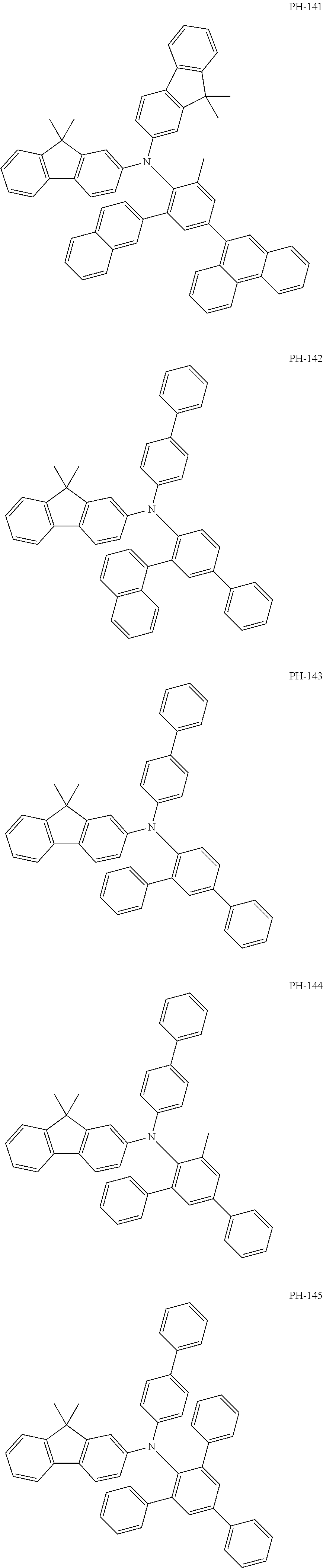 [SMILES: Cc1cc(-c2cc3ccccc3c3ccccc23)cc(-c2ccc3ccccc3c2)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc(-c4ccccc4)cc3)c3ccc(-c4ccccc4)cc3-c3cccc4ccccc34)cc21 ; CC1(C)c2ccccc2-c2ccc(N(c3ccc(-c4ccccc4)cc3)c3ccc(-c4ccccc4)cc3-c3ccccc3)cc21 ; Cc1cc(-c2ccccc2)cc(-c2ccccc2)c1N(c1ccc(-c2ccccc2)cc1)c1ccc2c(c1)C(C)(C)c1ccccc1-2 ; CC1(C)c2ccccc2-c2ccc(N(c3ccc(-c4ccccc4)cc3)c3c(-c4ccccc4)cc(-c4ccccc4)cc3-c3ccccc3)cc21]

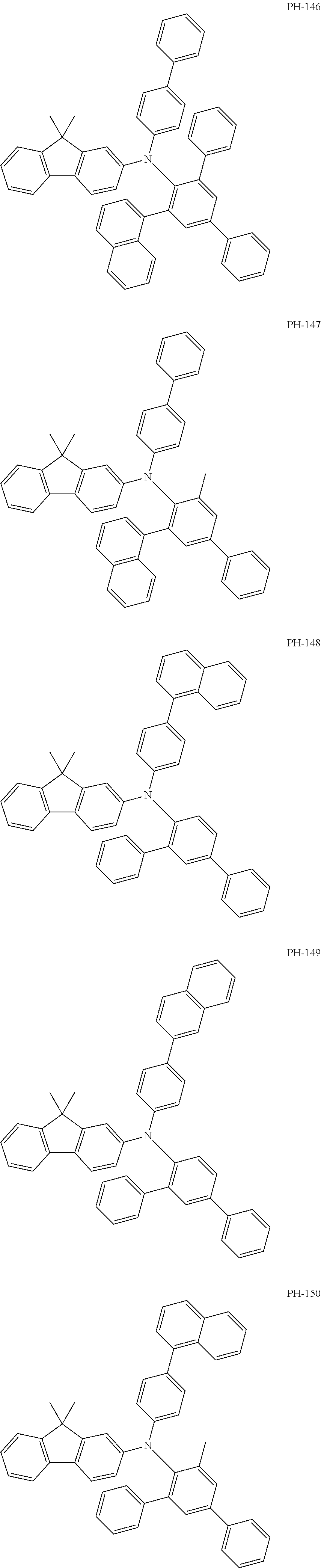 [SMILES: CC1(C)c2ccccc2-c2ccc(N(c3ccc(-c4ccccc4)cc3)c3c(-c4ccccc4)cc(-c4ccccc4)cc3-c3cccc4ccccc34)cc21 ; Cc1cc(-c2ccccc2)cc(-c2cccc3ccccc23)c1N(c1ccc(-c2ccccc2)cc1)c1ccc2c(c1)C(C)(C)c1ccccc1-2 ; CC1(C)c2ccccc2-c2ccc(N(c3ccc(-c4cccc5ccccc45)cc3)c3ccc(-c4ccccc4)cc3-c3ccccc3)cc21 ; CC1(C)c2ccccc2-c2ccc(N(c3ccc(-c4ccc5ccccc5c4)cc3)c3ccc(-c4ccccc4)cc3-c3ccccc3)cc21 ; Cc1cc(-c2ccccc2)cc(-c2ccccc2)c1N(c1ccc(-c2cccc3ccccc23)cc1)c1ccc2c(c1)C(C)(C)c1ccccc1-2]

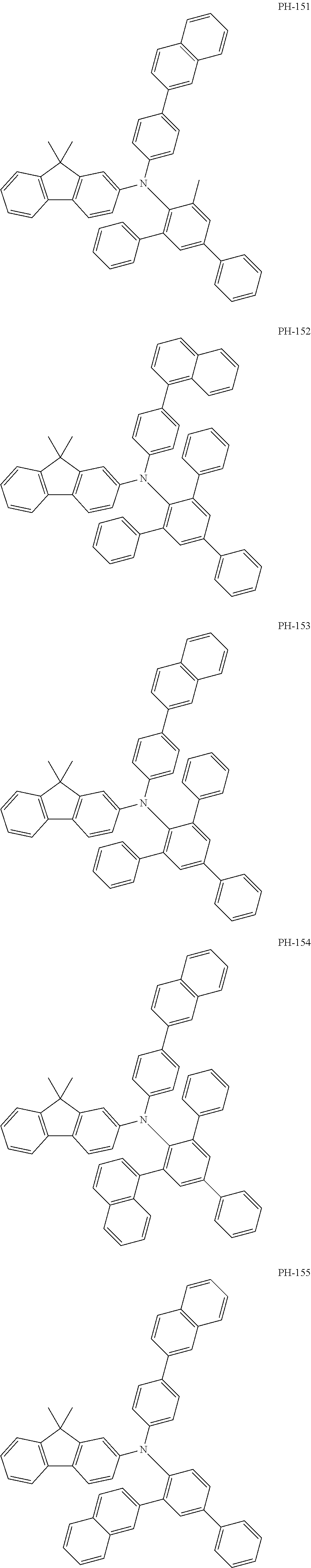 [SMILES: Cc1cc(-c2ccccc2)cc(-c2ccccc2)c1N(c1ccc(-c2ccc3ccccc3c2)cc1)c1ccc2c(c1)C(C)(C)c1ccccc1-2 ; CC1(C)c2ccccc2-c2ccc(N(c3ccc(-c4cccc5ccccc45)cc3)c3c(-c4ccccc4)cc(-c4ccccc4)cc3-c3ccccc3)cc21 ; CC1(C)c2ccccc2-c2ccc(N(c3ccc(-c4ccc5ccccc5c4)cc3)c3c(-c4ccccc4)cc(-c4ccccc4)cc3-c3ccccc3)cc21 ; CC1(C)c2ccccc2-c2ccc(N(c3ccc(-c4ccc5ccccc5c4)cc3)c3c(-c4ccccc4)cc(-c4ccccc4)cc3-c3cccc4ccccc34)cc21 ; CC1(C)c2ccccc2-c2ccc(N(c3ccc(-c4ccc5ccccc5c4)cc3)c3ccc(-c4ccccc4)cc3-c3ccc4ccccc4c3)cc21]

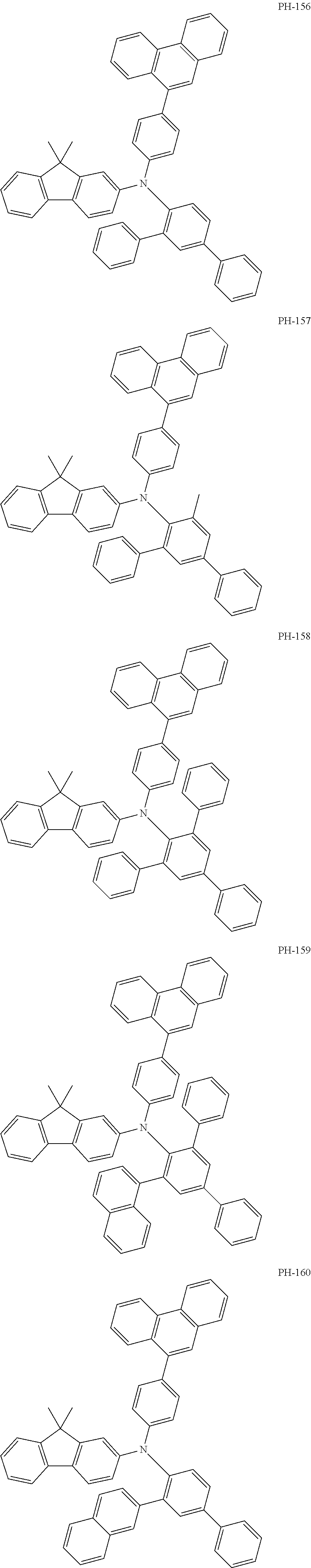

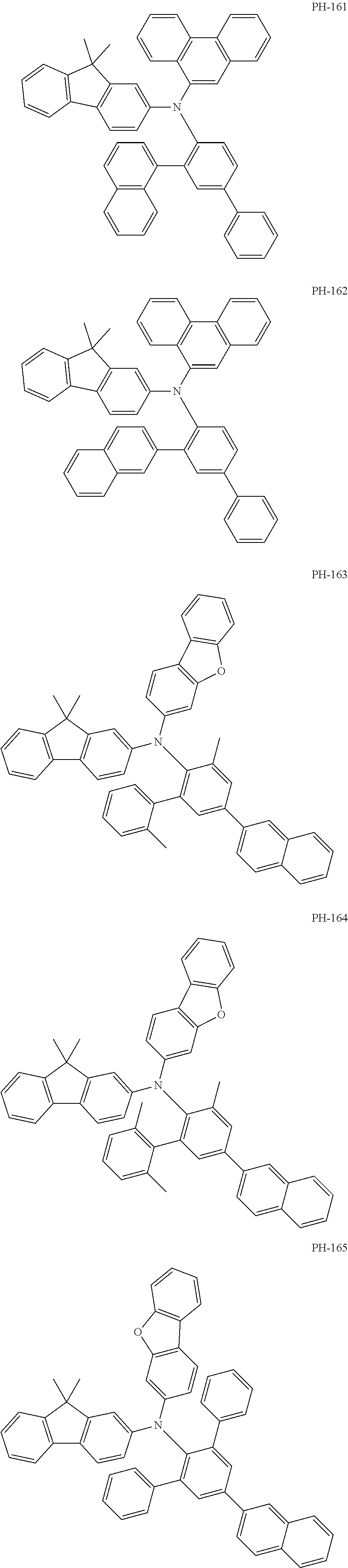 [SMILES: CC1(C)c2ccccc2-c2ccc(N(c3ccc(-c4ccccc4)cc3-c3cccc4ccccc34)c3cc4ccccc4c4ccccc34)cc21 ; CC1(C)c2ccccc2-c2ccc(N(c3ccc(-c4ccccc4)cc3-c3ccc4ccccc4c3)c3cc4ccccc4c4ccccc34)cc21 ; Cc1ccccc1-c1cc(-c2ccc3ccccc3c2)cc(C)c1N(c1ccc2c(c1)C(C)(C)c1ccccc1-2)c1ccc2c(c1)oc1ccccc12 ; Cc1cccc(C)c1-c1cc(-c2ccc3ccccc3c2)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccc5ccccc5c4)cc3-c3ccccc3)cc21]

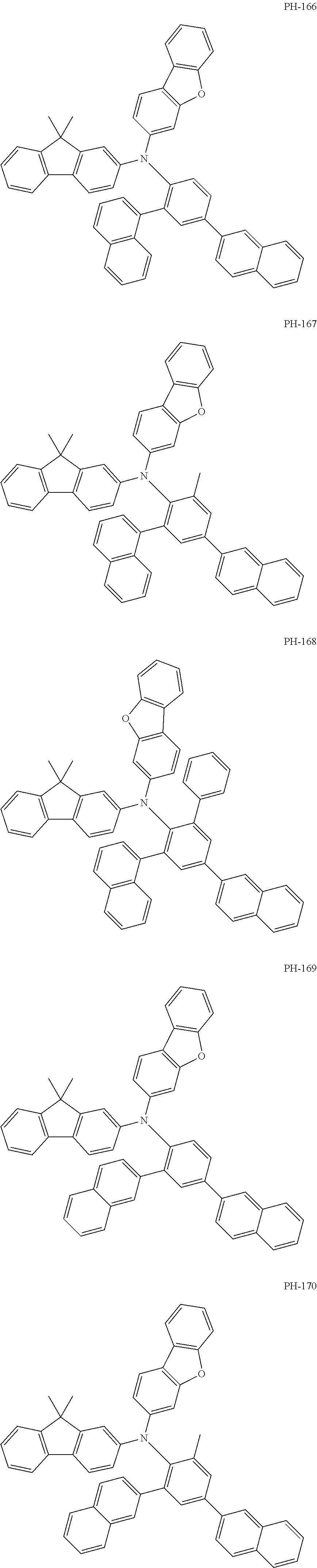 [SMILES: CC1(C)c2ccccc2-c2ccc(N(c3ccc4c(c3)oc3ccccc34)c3ccc(-c4ccc5ccccc5c4)cc3-c3cccc4ccccc34)cc21 ; Cc1cc(-c2ccc3ccccc3c2)cc(-c2cccc3ccccc23)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccc5ccccc5c4)cc3-c3cccc4ccccc34)cc21 ; CC1(C)c2ccccc2-c2ccc(N(c3ccc4c(c3)oc3ccccc34)c3ccc(-c4ccc5ccccc5c4)cc3-c3ccc4ccccc4c3)cc21 ; Cc1cc(-c2ccc3ccccc3c2)cc(-c2ccc3ccccc3c2)c1N(c1ccc2c(c1)C(C)(C)c1ccccc1-2)c1ccc2c(c1)oc1ccccc12]

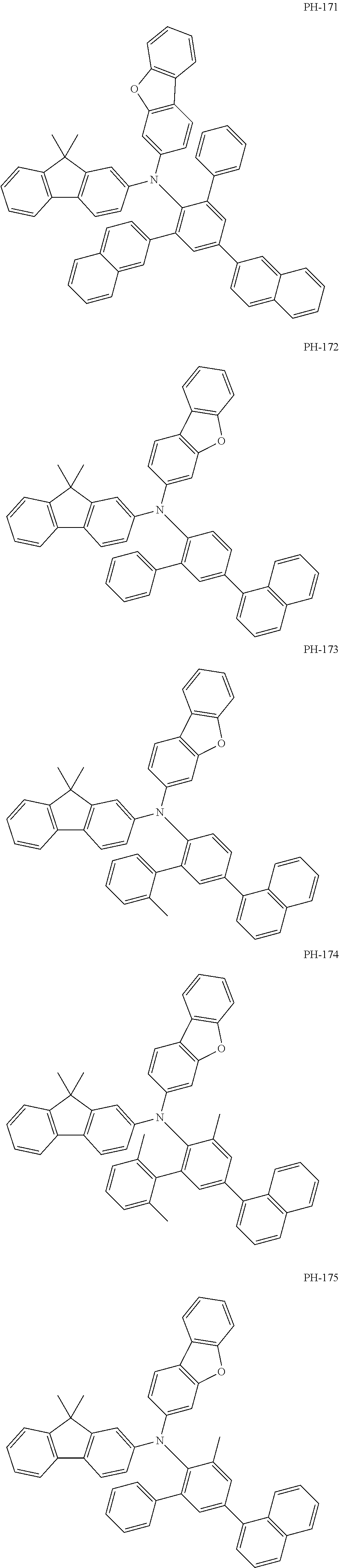 [SMILES: CC1(C)c2ccccc2-c2ccc(N(c3ccc4c(c3)oc3ccccc34)c3c(-c4ccccc4)cc(-c4ccc5ccccc5c4)cc3-c3ccc4ccccc4c3)cc21 ; CC1(C)c2ccccc2-c2ccc(N(c3ccc4c(c3)oc3ccccc34)c3ccc(-c4cccc5ccccc45)cc3-c3ccccc3)cc21 ; Cc1ccccc1-c1cc(-c2cccc3ccccc23)ccc1N(c1ccc2c(c1)C(C)(C)c1ccccc1-2)c1ccc2c(c1)oc1ccccc12 ; Cc1cccc(C)c1-c1cc(-c2cccc3ccccc23)cc(C)c1N(c1ccc2c(c1)C(C)(C)c1ccccc1-2)c1ccc2c(c1)oc1ccccc12 ; Cc1cc(-c2cccc3ccccc23)cc(-c2ccccc2)c1N(c1ccc2c(c1)C(C)(C)c1ccccc1-2)c1ccc2c(c1)oc1ccccc12]

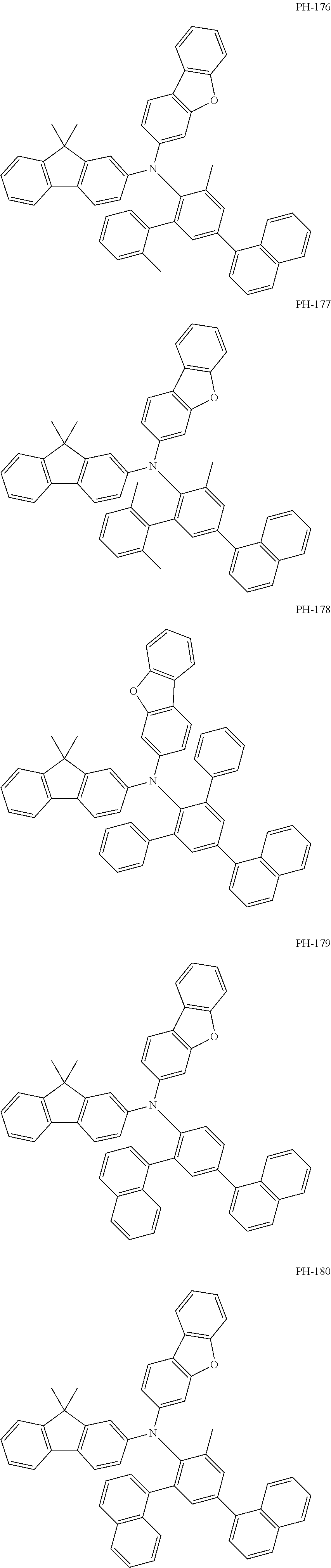 [SMILES: Cc1ccccc1-c1cc(-c2cccc3ccccc23)cc(C)c1N(c1ccc2c(c1)C(C)(C)c1ccccc1-2)c1ccc2c(c1)oc1ccccc12 ; Cc1cccc(C)c1-c1cc(-c2cccc3ccccc23)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4cccc5ccccc45)cc3-c3ccccc3)cc21 ; CC1(C)c2ccccc2-c2ccc(N(c3ccc4c(c3)oc3ccccc34)c3ccc(-c4cccc5ccccc45)cc3-c3cccc4ccccc34)cc21 ; Cc1cc(-c2cccc3ccccc23)cc(-c2cccc3ccccc23)c1N(c1ccc2c(c1)C(C)(C)c1ccccc1-2)c1ccc2c(c1)oc1ccccc12]

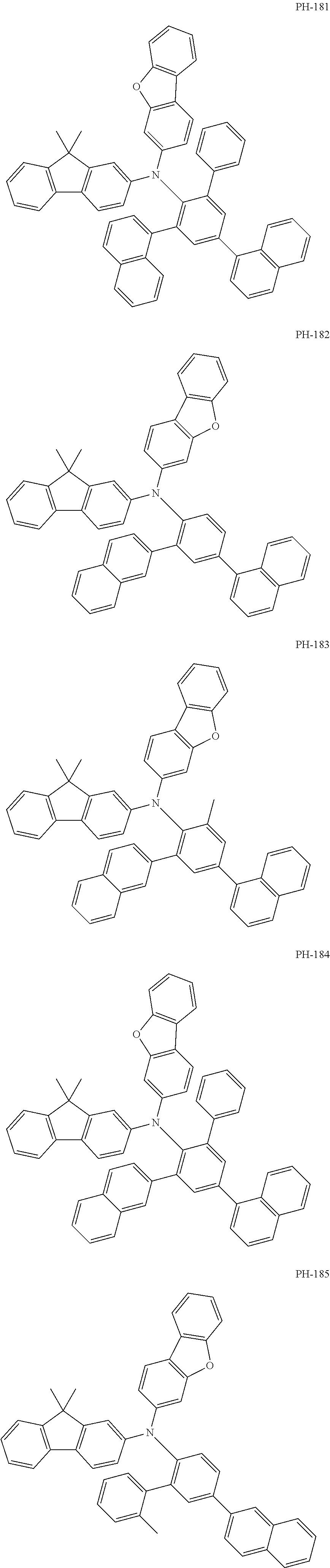 [SMILES: CC1(C)c2ccccc2-c2ccc(N(c3ccc4c(c3)oc3ccccc34)c3c(-c4ccccc4)cc(-c4cccc5ccccc45)cc3-c3cccc4ccccc34)cc21 ; CC1(C)c2ccccc2-c2ccc(N(c3ccc4c(c3)oc3ccccc34)c3ccc(-c4cccc5ccccc45)cc3-c3ccc4ccccc4c3)cc21 ; Cc1cc(-c2cccc3ccccc23)cc(-c2ccc3ccccc3c2)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4cccc5ccccc45)cc3-c3ccc4ccccc4c3)cc21 ; Cc1ccccc1-c1cc(-c2ccc3ccccc3c2)ccc1N(c1ccc2c(c1)C(C)(C)c1ccccc1-2)c1ccc2c(c1)oc1ccccc12]

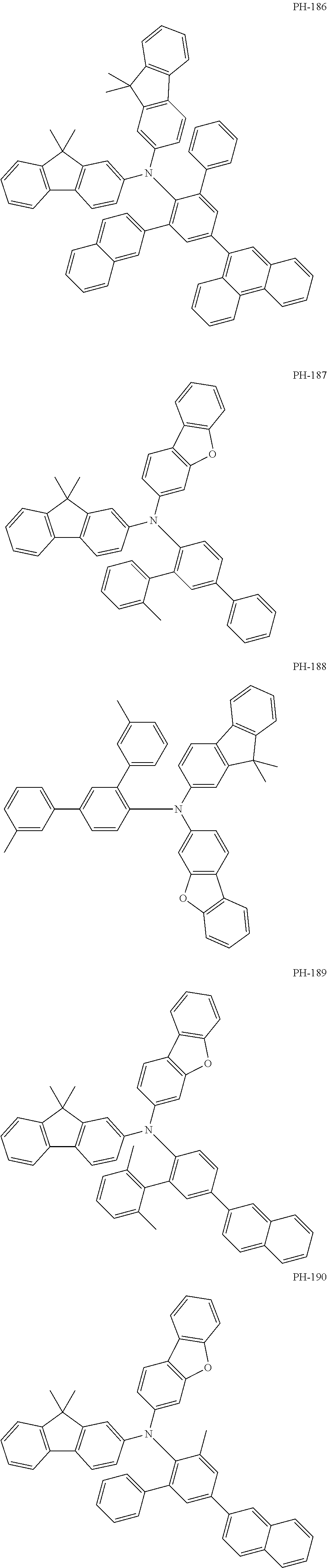 [SMILES: CC1(C)c2ccccc2-c2ccc(N(c3ccc4c(c3)C(C)(C)c3ccccc3-4)c3c(-c4ccccc4)cc(-c4cc5ccccc5c5ccccc45)cc3-c3ccc4ccccc4c3)cc21 ; Cc1ccccc1-c1cc(-c2ccccc2)ccc1N(c1ccc2c(c1)C(C)(C)c1ccccc1-2)c1ccc2c(c1)oc1ccccc12 ; Cc1cccc(-c2ccc(N(c3ccc4c(c3)C(C)(C)c3ccccc3-4)c3ccc4c(c3)oc3ccccc34)c(-c3cccc(C)c3)c2)c1 ; Cc1cccc(C)c1-c1cc(-c2ccc3ccccc3c2)ccc1N(c1ccc2c(c1)C(C)(C)c1ccccc1-2)c1ccc2c(c1)oc1ccccc12 ; Cc1cc(-c2ccc3ccccc3c2)cc(-c2ccccc2)c1N(c1ccc2c(c1)C(C)(C)c1ccccc1-2)c1ccc2c(c1)oc1ccccc12]

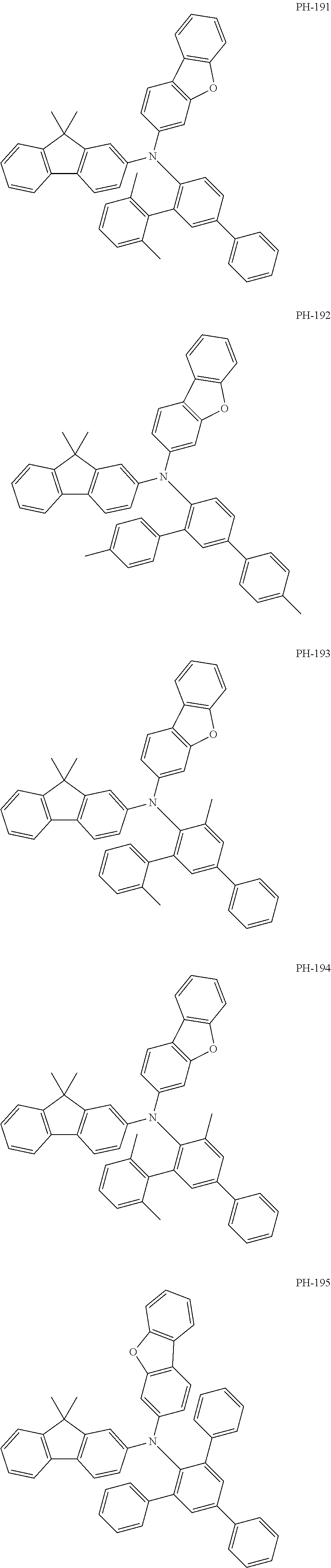 [SMILES: Cc1cccc(C)c1-c1cc(-c2ccccc2)ccc1N(c1ccc2c(c1)C(C)(C)c1ccccc1-2)c1ccc2c(c1)oc1ccccc12 ; Cc1ccc(-c2ccc(N(c3ccc4c(c3)C(C)(C)c3ccccc3-4)c3ccc4c(c3)oc3ccccc34)c(-c3ccc(C)cc3)c2)cc1 ; Cc1ccccc1-c1cc(-c2ccccc2)cc(C)c1N(c1ccc2c(c1)C(C)(C)c1ccccc1-2)c1ccc2c(c1)oc1ccccc12 ; Cc1cccc(C)c1-c1cc(-c2ccccc2)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccccc4)cc3-c3ccccc3)cc21]

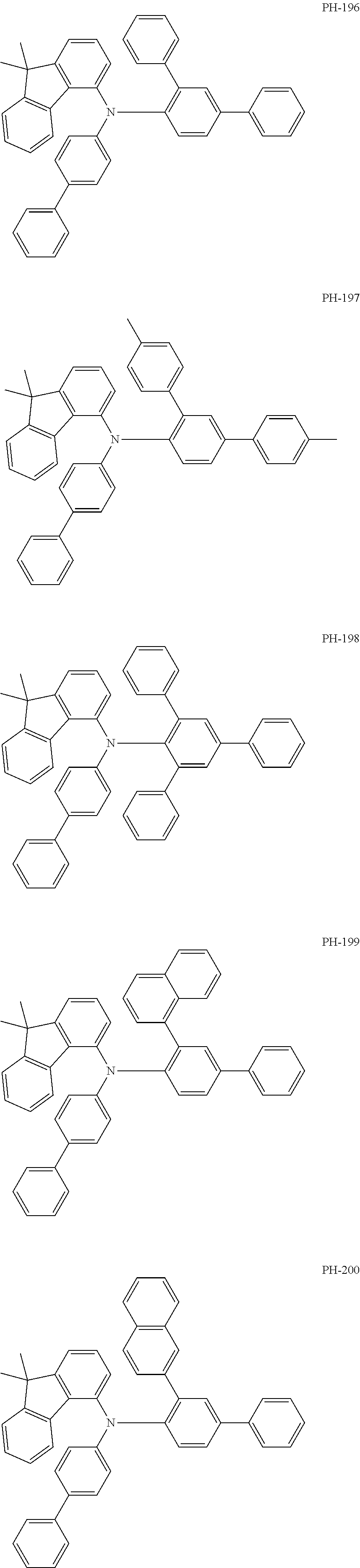

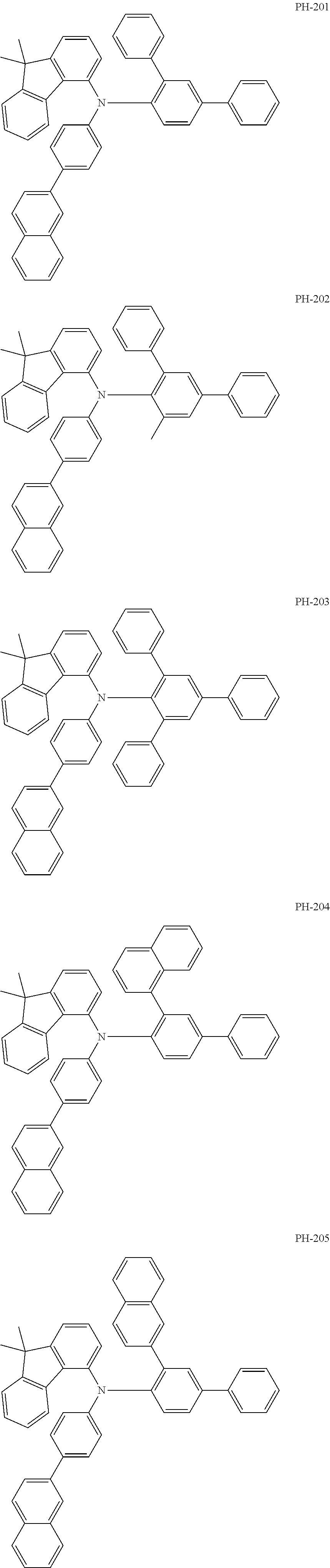 [SMILES: CC1(C)c2ccccc2-c2c(N(c3ccc(-c4ccc5ccccc5c4)cc3)c3ccc(-c4ccccc4)cc3-c3ccccc3)cccc21 ; Cc1cc(-c2ccccc2)cc(-c2ccccc2)c1N(c1ccc(-c2ccc3ccccc3c2)cc1)c1cccc2c1-c1ccccc1C2(C)C ; CC1(C)c2ccccc2-c2c(N(c3ccc(-c4ccc5ccccc5c4)cc3)c3c(-c4ccccc4)cc(-c4ccccc4)cc3-c3ccccc3)cccc21 ; CC1(C)c2ccccc2-c2c(N(c3ccc(-c4ccc5ccccc5c4)cc3)c3ccc(-c4ccccc4)cc3-c3cccc4ccccc34)cccc21 ; CC1(C)c2ccccc2-c2c(N(c3ccc(-c4ccc5ccccc5c4)cc3)c3ccc(-c4ccccc4)cc3-c3ccc4ccccc4c3)cccc21]

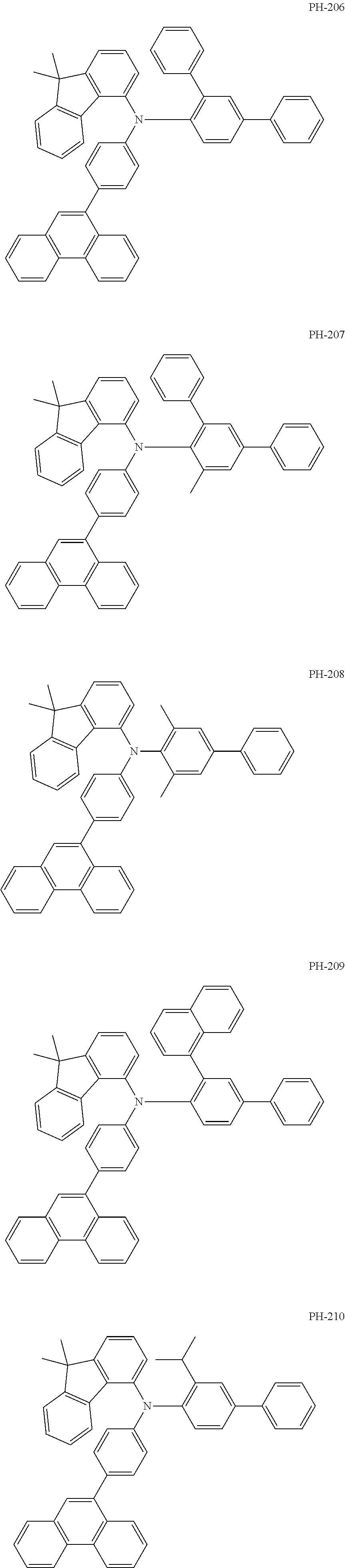 [SMILES: CC1(C)c2ccccc2-c2c(N(c3ccc(-c4cc5ccccc5c5ccccc45)cc3)c3ccc(-c4ccccc4)cc3-c3ccccc3)cccc21 ; Cc1cc(-c2ccccc2)cc(-c2ccccc2)c1N(c1ccc(-c2cc3ccccc3c3ccccc23)cc1)c1cccc2c1-c1ccccc1C2(C)C ; Cc1cc(-c2ccccc2)cc(C)c1N(c1ccc(-c2cc3ccccc3c3ccccc23)cc1)c1cccc2c1-c1ccccc1C2(C)C ; CC1(C)c2ccccc2-c2c(N(c3ccc(-c4cc5ccccc5c5ccccc45)cc3)c3ccc(-c4ccccc4)cc3-c3cccc4ccccc34)cccc21 ; CC(C)c1cc(-c2ccccc2)ccc1N(c1ccc(-c2cc3ccccc3c3ccccc23)cc1)c1cccc2c1-c1ccccc1C2(C)C]

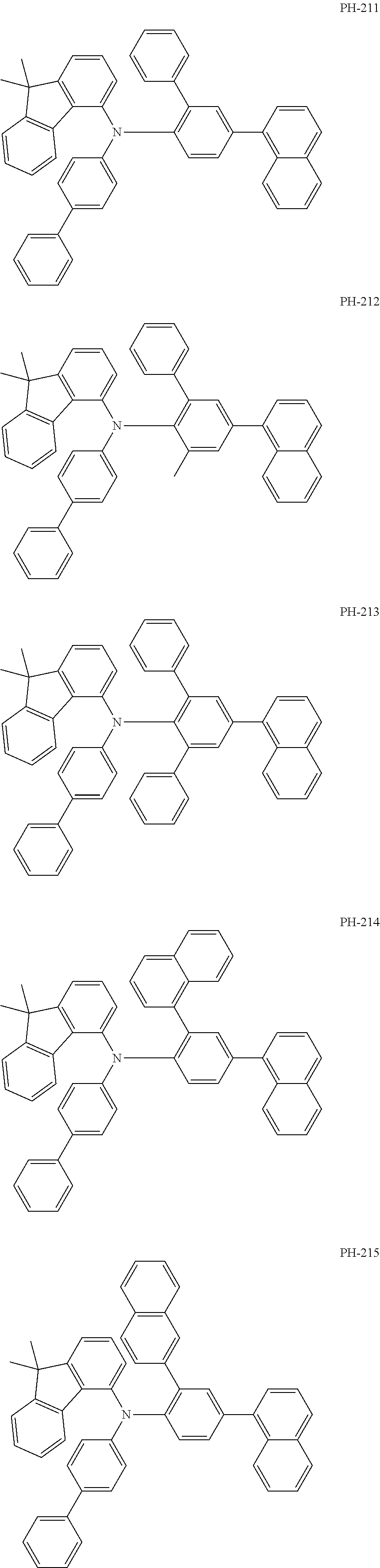 [SMILES: CC1(C)c2ccccc2-c2c(N(c3ccc(-c4ccccc4)cc3)c3ccc(-c4cccc5ccccc45)cc3-c3ccccc3)cccc21 ; Cc1cc(-c2cccc3ccccc23)cc(-c2ccccc2)c1N(c1ccc(-c2ccccc2)cc1)c1cccc2c1-c1ccccc1C2(C)C ; CC1(C)c2ccccc2-c2c(N(c3ccc(-c4ccccc4)cc3)c3c(-c4ccccc4)cc(-c4cccc5ccccc45)cc3-c3ccccc3)cccc21 ; CC1(C)c2ccccc2-c2c(N(c3ccc(-c4ccccc4)cc3)c3ccc(-c4cccc5ccccc45)cc3-c3cccc4ccccc34)cccc21 ; CC1(C)c2ccccc2-c2c(N(c3ccc(-c4ccccc4)cc3)c3ccc(-c4cccc5ccccc45)cc3-c3ccc4ccccc4c3)cccc21]

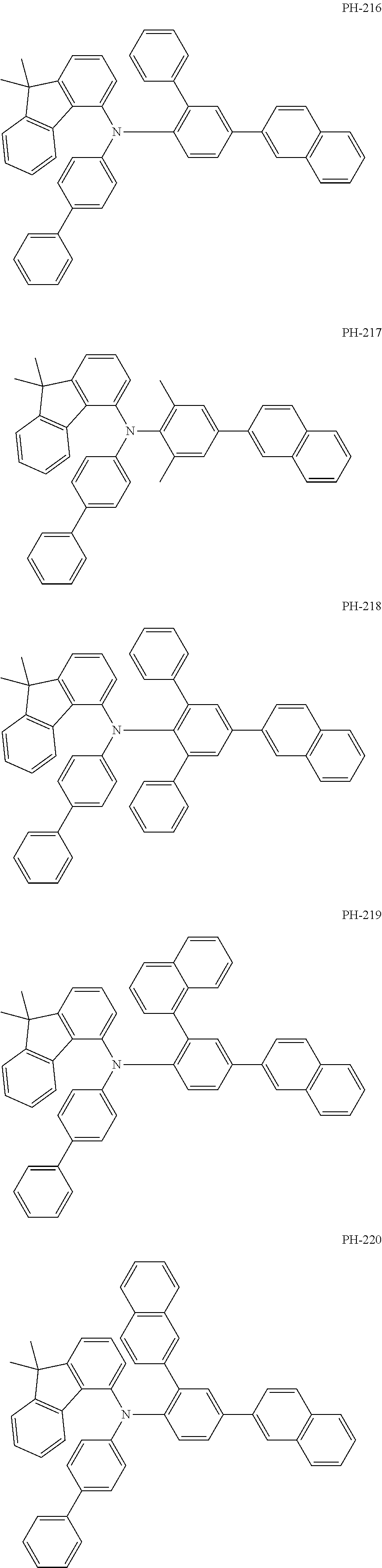 [SMILES: CC1(C)c2ccccc2-c2c(N(c3ccc(-c4ccccc4)cc3)c3ccc(-c4ccc5ccccc5c4)cc3-c3ccccc3)cccc21 ; Cc1cc(-c2ccc3ccccc3c2)cc(C)c1N(c1ccc(-c2ccccc2)cc1)c1cccc2c1-c1ccccc1C2(C)C ; CC1(C)c2ccccc2-c2c(N(c3ccc(-c4ccccc4)cc3)c3c(-c4ccccc4)cc(-c4ccc5ccccc5c4)cc3-c3ccccc3)cccc21 ; CC1(C)c2ccccc2-c2c(N(c3ccc(-c4ccccc4)cc3)c3ccc(-c4ccc5ccccc5c4)cc3-c3cccc4ccccc34)cccc21 ; CC1(C)c2ccccc2-c2c(N(c3ccc(-c4ccccc4)cc3)c3ccc(-c4ccc5ccccc5c4)cc3-c3ccc4ccccc4c3)cccc21]

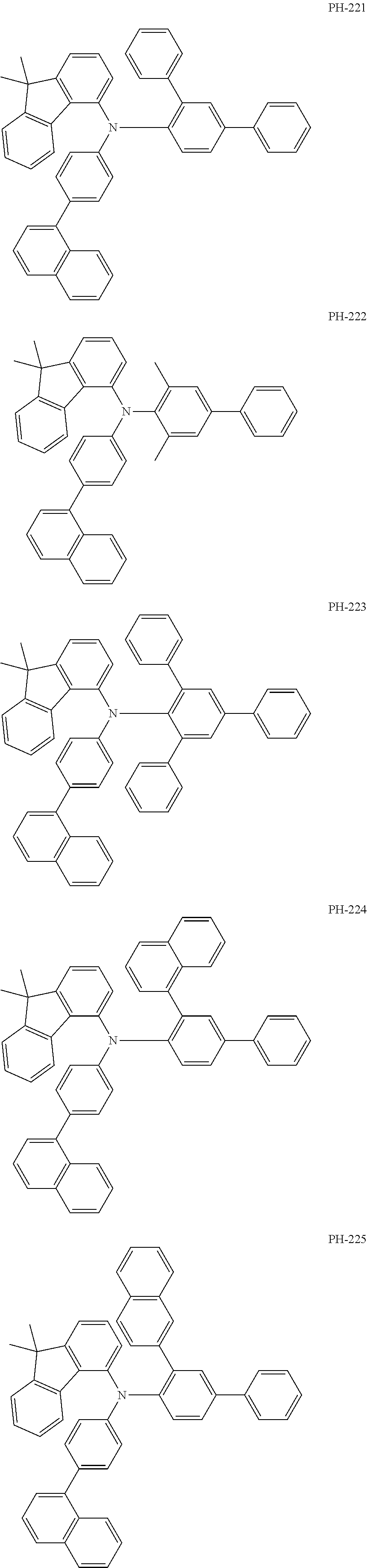 [SMILES: CC1(C)c2ccccc2-c2c(N(c3ccc(-c4cccc5ccccc45)cc3)c3ccc(-c4ccccc4)cc3-c3ccccc3)cccc21 ; Cc1cc(-c2ccccc2)cc(C)c1N(c1ccc(-c2cccc3ccccc23)cc1)c1cccc2c1-c1ccccc1C2(C)C ; CC1(C)c2ccccc2-c2c(N(c3ccc(-c4cccc5ccccc45)cc3)c3c(-c4ccccc4)cc(-c4ccccc4)cc3-c3ccccc3)cccc21 ; CC1(C)c2ccccc2-c2c(N(c3ccc(-c4cccc5ccccc45)cc3)c3ccc(-c4ccccc4)cc3-c3cccc4ccccc34)cccc21 ; CC1(C)c2ccccc2-c2c(N(c3ccc(-c4cccc5ccccc45)cc3)c3ccc(-c4ccccc4)cc3-c3ccc4ccccc4c3)cccc21]

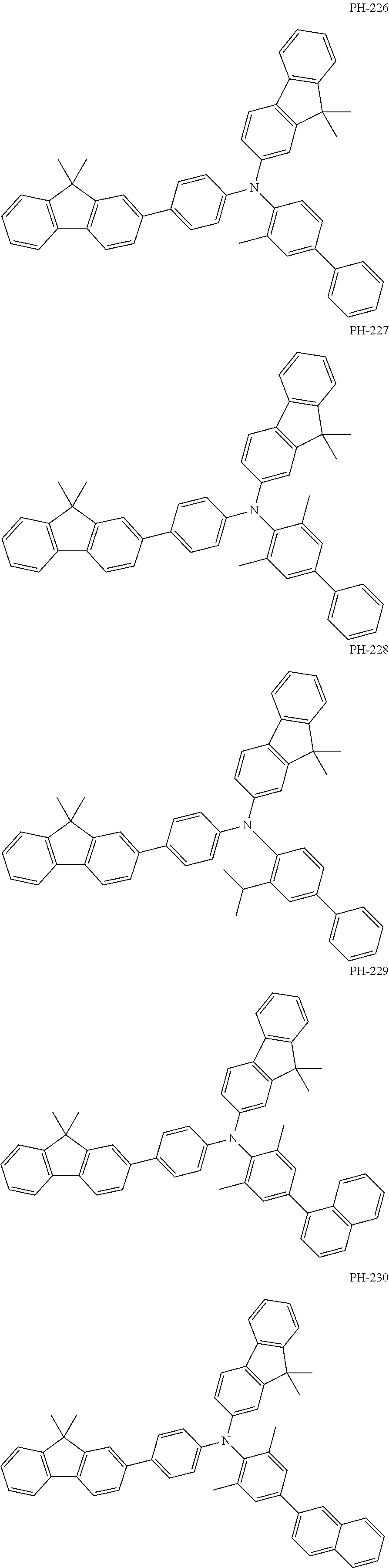 [SMILES: Cc1cc(-c2ccccc2)ccc1N(c1ccc(-c2ccc3c(c2)C(C)(C)c2ccccc2-3)cc1)c1ccc2c(c1)C(C)(C)c1ccccc1-2 ; Cc1cc(-c2ccccc2)cc(C)c1N(c1ccc(-c2ccc3c(c2)C(C)(C)c2ccccc2-3)cc1)c1ccc2c(c1)C(C)(C)c1ccccc1-2 ; CC(C)c1cc(-c2ccccc2)ccc1N(c1ccc(-c2ccc3c(c2)C(C)(C)c2ccccc2-3)cc1)c1ccc2c(c1)C(C)(C)c1ccccc1-2 ; Cc1cc(-c2cccc3ccccc23)cc(C)c1N(c1ccc(-c2ccc3c(c2)C(C)(C)c2ccccc2-3)cc1)c1ccc2c(c1)C(C)(C)c1ccccc1-2 ; Cc1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2]

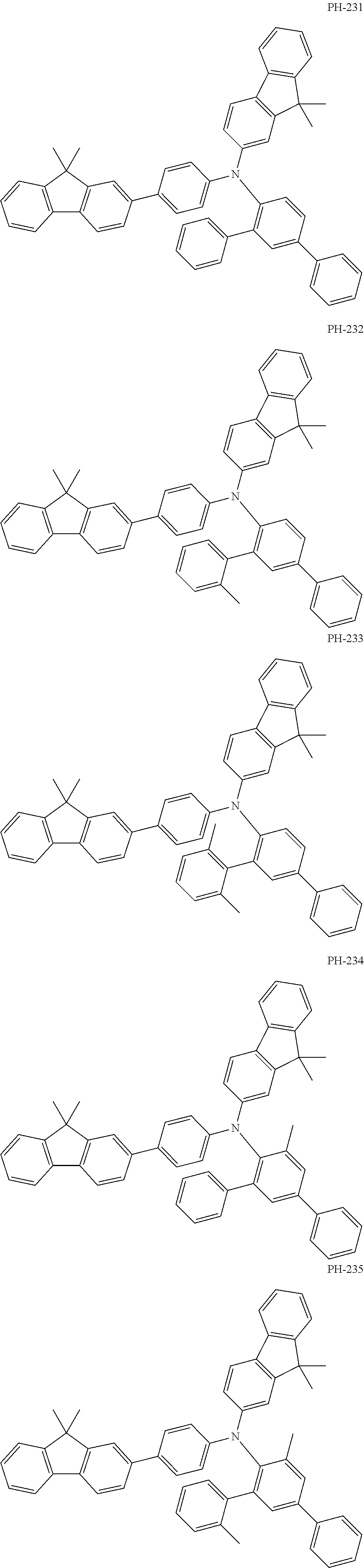

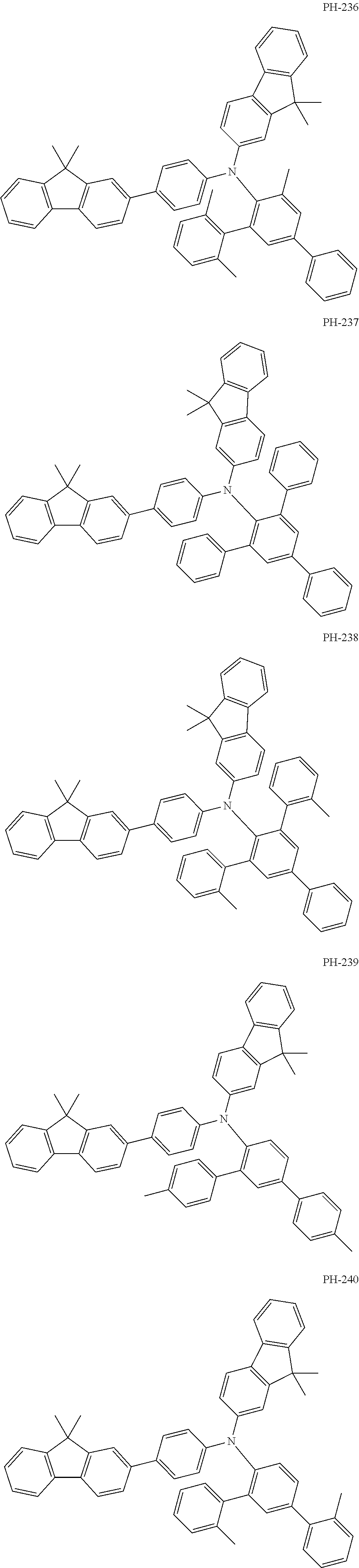

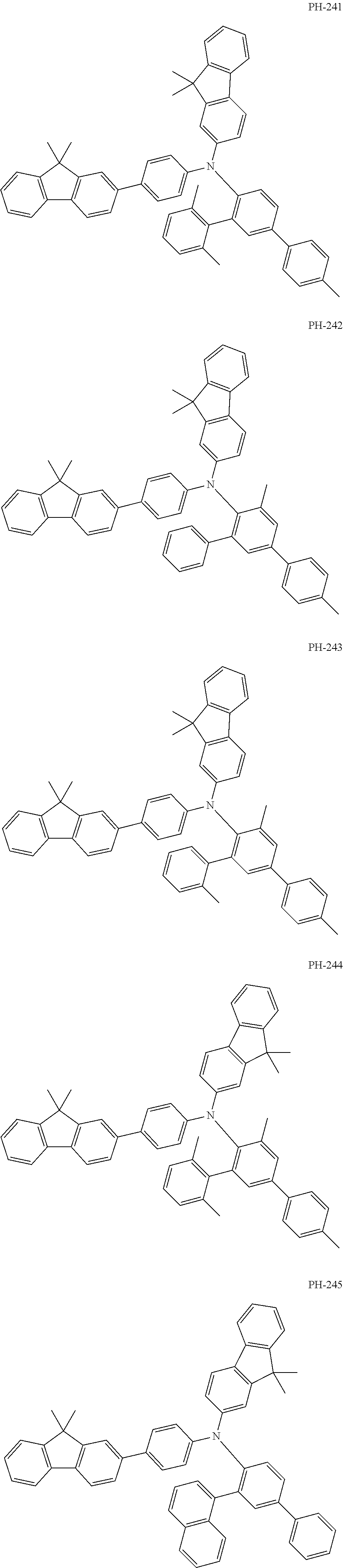

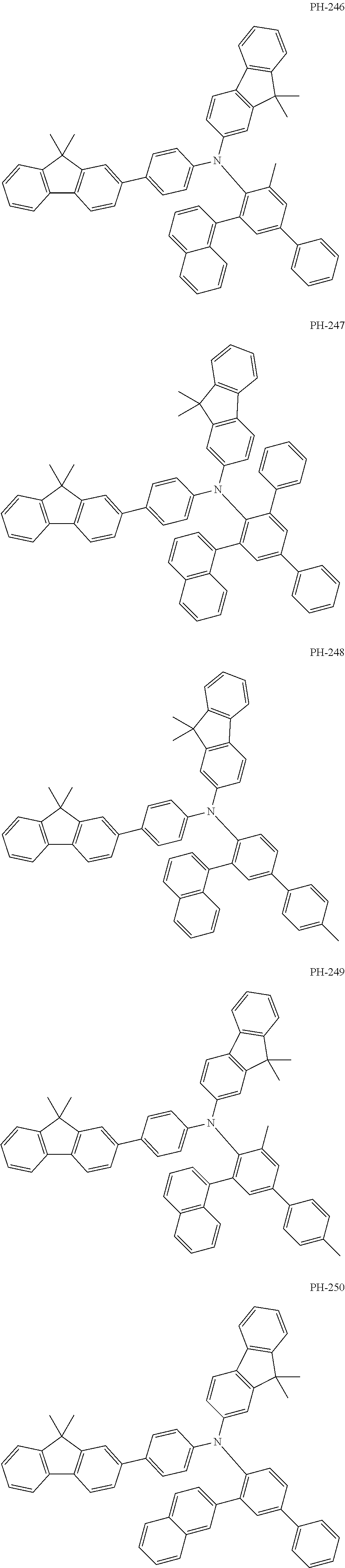

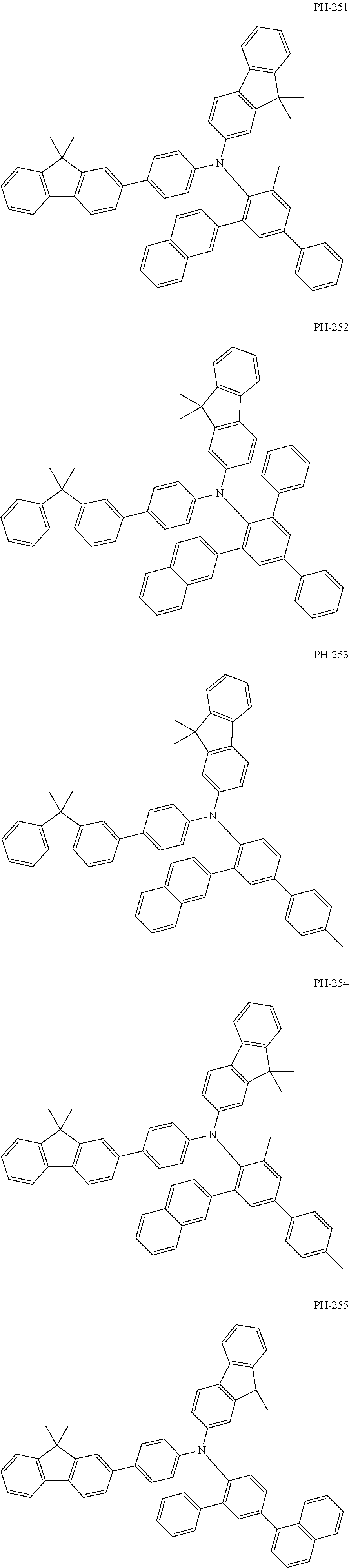

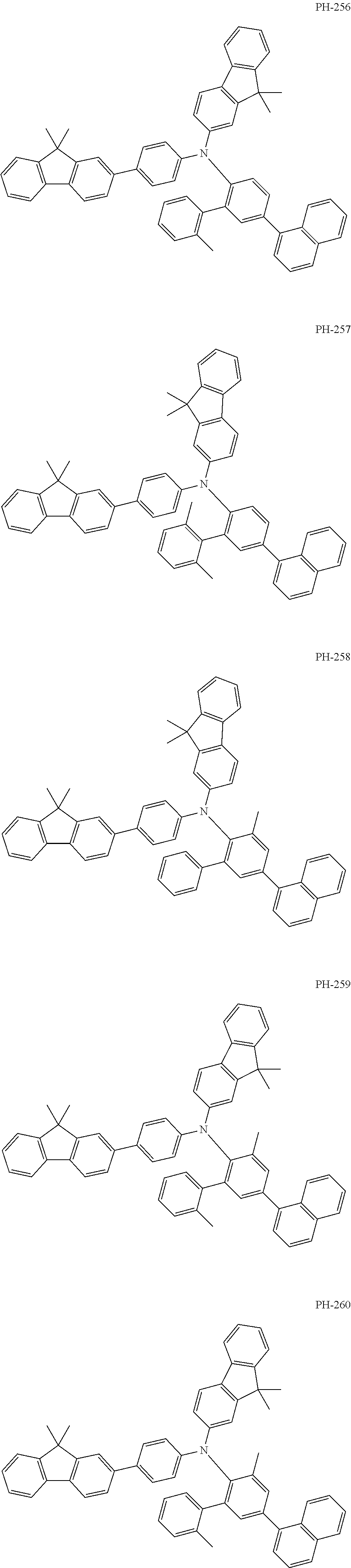

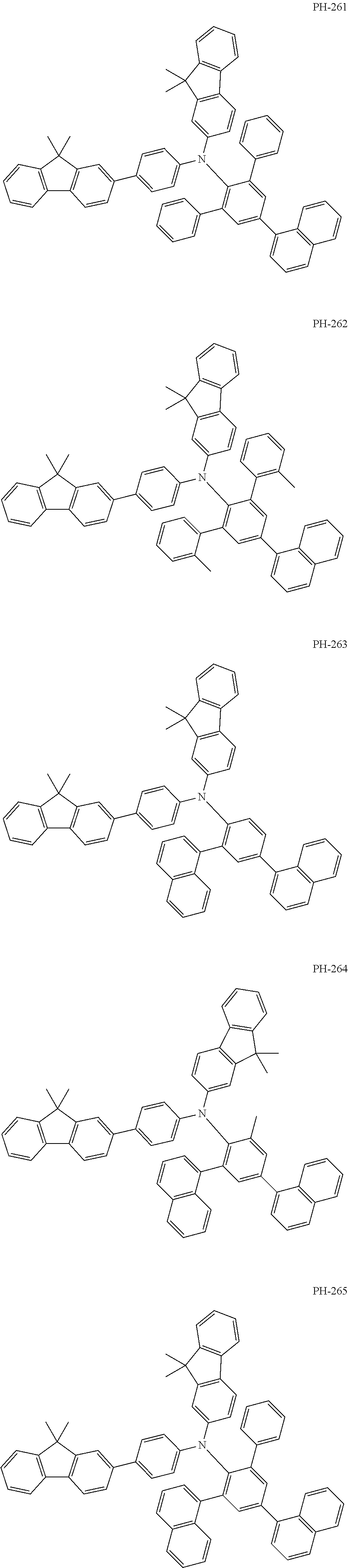

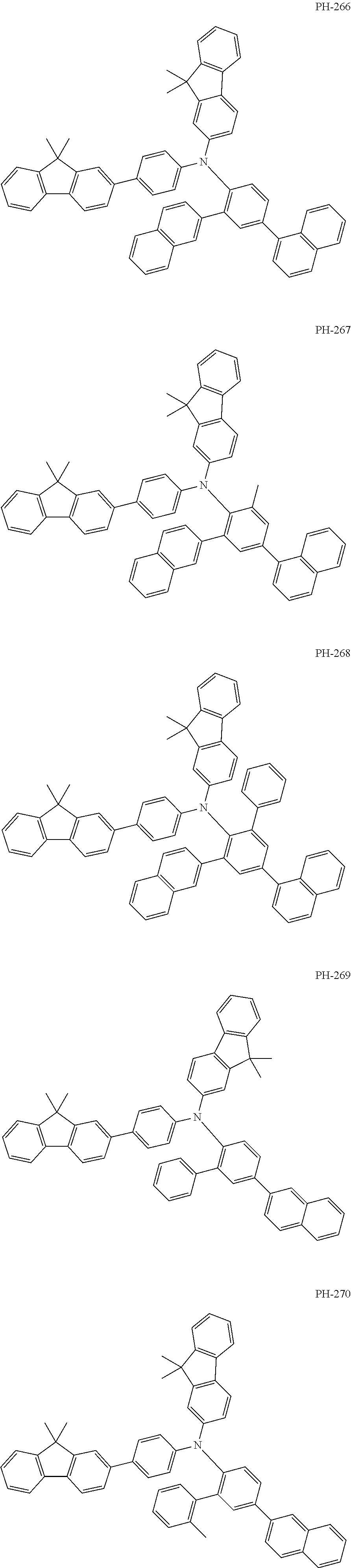

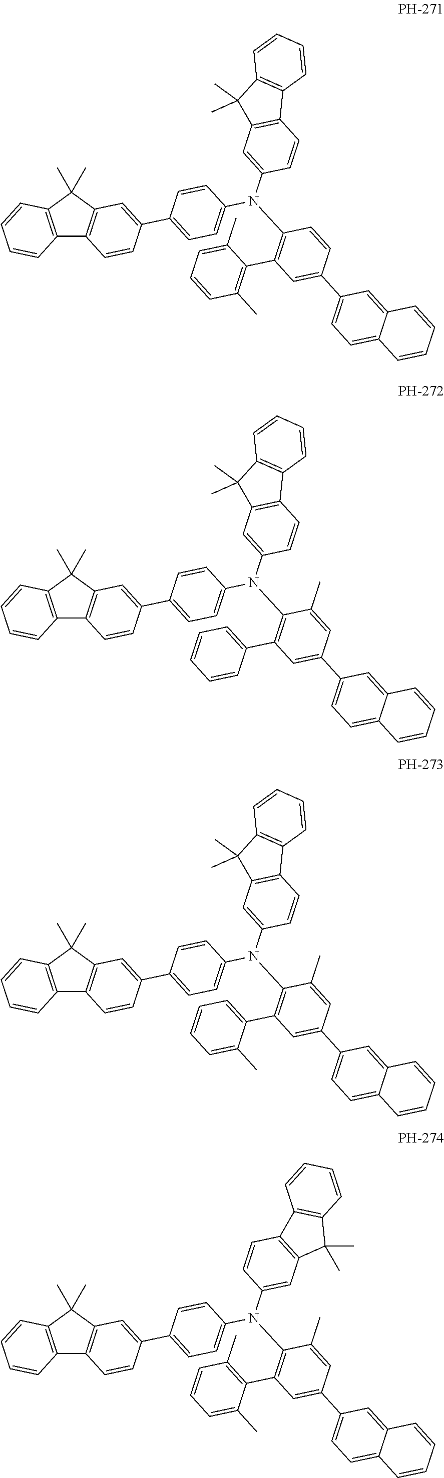 [SMILES: Cc1cccc(C)c1-c1cc(-c2ccc3ccccc3c2)ccc1N(c1ccc(-c2ccc3c(c2)C(C)(C)c2ccccc2-3)cc1)c1ccc2c(c1)C(C)(C)c1ccccc1-2 ; Cc1cc(-c2ccc3ccccc3c2)cc(-c2ccccc2)c1N(c1ccc(-c2ccc3c(c2)C(C)(C)c2ccccc2-3)cc1)c1ccc2c(c1)C(C)(C)c1ccccc1-2 ; Cc1ccccc1-c1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2 ; Cc1cccc(C)c1-c1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2]

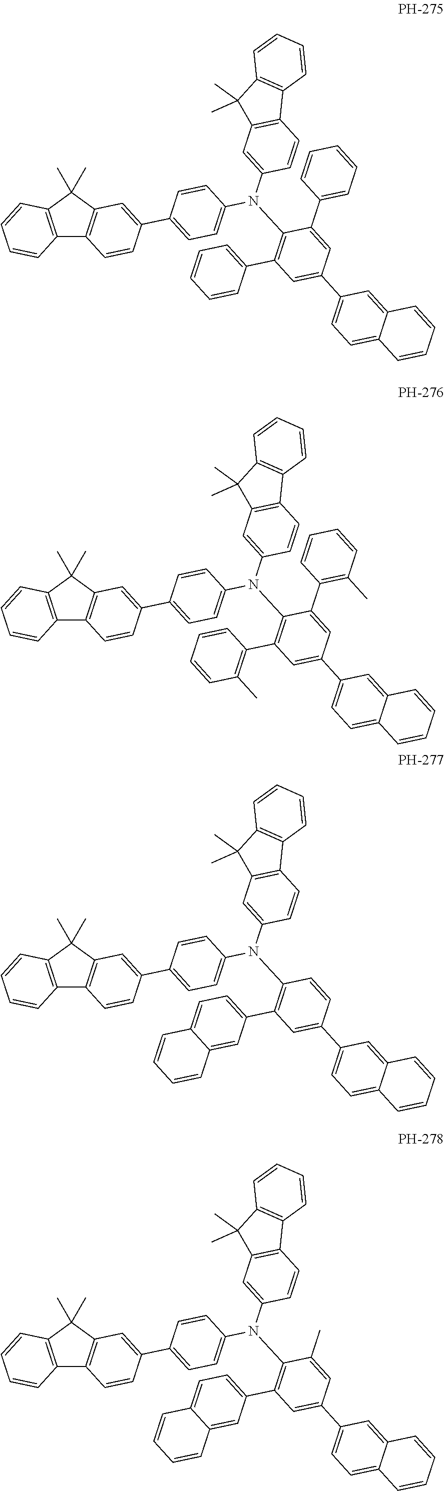 [SMILES: CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4ccccc4)cc3)cc21 ; Cc1ccccc1-c1cc(-c2ccc3ccccc3c2)cc(-c2ccccc2C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4ccc(-c5ccc6ccccc6c5)cc4-c4ccc5ccccc5c4)cc3)cc21 ; Cc1cc(-c2ccc3ccccc3c2)cc(-c2ccc3ccccc3c2)c1N(c1ccc(-c2ccc3c(c2)C(C)(C)c2ccccc2-3)cc1)c1ccc2c(c1)C(C)(C)c1ccccc1-2]

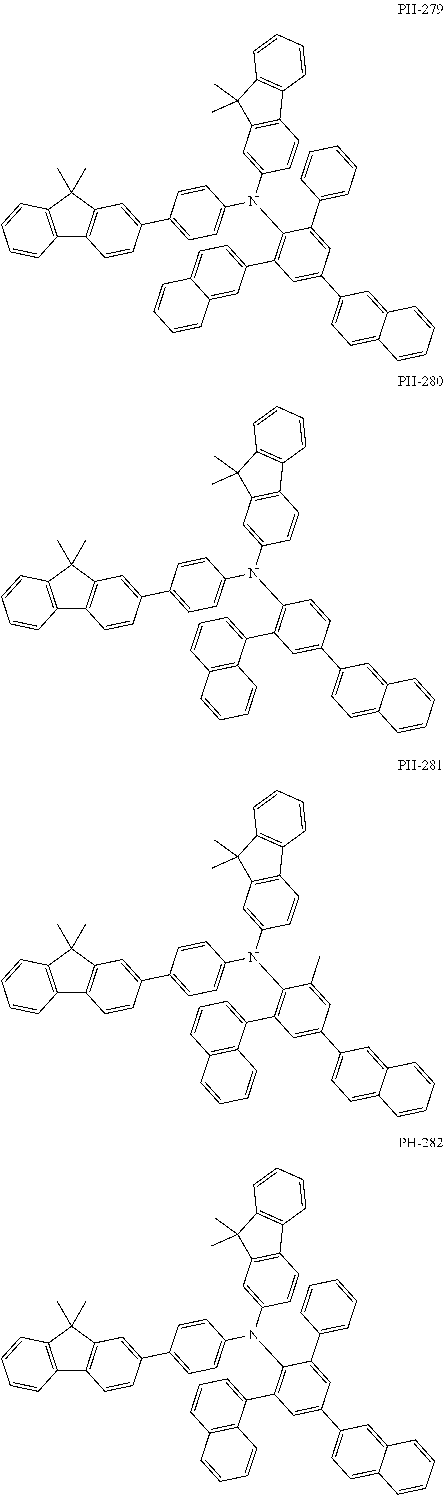 [SMILES: CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4ccc5ccccc5c4)cc3)cc21 ; CC1(C)c2ccccc2-c2ccc(-c3ccc(N(c4ccc5c(c4)C(C)(C)c4ccccc4-5)c4ccc(-c5ccc6ccccc6c5)cc4-c4cccc5ccccc45)cc3)cc21 ; Cc1cc(-c2ccc3ccccc3c2)cc(-c2cccc3ccccc23)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4cccc5ccccc45)cc3)cc21]

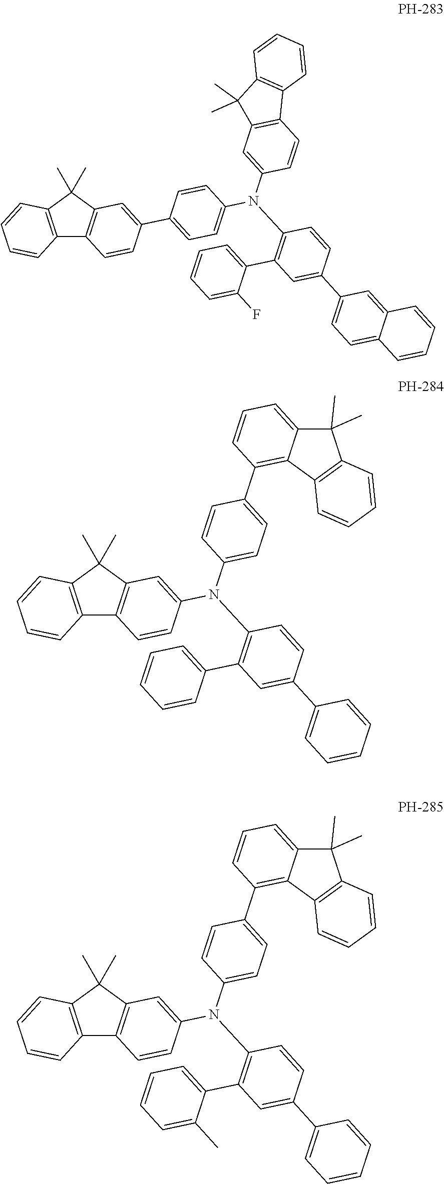 [SMILES: CC1(C)c2ccccc2-c2ccc(-c3ccc(N(c4ccc5c(c4)C(C)(C)c4ccccc4-5)c4ccc(-c5ccc6ccccc6c5)cc4-c4ccccc4F)cc3)cc21 ; CC1(C)c2ccccc2-c2ccc(N(c3ccc(-c4cccc5c4-c4ccccc4C5(C)C)cc3)c3ccc(-c4ccccc4)cc3-c3ccccc3)cc21 ; Cc1ccccc1-c1cc(-c2ccccc2)ccc1N(c1ccc(-c2cccc3c2-c2ccccc2C3(C)C)cc1)c1ccc2c(c1)C(C)(C)c1ccccc1-2]

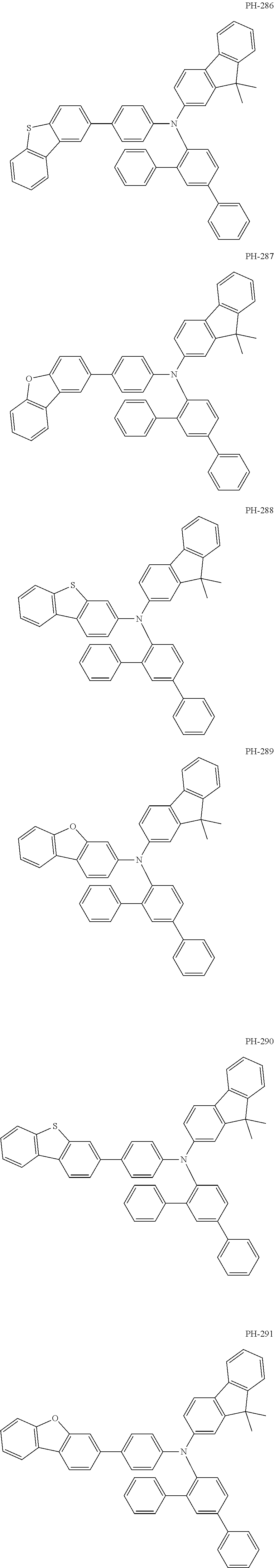

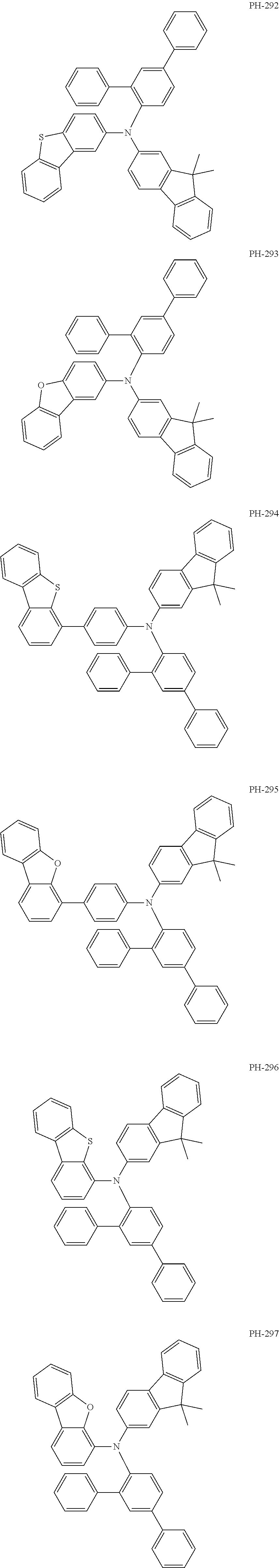

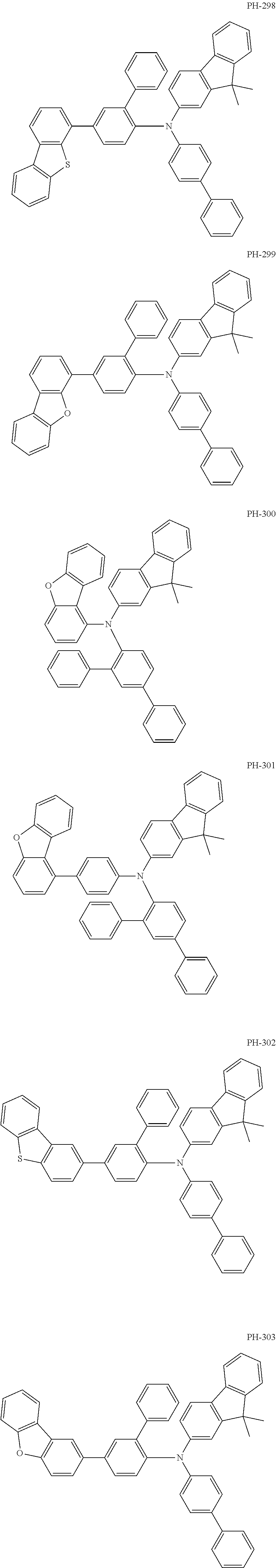

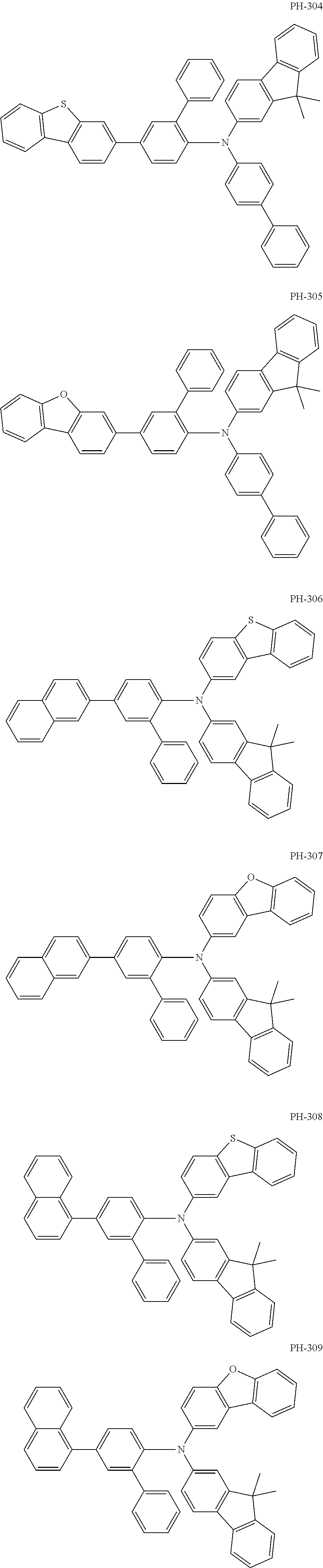

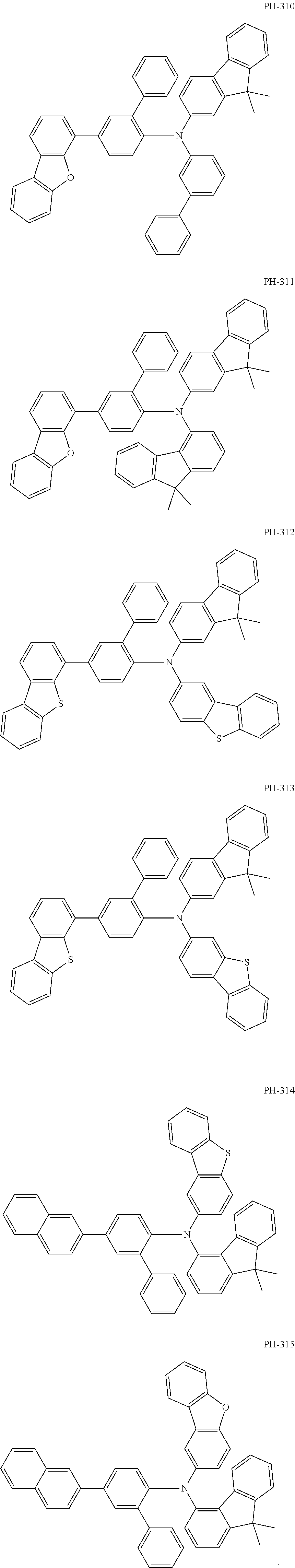

6. The organic light-emitting device of claim 1, wherein the second compound is contained in 50 to 90 wt % based on 100 wt % of a total weight of the hole injection layer.

7. The organic light-emitting device of claim 1, wherein the intermediate layer further comprises one or more of a hole transfer layer, an emission material layer, an electron-blocking layer, an electron transfer layer, and an electron injection layer.

8. An organic light-emitting device comprising:
an anode;
a cathode facing the anode; and
N emitting stacks between the anode and the cathode,
wherein the N is an integer greater than or equal to 2,
N−1 n-type charge generation layers and N−1 p-type charge generation layers are disposed between different the N emitting stacks, and
at least one of the p-type charge generation layers comprises a first compound represented by one of the following Chemical Formulas 1 and 2 and a second compound represented by the following Chemical Formula 3: 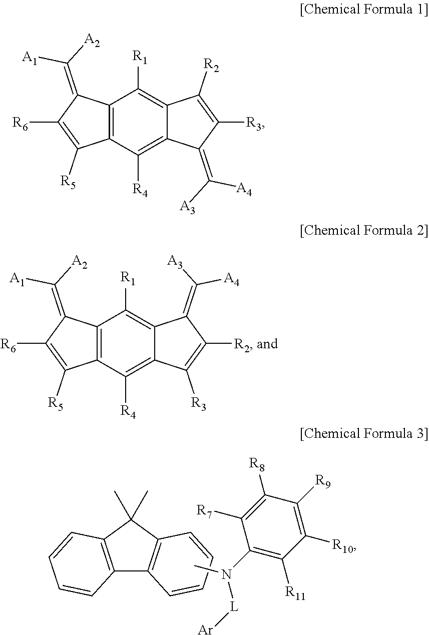
wherein in the Chemical Formulas 1 to 3,
R₁ to R₁₁ and A₁ to A₄ are the same or different from each other, and are each selected independently from a group consisting of hydrogen, deuterium, a cyano group, a trifluoromethyl group, a nitro group, a halogen group, a hydroxy group, a substituted or unsubstituted alkyl group having 1 to 30 carbon atoms, a substituted or unsubstituted cycloalkyl group having 3 to 20 carbon atoms, a substituted or unsubstituted alkenyl group having 2 to 30 carbon atoms, a substituted or unsubstituted cycloalkenyl group having 3 to 20 carbon atoms, a substituted or unsubstituted alkynyl group having 2 to 30 carbon atoms, a substituted or unsubstituted cycloalkynyl group having 3 to 20 carbon atoms, a substituted or unsubstituted aryl group having 6 to 30 carbon atoms, a substituted or unsubstituted arylalkyl group having 7 to 30 carbon atoms, a substituted or unsubstituted heteroaryl group having 5 to 60 carbon atoms, a substituted or unsubstituted heteroarylalkyl group having 6 to 60 carbon atoms, a substituted or unsubstituted amine group, a substituted or unsubstituted alkylamino group having 1 to 30 carbon atoms, an arylalkylamino group having 7 to 30 carbon atoms, a substituted or unsubstituted arylamino group having 6 to 30 carbon atoms, a substituted or unsubstituted heteroarylamino group having 5 to 60 carbon atoms, a substituted or unsubstituted silyl group, a substituted or unsubstituted alkylsilyl group having 1 to 30 carbon atoms, a substituted or unsubstituted arylsilyl group having 6 to 30 carbon atoms, a substituted or unsubstituted alkoxy group having 1 to 30 carbon atoms, a substituted or unsubstituted aryloxy group having 6 to 30 carbon atoms, a substituted or unsubstituted alkylthio group having 1 to 30 carbon atoms, and a substituted or unsubstituted arylthio group having 6 to 30 carbon atoms,
at least one or more of R₇, R₉, and R₁₁ are selected from a group consisting of a substituted or unsubstituted alkyl group having 1 to 30 carbon atoms, a substituted or unsubstituted aryl group having 5 to 30 carbon atoms, and a substituted or unsubstituted heteroaryl group having 3 to 30 carbon atoms,
L is each selected independently from a single bond, a substituted or unsubstituted aryl group having 6 to 30 carbon atoms, and a substituted or unsubstituted heteroaryl group having 6 to 30 carbon atoms,
Ar is the same or different from each other, and is each selected independently from a substituted or unsubstituted aryl group having 6 to 30 carbon atoms and a substituted or unsubstituted heteroaryl group having 5 to 60 carbon atoms, wherein Ar does not comprise a 9,9-diphenylfluorenyl group, and
if there are substituents of R₁ to R₁₁ and A₁ to A₄, L, and Ar present, the substituents are each substituted independently by one or more substituents selected from a group consisting of a cyano group, a trifluoromethyl group, a nitro group, a halogen group, a hydroxy group, an alkyl group having 1 to 30 carbon atoms, a cycloalkyl group having 3 to 20 carbon atoms, an alkenyl group having 2 to 30 carbon atoms, a cycloalkenyl group having 3 to 20 carbon atoms, an alkynyl group having 2 to 30 carbon atoms, a cycloalkynyl group having 3 to 20 carbon atoms, an aryl group having 6 to 30 carbon atoms, an arylalkyl group having 7 to 30 carbon atoms, a heteroaryl group having 5 to 60 carbon atoms, a heteroarylalkyl group having 6 to 60 carbon atoms, an amine group, an alkylamino group having 1 to 30 carbon atoms, an arylalkylamino group having 7 to 30 carbon atoms, an arylamino group having 6 to 30 carbon atoms, a heteroarylamino group having 5 to 60 carbon atoms, an alkylsilyl group having 1 to 30 carbon atoms, an arylsilyl group having 6 to 30 carbon atoms, an alkoxy group having 1 to 30 carbon atoms, an aryloxy group having 6 to 30 carbon atoms, an alkylthio group having 1 to 30 carbon atoms, and an arylthio group having 6 to 30 carbon atoms, and if substituted by a plurality of substituents, the substituents are the same or different from each other.

9. The organic light-emitting device of claim 8, wherein the Chemical Formula 3 is represented by one selected from the following Chemical Formulas 3-1 to 3-4: 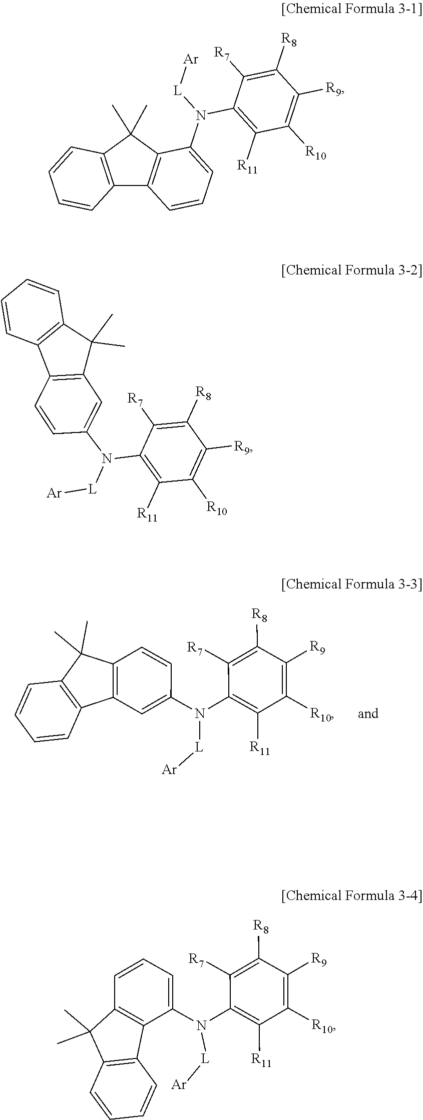
where R₇ to R₁₁, L, and Ar are the same as defined in the Chemical Formula 3.

10. The organic light-emitting device of claim 9, wherein the Chemical Formula 3 is represented by one selected from the Chemical Formulas 3-2 and 3-4.

11. The organic light-emitting device of claim 8, wherein a structure of the first compound represented by one of the Chemical Formulas 1 and 2 is selected from a group consisting of the following Compounds PD-1 to PD-450:

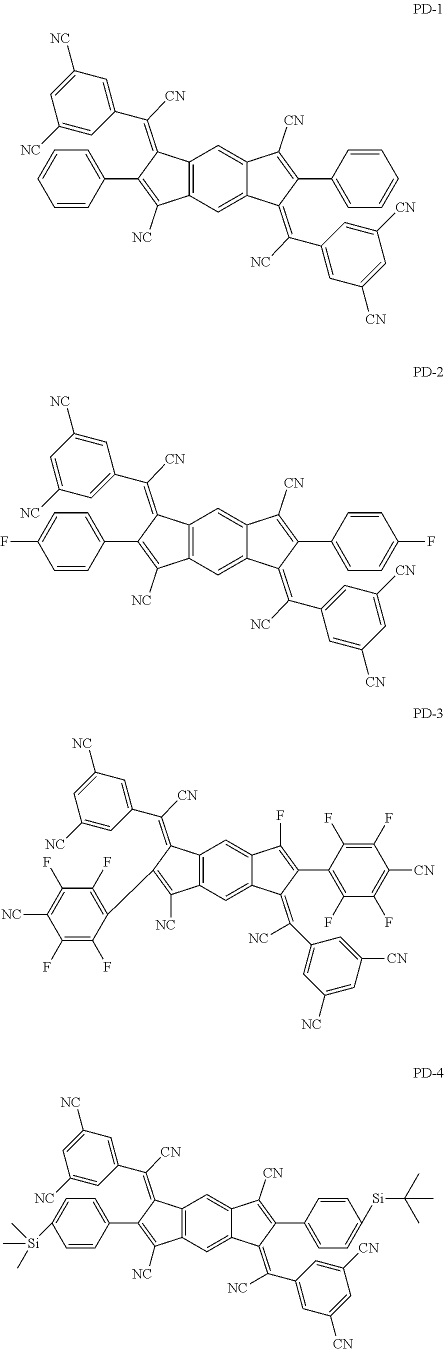

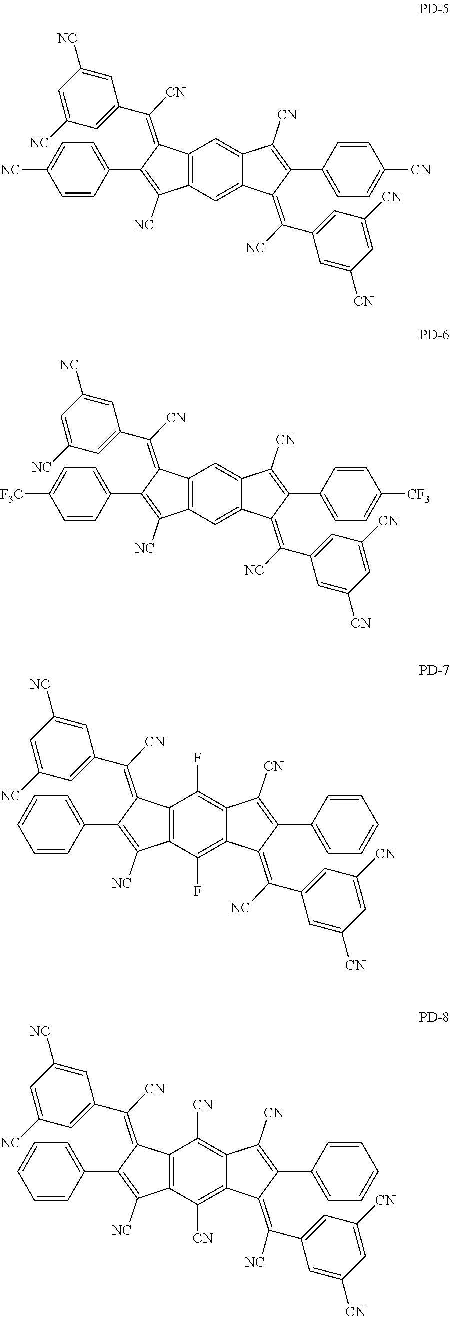 [SMILES: N#CC1=C(c2ccc(C#N)cc2)/C(=C(/C#N)c2cc(C#N)cc(C#N)c2)c2cc3c(cc21)/C(=C(\C#N)c1cc(C#N)cc(C#N)c1)C(c1ccc(C#N)cc1)=C3C#N ; N#CC1=C(c2ccc(C(F)(F)F)cc2)/C(=C(/C#N)c2cc(C#N)cc(C#N)c2)c2cc3c(cc21)/C(=C(\C#N)c1cc(C#N)cc(C#N)c1)C(c1ccc(C(F)(F)F)cc1)=C3C#N ; N#CC1=C(c2ccccc2)/C(=C(/C#N)c2cc(C#N)cc(C#N)c2)c2c(F)c3c(c(F)c21)/C(=C(\C#N)c1cc(C#N)cc(C#N)c1)C(c1ccccc1)=C3C#N ; N#CC1=C(c2ccccc2)/C(=C(/C#N)c2cc(C#N)cc(C#N)c2)c2c(C#N)c3c(c(C#N)c21)/C(=C(\C#N)c1cc(C#N)cc(C#N)c1)C(c1ccccc1)=C3C#N]

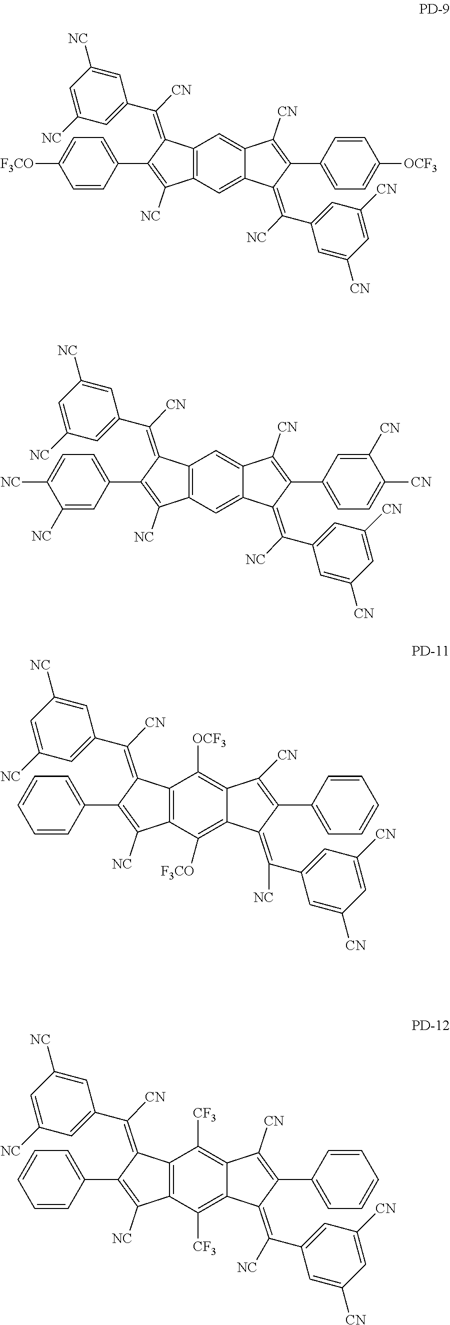

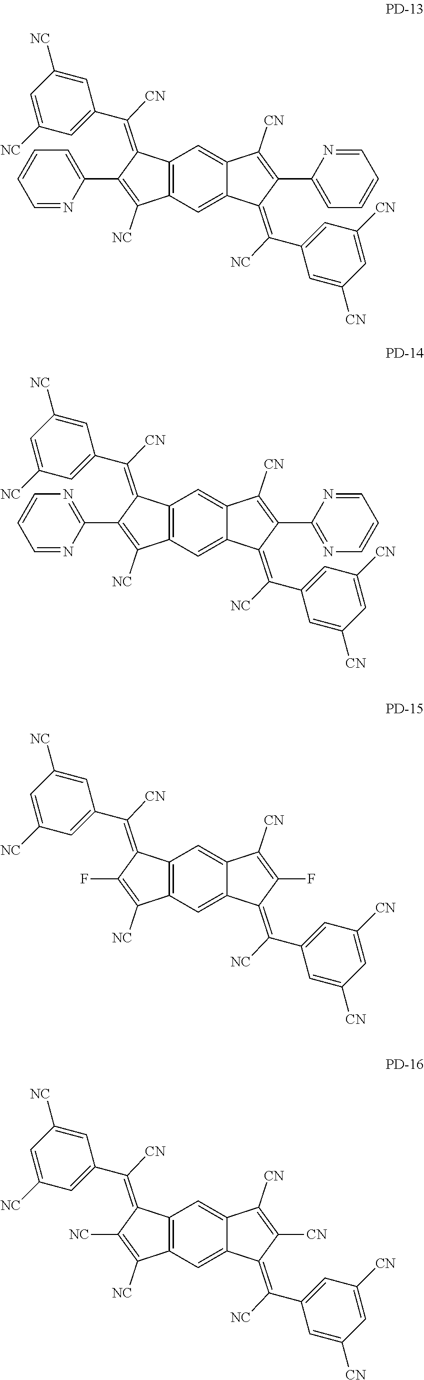 [SMILES: N#CC1=C(c2ccccn2)/C(=C(/C#N)c2cc(C#N)cc(C#N)c2)c2cc3c(cc21)/C(=C(\C#N)c1cc(C#N)cc(C#N)c1)C(c1ccccn1)=C3C#N ; N#CC1=C(c2ncccn2)/C(=C(/C#N)c2cc(C#N)cc(C#N)c2)c2cc3c(cc21)/C(=C(\C#N)c1cc(C#N)cc(C#N)c1)C(c1ncccn1)=C3C#N ; N#CC1=C(F)/C(=C(/C#N)c2cc(C#N)cc(C#N)c2)c2cc3c(cc21)/C(=C(\C#N)c1cc(C#N)cc(C#N)c1)C(F)=C3C#N ; N#CC1=C(C#N)c2cc3c(cc2/C1=C(\C#N)c1cc(C#N)cc(C#N)c1)C(C#N)=C(C#N)/C3=C(/C#N)c1cc(C#N)cc(C#N)c1]

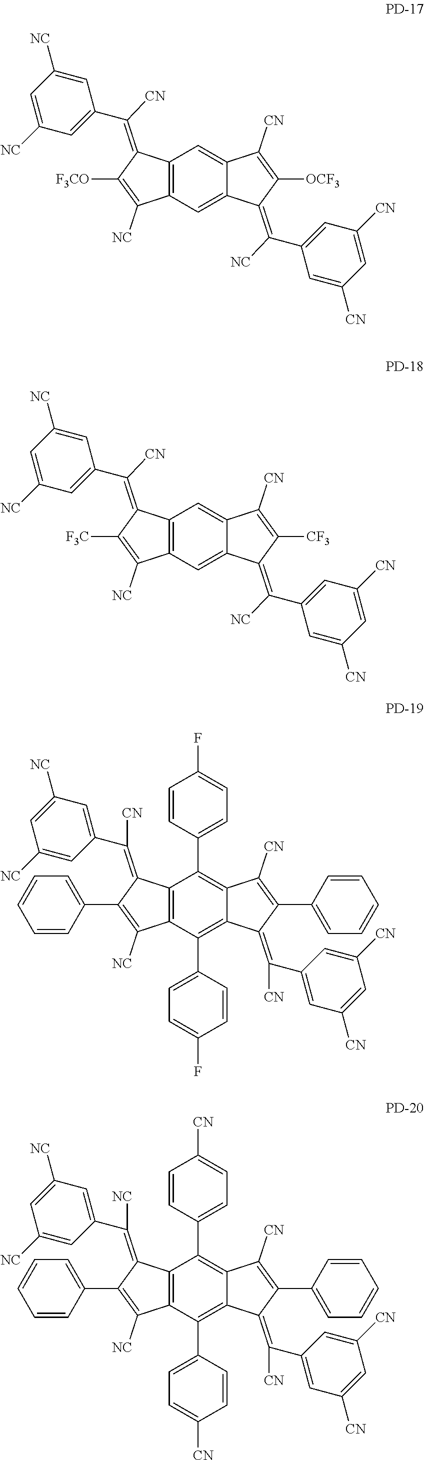 [SMILES: N#CC1=C(OC(F)(F)F)/C(=C(/C#N)c2cc(C#N)cc(C#N)c2)c2cc3c(cc21)/C(=C(\C#N)c1cc(C#N)cc(C#N)c1)C(OC(F)(F)F)=C3C#N ; N#CC1=C(C(F)(F)F)/C(=C(/C#N)c2cc(C#N)cc(C#N)c2)c2cc3c(cc21)/C(=C(\C#N)c1cc(C#N)cc(C#N)c1)C(C(F)(F)F)=C3C#N ; N#CC1=C(c2ccccc2)/C(=C(/C#N)c2cc(C#N)cc(C#N)c2)c2c1c(-c1ccc(F)cc1)c1c(c2-c2ccc(F)cc2)C(C#N)=C(c2ccccc2)/C1=C(/C#N)c1cc(C#N)cc(C#N)c1 ; N#CC1=C(c2ccccc2)/C(=C(/C#N)c2cc(C#N)cc(C#N)c2)c2c1c(-c1ccc(C#N)cc1)c1c(c2-c2ccc(C#N)cc2)C(C#N)=C(c2ccccc2)/C1=C(/C#N)c1cc(C#N)cc(C#N)c1]

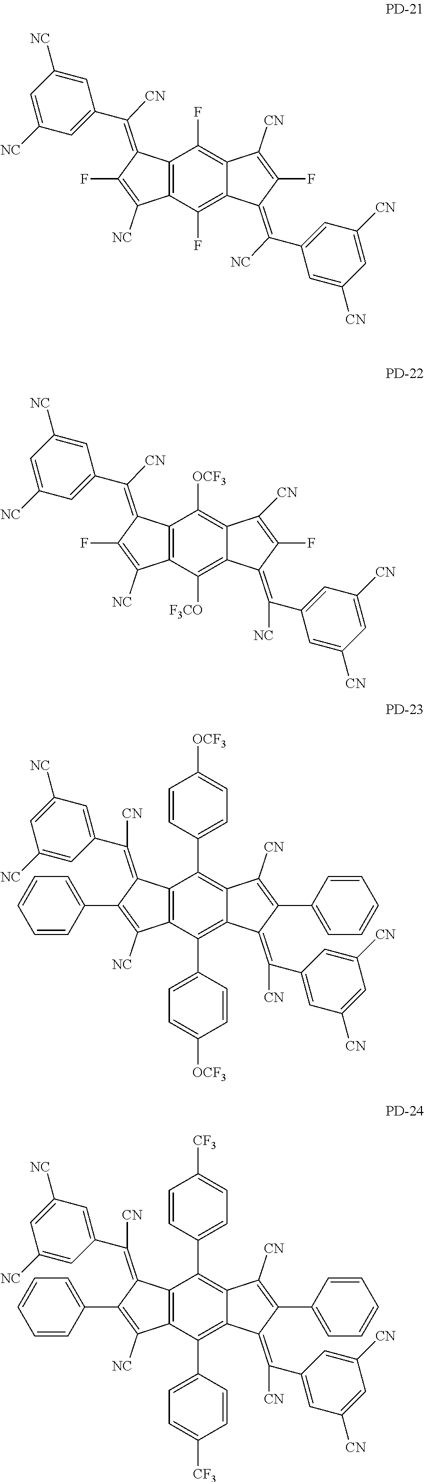

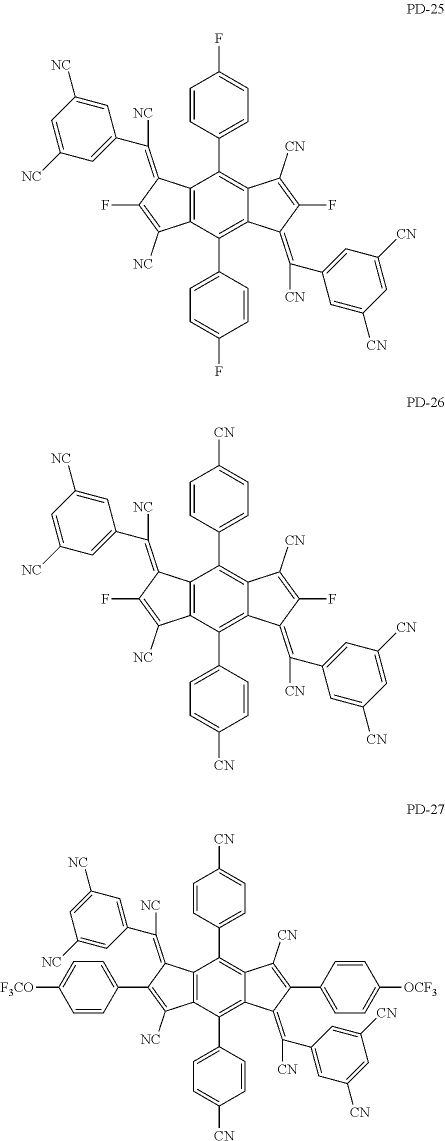 [SMILES: N#CC1=C(F)/C(=C(/C#N)c2cc(C#N)cc(C#N)c2)c2c1c(-c1ccc(F)cc1)c1c(c2-c2ccc(F)cc2)C(C#N)=C(F)/C1=C(/C#N)c1cc(C#N)cc(C#N)c1 ; N#CC1=C(F)/C(=C(/C#N)c2cc(C#N)cc(C#N)c2)c2c1c(-c1ccc(C#N)cc1)c1c(c2-c2ccc(C#N)cc2)C(C#N)=C(F)/C1=C(/C#N)c1cc(C#N)cc(C#N)c1 ; N#CC1=C(c2ccc(OC(F)(F)F)cc2)/C(=C(/C#N)c2cc(C#N)cc(C#N)c2)c2c1c(-c1ccc(C#N)cc1)c1c(c2-c2ccc(C#N)cc2)C(C#N)=C(c2ccc(OC(F)(F)F)cc2)/C1=C(/C#N)c1cc(C#N)cc(C#N)c1]

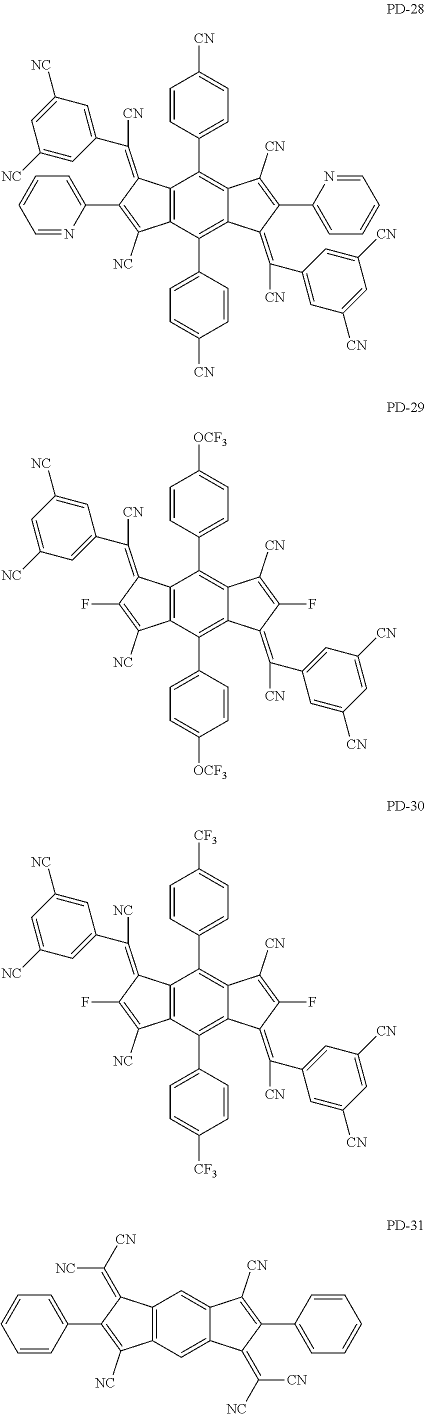 [SMILES: N#CC1=C(c2ccccn2)/C(=C(/C#N)c2cc(C#N)cc(C#N)c2)c2c1c(-c1ccc(C#N)cc1)c1c(c2-c2ccc(C#N)cc2)C(C#N)=C(c2ccccn2)/C1=C(/C#N)c1cc(C#N)cc(C#N)c1 ; N#CC1=C(F)/C(=C(/C#N)c2cc(C#N)cc(C#N)c2)c2c1c(-c1ccc(OC(F)(F)F)cc1)c1c(c2-c2ccc(OC(F)(F)F)cc2)C(C#N)=C(F)/C1=C(/C#N)c1cc(C#N)cc(C#N)c1 ; N#CC1=C(F)/C(=C(/C#N)c2cc(C#N)cc(C#N)c2)c2c1c(-c1ccc(C(F)(F)F)cc1)c1c(c2-c2ccc(C(F)(F)F)cc2)C(C#N)=C(F)/C1=C(/C#N)c1cc(C#N)cc(C#N)c1 ; N#CC(C#N)=C1C(c2ccccc2)=C(C#N)c2cc3c(cc21)C(C#N)=C(c1ccccc1)C3=C(C#N)C#N]

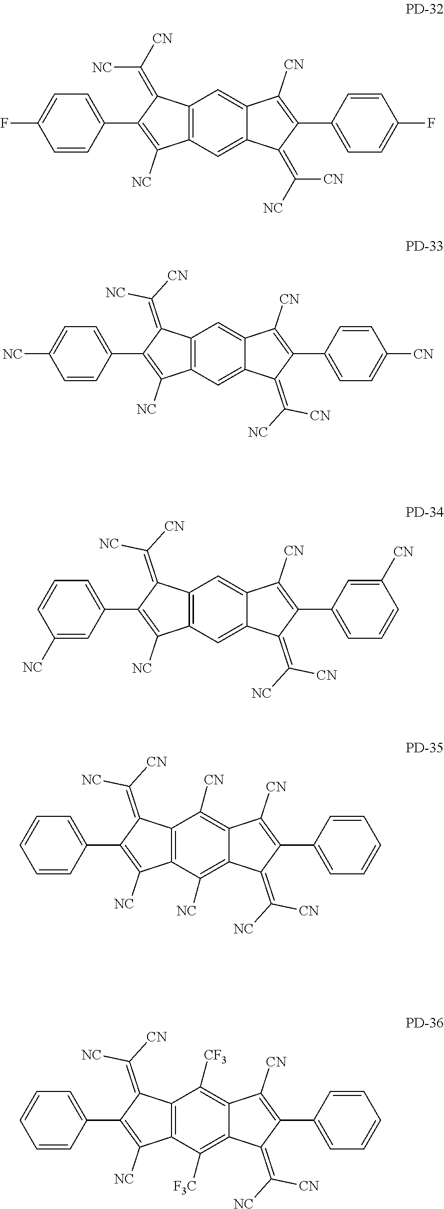 [SMILES: N#CC(C#N)=C1C(c2ccc(F)cc2)=C(C#N)c2cc3c(cc21)C(C#N)=C(c1ccc(F)cc1)C3=C(C#N)C#N ; N#CC(C#N)=C1C(c2ccc(C#N)cc2)=C(C#N)c2cc3c(cc21)C(C#N)=C(c1ccc(C#N)cc1)C3=C(C#N)C#N ; N#CC(C#N)=C1C(c2cccc(C#N)c2)=C(C#N)c2cc3c(cc21)C(C#N)=C(c1cccc(C#N)c1)C3=C(C#N)C#N ; N#CC(C#N)=C1C(c2ccccc2)=C(C#N)c2c(C#N)c3c(c(C#N)c21)C(C#N)=C(c1ccccc1)C3=C(C#N)C#N ; N#CC(C#N)=C1C(c2ccccc2)=C(C#N)c2c1c(C(F)(F)F)c1c(c2C(F)(F)F)C(=C(C#N)C#N)C(c2ccccc2)=C1C#N]

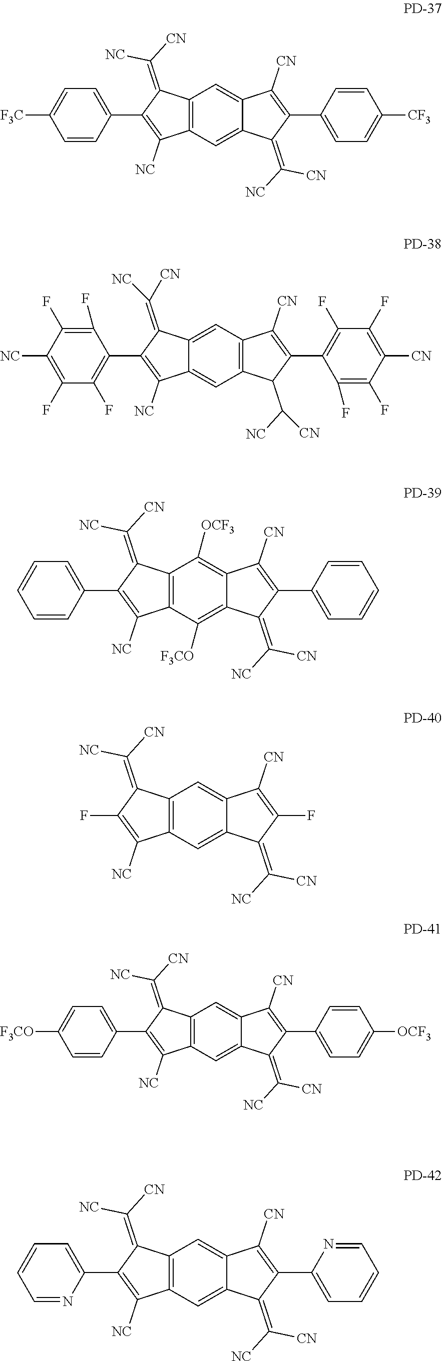

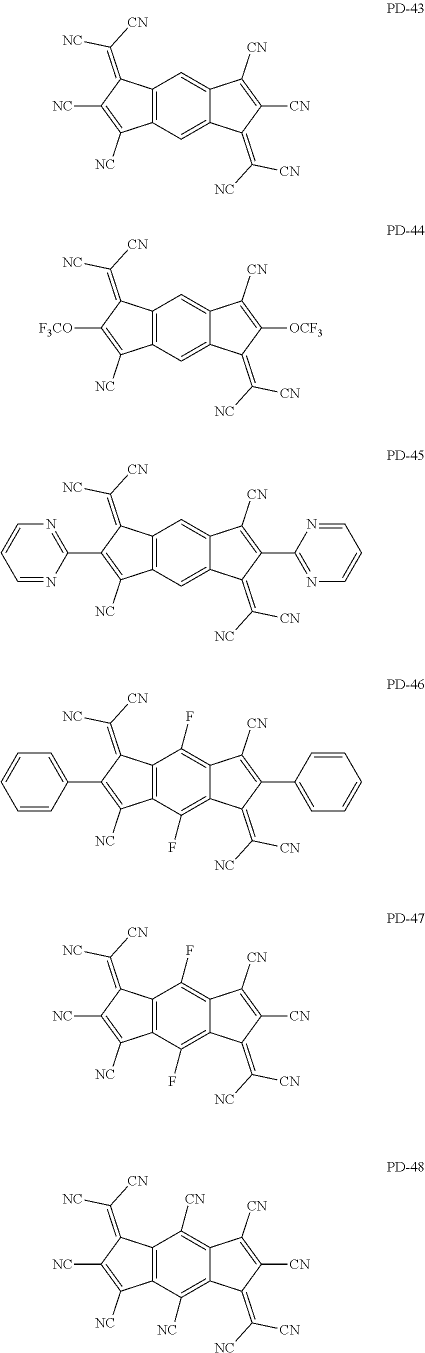 [SMILES: N#CC(C#N)=C1C(C#N)=C(C#N)c2cc3c(cc21)C(C#N)=C(C#N)C3=C(C#N)C#N ; N#CC(C#N)=C1C(OC(F)(F)F)=C(C#N)c2cc3c(cc21)C(C#N)=C(OC(F)(F)F)C3=C(C#N)C#N ; N#CC(C#N)=C1C(c2ncccn2)=C(C#N)c2cc3c(cc21)C(C#N)=C(c1ncccn1)C3=C(C#N)C#N ; N#CC(C#N)=C1C(c2ccccc2)=C(C#N)c2c(F)c3c(c(F)c21)C(C#N)=C(c1ccccc1)C3=C(C#N)C#N ; N#CC(C#N)=C1C(C#N)=C(C#N)c2c(F)c3c(c(F)c21)C(C#N)=C(C#N)C3=C(C#N)C#N ; N#CC(C#N)=C1C(C#N)=C(C#N)c2c(C#N)c3c(c(C#N)c21)C(C#N)=C(C#N)C3=C(C#N)C#N]

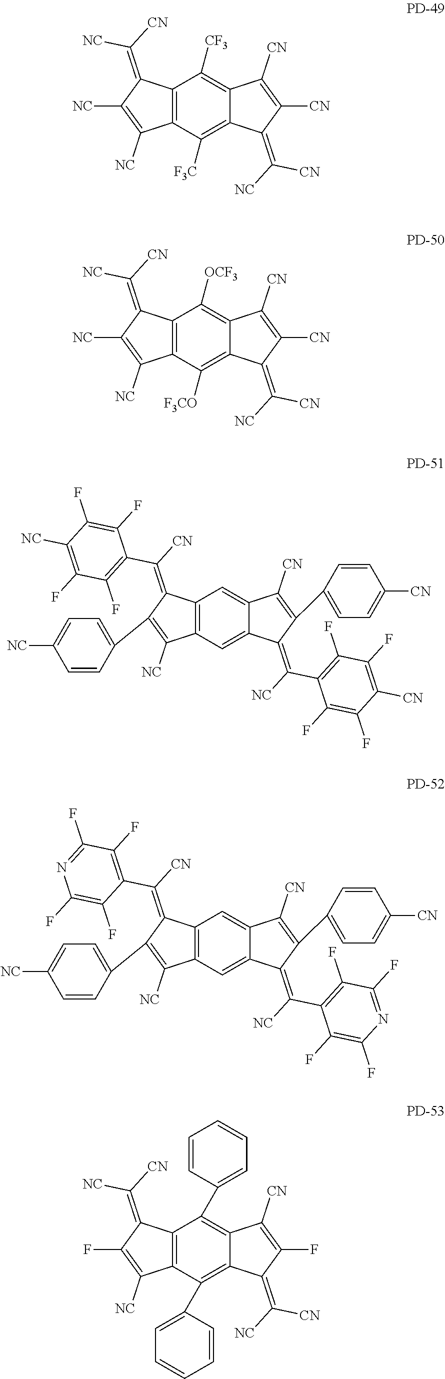 [SMILES: N#CC(C#N)=C1C(C#N)=C(C#N)c2c1c(C(F)(F)F)c1c(c2C(F)(F)F)C(=C(C#N)C#N)C(C#N)=C1C#N ; N#CC(C#N)=C1C(C#N)=C(C#N)c2c(OC(F)(F)F)c3c(c(OC(F)(F)F)c21)C(C#N)=C(C#N)C3=C(C#N)C#N ; N#CC1=C(c2ccc(C#N)cc2)/C(=C(/C#N)c2c(F)c(F)c(C#N)c(F)c2F)c2cc3c(cc21)/C(=C(\C#N)c1c(F)c(F)c(C#N)c(F)c1F)C(c1ccc(C#N)cc1)=C3C#N ; N#CC1=C(c2ccc(C#N)cc2)/C(=C(/C#N)c2c(F)c(F)nc(F)c2F)c2cc3c(cc21)/C(=C(\C#N)c1c(F)c(F)nc(F)c1F)C(c1ccc(C#N)cc1)=C3C#N ; N#CC(C#N)=C1C(F)=C(C#N)c2c1c(-c1ccccc1)c1c(c2-c2ccccc2)C(=C(C#N)C#N)C(F)=C1C#N]

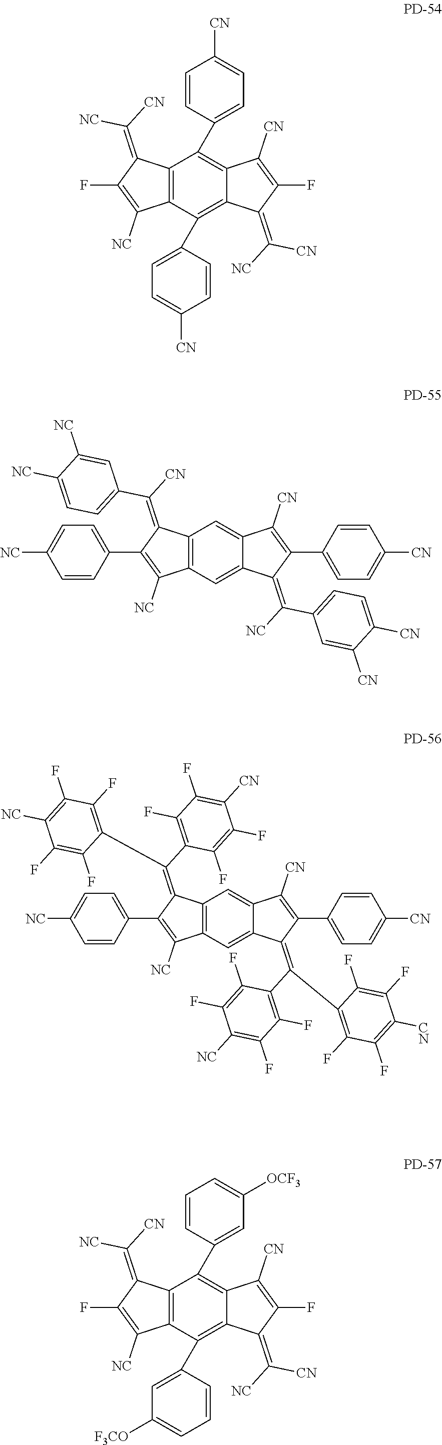 [SMILES: N#CC(C#N)=C1C(F)=C(C#N)c2c1c(-c1ccc(C#N)cc1)c1c(c2-c2ccc(C#N)cc2)C(=C(C#N)C#N)C(F)=C1C#N ; N#CC1=C(c2ccc(C#N)cc2)/C(=C(/C#N)c2ccc(C#N)c(C#N)c2)c2cc3c(cc21)/C(=C(\C#N)c1ccc(C#N)c(C#N)c1)C(c1ccc(C#N)cc1)=C3C#N ; N#CC1=C(c2ccc(C#N)cc2)C(=C(c2c(F)c(F)c(C#N)c(F)c2F)c2c(F)c(F)c(C#N)c(F)c2F)c2cc3c(cc21)C(=C(c1c(F)c(F)c(C#N)c(F)c1F)c1c(F)c(F)c(C#N)c(F)c1F)C(c1ccc(C#N)cc1)=C3C#N ; N#CC(C#N)=C1C(F)=C(C#N)c2c1c(-c1cccc(OC(F)(F)F)c1)c1c(c2-c2cccc(OC(F)(F)F)c2)C(=C(C#N)C#N)C(F)=C1C#N]

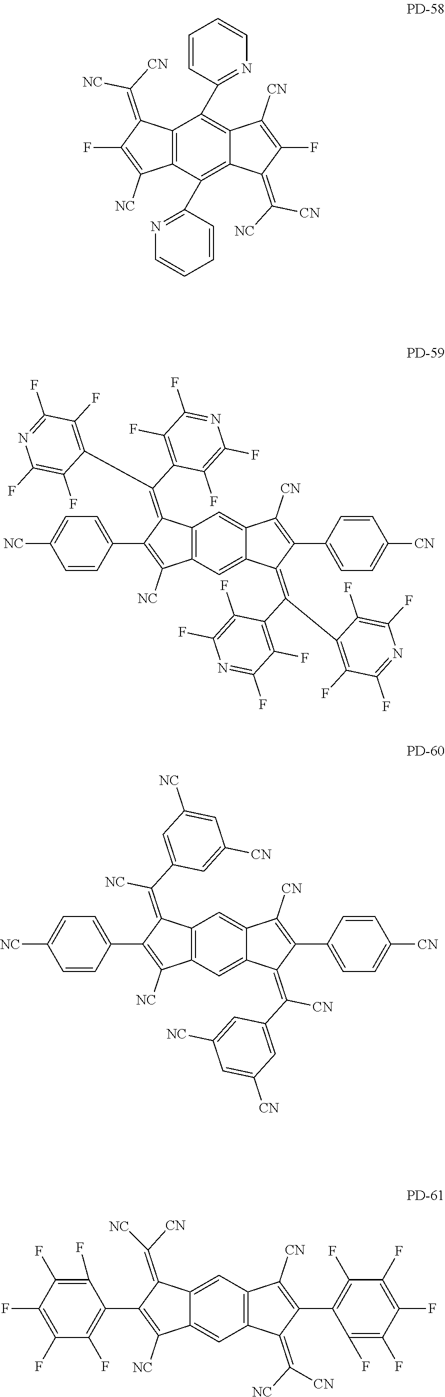 [SMILES: N#CC(C#N)=C1C(F)=C(C#N)c2c1c(-c1ccccn1)c1c(c2-c2ccccn2)C(=C(C#N)C#N)C(F)=C1C#N ; N#CC1=C(c2ccc(C#N)cc2)C(=C(c2c(F)c(F)nc(F)c2F)c2c(F)c(F)nc(F)c2F)c2cc3c(cc21)C(=C(c1c(F)c(F)nc(F)c1F)c1c(F)c(F)nc(F)c1F)C(c1ccc(C#N)cc1)=C3C#N ; N#CC1=C(c2ccc(C#N)cc2)/C(=C(\C#N)c2cc(C#N)cc(C#N)c2)c2cc3c(cc21)/C(=C(/C#N)c1cc(C#N)cc(C#N)c1)C(c1ccc(C#N)cc1)=C3C#N ; N#CC(C#N)=C1C(c2c(F)c(F)c(F)c(F)c2F)=C(C#N)c2cc3c(cc21)C(C#N)=C(c1c(F)c(F)c(F)c(F)c1F)C3=C(C#N)C#N]

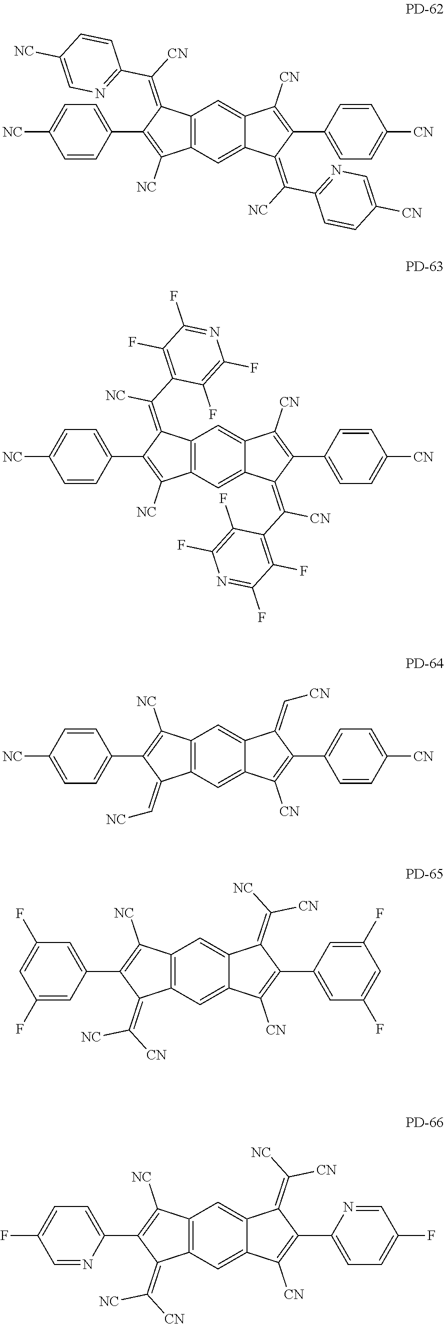 [SMILES: N#CC1=C(c2ccc(C#N)cc2)/C(=C(/C#N)c2ccc(C#N)cn2)c2cc3c(cc21)/C(=C(\C#N)c1ccc(C#N)cn1)C(c1ccc(C#N)cc1)=C3C#N ; N#CC1=C(c2ccc(C#N)cc2)/C(=C(\C#N)c2c(F)c(F)nc(F)c2F)c2cc3c(cc21)/C(=C(/C#N)c1c(F)c(F)nc(F)c1F)C(c1ccc(C#N)cc1)=C3C#N ; N#C/C=C1\C(c2ccc(C#N)cc2)=C(C#N)c2cc3c(cc21)C(C#N)=C(c1ccc(C#N)cc1)/C3=C\C#N ; N#CC(C#N)=C1C(c2cc(F)cc(F)c2)=C(C#N)c2cc3c(cc21)C(C#N)=C(c1cc(F)cc(F)c1)C3=C(C#N)C#N ; N#CC(C#N)=C1C(c2ccc(F)cn2)=C(C#N)c2cc3c(cc21)C(C#N)=C(c1ccc(F)cn1)C3=C(C#N)C#N]

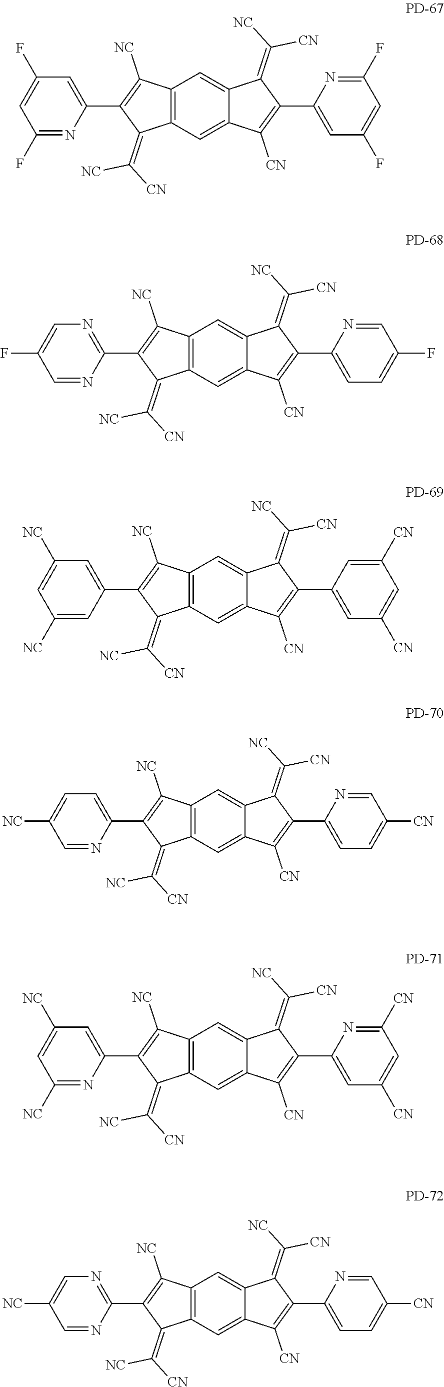

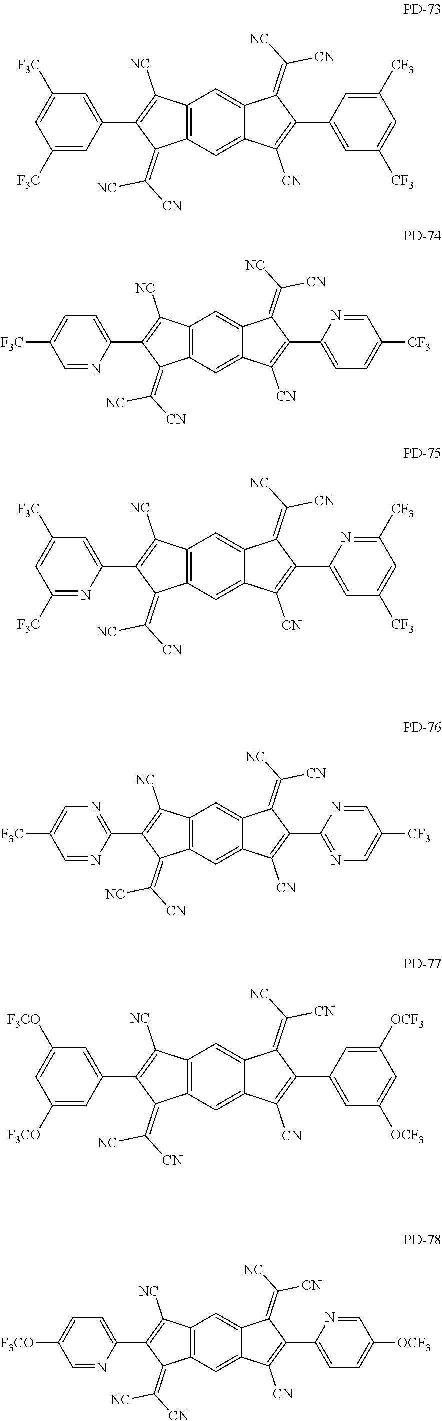

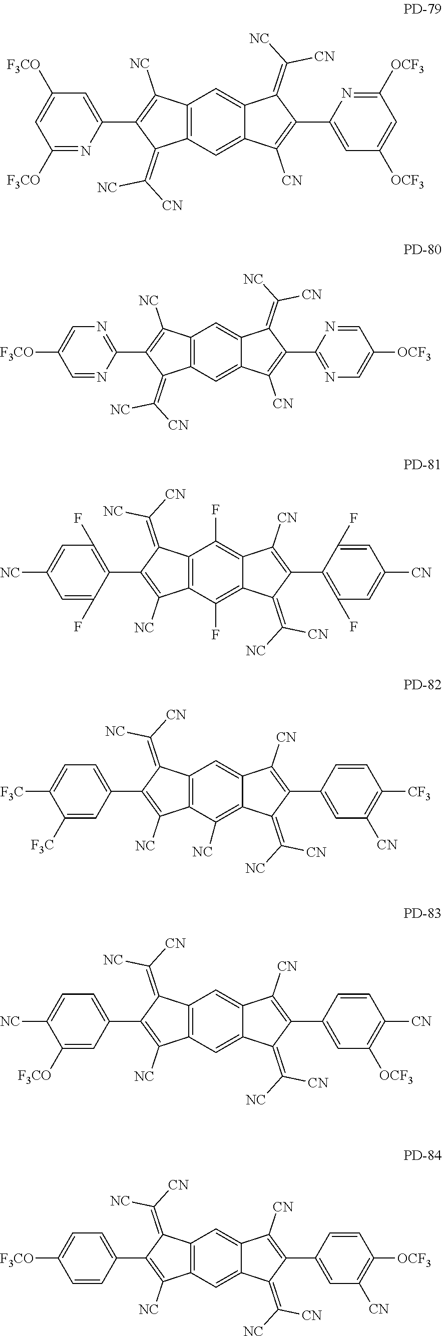

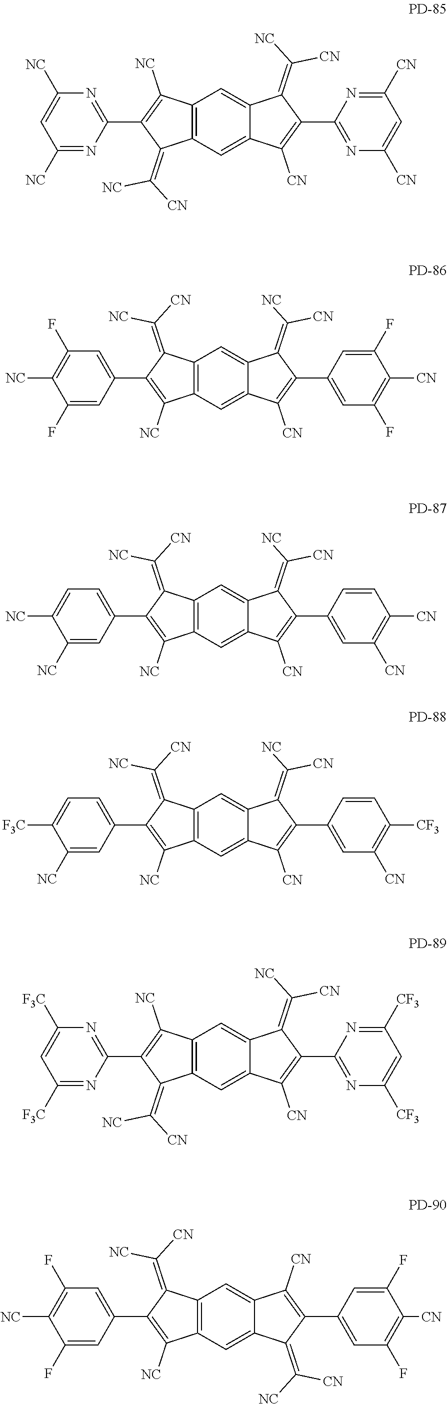

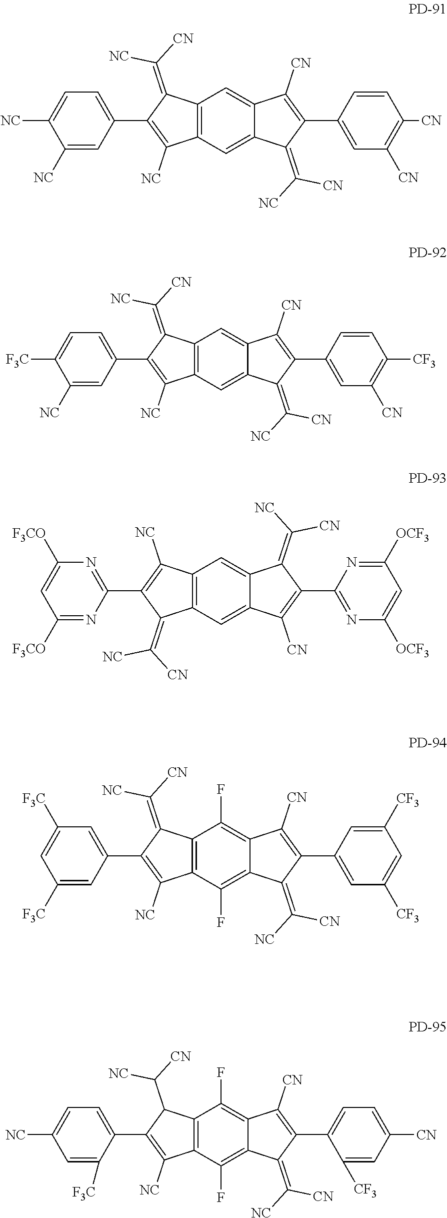

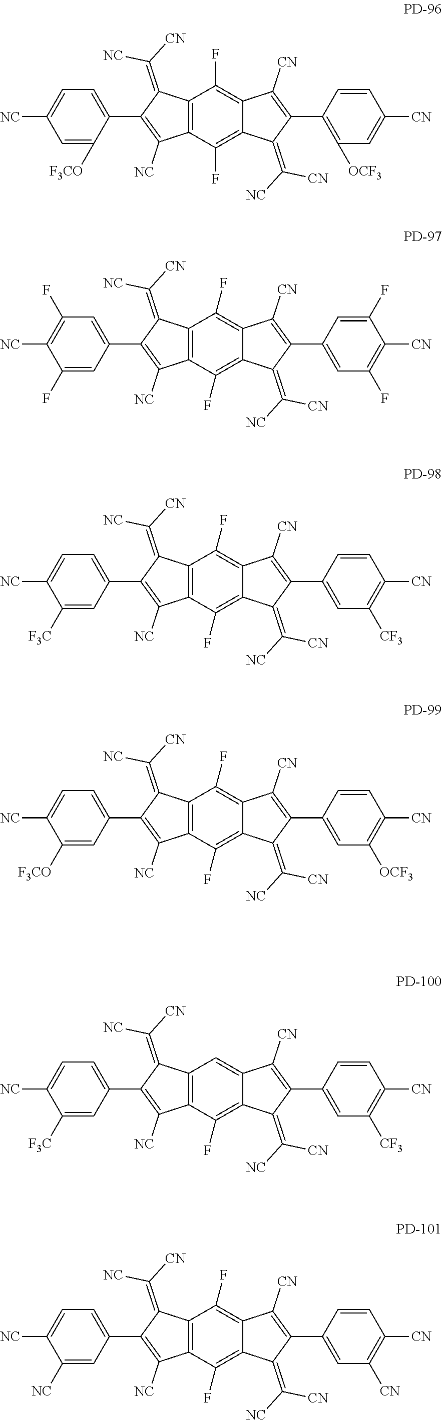

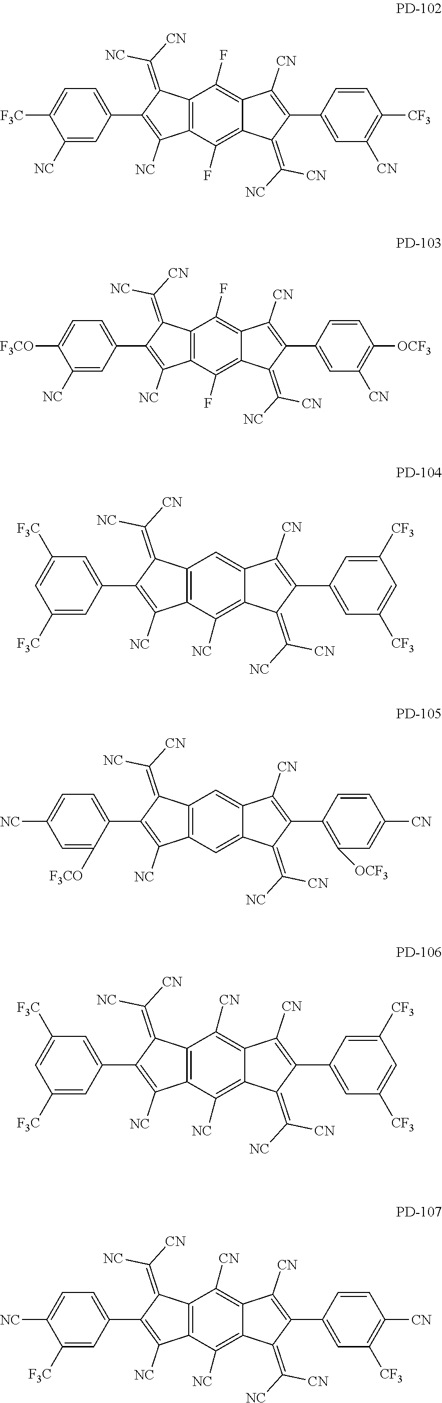

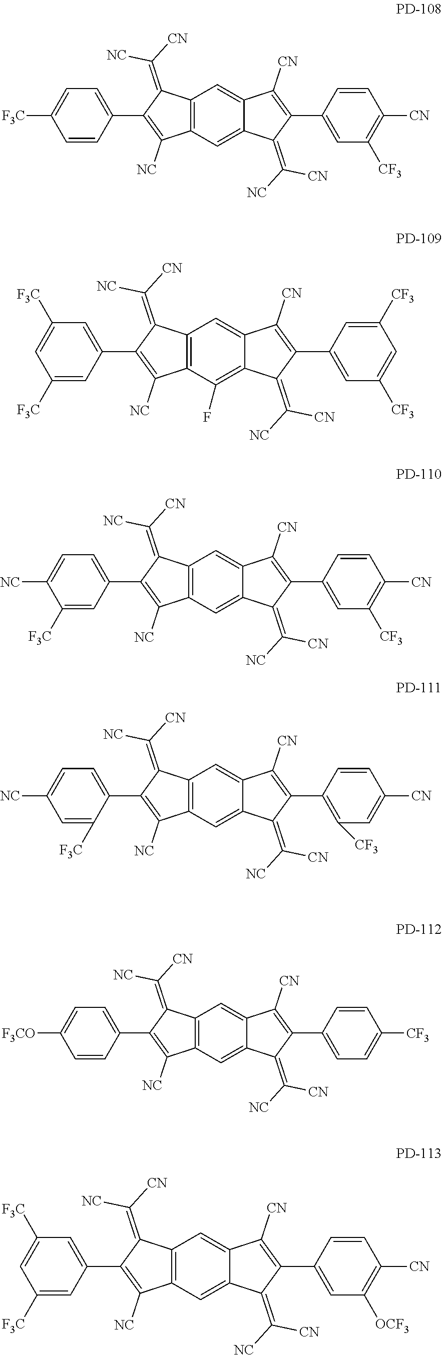

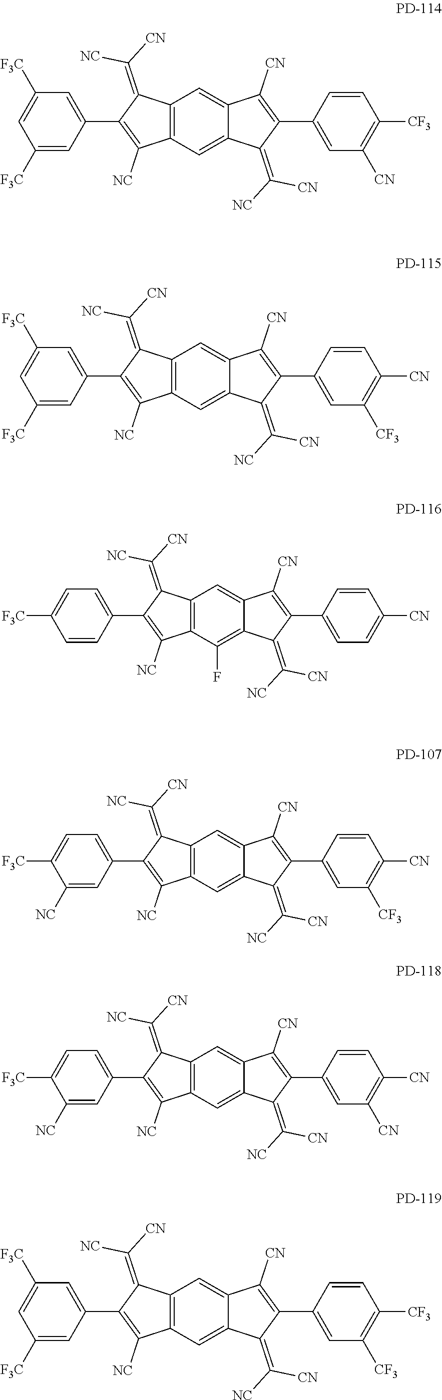

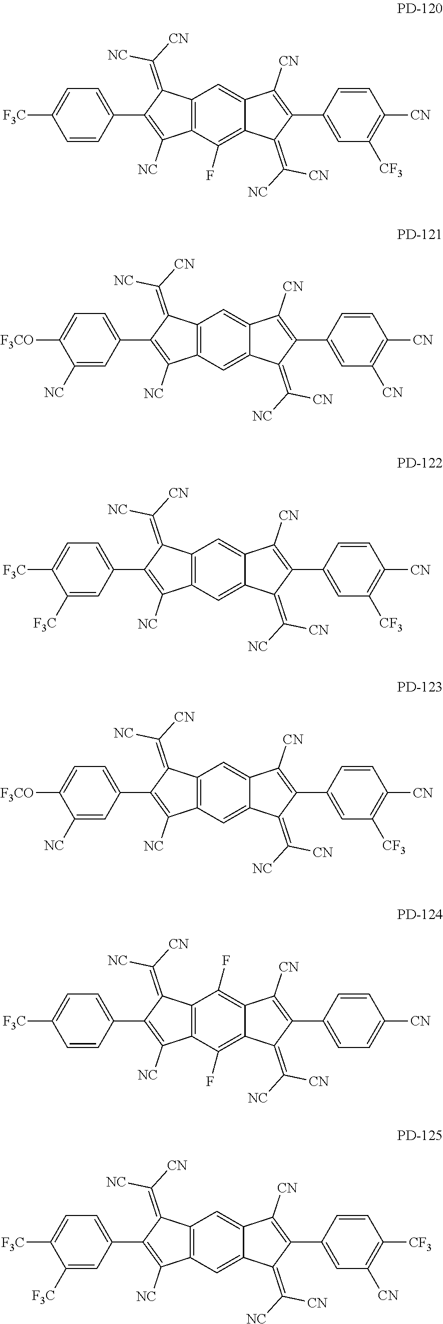

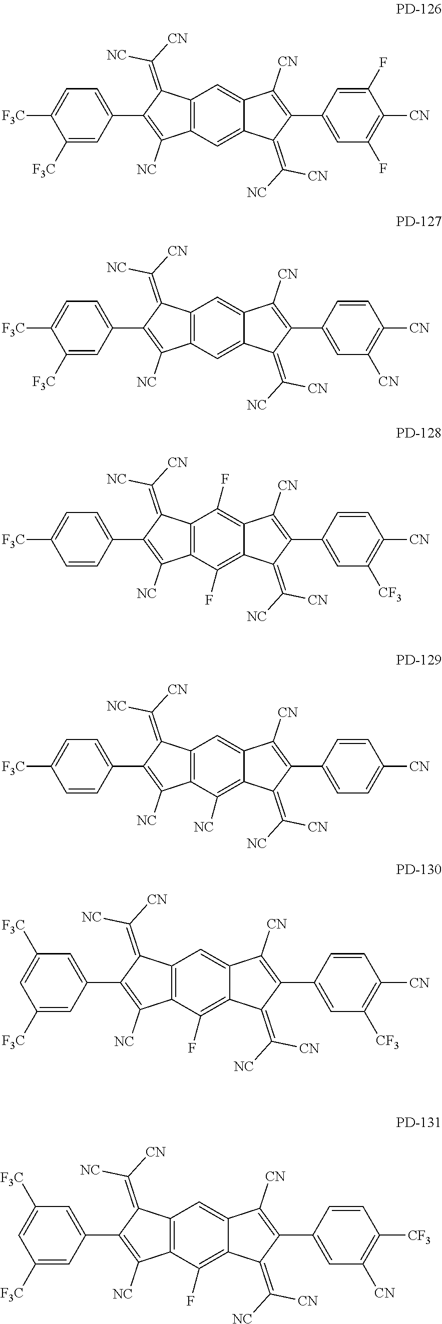

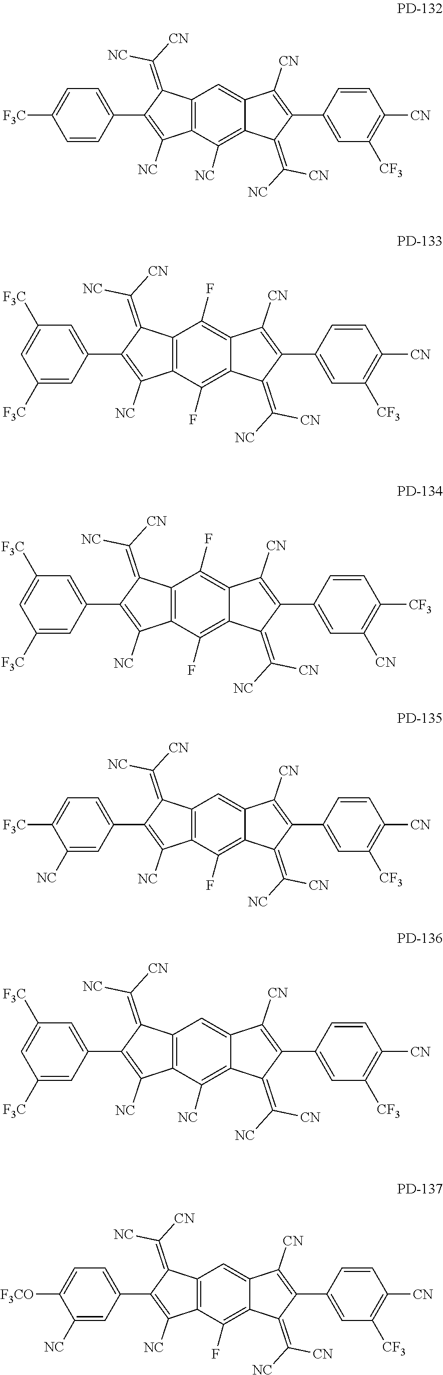

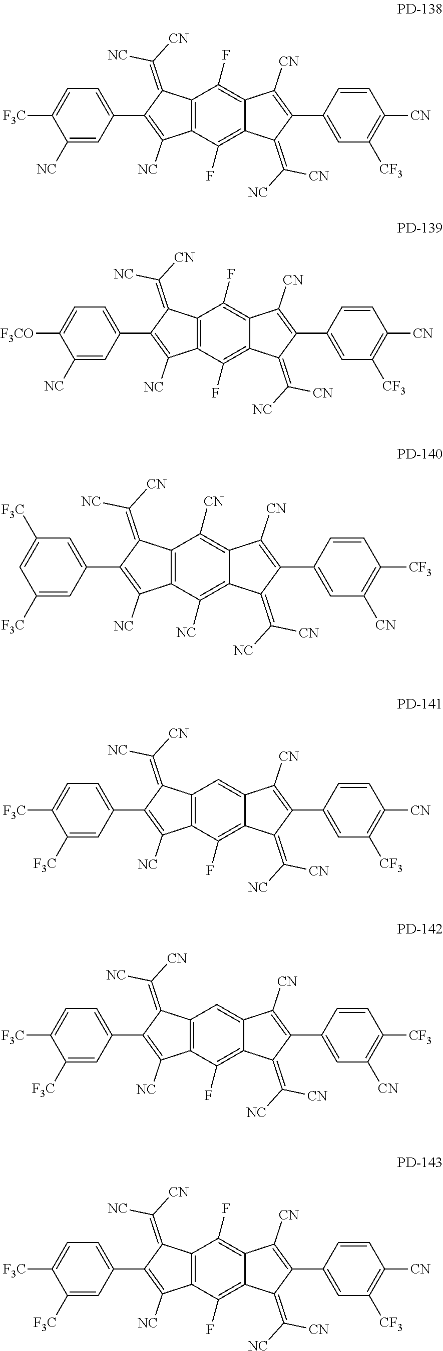

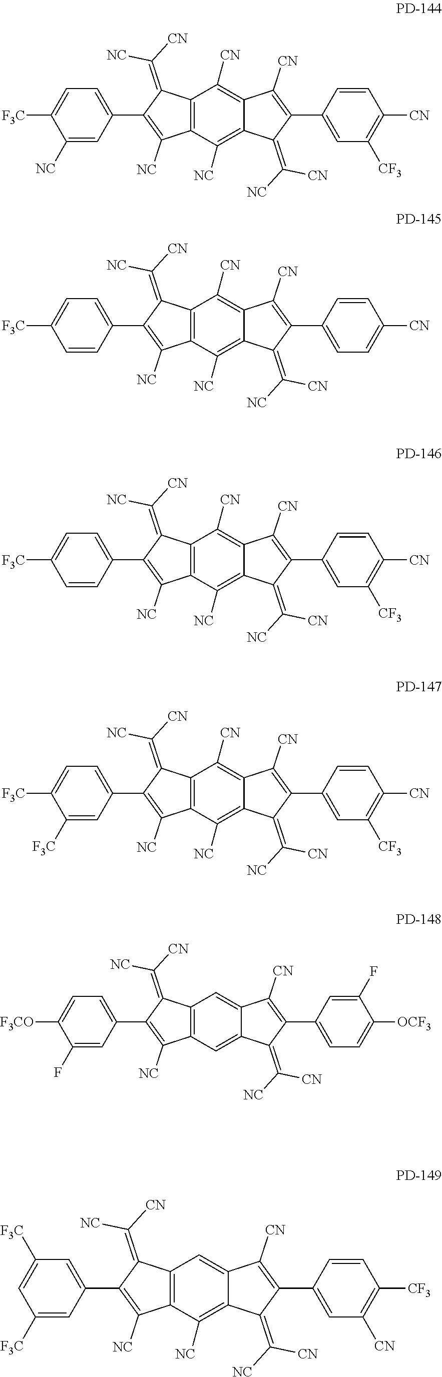

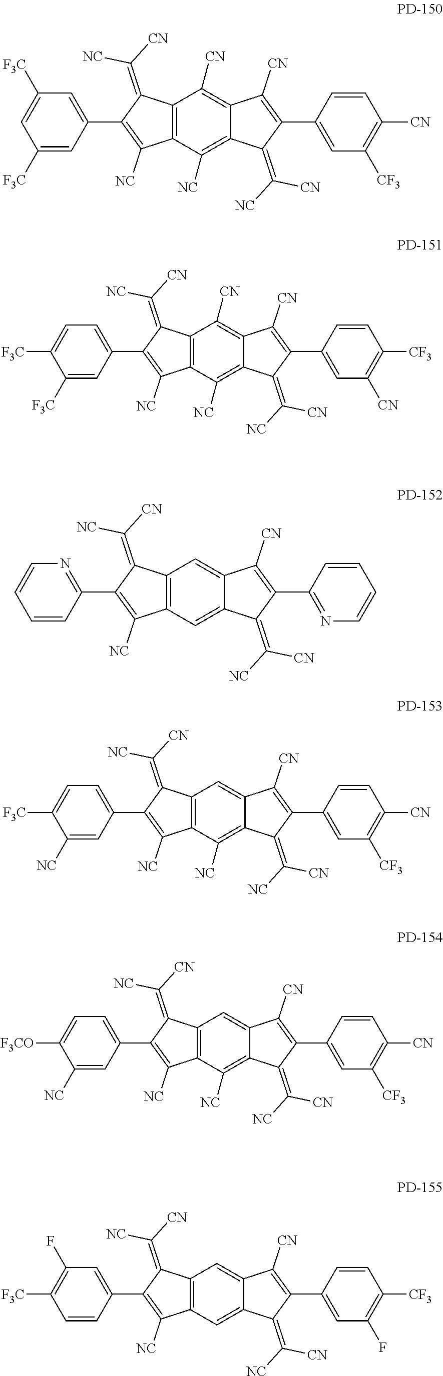

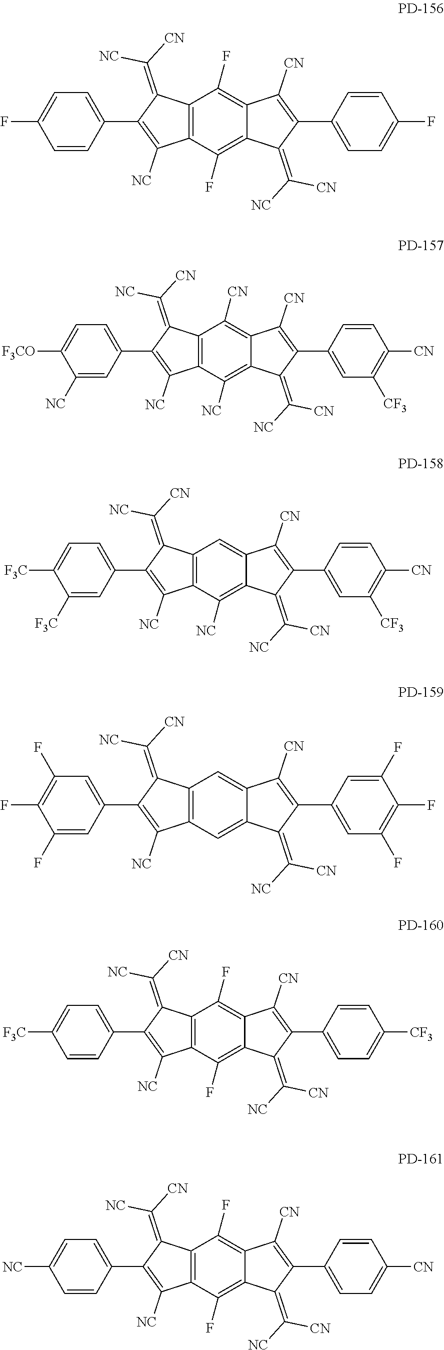

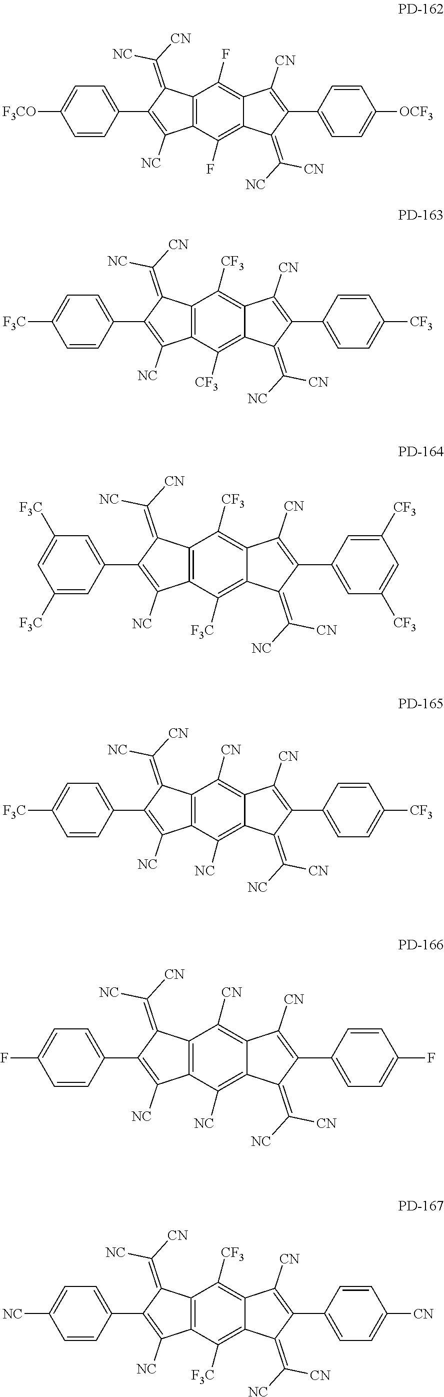

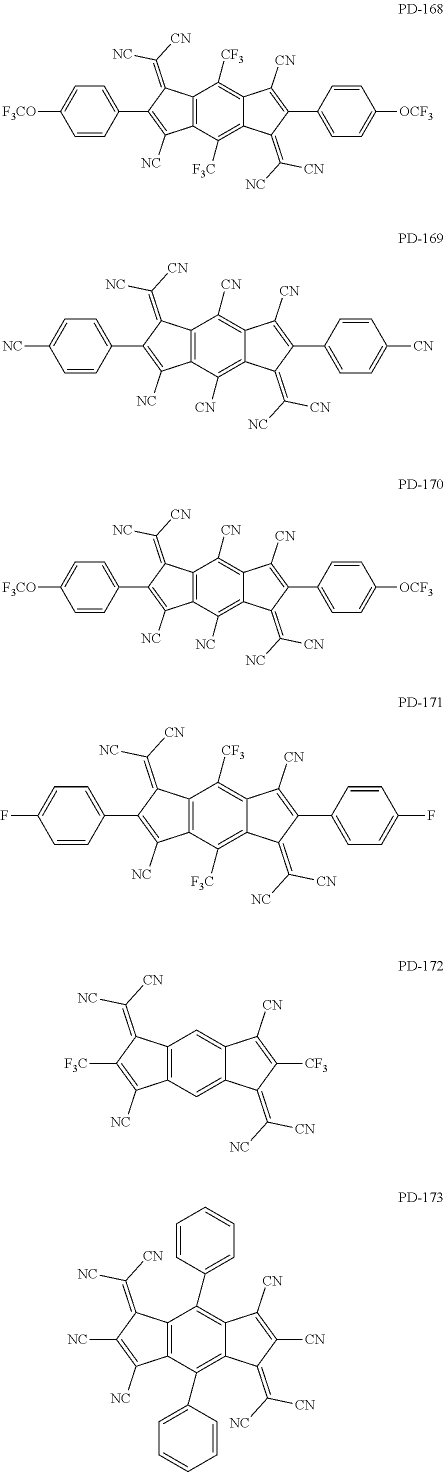

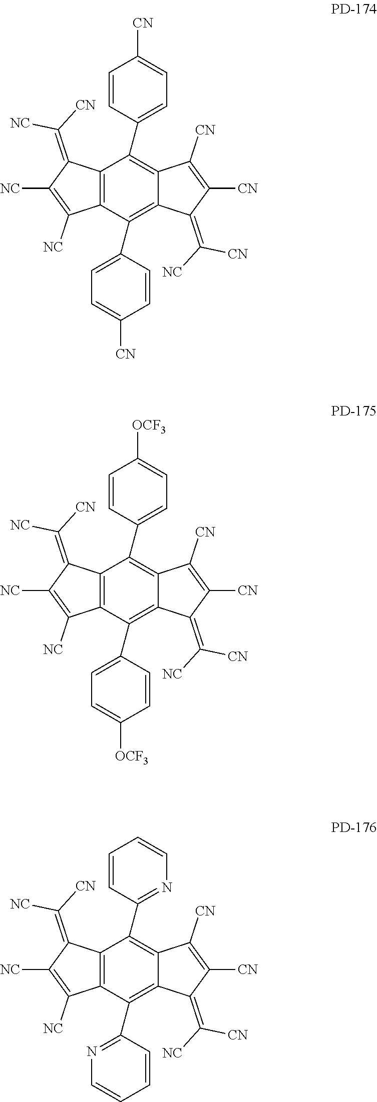 [SMILES: N#CC(C#N)=C1C(C#N)=C(C#N)c2c1c(-c1ccc(C#N)cc1)c1c(c2-c2ccc(C#N)cc2)C(=C(C#N)C#N)C(C#N)=C1C#N ; N#CC(C#N)=C1C(C#N)=C(C#N)c2c1c(-c1ccc(OC(F)(F)F)cc1)c1c(c2-c2ccc(OC(F)(F)F)cc2)C(=C(C#N)C#N)C(C#N)=C1C#N ; N#CC(C#N)=C1C(C#N)=C(C#N)c2c1c(-c1ccccn1)c1c(c2-c2ccccn2)C(=C(C#N)C#N)C(C#N)=C1C#N]

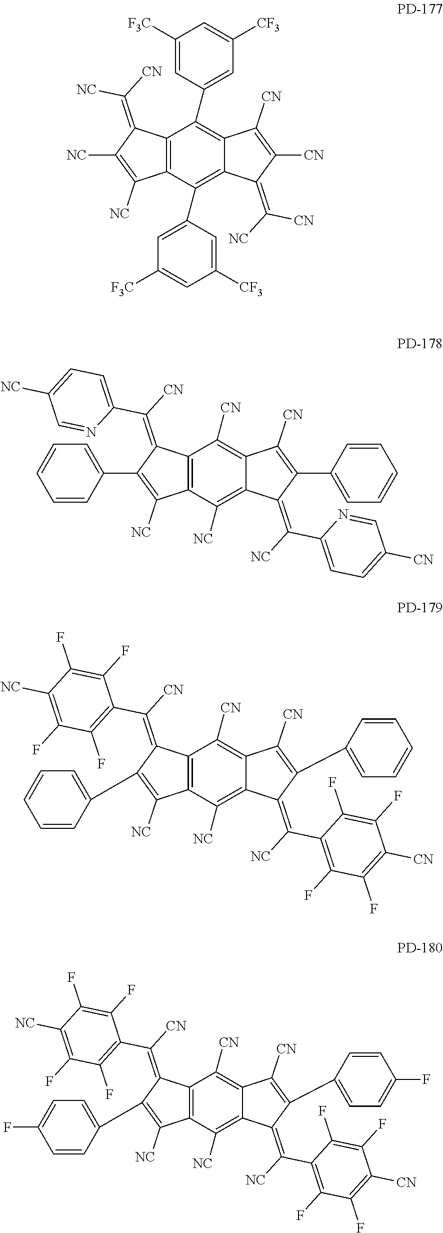 [SMILES: N#CC(C#N)=C1C(C#N)=C(C#N)c2c1c(-c1cc(C(F)(F)F)cc(C(F)(F)F)c1)c1c(c2-c2cc(C(F)(F)F)cc(C(F)(F)F)c2)C(=C(C#N)C#N)C(C#N)=C1C#N ; N#CC1=C(c2ccccc2)/C(=C(/C#N)c2ccc(C#N)cn2)c2c(C#N)c3c(c(C#N)c21)/C(=C(\C#N)c1ccc(C#N)cn1)C(c1ccccc1)=C3C#N ; N#CC1=C(c2ccccc2)/C(=C(/C#N)c2c(F)c(F)c(C#N)c(F)c2F)c2c(C#N)c3c(c(C#N)c21)/C(=C(\C#N)c1c(F)c(F)c(C#N)c(F)c1F)C(c1ccccc1)=C3C#N ; N#CC1=C(c2ccc(F)cc2)/C(=C(/C#N)c2c(F)c(F)c(C#N)c(F)c2F)c2c(C#N)c3c(c(C#N)c21)/C(=C(\C#N)c1c(F)c(F)c(C#N)c(F)c1F)C(c1ccc(F)cc1)=C3C#N]

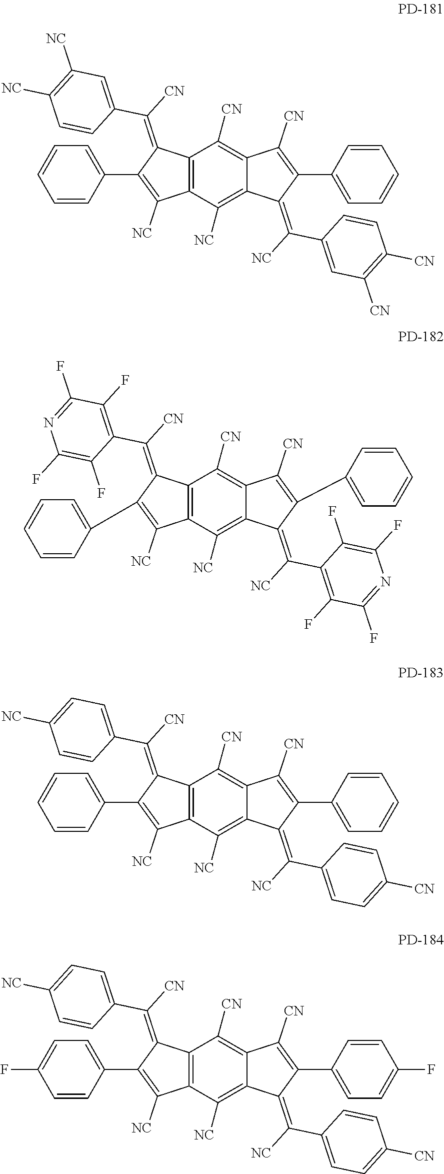 [SMILES: N#CC1=C(c2ccccc2)/C(=C(/C#N)c2ccc(C#N)c(C#N)c2)c2c(C#N)c3c(c(C#N)c21)/C(=C(\C#N)c1ccc(C#N)c(C#N)c1)C(c1ccccc1)=C3C#N ; N#CC1=C(c2ccccc2)/C(=C(/C#N)c2c(F)c(F)nc(F)c2F)c2c(C#N)c3c(c(C#N)c21)/C(=C(\C#N)c1c(F)c(F)nc(F)c1F)C(c1ccccc1)=C3C#N ; N#CC1=C(c2ccccc2)/C(=C(/C#N)c2ccc(C#N)cc2)c2c(C#N)c3c(c(C#N)c21)/C(=C(\C#N)c1ccc(C#N)cc1)C(c1ccccc1)=C3C#N ; N#CC1=C(c2ccc(F)cc2)/C(=C(/C#N)c2ccc(C#N)cc2)c2c(C#N)c3c(c(C#N)c21)/C(=C(\C#N)c1ccc(C#N)cc1)C(c1ccc(F)cc1)=C3C#N]

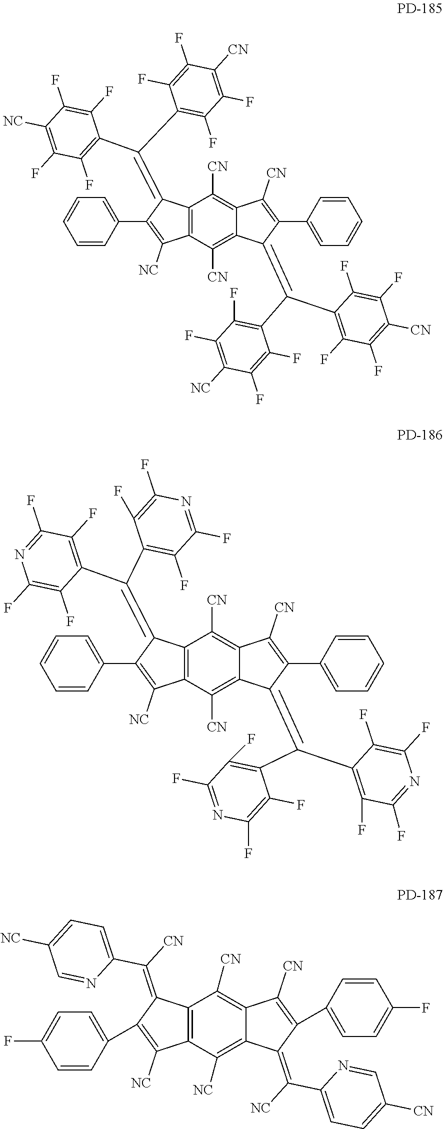 [SMILES: N#CC1=C(c2ccccc2)C(=C(c2c(F)c(F)c(C#N)c(F)c2F)c2c(F)c(F)c(C#N)c(F)c2F)c2c(C#N)c3c(c(C#N)c21)C(=C(c1c(F)c(F)c(C#N)c(F)c1F)c1c(F)c(F)c(C#N)c(F)c1F)C(c1ccccc1)=C3C#N ; N#CC1=C(c2ccccc2)C(=C(c2c(F)c(F)nc(F)c2F)c2c(F)c(F)nc(F)c2F)c2c(C#N)c3c(c(C#N)c21)C(=C(c1c(F)c(F)nc(F)c1F)c1c(F)c(F)nc(F)c1F)C(c1ccccc1)=C3C#N ; N#CC1=C(c2ccc(F)cc2)/C(=C(/C#N)c2ccc(C#N)cn2)c2c(C#N)c3c(c(C#N)c21)/C(=C(\C#N)c1ccc(C#N)cn1)C(c1ccc(F)cc1)=C3C#N]

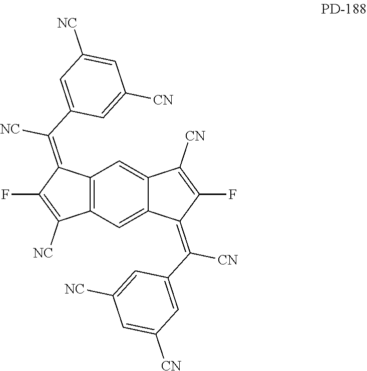 [SMILES: N#CC1=C(F)/C(=C(\C#N)c2cc(C#N)cc(C#N)c2)c2cc3c(cc21)/C(=C(/C#N)c1cc(C#N)cc(C#N)c1)C(F)=C3C#N]

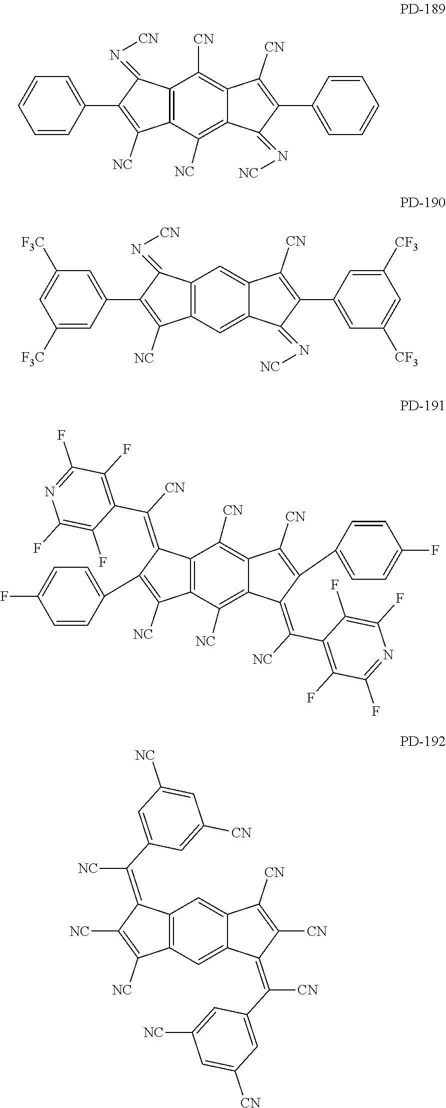 [SMILES: N#C/N=c1/c(-c2ccccc2)c(C#N)c2c(C#N)c3/c(=N\C#N)c(-c4ccccc4)c(C#N)c3c(C#N)c12 ; N#C/N=c1/c(-c2cc(C(F)(F)F)cc(C(F)(F)F)c2)c(C#N)c2cc3/c(=N\C#N)c(-c4cc(C(F)(F)F)cc(C(F)(F)F)c4)c(C#N)c3cc12 ; N#CC1=C(c2ccc(F)cc2)/C(=C(/C#N)c2c(F)c(F)nc(F)c2F)c2c(C#N)c3c(c(C#N)c21)/C(=C(\C#N)c1c(F)c(F)nc(F)c1F)C(c1ccc(F)cc1)=C3C#N ; N#CC1=C(C#N)c2cc3c(cc2/C1=C(/C#N)c1cc(C#N)cc(C#N)c1)C(C#N)=C(C#N)/C3=C(\C#N)c1cc(C#N)cc(C#N)c1]

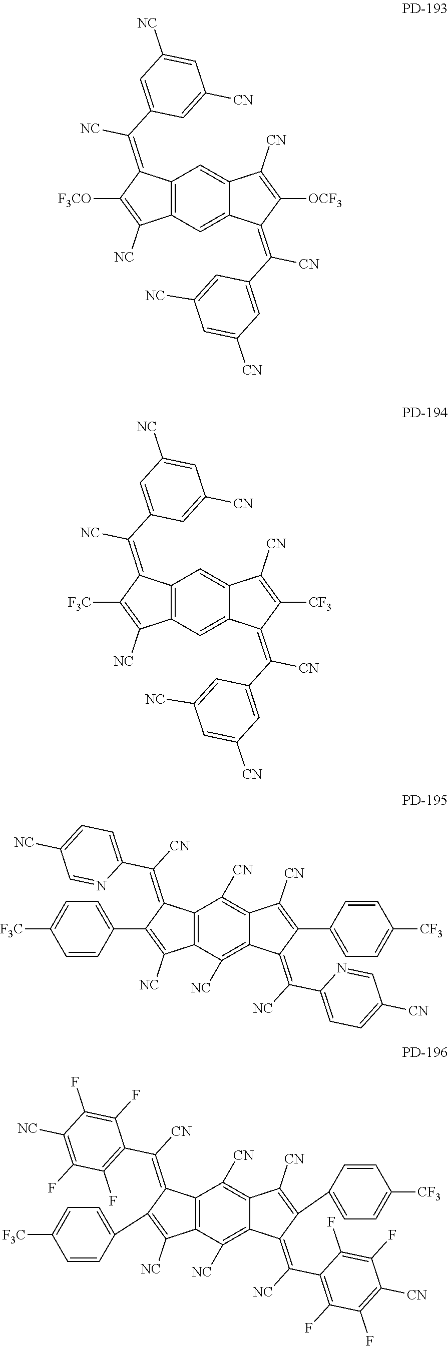 [SMILES: N#CC1=C(OC(F)(F)F)/C(=C(\C#N)c2cc(C#N)cc(C#N)c2)c2cc3c(cc21)/C(=C(/C#N)c1cc(C#N)cc(C#N)c1)C(OC(F)(F)F)=C3C#N ; N#CC1=C(C(F)(F)F)/C(=C(\C#N)c2cc(C#N)cc(C#N)c2)c2cc3c(cc21)/C(=C(/C#N)c1cc(C#N)cc(C#N)c1)C(C(F)(F)F)=C3C#N ; N#CC1=C(c2ccc(C(F)(F)F)cc2)/C(=C(/C#N)c2ccc(C#N)cn2)c2c(C#N)c3c(c(C#N)c21)/C(=C(\C#N)c1ccc(C#N)cn1)C(c1ccc(C(F)(F)F)cc1)=C3C#N ; N#CC1=C(c2ccc(C(F)(F)F)cc2)/C(=C(/C#N)c2c(F)c(F)c(C#N)c(F)c2F)c2c(C#N)c3c(c(C#N)c21)/C(=C(\C#N)c1c(F)c(F)c(C#N)c(F)c1F)C(c1ccc(C(F)(F)F)cc1)=C3C#N]

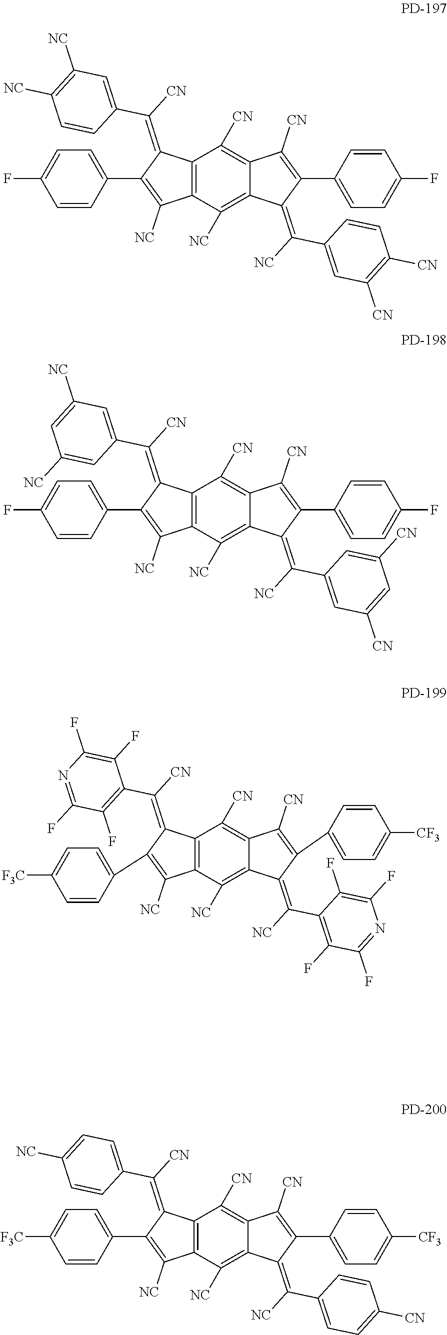

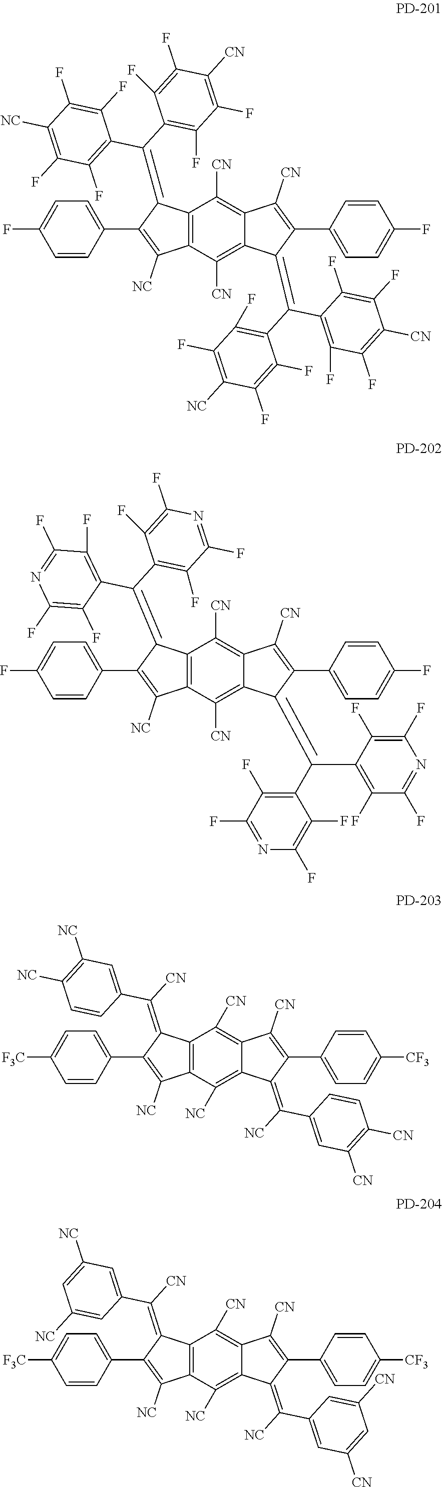

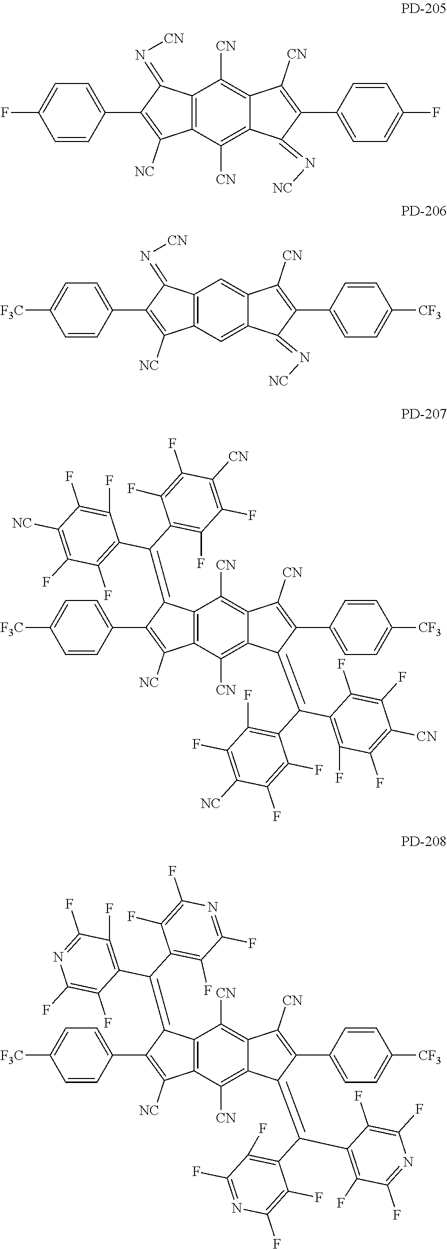

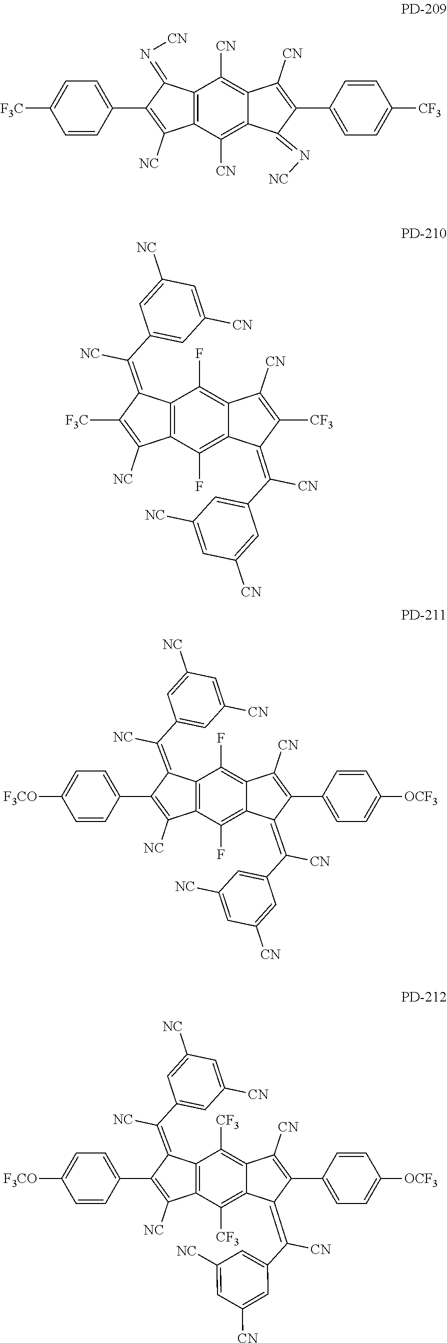 [SMILES: N#C/N=c1/c(-c2ccc(C(F)(F)F)cc2)c(C#N)c2c(C#N)c3/c(=N\C#N)c(-c4ccc(C(F)(F)F)cc4)c(C#N)c3c(C#N)c12 ; N#CC1=C(C(F)(F)F)/C(=C(\C#N)c2cc(C#N)cc(C#N)c2)c2c(F)c3c(c(F)c21)/C(=C(/C#N)c1cc(C#N)cc(C#N)c1)C(C(F)(F)F)=C3C#N ; N#CC1=C(c2ccc(OC(F)(F)F)cc2)/C(=C(\C#N)c2cc(C#N)cc(C#N)c2)c2c(F)c3c(c(F)c21)/C(=C(/C#N)c1cc(C#N)cc(C#N)c1)C(c1ccc(OC(F)(F)F)cc1)=C3C#N ; N#CC1=C(c2ccc(OC(F)(F)F)cc2)/C(=C(\C#N)c2cc(C#N)cc(C#N)c2)c2c1c(C(F)(F)F)c1c(c2C(F)(F)F)C(C#N)=C(c2ccc(OC(F)(F)F)cc2)/C1=C(\C#N)c1cc(C#N)cc(C#N)c1]

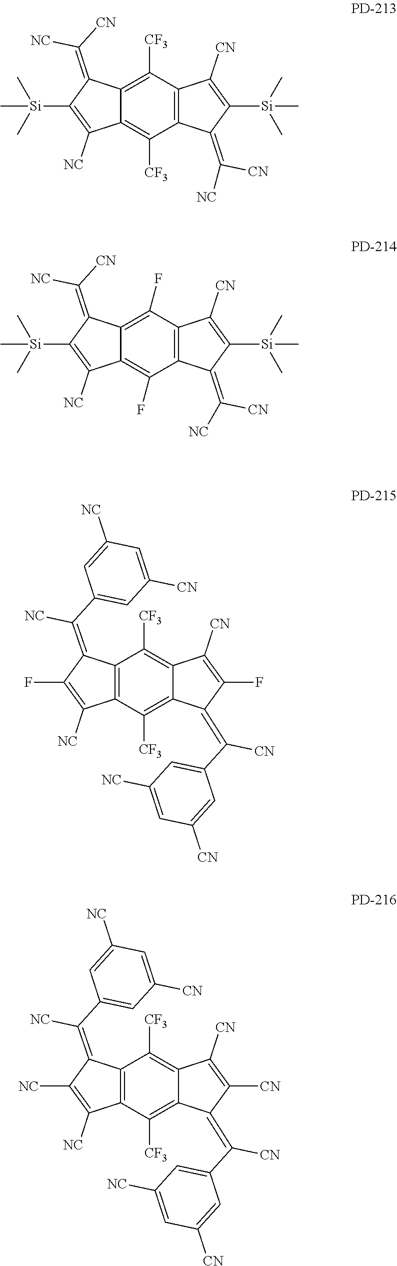

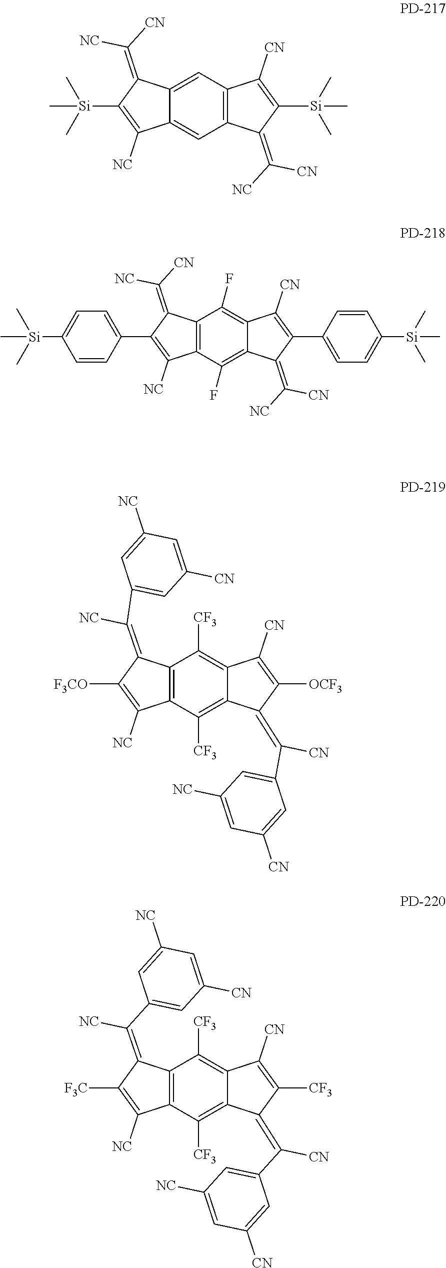

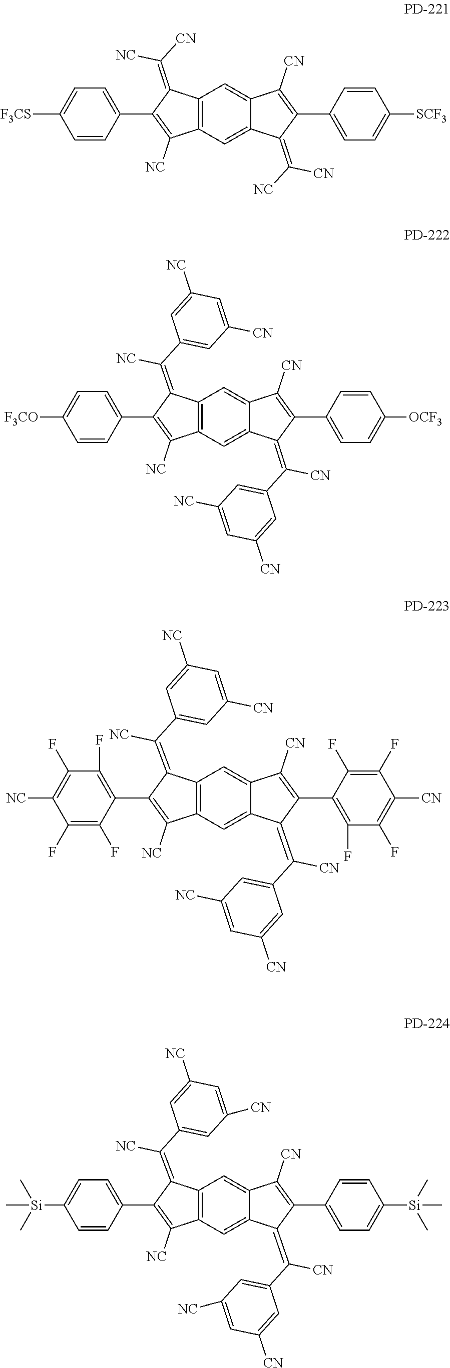

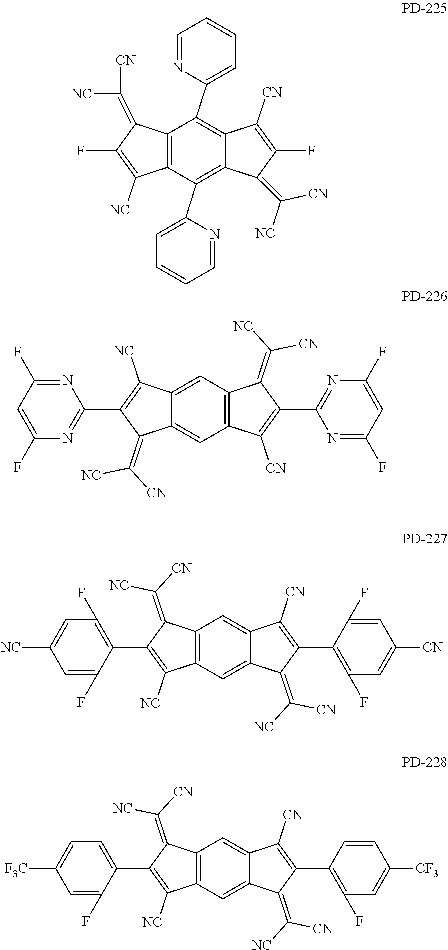 [SMILES: N#CC(C#N)=C1C(F)=C(C#N)c2c1c(-c1ccccn1)c1c(c2-c2ccccn2)C(=C(C#N)C#N)C(F)=C1C#N ; N#CC(C#N)=C1C(c2nc(F)cc(F)n2)=C(C#N)c2cc3c(cc21)C(C#N)=C(c1nc(F)cc(F)n1)C3=C(C#N)C#N ; N#CC(C#N)=C1C(c2c(F)cc(C#N)cc2F)=C(C#N)c2cc3c(cc21)C(C#N)=C(c1c(F)cc(C#N)cc1F)C3=C(C#N)C#N ; N#CC(C#N)=C1C(c2ccc(C(F)(F)F)cc2F)=C(C#N)c2cc3c(cc21)C(C#N)=C(c1ccc(C(F)(F)F)cc1F)C3=C(C#N)C#N]

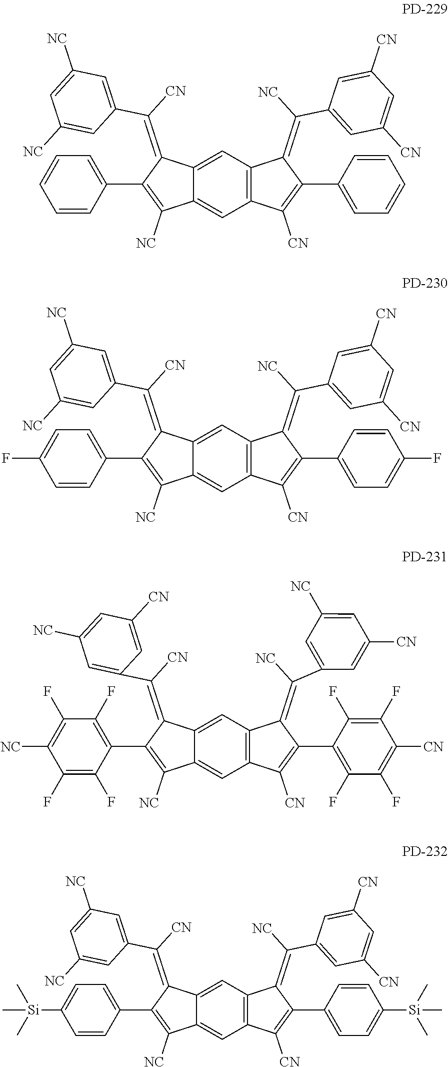

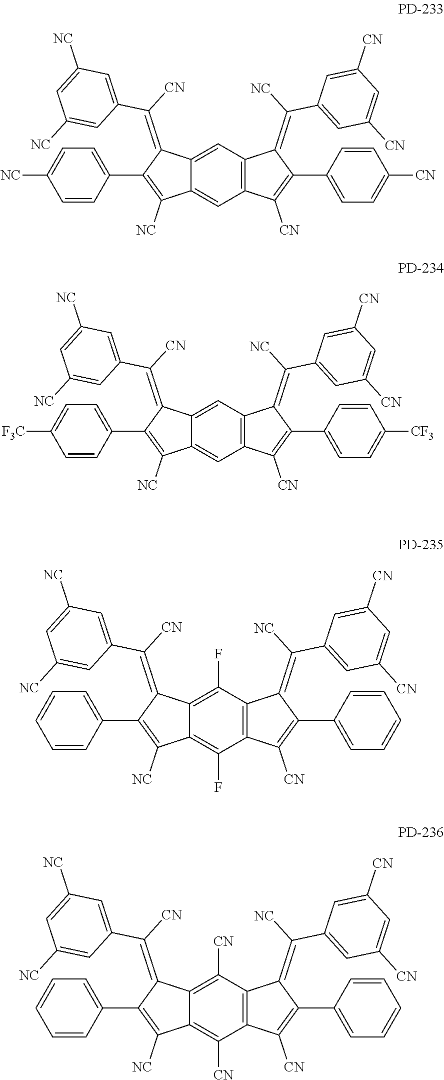 [SMILES: N#CC1=C(c2ccc(C#N)cc2)/C(=C(/C#N)c2cc(C#N)cc(C#N)c2)c2cc3c(cc21)C(C#N)=C(c1ccc(C#N)cc1)/C3=C(/C#N)c1cc(C#N)cc(C#N)c1 ; N#CC1=C(c2ccc(C(F)(F)F)cc2)/C(=C(/C#N)c2cc(C#N)cc(C#N)c2)c2cc3c(cc21)C(C#N)=C(c1ccc(C(F)(F)F)cc1)/C3=C(/C#N)c1cc(C#N)cc(C#N)c1 ; N#CC1=C(c2ccccc2)/C(=C(/C#N)c2cc(C#N)cc(C#N)c2)c2c(F)c3c(c(F)c21)C(C#N)=C(c1ccccc1)/C3=C(/C#N)c1cc(C#N)cc(C#N)c1 ; N#CC1=C(c2ccccc2)/C(=C(/C#N)c2cc(C#N)cc(C#N)c2)c2c(C#N)c3c(c(C#N)c21)C(C#N)=C(c1ccccc1)/C3=C(/C#N)c1cc(C#N)cc(C#N)c1]

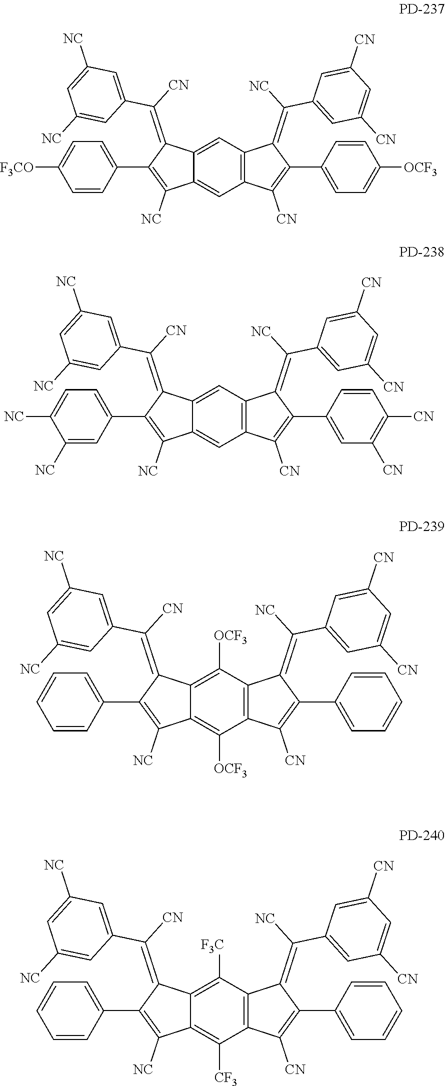

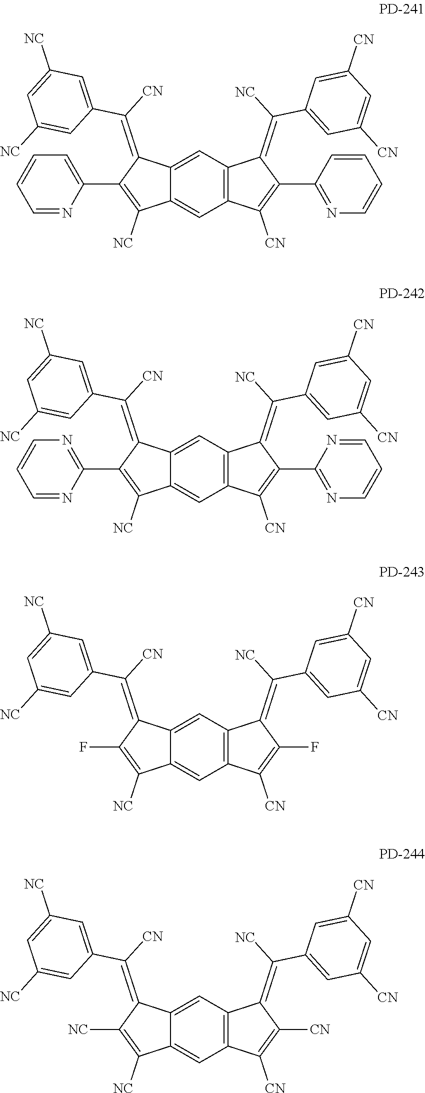 [SMILES: N#CC1=C(c2ccccn2)/C(=C(/C#N)c2cc(C#N)cc(C#N)c2)c2cc3c(cc21)C(C#N)=C(c1ccccn1)/C3=C(/C#N)c1cc(C#N)cc(C#N)c1 ; N#CC1=C(c2ncccn2)/C(=C(/C#N)c2cc(C#N)cc(C#N)c2)c2cc3c(cc21)C(C#N)=C(c1ncccn1)/C3=C(/C#N)c1cc(C#N)cc(C#N)c1 ; N#CC1=C(F)/C(=C(/C#N)c2cc(C#N)cc(C#N)c2)c2cc3c(cc21)C(C#N)=C(F)/C3=C(/C#N)c1cc(C#N)cc(C#N)c1 ; N#CC1=C(C#N)c2cc3c(cc2/C1=C(\C#N)c1cc(C#N)cc(C#N)c1)/C(=C(\C#N)c1cc(C#N)cc(C#N)c1)C(C#N)=C3C#N]

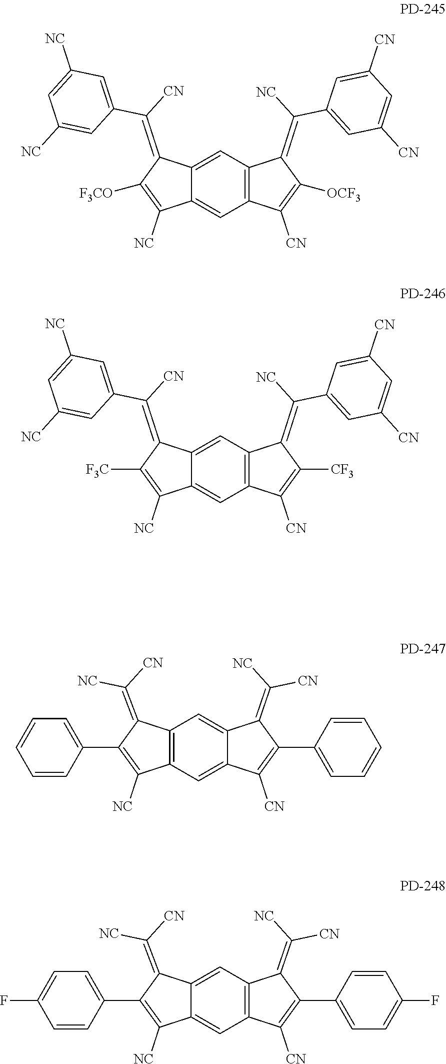 [SMILES: N#CC1=C(OC(F)(F)F)/C(=C(/C#N)c2cc(C#N)cc(C#N)c2)c2cc3c(cc21)C(C#N)=C(OC(F)(F)F)/C3=C(/C#N)c1cc(C#N)cc(C#N)c1 ; N#CC1=C(C(F)(F)F)/C(=C(/C#N)c2cc(C#N)cc(C#N)c2)c2cc3c(cc21)C(C#N)=C(C(F)(F)F)/C3=C(/C#N)c1cc(C#N)cc(C#N)c1 ; N#CC(C#N)=C1C(c2ccccc2)=C(C#N)c2cc3c(cc21)C(=C(C#N)C#N)C(c1ccccc1)=C3C#N ; N#CC(C#N)=C1C(c2ccc(F)cc2)=C(C#N)c2cc3c(cc21)C(=C(C#N)C#N)C(c1ccc(F)cc1)=C3C#N]

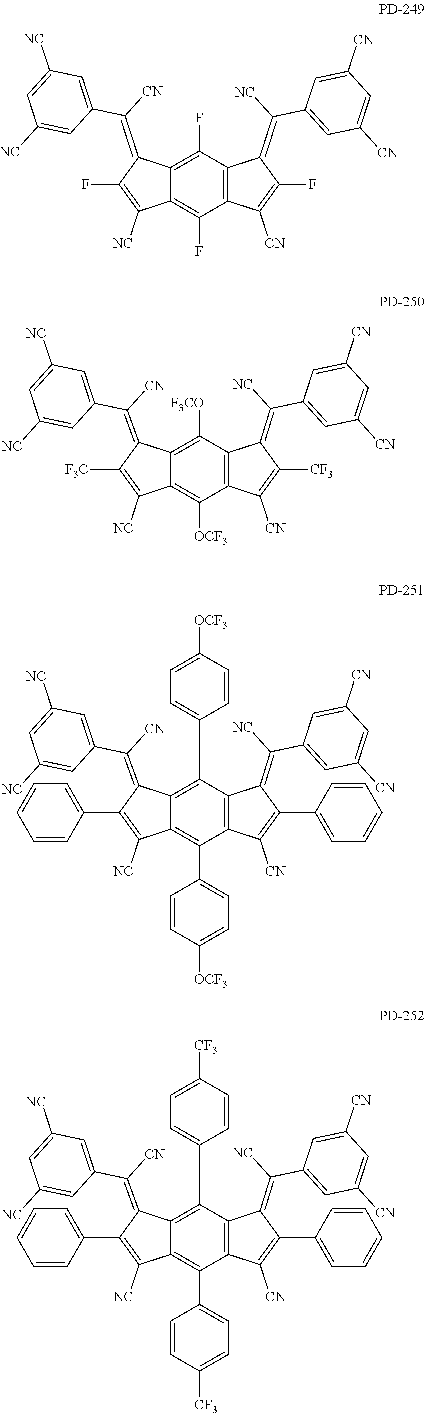

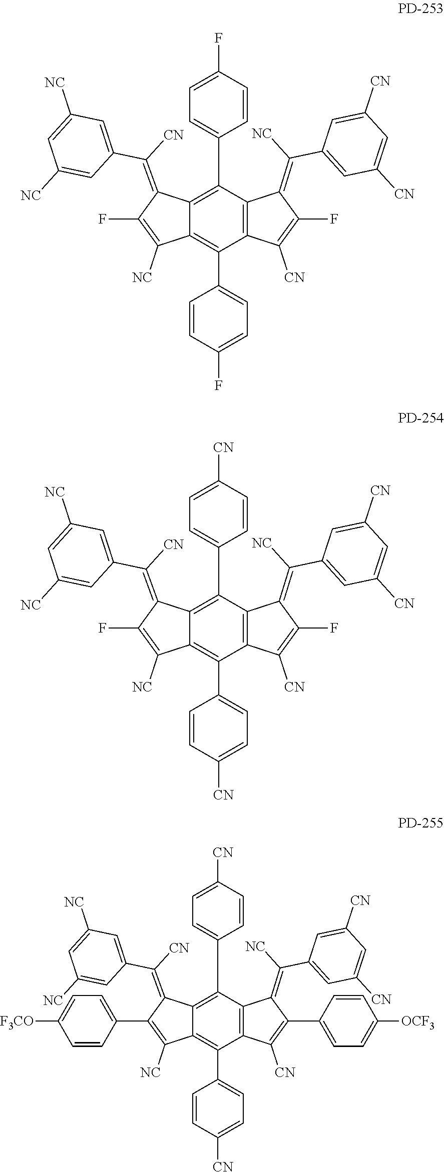 [SMILES: N#CC1=C(F)/C(=C(/C#N)c2cc(C#N)cc(C#N)c2)c2c1c(-c1ccc(F)cc1)c1c(c2-c2ccc(F)cc2)/C(=C(\C#N)c2cc(C#N)cc(C#N)c2)C(F)=C1C#N ; N#CC1=C(F)/C(=C(/C#N)c2cc(C#N)cc(C#N)c2)c2c1c(-c1ccc(C#N)cc1)c1c(c2-c2ccc(C#N)cc2)/C(=C(\C#N)c2cc(C#N)cc(C#N)c2)C(F)=C1C#N ; N#CC1=C(c2ccc(OC(F)(F)F)cc2)/C(=C(/C#N)c2cc(C#N)cc(C#N)c2)c2c1c(-c1ccc(C#N)cc1)c1c(c2-c2ccc(C#N)cc2)/C(=C(\C#N)c2cc(C#N)cc(C#N)c2)C(c2ccc(OC(F)(F)F)cc2)=C1C#N]

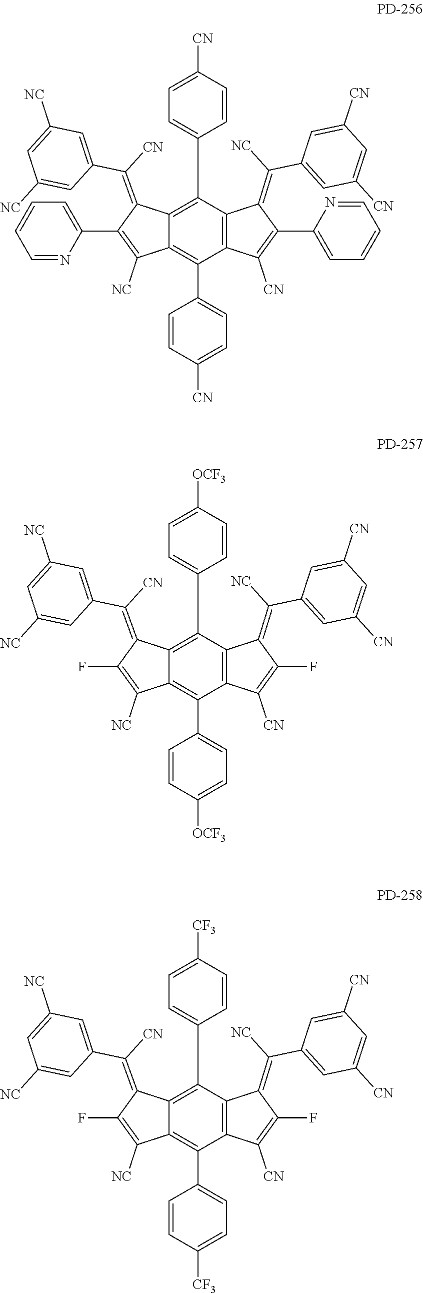 [SMILES: N#CC1=C(c2ccccn2)/C(=C(/C#N)c2cc(C#N)cc(C#N)c2)c2c1c(-c1ccc(C#N)cc1)c1c(c2-c2ccc(C#N)cc2)/C(=C(\C#N)c2cc(C#N)cc(C#N)c2)C(c2ccccn2)=C1C#N ; N#CC1=C(F)/C(=C(/C#N)c2cc(C#N)cc(C#N)c2)c2c1c(-c1ccc(OC(F)(F)F)cc1)c1c(c2-c2ccc(OC(F)(F)F)cc2)/C(=C(\C#N)c2cc(C#N)cc(C#N)c2)C(F)=C1C#N ; N#CC1=C(F)/C(=C(/C#N)c2cc(C#N)cc(C#N)c2)c2c1c(-c1ccc(C(F)(F)F)cc1)c1c(c2-c2ccc(C(F)(F)F)cc2)/C(=C(\C#N)c2cc(C#N)cc(C#N)c2)C(F)=C1C#N]

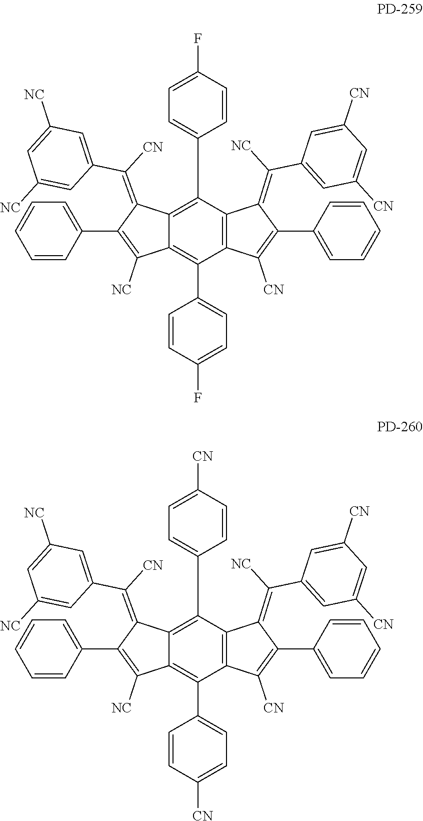 [SMILES: N#CC1=C(c2ccccc2)/C(=C(/C#N)c2cc(C#N)cc(C#N)c2)c2c1c(-c1ccc(F)cc1)c1c(c2-c2ccc(F)cc2)/C(=C(\C#N)c2cc(C#N)cc(C#N)c2)C(c2ccccc2)=C1C#N ; N#CC1=C(c2ccccc2)/C(=C(/C#N)c2cc(C#N)cc(C#N)c2)c2c1c(-c1ccc(C#N)cc1)c1c(c2-c2ccc(C#N)cc2)/C(=C(\C#N)c2cc(C#N)cc(C#N)c2)C(c2ccccc2)=C1C#N]

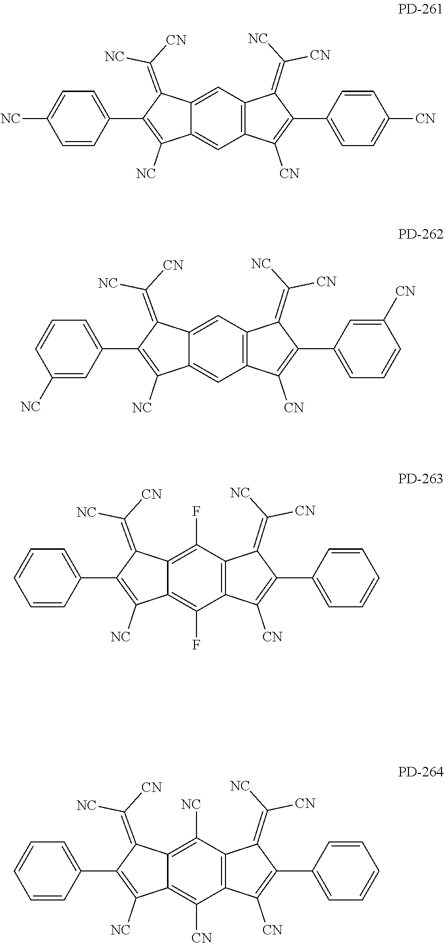 [SMILES: N#CC(C#N)=C1C(c2ccc(C#N)cc2)=C(C#N)c2cc3c(cc21)C(=C(C#N)C#N)C(c1ccc(C#N)cc1)=C3C#N ; N#CC(C#N)=C1C(c2cccc(C#N)c2)=C(C#N)c2cc3c(cc21)C(=C(C#N)C#N)C(c1cccc(C#N)c1)=C3C#N ; N#CC(C#N)=C1C(c2ccccc2)=C(C#N)c2c(F)c3c(c(F)c21)C(=C(C#N)C#N)C(c1ccccc1)=C3C#N ; N#CC(C#N)=C1C(c2ccccc2)=C(C#N)c2c(C#N)c3c(c(C#N)c21)C(=C(C#N)C#N)C(c1ccccc1)=C3C#N]

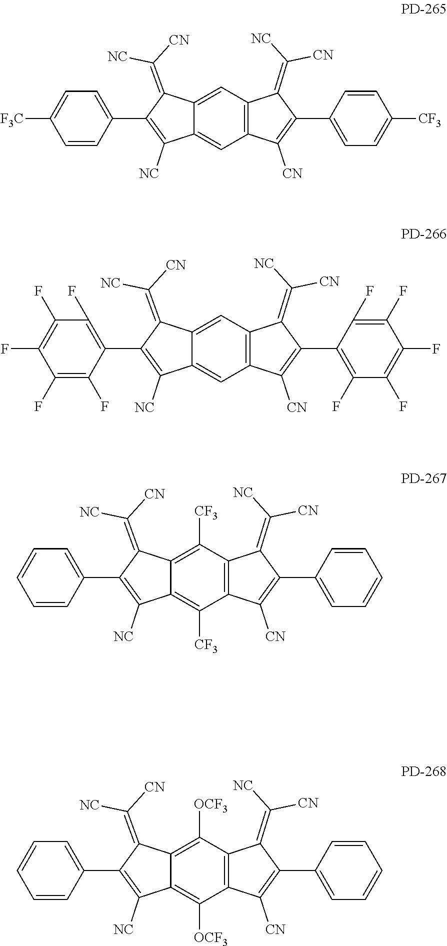 [SMILES: N#CC(C#N)=C1C(c2ccc(C(F)(F)F)cc2)=C(C#N)c2cc3c(cc21)C(=C(C#N)C#N)C(c1ccc(C(F)(F)F)cc1)=C3C#N ; N#CC(C#N)=C1C(c2c(F)c(F)c(F)c(F)c2F)=C(C#N)c2cc3c(cc21)C(=C(C#N)C#N)C(c1c(F)c(F)c(F)c(F)c1F)=C3C#N ; N#CC(C#N)=C1C(c2ccccc2)=C(C#N)c2c1c(C(F)(F)F)c1c(c2C(F)(F)F)C(C#N)=C(c2ccccc2)C1=C(C#N)C#N ; N#CC(C#N)=C1C(c2ccccc2)=C(C#N)c2c(OC(F)(F)F)c3c(c(OC(F)(F)F)c21)C(=C(C#N)C#N)C(c1ccccc1)=C3C#N]

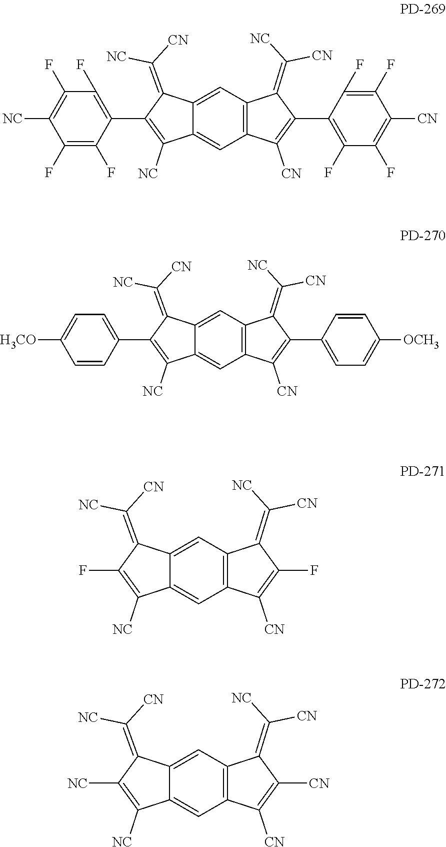 [SMILES: N#CC(C#N)=C1C(c2c(F)c(F)c(C#N)c(F)c2F)=C(C#N)c2cc3c(cc21)C(=C(C#N)C#N)C(c1c(F)c(F)c(C#N)c(F)c1F)=C3C#N ; COc1ccc(C2=C(C#N)c3cc4c(cc3C2=C(C#N)C#N)C(=C(C#N)C#N)C(c2ccc(OC)cc2)=C4C#N)cc1 ; N#CC(C#N)=C1C(F)=C(C#N)c2cc3c(cc21)C(=C(C#N)C#N)C(F)=C3C#N ; N#CC(C#N)=C1C(C#N)=C(C#N)c2cc3c(cc21)C(=C(C#N)C#N)C(C#N)=C3C#N]

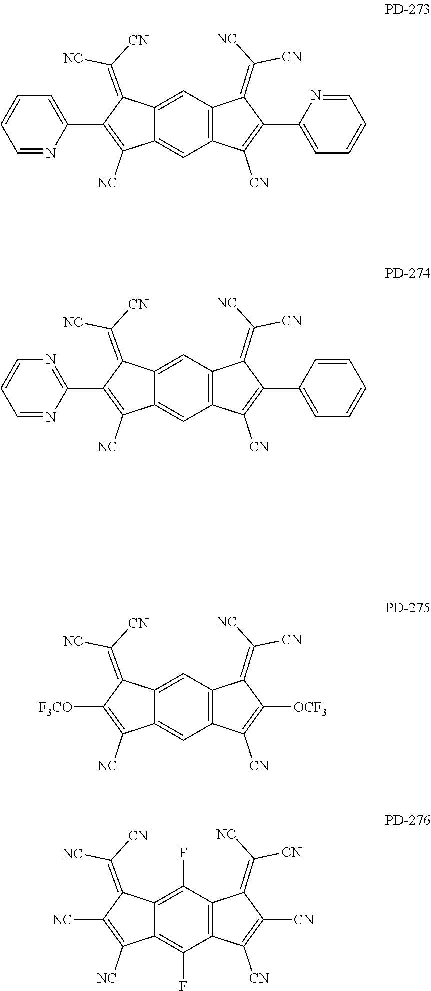 [SMILES: N#CC(C#N)=C1C(c2ccccn2)=C(C#N)c2cc3c(cc21)C(=C(C#N)C#N)C(c1ccccn1)=C3C#N ; N#CC(C#N)=C1C(c2ccccc2)=C(C#N)c2cc3c(cc21)C(=C(C#N)C#N)C(c1ncccn1)=C3C#N ; N#CC(C#N)=C1C(OC(F)(F)F)=C(C#N)c2cc3c(cc21)C(=C(C#N)C#N)C(OC(F)(F)F)=C3C#N ; N#CC(C#N)=C1C(C#N)=C(C#N)c2c(F)c3c(c(F)c21)C(=C(C#N)C#N)C(C#N)=C3C#N]

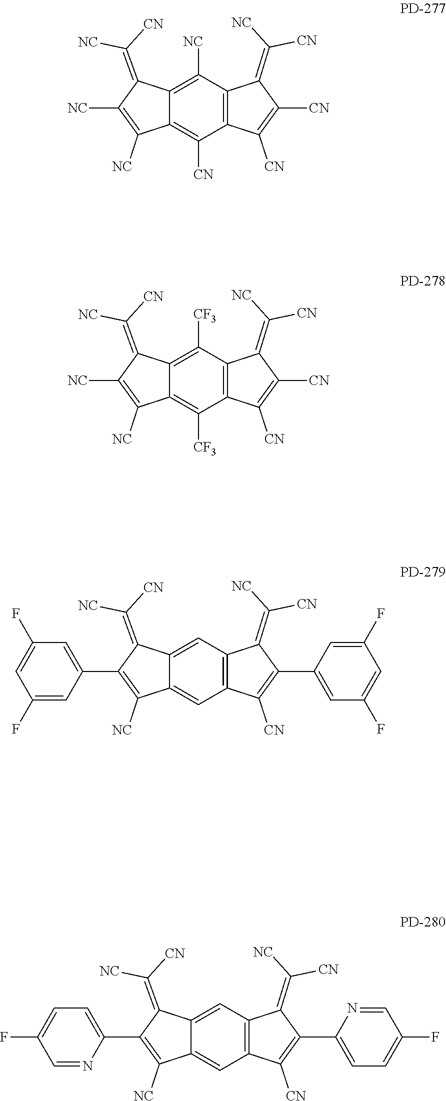 [SMILES: N#CC(C#N)=C1C(C#N)=C(C#N)c2c(C#N)c3c(c(C#N)c21)C(=C(C#N)C#N)C(C#N)=C3C#N ; N#CC(C#N)=C1C(C#N)=C(C#N)c2c1c(C(F)(F)F)c1c(c2C(F)(F)F)C(C#N)=C(C#N)C1=C(C#N)C#N ; N#CC(C#N)=C1C(c2cc(F)cc(F)c2)=C(C#N)c2cc3c(cc21)C(=C(C#N)C#N)C(c1cc(F)cc(F)c1)=C3C#N ; N#CC(C#N)=C1C(c2ccc(F)cn2)=C(C#N)c2cc3c(cc21)C(=C(C#N)C#N)C(c1ccc(F)cn1)=C3C#N]

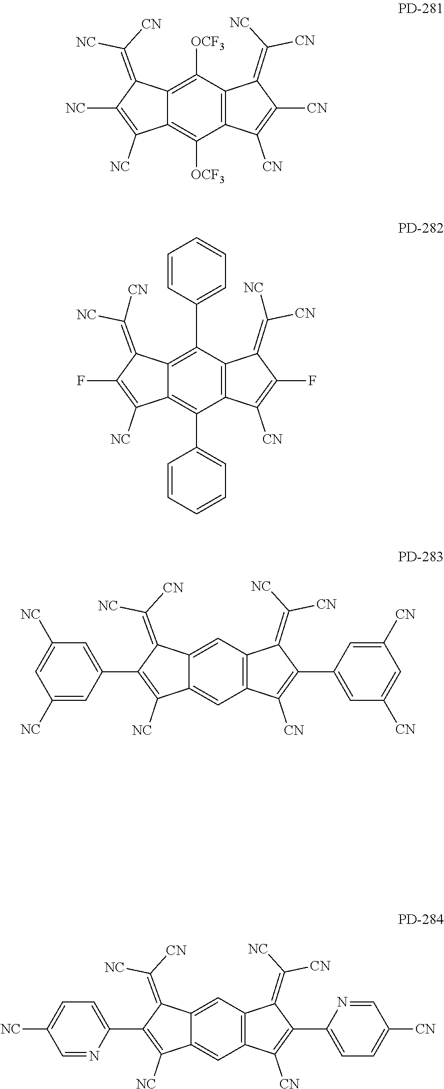 [SMILES: N#CC(C#N)=C1C(C#N)=C(C#N)c2c(OC(F)(F)F)c3c(c(OC(F)(F)F)c21)C(=C(C#N)C#N)C(C#N)=C3C#N ; N#CC(C#N)=C1C(F)=C(C#N)c2c1c(-c1ccccc1)c1c(c2-c2ccccc2)C(C#N)=C(F)C1=C(C#N)C#N ; N#CC(C#N)=C1C(c2cc(C#N)cc(C#N)c2)=C(C#N)c2cc3c(cc21)C(=C(C#N)C#N)C(c1cc(C#N)cc(C#N)c1)=C3C#N ; N#CC(C#N)=C1C(c2ccc(C#N)cn2)=C(C#N)c2cc3c(cc21)C(=C(C#N)C#N)C(c1ccc(C#N)cn1)=C3C#N]

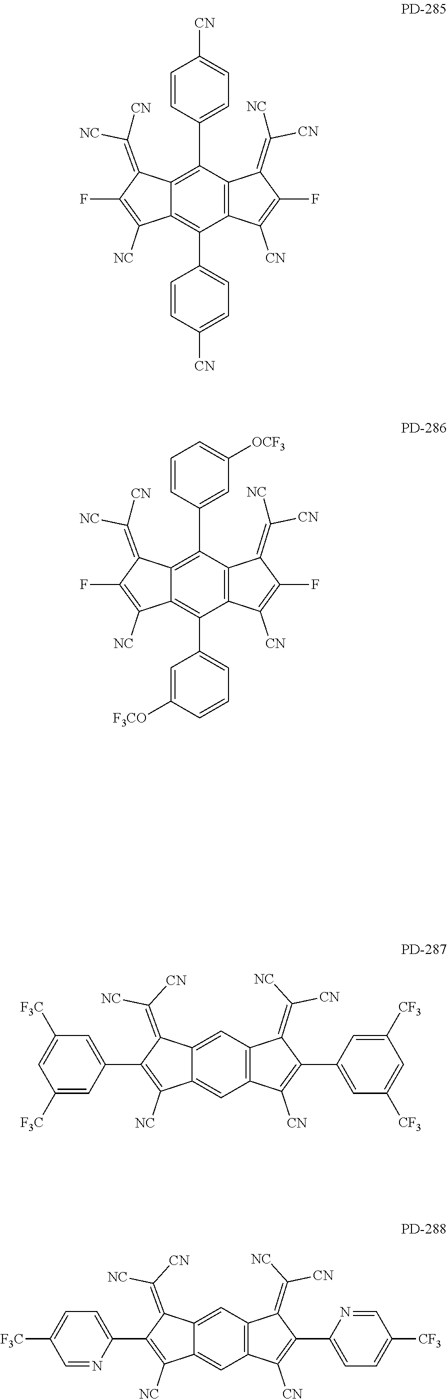 [SMILES: N#CC(C#N)=C1C(F)=C(C#N)c2c1c(-c1ccc(C#N)cc1)c1c(c2-c2ccc(C#N)cc2)C(C#N)=C(F)C1=C(C#N)C#N ; N#CC(C#N)=C1C(F)=C(C#N)c2c1c(-c1cccc(OC(F)(F)F)c1)c1c(c2-c2cccc(OC(F)(F)F)c2)C(C#N)=C(F)C1=C(C#N)C#N ; N#CC(C#N)=C1C(c2cc(C(F)(F)F)cc(C(F)(F)F)c2)=C(C#N)c2cc3c(cc21)C(=C(C#N)C#N)C(c1cc(C(F)(F)F)cc(C(F)(F)F)c1)=C3C#N ; N#CC(C#N)=C1C(c2ccc(C(F)(F)F)cn2)=C(C#N)c2cc3c(cc21)C(=C(C#N)C#N)C(c1ccc(C(F)(F)F)cn1)=C3C#N]

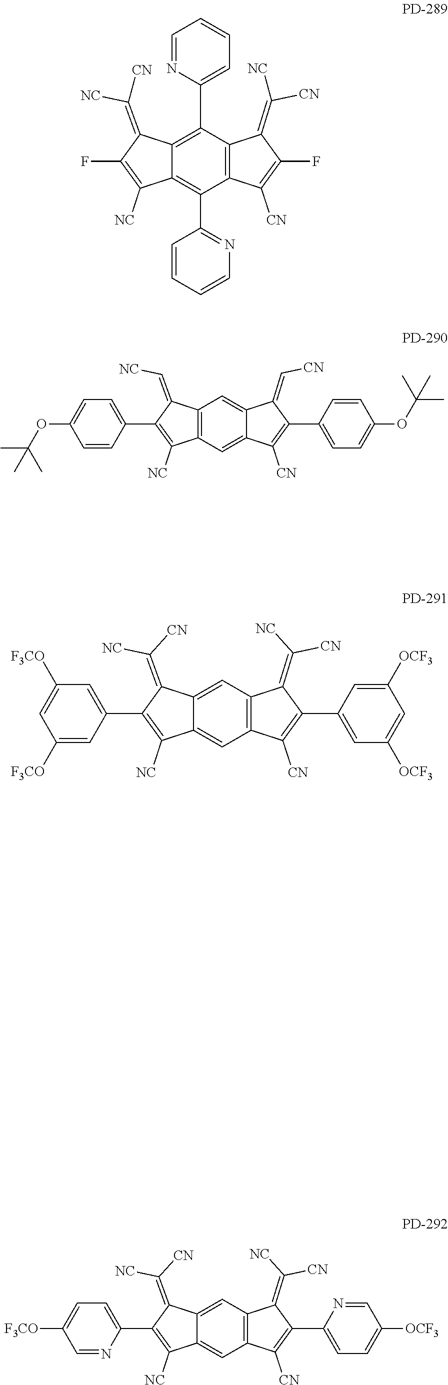 [SMILES: N#CC(C#N)=C1C(F)=C(C#N)c2c1c(-c1ccccn1)c1c(c2-c2ccccn2)C(C#N)=C(F)C1=C(C#N)C#N ; CC(C)(C)Oc1ccc(C2=C(C#N)c3cc4c(cc3/C2=C/C#N)/C(=C/C#N)C(c2ccc(OC(C)(C)C)cc2)=C4C#N)cc1 ; N#CC(C#N)=C1C(c2cc(OC(F)(F)F)cc(OC(F)(F)F)c2)=C(C#N)c2cc3c(cc21)C(=C(C#N)C#N)C(c1cc(OC(F)(F)F)cc(OC(F)(F)F)c1)=C3C#N ; N#CC(C#N)=C1C(c2ccc(OC(F)(F)F)cn2)=C(C#N)c2cc3c(cc21)C(=C(C#N)C#N)C(c1ccc(OC(F)(F)F)cn1)=C3C#N]

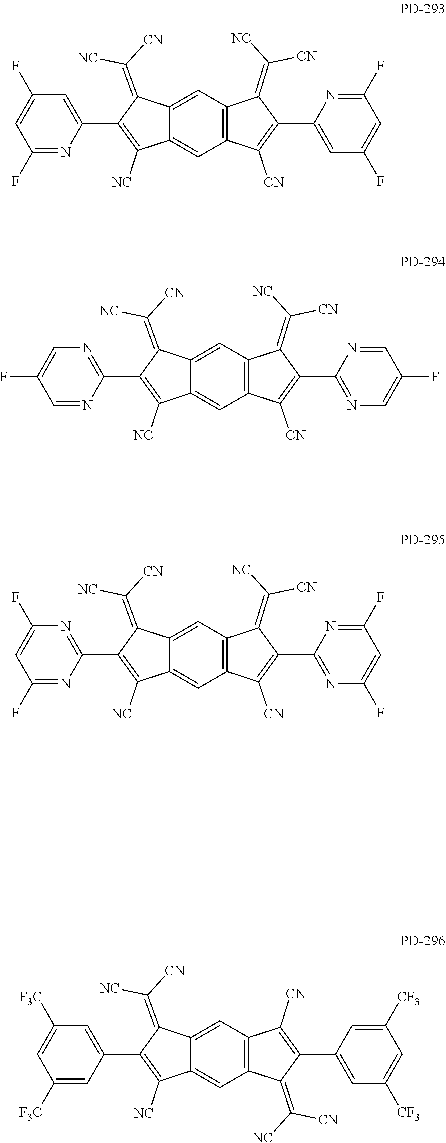 [SMILES: N#CC(C#N)=C1C(c2cc(F)cc(F)n2)=C(C#N)c2cc3c(cc21)C(=C(C#N)C#N)C(c1cc(F)cc(F)n1)=C3C#N ; N#CC(C#N)=C1C(c2ncc(F)cn2)=C(C#N)c2cc3c(cc21)C(=C(C#N)C#N)C(c1ncc(F)cn1)=C3C#N ; N#CC(C#N)=C1C(c2nc(F)cc(F)n2)=C(C#N)c2cc3c(cc21)C(=C(C#N)C#N)C(c1nc(F)cc(F)n1)=C3C#N ; N#CC(C#N)=C1C(c2cc(C(F)(F)F)cc(C(F)(F)F)c2)=C(C#N)c2cc3c(cc21)C(C#N)=C(c1cc(C(F)(F)F)cc(C(F)(F)F)c1)C3=C(C#N)C#N]

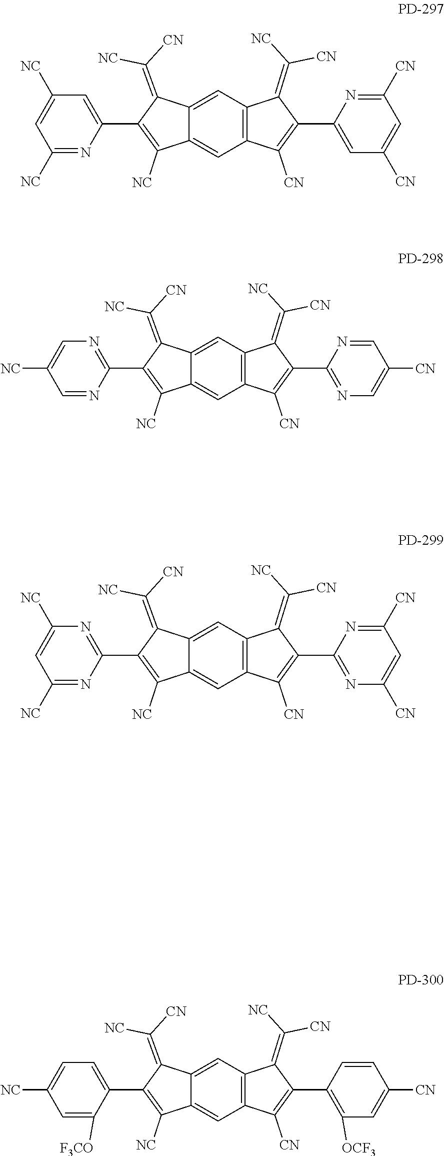 [SMILES: N#CC(C#N)=C1C(c2cc(C#N)cc(C#N)n2)=C(C#N)c2cc3c(cc21)C(=C(C#N)C#N)C(c1cc(C#N)cc(C#N)n1)=C3C#N ; N#CC(C#N)=C1C(c2ncc(C#N)cn2)=C(C#N)c2cc3c(cc21)C(=C(C#N)C#N)C(c1ncc(C#N)cn1)=C3C#N ; N#CC(C#N)=C1C(c2nc(C#N)cc(C#N)n2)=C(C#N)c2cc3c(cc21)C(=C(C#N)C#N)C(c1nc(C#N)cc(C#N)n1)=C3C#N ; N#CC(C#N)=C1C(c2ccc(C#N)cc2OC(F)(F)F)=C(C#N)c2cc3c(cc21)C(=C(C#N)C#N)C(c1ccc(C#N)cc1OC(F)(F)F)=C3C#N]

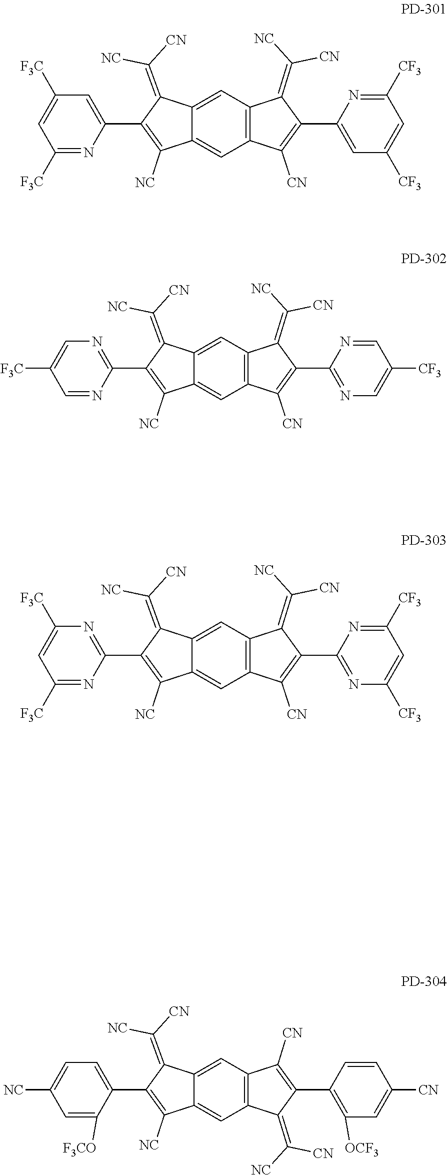 [SMILES: N#CC(C#N)=C1C(c2cc(C(F)(F)F)cc(C(F)(F)F)n2)=C(C#N)c2cc3c(cc21)C(=C(C#N)C#N)C(c1cc(C(F)(F)F)cc(C(F)(F)F)n1)=C3C#N ; N#CC(C#N)=C1C(c2ncc(C(F)(F)F)cn2)=C(C#N)c2cc3c(cc21)C(=C(C#N)C#N)C(c1ncc(C(F)(F)F)cn1)=C3C#N ; N#CC(C#N)=C1C(c2nc(C(F)(F)F)cc(C(F)(F)F)n2)=C(C#N)c2cc3c(cc21)C(=C(C#N)C#N)C(c1nc(C(F)(F)F)cc(C(F)(F)F)n1)=C3C#N ; N#CC(C#N)=C1C(c2ccc(C#N)cc2OC(F)(F)F)=C(C#N)c2cc3c(cc21)C(C#N)=C(c1ccc(C#N)cc1OC(F)(F)F)C3=C(C#N)C#N]

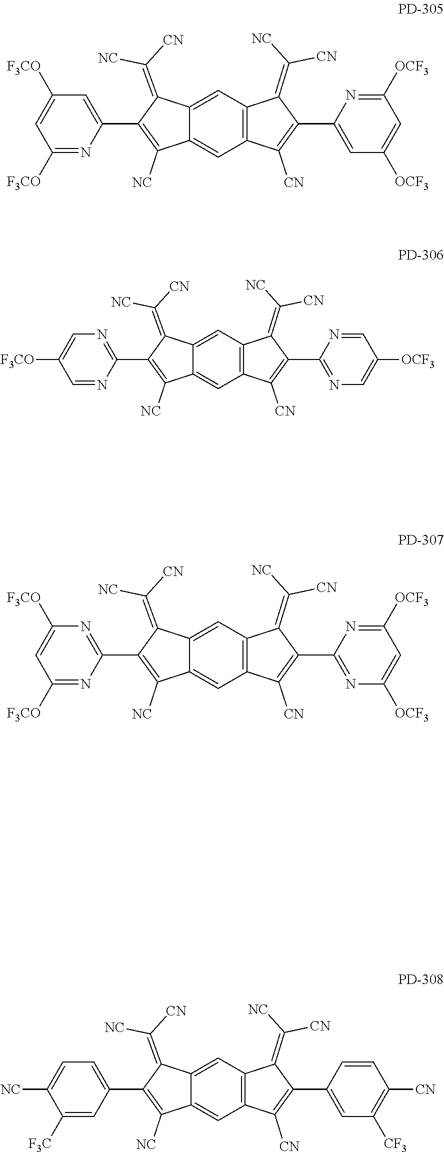 [SMILES: N#CC(C#N)=C1C(c2cc(OC(F)(F)F)cc(OC(F)(F)F)n2)=C(C#N)c2cc3c(cc21)C(=C(C#N)C#N)C(c1cc(OC(F)(F)F)cc(OC(F)(F)F)n1)=C3C#N ; N#CC(C#N)=C1C(c2ncc(OC(F)(F)F)cn2)=C(C#N)c2cc3c(cc21)C(=C(C#N)C#N)C(c1ncc(OC(F)(F)F)cn1)=C3C#N ; N#CC(C#N)=C1C(c2nc(OC(F)(F)F)cc(OC(F)(F)F)n2)=C(C#N)c2cc3c(cc21)C(=C(C#N)C#N)C(c1nc(OC(F)(F)F)cc(OC(F)(F)F)n1)=C3C#N ; N#CC(C#N)=C1C(c2ccc(C#N)c(C(F)(F)F)c2)=C(C#N)c2cc3c(cc21)C(=C(C#N)C#N)C(c1ccc(C#N)c(C(F)(F)F)c1)=C3C#N]

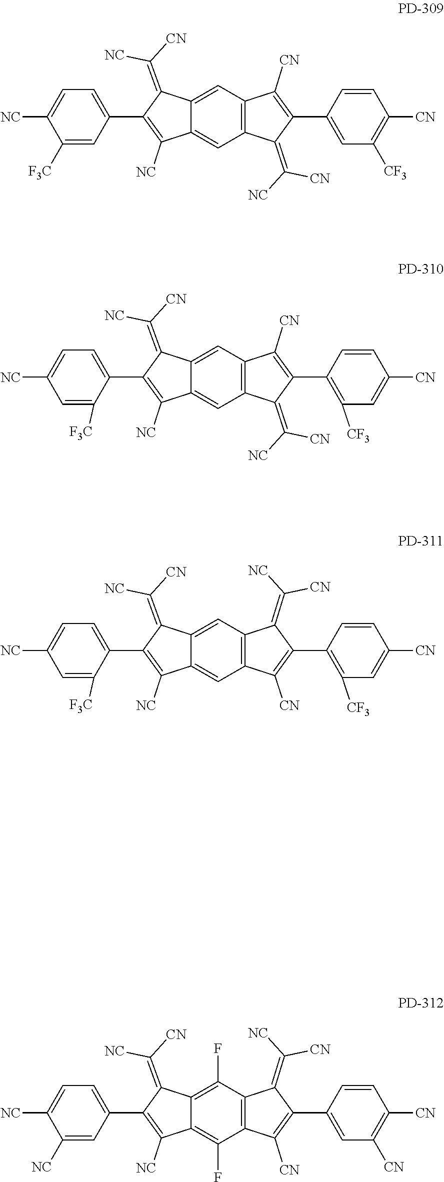 [SMILES: N#CC(C#N)=C1C(c2ccc(C#N)c(C(F)(F)F)c2)=C(C#N)c2cc3c(cc21)C(C#N)=C(c1ccc(C#N)c(C(F)(F)F)c1)C3=C(C#N)C#N ; N#CC(C#N)=C1C(c2ccc(C#N)cc2C(F)(F)F)=C(C#N)c2cc3c(cc21)C(C#N)=C(c1ccc(C#N)cc1C(F)(F)F)C3=C(C#N)C#N ; N#CC(C#N)=C1C(c2ccc(C#N)cc2C(F)(F)F)=C(C#N)c2cc3c(cc21)C(=C(C#N)C#N)C(c1ccc(C#N)cc1C(F)(F)F)=C3C#N ; N#CC(C#N)=C1C(c2ccc(C#N)c(C#N)c2)=C(C#N)c2c(F)c3c(c(F)c21)C(=C(C#N)C#N)C(c1ccc(C#N)c(C#N)c1)=C3C#N]

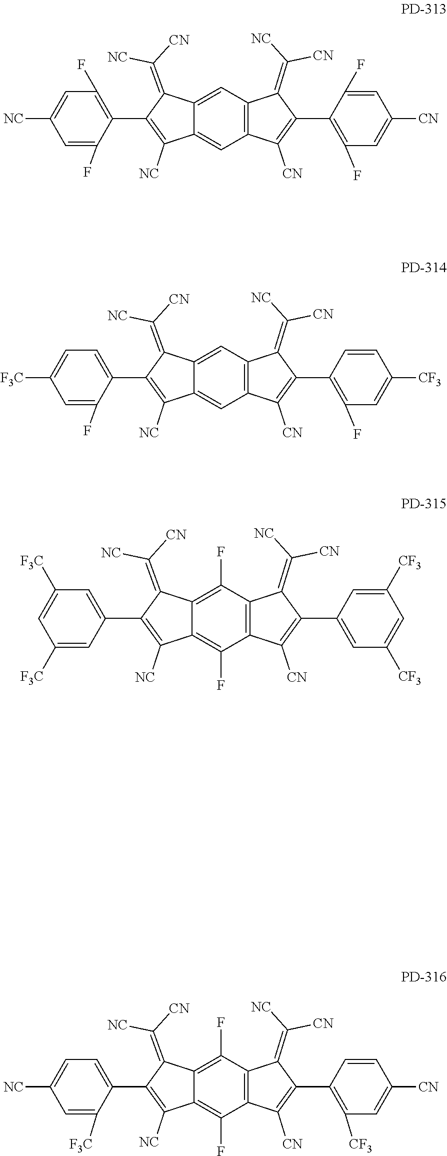 [SMILES: N#CC(C#N)=C1C(c2c(F)cc(C#N)cc2F)=C(C#N)c2cc3c(cc21)C(=C(C#N)C#N)C(c1c(F)cc(C#N)cc1F)=C3C#N ; N#CC(C#N)=C1C(c2ccc(C(F)(F)F)cc2F)=C(C#N)c2cc3c(cc21)C(=C(C#N)C#N)C(c1ccc(C(F)(F)F)cc1F)=C3C#N ; N#CC(C#N)=C1C(c2cc(C(F)(F)F)cc(C(F)(F)F)c2)=C(C#N)c2c(F)c3c(c(F)c21)C(=C(C#N)C#N)C(c1cc(C(F)(F)F)cc(C(F)(F)F)c1)=C3C#N ; N#CC(C#N)=C1C(c2ccc(C#N)cc2C(F)(F)F)=C(C#N)c2c(F)c3c(c(F)c21)C(=C(C#N)C#N)C(c1ccc(C#N)cc1C(F)(F)F)=C3C#N]

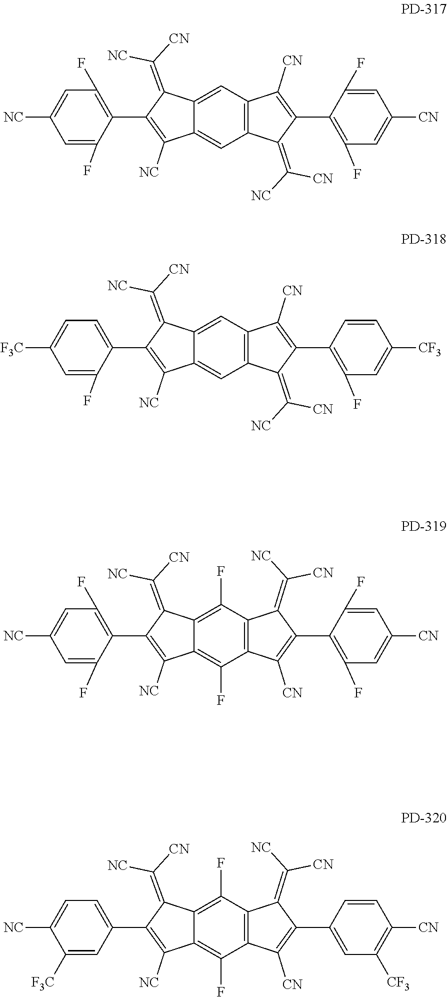 [SMILES: N#CC(C#N)=C1C(c2c(F)cc(C#N)cc2F)=C(C#N)c2cc3c(cc21)C(C#N)=C(c1c(F)cc(C#N)cc1F)C3=C(C#N)C#N ; N#CC(C#N)=C1C(c2ccc(C(F)(F)F)cc2F)=C(C#N)c2cc3c(cc21)C(C#N)=C(c1ccc(C(F)(F)F)cc1F)C3=C(C#N)C#N ; N#CC(C#N)=C1C(c2c(F)cc(C#N)cc2F)=C(C#N)c2c(F)c3c(c(F)c21)C(=C(C#N)C#N)C(c1c(F)cc(C#N)cc1F)=C3C#N ; N#CC(C#N)=C1C(c2ccc(C#N)c(C(F)(F)F)c2)=C(C#N)c2c(F)c3c(c(F)c21)C(=C(C#N)C#N)C(c1ccc(C#N)c(C(F)(F)F)c1)=C3C#N]

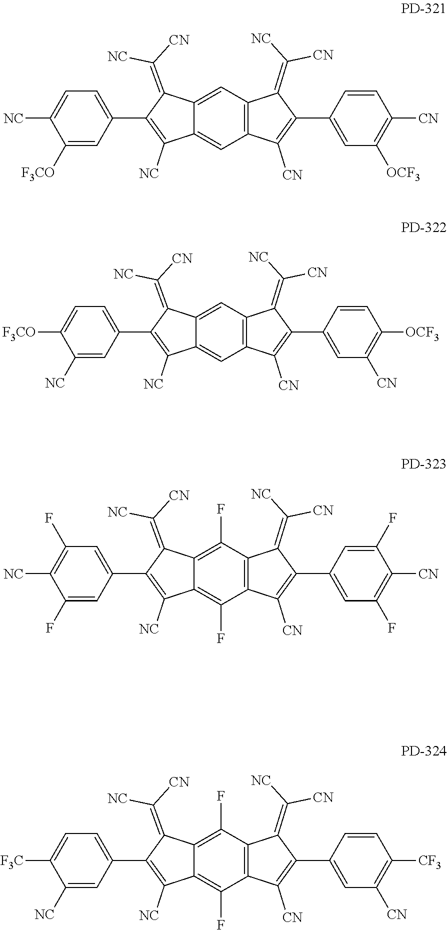 [SMILES: N#CC(C#N)=C1C(c2ccc(C#N)c(OC(F)(F)F)c2)=C(C#N)c2cc3c(cc21)C(=C(C#N)C#N)C(c1ccc(C#N)c(OC(F)(F)F)c1)=C3C#N ; N#CC(C#N)=C1C(c2ccc(OC(F)(F)F)c(C#N)c2)=C(C#N)c2cc3c(cc21)C(=C(C#N)C#N)C(c1ccc(OC(F)(F)F)c(C#N)c1)=C3C#N ; N#CC(C#N)=C1C(c2cc(F)c(C#N)c(F)c2)=C(C#N)c2c(F)c3c(c(F)c21)C(=C(C#N)C#N)C(c1cc(F)c(C#N)c(F)c1)=C3C#N ; N#CC(C#N)=C1C(c2ccc(C(F)(F)F)c(C#N)c2)=C(C#N)c2c(F)c3c(c(F)c21)C(=C(C#N)C#N)C(c1ccc(C(F)(F)F)c(C#N)c1)=C3C#N]

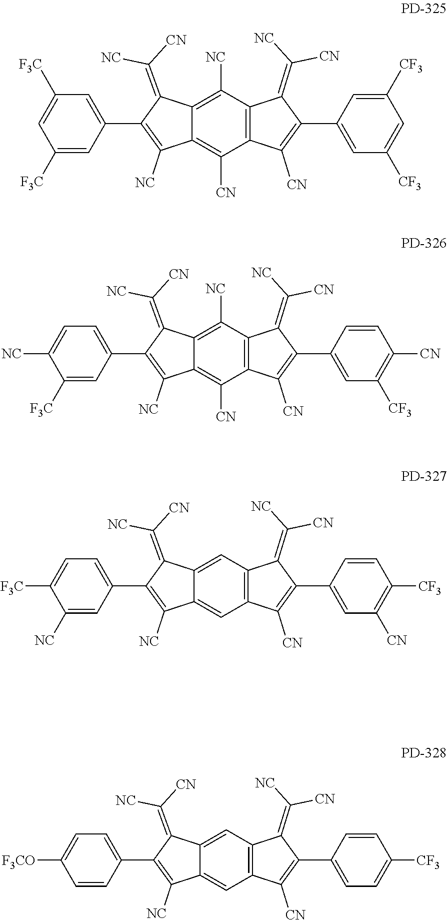 [SMILES: N#CC(C#N)=C1C(c2cc(C(F)(F)F)cc(C(F)(F)F)c2)=C(C#N)c2c(C#N)c3c(c(C#N)c21)C(=C(C#N)C#N)C(c1cc(C(F)(F)F)cc(C(F)(F)F)c1)=C3C#N ; N#CC(C#N)=C1C(c2ccc(C#N)c(C(F)(F)F)c2)=C(C#N)c2c(C#N)c3c(c(C#N)c21)C(=C(C#N)C#N)C(c1ccc(C#N)c(C(F)(F)F)c1)=C3C#N ; N#CC(C#N)=C1C(c2ccc(C(F)(F)F)c(C#N)c2)=C(C#N)c2cc3c(cc21)C(=C(C#N)C#N)C(c1ccc(C(F)(F)F)c(C#N)c1)=C3C#N ; N#CC(C#N)=C1C(c2ccc(OC(F)(F)F)cc2)=C(C#N)c2cc3c(cc21)C(=C(C#N)C#N)C(c1ccc(C(F)(F)F)cc1)=C3C#N]

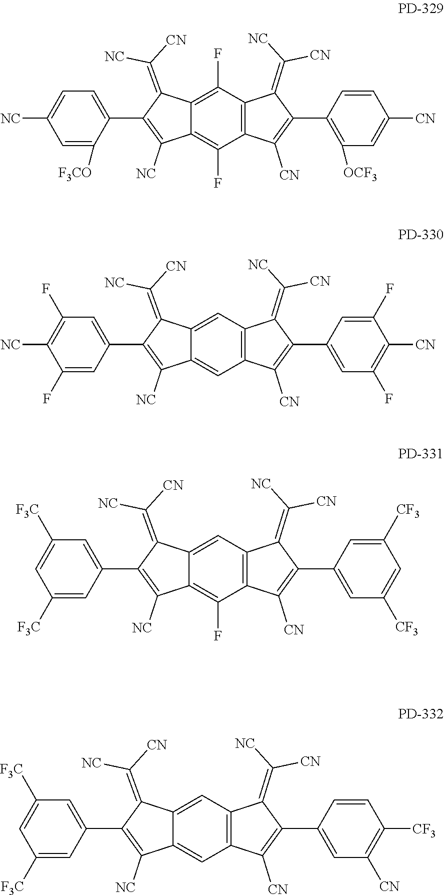 [SMILES: N#CC(C#N)=C1C(c2ccc(C#N)cc2OC(F)(F)F)=C(C#N)c2c(F)c3c(c(F)c21)C(=C(C#N)C#N)C(c1ccc(C#N)cc1OC(F)(F)F)=C3C#N ; N#CC(C#N)=C1C(c2cc(F)c(C#N)c(F)c2)=C(C#N)c2cc3c(cc21)C(=C(C#N)C#N)C(c1cc(F)c(C#N)c(F)c1)=C3C#N ; N#CC(C#N)=C1C(c2cc(C(F)(F)F)cc(C(F)(F)F)c2)=C(C#N)c2c1cc1c(c2F)C(C#N)=C(c2cc(C(F)(F)F)cc(C(F)(F)F)c2)C1=C(C#N)C#N ; N#CC(C#N)=C1C(c2cc(C(F)(F)F)cc(C(F)(F)F)c2)=C(C#N)c2cc3c(cc21)C(=C(C#N)C#N)C(c1ccc(C(F)(F)F)c(C#N)c1)=C3C#N]

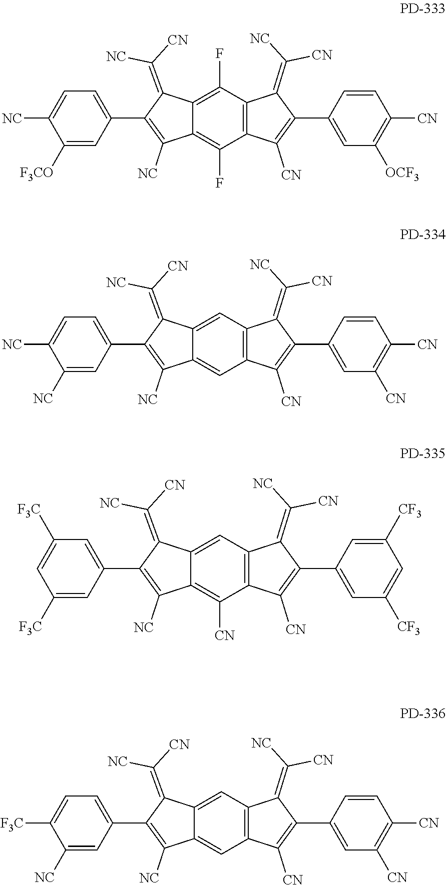 [SMILES: N#CC(C#N)=C1C(c2ccc(C#N)c(OC(F)(F)F)c2)=C(C#N)c2c(F)c3c(c(F)c21)C(=C(C#N)C#N)C(c1ccc(C#N)c(OC(F)(F)F)c1)=C3C#N ; N#CC(C#N)=C1C(c2ccc(C#N)c(C#N)c2)=C(C#N)c2cc3c(cc21)C(=C(C#N)C#N)C(c1ccc(C#N)c(C#N)c1)=C3C#N ; N#CC(C#N)=C1C(c2cc(C(F)(F)F)cc(C(F)(F)F)c2)=C(C#N)c2c1cc1c(c2C#N)C(C#N)=C(c2cc(C(F)(F)F)cc(C(F)(F)F)c2)C1=C(C#N)C#N ; N#CC(C#N)=C1C(c2ccc(C#N)c(C#N)c2)=C(C#N)c2cc3c(cc21)C(=C(C#N)C#N)C(c1ccc(C(F)(F)F)c(C#N)c1)=C3C#N]

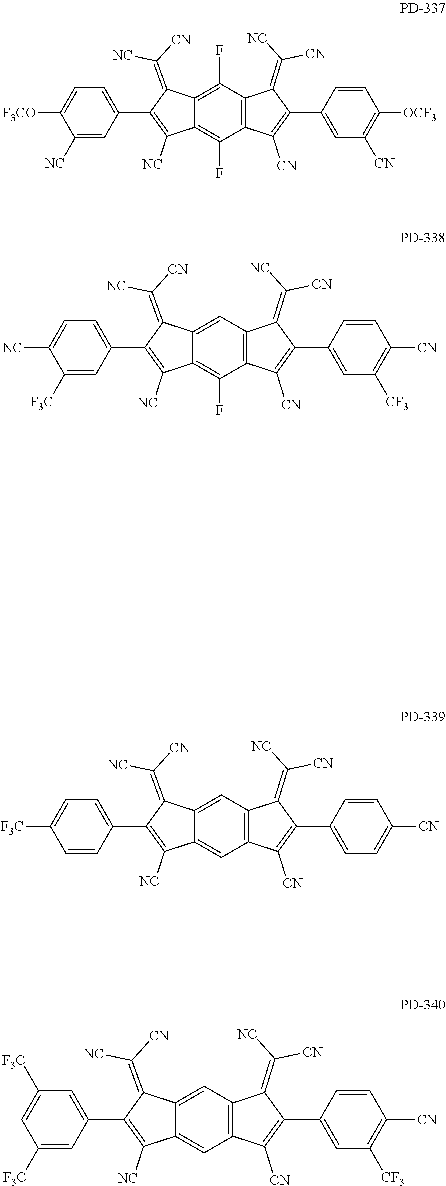 [SMILES: N#CC(C#N)=C1C(c2ccc(OC(F)(F)F)c(C#N)c2)=C(C#N)c2c(F)c3c(c(F)c21)C(=C(C#N)C#N)C(c1ccc(OC(F)(F)F)c(C#N)c1)=C3C#N ; N#CC(C#N)=C1C(c2ccc(C#N)c(C(F)(F)F)c2)=C(C#N)c2c1cc1c(c2F)C(C#N)=C(c2ccc(C#N)c(C(F)(F)F)c2)C1=C(C#N)C#N ; N#CC(C#N)=C1C(c2ccc(C#N)cc2)=C(C#N)c2cc3c(cc21)C(=C(C#N)C#N)C(c1ccc(C(F)(F)F)cc1)=C3C#N ; N#CC(C#N)=C1C(c2cc(C(F)(F)F)cc(C(F)(F)F)c2)=C(C#N)c2cc3c(cc21)C(=C(C#N)C#N)C(c1ccc(C#N)c(C(F)(F)F)c1)=C3C#N]

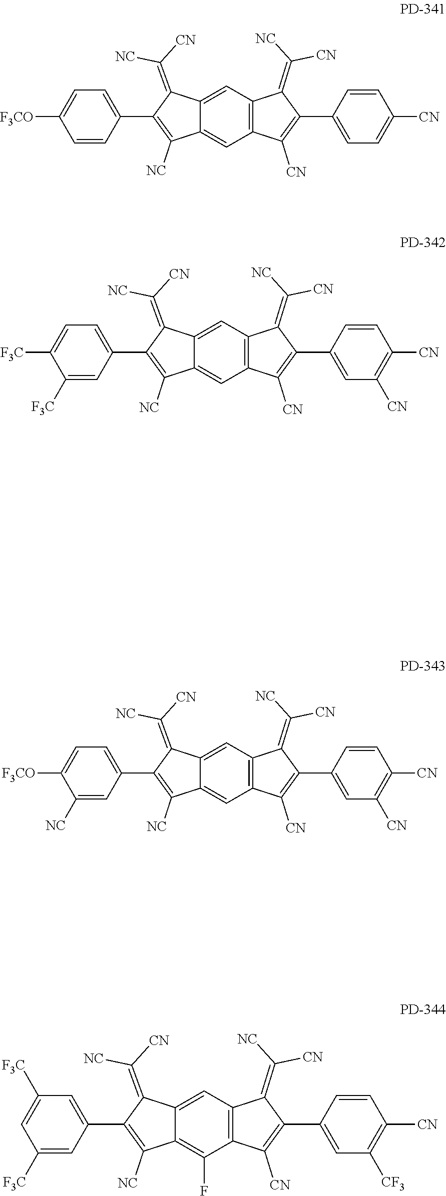 [SMILES: N#CC(C#N)=C1C(c2ccc(C#N)cc2)=C(C#N)c2cc3c(cc21)C(=C(C#N)C#N)C(c1ccc(OC(F)(F)F)cc1)=C3C#N ; N#CC(C#N)=C1C(c2ccc(C#N)c(C#N)c2)=C(C#N)c2cc3c(cc21)C(=C(C#N)C#N)C(c1ccc(C(F)(F)F)c(C(F)(F)F)c1)=C3C#N ; N#CC(C#N)=C1C(c2ccc(C#N)c(C#N)c2)=C(C#N)c2cc3c(cc21)C(=C(C#N)C#N)C(c1ccc(OC(F)(F)F)c(C#N)c1)=C3C#N ; N#CC(C#N)=C1C(c2cc(C(F)(F)F)cc(C(F)(F)F)c2)=C(C#N)c2c1cc1c(c2F)C(C#N)=C(c2ccc(C#N)c(C(F)(F)F)c2)C1=C(C#N)C#N]

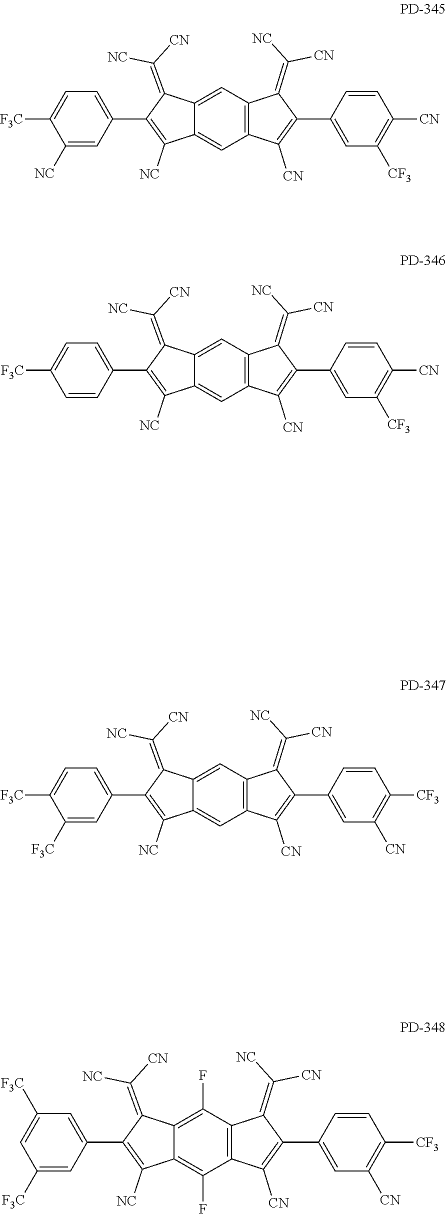 [SMILES: N#CC(C#N)=C1C(c2ccc(C(F)(F)F)c(C#N)c2)=C(C#N)c2cc3c(cc21)C(=C(C#N)C#N)C(c1ccc(C#N)c(C(F)(F)F)c1)=C3C#N ; N#CC(C#N)=C1C(c2ccc(C(F)(F)F)cc2)=C(C#N)c2cc3c(cc21)C(=C(C#N)C#N)C(c1ccc(C#N)c(C(F)(F)F)c1)=C3C#N ; N#CC(C#N)=C1C(c2ccc(C(F)(F)F)c(C#N)c2)=C(C#N)c2cc3c(cc21)C(=C(C#N)C#N)C(c1ccc(C(F)(F)F)c(C(F)(F)F)c1)=C3C#N ; N#CC(C#N)=C1C(c2cc(C(F)(F)F)cc(C(F)(F)F)c2)=C(C#N)c2c(F)c3c(c(F)c21)C(=C(C#N)C#N)C(c1ccc(C(F)(F)F)c(C#N)c1)=C3C#N]

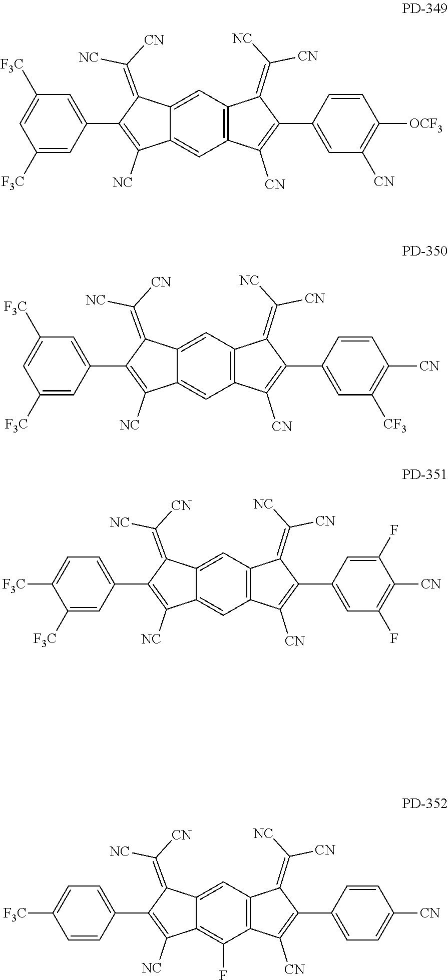 [SMILES: N#CC(C#N)=C1C(c2cc(C(F)(F)F)cc(C(F)(F)F)c2)=C(C#N)c2cc3c(cc21)C(=C(C#N)C#N)C(c1ccc(OC(F)(F)F)c(C#N)c1)=C3C#N ; N#CC(C#N)=C1C(c2cc(C(F)(F)F)cc(C(F)(F)F)c2)=C(C#N)c2cc3c(cc21)C(=C(C#N)C#N)C(c1ccc(C#N)c(C(F)(F)F)c1)=C3C#N ; N#CC(C#N)=C1C(c2cc(F)c(C#N)c(F)c2)=C(C#N)c2cc3c(cc21)C(=C(C#N)C#N)C(c1ccc(C(F)(F)F)c(C(F)(F)F)c1)=C3C#N ; N#CC(C#N)=C1C(c2ccc(C#N)cc2)=C(C#N)c2c1cc1c(c2F)C(C#N)=C(c2ccc(C(F)(F)F)cc2)C1=C(C#N)C#N]

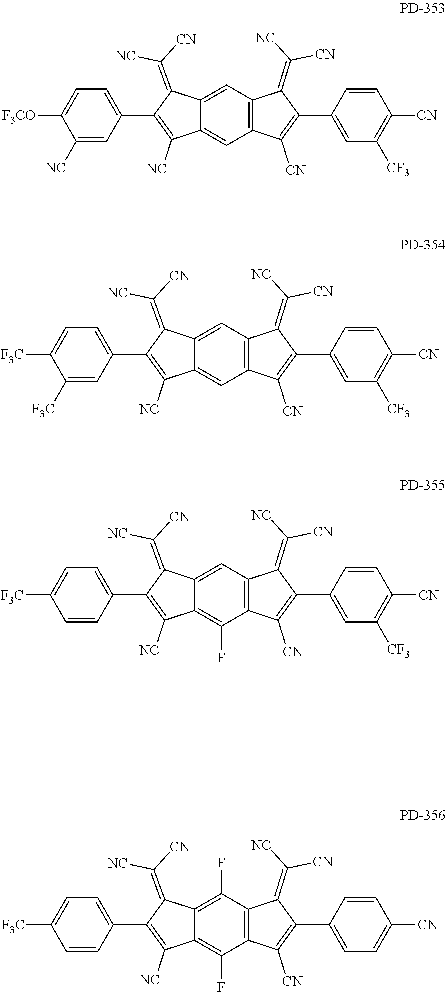 [SMILES: N#CC(C#N)=C1C(c2ccc(OC(F)(F)F)c(C#N)c2)=C(C#N)c2cc3c(cc21)C(=C(C#N)C#N)C(c1ccc(C#N)c(C(F)(F)F)c1)=C3C#N ; N#CC(C#N)=C1C(c2ccc(C#N)c(C(F)(F)F)c2)=C(C#N)c2cc3c(cc21)C(=C(C#N)C#N)C(c1ccc(C(F)(F)F)c(C(F)(F)F)c1)=C3C#N ; N#CC(C#N)=C1C(c2ccc(C(F)(F)F)cc2)=C(C#N)c2c1cc1c(c2F)C(C#N)=C(c2ccc(C#N)c(C(F)(F)F)c2)C1=C(C#N)C#N ; N#CC(C#N)=C1C(c2ccc(C#N)cc2)=C(C#N)c2c(F)c3c(c(F)c21)C(=C(C#N)C#N)C(c1ccc(C(F)(F)F)cc1)=C3C#N]

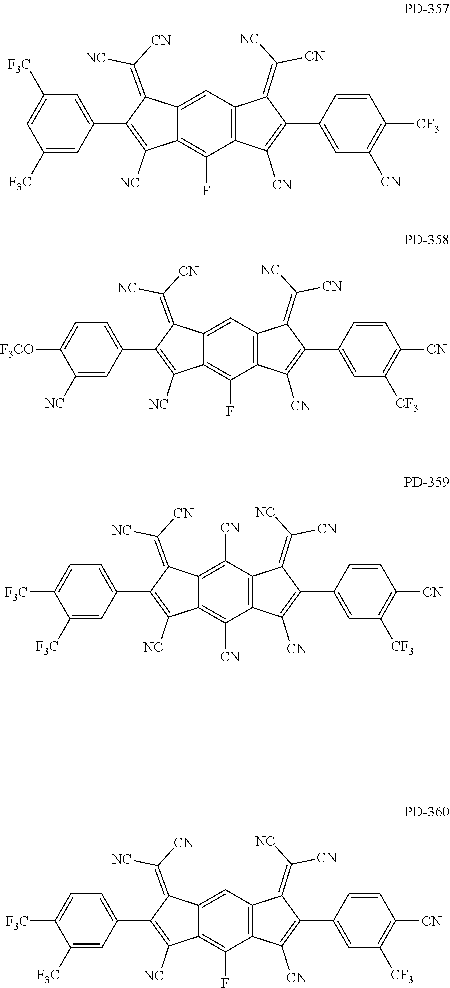 [SMILES: N#CC(C#N)=C1C(c2cc(C(F)(F)F)cc(C(F)(F)F)c2)=C(C#N)c2c1cc1c(c2F)C(C#N)=C(c2ccc(C(F)(F)F)c(C#N)c2)C1=C(C#N)C#N ; N#CC(C#N)=C1C(c2ccc(OC(F)(F)F)c(C#N)c2)=C(C#N)c2c1cc1c(c2F)C(C#N)=C(c2ccc(C#N)c(C(F)(F)F)c2)C1=C(C#N)C#N ; N#CC(C#N)=C1C(c2ccc(C#N)c(C(F)(F)F)c2)=C(C#N)c2c(C#N)c3c(c(C#N)c21)C(=C(C#N)C#N)C(c1ccc(C(F)(F)F)c(C(F)(F)F)c1)=C3C#N ; N#CC(C#N)=C1C(c2ccc(C#N)c(C(F)(F)F)c2)=C(C#N)c2c1cc1c(c2F)C(C#N)=C(c2ccc(C(F)(F)F)c(C(F)(F)F)c2)C1=C(C#N)C#N]

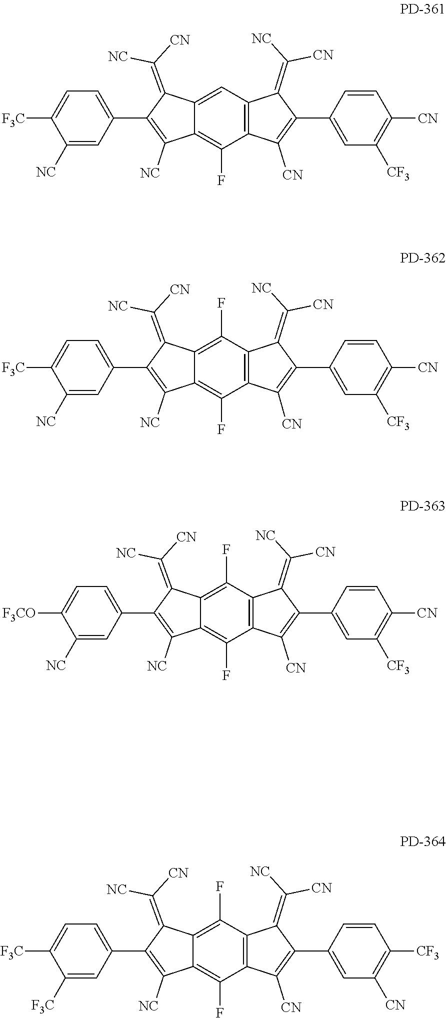 [SMILES: N#CC(C#N)=C1C(c2ccc(C(F)(F)F)c(C#N)c2)=C(C#N)c2c1cc1c(c2F)C(C#N)=C(c2ccc(C#N)c(C(F)(F)F)c2)C1=C(C#N)C#N ; N#CC(C#N)=C1C(c2ccc(C(F)(F)F)c(C#N)c2)=C(C#N)c2c(F)c3c(c(F)c21)C(=C(C#N)C#N)C(c1ccc(C#N)c(C(F)(F)F)c1)=C3C#N ; N#CC(C#N)=C1C(c2ccc(OC(F)(F)F)c(C#N)c2)=C(C#N)c2c(F)c3c(c(F)c21)C(=C(C#N)C#N)C(c1ccc(C#N)c(C(F)(F)F)c1)=C3C#N ; N#CC(C#N)=C1C(c2ccc(C(F)(F)F)c(C#N)c2)=C(C#N)c2c(F)c3c(c(F)c21)C(=C(C#N)C#N)C(c1ccc(C(F)(F)F)c(C(F)(F)F)c1)=C3C#N]

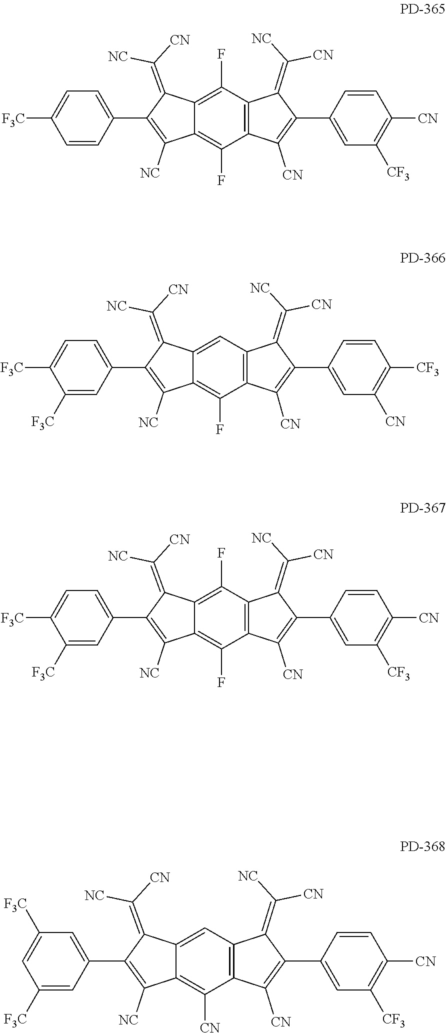 [SMILES: N#CC(C#N)=C1C(c2ccc(C(F)(F)F)cc2)=C(C#N)c2c(F)c3c(c(F)c21)C(=C(C#N)C#N)C(c1ccc(C#N)c(C(F)(F)F)c1)=C3C#N ; N#CC(C#N)=C1C(c2ccc(C(F)(F)F)c(C#N)c2)=C(C#N)c2c1cc1c(c2F)C(C#N)=C(c2ccc(C(F)(F)F)c(C(F)(F)F)c2)C1=C(C#N)C#N ; N#CC(C#N)=C1C(c2ccc(C#N)c(C(F)(F)F)c2)=C(C#N)c2c(F)c3c(c(F)c21)C(=C(C#N)C#N)C(c1ccc(C(F)(F)F)c(C(F)(F)F)c1)=C3C#N ; N#CC(C#N)=C1C(c2cc(C(F)(F)F)cc(C(F)(F)F)c2)=C(C#N)c2c1cc1c(c2C#N)C(C#N)=C(c2ccc(C#N)c(C(F)(F)F)c2)C1=C(C#N)C#N]

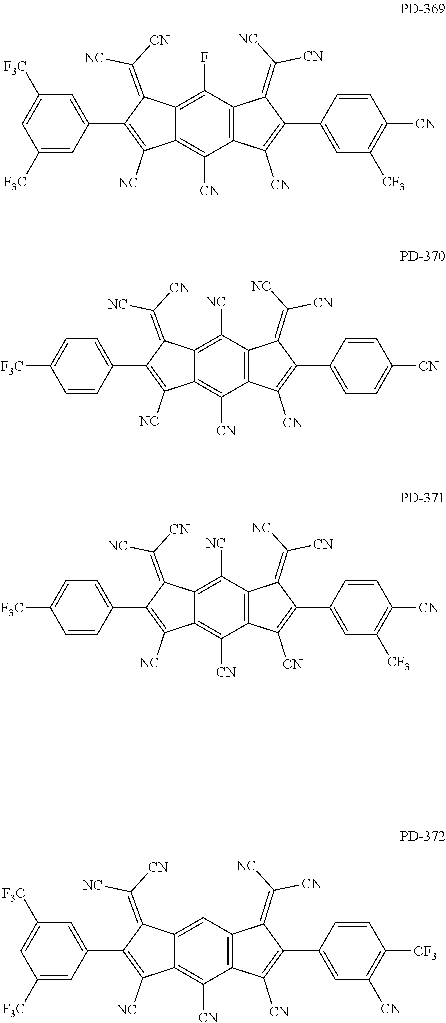 [SMILES: N#CC(C#N)=C1C(c2cc(C(F)(F)F)cc(C(F)(F)F)c2)=C(C#N)c2c(C#N)c3c(c(F)c21)C(=C(C#N)C#N)C(c1ccc(C#N)c(C(F)(F)F)c1)=C3C#N ; N#CC(C#N)=C1C(c2ccc(C#N)cc2)=C(C#N)c2c(C#N)c3c(c(C#N)c21)C(=C(C#N)C#N)C(c1ccc(C(F)(F)F)cc1)=C3C#N ; N#CC(C#N)=C1C(c2ccc(C(F)(F)F)cc2)=C(C#N)c2c(C#N)c3c(c(C#N)c21)C(=C(C#N)C#N)C(c1ccc(C#N)c(C(F)(F)F)c1)=C3C#N ; N#CC(C#N)=C1C(c2cc(C(F)(F)F)cc(C(F)(F)F)c2)=C(C#N)c2c1cc1c(c2C#N)C(C#N)=C(c2ccc(C(F)(F)F)c(C#N)c2)C1=C(C#N)C#N]

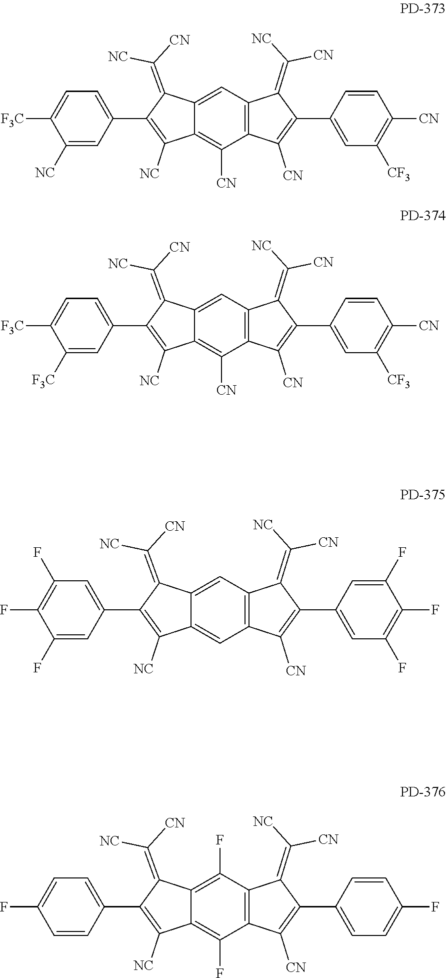 [SMILES: N#CC(C#N)=C1C(c2ccc(C(F)(F)F)c(C#N)c2)=C(C#N)c2c1cc1c(c2C#N)C(C#N)=C(c2ccc(C#N)c(C(F)(F)F)c2)C1=C(C#N)C#N ; N#CC(C#N)=C1C(c2ccc(C#N)c(C(F)(F)F)c2)=C(C#N)c2c1cc1c(c2C#N)C(C#N)=C(c2ccc(C(F)(F)F)c(C(F)(F)F)c2)C1=C(C#N)C#N ; N#CC(C#N)=C1C(c2cc(F)c(F)c(F)c2)=C(C#N)c2cc3c(cc21)C(=C(C#N)C#N)C(c1cc(F)c(F)c(F)c1)=C3C#N ; N#CC(C#N)=C1C(c2ccc(F)cc2)=C(C#N)c2c(F)c3c(c(F)c21)C(=C(C#N)C#N)C(c1ccc(F)cc1)=C3C#N]

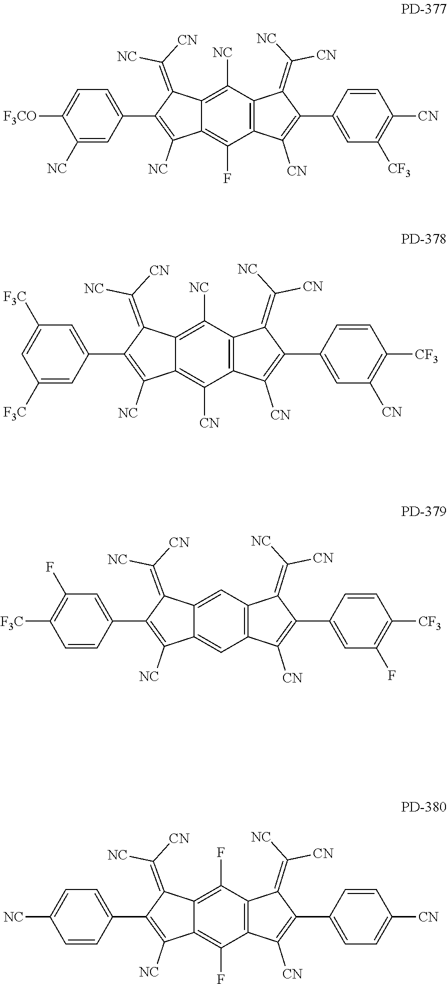 [SMILES: N#CC(C#N)=C1C(c2ccc(OC(F)(F)F)c(C#N)c2)=C(C#N)c2c(F)c3c(c(C#N)c21)C(=C(C#N)C#N)C(c1ccc(C#N)c(C(F)(F)F)c1)=C3C#N ; N#CC(C#N)=C1C(c2cc(C(F)(F)F)cc(C(F)(F)F)c2)=C(C#N)c2c(C#N)c3c(c(C#N)c21)C(=C(C#N)C#N)C(c1ccc(C(F)(F)F)c(C#N)c1)=C3C#N ; N#CC(C#N)=C1C(c2ccc(C(F)(F)F)c(F)c2)=C(C#N)c2cc3c(cc21)C(=C(C#N)C#N)C(c1ccc(C(F)(F)F)c(F)c1)=C3C#N ; N#CC(C#N)=C1C(c2ccc(C#N)cc2)=C(C#N)c2c(F)c3c(c(F)c21)C(=C(C#N)C#N)C(c1ccc(C#N)cc1)=C3C#N]

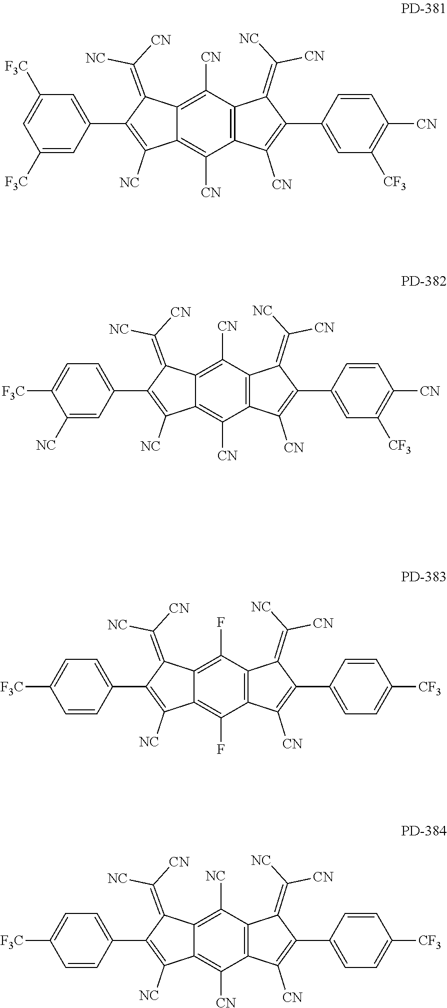 [SMILES: N#CC(C#N)=C1C(c2cc(C(F)(F)F)cc(C(F)(F)F)c2)=C(C#N)c2c(C#N)c3c(c(C#N)c21)C(=C(C#N)C#N)C(c1ccc(C#N)c(C(F)(F)F)c1)=C3C#N ; N#CC(C#N)=C1C(c2ccc(C(F)(F)F)c(C#N)c2)=C(C#N)c2c(C#N)c3c(c(C#N)c21)C(=C(C#N)C#N)C(c1ccc(C#N)c(C(F)(F)F)c1)=C3C#N ; N#CC(C#N)=C1C(c2ccc(C(F)(F)F)cc2)=C(C#N)c2c(F)c3c(c(F)c21)C(=C(C#N)C#N)C(c1ccc(C(F)(F)F)cc1)=C3C#N ; N#CC(C#N)=C1C(c2ccc(C(F)(F)F)cc2)=C(C#N)c2c(C#N)c3c(c(C#N)c21)C(=C(C#N)C#N)C(c1ccc(C(F)(F)F)cc1)=C3C#N]

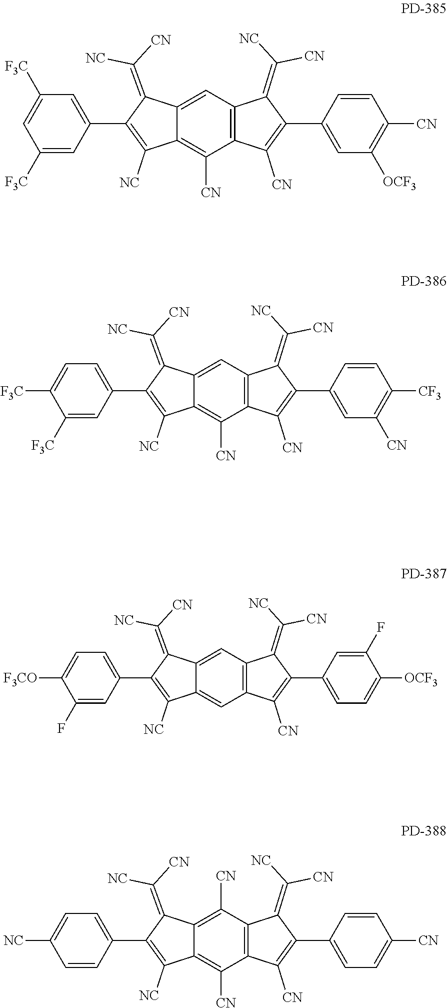 [SMILES: N#CC(C#N)=C1C(c2cc(C(F)(F)F)cc(C(F)(F)F)c2)=C(C#N)c2c1cc1c(c2C#N)C(C#N)=C(c2ccc(C#N)c(OC(F)(F)F)c2)C1=C(C#N)C#N ; N#CC(C#N)=C1C(c2ccc(C(F)(F)F)c(C#N)c2)=C(C#N)c2c1cc1c(c2C#N)C(C#N)=C(c2ccc(C(F)(F)F)c(C(F)(F)F)c2)C1=C(C#N)C#N ; N#CC(C#N)=C1C(c2ccc(OC(F)(F)F)c(F)c2)=C(C#N)c2cc3c(cc21)C(=C(C#N)C#N)C(c1ccc(OC(F)(F)F)c(F)c1)=C3C#N ; N#CC(C#N)=C1C(c2ccc(C#N)cc2)=C(C#N)c2c(C#N)c3c(c(C#N)c21)C(=C(C#N)C#N)C(c1ccc(C#N)cc1)=C3C#N]

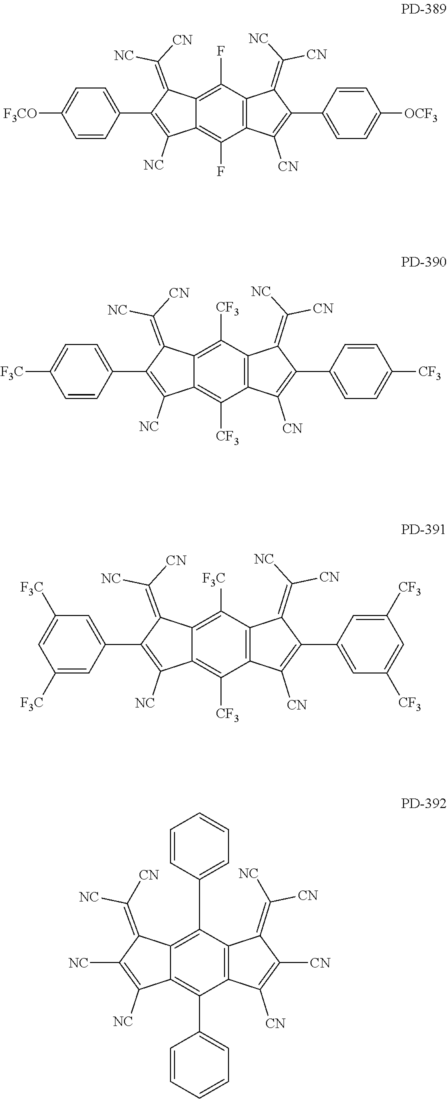 [SMILES: N#CC(C#N)=C1C(c2ccc(OC(F)(F)F)cc2)=C(C#N)c2c(F)c3c(c(F)c21)C(=C(C#N)C#N)C(c1ccc(OC(F)(F)F)cc1)=C3C#N ; N#CC(C#N)=C1C(c2ccc(C(F)(F)F)cc2)=C(C#N)c2c1c(C(F)(F)F)c1c(c2C(F)(F)F)C(C#N)=C(c2ccc(C(F)(F)F)cc2)C1=C(C#N)C#N ; N#CC(C#N)=C1C(c2cc(C(F)(F)F)cc(C(F)(F)F)c2)=C(C#N)c2c1c(C(F)(F)F)c1c(c2C(F)(F)F)C(C#N)=C(c2cc(C(F)(F)F)cc(C(F)(F)F)c2)C1=C(C#N)C#N ; N#CC(C#N)=C1C(C#N)=C(C#N)c2c1c(-c1ccccc1)c1c(c2-c2ccccc2)C(C#N)=C(C#N)C1=C(C#N)C#N]

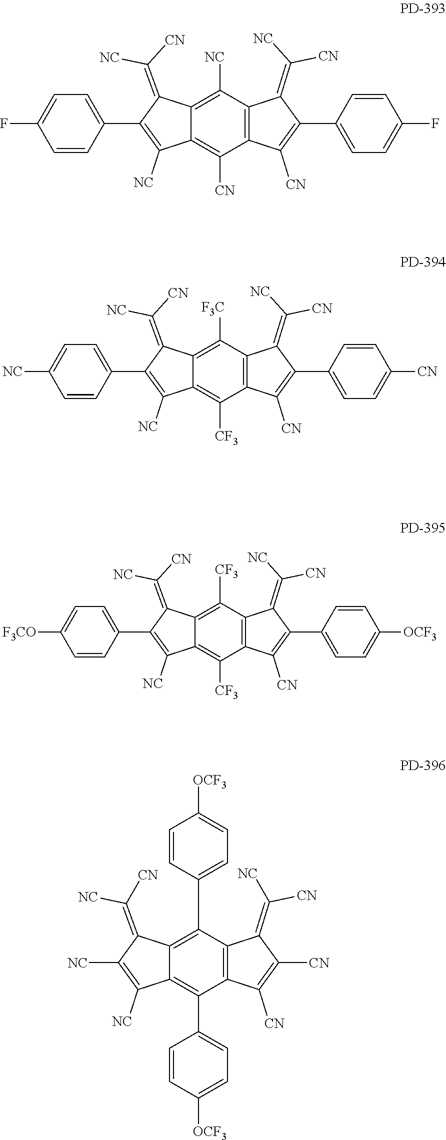 [SMILES: N#CC(C#N)=C1C(c2ccc(F)cc2)=C(C#N)c2c(C#N)c3c(c(C#N)c21)C(=C(C#N)C#N)C(c1ccc(F)cc1)=C3C#N ; N#CC(C#N)=C1C(c2ccc(C#N)cc2)=C(C#N)c2c1c(C(F)(F)F)c1c(c2C(F)(F)F)C(C#N)=C(c2ccc(C#N)cc2)C1=C(C#N)C#N ; N#CC(C#N)=C1C(c2ccc(OC(F)(F)F)cc2)=C(C#N)c2c1c(C(F)(F)F)c1c(c2C(F)(F)F)C(C#N)=C(c2ccc(OC(F)(F)F)cc2)C1=C(C#N)C#N ; N#CC(C#N)=C1C(C#N)=C(C#N)c2c1c(-c1ccc(OC(F)(F)F)cc1)c1c(c2-c2ccc(OC(F)(F)F)cc2)C(C#N)=C(C#N)C1=C(C#N)C#N]

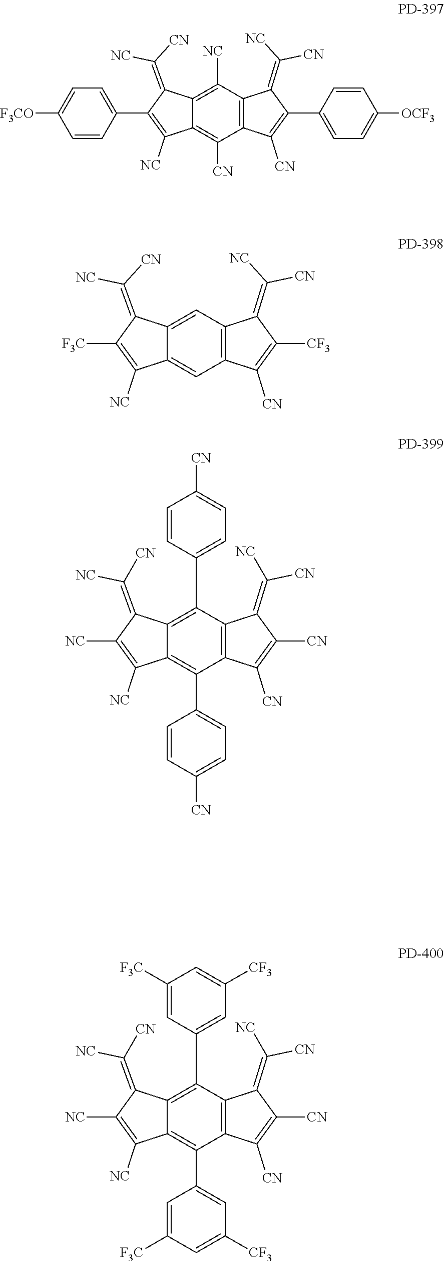 [SMILES: N#CC(C#N)=C1C(c2ccc(OC(F)(F)F)cc2)=C(C#N)c2c(C#N)c3c(c(C#N)c21)C(=C(C#N)C#N)C(c1ccc(OC(F)(F)F)cc1)=C3C#N ; N#CC(C#N)=C1C(C(F)(F)F)=C(C#N)c2cc3c(cc21)C(=C(C#N)C#N)C(C(F)(F)F)=C3C#N ; N#CC(C#N)=C1C(C#N)=C(C#N)c2c1c(-c1ccc(C#N)cc1)c1c(c2-c2ccc(C#N)cc2)C(C#N)=C(C#N)C1=C(C#N)C#N ; N#CC(C#N)=C1C(C#N)=C(C#N)c2c1c(-c1cc(C(F)(F)F)cc(C(F)(F)F)c1)c1c(c2-c2cc(C(F)(F)F)cc(C(F)(F)F)c2)C(C#N)=C(C#N)C1=C(C#N)C#N]

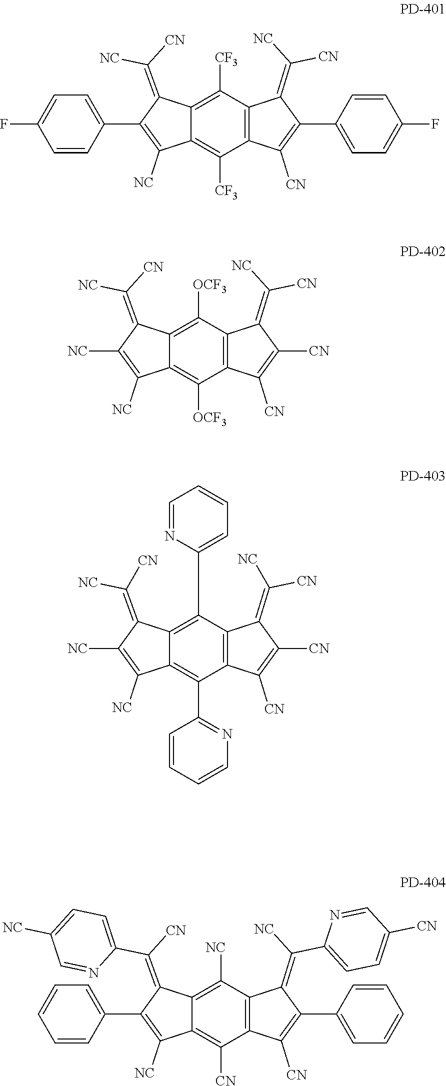 [SMILES: N#CC(C#N)=C1C(c2ccc(F)cc2)=C(C#N)c2c1c(C(F)(F)F)c1c(c2C(F)(F)F)C(C#N)=C(c2ccc(F)cc2)C1=C(C#N)C#N ; N#CC(C#N)=C1C(C#N)=C(C#N)c2c(OC(F)(F)F)c3c(c(OC(F)(F)F)c21)C(=C(C#N)C#N)C(C#N)=C3C#N ; N#CC(C#N)=C1C(C#N)=C(C#N)c2c1c(-c1ccccn1)c1c(c2-c2ccccn2)C(C#N)=C(C#N)C1=C(C#N)C#N ; N#CC1=C(c2ccccc2)/C(=C(/C#N)c2ccc(C#N)cn2)c2c(C#N)c3c(c(C#N)c21)C(C#N)=C(c1ccccc1)/C3=C(/C#N)c1ccc(C#N)cn1]

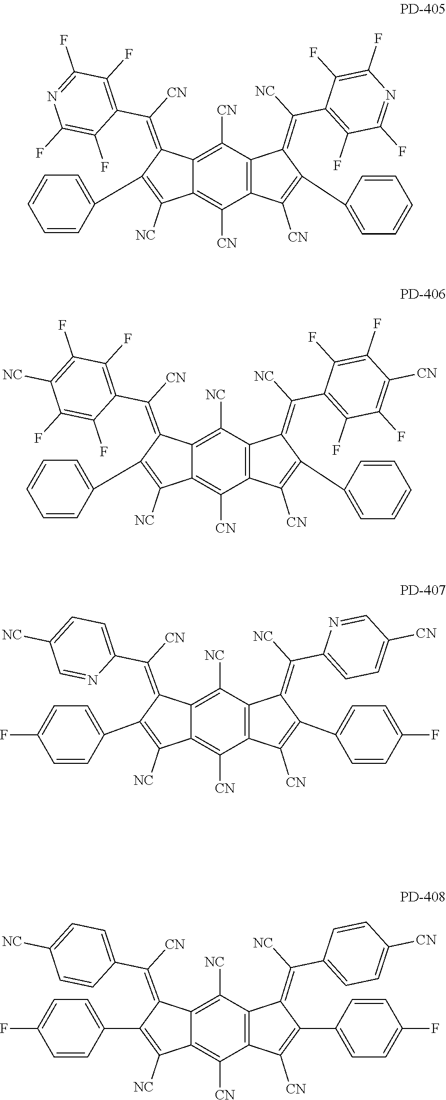 [SMILES: N#CC1=C(c2ccccc2)/C(=C(/C#N)c2c(F)c(F)nc(F)c2F)c2c(C#N)c3c(c(C#N)c21)C(C#N)=C(c1ccccc1)/C3=C(/C#N)c1c(F)c(F)nc(F)c1F ; N#CC1=C(c2ccccc2)/C(=C(/C#N)c2c(F)c(F)c(C#N)c(F)c2F)c2c(C#N)c3c(c(C#N)c21)C(C#N)=C(c1ccccc1)/C3=C(/C#N)c1c(F)c(F)c(C#N)c(F)c1F ; N#CC1=C(c2ccc(F)cc2)/C(=C(/C#N)c2ccc(C#N)cn2)c2c(C#N)c3c(c(C#N)c21)C(C#N)=C(c1ccc(F)cc1)/C3=C(/C#N)c1ccc(C#N)cn1 ; N#CC1=C(c2ccc(F)cc2)/C(=C(/C#N)c2ccc(C#N)cc2)c2c(C#N)c3c(c(C#N)c21)C(C#N)=C(c1ccc(F)cc1)/C3=C(/C#N)c1ccc(C#N)cc1]

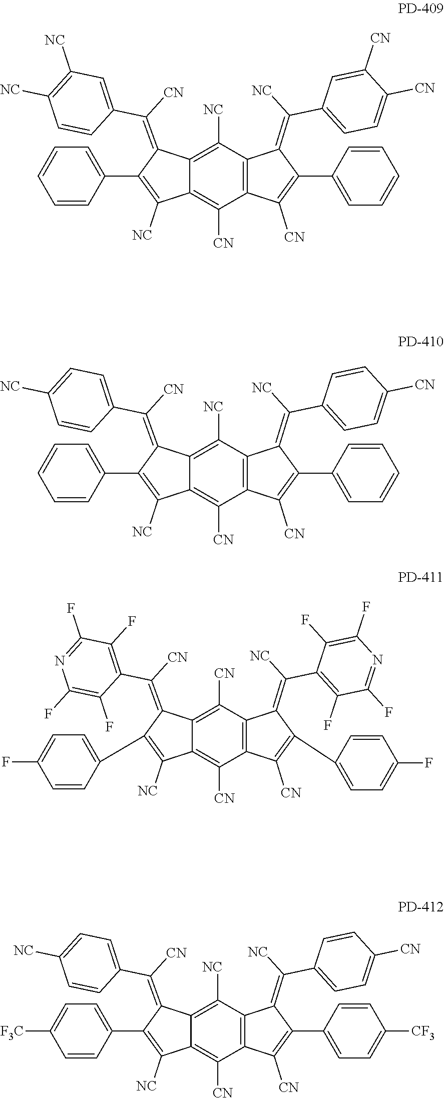 [SMILES: N#CC1=C(c2ccccc2)/C(=C(/C#N)c2ccc(C#N)c(C#N)c2)c2c(C#N)c3c(c(C#N)c21)C(C#N)=C(c1ccccc1)/C3=C(/C#N)c1ccc(C#N)c(C#N)c1 ; N#CC1=C(c2ccccc2)/C(=C(/C#N)c2ccc(C#N)cc2)c2c(C#N)c3c(c(C#N)c21)C(C#N)=C(c1ccccc1)/C3=C(/C#N)c1ccc(C#N)cc1 ; N#CC1=C(c2ccc(F)cc2)/C(=C(/C#N)c2c(F)c(F)nc(F)c2F)c2c(C#N)c3c(c(C#N)c21)C(C#N)=C(c1ccc(F)cc1)/C3=C(/C#N)c1c(F)c(F)nc(F)c1F ; N#CC1=C(c2ccc(C(F)(F)F)cc2)/C(=C(/C#N)c2ccc(C#N)cc2)c2c(C#N)c3c(c(C#N)c21)C(C#N)=C(c1ccc(C(F)(F)F)cc1)/C3=C(/C#N)c1ccc(C#N)cc1]

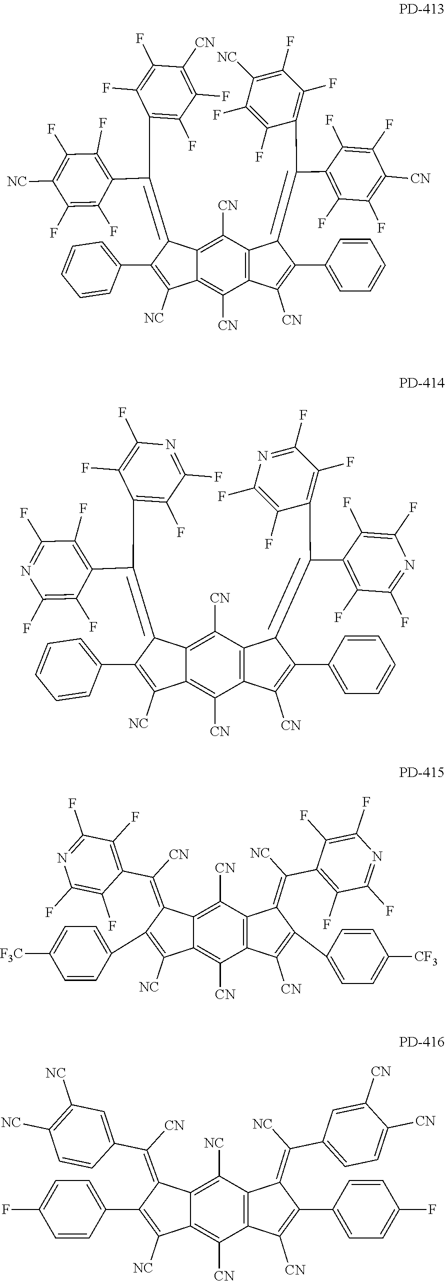

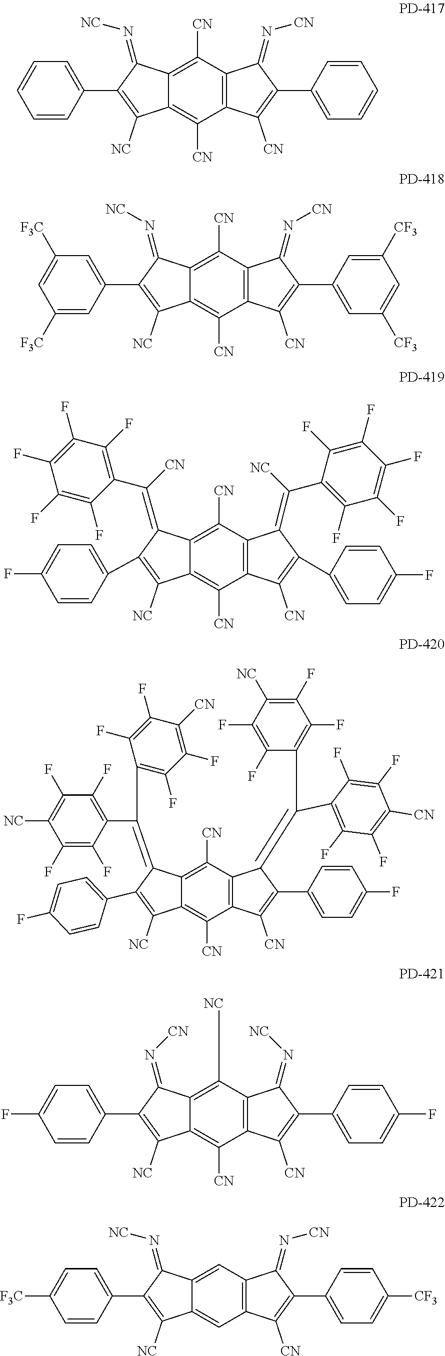

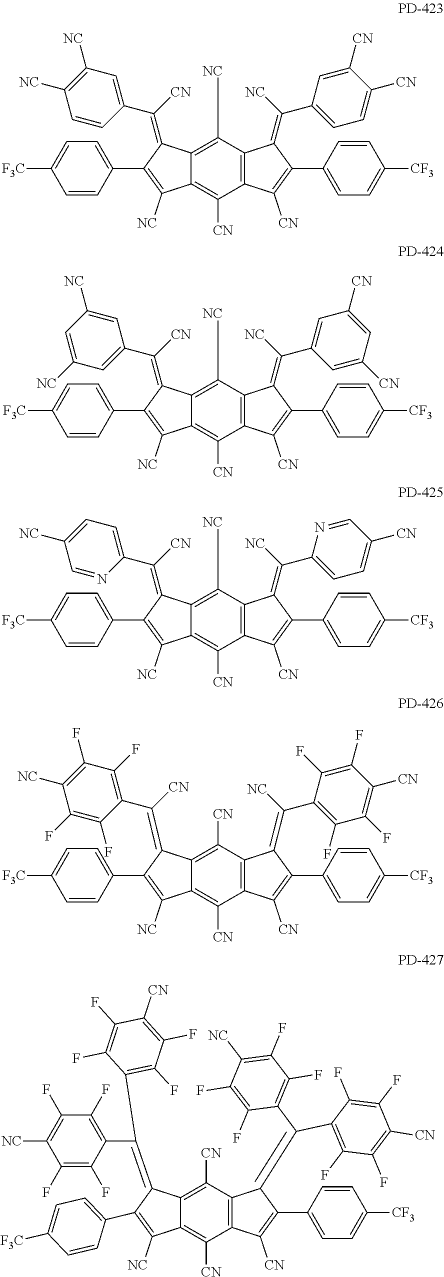

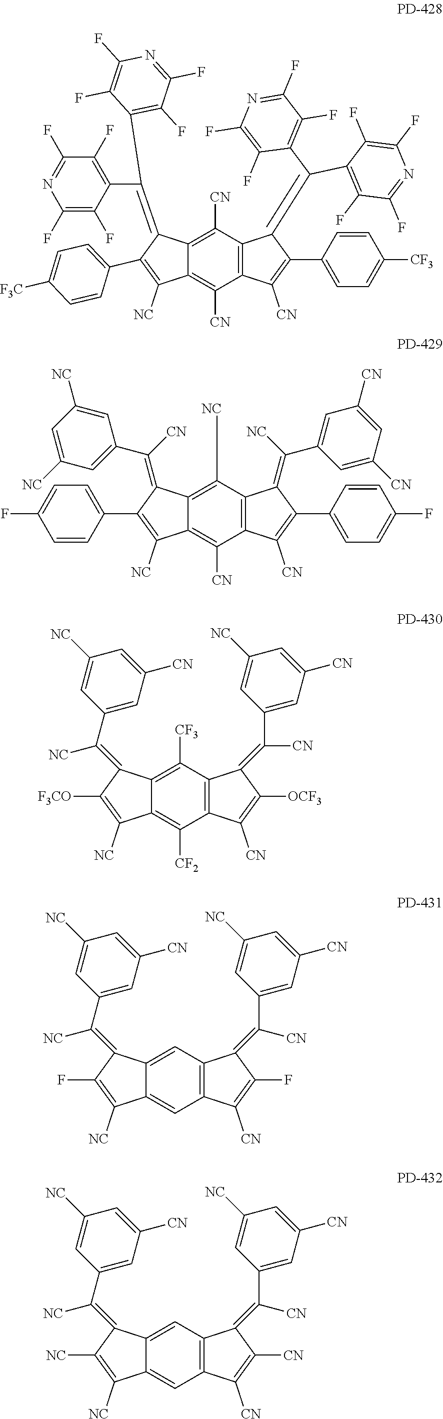

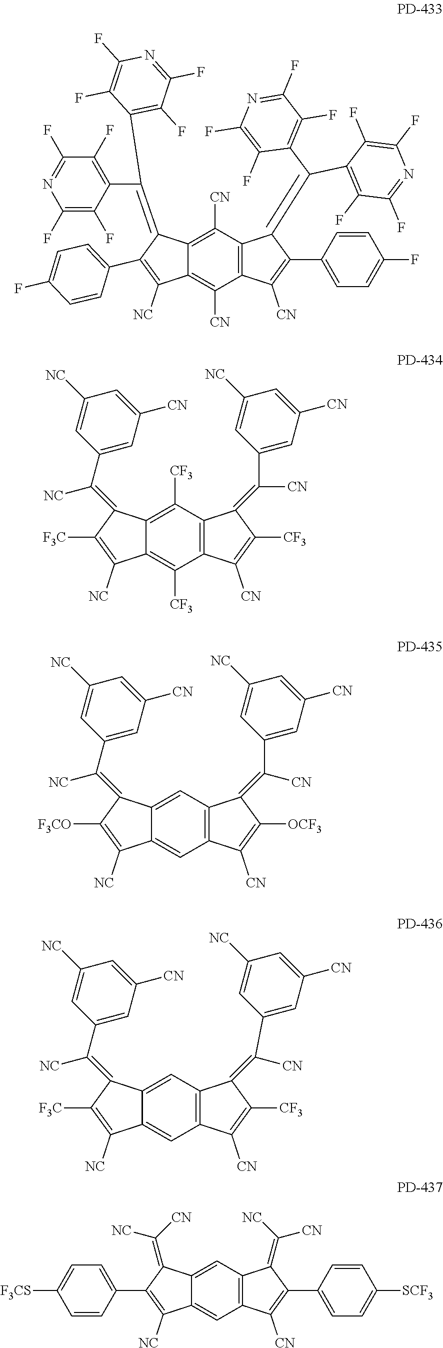

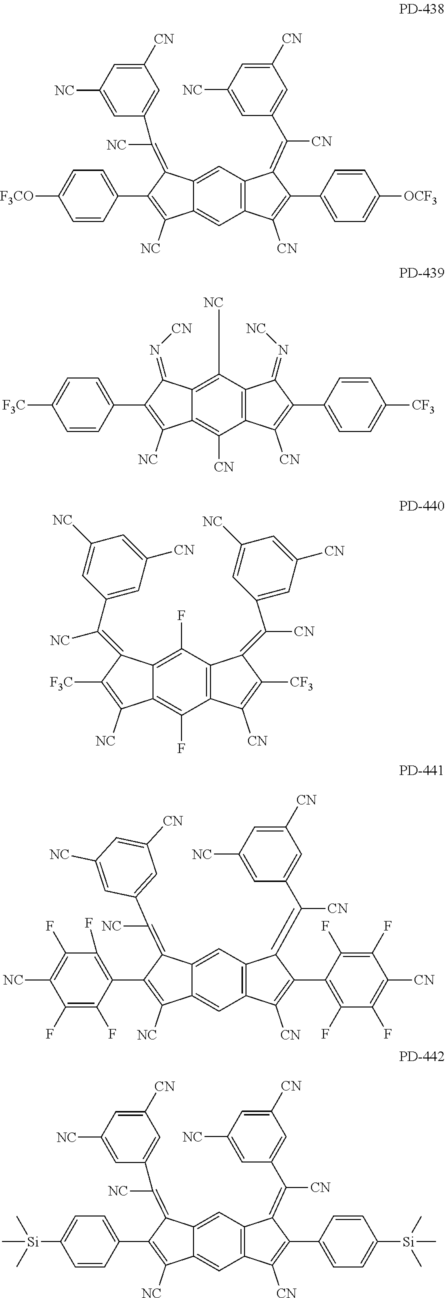

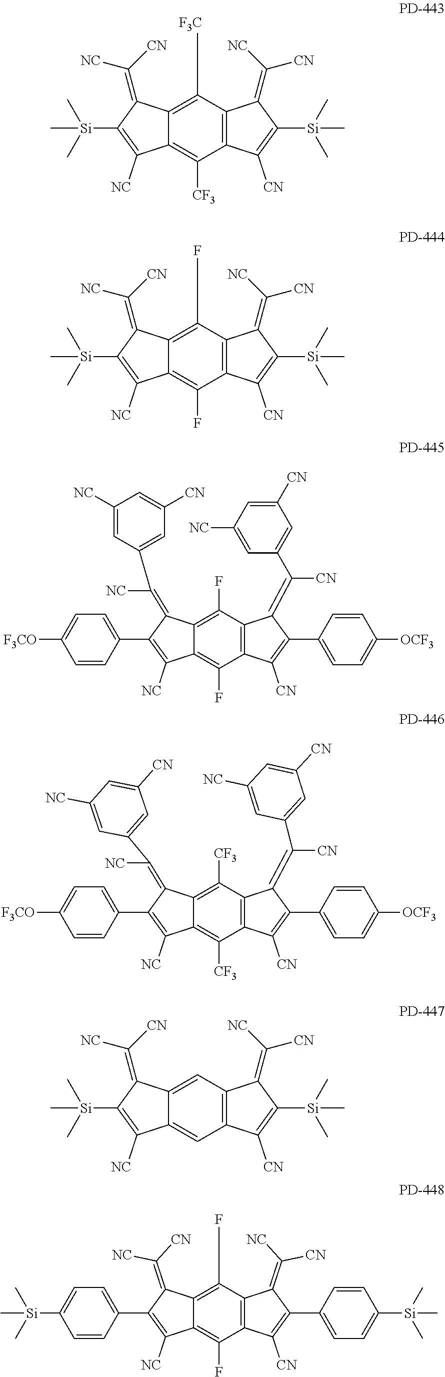

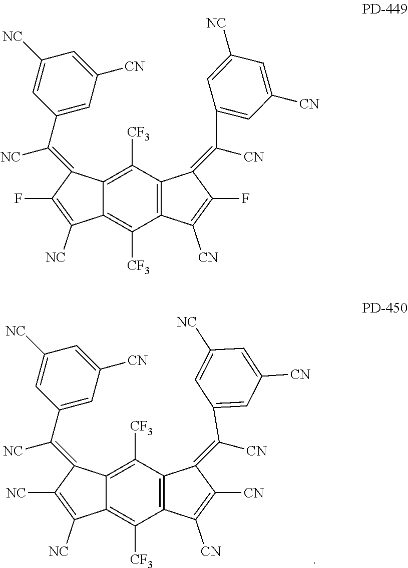 [SMILES: N#CC1=C(F)/C(=C(\C#N)c2cc(C#N)cc(C#N)c2)c2c1c(C(F)(F)F)c1c(c2C(F)(F)F)/C(=C(/C#N)c2cc(C#N)cc(C#N)c2)C(F)=C1C#N ; N#CC1=C(C#N)c2c(c(C(F)(F)F)c3c(c2C(F)(F)F)C(C#N)=C(C#N)/C3=C(\C#N)c2cc(C#N)cc(C#N)c2)/C1=C(/C#N)c1cc(C#N)cc(C#N)c1]

12. The organic light-emitting device of claim 8, wherein a structure of the second compound represented by the Chemical Formula 3 is selected from a group consisting of the following Compounds PH-1 to PH-315:

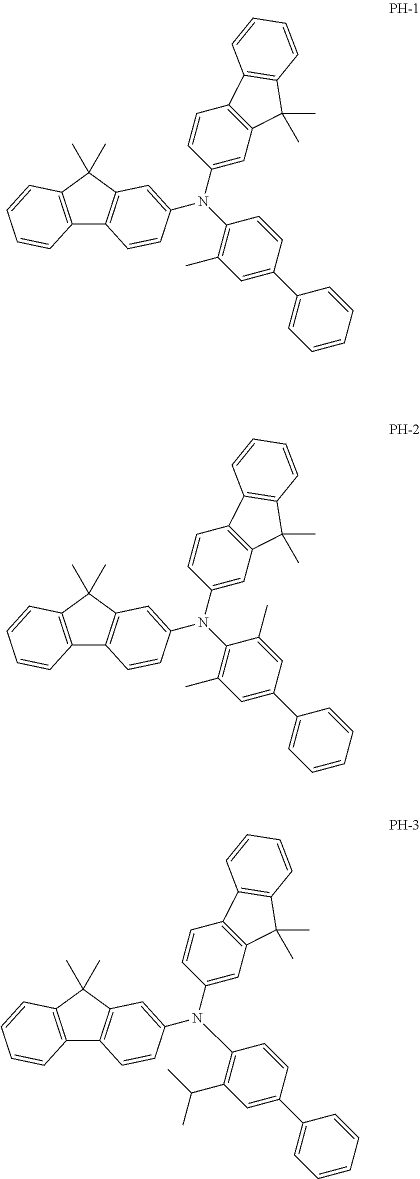 [SMILES: Cc1cc(-c2ccccc2)ccc1N(c1ccc2c(c1)C(C)(C)c1ccccc1-2)c1ccc2c(c1)C(C)(C)c1ccccc1-2 ; Cc1cc(-c2ccccc2)cc(C)c1N(c1ccc2c(c1)C(C)(C)c1ccccc1-2)c1ccc2c(c1)C(C)(C)c1ccccc1-2 ; CC(C)c1cc(-c2ccccc2)ccc1N(c1ccc2c(c1)C(C)(C)c1ccccc1-2)c1ccc2c(c1)C(C)(C)c1ccccc1-2]

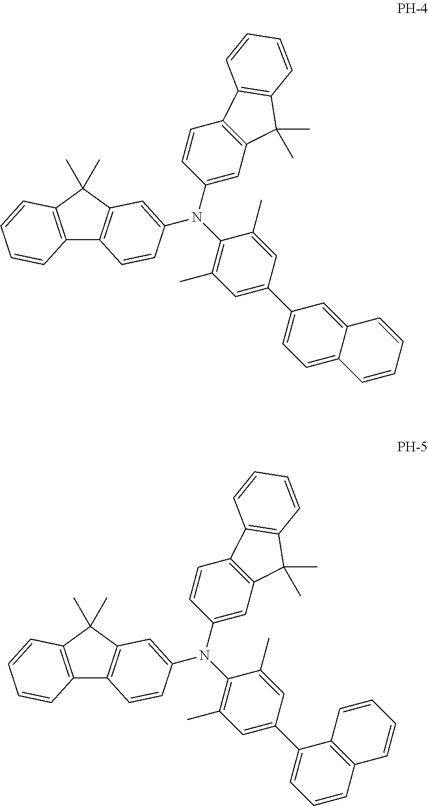 [SMILES: Cc1cc(-c2ccc3ccccc3c2)cc(C)c1N(c1ccc2c(c1)C(C)(C)c1ccccc1-2)c1ccc2c(c1)C(C)(C)c1ccccc1-2 ; Cc1cc(-c2cccc3ccccc23)cc(C)c1N(c1ccc2c(c1)C(C)(C)c1ccccc1-2)c1ccc2c(c1)C(C)(C)c1ccccc1-2]

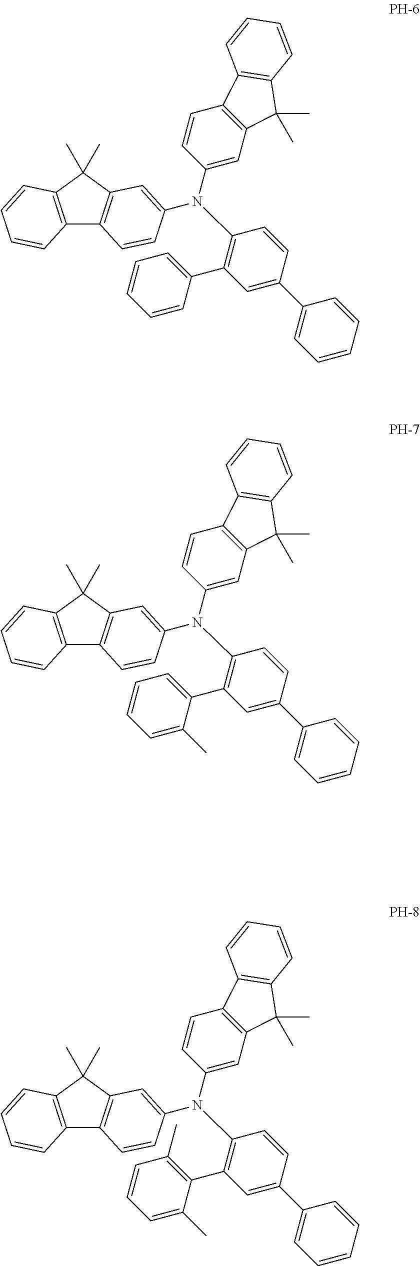 [SMILES: CC1(C)c2ccccc2-c2ccc(N(c3ccc4c(c3)C(C)(C)c3ccccc3-4)c3ccc(-c4ccccc4)cc3-c3ccccc3)cc21 ; Cc1ccccc1-c1cc(-c2ccccc2)ccc1N(c1ccc2c(c1)C(C)(C)c1ccccc1-2)c1ccc2c(c1)C(C)(C)c1ccccc1-2 ; Cc1cccc(C)c1-c1cc(-c2ccccc2)ccc1N(c1ccc2c(c1)C(C)(C)c1ccccc1-2)c1ccc2c(c1)C(C)(C)c1ccccc1-2]

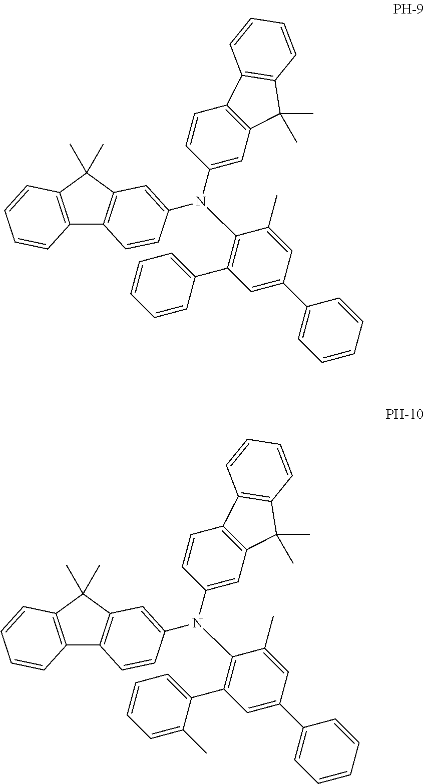 [SMILES: Cc1cc(-c2ccccc2)cc(-c2ccccc2)c1N(c1ccc2c(c1)C(C)(C)c1ccccc1-2)c1ccc2c(c1)C(C)(C)c1ccccc1-2 ; Cc1ccccc1-c1cc(-c2ccccc2)cc(C)c1N(c1ccc2c(c1)C(C)(C)c1ccccc1-2)c1ccc2c(c1)C(C)(C)c1ccccc1-2]

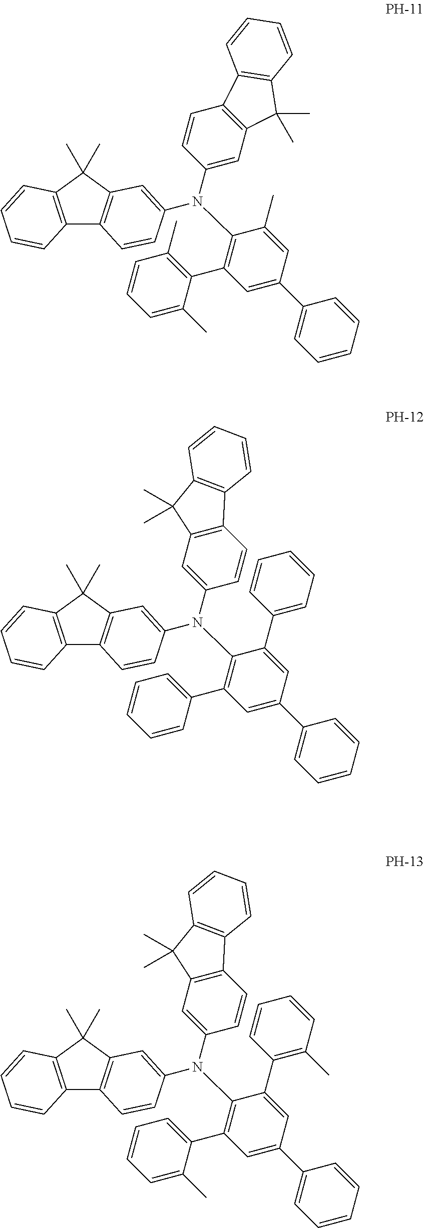 [SMILES: Cc1cccc(C)c1-c1cc(-c2ccccc2)cc(C)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3ccccc3)cc21 ; Cc1ccccc1-c1cc(-c2ccccc2)cc(-c2ccccc2C)c1N(c1ccc2c(c1)C(C)(C)c1ccccc1-2)c1ccc2c(c1)C(C)(C)c1ccccc1-2]

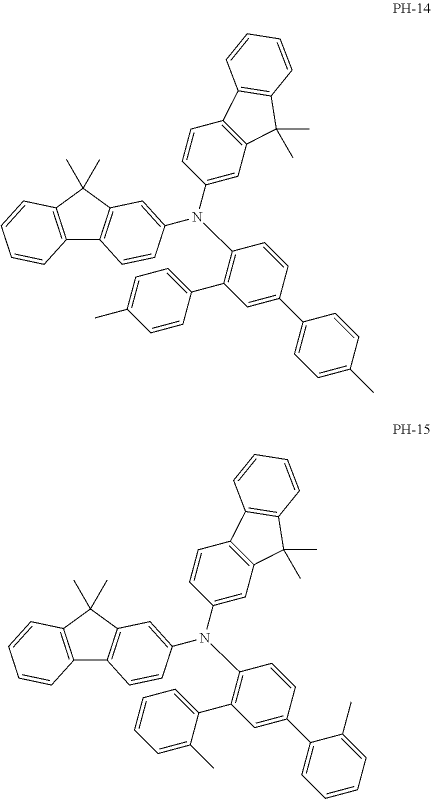 [SMILES: Cc1ccc(-c2ccc(N(c3ccc4c(c3)C(C)(C)c3ccccc3-4)c3ccc4c(c3)C(C)(C)c3ccccc3-4)c(-c3ccc(C)cc3)c2)cc1 ; Cc1ccccc1-c1ccc(N(c2ccc3c(c2)C(C)(C)c2ccccc2-3)c2ccc3c(c2)C(C)(C)c2ccccc2-3)c(-c2ccccc2C)c1]

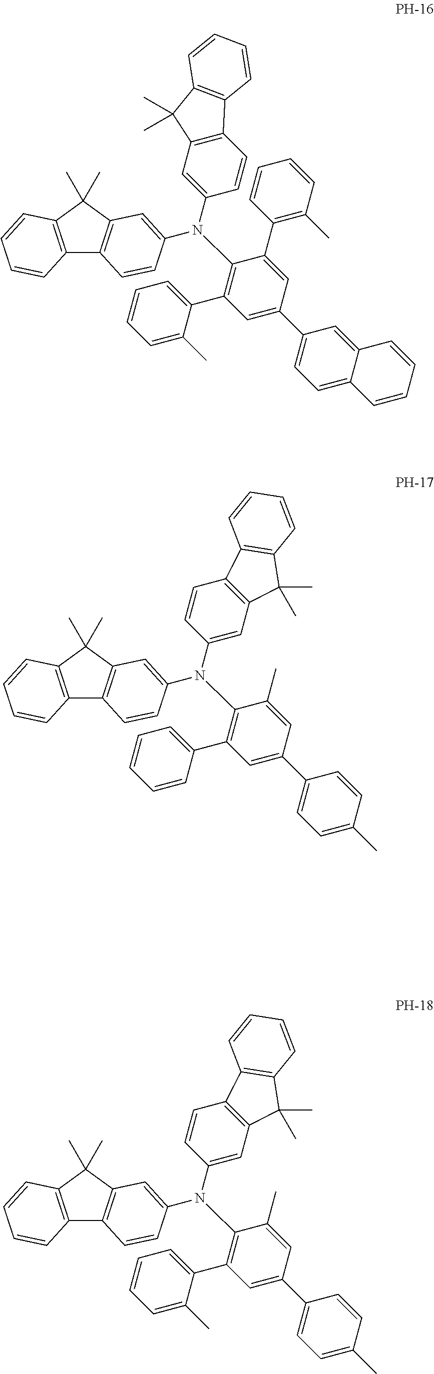 [SMILES: Cc1ccccc1-c1cc(-c2ccc3ccccc3c2)cc(-c2ccccc2C)c1N(c1ccc2c(c1)C(C)(C)c1ccccc1-2)c1ccc2c(c1)C(C)(C)c1ccccc1-2 ; Cc1ccc(-c2cc(C)c(N(c3ccc4c(c3)C(C)(C)c3ccccc3-4)c3ccc4c(c3)C(C)(C)c3ccccc3-4)c(-c3ccccc3)c2)cc1 ; Cc1ccc(-c2cc(C)c(N(c3ccc4c(c3)C(C)(C)c3ccccc3-4)c3ccc4c(c3)C(C)(C)c3ccccc3-4)c(-c3ccccc3C)c2)cc1]

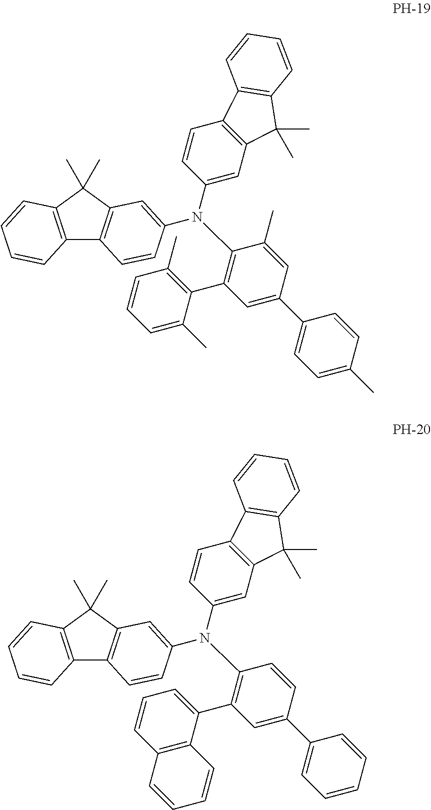 [SMILES: Cc1ccc(-c2cc(C)c(N(c3ccc4c(c3)C(C)(C)c3ccccc3-4)c3ccc4c(c3)C(C)(C)c3ccccc3-4)c(-c3c(C)cccc3C)c2)cc1 ; CC1(C)c2ccccc2-c2ccc(N(c3ccc4c(c3)C(C)(C)c3ccccc3-4)c3ccc(-c4ccccc4)cc3-c3cccc4ccccc34)cc21]

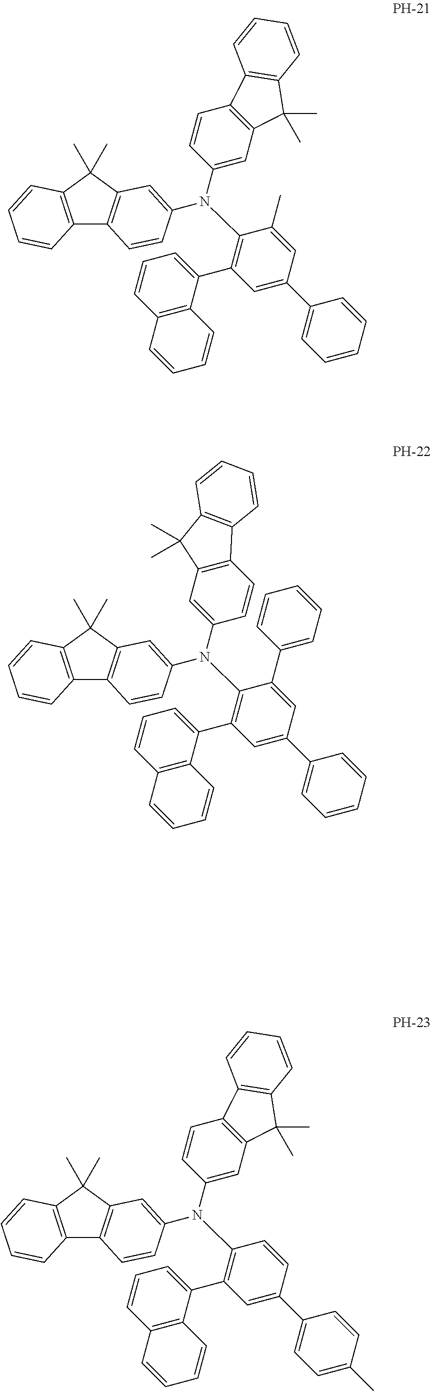 [SMILES: Cc1cc(-c2ccccc2)cc(-c2cccc3ccccc23)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3cccc4ccccc34)cc21 ; Cc1ccc(-c2ccc(N(c3ccc4c(c3)C(C)(C)c3ccccc3-4)c3ccc4c(c3)C(C)(C)c3ccccc3-4)c(-c3cccc4ccccc34)c2)cc1]

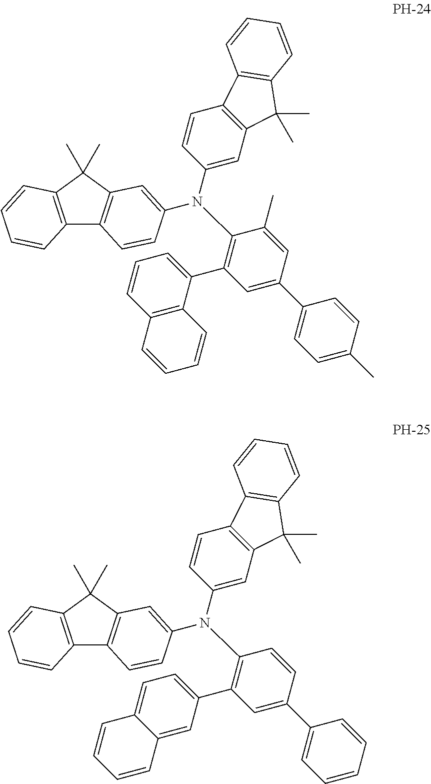 [SMILES: Cc1ccc(-c2cc(C)c(N(c3ccc4c(c3)C(C)(C)c3ccccc3-4)c3ccc4c(c3)C(C)(C)c3ccccc3-4)c(-c3cccc4ccccc34)c2)cc1 ; CC1(C)c2ccccc2-c2ccc(N(c3ccc4c(c3)C(C)(C)c3ccccc3-4)c3ccc(-c4ccccc4)cc3-c3ccc4ccccc4c3)cc21]

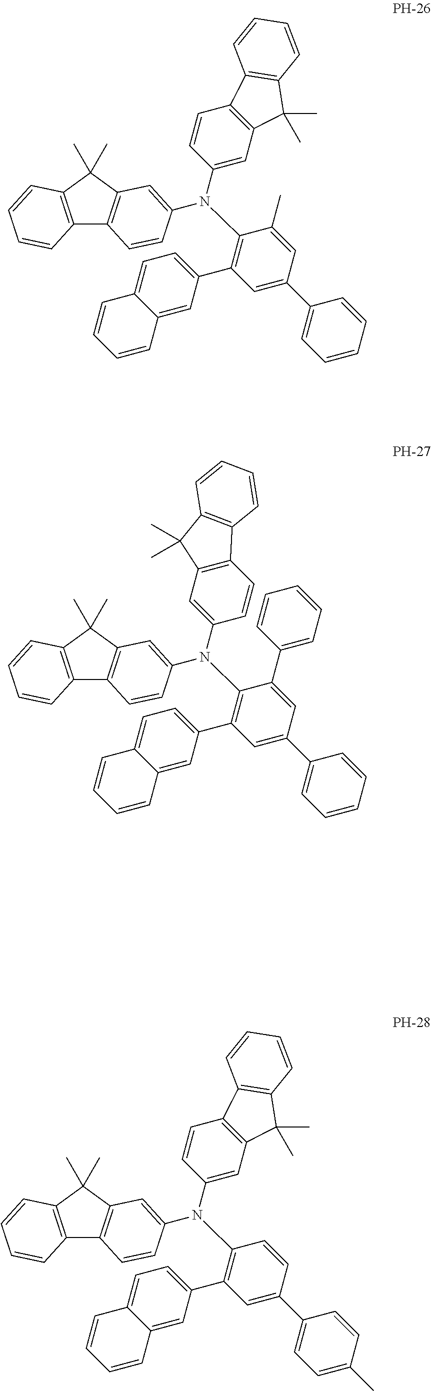 [SMILES: Cc1cc(-c2ccccc2)cc(-c2ccc3ccccc3c2)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccccc4)cc3-c3ccc4ccccc4c3)cc21 ; Cc1ccc(-c2ccc(N(c3ccc4c(c3)C(C)(C)c3ccccc3-4)c3ccc4c(c3)C(C)(C)c3ccccc3-4)c(-c3ccc4ccccc4c3)c2)cc1]

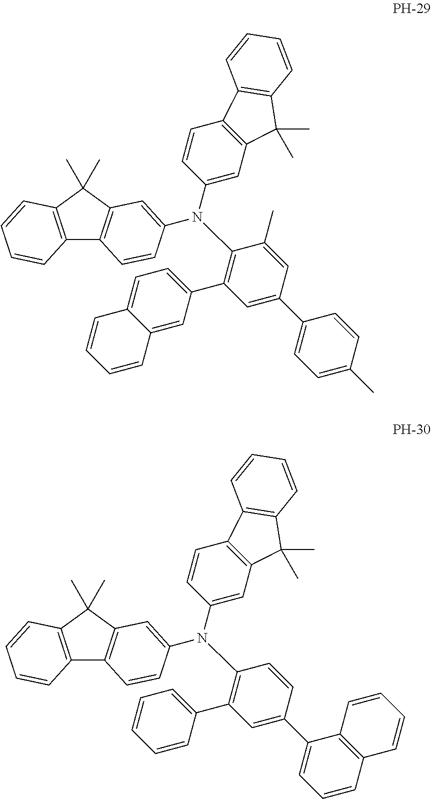 [SMILES: Cc1ccc(-c2cc(C)c(N(c3ccc4c(c3)C(C)(C)c3ccccc3-4)c3ccc4c(c3)C(C)(C)c3ccccc3-4)c(-c3ccc4ccccc4c3)c2)cc1 ; CC1(C)c2ccccc2-c2ccc(N(c3ccc4c(c3)C(C)(C)c3ccccc3-4)c3ccc(-c4cccc5ccccc45)cc3-c3ccccc3)cc21]

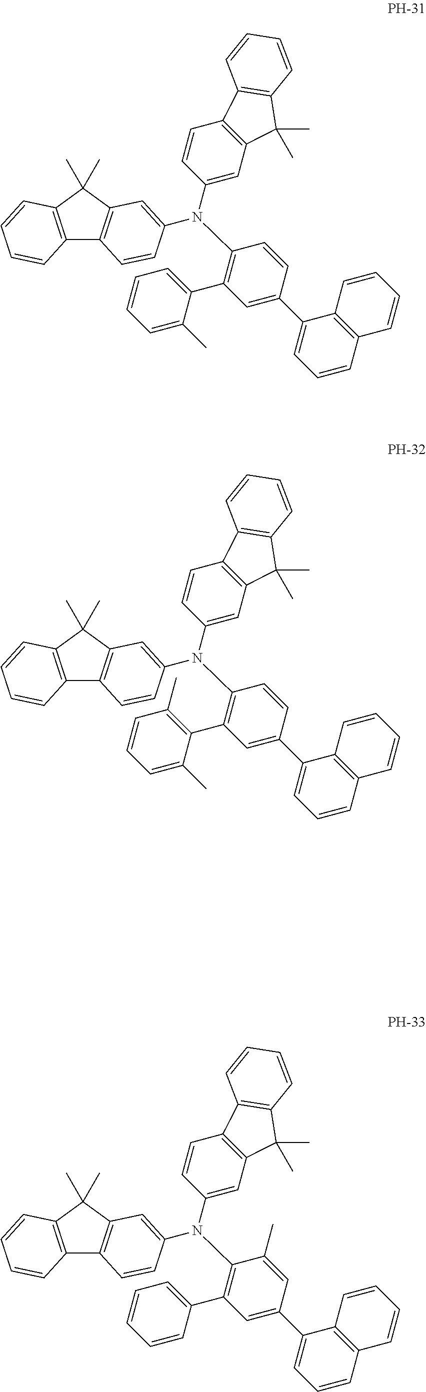 [SMILES: Cc1ccccc1-c1cc(-c2cccc3ccccc23)ccc1N(c1ccc2c(c1)C(C)(C)c1ccccc1-2)c1ccc2c(c1)C(C)(C)c1ccccc1-2 ; Cc1cccc(C)c1-c1cc(-c2cccc3ccccc23)ccc1N(c1ccc2c(c1)C(C)(C)c1ccccc1-2)c1ccc2c(c1)C(C)(C)c1ccccc1-2 ; Cc1cc(-c2cccc3ccccc23)cc(-c2ccccc2)c1N(c1ccc2c(c1)C(C)(C)c1ccccc1-2)c1ccc2c(c1)C(C)(C)c1ccccc1-2]

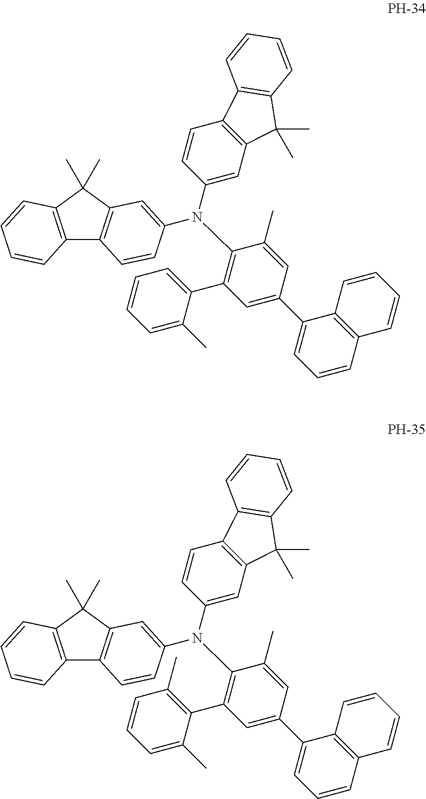 [SMILES: Cc1ccccc1-c1cc(-c2cccc3ccccc23)cc(C)c1N(c1ccc2c(c1)C(C)(C)c1ccccc1-2)c1ccc2c(c1)C(C)(C)c1ccccc1-2 ; Cc1cccc(C)c1-c1cc(-c2cccc3ccccc23)cc(C)c1N(c1ccc2c(c1)C(C)(C)c1ccccc1-2)c1ccc2c(c1)C(C)(C)c1ccccc1-2]

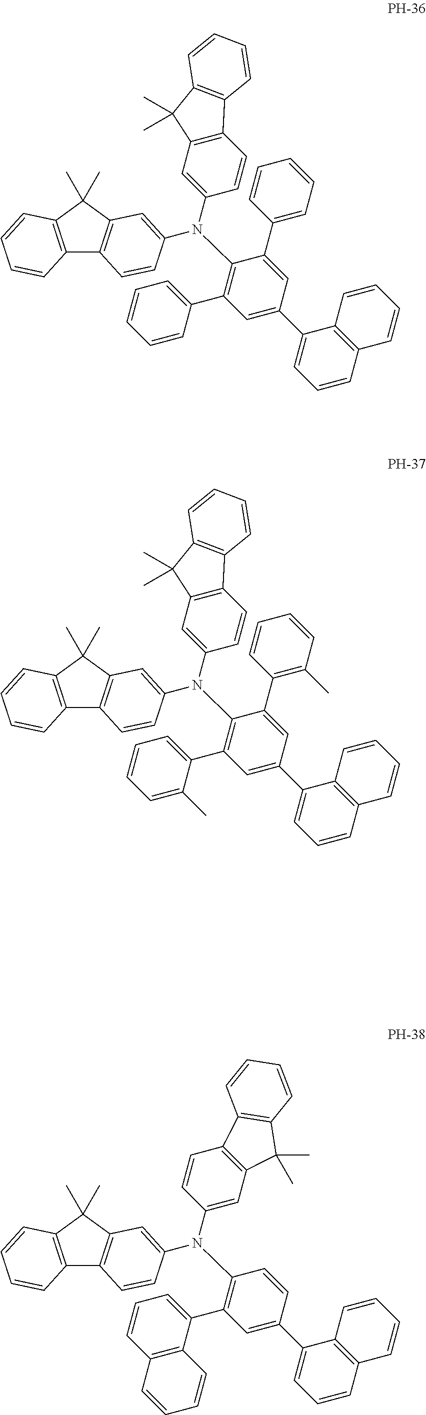 [SMILES: CC1(C)c2ccccc2-c2ccc(N(c3ccc4c(c3)C(C)(C)c3ccccc3-4)c3c(-c4ccccc4)cc(-c4cccc5ccccc45)cc3-c3ccccc3)cc21 ; Cc1ccccc1-c1cc(-c2cccc3ccccc23)cc(-c2ccccc2C)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3ccc(-c4cccc5ccccc45)cc3-c3cccc4ccccc34)cc21]

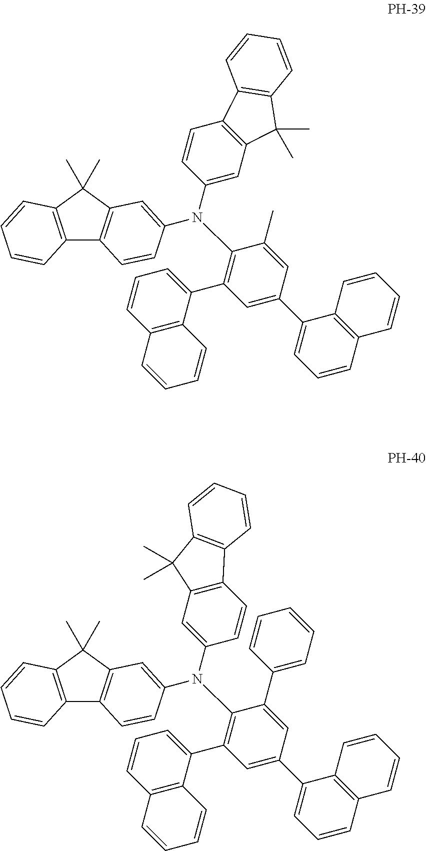 [SMILES: Cc1cc(-c2cccc3ccccc23)cc(-c2cccc3ccccc23)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4cccc5ccccc45)cc3-c3cccc4ccccc34)cc21]

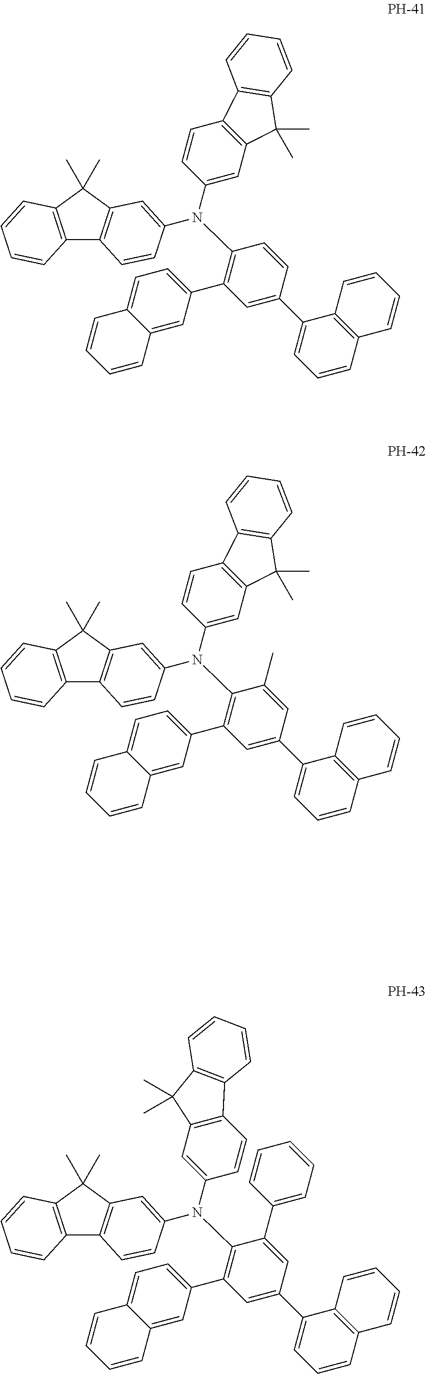 [SMILES: CC1(C)c2ccccc2-c2ccc(N(c3ccc4c(c3)C(C)(C)c3ccccc3-4)c3ccc(-c4cccc5ccccc45)cc3-c3ccc4ccccc4c3)cc21 ; Cc1cc(-c2cccc3ccccc23)cc(-c2ccc3ccccc3c2)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4cccc5ccccc45)cc3-c3ccc4ccccc4c3)cc21]

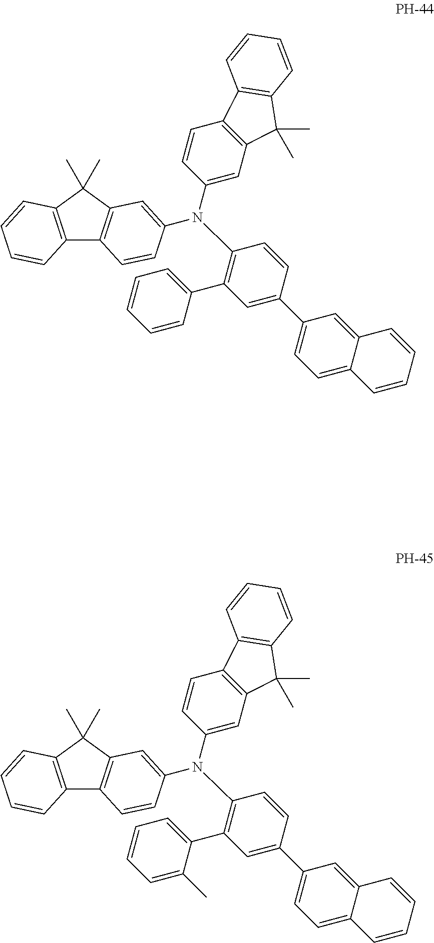 [SMILES: CC1(C)c2ccccc2-c2ccc(N(c3ccc4c(c3)C(C)(C)c3ccccc3-4)c3ccc(-c4ccc5ccccc5c4)cc3-c3ccccc3)cc21 ; Cc1ccccc1-c1cc(-c2ccc3ccccc3c2)ccc1N(c1ccc2c(c1)C(C)(C)c1ccccc1-2)c1ccc2c(c1)C(C)(C)c1ccccc1-2]

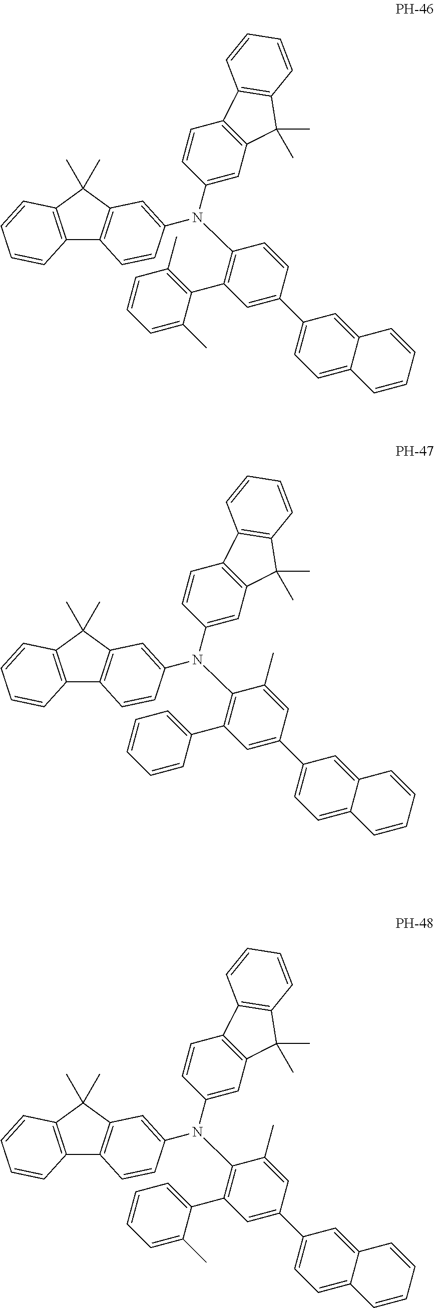 [SMILES: Cc1cccc(C)c1-c1cc(-c2ccc3ccccc3c2)ccc1N(c1ccc2c(c1)C(C)(C)c1ccccc1-2)c1ccc2c(c1)C(C)(C)c1ccccc1-2 ; Cc1cc(-c2ccc3ccccc3c2)cc(-c2ccccc2)c1N(c1ccc2c(c1)C(C)(C)c1ccccc1-2)c1ccc2c(c1)C(C)(C)c1ccccc1-2 ; Cc1ccccc1-c1cc(-c2ccc3ccccc3c2)cc(C)c1N(c1ccc2c(c1)C(C)(C)c1ccccc1-2)c1ccc2c(c1)C(C)(C)c1ccccc1-2]

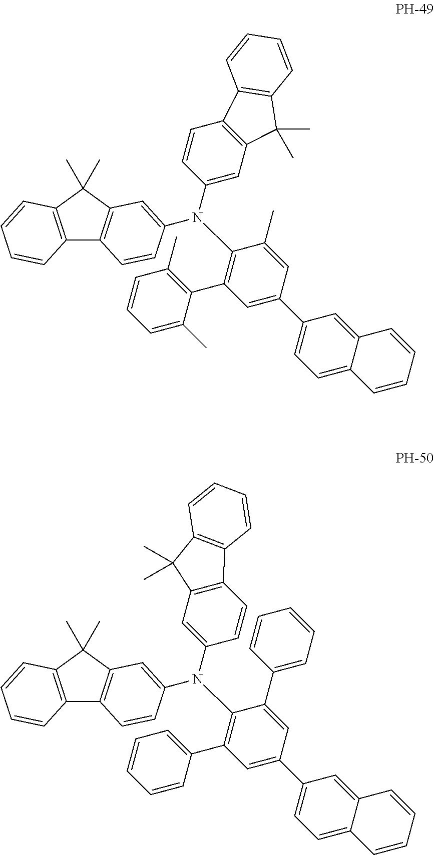 [SMILES: Cc1cccc(C)c1-c1cc(-c2ccc3ccccc3c2)cc(C)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccc5ccccc5c4)cc3-c3ccccc3)cc21]

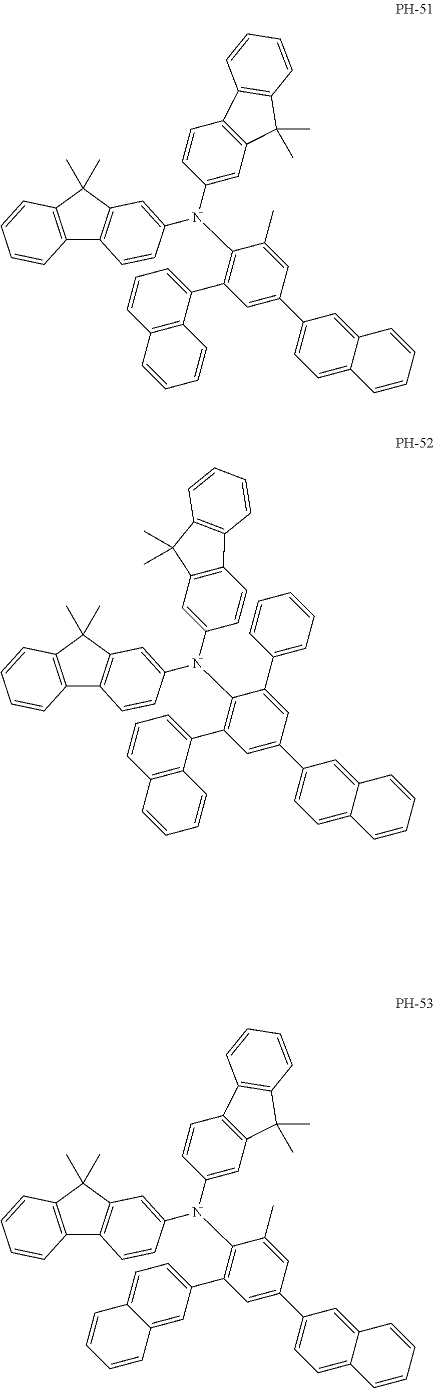 [SMILES: Cc1cc(-c2ccc3ccccc3c2)cc(-c2cccc3ccccc23)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3c(-c4ccccc4)cc(-c4ccc5ccccc5c4)cc3-c3cccc4ccccc34)cc21 ; Cc1cc(-c2ccc3ccccc3c2)cc(-c2ccc3ccccc3c2)c1N(c1ccc2c(c1)C(C)(C)c1ccccc1-2)c1ccc2c(c1)C(C)(C)c1ccccc1-2]

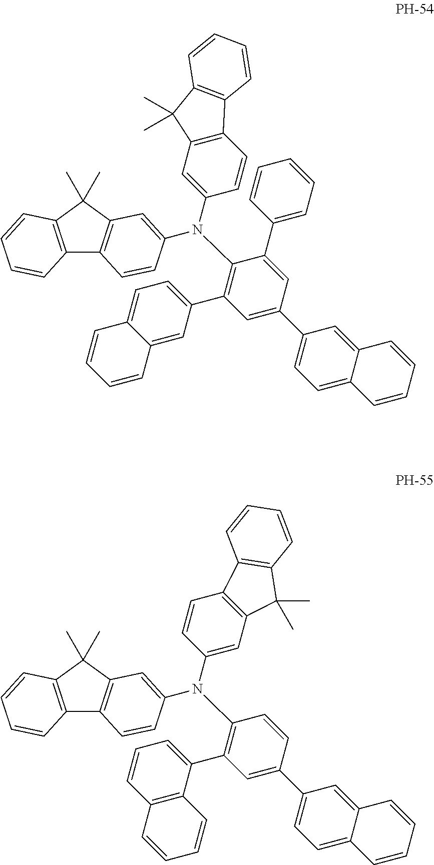 [SMILES: CC1(C)c2ccccc2-c2ccc(N(c3ccc4c(c3)C(C)(C)c3ccccc3-4)c3c(-c4ccccc4)cc(-c4ccc5ccccc5c4)cc3-c3ccc4ccccc4c3)cc21 ; CC1(C)c2ccccc2-c2ccc(N(c3ccc4c(c3)C(C)(C)c3ccccc3-4)c3ccc(-c4ccc5ccccc5c4)cc3-c3cccc4ccccc34)cc21]

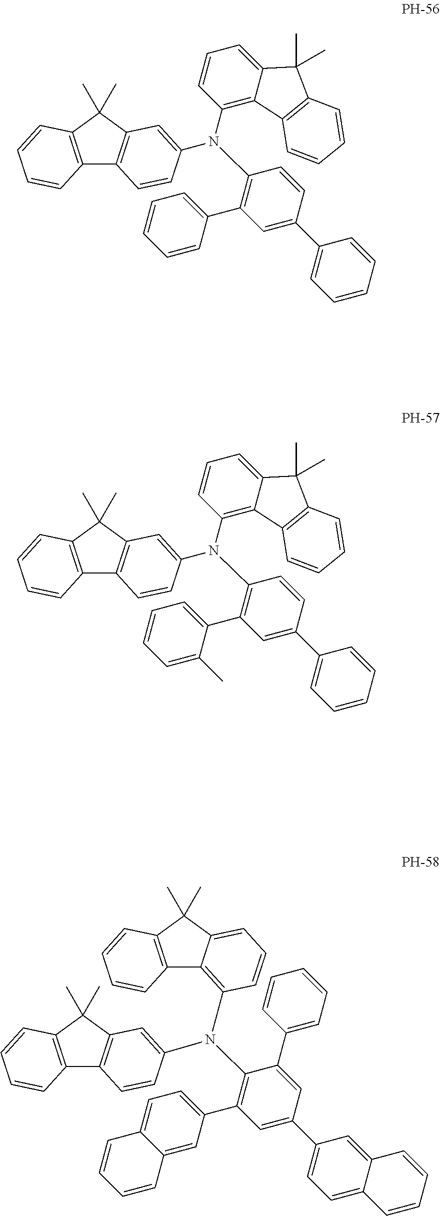 [SMILES: CC1(C)c2ccccc2-c2ccc(N(c3ccc(-c4ccccc4)cc3-c3ccccc3)c3cccc4c3-c3ccccc3C4(C)C)cc21 ; Cc1ccccc1-c1cc(-c2ccccc2)ccc1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4ccc5ccccc5c4)cc3-c3ccc4ccccc4c3)cc21]

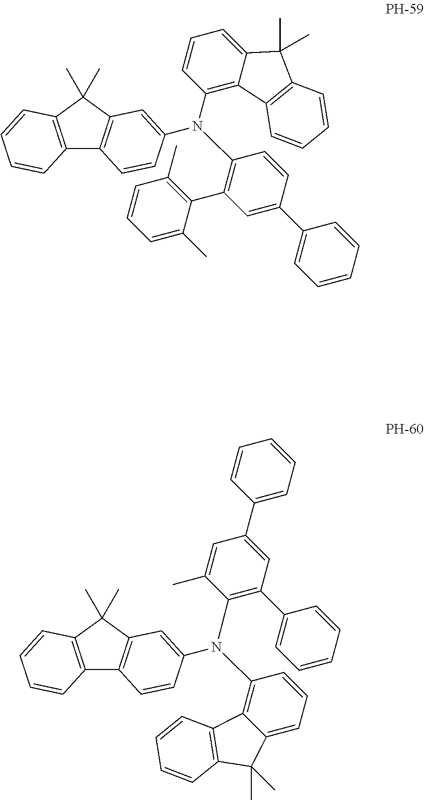 [SMILES: Cc1cccc(C)c1-c1cc(-c2ccccc2)ccc1N(c1ccc2c(c1)C(C)(C)c1ccccc1-2)c1cccc2c1-c1ccccc1C2(C)C ; Cc1cc(-c2ccccc2)cc(-c2ccccc2)c1N(c1ccc2c(c1)C(C)(C)c1ccccc1-2)c1cccc2c1-c1ccccc1C2(C)C]

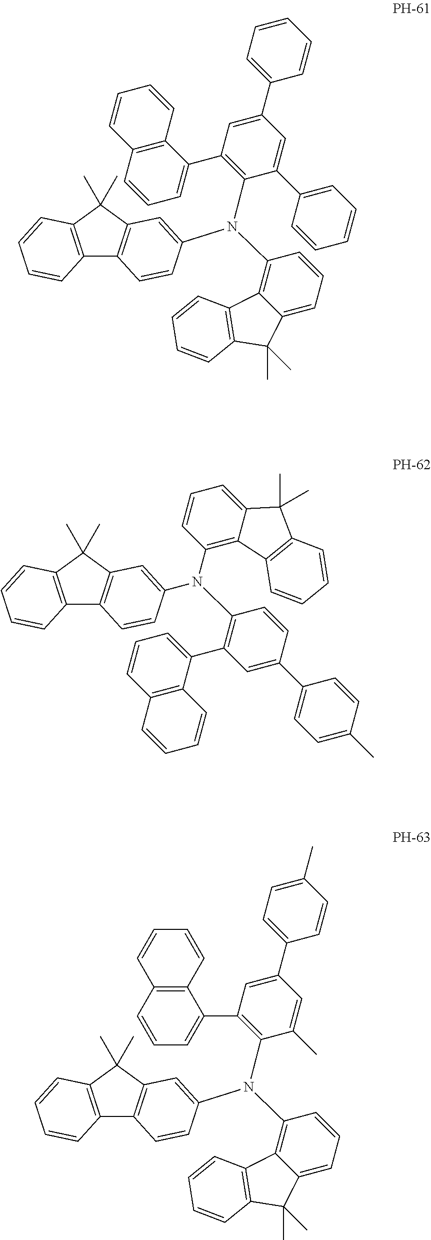 [SMILES: CC1(C)c2ccccc2-c2ccc(N(c3cccc4c3-c3ccccc3C4(C)C)c3c(-c4ccccc4)cc(-c4ccccc4)cc3-c3cccc4ccccc34)cc21 ; Cc1ccc(-c2ccc(N(c3ccc4c(c3)C(C)(C)c3ccccc3-4)c3cccc4c3-c3ccccc3C4(C)C)c(-c3cccc4ccccc34)c2)cc1 ; Cc1ccc(-c2cc(C)c(N(c3ccc4c(c3)C(C)(C)c3ccccc3-4)c3cccc4c3-c3ccccc3C4(C)C)c(-c3cccc4ccccc34)c2)cc1]

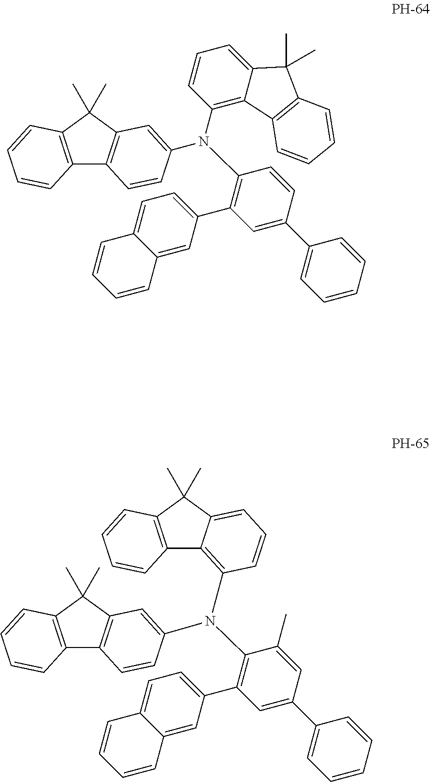 [SMILES: CC1(C)c2ccccc2-c2ccc(N(c3ccc(-c4ccccc4)cc3-c3ccc4ccccc4c3)c3cccc4c3-c3ccccc3C4(C)C)cc21 ; Cc1cc(-c2ccccc2)cc(-c2ccc3ccccc3c2)c1N(c1ccc2c(c1)C(C)(C)c1ccccc1-2)c1cccc2c1-c1ccccc1C2(C)C]

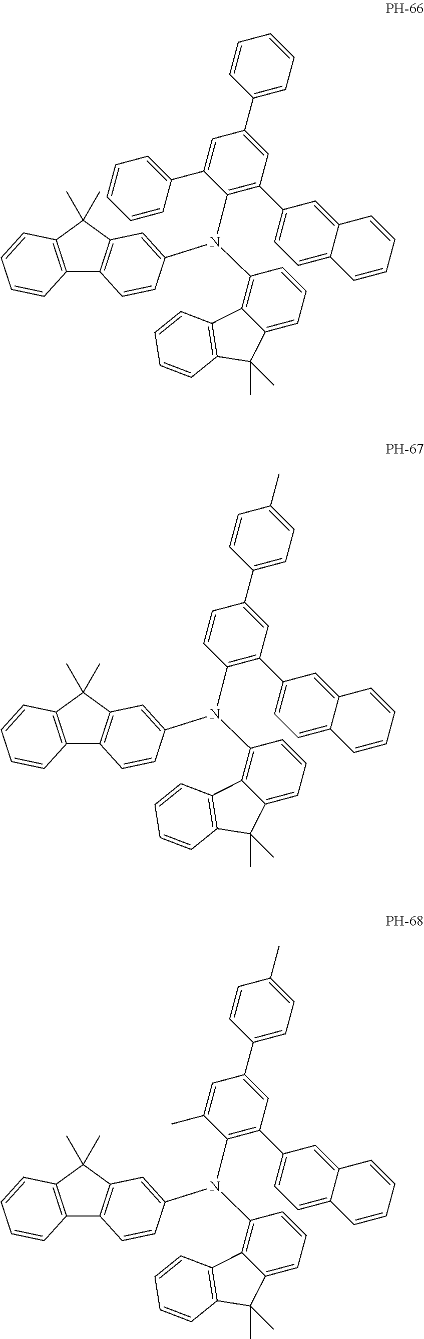 [SMILES: CC1(C)c2ccccc2-c2ccc(N(c3cccc4c3-c3ccccc3C4(C)C)c3c(-c4ccccc4)cc(-c4ccccc4)cc3-c3ccc4ccccc4c3)cc21 ; Cc1ccc(-c2ccc(N(c3ccc4c(c3)C(C)(C)c3ccccc3-4)c3cccc4c3-c3ccccc3C4(C)C)c(-c3ccc4ccccc4c3)c2)cc1 ; Cc1ccc(-c2cc(C)c(N(c3ccc4c(c3)C(C)(C)c3ccccc3-4)c3cccc4c3-c3ccccc3C4(C)C)c(-c3ccc4ccccc4c3)c2)cc1]

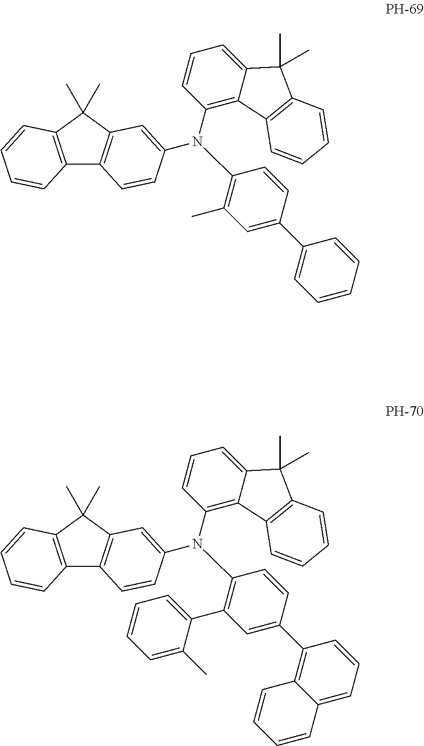 [SMILES: Cc1cc(-c2ccccc2)ccc1N(c1ccc2c(c1)C(C)(C)c1ccccc1-2)c1cccc2c1-c1ccccc1C2(C)C ; Cc1ccccc1-c1cc(-c2cccc3ccccc23)ccc1N(c1ccc2c(c1)C(C)(C)c1ccccc1-2)c1cccc2c1-c1ccccc1C2(C)C]

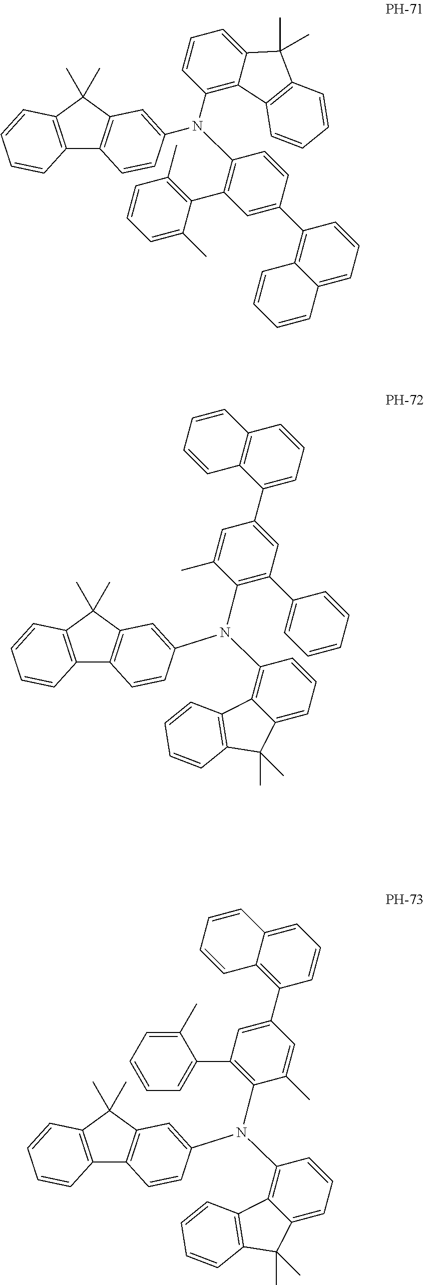 [SMILES: Cc1cccc(C)c1-c1cc(-c2cccc3ccccc23)ccc1N(c1ccc2c(c1)C(C)(C)c1ccccc1-2)c1cccc2c1-c1ccccc1C2(C)C ; Cc1cc(-c2cccc3ccccc23)cc(-c2ccccc2)c1N(c1ccc2c(c1)C(C)(C)c1ccccc1-2)c1cccc2c1-c1ccccc1C2(C)C ; Cc1ccccc1-c1cc(-c2cccc3ccccc23)cc(C)c1N(c1ccc2c(c1)C(C)(C)c1ccccc1-2)c1cccc2c1-c1ccccc1C2(C)C]

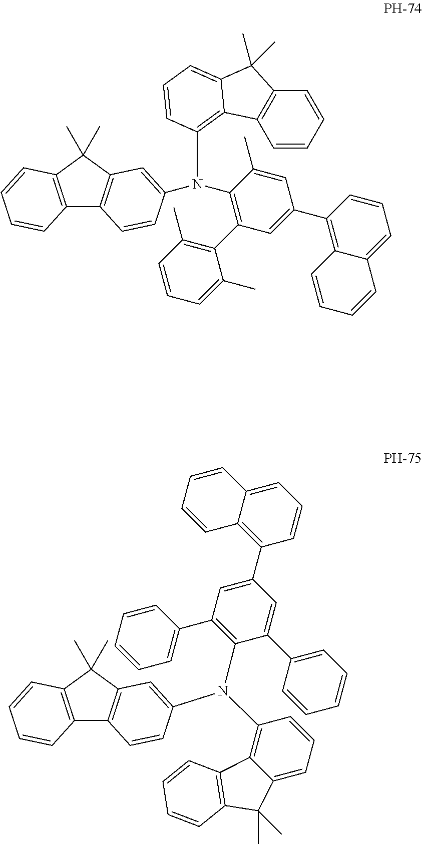 [SMILES: Cc1cccc(C)c1-c1cc(-c2cccc3ccccc23)cc(C)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4cccc5ccccc45)cc3-c3ccccc3)cc21]

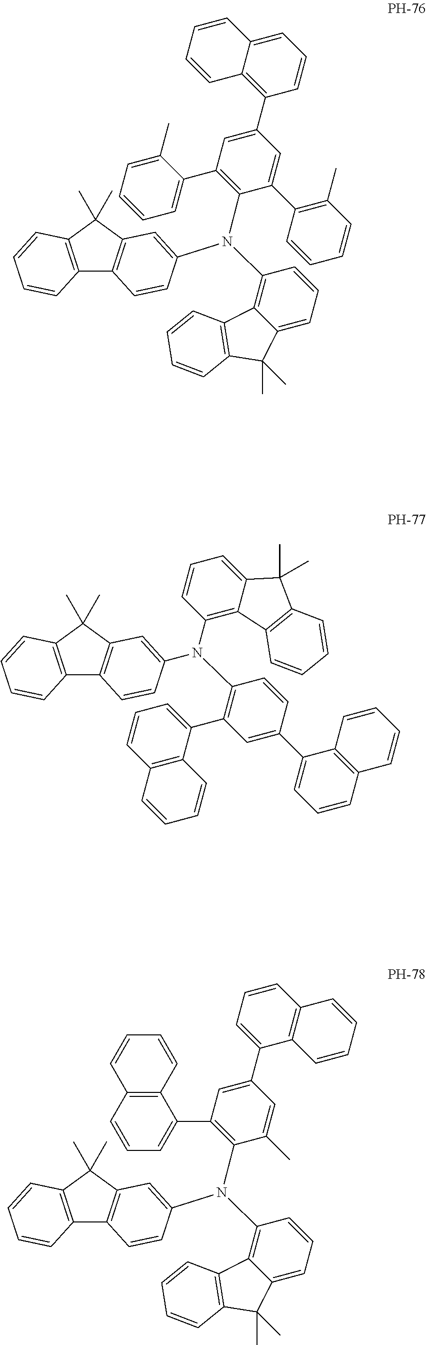 [SMILES: Cc1ccccc1-c1cc(-c2cccc3ccccc23)cc(-c2ccccc2C)c1N(c1ccc2c(c1)C(C)(C)c1ccccc1-2)c1cccc2c1-c1ccccc1C2(C)C ; CC1(C)c2ccccc2-c2ccc(N(c3ccc(-c4cccc5ccccc45)cc3-c3cccc4ccccc34)c3cccc4c3-c3ccccc3C4(C)C)cc21 ; Cc1cc(-c2cccc3ccccc23)cc(-c2cccc3ccccc23)c1N(c1ccc2c(c1)C(C)(C)c1ccccc1-2)c1cccc2c1-c1ccccc1C2(C)C]

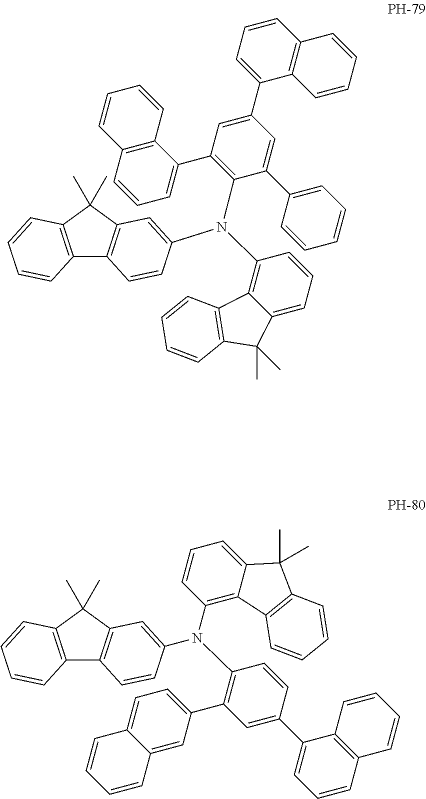 [SMILES: CC1(C)c2ccccc2-c2ccc(N(c3cccc4c3-c3ccccc3C4(C)C)c3c(-c4ccccc4)cc(-c4cccc5ccccc45)cc3-c3cccc4ccccc34)cc21 ; CC1(C)c2ccccc2-c2ccc(N(c3ccc(-c4cccc5ccccc45)cc3-c3ccc4ccccc4c3)c3cccc4c3-c3ccccc3C4(C)C)cc21]

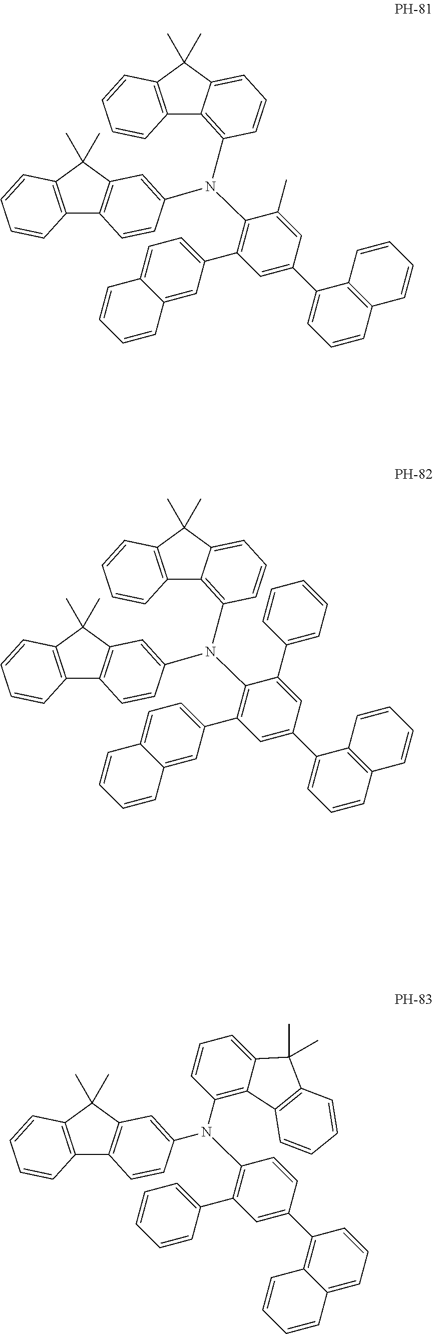 [SMILES: Cc1cc(-c2cccc3ccccc23)cc(-c2ccc3ccccc3c2)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4cccc5ccccc45)cc3-c3ccc4ccccc4c3)cc21 ; CC1(C)c2ccccc2-c2ccc(N(c3ccc(-c4cccc5ccccc45)cc3-c3ccccc3)c3cccc4c3-c3ccccc3C4(C)C)cc21]

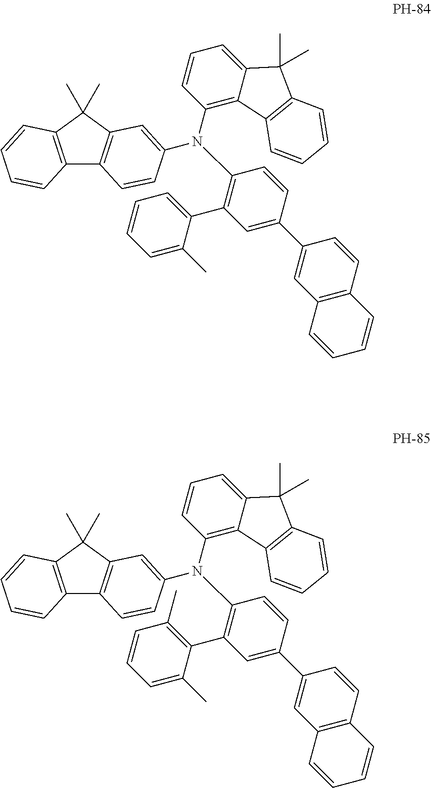 [SMILES: Cc1ccccc1-c1cc(-c2ccc3ccccc3c2)ccc1N(c1ccc2c(c1)C(C)(C)c1ccccc1-2)c1cccc2c1-c1ccccc1C2(C)C ; Cc1cccc(C)c1-c1cc(-c2ccc3ccccc3c2)ccc1N(c1ccc2c(c1)C(C)(C)c1ccccc1-2)c1cccc2c1-c1ccccc1C2(C)C]

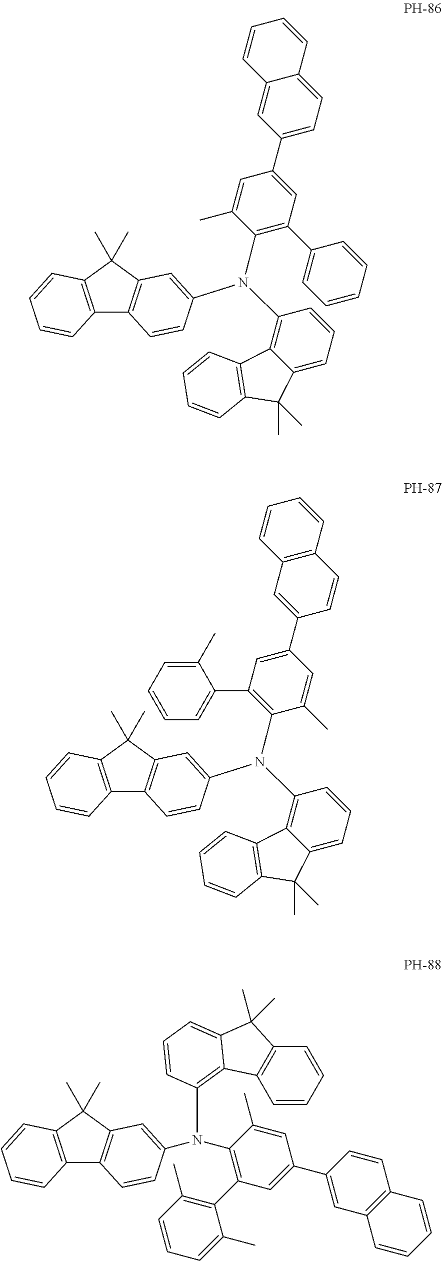 [SMILES: Cc1cc(-c2ccc3ccccc3c2)cc(-c2ccccc2)c1N(c1ccc2c(c1)C(C)(C)c1ccccc1-2)c1cccc2c1-c1ccccc1C2(C)C ; Cc1ccccc1-c1cc(-c2ccc3ccccc3c2)cc(C)c1N(c1ccc2c(c1)C(C)(C)c1ccccc1-2)c1cccc2c1-c1ccccc1C2(C)C ; Cc1cccc(C)c1-c1cc(-c2ccc3ccccc3c2)cc(C)c1N(c1ccc2c(c1)C(C)(C)c1ccccc1-2)c1cccc2c1-c1ccccc1C2(C)C]

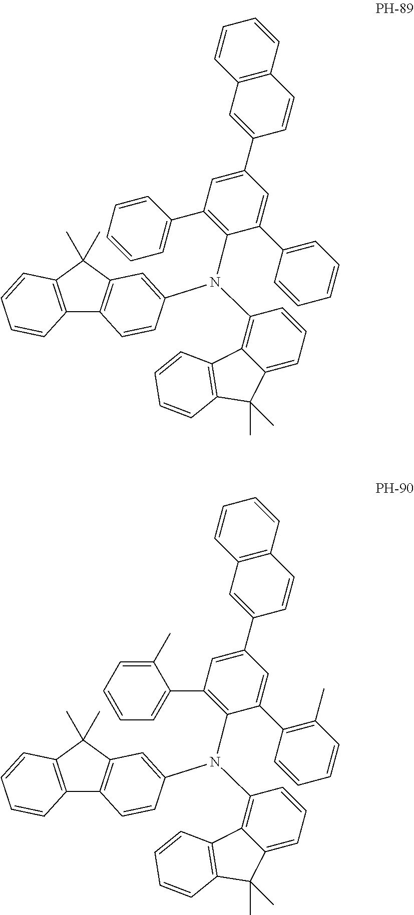 [SMILES: CC1(C)c2ccccc2-c2ccc(N(c3cccc4c3-c3ccccc3C4(C)C)c3c(-c4ccccc4)cc(-c4ccc5ccccc5c4)cc3-c3ccccc3)cc21 ; Cc1ccccc1-c1cc(-c2ccc3ccccc3c2)cc(-c2ccccc2C)c1N(c1ccc2c(c1)C(C)(C)c1ccccc1-2)c1cccc2c1-c1ccccc1C2(C)C]

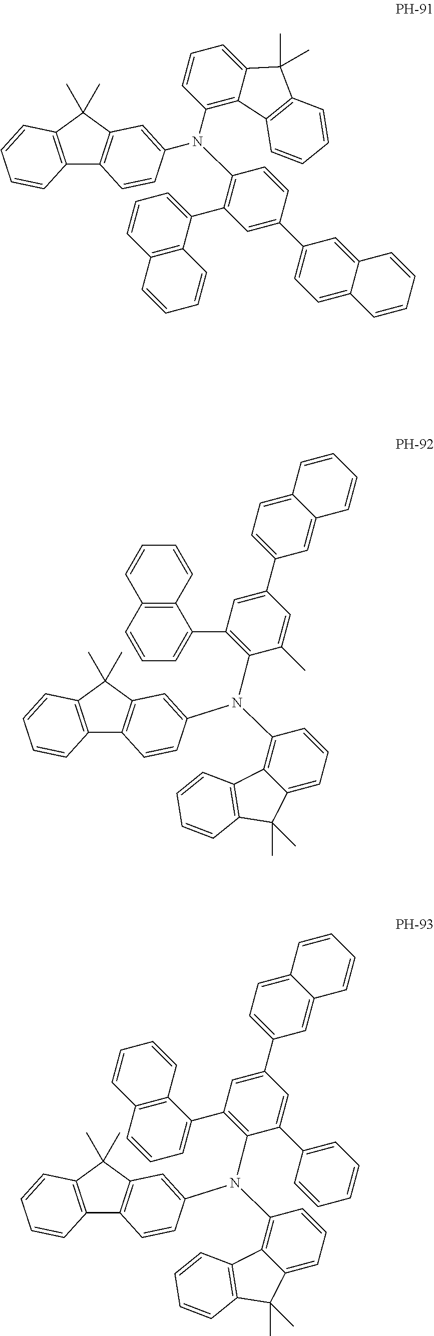 [SMILES: CC1(C)c2ccccc2-c2ccc(N(c3ccc(-c4ccc5ccccc5c4)cc3-c3cccc4ccccc34)c3cccc4c3-c3ccccc3C4(C)C)cc21 ; Cc1cc(-c2ccc3ccccc3c2)cc(-c2cccc3ccccc23)c1N(c1ccc2c(c1)C(C)(C)c1ccccc1-2)c1cccc2c1-c1ccccc1C2(C)C ; CC1(C)c2ccccc2-c2ccc(N(c3cccc4c3-c3ccccc3C4(C)C)c3c(-c4ccccc4)cc(-c4ccc5ccccc5c4)cc3-c3cccc4ccccc34)cc21]

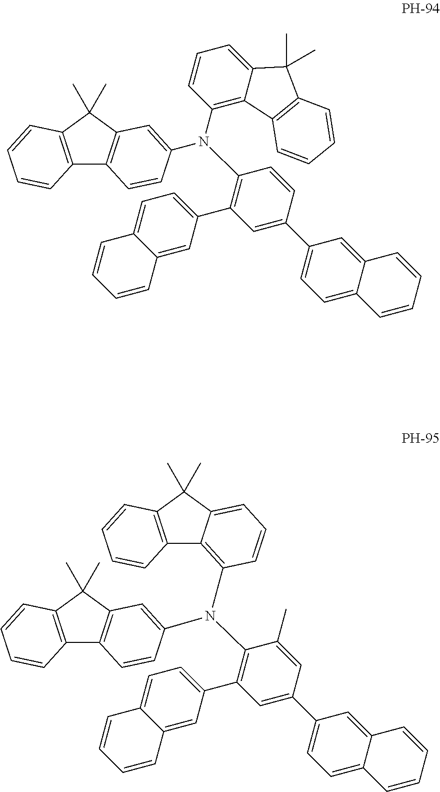 [SMILES: CC1(C)c2ccccc2-c2ccc(N(c3ccc(-c4ccc5ccccc5c4)cc3-c3ccc4ccccc4c3)c3cccc4c3-c3ccccc3C4(C)C)cc21 ; Cc1cc(-c2ccc3ccccc3c2)cc(-c2ccc3ccccc3c2)c1N(c1ccc2c(c1)C(C)(C)c1ccccc1-2)c1cccc2c1-c1ccccc1C2(C)C]

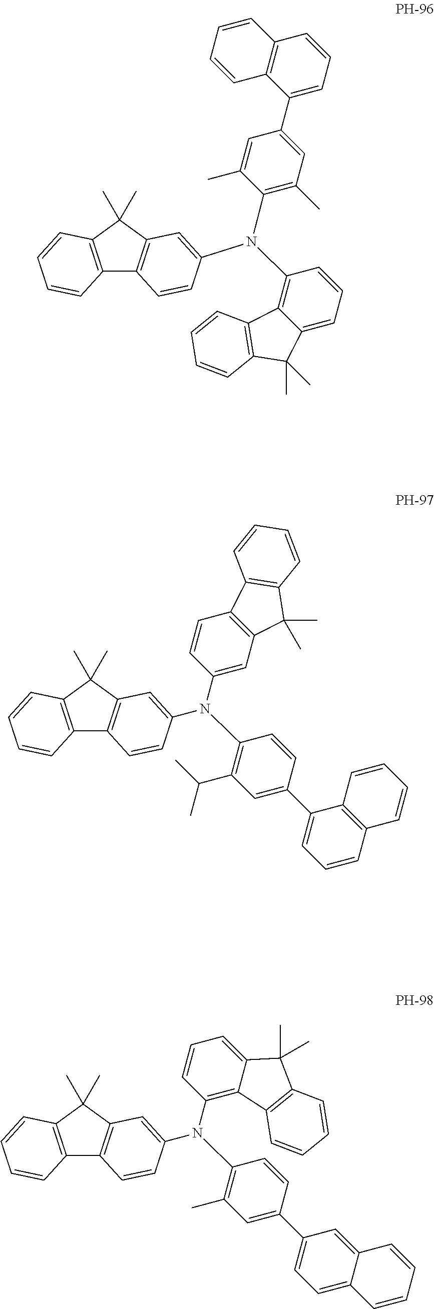 [SMILES: Cc1cc(-c2cccc3ccccc23)cc(C)c1N(c1ccc2c(c1)C(C)(C)c1ccccc1-2)c1cccc2c1-c1ccccc1C2(C)C ; CC(C)c1cc(-c2cccc3ccccc23)ccc1N(c1ccc2c(c1)C(C)(C)c1ccccc1-2)c1ccc2c(c1)C(C)(C)c1ccccc1-2 ; Cc1cc(-c2ccc3ccccc3c2)ccc1N(c1ccc2c(c1)C(C)(C)c1ccccc1-2)c1cccc2c1-c1ccccc1C2(C)C]

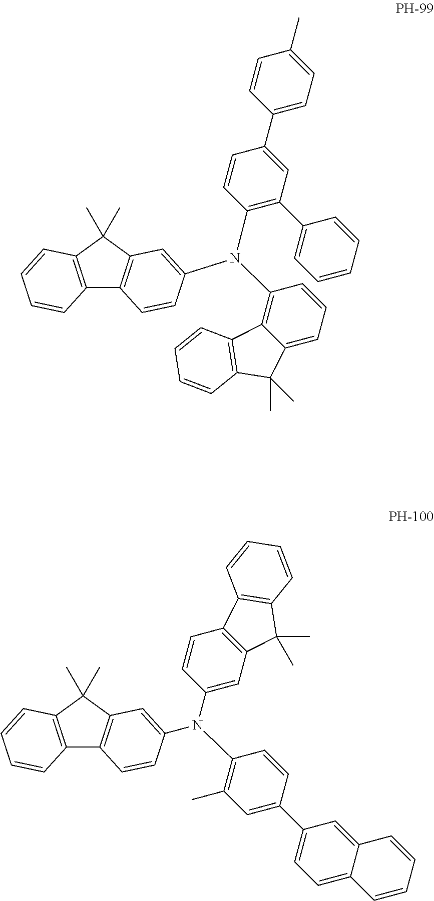 [SMILES: Cc1ccc(-c2ccc(N(c3ccc4c(c3)C(C)(C)c3ccccc3-4)c3cccc4c3-c3ccccc3C4(C)C)c(-c3ccccc3)c2)cc1 ; Cc1cc(-c2ccc3ccccc3c2)ccc1N(c1ccc2c(c1)C(C)(C)c1ccccc1-2)c1ccc2c(c1)C(C)(C)c1ccccc1-2]

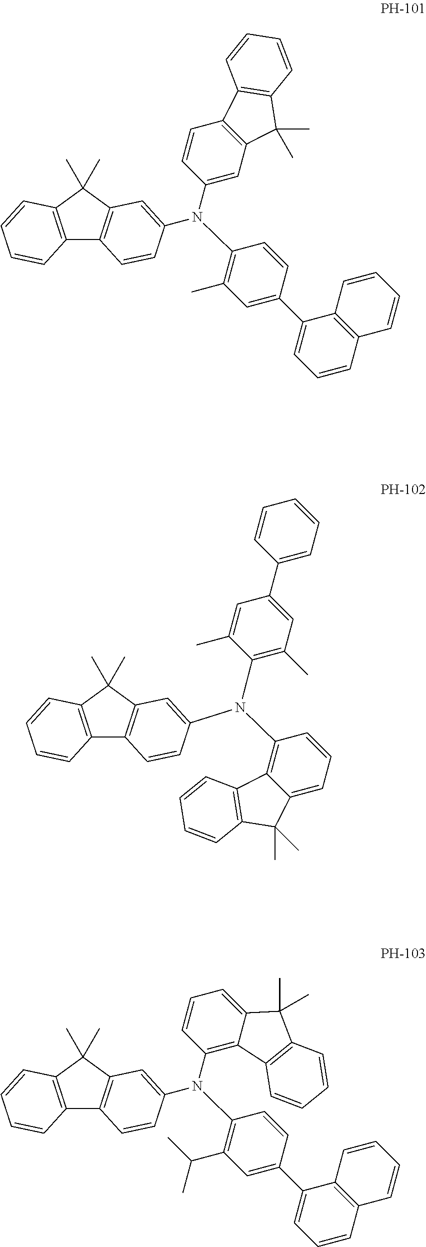 [SMILES: Cc1cc(-c2cccc3ccccc23)ccc1N(c1ccc2c(c1)C(C)(C)c1ccccc1-2)c1ccc2c(c1)C(C)(C)c1ccccc1-2 ; Cc1cc(-c2ccccc2)cc(C)c1N(c1ccc2c(c1)C(C)(C)c1ccccc1-2)c1cccc2c1-c1ccccc1C2(C)C ; CC(C)c1cc(-c2cccc3ccccc23)ccc1N(c1ccc2c(c1)C(C)(C)c1ccccc1-2)c1cccc2c1-c1ccccc1C2(C)C]

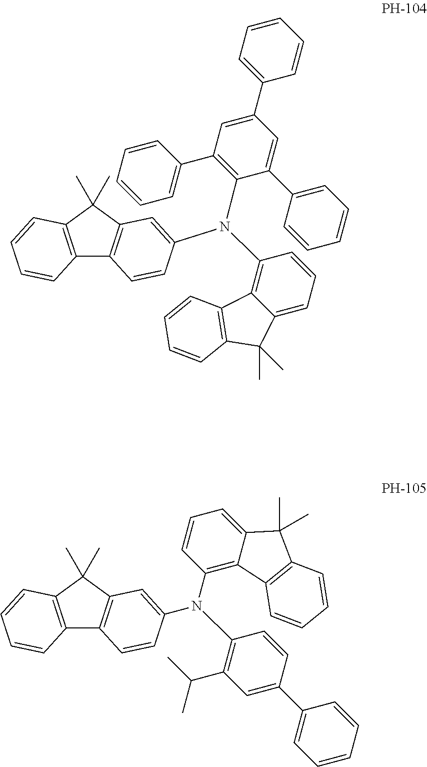 [SMILES: CC1(C)c2ccccc2-c2ccc(N(c3cccc4c3-c3ccccc3C4(C)C)c3c(-c4ccccc4)cc(-c4ccccc4)cc3-c3ccccc3)cc21 ; CC(C)c1cc(-c2ccccc2)ccc1N(c1ccc2c(c1)C(C)(C)c1ccccc1-2)c1cccc2c1-c1ccccc1C2(C)C]

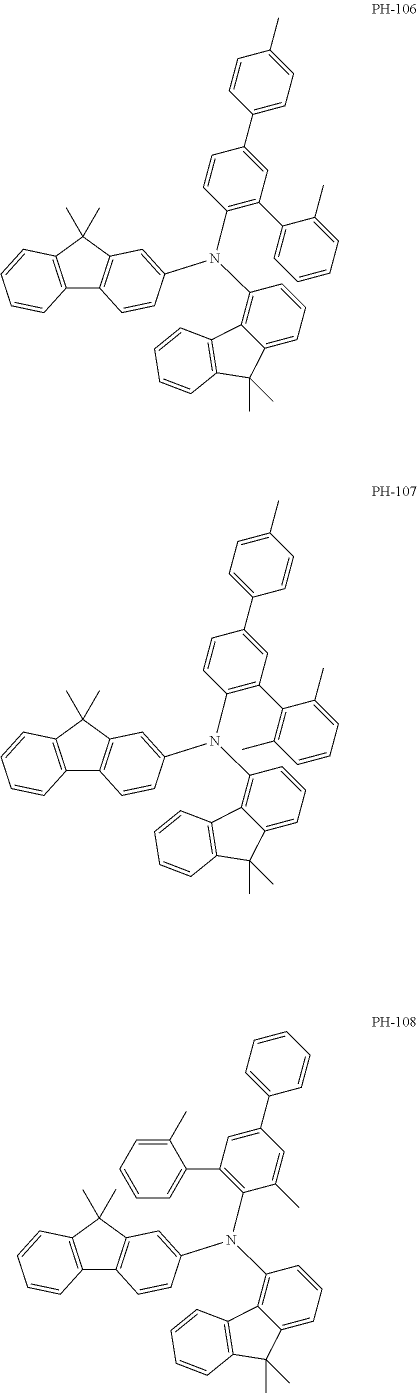 [SMILES: Cc1ccc(-c2ccc(N(c3ccc4c(c3)C(C)(C)c3ccccc3-4)c3cccc4c3-c3ccccc3C4(C)C)c(-c3ccccc3C)c2)cc1 ; Cc1ccc(-c2ccc(N(c3ccc4c(c3)C(C)(C)c3ccccc3-4)c3cccc4c3-c3ccccc3C4(C)C)c(-c3c(C)cccc3C)c2)cc1 ; Cc1ccccc1-c1cc(-c2ccccc2)cc(C)c1N(c1ccc2c(c1)C(C)(C)c1ccccc1-2)c1cccc2c1-c1ccccc1C2(C)C]

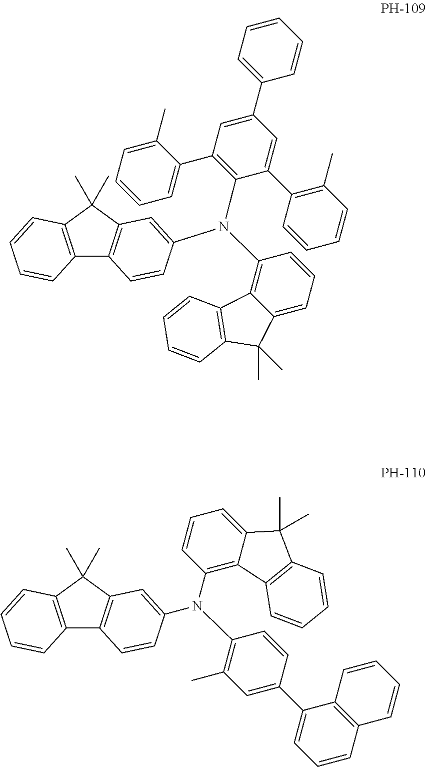 [SMILES: Cc1ccccc1-c1cc(-c2ccccc2)cc(-c2ccccc2C)c1N(c1ccc2c(c1)C(C)(C)c1ccccc1-2)c1cccc2c1-c1ccccc1C2(C)C ; Cc1cc(-c2cccc3ccccc23)ccc1N(c1ccc2c(c1)C(C)(C)c1ccccc1-2)c1cccc2c1-c1ccccc1C2(C)C]

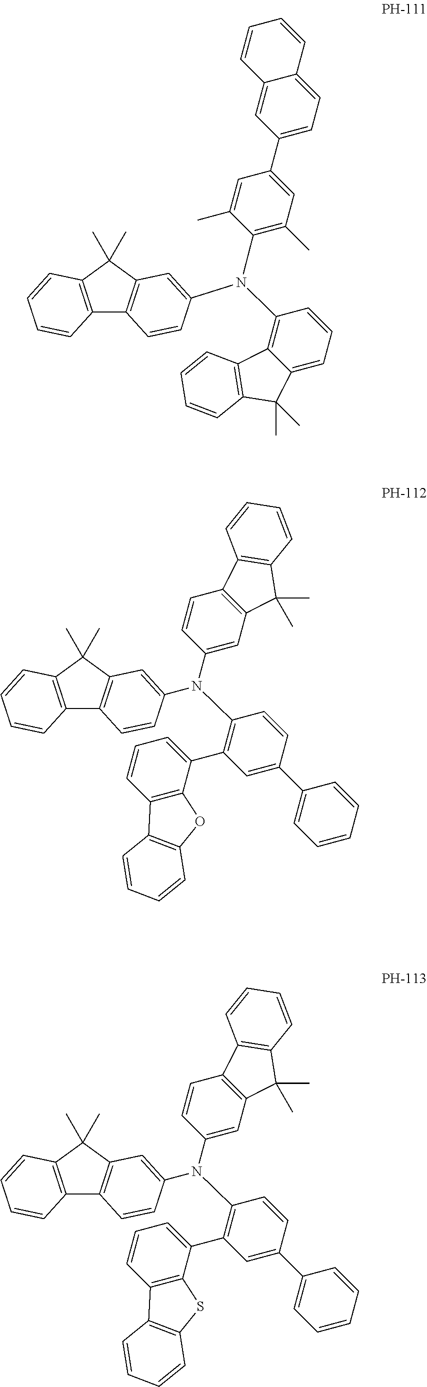 [SMILES: Cc1cc(-c2ccc3ccccc3c2)cc(C)c1N(c1ccc2c(c1)C(C)(C)c1ccccc1-2)c1cccc2c1-c1ccccc1C2(C)C ; CC1(C)c2ccccc2-c2ccc(N(c3ccc4c(c3)C(C)(C)c3ccccc3-4)c3ccc(-c4ccccc4)cc3-c3cccc4c3oc3ccccc34)cc21 ; CC1(C)c2ccccc2-c2ccc(N(c3ccc4c(c3)C(C)(C)c3ccccc3-4)c3ccc(-c4ccccc4)cc3-c3cccc4c3sc3ccccc34)cc21]

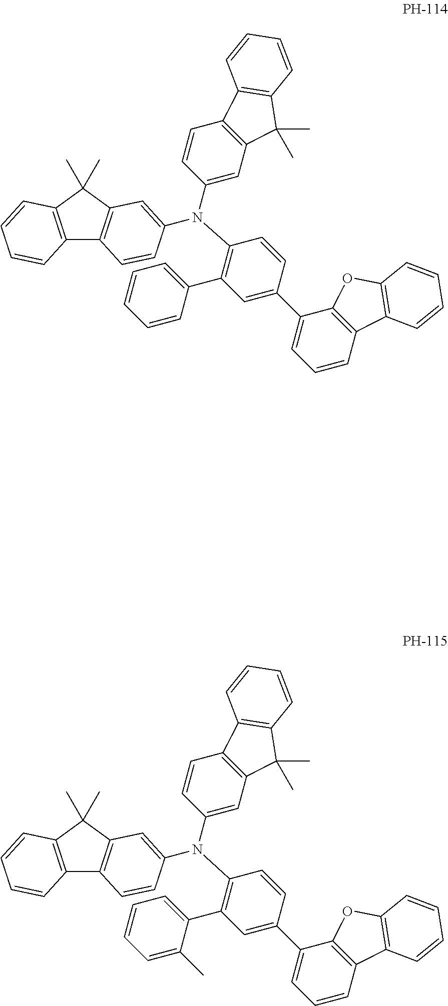 [SMILES: CC1(C)c2ccccc2-c2ccc(N(c3ccc4c(c3)C(C)(C)c3ccccc3-4)c3ccc(-c4cccc5c4oc4ccccc45)cc3-c3ccccc3)cc21 ; Cc1ccccc1-c1cc(-c2cccc3c2oc2ccccc23)ccc1N(c1ccc2c(c1)C(C)(C)c1ccccc1-2)c1ccc2c(c1)C(C)(C)c1ccccc1-2]

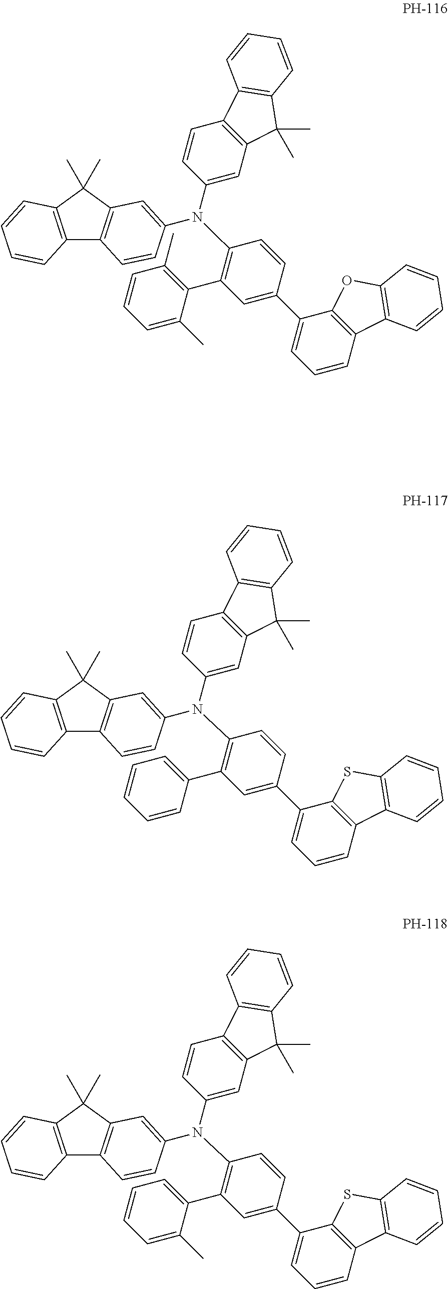 [SMILES: Cc1cccc(C)c1-c1cc(-c2cccc3c2oc2ccccc23)ccc1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3ccc(-c4cccc5c4sc4ccccc45)cc3-c3ccccc3)cc21 ; Cc1ccccc1-c1cc(-c2cccc3c2sc2ccccc23)ccc1N(c1ccc2c(c1)C(C)(C)c1ccccc1-2)c1ccc2c(c1)C(C)(C)c1ccccc1-2]

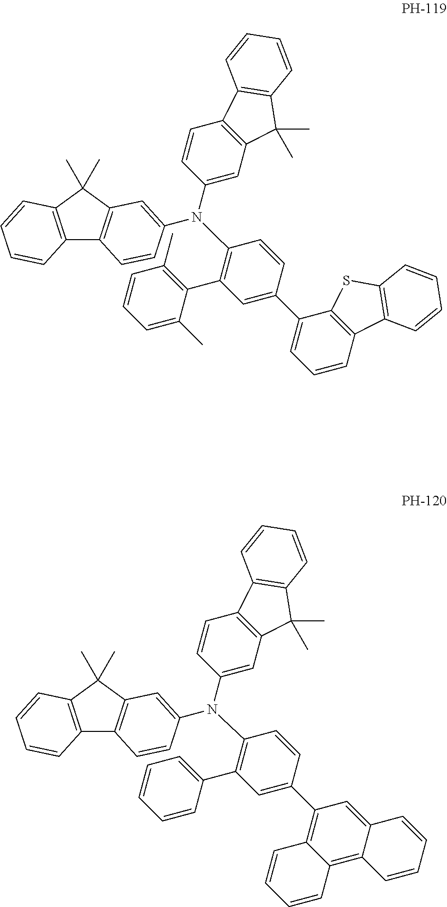 [SMILES: Cc1cccc(C)c1-c1cc(-c2cccc3c2sc2ccccc23)ccc1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3ccc(-c4cc5ccccc5c5ccccc45)cc3-c3ccccc3)cc21]

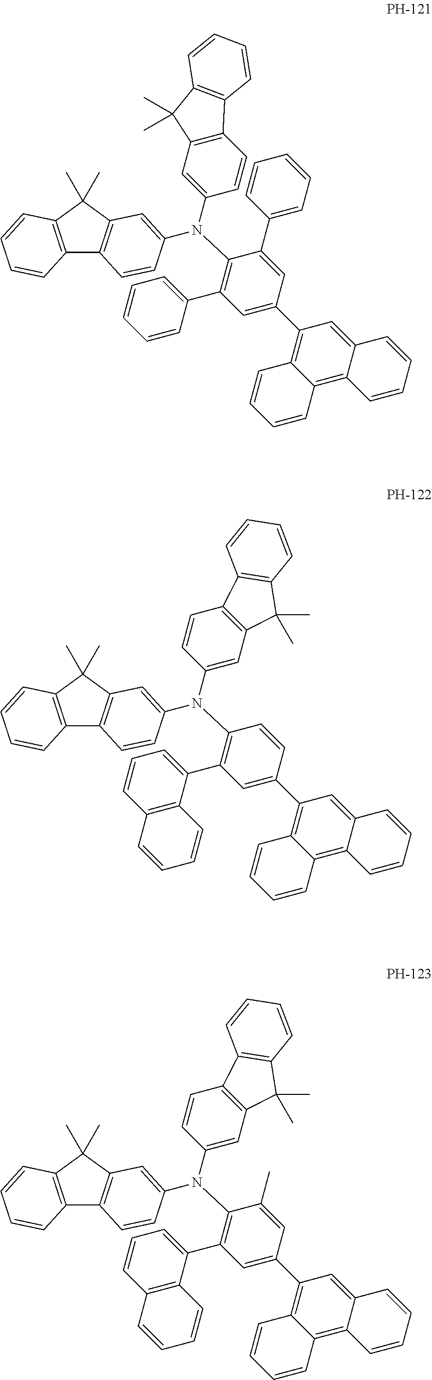 [SMILES: CC1(C)c2ccccc2-c2ccc(N(c3ccc4c(c3)C(C)(C)c3ccccc3-4)c3c(-c4ccccc4)cc(-c4cc5ccccc5c5ccccc45)cc3-c3ccccc3)cc21 ; CC1(C)c2ccccc2-c2ccc(N(c3ccc4c(c3)C(C)(C)c3ccccc3-4)c3ccc(-c4cc5ccccc5c5ccccc45)cc3-c3cccc4ccccc34)cc21 ; Cc1cc(-c2cc3ccccc3c3ccccc23)cc(-c2cccc3ccccc23)c1N(c1ccc2c(c1)C(C)(C)c1ccccc1-2)c1ccc2c(c1)C(C)(C)c1ccccc1-2]

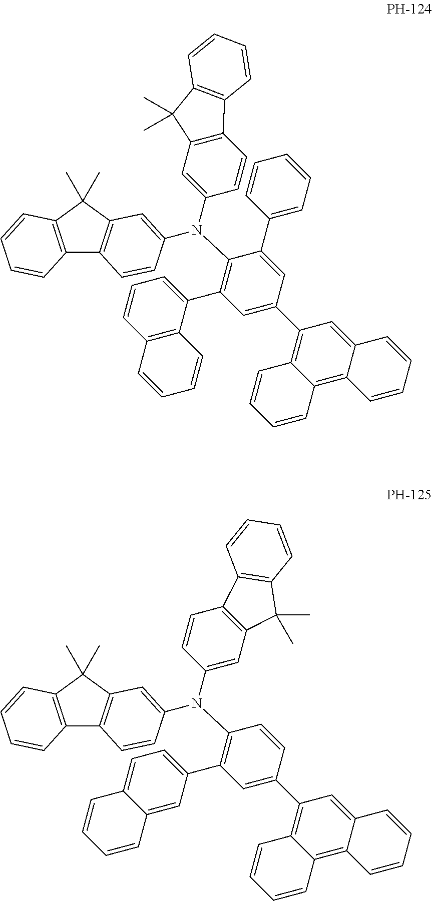 [SMILES: CC1(C)c2ccccc2-c2ccc(N(c3ccc4c(c3)C(C)(C)c3ccccc3-4)c3c(-c4ccccc4)cc(-c4cc5ccccc5c5ccccc45)cc3-c3cccc4ccccc34)cc21 ; CC1(C)c2ccccc2-c2ccc(N(c3ccc4c(c3)C(C)(C)c3ccccc3-4)c3ccc(-c4cc5ccccc5c5ccccc45)cc3-c3ccc4ccccc4c3)cc21]

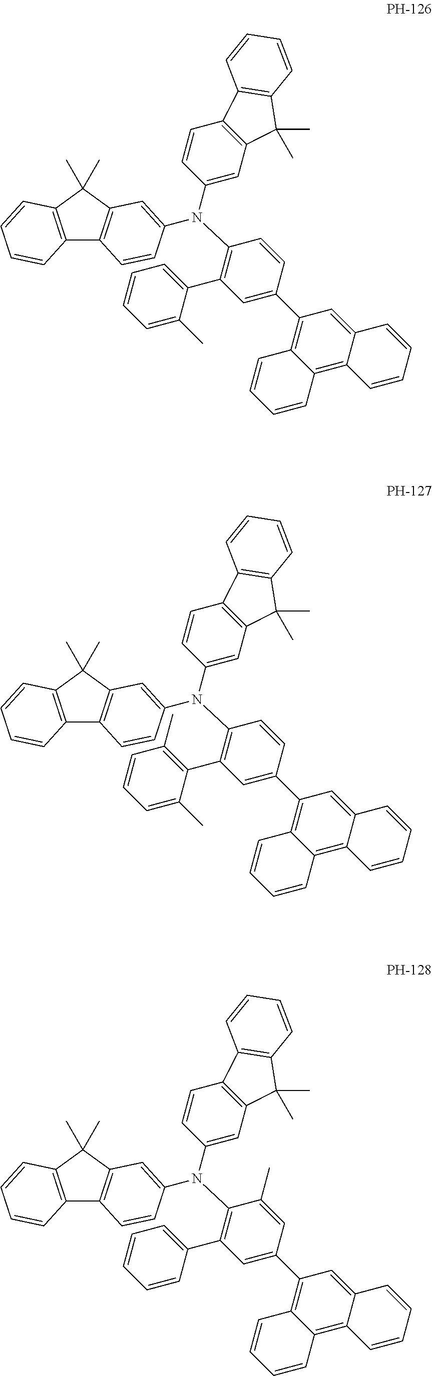 [SMILES: Cc1ccccc1-c1cc(-c2cc3ccccc3c3ccccc23)ccc1N(c1ccc2c(c1)C(C)(C)c1ccccc1-2)c1ccc2c(c1)C(C)(C)c1ccccc1-2 ; Cc1cccc(C)c1-c1cc(-c2cc3ccccc3c3ccccc23)ccc1N(c1ccc2c(c1)C(C)(C)c1ccccc1-2)c1ccc2c(c1)C(C)(C)c1ccccc1-2 ; Cc1cc(-c2cc3ccccc3c3ccccc23)cc(-c2ccccc2)c1N(c1ccc2c(c1)C(C)(C)c1ccccc1-2)c1ccc2c(c1)C(C)(C)c1ccccc1-2]

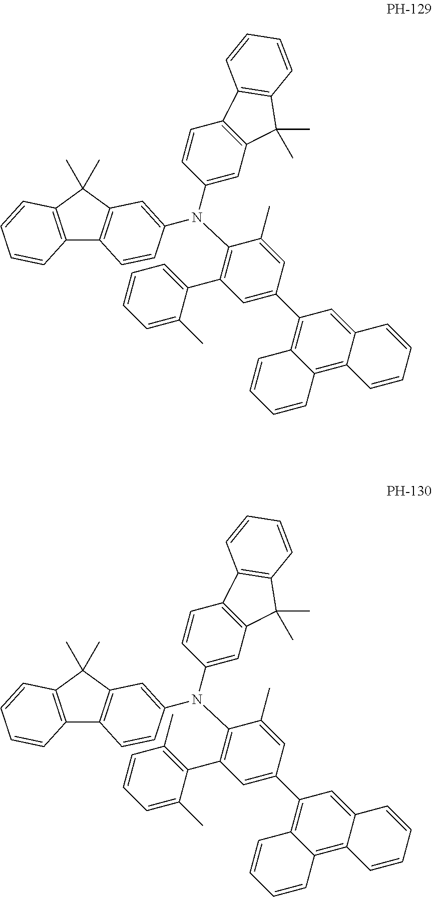 [SMILES: Cc1ccccc1-c1cc(-c2cc3ccccc3c3ccccc23)cc(C)c1N(c1ccc2c(c1)C(C)(C)c1ccccc1-2)c1ccc2c(c1)C(C)(C)c1ccccc1-2 ; Cc1cccc(C)c1-c1cc(-c2cc3ccccc3c3ccccc23)cc(C)c1N(c1ccc2c(c1)C(C)(C)c1ccccc1-2)c1ccc2c(c1)C(C)(C)c1ccccc1-2]

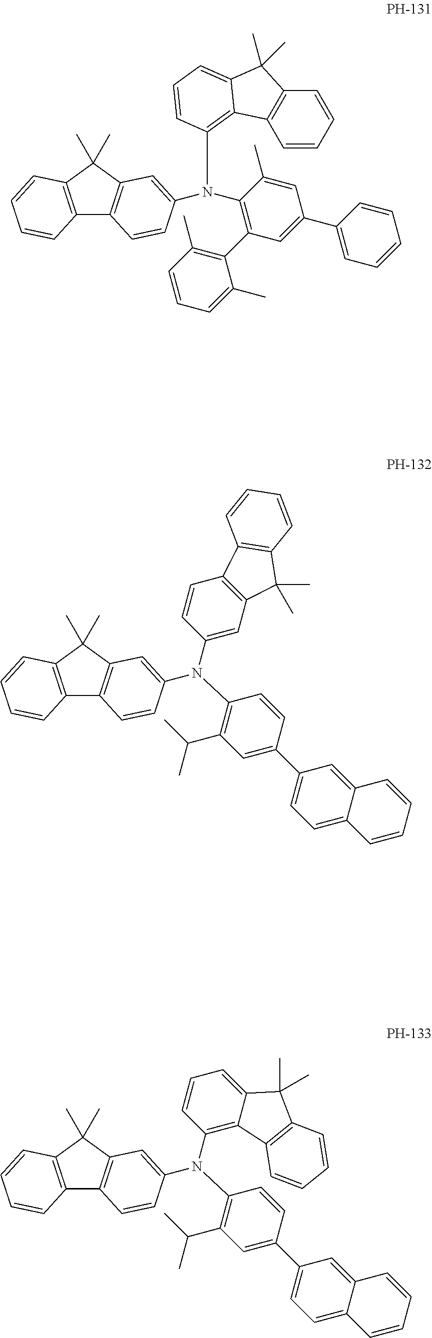 [SMILES: Cc1cccc(C)c1-c1cc(-c2ccccc2)cc(C)c1N(c1ccc2c(c1)C(C)(C)c1ccccc1-2)c1cccc2c1-c1ccccc1C2(C)C ; CC(C)c1cc(-c2ccc3ccccc3c2)ccc1N(c1ccc2c(c1)C(C)(C)c1ccccc1-2)c1ccc2c(c1)C(C)(C)c1ccccc1-2 ; CC(C)c1cc(-c2ccc3ccccc3c2)ccc1N(c1ccc2c(c1)C(C)(C)c1ccccc1-2)c1cccc2c1-c1ccccc1C2(C)C]

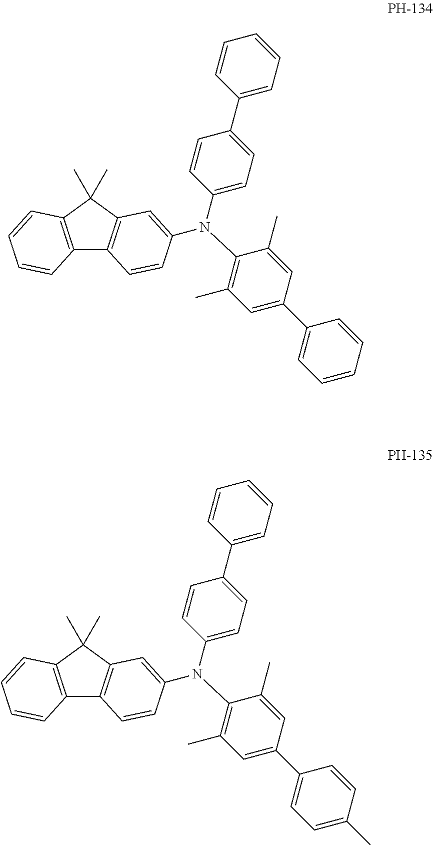 [SMILES: Cc1cc(-c2ccccc2)cc(C)c1N(c1ccc(-c2ccccc2)cc1)c1ccc2c(c1)C(C)(C)c1ccccc1-2 ; Cc1ccc(-c2cc(C)c(N(c3ccc(-c4ccccc4)cc3)c3ccc4c(c3)C(C)(C)c3ccccc3-4)c(C)c2)cc1]

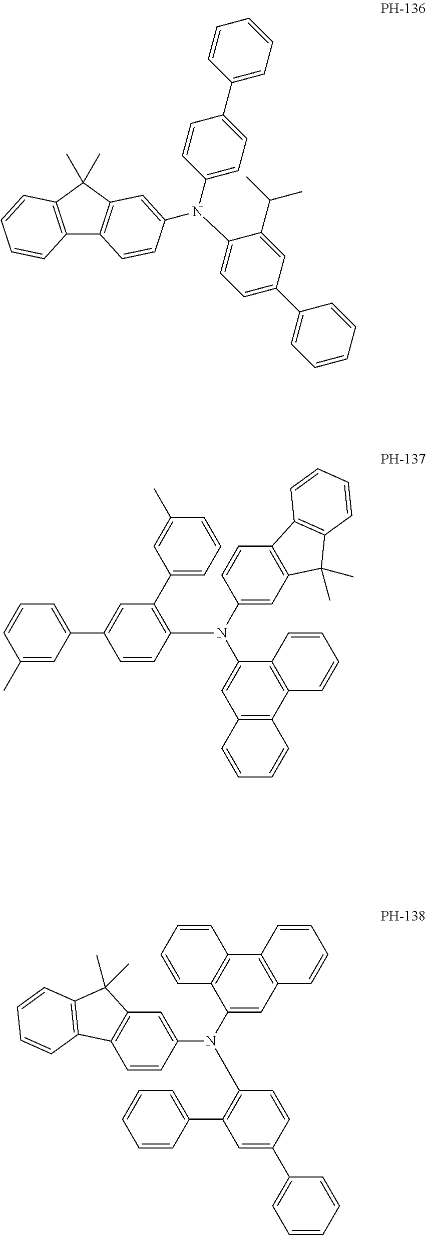 [SMILES: CC(C)c1cc(-c2ccccc2)ccc1N(c1ccc(-c2ccccc2)cc1)c1ccc2c(c1)C(C)(C)c1ccccc1-2 ; Cc1cccc(-c2ccc(N(c3ccc4c(c3)C(C)(C)c3ccccc3-4)c3cc4ccccc4c4ccccc34)c(-c3cccc(C)c3)c2)c1 ; CC1(C)c2ccccc2-c2ccc(N(c3ccc(-c4ccccc4)cc3-c3ccccc3)c3cc4ccccc4c4ccccc34)cc21]

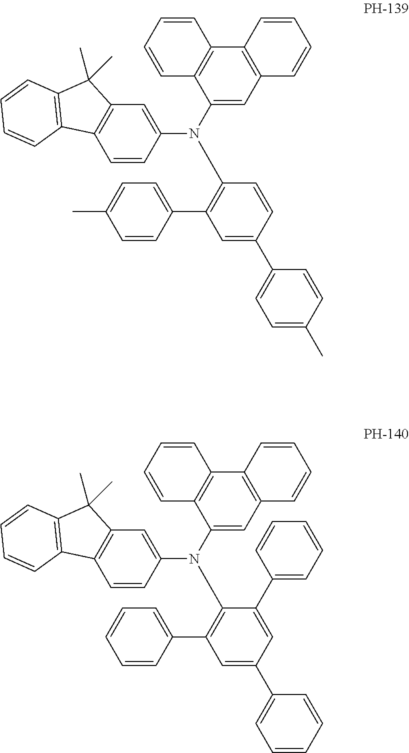 [SMILES: Cc1ccc(-c2ccc(N(c3ccc4c(c3)C(C)(C)c3ccccc3-4)c3cc4ccccc4c4ccccc34)c(-c3ccc(C)cc3)c2)cc1 ; CC1(C)c2ccccc2-c2ccc(N(c3c(-c4ccccc4)cc(-c4ccccc4)cc3-c3ccccc3)c3cc4ccccc4c4ccccc34)cc21]

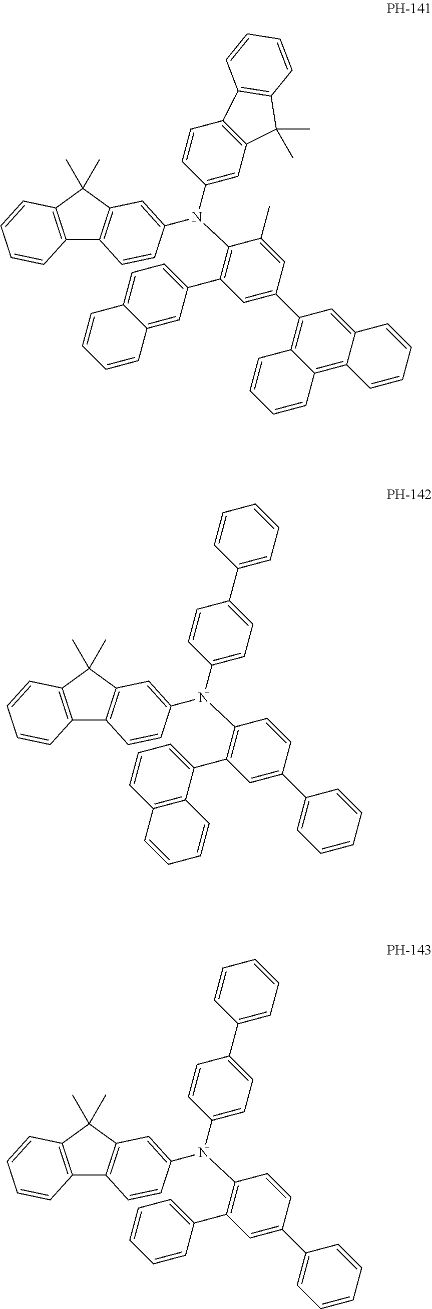 [SMILES: Cc1cc(-c2cc3ccccc3c3ccccc23)cc(-c2ccc3ccccc3c2)c1N(c1ccc2c(c1)C(C)(C)c1ccccc1-2)c1ccc2c(c1)C(C)(C)c1ccccc1-2 ; CC1(C)c2ccccc2-c2ccc(N(c3ccc(-c4ccccc4)cc3)c3ccc(-c4ccccc4)cc3-c3cccc4ccccc34)cc21 ; CC1(C)c2ccccc2-c2ccc(N(c3ccc(-c4ccccc4)cc3)c3ccc(-c4ccccc4)cc3-c3ccccc3)cc21]

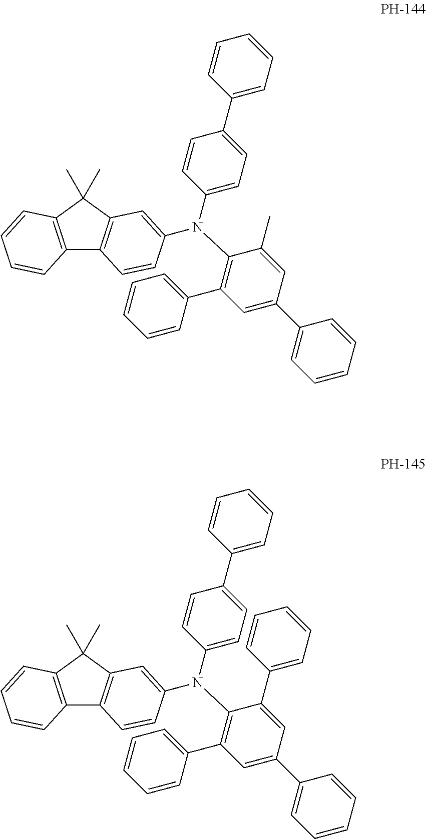 [SMILES: Cc1cc(-c2ccccc2)cc(-c2ccccc2)c1N(c1ccc(-c2ccccc2)cc1)c1ccc2c(c1)C(C)(C)c1ccccc1-2 ; CC1(C)c2ccccc2-c2ccc(N(c3ccc(-c4ccccc4)cc3)c3c(-c4ccccc4)cc(-c4ccccc4)cc3-c3ccccc3)cc21]

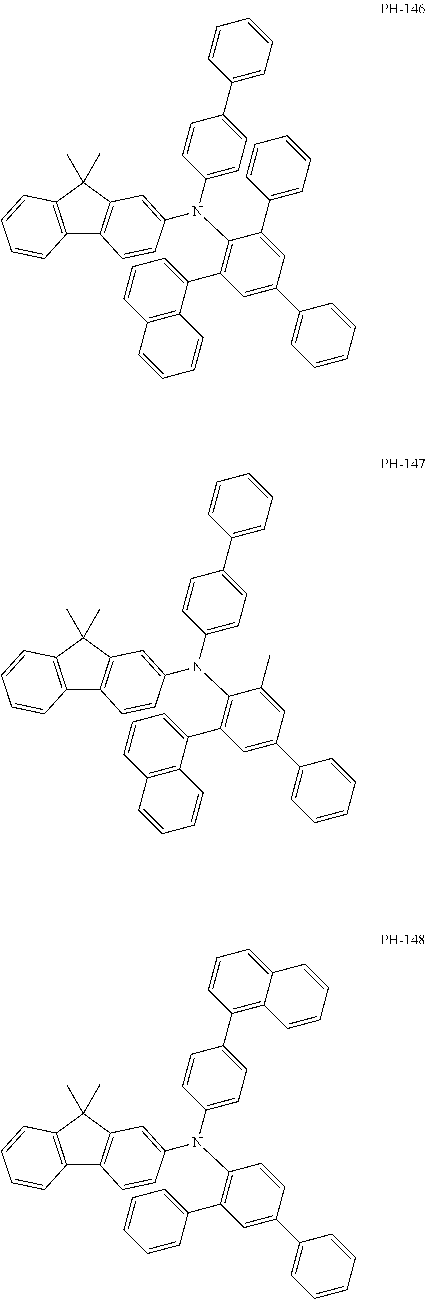 [SMILES: CC1(C)c2ccccc2-c2ccc(N(c3ccc(-c4ccccc4)cc3)c3c(-c4ccccc4)cc(-c4ccccc4)cc3-c3cccc4ccccc34)cc21 ; Cc1cc(-c2ccccc2)cc(-c2cccc3ccccc23)c1N(c1ccc(-c2ccccc2)cc1)c1ccc2c(c1)C(C)(C)c1ccccc1-2 ; CC1(C)c2ccccc2-c2ccc(N(c3ccc(-c4cccc5ccccc45)cc3)c3ccc(-c4ccccc4)cc3-c3ccccc3)cc21]

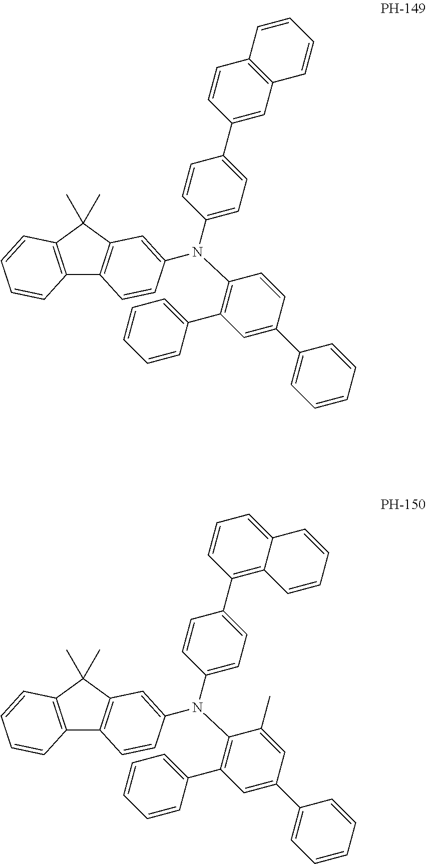 [SMILES: CC1(C)c2ccccc2-c2ccc(N(c3ccc(-c4ccc5ccccc5c4)cc3)c3ccc(-c4ccccc4)cc3-c3ccccc3)cc21 ; Cc1cc(-c2ccccc2)cc(-c2ccccc2)c1N(c1ccc(-c2cccc3ccccc23)cc1)c1ccc2c(c1)C(C)(C)c1ccccc1-2]

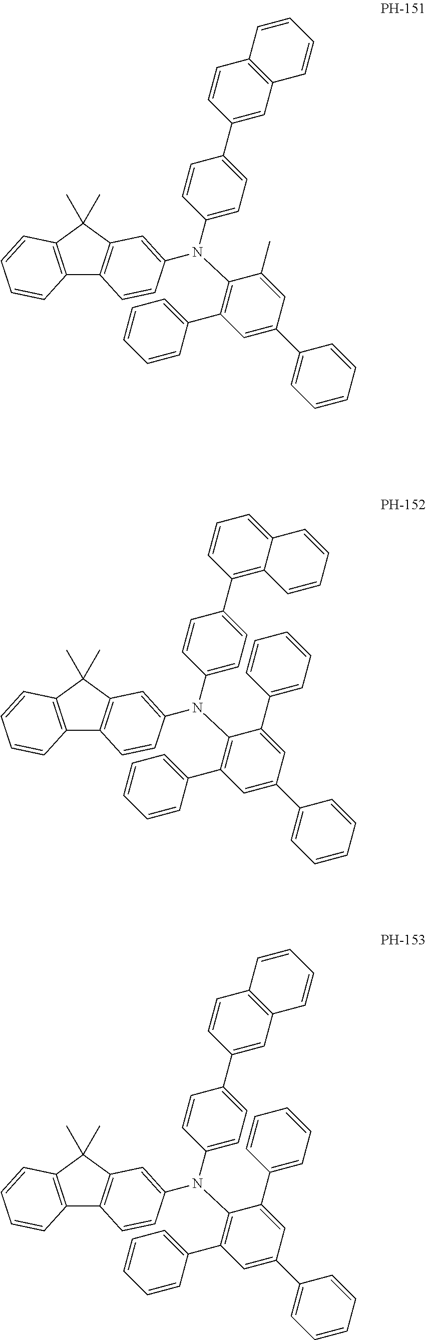 [SMILES: Cc1cc(-c2ccccc2)cc(-c2ccccc2)c1N(c1ccc(-c2ccc3ccccc3c2)cc1)c1ccc2c(c1)C(C)(C)c1ccccc1-2 ; CC1(C)c2ccccc2-c2ccc(N(c3ccc(-c4cccc5ccccc45)cc3)c3c(-c4ccccc4)cc(-c4ccccc4)cc3-c3ccccc3)cc21 ; CC1(C)c2ccccc2-c2ccc(N(c3ccc(-c4ccc5ccccc5c4)cc3)c3c(-c4ccccc4)cc(-c4ccccc4)cc3-c3ccccc3)cc21]

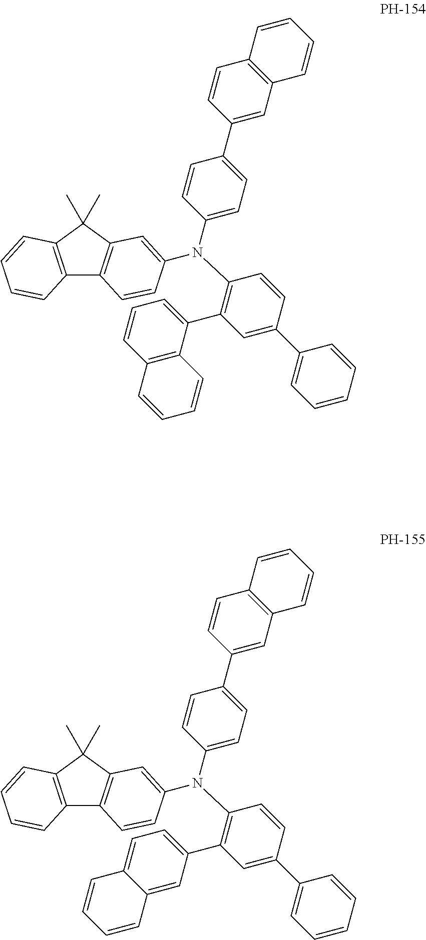 [SMILES: CC1(C)c2ccccc2-c2ccc(N(c3ccc(-c4ccc5ccccc5c4)cc3)c3ccc(-c4ccccc4)cc3-c3cccc4ccccc34)cc21 ; CC1(C)c2ccccc2-c2ccc(N(c3ccc(-c4ccc5ccccc5c4)cc3)c3ccc(-c4ccccc4)cc3-c3ccc4ccccc4c3)cc21]

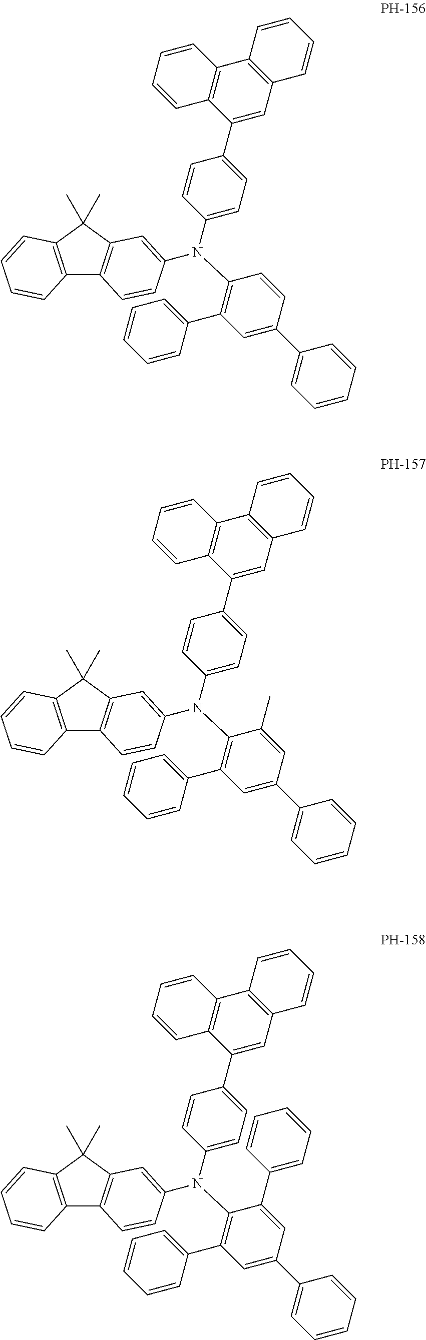 [SMILES: CC1(C)c2ccccc2-c2ccc(N(c3ccc(-c4cc5ccccc5c5ccccc45)cc3)c3ccc(-c4ccccc4)cc3-c3ccccc3)cc21 ; Cc1cc(-c2ccccc2)cc(-c2ccccc2)c1N(c1ccc(-c2cc3ccccc3c3ccccc23)cc1)c1ccc2c(c1)C(C)(C)c1ccccc1-2 ; CC1(C)c2ccccc2-c2ccc(N(c3ccc(-c4cc5ccccc5c5ccccc45)cc3)c3c(-c4ccccc4)cc(-c4ccccc4)cc3-c3ccccc3)cc21]

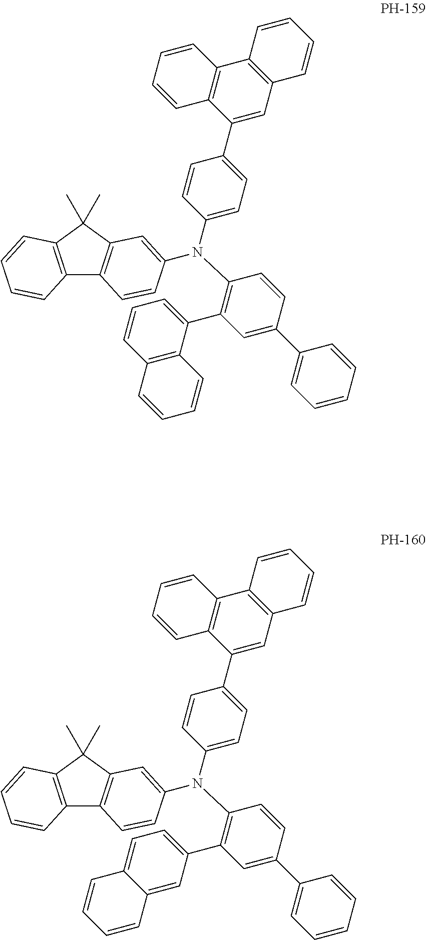 [SMILES: CC1(C)c2ccccc2-c2ccc(N(c3ccc(-c4cc5ccccc5c5ccccc45)cc3)c3ccc(-c4ccccc4)cc3-c3cccc4ccccc34)cc21 ; CC1(C)c2ccccc2-c2ccc(N(c3ccc(-c4cc5ccccc5c5ccccc45)cc3)c3ccc(-c4ccccc4)cc3-c3ccc4ccccc4c3)cc21]

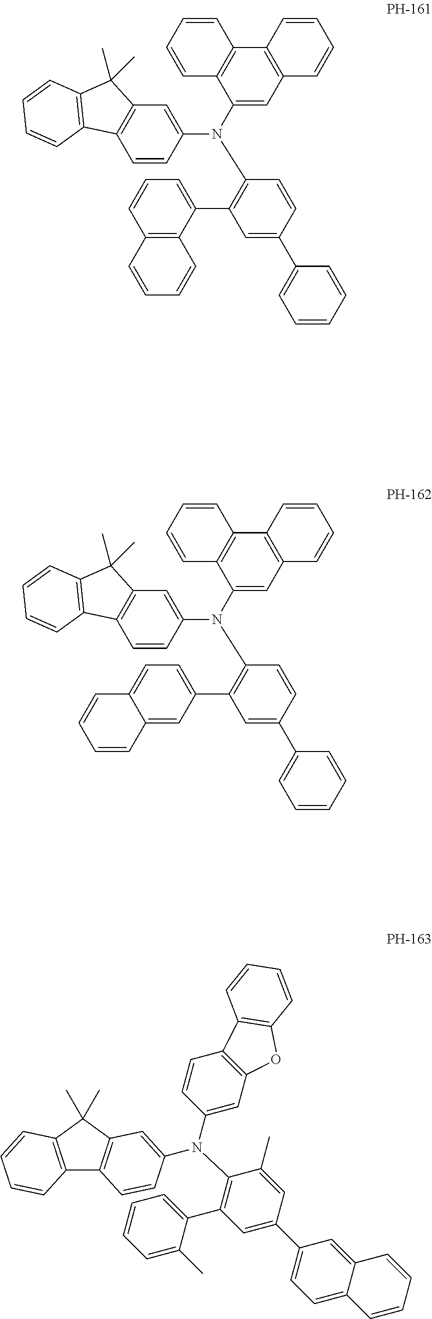 [SMILES: CC1(C)c2ccccc2-c2ccc(N(c3ccc(-c4ccccc4)cc3-c3cccc4ccccc34)c3cc4ccccc4c4ccccc34)cc21 ; CC1(C)c2ccccc2-c2ccc(N(c3ccc(-c4ccccc4)cc3-c3ccc4ccccc4c3)c3cc4ccccc4c4ccccc34)cc21 ; Cc1ccccc1-c1cc(-c2ccc3ccccc3c2)cc(C)c1N(c1ccc2c(c1)C(C)(C)c1ccccc1-2)c1ccc2c(c1)oc1ccccc12]

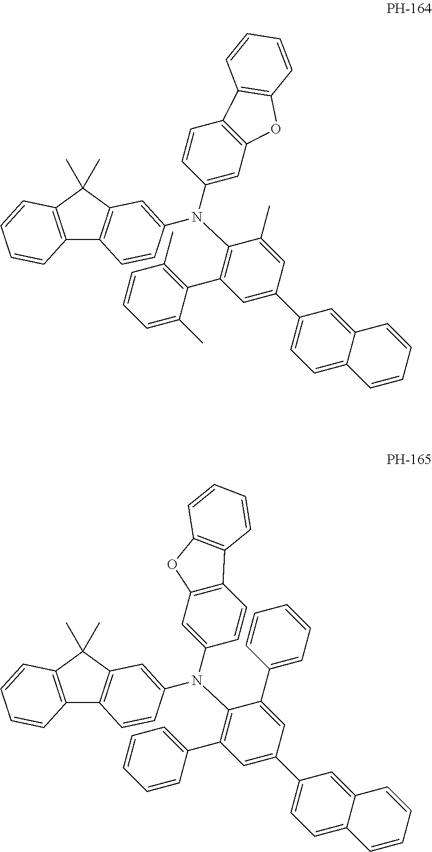 [SMILES: Cc1cccc(C)c1-c1cc(-c2ccc3ccccc3c2)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccc5ccccc5c4)cc3-c3ccccc3)cc21]

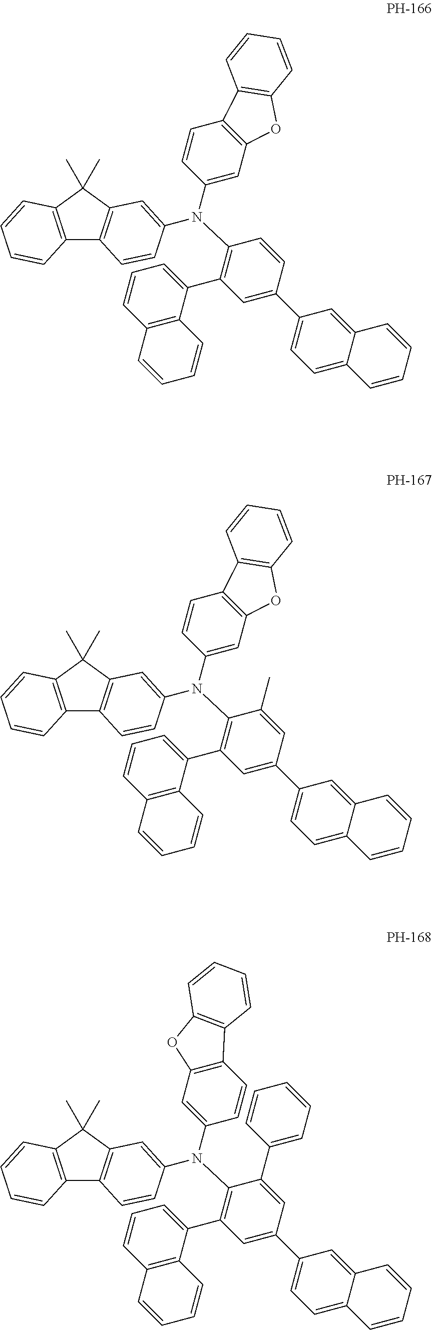 [SMILES: CC1(C)c2ccccc2-c2ccc(N(c3ccc4c(c3)oc3ccccc34)c3ccc(-c4ccc5ccccc5c4)cc3-c3cccc4ccccc34)cc21 ; Cc1cc(-c2ccc3ccccc3c2)cc(-c2cccc3ccccc23)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccc5ccccc5c4)cc3-c3cccc4ccccc34)cc21]

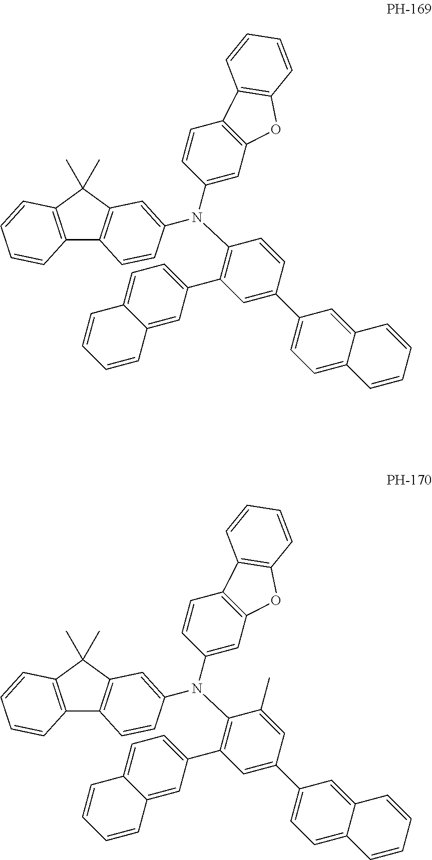 [SMILES: CC1(C)c2ccccc2-c2ccc(N(c3ccc4c(c3)oc3ccccc34)c3ccc(-c4ccc5ccccc5c4)cc3-c3ccc4ccccc4c3)cc21 ; Cc1cc(-c2ccc3ccccc3c2)cc(-c2ccc3ccccc3c2)c1N(c1ccc2c(c1)C(C)(C)c1ccccc1-2)c1ccc2c(c1)oc1ccccc12]

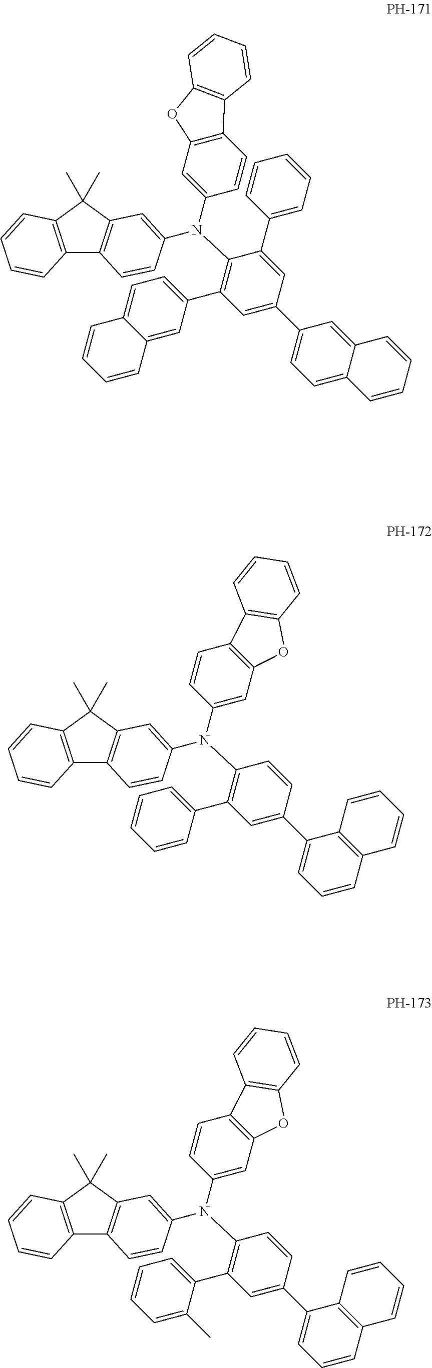 [SMILES: CC1(C)c2ccccc2-c2ccc(N(c3ccc4c(c3)oc3ccccc34)c3c(-c4ccccc4)cc(-c4ccc5ccccc5c4)cc3-c3ccc4ccccc4c3)cc21 ; CC1(C)c2ccccc2-c2ccc(N(c3ccc4c(c3)oc3ccccc34)c3ccc(-c4cccc5ccccc45)cc3-c3ccccc3)cc21 ; Cc1ccccc1-c1cc(-c2cccc3ccccc23)ccc1N(c1ccc2c(c1)C(C)(C)c1ccccc1-2)c1ccc2c(c1)oc1ccccc12]

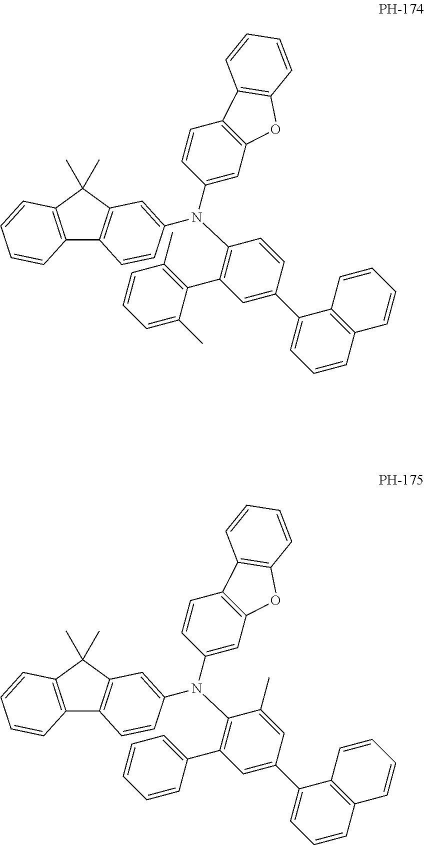 [SMILES: Cc1cccc(C)c1-c1cc(-c2cccc3ccccc23)ccc1N(c1ccc2c(c1)C(C)(C)c1ccccc1-2)c1ccc2c(c1)oc1ccccc12 ; Cc1cc(-c2cccc3ccccc23)cc(-c2ccccc2)c1N(c1ccc2c(c1)C(C)(C)c1ccccc1-2)c1ccc2c(c1)oc1ccccc12]

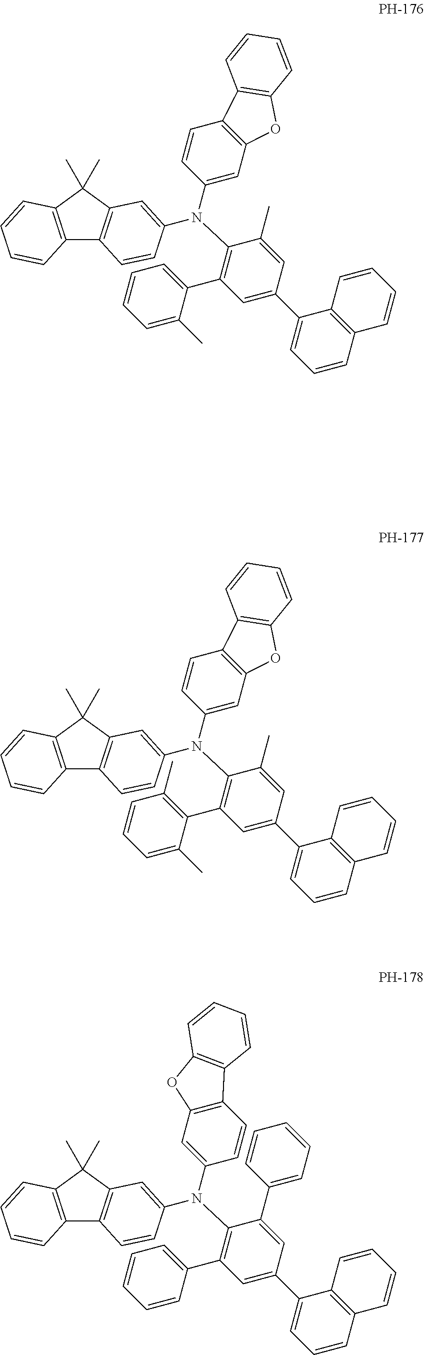 [SMILES: Cc1ccccc1-c1cc(-c2cccc3ccccc23)cc(C)c1N(c1ccc2c(c1)C(C)(C)c1ccccc1-2)c1ccc2c(c1)oc1ccccc12 ; Cc1cccc(C)c1-c1cc(-c2cccc3ccccc23)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4cccc5ccccc45)cc3-c3ccccc3)cc21]

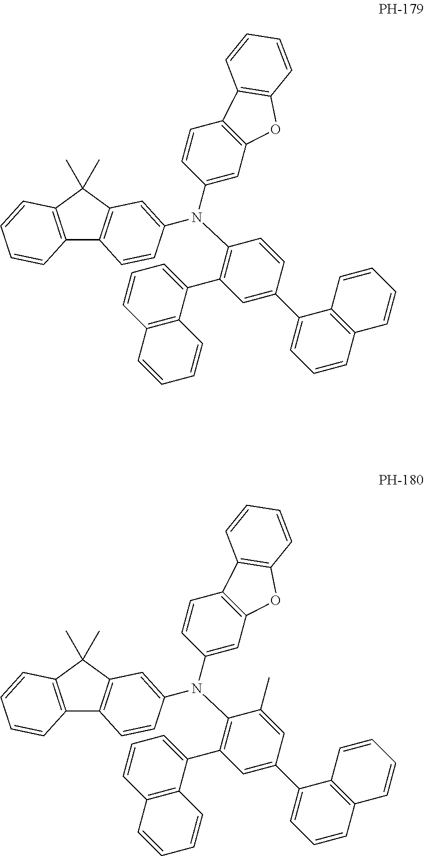 [SMILES: CC1(C)c2ccccc2-c2ccc(N(c3ccc4c(c3)oc3ccccc34)c3ccc(-c4cccc5ccccc45)cc3-c3cccc4ccccc34)cc21 ; Cc1cc(-c2cccc3ccccc23)cc(-c2cccc3ccccc23)c1N(c1ccc2c(c1)C(C)(C)c1ccccc1-2)c1ccc2c(c1)oc1ccccc12]

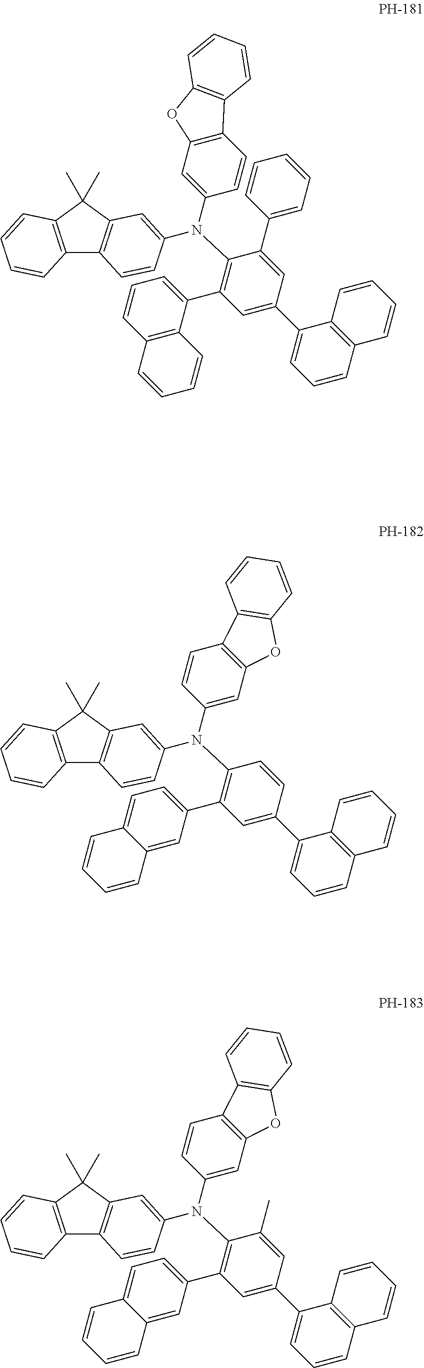 [SMILES: CC1(C)c2ccccc2-c2ccc(N(c3ccc4c(c3)oc3ccccc34)c3c(-c4ccccc4)cc(-c4cccc5ccccc45)cc3-c3cccc4ccccc34)cc21 ; CC1(C)c2ccccc2-c2ccc(N(c3ccc4c(c3)oc3ccccc34)c3ccc(-c4cccc5ccccc45)cc3-c3ccc4ccccc4c3)cc21 ; Cc1cc(-c2cccc3ccccc23)cc(-c2ccc3ccccc3c2)c1N(c1ccc2c(c1)C(C)(C)c1ccccc1-2)c1ccc2c(c1)oc1ccccc12]

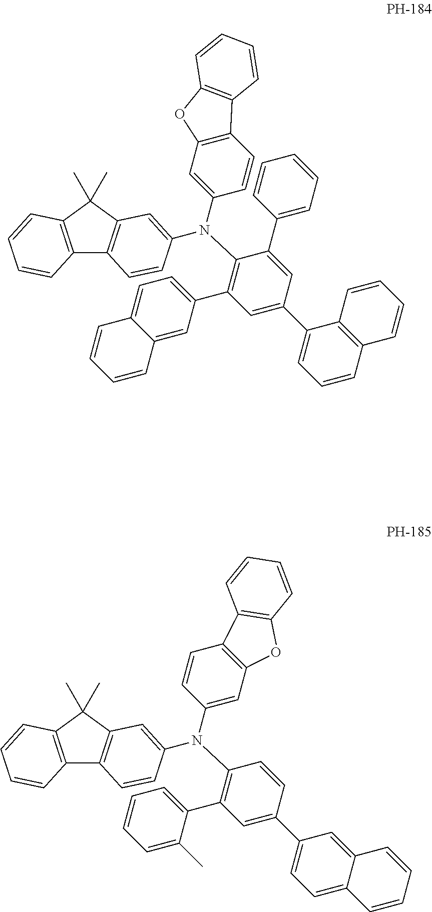 [SMILES: CC1(C)c2ccccc2-c2ccc(N(c3ccc4c(c3)oc3ccccc34)c3c(-c4ccccc4)cc(-c4cccc5ccccc45)cc3-c3ccc4ccccc4c3)cc21 ; Cc1ccccc1-c1cc(-c2ccc3ccccc3c2)ccc1N(c1ccc2c(c1)C(C)(C)c1ccccc1-2)c1ccc2c(c1)oc1ccccc12]

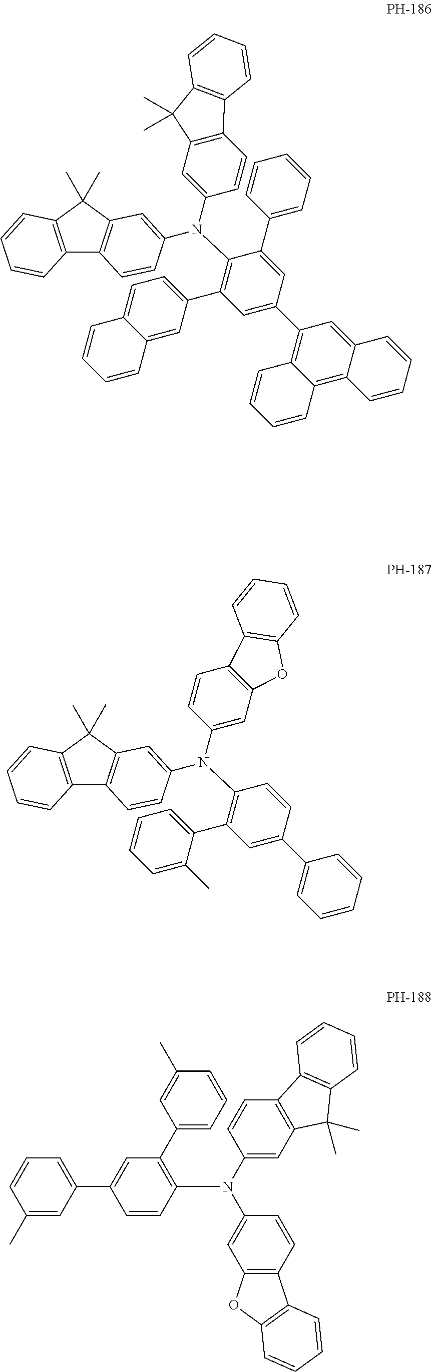 [SMILES: CC1(C)c2ccccc2-c2ccc(N(c3ccc4c(c3)C(C)(C)c3ccccc3-4)c3c(-c4ccccc4)cc(-c4cc5ccccc5c5ccccc45)cc3-c3ccc4ccccc4c3)cc21 ; Cc1ccccc1-c1cc(-c2ccccc2)ccc1N(c1ccc2c(c1)C(C)(C)c1ccccc1-2)c1ccc2c(c1)oc1ccccc12 ; Cc1cccc(-c2ccc(N(c3ccc4c(c3)C(C)(C)c3ccccc3-4)c3ccc4c(c3)oc3ccccc34)c(-c3cccc(C)c3)c2)c1]

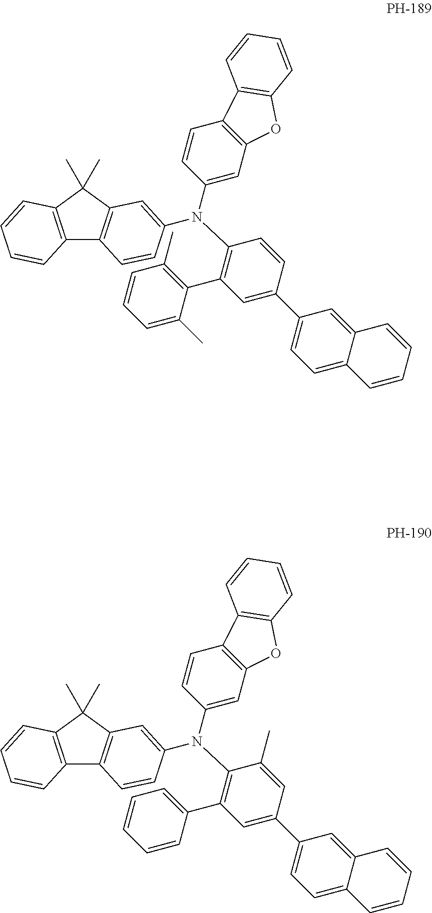 [SMILES: Cc1cccc(C)c1-c1cc(-c2ccc3ccccc3c2)ccc1N(c1ccc2c(c1)C(C)(C)c1ccccc1-2)c1ccc2c(c1)oc1ccccc12 ; Cc1cc(-c2ccc3ccccc3c2)cc(-c2ccccc2)c1N(c1ccc2c(c1)C(C)(C)c1ccccc1-2)c1ccc2c(c1)oc1ccccc12]

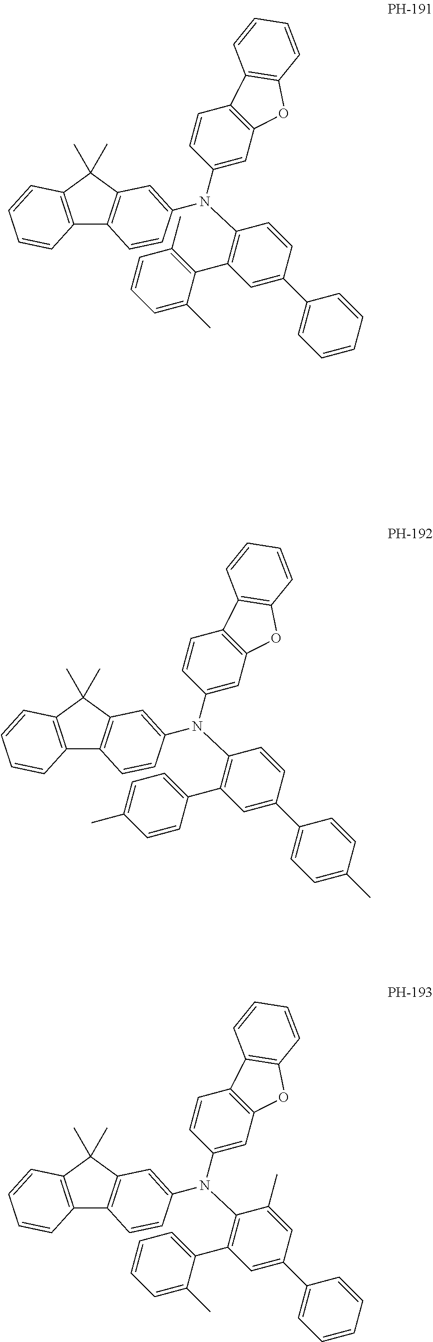 [SMILES: Cc1cccc(C)c1-c1cc(-c2ccccc2)ccc1N(c1ccc2c(c1)C(C)(C)c1ccccc1-2)c1ccc2c(c1)oc1ccccc12 ; Cc1ccc(-c2ccc(N(c3ccc4c(c3)C(C)(C)c3ccccc3-4)c3ccc4c(c3)oc3ccccc34)c(-c3ccc(C)cc3)c2)cc1 ; Cc1ccccc1-c1cc(-c2ccccc2)cc(C)c1N(c1ccc2c(c1)C(C)(C)c1ccccc1-2)c1ccc2c(c1)oc1ccccc12]

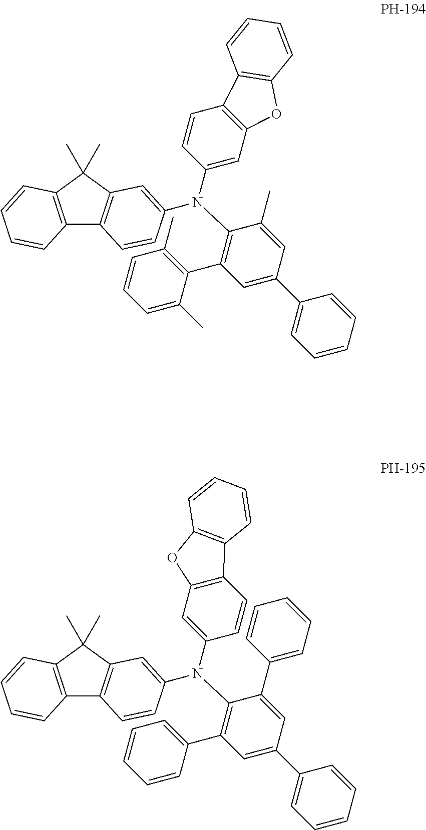 [SMILES: Cc1cccc(C)c1-c1cc(-c2ccccc2)cc(C)c1N(c1ccc2c(c1)C(C)(C)c1ccccc1-2)c1ccc2c(c1)oc1ccccc12 ; CC1(C)c2ccccc2-c2ccc(N(c3ccc4c(c3)oc3ccccc34)c3c(-c4ccccc4)cc(-c4ccccc4)cc3-c3ccccc3)cc21]

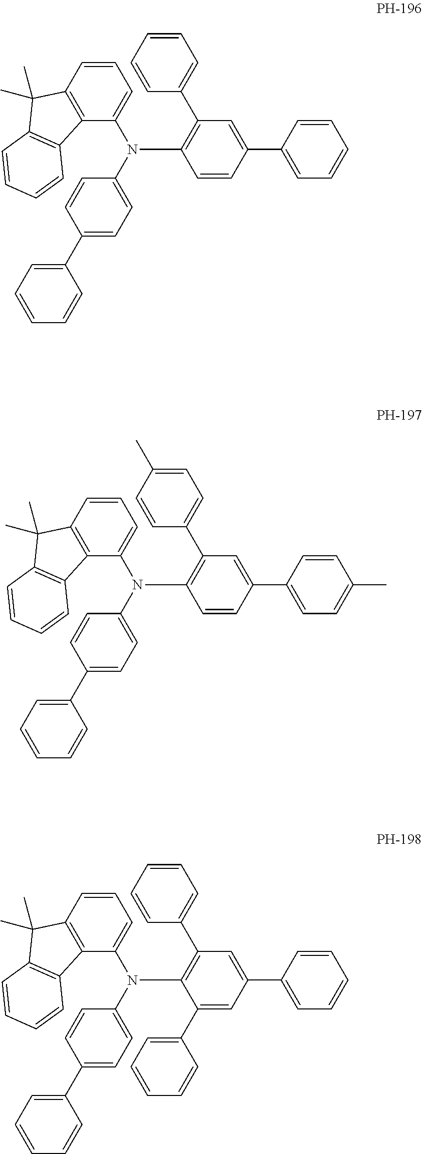

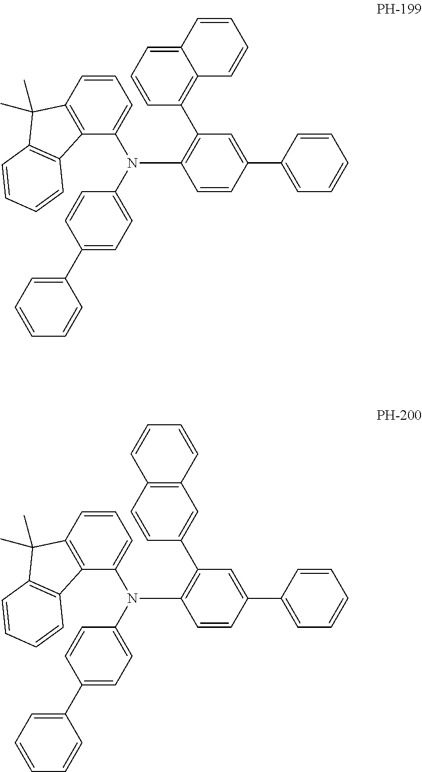 [SMILES: CC1(C)c2ccccc2-c2c(N(c3ccc(-c4ccccc4)cc3)c3ccc(-c4ccccc4)cc3-c3cccc4ccccc34)cccc21 ; CC1(C)c2ccccc2-c2c(N(c3ccc(-c4ccccc4)cc3)c3ccc(-c4ccccc4)cc3-c3ccc4ccccc4c3)cccc21]

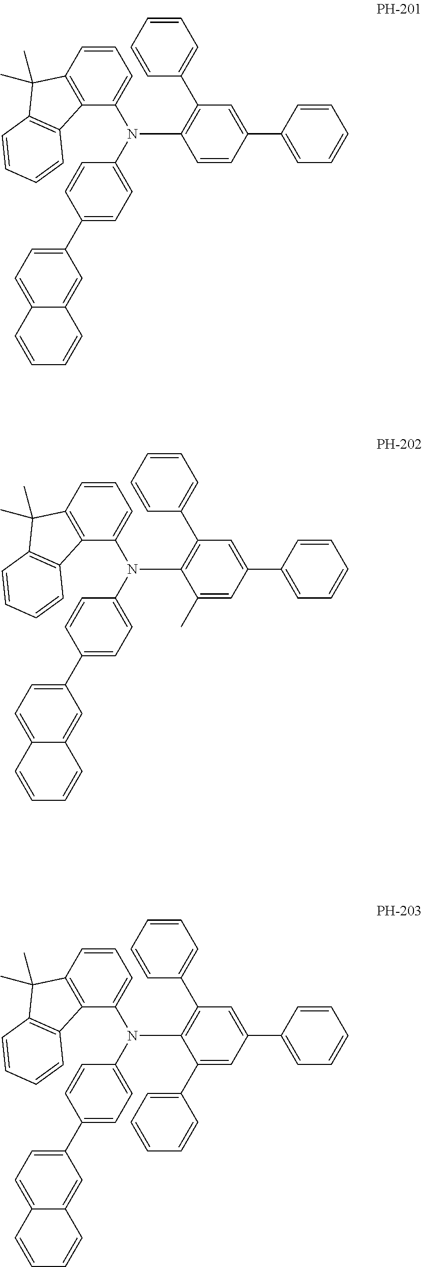 [SMILES: CC1(C)c2ccccc2-c2c(N(c3ccc(-c4ccc5ccccc5c4)cc3)c3ccc(-c4ccccc4)cc3-c3ccccc3)cccc21 ; Cc1cc(-c2ccccc2)cc(-c2ccccc2)c1N(c1ccc(-c2ccc3ccccc3c2)cc1)c1cccc2c1-c1ccccc1C2(C)C ; CC1(C)c2ccccc2-c2c(N(c3ccc(-c4ccc5ccccc5c4)cc3)c3c(-c4ccccc4)cc(-c4ccccc4)cc3-c3ccccc3)cccc21]

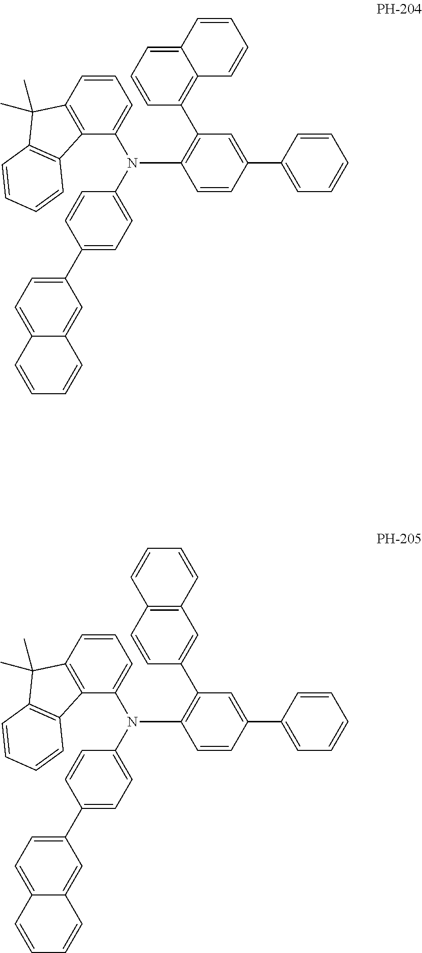 [SMILES: CC1(C)c2ccccc2-c2c(N(c3ccc(-c4ccc5ccccc5c4)cc3)c3ccc(-c4ccccc4)cc3-c3cccc4ccccc34)cccc21 ; CC1(C)c2ccccc2-c2c(N(c3ccc(-c4ccc5ccccc5c4)cc3)c3ccc(-c4ccccc4)cc3-c3ccc4ccccc4c3)cccc21]

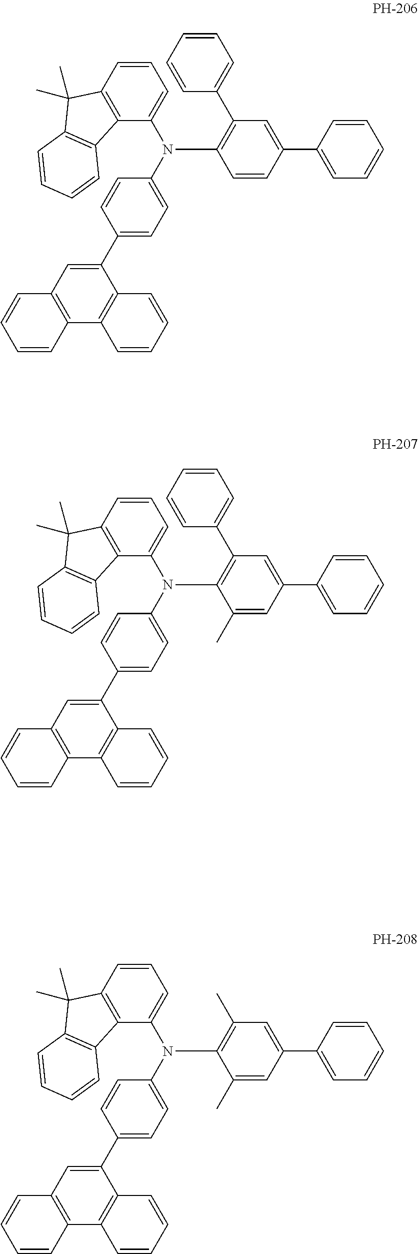 [SMILES: CC1(C)c2ccccc2-c2c(N(c3ccc(-c4cc5ccccc5c5ccccc45)cc3)c3ccc(-c4ccccc4)cc3-c3ccccc3)cccc21 ; Cc1cc(-c2ccccc2)cc(-c2ccccc2)c1N(c1ccc(-c2cc3ccccc3c3ccccc23)cc1)c1cccc2c1-c1ccccc1C2(C)C ; Cc1cc(-c2ccccc2)cc(C)c1N(c1ccc(-c2cc3ccccc3c3ccccc23)cc1)c1cccc2c1-c1ccccc1C2(C)C]

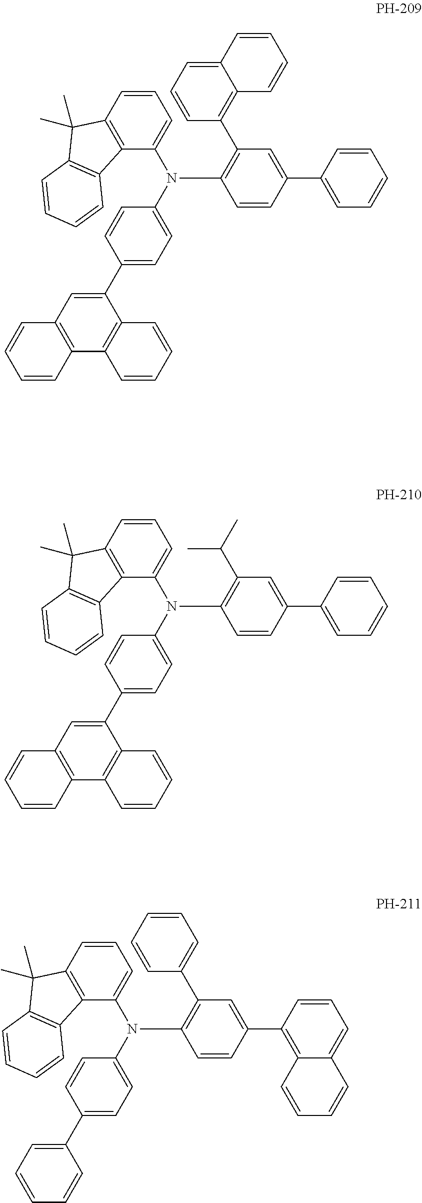 [SMILES: CC1(C)c2ccccc2-c2c(N(c3ccc(-c4cc5ccccc5c5ccccc45)cc3)c3ccc(-c4ccccc4)cc3-c3cccc4ccccc34)cccc21 ; CC(C)c1cc(-c2ccccc2)ccc1N(c1ccc(-c2cc3ccccc3c3ccccc23)cc1)c1cccc2c1-c1ccccc1C2(C)C ; CC1(C)c2ccccc2-c2c(N(c3ccc(-c4ccccc4)cc3)c3ccc(-c4cccc5ccccc45)cc3-c3ccccc3)cccc21]

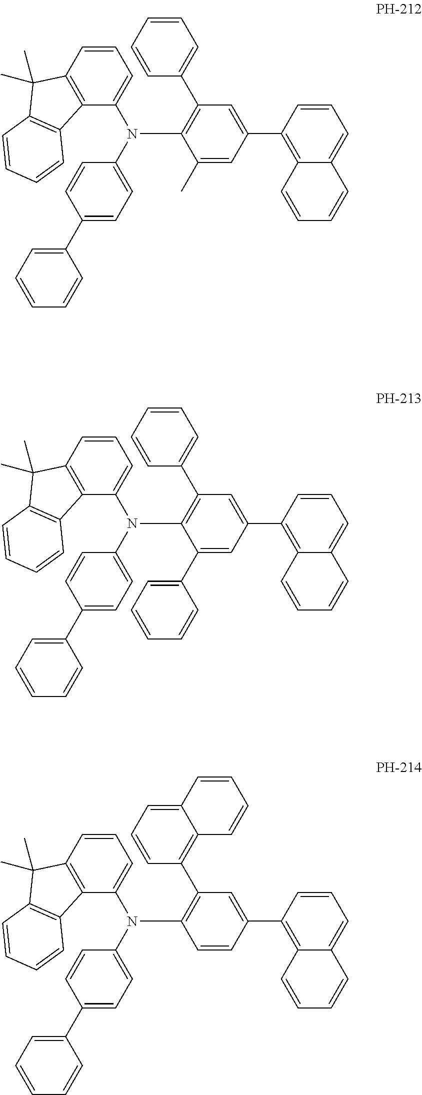 [SMILES: Cc1cc(-c2cccc3ccccc23)cc(-c2ccccc2)c1N(c1ccc(-c2ccccc2)cc1)c1cccc2c1-c1ccccc1C2(C)C ; CC1(C)c2ccccc2-c2c(N(c3ccc(-c4ccccc4)cc3)c3c(-c4ccccc4)cc(-c4cccc5ccccc45)cc3-c3ccccc3)cccc21 ; CC1(C)c2ccccc2-c2c(N(c3ccc(-c4ccccc4)cc3)c3ccc(-c4cccc5ccccc45)cc3-c3cccc4ccccc34)cccc21]

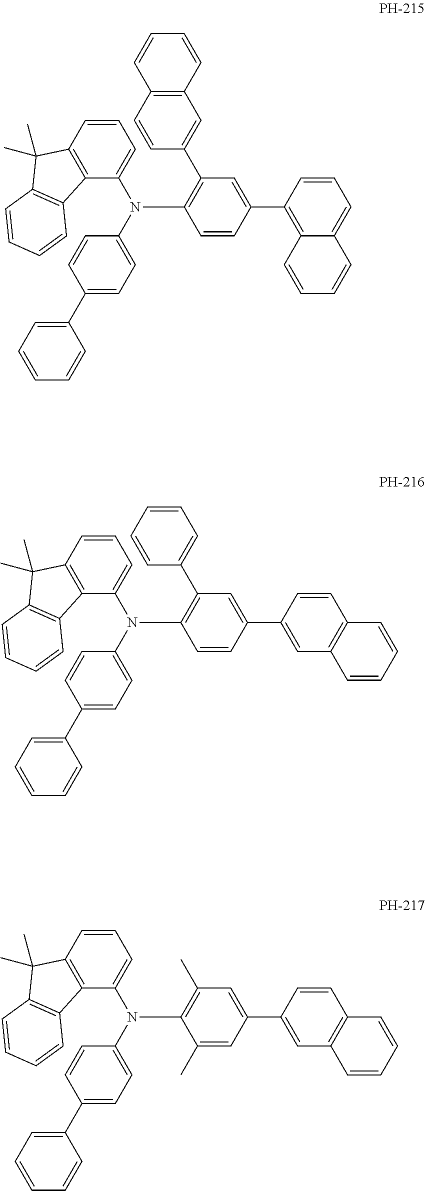 [SMILES: CC1(C)c2ccccc2-c2c(N(c3ccc(-c4ccccc4)cc3)c3ccc(-c4cccc5ccccc45)cc3-c3ccc4ccccc4c3)cccc21 ; CC1(C)c2ccccc2-c2c(N(c3ccc(-c4ccccc4)cc3)c3ccc(-c4ccc5ccccc5c4)cc3-c3ccccc3)cccc21 ; Cc1cc(-c2ccc3ccccc3c2)cc(C)c1N(c1ccc(-c2ccccc2)cc1)c1cccc2c1-c1ccccc1C2(C)C]

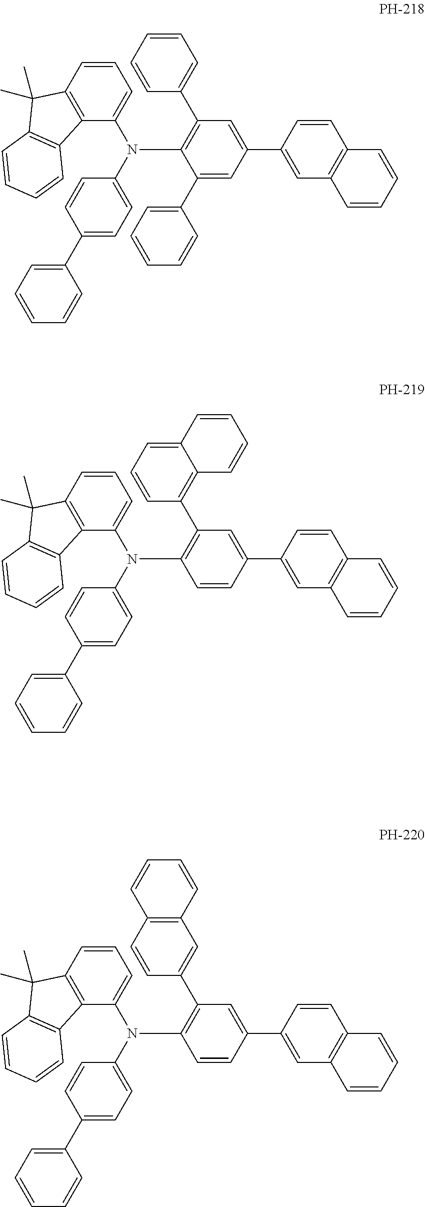 [SMILES: CC1(C)c2ccccc2-c2c(N(c3ccc(-c4ccccc4)cc3)c3c(-c4ccccc4)cc(-c4ccc5ccccc5c4)cc3-c3ccccc3)cccc21 ; CC1(C)c2ccccc2-c2c(N(c3ccc(-c4ccccc4)cc3)c3ccc(-c4ccc5ccccc5c4)cc3-c3cccc4ccccc34)cccc21 ; CC1(C)c2ccccc2-c2c(N(c3ccc(-c4ccccc4)cc3)c3ccc(-c4ccc5ccccc5c4)cc3-c3ccc4ccccc4c3)cccc21]

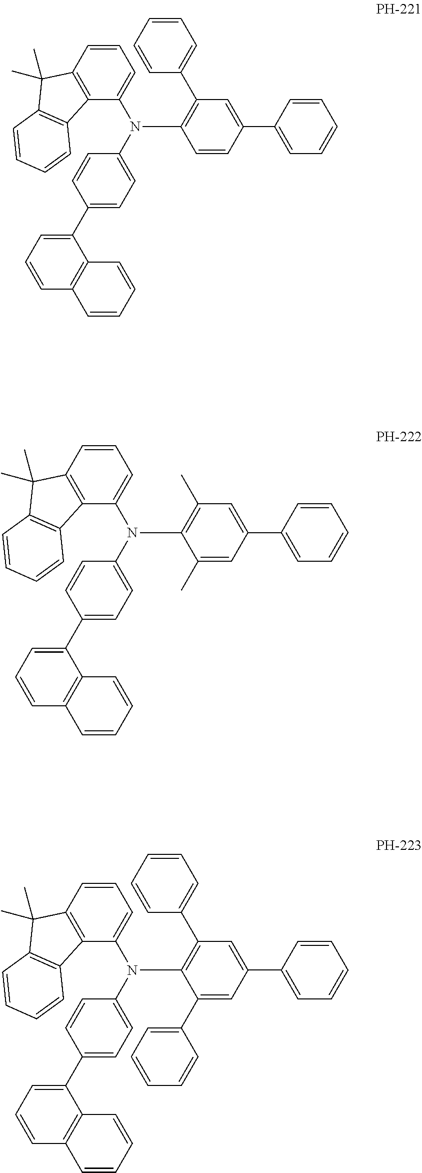 [SMILES: CC1(C)c2ccccc2-c2c(N(c3ccc(-c4cccc5ccccc45)cc3)c3ccc(-c4ccccc4)cc3-c3ccccc3)cccc21 ; Cc1cc(-c2ccccc2)cc(C)c1N(c1ccc(-c2cccc3ccccc23)cc1)c1cccc2c1-c1ccccc1C2(C)C ; CC1(C)c2ccccc2-c2c(N(c3ccc(-c4cccc5ccccc45)cc3)c3c(-c4ccccc4)cc(-c4ccccc4)cc3-c3ccccc3)cccc21]

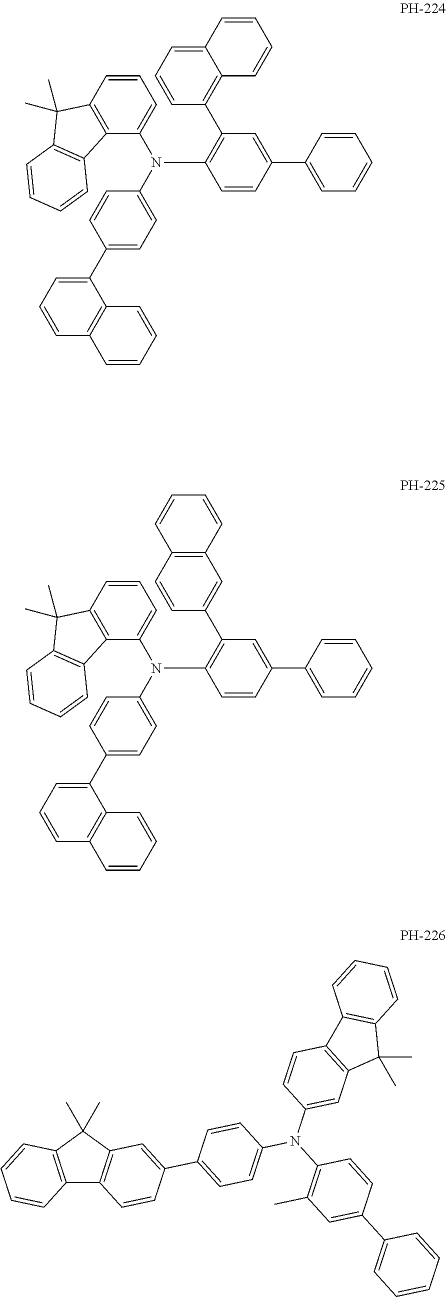 [SMILES: CC1(C)c2ccccc2-c2c(N(c3ccc(-c4cccc5ccccc45)cc3)c3ccc(-c4ccccc4)cc3-c3cccc4ccccc34)cccc21 ; CC1(C)c2ccccc2-c2c(N(c3ccc(-c4cccc5ccccc45)cc3)c3ccc(-c4ccccc4)cc3-c3ccc4ccccc4c3)cccc21 ; Cc1cc(-c2ccccc2)ccc1N(c1ccc(-c2ccc3c(c2)C(C)(C)c2ccccc2-3)cc1)c1ccc2c(c1)C(C)(C)c1ccccc1-2]

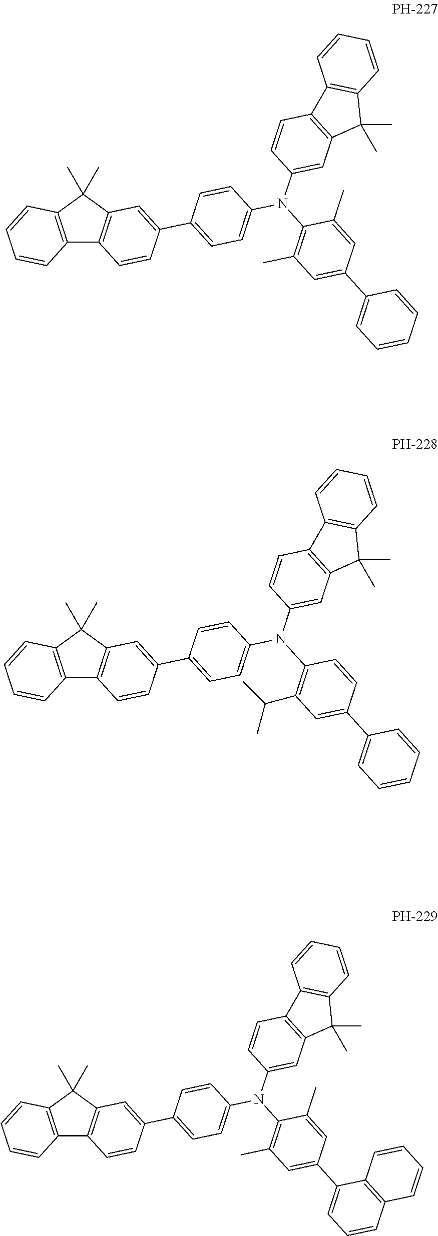 [SMILES: Cc1cc(-c2ccccc2)cc(C)c1N(c1ccc(-c2ccc3c(c2)C(C)(C)c2ccccc2-3)cc1)c1ccc2c(c1)C(C)(C)c1ccccc1-2 ; CC(C)c1cc(-c2ccccc2)ccc1N(c1ccc(-c2ccc3c(c2)C(C)(C)c2ccccc2-3)cc1)c1ccc2c(c1)C(C)(C)c1ccccc1-2 ; Cc1cc(-c2cccc3ccccc23)cc(C)c1N(c1ccc(-c2ccc3c(c2)C(C)(C)c2ccccc2-3)cc1)c1ccc2c(c1)C(C)(C)c1ccccc1-2]

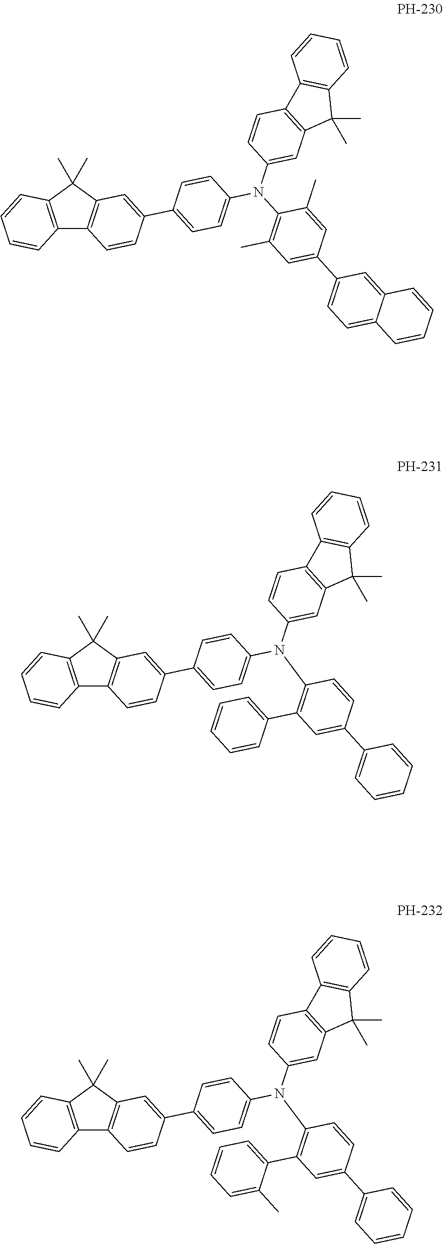 [SMILES: Cc1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4ccc(-c5ccccc5)cc4-c4ccccc4)cc3)cc21 ; Cc1ccccc1-c1cc(-c2ccccc2)ccc1N(c1ccc(-c2ccc3c(c2)C(C)(C)c2ccccc2-3)cc1)c1ccc2c(c1)C(C)(C)c1ccccc1-2]

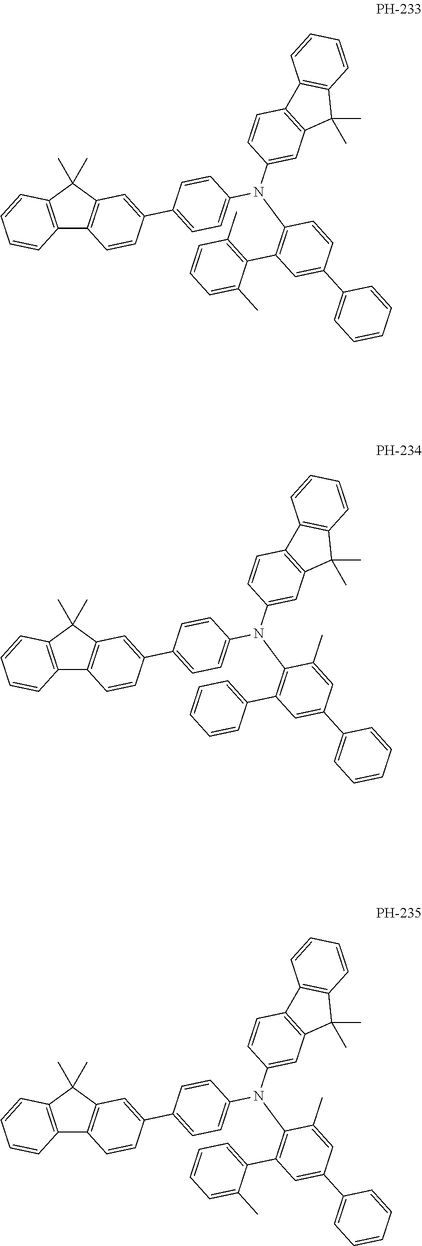 [SMILES: Cc1cccc(C)c1-c1cc(-c2ccccc2)ccc1N(c1ccc(-c2ccc3c(c2)C(C)(C)c2ccccc2-3)cc1)c1ccc2c(c1)C(C)(C)c1ccccc1-2 ; Cc1cc(-c2ccccc2)cc(-c2ccccc2)c1N(c1ccc(-c2ccc3c(c2)C(C)(C)c2ccccc2-3)cc1)c1ccc2c(c1)C(C)(C)c1ccccc1-2 ; Cc1ccccc1-c1cc(-c2ccccc2)cc(C)c1N(c1ccc(-c2ccc3c(c2)C(C)(C)c2ccccc2-3)cc1)c1ccc2c(c1)C(C)(C)c1ccccc1-2]

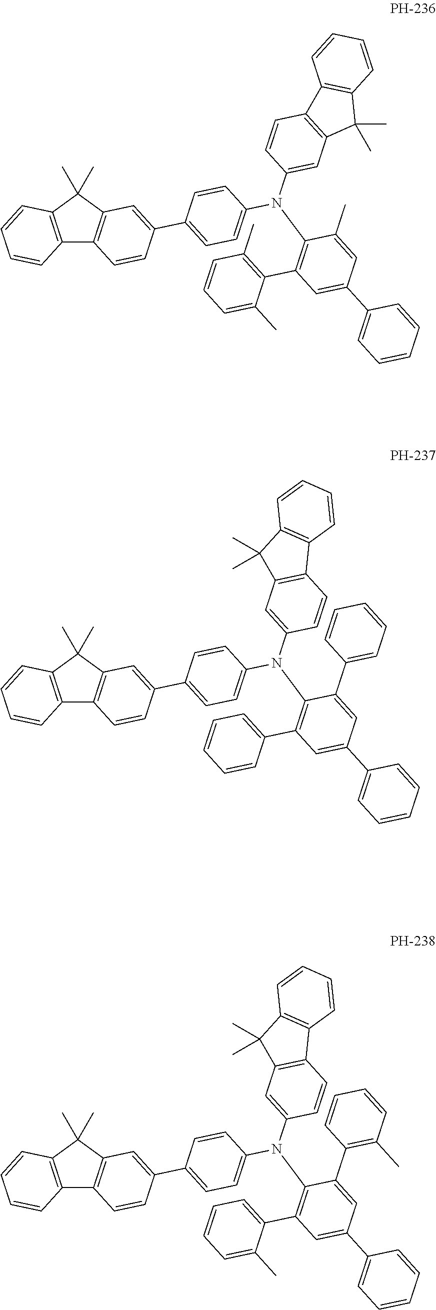 [SMILES: Cc1cccc(C)c1-c1cc(-c2ccccc2)cc(C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccccc5)cc4-c4ccccc4)cc3)cc21 ; Cc1ccccc1-c1cc(-c2ccccc2)cc(-c2ccccc2C)c1N(c1ccc(-c2ccc3c(c2)C(C)(C)c2ccccc2-3)cc1)c1ccc2c(c1)C(C)(C)c1ccccc1-2]

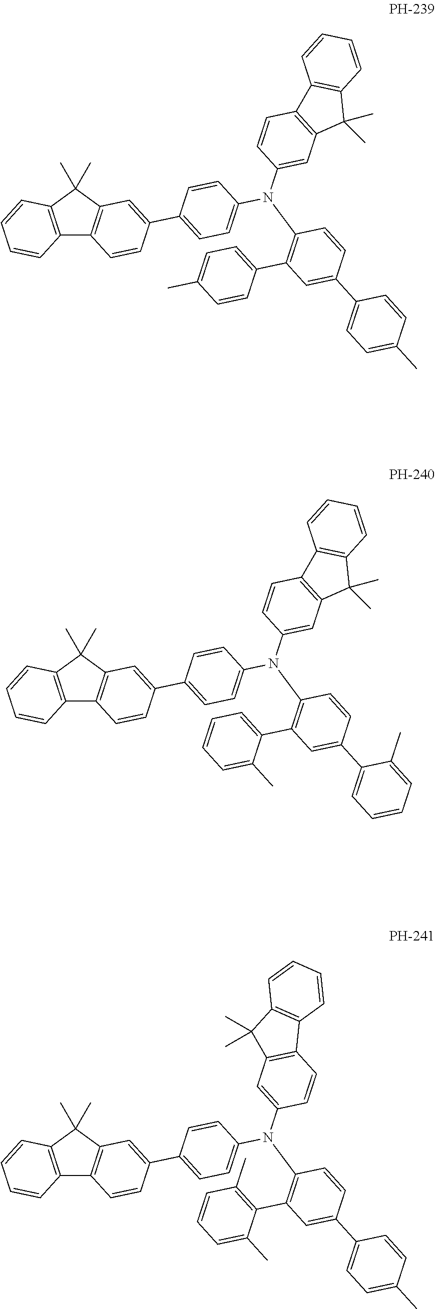 [SMILES: Cc1ccc(-c2ccc(N(c3ccc(-c4ccc5c(c4)C(C)(C)c4ccccc4-5)cc3)c3ccc4c(c3)C(C)(C)c3ccccc3-4)c(-c3ccc(C)cc3)c2)cc1 ; Cc1ccccc1-c1ccc(N(c2ccc(-c3ccc4c(c3)C(C)(C)c3ccccc3-4)cc2)c2ccc3c(c2)C(C)(C)c2ccccc2-3)c(-c2ccccc2C)c1 ; Cc1ccc(-c2ccc(N(c3ccc(-c4ccc5c(c4)C(C)(C)c4ccccc4-5)cc3)c3ccc4c(c3)C(C)(C)c3ccccc3-4)c(-c3c(C)cccc3C)c2)cc1]

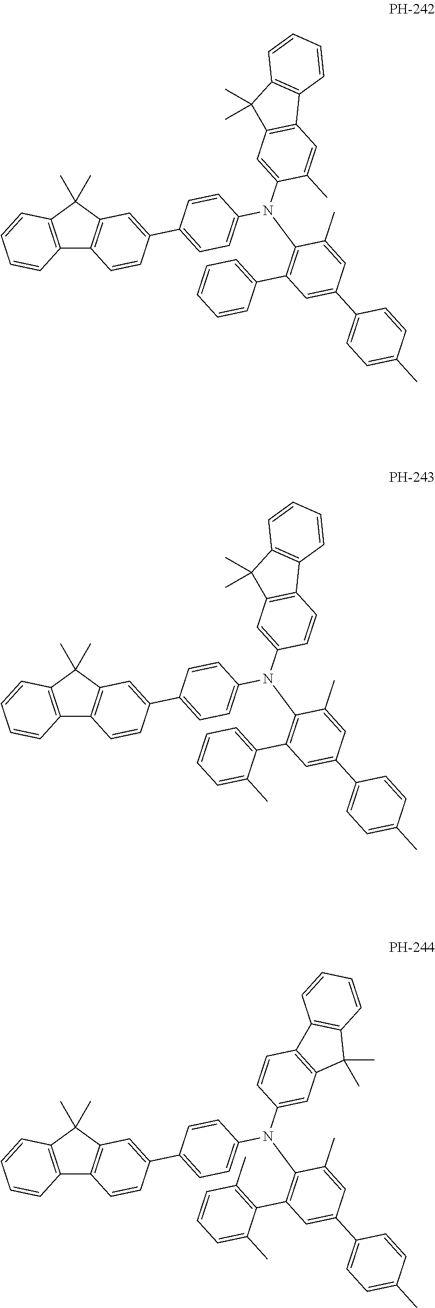 [SMILES: Cc1ccc(-c2cc(C)c(N(c3ccc(-c4ccc5c(c4)C(C)(C)c4ccccc4-5)cc3)c3cc4c(cc3C)-c3ccccc3C4(C)C)c(-c3ccccc3)c2)cc1 ; Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3ccccc3C)c2)cc1 ; Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3c(C)cccc3C)c2)cc1]

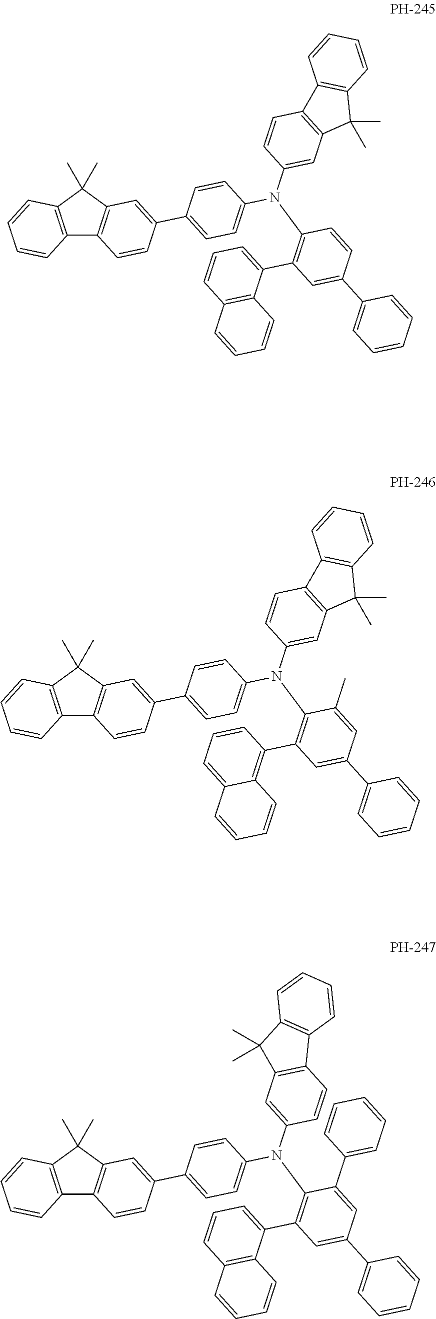 [SMILES: CC1(C)c2ccccc2-c2ccc(-c3ccc(N(c4ccc5c(c4)C(C)(C)c4ccccc4-5)c4ccc(-c5ccccc5)cc4-c4cccc5ccccc45)cc3)cc21 ; Cc1cc(-c2ccccc2)cc(-c2cccc3ccccc23)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccccc5)cc4-c4cccc5ccccc45)cc3)cc21]

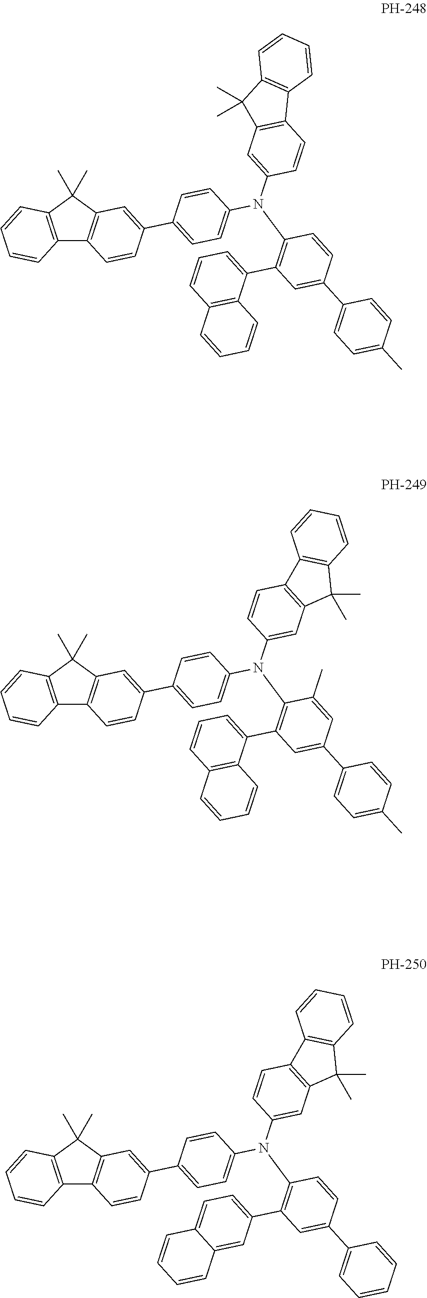 [SMILES: Cc1ccc(-c2ccc(N(c3ccc(-c4ccc5c(c4)C(C)(C)c4ccccc4-5)cc3)c3ccc4c(c3)C(C)(C)c3ccccc3-4)c(-c3cccc4ccccc34)c2)cc1 ; Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3cccc4ccccc34)c2)cc1 ; CC1(C)c2ccccc2-c2ccc(-c3ccc(N(c4ccc5c(c4)C(C)(C)c4ccccc4-5)c4ccc(-c5ccccc5)cc4-c4ccc5ccccc5c4)cc3)cc21]

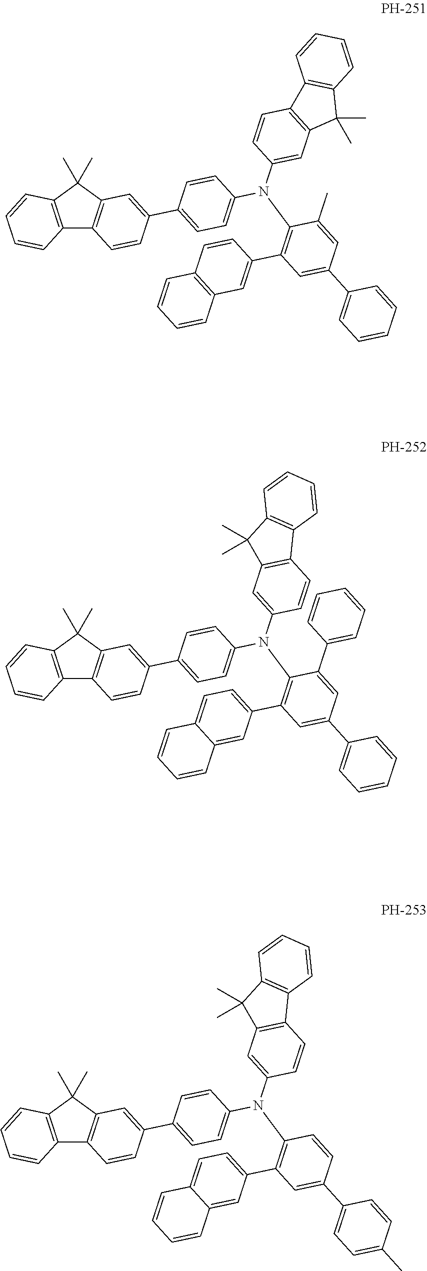 [SMILES: Cc1cc(-c2ccccc2)cc(-c2ccc3ccccc3c2)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccccc5)cc4-c4ccc5ccccc5c4)cc3)cc21 ; Cc1ccc(-c2ccc(N(c3ccc(-c4ccc5c(c4)C(C)(C)c4ccccc4-5)cc3)c3ccc4c(c3)C(C)(C)c3ccccc3-4)c(-c3ccc4ccccc4c3)c2)cc1]

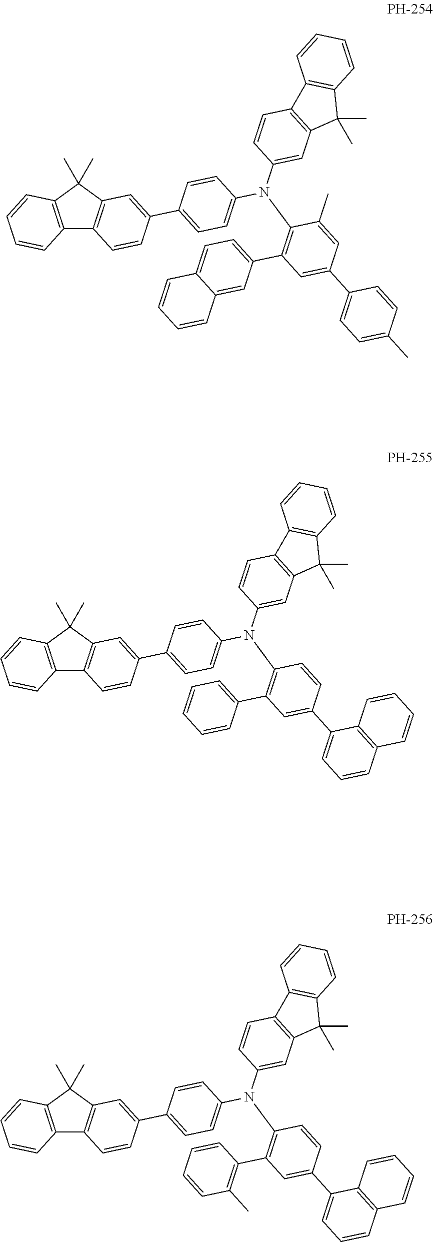 [SMILES: Cc1ccc(-c2cc(C)c(N(c3ccc(-c4ccc5c(c4)C(C)(C)c4ccccc4-5)cc3)c3ccc4c(c3)C(C)(C)c3ccccc3-4)c(-c3ccc4ccccc4c3)c2)cc1 ; CC1(C)c2ccccc2-c2ccc(-c3ccc(N(c4ccc5c(c4)C(C)(C)c4ccccc4-5)c4ccc(-c5cccc6ccccc56)cc4-c4ccccc4)cc3)cc21 ; Cc1ccccc1-c1cc(-c2cccc3ccccc23)ccc1N(c1ccc(-c2ccc3c(c2)C(C)(C)c2ccccc2-3)cc1)c1ccc2c(c1)C(C)(C)c1ccccc1-2]

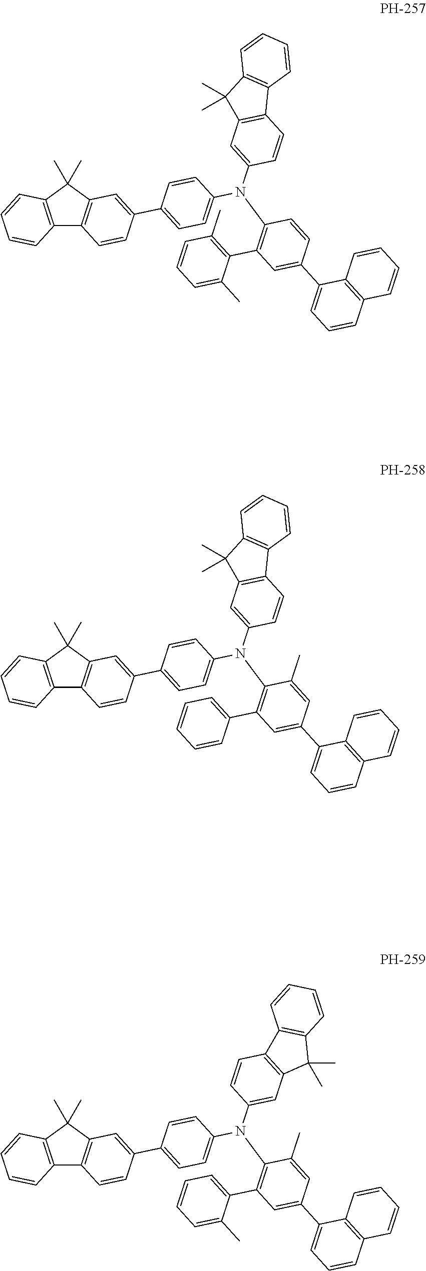 [SMILES: Cc1cccc(C)c1-c1cc(-c2cccc3ccccc23)ccc1N(c1ccc(-c2ccc3c(c2)C(C)(C)c2ccccc2-3)cc1)c1ccc2c(c1)C(C)(C)c1ccccc1-2 ; Cc1cc(-c2cccc3ccccc23)cc(-c2ccccc2)c1N(c1ccc(-c2ccc3c(c2)C(C)(C)c2ccccc2-3)cc1)c1ccc2c(c1)C(C)(C)c1ccccc1-2 ; Cc1ccccc1-c1cc(-c2cccc3ccccc23)cc(C)c1N(c1ccc(-c2ccc3c(c2)C(C)(C)c2ccccc2-3)cc1)c1ccc2c(c1)C(C)(C)c1ccccc1-2]

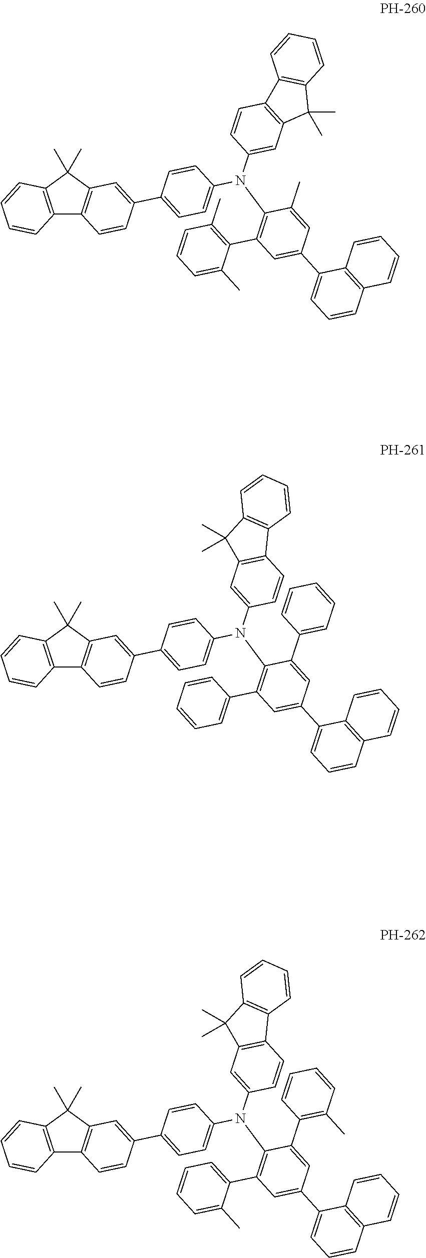 [SMILES: Cc1cccc(C)c1-c1cc(-c2cccc3ccccc23)cc(C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5cccc6ccccc56)cc4-c4ccccc4)cc3)cc21 ; Cc1ccccc1-c1cc(-c2cccc3ccccc23)cc(-c2ccccc2C)c1N(c1ccc(-c2ccc3c(c2)C(C)(C)c2ccccc2-3)cc1)c1ccc2c(c1)C(C)(C)c1ccccc1-2]

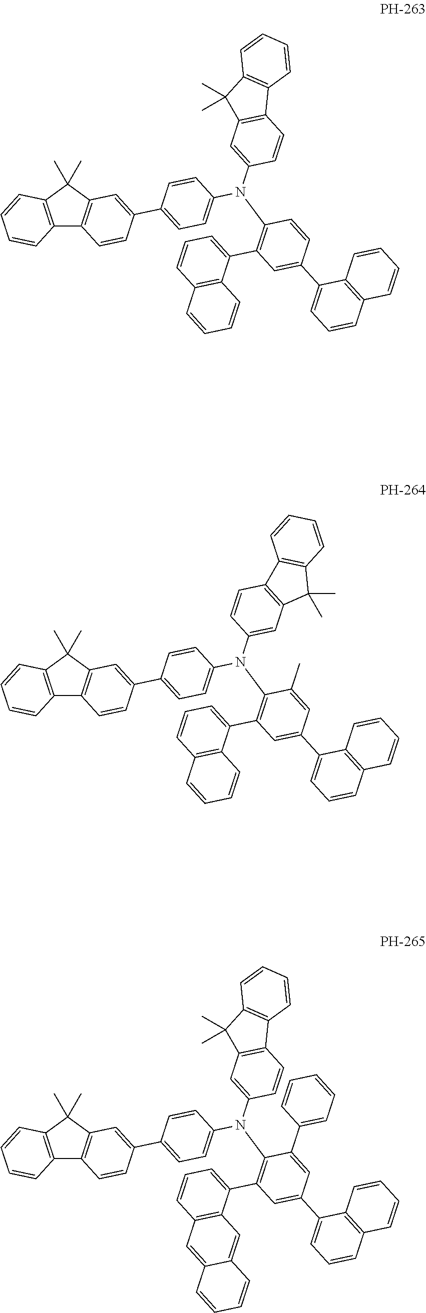 [SMILES: CC1(C)c2ccccc2-c2ccc(-c3ccc(N(c4ccc5c(c4)C(C)(C)c4ccccc4-5)c4ccc(-c5cccc6ccccc56)cc4-c4cccc5ccccc45)cc3)cc21 ; Cc1cc(-c2cccc3ccccc23)cc(-c2cccc3ccccc23)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5cccc6ccccc56)cc4-c4cccc5cc6ccccc6cc45)cc3)cc21]

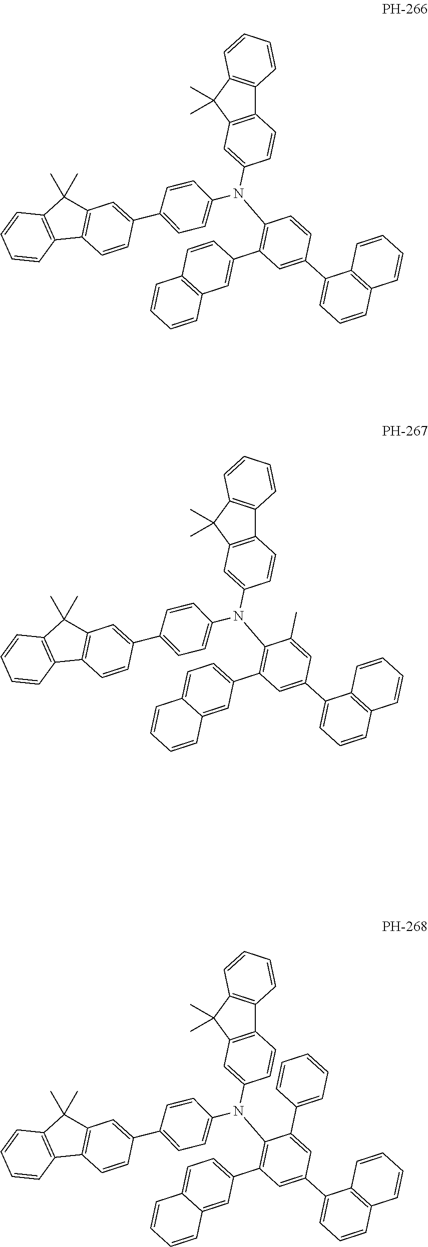 [SMILES: CC1(C)c2ccccc2-c2ccc(-c3ccc(N(c4ccc5c(c4)C(C)(C)c4ccccc4-5)c4ccc(-c5cccc6ccccc56)cc4-c4ccc5ccccc5c4)cc3)cc21 ; Cc1cc(-c2cccc3ccccc23)cc(-c2ccc3ccccc3c2)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5cccc6ccccc56)cc4-c4ccc5ccccc5c4)cc3)cc21]

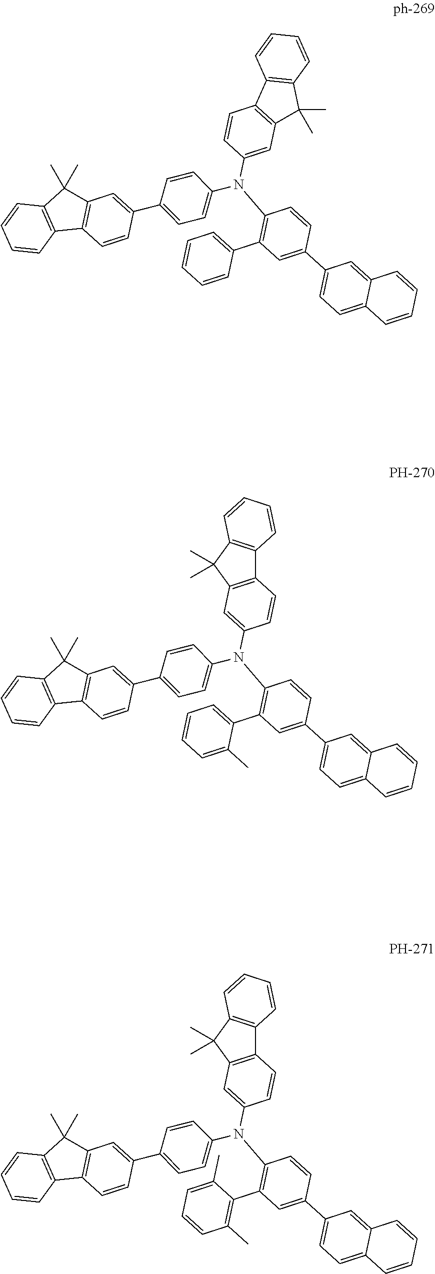 [SMILES: CC1(C)c2ccccc2-c2ccc(-c3ccc(N(c4ccc5c(c4)C(C)(C)c4ccccc4-5)c4ccc(-c5ccc6ccccc6c5)cc4-c4ccccc4)cc3)cc21 ; Cc1ccccc1-c1cc(-c2ccc3ccccc3c2)ccc1N(c1ccc(-c2ccc3c(c2)C(C)(C)c2ccccc2-3)cc1)c1ccc2c(c1)C(C)(C)c1ccccc1-2 ; Cc1cccc(C)c1-c1cc(-c2ccc3ccccc3c2)ccc1N(c1ccc(-c2ccc3c(c2)C(C)(C)c2ccccc2-3)cc1)c1ccc2c(c1)C(C)(C)c1ccccc1-2]

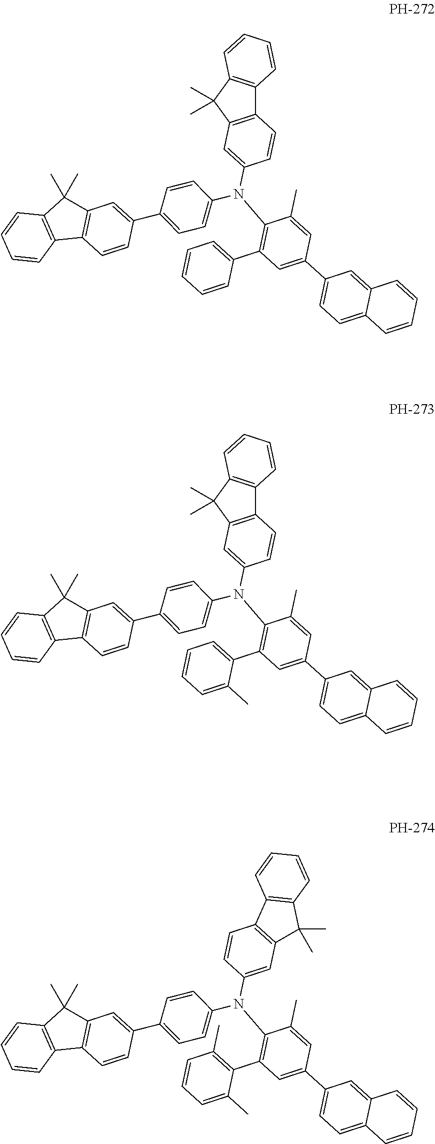 [SMILES: Cc1cc(-c2ccc3ccccc3c2)cc(-c2ccccc2)c1N(c1ccc(-c2ccc3c(c2)C(C)(C)c2ccccc2-3)cc1)c1ccc2c(c1)C(C)(C)c1ccccc1-2 ; Cc1ccccc1-c1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2 ; Cc1cccc(C)c1-c1cc(-c2ccc3ccccc3c2)cc(C)c1N(c1ccc(-c2ccc3c(c2)C(C)(C)c2ccccc2-3)cc1)c1ccc2c(c1)C(C)(C)c1ccccc1-2]

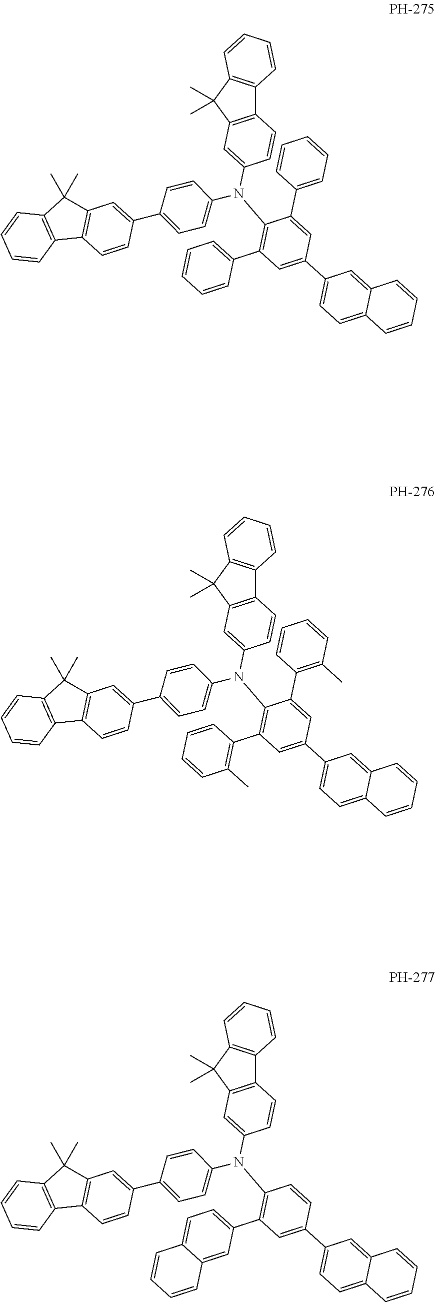 [SMILES: CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4ccccc4)cc3)cc21 ; Cc1ccccc1-c1cc(-c2ccc3ccccc3c2)cc(-c2ccccc2C)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4ccc(-c5ccc6ccccc6c5)cc4-c4ccc5ccccc5c4)cc3)cc21]

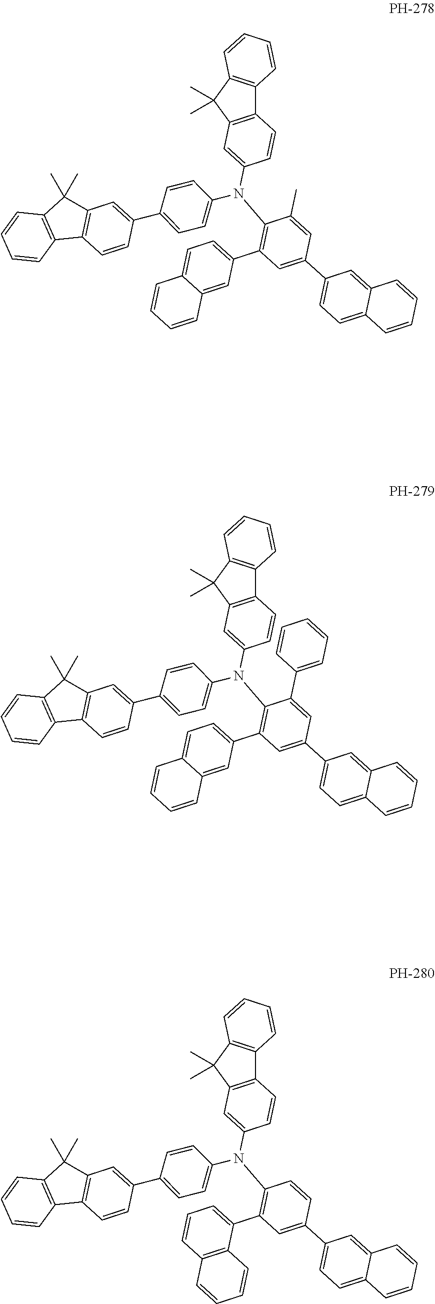 [SMILES: Cc1cc(-c2ccc3ccccc3c2)cc(-c2ccc3ccccc3c2)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4ccc5ccccc5c4)cc3)cc21 ; CC1(C)c2ccccc2-c2ccc(-c3ccc(N(c4ccc5c(c4)C(C)(C)c4ccccc4-5)c4ccc(-c5ccc6ccccc6c5)cc4-c4cccc5ccccc45)cc3)cc21]

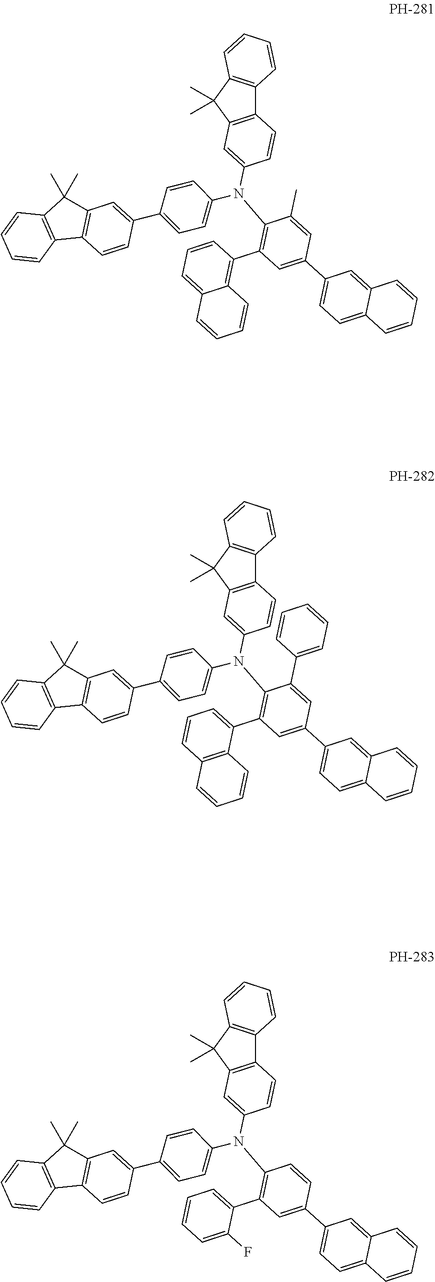 [SMILES: Cc1cc(-c2ccc3ccccc3c2)cc(-c2cccc3ccccc23)c1N(c1ccc(-c2ccc3c(c2)C(C)(C)c2ccccc2-3)cc1)c1ccc2c(c1)C(C)(C)c1ccccc1-2 ; CC1(C)c2ccccc2-c2ccc(-c3ccc(N(c4ccc5c(c4)C(C)(C)c4ccccc4-5)c4c(-c5ccccc5)cc(-c5ccc6ccccc6c5)cc4-c4cccc5ccccc45)cc3)cc21 ; CC1(C)c2ccccc2-c2ccc(-c3ccc(N(c4ccc5c(c4)C(C)(C)c4ccccc4-5)c4ccc(-c5ccc6ccccc6c5)cc4-c4ccccc4F)cc3)cc21]

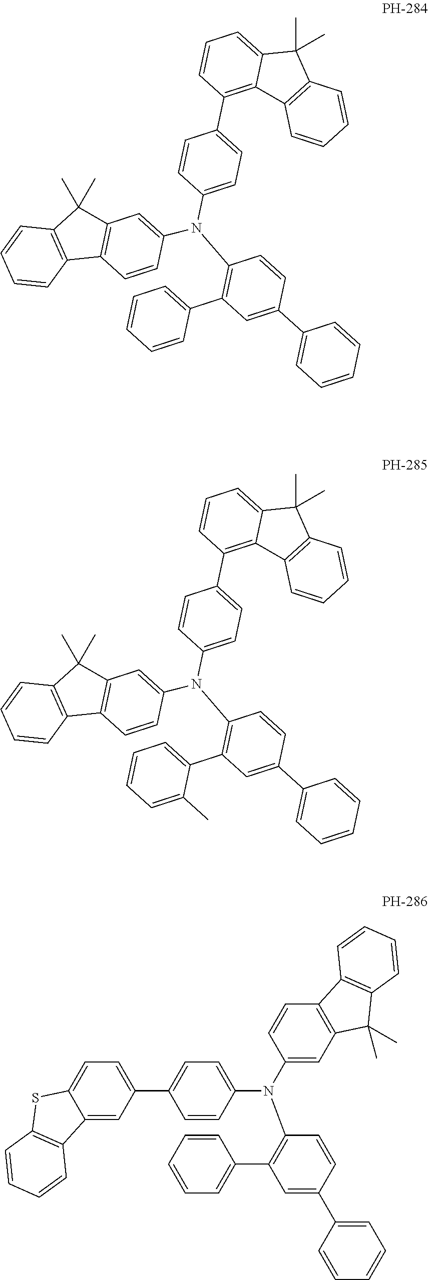 [SMILES: CC1(C)c2ccccc2-c2ccc(N(c3ccc(-c4cccc5c4-c4ccccc4C5(C)C)cc3)c3ccc(-c4ccccc4)cc3-c3ccccc3)cc21 ; Cc1ccccc1-c1cc(-c2ccccc2)ccc1N(c1ccc(-c2cccc3c2-c2ccccc2C3(C)C)cc1)c1ccc2c(c1)C(C)(C)c1ccccc1-2 ; CC1(C)c2ccccc2-c2ccc(N(c3ccc(-c4ccc5sc6ccccc6c5c4)cc3)c3ccc(-c4ccccc4)cc3-c3ccccc3)cc21]

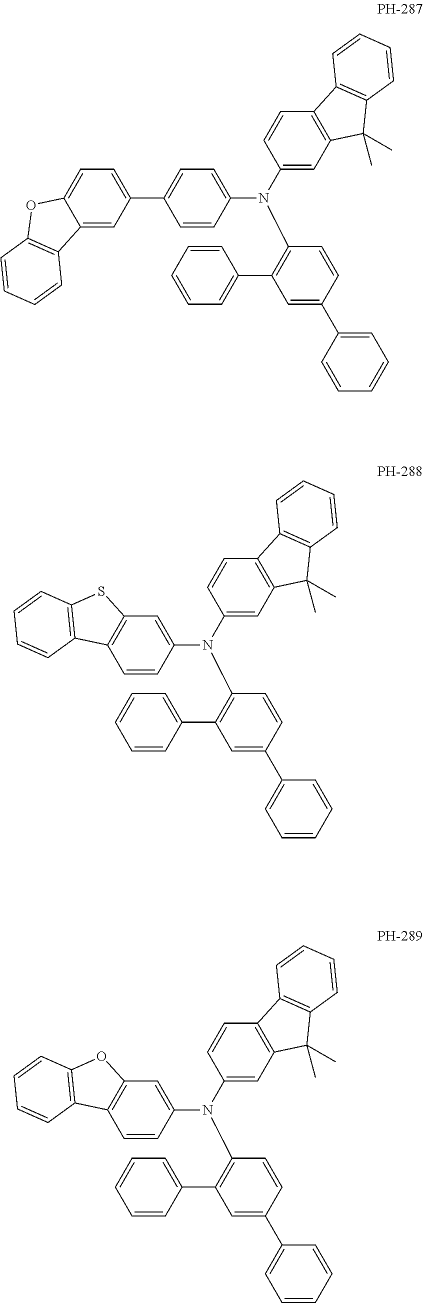 [SMILES: CC1(C)c2ccccc2-c2ccc(N(c3ccc(-c4ccc5oc6ccccc6c5c4)cc3)c3ccc(-c4ccccc4)cc3-c3ccccc3)cc21 ; CC1(C)c2ccccc2-c2ccc(N(c3ccc4c(c3)sc3ccccc34)c3ccc(-c4ccccc4)cc3-c3ccccc3)cc21 ; CC1(C)c2ccccc2-c2ccc(N(c3ccc4c(c3)oc3ccccc34)c3ccc(-c4ccccc4)cc3-c3ccccc3)cc21]

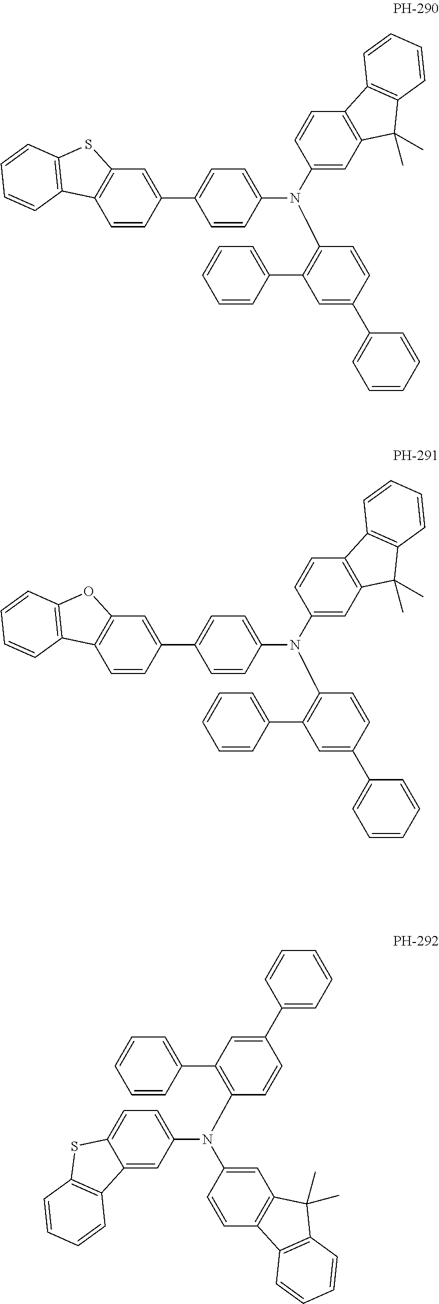 [SMILES: CC1(C)c2ccccc2-c2ccc(N(c3ccc(-c4ccc5c(c4)sc4ccccc45)cc3)c3ccc(-c4ccccc4)cc3-c3ccccc3)cc21 ; CC1(C)c2ccccc2-c2ccc(N(c3ccc(-c4ccc5c(c4)oc4ccccc45)cc3)c3ccc(-c4ccccc4)cc3-c3ccccc3)cc21 ; CC1(C)c2ccccc2-c2ccc(N(c3ccc4sc5ccccc5c4c3)c3ccc(-c4ccccc4)cc3-c3ccccc3)cc21]

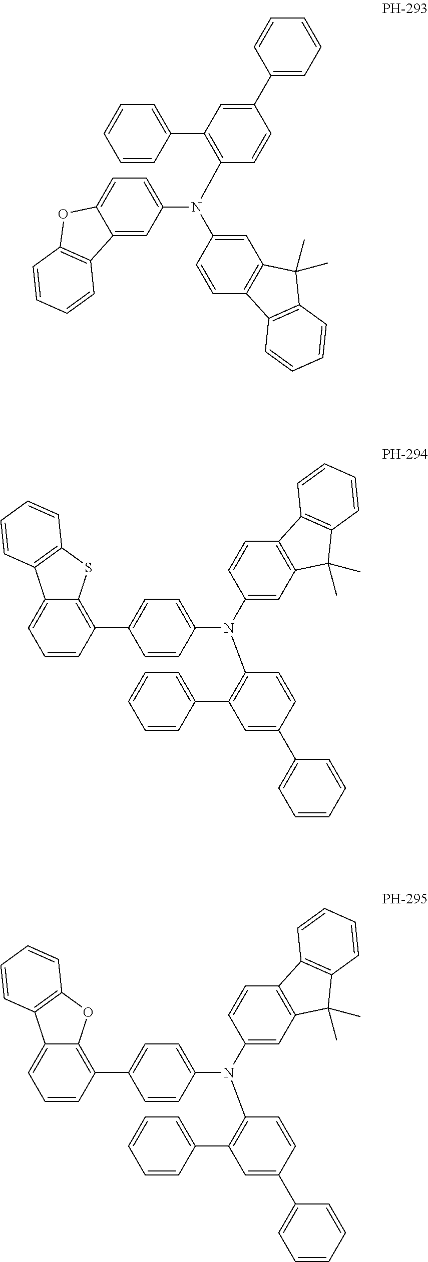 [SMILES: CC1(C)c2ccccc2-c2ccc(N(c3ccc4oc5ccccc5c4c3)c3ccc(-c4ccccc4)cc3-c3ccccc3)cc21 ; CC1(C)c2ccccc2-c2ccc(N(c3ccc(-c4cccc5c4sc4ccccc45)cc3)c3ccc(-c4ccccc4)cc3-c3ccccc3)cc21 ; CC1(C)c2ccccc2-c2ccc(N(c3ccc(-c4cccc5c4oc4ccccc45)cc3)c3ccc(-c4ccccc4)cc3-c3ccccc3)cc21]

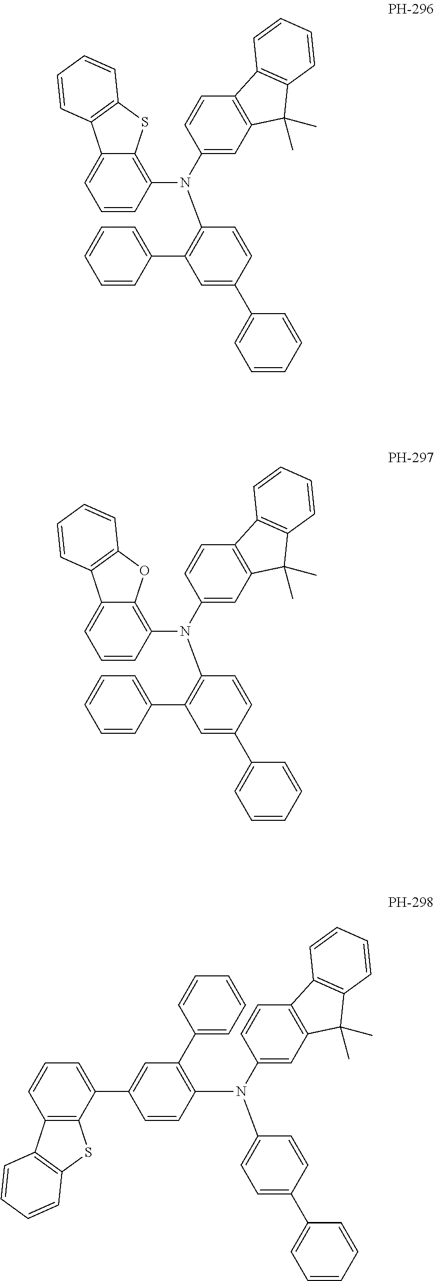 [SMILES: CC1(C)c2ccccc2-c2ccc(N(c3ccc(-c4ccccc4)cc3-c3ccccc3)c3cccc4c3sc3ccccc34)cc21 ; CC1(C)c2ccccc2-c2ccc(N(c3ccc(-c4ccccc4)cc3-c3ccccc3)c3cccc4c3oc3ccccc34)cc21 ; CC1(C)c2ccccc2-c2ccc(N(c3ccc(-c4ccccc4)cc3)c3ccc(-c4cccc5c4sc4ccccc45)cc3-c3ccccc3)cc21]

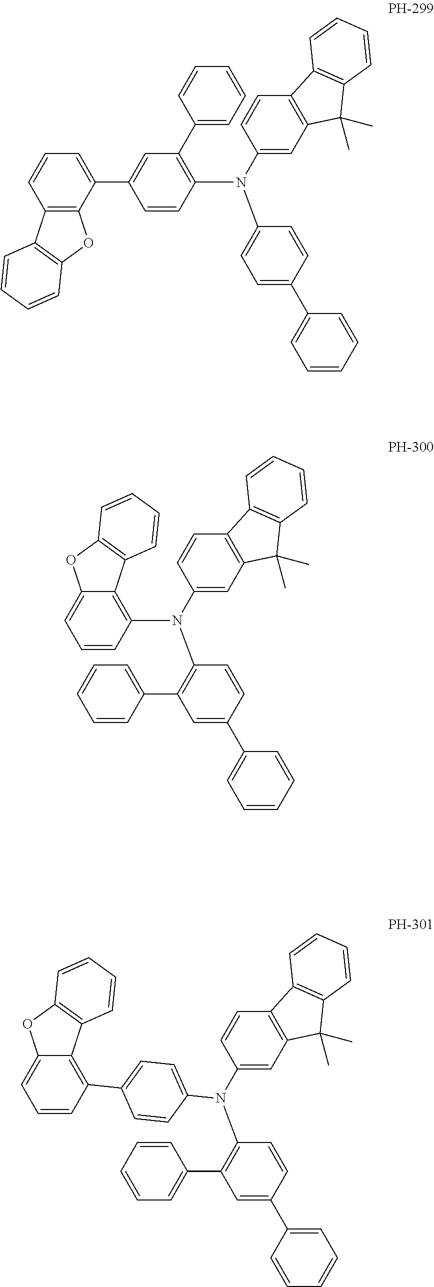 [SMILES: CC1(C)c2ccccc2-c2ccc(N(c3ccc(-c4ccccc4)cc3)c3ccc(-c4cccc5c4oc4ccccc45)cc3-c3ccccc3)cc21 ; CC1(C)c2ccccc2-c2ccc(N(c3ccc(-c4ccccc4)cc3-c3ccccc3)c3cccc4oc5ccccc5c34)cc21 ; CC1(C)c2ccccc2-c2ccc(N(c3ccc(-c4cccc5oc6ccccc6c45)cc3)c3ccc(-c4ccccc4)cc3-c3ccccc3)cc21]

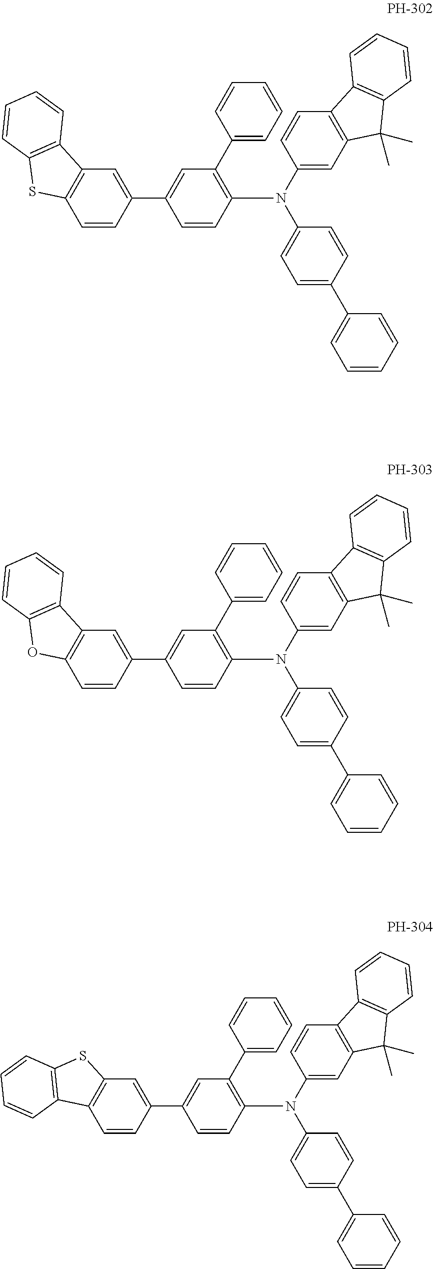 [SMILES: CC1(C)c2ccccc2-c2ccc(N(c3ccc(-c4ccccc4)cc3)c3ccc(-c4ccc5sc6ccccc6c5c4)cc3-c3ccccc3)cc21 ; CC1(C)c2ccccc2-c2ccc(N(c3ccc(-c4ccccc4)cc3)c3ccc(-c4ccc5oc6ccccc6c5c4)cc3-c3ccccc3)cc21 ; CC1(C)c2ccccc2-c2ccc(N(c3ccc(-c4ccccc4)cc3)c3ccc(-c4ccc5c(c4)sc4ccccc45)cc3-c3ccccc3)cc21]

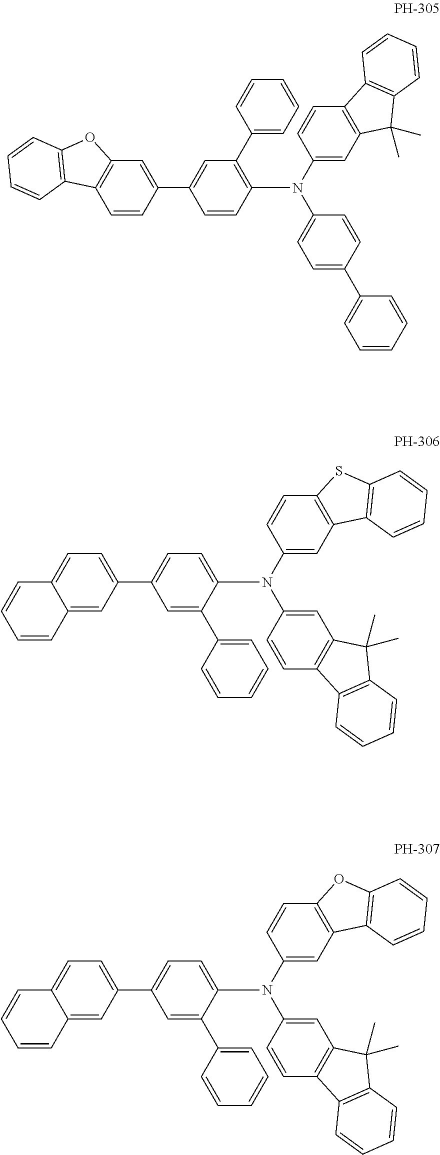 [SMILES: CC1(C)c2ccccc2-c2ccc(N(c3ccc(-c4ccccc4)cc3)c3ccc(-c4ccc5c(c4)oc4ccccc45)cc3-c3ccccc3)cc21 ; CC1(C)c2ccccc2-c2ccc(N(c3ccc4sc5ccccc5c4c3)c3ccc(-c4ccc5ccccc5c4)cc3-c3ccccc3)cc21 ; CC1(C)c2ccccc2-c2ccc(N(c3ccc4oc5ccccc5c4c3)c3ccc(-c4ccc5ccccc5c4)cc3-c3ccccc3)cc21]

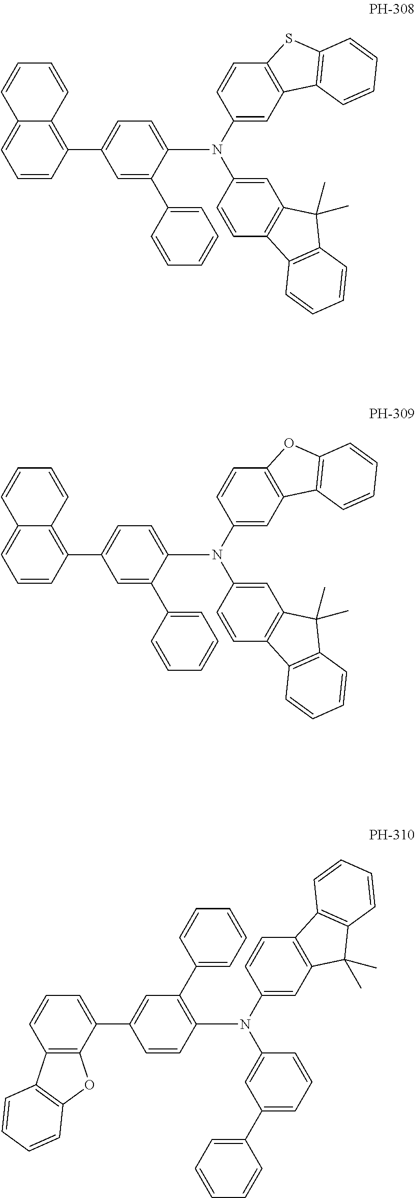 [SMILES: CC1(C)c2ccccc2-c2ccc(N(c3ccc4sc5ccccc5c4c3)c3ccc(-c4cccc5ccccc45)cc3-c3ccccc3)cc21 ; CC1(C)c2ccccc2-c2ccc(N(c3ccc4oc5ccccc5c4c3)c3ccc(-c4cccc5ccccc45)cc3-c3ccccc3)cc21 ; CC1(C)c2ccccc2-c2ccc(N(c3cccc(-c4ccccc4)c3)c3ccc(-c4cccc5c4oc4ccccc45)cc3-c3ccccc3)cc21]

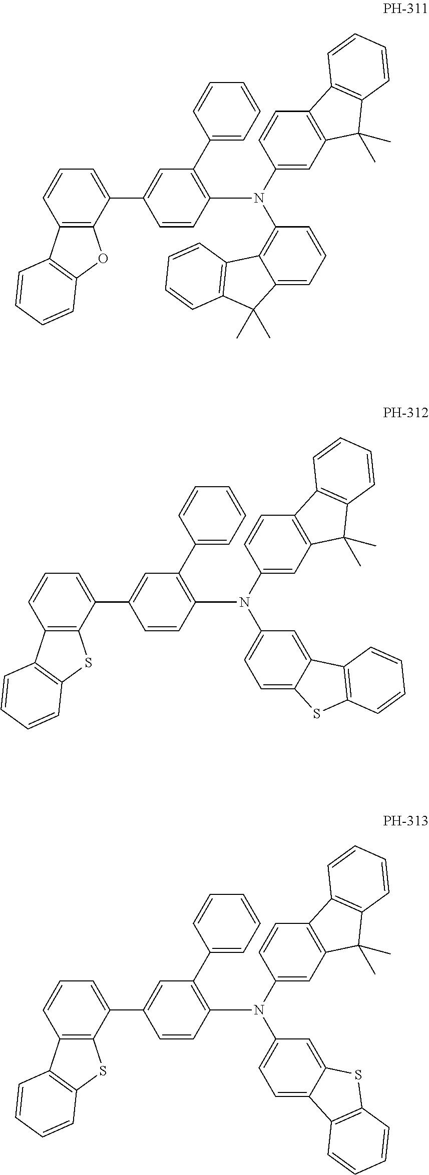 [SMILES: CC1(C)c2ccccc2-c2ccc(N(c3ccc(-c4cccc5c4oc4ccccc45)cc3-c3ccccc3)c3cccc4c3-c3ccccc3C4(C)C)cc21 ; CC1(C)c2ccccc2-c2ccc(N(c3ccc4sc5ccccc5c4c3)c3ccc(-c4cccc5c4sc4ccccc45)cc3-c3ccccc3)cc21 ; CC1(C)c2ccccc2-c2ccc(N(c3ccc4c(c3)sc3ccccc34)c3ccc(-c4cccc5c4sc4ccccc45)cc3-c3ccccc3)cc21]

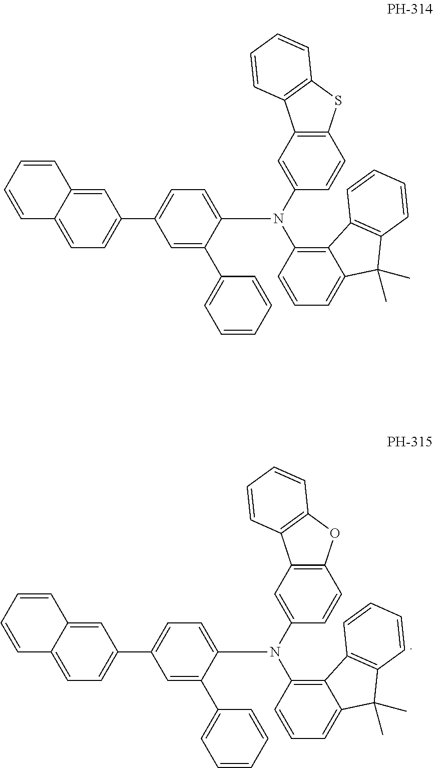 [SMILES: CC1(C)c2ccccc2-c2c(N(c3ccc4sc5ccccc5c4c3)c3ccc(-c4ccc5ccccc5c4)cc3-c3ccccc3)cccc21 ; CC1(C)c2ccccc2-c2c(N(c3ccc4oc5ccccc5c4c3)c3ccc(-c4ccc5ccccc5c4)cc3-c3ccccc3)cccc21]

13. The organic light-emitting device of claim 8, wherein the first compound is contained in 1 to 10 wt % when a weight of the second compound is 100 wt %.

14. An organic light-emitting display device comprising:
a substrate;
a driving device positioned on the substrate; and
the organic light-emitting device, according to claim 1, positioned on the substrate and connected to the driving device.
